(19) United States
(12) Patent Application Publication
(10) Pub. No.: US 2026/0082761 A1
(43) Pub. Date: Mar. 19, 2026

(54) PLURALITY OF HOST MATERIALS, AN ORGANIC ELECTROLUMINESCENT COMPOUND, AND ORGANIC ELECTROLUMINESCENT DEVICE COMPRISING THE SAME

(71) Applicant: DuPont Specialty Materials Korea Ltd., Chungcheongnam-do (KR)

(72) Inventors: Hyo-Jung LEE, Gyeonggi-do (KR); So-Young JUNG, Gyeonggi-do (KR); Du-Yong PARK, Gyeonggi-do (KR); Sang-Hee CHO, Gyeonggi-do (KR); Hee-Ryong KANG, Gyeonggi-do (KR); Hyun-Ju KANG, Gyeonggi-do (KR); Mi-Ran SEO, Gyeonggi-do (KR); Ji-Song JUN, Gyeonggi-do (KR)

(21) Appl. No.: 19/302,857

(22) Filed: Aug. 18, 2025

(30) Foreign Application Priority Data
Sep. 19, 2024 (KR) 10-2024-0126385

(51) Int. Cl. H10K 50/11; C09K 11/06; H10K 85/30; H10K 85/60; H10K 101/00

(52) U.S. Cl. CPC H10K 50/11; C09K 11/06; H10K 85/342; H10K 85/622; H10K 85/626; H10K 85/633; H10K 85/636; H10K 85/654; H10K 85/656; H10K 85/6572; H10K 85/6574; H10K 85/6576; C09K 2211/1029; C09K 2211/1088; H10K 2101/90

(57) ABSTRACT

The present disclosure relates to a plurality of host materials, an organic electroluminescent compound, and an organic electroluminescent device comprising the same. By comprising the compound according to the present disclosure or by comprising a specific combination of compounds according to the present disclosure as a plurality of host materials, it is possible to produce an organic electroluminescent device having improved luminous efficiency and/or lifetime properties compared to conventional organic electroluminescent devices.

### TECHNICAL FIELD

The present disclosure relates to a plurality of host materials, an organic electroluminescent compound, and an organic electroluminescent device comprising the same.

### BACKGROUND ART

A small molecular green organic electroluminescent device (OLED) was first developed by Tang et al. of Eastman Kodak in 1987 by using TPD/ALq3 bi-layer consisting of a light-emitting layer and a charge transport layer. Thereafter, the development of OLEDs was rapidly effected, and OLEDs have been commercialized. At present, OLEDs primarily use phosphorescent materials having excellent luminous efficiency in panel implementation. However, in many applications such as TVs and lightings, the lifetime of OLEDs is insufficient, and higher OLED efficiency is still required. Typically, as the luminance of an OLED increases, the lifetime that the OLED has decreases. Therefore, an OLED having high luminous efficiency and/or long lifetime characteristics is required for long-term use and high display resolution.

In order to enhance luminous efficiency, driving voltage, and/or lifetime, various materials or concepts for an organic layer of an OLED have been proposed. However, these were not satisfactory in practical use. Accordingly, there is a continuous demand for developing organic electroluminescent devices having improved performance, such as improved driving voltage, luminous efficiency, power efficiency, and/or lifetime properties, compared to conventional organic electroluminescent devices.

Meanwhile, Korean Patent Application Laid-Open Nos. 10-2021-0076837, 10-2022-0163858, and 10-2021-0080183 disclose organic electroluminescent compounds having a phenanthro-benzofuran structure and organic electroluminescent devices using the same, or a plurality of host materials comprising compounds having a phenanthro-benzofuran structure as a host and organic electroluminescent devices using the same. Nevertheless, as described herein, there is no disclosure of an organic electroluminescent device having improved performance, such as low driving voltage and/or high luminous efficiency and/or long lifetime properties, by including an organic electroluminescent compound having a specific substituent at a specific position or a plurality of host materials in a specific combination.

### DISCLOSURE OF INVENTION

### Technical Problem

The objective of the present disclosure is to provide an organic electroluminescent compound with a new structure suitable for application to an organic electroluminescent device. Another objective of the present disclosure is to provide an organic electroluminescent device having lower driving voltage, higher efficiency, and/or improved lifetime properties by comprising a plurality of host materials including a specific combination of compounds.

### Solution to Problem

As a result of intensive study to solve the technical problems, the present inventors found that the above objective can be achieved by a plurality of host materials comprising at least one first host compound and at least one second host compound, wherein the first host compound comprises a compound represented by the following Formula 1 and the second host compound comprises a compound represented by the following Formula 2; or an organic electroluminescent compound represented by the following Formula 1′.

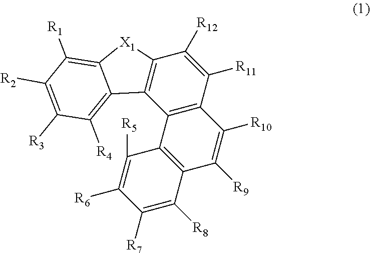

wherein in Formula 1,
X₁ represents O, S, or CR₁₃R₁₄;
R₁₃ and R₁₄ each independently represent a substituted or unsubstituted (C₁-C₃₀)alkyl, a substituted or unsubstituted (C₆-C₃₀)aryl, or a substituted or unsubstituted (3- to 30-membered)heteroaryl, or R₁₃ and R₁₄ may be linked to each other to form a ring(s);
R₁ to R₁₂ each independently represent hydrogen, deuterium, a halogen, a cyano, a substituted or unsubstituted (C₁-C₃₀)alkyl, a substituted or unsubstituted (C₂-C₃₀)alkenyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₃-C₃₀)cycloalkenyl, a substituted or unsubstituted (3- to 7-membered)heterocycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted fused ring of (C₃-C₃₀) aliphatic ring(s) and (C₆-C₃₀) aromatic ring(s), a substituted or unsubstituted mono- or di-(C₁-C₃₀)alkylamino, a substituted or unsubstituted mono- or di-(C₆-C₃₀)arylamino, a substituted or unsubstituted (C₁-C₃₀)alkyl(C₆-C₃₀)arylamino, a substituted or unsubstituted mono- or di-(3- to 30-membered)heteroarylamino, or a substituted or unsubstituted (C₆-C₃₀)aryl(3- to 30-membered)heteroarylamino; or may be linked to the adjacent substituent(s) to form a ring(s);
with a proviso that at least one of R₁ to R₁₂ represents the following Formula 1-a;

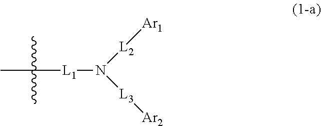

wherein in Formula 1-a,

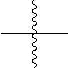

is a site linked to at least one of R₁ to R₁₂;
L₁ to L₃ each independently represent a single bond, a substituted or unsubstituted (C₆-C₃₀)arylene, a substituted or unsubstituted (3- to 30-membered)heteroarylene, or a substituted or unsubstituted (C₃-C₃₀)cycloalkylene;
Ar₁ and Ar₂ each independently represent a substituted or unsubstituted (C₆-C₃₀)aryl, a substituted or unsubstituted (3- to 30-membered)heteroaryl, or a substituted or unsubstituted (C₃-C₃₀)cycloalkyl;

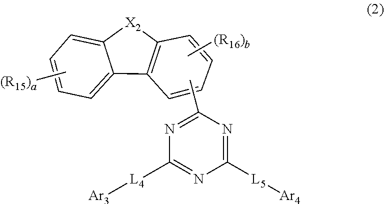

wherein in Formula 2,
X₂ represents O, S, or Se;
L₄ and L₅ each independently represent a single bond, a substituted or unsubstituted (C₆-C₃₀)arylene, or a substituted or unsubstituted (3- to 30-membered)heteroarylene;
Ar₃ and Ar₄ each independently represent a substituted or unsubstituted (C₆-C₃₀)aryl or a substituted or unsubstituted (3- to 30-membered)heteroaryl;
R₁₅ and R₁₆ each independently represent hydrogen, deuterium, a halogen, a cyano, a substituted or unsubstituted (C₁-C₃₀)alkyl, a substituted or unsubstituted (C₂-C₃₀)alkenyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₃-C₃₀)cycloalkenyl, a substituted or unsubstituted (3- to 7-membered)heterocycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted fused ring of (C₃-C₃₀) aliphatic ring(s) and (C₆-C₃₀) aromatic ring(s), a substituted or unsubstituted mono- or di-(C₁-C₃₀)alkylamino, a substituted or unsubstituted mono- or di-(C₆-C₃₀)arylamino, a substituted or unsubstituted (C₁-C₃₀)alkyl(C₆-C₃₀)arylamino, a substituted or unsubstituted mono- or di-(3- to 30-membered)heteroarylamino, or a substituted or unsubstituted (C₆-C₃₀)aryl(3- to 30-membered)heteroarylamino; or may be linked to the adjacent substituent(s) to form a ring(s);
a represents an integer of 1 to 4, b represents an integer of 1 to 3, and when each a and b are an integer of 2 or more, each of R₁₅ and each of R₁₆ may be the same or different;
with a proviso that when both R₁₅ and R₁₆ of Formula 2 are hydrogen or deuterium, at least one of R₁ to R₁₂ of Formula 1 represents Formula 1-a and at least one of the others represents a substituted or unsubstituted (C₆-C₃₀)aryl or a substituted or unsubstituted (3- to 30-membered)heteroaryl.

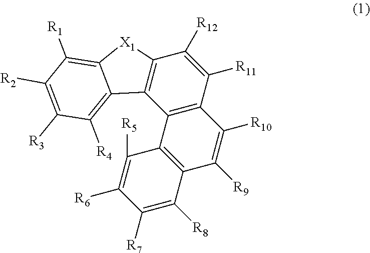

In Formula 1′,
X₁ represents O, S, or CR₁₃R₁₄;
R₁₃ and R₁₄ each independently represent a substituted or unsubstituted (C₁-C₃₀)alkyl, a substituted or unsubstituted (C₆-C₃₀)aryl, or a substituted or unsubstituted (3- to 30-membered)heteroaryl, or R₁₃ and R₁₄ may be linked to each other to form a ring(s);
R₁ to R₁₂ each independently represent hydrogen, deuterium, a halogen, a cyano, a substituted or unsubstituted (C₁-C₃₀)alkyl, a substituted or unsubstituted (C₂-C₃₀)alkenyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₃-C₃₀)cycloalkenyl, a substituted or unsubstituted (3- to 7-membered)heterocycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted fused ring of (C₃-C₃₀) aliphatic ring(s) and (C₆-C₃₀) aromatic ring(s), a substituted or unsubstituted mono- or di-(C₁-C₃₀)alkylamino, a substituted or unsubstituted mono- or di-(C₆-C₃₀)arylamino, a substituted or unsubstituted (C₁-C₃₀)alkyl(C₆-C₃₀)arylamino, a substituted or unsubstituted mono- or di-(3- to 30-membered)heteroarylamino, or a substituted or unsubstituted (C₆-C₃₀)aryl(3- to 30-membered)heteroarylamino; or may be linked to the adjacent substituent(s) to form a ring(s);
wherein at least one of R₉ and R₁₀ represents a substituted or unsubstituted (C₆-C₃₀)aryl or a substituted or unsubstituted (C₆-C₃₀)heteroaryl;
with a proviso that at least one of R₁ to R₁₂ represents the following Formula 1′-a:

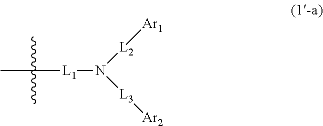

wherein in Formula 1′-a,

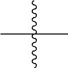

L₁ to L₃ each independently represent a single bond, a substituted or unsubstituted (C₆-C₃₀)arylene, a substituted or unsubstituted (3- to 30-membered)heteroarylene, or a substituted or unsubstituted (C₃-C₃₀)cycloalkylene; and
Ar₁ and Ar₂ each independently represent a substituted or unsubstituted (C₆-C₃₀)aryl, a substituted or unsubstituted (3- to 30-membered)heteroaryl, or a substituted or unsubstituted (C₃-C₃₀)cycloalkyl.

### Advantageous Effects of Invention

An organic electroluminescent device with improved driving voltage, luminous efficiency, and/or lifetime properties can be provided by comprising compounds according to the present disclosure as host materials. In addition, an organic electroluminescent compound according to the present disclosure exhibits performance suitable for use in an organic electroluminescent device, and it is possible to manufacture a display device or lighting device using the same.

### MODE FOR INVENTION

Hereinafter, the present disclosure will be described in detail. However, the following description is intended to explain the present disclosure, and is not meant to restrict the scope of the present disclosure.

The “organic electroluminescent compound” in the present disclosure refers to a compound that may be used in an organic electroluminescent device, and may be incorporated into any layer constituting an organic electroluminescent device, as necessary.

The “organic electroluminescent material” in the present disclosure refers to a material that may be used in an organic electroluminescent device, and may comprise at least one compound. The organic electroluminescent material may be incorporated into any layer constituting an organic electroluminescent device, as necessary. For example, the organic electroluminescent material may be any of the following: a hole injection material, a hole transport material, a hole auxiliary material, a light-emitting auxiliary material, an electron-blocking material, a light-emitting material (including a host material and a dopant material), an electron buffer material, a hole-blocking material, an electron transport material, an electron injection material, etc.

The “plurality of host materials” in the present disclosure means a host material comprising a combination of at least two compounds, which may be comprised in any light-emitting layer constituting an organic electroluminescent device. It may mean both a material before being comprised in an organic electroluminescent device (for example, before vapor deposition) and a material after being comprised in an organic electroluminescent device (for example, after vapor deposition). For example, the plurality of host materials of the present disclosure is a combination of at least two host materials, and may selectively further comprise conventional materials comprised in an organic electroluminescent material. At least two compounds comprised in the plurality of host materials of the present disclosure may be comprised together in one light-emitting layer or may respectively be comprised in different light-emitting layers. For example, the at least two host materials may be mixture-evaporated or co-evaporated, or may be individually evaporated.

Herein, the “(C₁-C₃₀)alkyl” is meant to be a linear or branched alkyl having 1 to 30 carbon atoms constituting the chain, in which the number of carbon atoms is preferably 1 to 10, and more preferably 1 to 6. The above alkyl may include methyl, ethyl, n-propyl, isopropyl, n-butyl, isobutyl, tert-butyl, sec-butyl, etc. The “(C₃-C₃₀)cycloalkyl” is meant to be a mono- or polycyclic hydrocarbon having 3 to 30 ring backbone carbon atoms, in which the number of carbon atoms is preferably 3 to 20, and more preferably 3 to 7. The above cycloalkyl may include cyclopropyl, cyclobutyl, cyclopentyl, cyclohexyl, cyclopentylmethyl, cyclohexylmethyl, etc. The “(3- to 7-membered)heterocycloalkyl” is meant to be a cycloalkyl having 3 to 7 ring backbone atoms, and including at least one heteroatom selected from the group consisting of B, N, O, S, Si, and P, and preferably the group consisting of O, S, and N. The above heterocycloalkyl may include tetrahydrofuran, pyrrolidine, thiolan, tetrahydropyran, etc. The “(C₆-C₃₀)aryl” and “(C₆-C₃₀)arylene” are meant to be a monocyclic or fused ring radical derived from an aromatic hydrocarbon having 6 to 30 ring backbone carbon atoms. The above aryl and arylene may be partially saturated, and may comprise a spiro structure. The above aryl may include phenyl, biphenyl, terphenyl, quinquephenyl, naphthyl, binaphthyl, phenylnaphthyl, naphthylphenyl, fluorenyl, phenylfluorenyl, diphenylfluorenyl, benzofluorenyl, dibenzofluorenyl, phenanthrenyl, phenylphenanthrenyl, benzophenanthrenyl, anthracenyl, indenyl, triphenylenyl, pyrenyl, tetracenyl, perylenyl, chrysenyl, naphthacenyl, fluoranthenyl, spirobifluorenyl, spiro[fluorene-benzofluoren]yl, spiro[cyclopentene-fluoren]yl, spiro[dihydroindene-fluoren]yl, azulenyl, tetramethyldihydrophenanthrenyl, etc. Specifically, the above aryl may include phenyl, 1-naphthyl, 2-naphthyl, 1-anthryl, 2-anthryl, 9-anthryl, benzanthryl, 1-phenanthryl, 2-phenanthryl, 3-phenanthryl, 4-phenanthryl, 9-phenanthryl, naphthacenyl, pyrenyl, 1-chrysenyl, 2-chrysenyl, 3-chrysenyl, 4-chrysenyl, 5-chrysenyl, 6-chrysenyl, benzo[c]phenanthryl, benzo[g]chrysenyl, 1-triphenylenyl, 2-triphenylenyl, 3-triphenylenyl, 4-triphenylenyl, 1-fluorenyl, 2-fluorenyl, 3-fluorenyl, 4-fluorenyl, 9-fluorenyl, benzo[a]fluorenyl, benzo[b]fluorenyl, benzo[c]fluorenyl, dibenzofluorenyl, 2-biphenyl, 3-biphenyl, 4-biphenyl, o-terphenyl, m-terphenyl-4-yl, m-terphenyl-3-yl, m-terphenyl-2-yl, p-terphenyl-4-yl, p-terphenyl-3-yl, p-terphenyl-2-yl, m-quaterphenyl, 3-fluoranthenyl, 4-fluoranthenyl, 8-fluoranthenyl, 9-fluoranthenyl, benzofluoranthenyl, o-tolyl, m-tolyl, p-tolyl, 2,3-xylyl, 3,4-xylyl, 2,5-xylyl, mesityl, o-cumenyl, m-cumenyl, p-cumenyl, p-tert-butylphenyl, p-(2-phenylpropyl)phenyl, 4′-methylbiphenyl, 4″-tert-butyl-p-terphenyl-4-yl, 9,9-dimethyl-1-fluorenyl, 9,9-dimethyl-2-fluorenyl, 9,9-dimethyl-3-fluorenyl, 9,9-dimethyl-4-fluorenyl, 9,9-diphenyl-1-fluorenyl, 9,9-diphenyl-2-fluorenyl, 9,9-diphenyl-3-fluorenyl, 9,9-diphenyl-4-fluorenyl, 11,11-dimethyl-1-benzo[a]fluorenyl, 11,11-dimethyl-2-benzo[a]fluorenyl, 11,11-dimethyl-3-benzo[a]fluorenyl, 11,11-dimethyl-4-benzo[a]fluorenyl, 11,11-dimethyl-5-benzo[a]fluorenyl, 11,11-dimethyl-6-benzo[a]fluorenyl, 11,11-dimethyl-7-benzo[a]fluorenyl, 11,11-dimethyl-8-benzo[a]fluorenyl, 11,11-dimethyl-9-benzo[b]fluorenyl, 11,11-dimethyl-10-benzo[a]fluorenyl, 11,11-dimethyl-1-benzo[b]fluorenyl, 11,11-dimethyl-2-benzo[b]fluorenyl, 11,11-dimethyl-3-benzo[b]fluorenyl, 11,11-dimethyl-4-benzo[b]fluorenyl, 11,11-dimethyl-5-benzo[b]fluorenyl, 11,11-dimethyl-6-benzo[b]fluorenyl, 11,11-dimethyl-7-benzo[b]fluorenyl, 11,11-dimethyl-8-benzo[b]fluorenyl, 11,11-dimethyl-9-benzo[b]fluorenyl, 11,11-dimethyl-10-benzo[b]fluorenyl, 11,11-dimethyl-1-benzo[c]fluorenyl, 11,11-dimethyl-2-benzo[c]fluorenyl, 11,11-dimethyl-3-benzo[c]fluorenyl, 11,11-dimethyl-4-benzo[c]fluorenyl, 11,11-dimethyl-5-benzo[c]fluorenyl, 11,11-dimethyl-6-benzo[c]fluorenyl, 11,11-dimethyl-7-benzo[c]fluorenyl, 11,11-dimethyl-8-benzo[c]fluorenyl, 11,11-dimethyl-9-benzo[c]fluorenyl, 11,11-dimethyl-10-benzo[c]fluorenyl, 11,11-diphenyl-1-benzo[a]fluorenyl, 11,11-diphenyl-2-benzo[a]fluorenyl, 11,11-diphenyl-3-benzo[a]fluorenyl, 11,11-diphenyl-4-benzo[a]fluorenyl, 11,11-diphenyl-5-benzo[a]fluorenyl, 11,11-diphenyl-6-benzo[a]fluorenyl, 11,11-diphenyl-7-benzo[a]fluorenyl, 11,11-diphenyl-8-benzo[a]fluorenyl, 11,11-diphenyl-9-benzo[a]fluorenyl, 11,11-diphenyl-10-benzo[a]fluorenyl, 11,11-diphenyl-1-benzo[b]fluorenyl, 11,11-diphenyl-2-benzo[b]fluorenyl, 11,11-diphenyl-3-benzo[b]fluorenyl, 11,11-diphenyl-4-benzo[b]fluorenyl, 11,11-diphenyl-5-benzo[b]fluorenyl, 11,11-diphenyl-6-benzo[b]fluorenyl, 11,11-diphenyl-7-benzo[b]fluorenyl, 11,11-diphenyl-8-benzo[b]fluorenyl, 11,11-diphenyl-9-benzo[b]fluorenyl, 11,11-diphenyl-10-benzo[b]fluorenyl, 11,11-diphenyl-1-benzo[c]fluorenyl, 11,11-diphenyl-2-benzo[c]fluorenyl, 11,11-diphenyl-3-benzo[c]fluorenyl, 11,11-diphenyl-4-benzo[c]fluorenyl, 11,11-diphenyl-5-benzo[c]fluorenyl, 11,11-diphenyl-6-benzo[c]fluorenyl, 11,11-diphenyl-7-benzo[c]fluorenyl, 11,11-diphenyl-8-benzo[c]fluorenyl, 11,11-diphenyl-9-benzo[c]fluorenyl, 11,11-diphenyl-10-benzo[c]fluorenyl, 9,9,10,10-tetramethyl-9,10-dihydro-1-phenanthrenyl, 9,9,10,10-tetramethyl-9,10-dihydro-2-phenanthrenyl, 9,9,10,10-tetramethyl-9,10-dihydro-3-phenanthrenyl, 9,9,10,10-tetramethyl-9,10-dihydro-4-phenanthrenyl, etc.

The “(3- to 30-membered)heteroaryl” and “(3- to 30-membered)heteroarylene” are meant to be an aryl group having 3 to 30 ring backbone atoms, and including at least one, preferably 1 to 4 heteroatoms selected from the group consisting of B, N, O, S, Si, P, Se, Te, and Ge. The above heteroaryl may be a monocyclic ring, or a fused ring condensed with at least one benzene ring; may be partially saturated; may be one formed by linking at least one heteroaryl or aryl group to a heteroaryl group via a single bond(s); and may comprise a spiro structure. The above heteroaryl may include a monocyclic ring-type heteroaryl such as furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, and pyridazinyl, and a fused ring-type heteroaryl such as benzofuranyl, benzothiophenyl, isobenzofuranyl, dibenzofuranyl, dibenzothiophenyl, dibenzoselenophenyl, naphthobenzothiophenyl, naphthobenzofuranyl, naphthooxazolyl, benzofuroquinolinyl, benzofuroquinazolinyl, benzofuronaphthyridinyl, benzofuropyrimidinyl, naphthofuropyrimidinyl, benzothienoquinolyl, benzothienoquinazolinyl, naphthyridinyl, benzothienonaphthyridinyl, benzothienopyrimidinyl, naphthothienopyrimidinyl, pyrimidoindolyl, benzopyrimidoindolyl, benzofuropyrazinyl, naphthofuropyrazinyl, benzothienopyrazinyl, naphthothienopyrazinyl, phenanthrooxazolyl, phenanthrothiazolyl, phenanthrobenzofuranyl, benzophenanthrothiophenyl, pyrazinoindolyl, benzopyrazinoindolyl, benzimidazolyl, benzothiazolyl, benzoisothiazolyl, benzoisoxazolyl, benzoxazolyl, isoindolyl, indolyl, indazolyl, benzothiadiazolyl, quinolyl, isoquinolyl, cinnolinyl, quinazolinyl, benzoquinazolinyl, quinoxalinyl, benzoquinoxalinyl, carbazolyl, benzocarbazolyl, dibenzocarbazolyl, phenoxazinyl, phenanthridinyl, benzodioxolyl, dihydroacridinyl, benzotriazolyl, phenazinyl, imidazopyridyl, chromenoquinazolinyl, thiochromenoquinazolinyl, dimethylbenzoperimidinyl, indolocarbazolyl, indenocarbazolyl, etc. More specifically, the above heteroaryl may include 1-pyrrolyl, 2-pyrrolyl, 3-pyrrolyl, pyrazinyl, 2-pyridyl, 2-pyrimidinyl, 4-pyrimidinyl, 5-pyrimidinyl, 6-pyrimidinyl, 1,2,3-triazin-4-yl, 1,2,4-triazin-3-yl, 1,3,5-triazin-2-yl, 1-imidazolyl, 2-imidazolyl, 1-pyrazolyl, 1-indolidinyl, 2-indolidinyl, 3-indolidinyl, 5-indolidinyl, 6-indolidinyl, 7-indolidinyl, 8-indolidinyl, 2-imidazopyridyl, 3-imidazopyridyl, 5-imidazopyridyl, 6-imidazopyridyl, 7-imidazopyridyl, 8-imidazopyridyl, 3-pyridyl, 4-pyridyl, 1-indolyl, 2-indolyl, 3-indolyl, 4-indolyl, 5-indolyl, 6-indolyl, 7-indolyl, 1-isoindolyl, 2-isoindolyl, 3-isoindolyl, 4-isoindolyl, 5-isoindolyl, 6-isoindolyl, 7-isoindolyl, 2-furyl, 3-furyl, 2-benzofuranyl, 3-benzofuranyl, 4-benzofuranyl, 5-benzofuranyl, 6-benzofuranyl, 7-benzofuranyl, 1-isobenzofuranyl, 3-isobenzofuranyl, 4-isobenzofuranyl, 5-isobenzofuranyl, 6-isobenzofuranyl, 7-isobenzofuranyl, 2-quinolyl, 3-quinolyl, 4-quinolyl, 5-quinolyl, 6-quinolyl, 7-quinolyl, 8-quinolyl, 1-isoquinolyl, 3-isoquinolyl, 4-isoquinolyl, 5-isoquinolyl, 6-isoquinolyl, 7-isoquinolyl, 8-isoquinolyl, 2-quinoxalinyl, 5-quinoxalinyl, 6-quinoxalinyl, 1-carbazolyl, 2-carbazolyl, 3-carbazolyl, 4-carbazolyl, 9-carbazolyl, azacarbazol-1-yl, azacarbazol-2-yl, azacarbazol-3-yl, azacarbazol-4-yl, azacarbazol-5-yl, azacarbazol-6-yl, azacarbazol-7-yl, azacarbazol-8-yl, azacarbazol-9-yl, 1-phenanthridinyl, 2-phenanthridinyl, 3-phenanthridinyl, 4-phenanthridinyl, 6-phenanthridinyl, 7-phenanthridinyl, 8-phenanthridinyl, 9-phenanthridinyl, 10-phenanthridinyl, 1-acridinyl, 2-acridinyl, 3-acridinyl, 4-acridinyl, 9-acridinyl, 2-oxazolyl, 4-oxazolyl, 5-oxazolyl, 2-oxadiazolyl, 5-oxadiazolyl, 3-furazanyl, 2-thienyl, 3-thienyl, 2-methylpyrrol-1-yl, 2-methylpyrrol-3-yl, 2-methylpyrrol-4-yl, 2-methylpyrrol-5-yl, 3-methylpyrrol-1-yl, 3-methylpyrrol-2-yl, 3-methylpyrrol-4-yl, 3-methylpyrrol-5-yl, 2-tert-butylpyrrol-4-yl, 3-(2-phenylpropyl) pyrrol-1-yl, 2-methyl-1-indolyl, 4-methyl-1-indolyl, 2-methyl-3-indolyl, 4-methyl-3-indolyl, 2-tert-butyl-1-indolyl, 4-tert-butyl-1-indolyl, 2-tert-butyl-3-indolyl, 4-tert-butyl-3-indolyl, 1-dibenzofuranyl, 2-dibenzofuranyl, 3-dibenzofuranyl, 4-dibenzofuranyl, 1-dibenzothiophenyl, 2-dibenzothiophenyl, 3-dibenzothiophenyl, 4-dibenzothiophenyl, 1-naphtho-[1,2-b]-benzofuranyl, 2-naphtho-[1,2-b]-benzofuranyl, 3-naphtho-[1,2-b]-benzofuranyl, 4-naphtho-[1,2-b]-benzofuranyl, 5-naphtho-[1,2-b]-benzofuranyl, 6-naphtho-[1,2-b]-benzofuranyl, 7-naphtho-[1,2-b]-benzofuranyl, 8-naphtho-[1,2-b]-benzofuranyl, 9-naphtho-[1,2-b]-benzofuranyl, 10-naphtho-[1,2-b]-benzofuranyl, 1-naphtho-[2,3-b]-benzofuranyl, 2-naphtho-[2,3-b]-benzofuranyl, 3-naphtho-[2,3-b]-benzofuranyl, 4-naphtho-[2,3-b]-benzofuranyl, 5-naphtho-[2,3-b]-benzofuranyl, 6-naphtho-[2,3-b]-benzofuranyl, 7-naphtho-[2,3-b]-benzofuranyl, 8-naphtho-[2,3-b]-benzofuranyl, 9-naphtho-[2,3-b]-benzofuranyl, 10-naphtho-[2,3-b]-benzofuranyl, 1-naphtho-[2,1-b]-benzofuranyl, 2-naphtho-[2,1-b]-benzofuranyl, 3-naphtho-[2,1-b]-benzofuranyl, 4-naphtho-[2,1-b]-benzofuranyl, 5-naphtho-[2,1-b]-benzofuranyl, 6-naphtho-[2,1-b]-benzofuranyl, 7-naphtho-[2,1-b]-benzofuranyl, 8-naphtho-[2,1-b]-benzofuranyl, 9-naphtho-[2,1-b]-benzofuranyl, 10-naphtho-[2,1-b]-benzofuranyl, 1-naphtho-[1,2-b]-benzothiophenyl, 2-naphtho-[1,2-b]-benzothiophenyl, 3-naphtho-[1,2-b]-benzothiophenyl, 4-naphtho-[1,2-b]-benzothiophenyl, 5-naphtho-[1,2-b]-benzothiophenyl, 6-naphtho-[1,2-b]-benzothiophenyl, 7-naphtho-[1,2-b]-benzothiophenyl, 8-naphtho-[1,2-b]-benzothiophenyl, 9-naphtho-[1,2-b]-benzothiophenyl, 10-naphtho-[1,2-b]-benzothiophenyl, 1-naphtho-[2,3-b]-benzothiophenyl, 2-naphtho-[2,3-b]-benzothiophenyl, 3-naphtho-[2,3-b]-benzothiophenyl, 4-naphtho-[2,3-b]-benzothiophenyl, 5-naphtho-[2,3-b]-benzothiophenyl, 1-naphtho-[2,1-b]-benzothiophenyl, 2-naphtho-[2,1-b]-benzothiophenyl, 3-naphtho-[2,1-b]-benzothiophenyl, 4-naphtho-[2,1-b]-benzothiophenyl, benzothiophenyl, 5-naphtho-[2,1-b]-benzothiophenyl, 6-naphtho-[2,1-b]-benzothiophenyl, 7-naphtho-[2,1-b]-benzothiophenyl, 8-naphtho-[2,1-b]-benzothiophenyl, 9-naphtho-[2,1-b]-benzothiophenyl, 10-naphtho-[2,1-b]-benzothiophenyl, 2-benzofuro[3,2-d]pyrimidinyl, 6-benzofuro[3,2-d]pyrimidinyl, 7-benzofuro[3,2-d]pyrimidinyl, 8-benzofuro[3,2-d]pyrimidinyl, 9-benzofuro[3,2-d]pyrimidinyl, 2-benzothio[3,2-d]pyrimidinyl, 6-benzothio[3,2-d]pyrimidinyl, 7-benzothio[3,2-d]pyrimidinyl, 8-benzothio[3,2-d]pyrimidinyl, 9-benzothio[3,2-d]pyrimidinyl, 2-benzofuro[3,2-d]pyrazinyl, 6-benzofuro[3,2-d]pyrazinyl, 7-benzofuro[3,2-d]pyrazinyl, 8-benzofuro[3,2-d]pyrazinyl, 9-benzofuro[3,2-d]pyrazinyl, 2-benzothio[3,2-d]pyrazinyl, 6-benzothio[3,2-d]pyrazinyl, 7-benzothio[3,2-d]pyrazinyl, 8-benzothio[3,2-d]pyrazinyl, 9-benzothio[3,2-d]pyrazinyl, 1-silafluorenyl, 2-silafluorenyl, 3-silafluorenyl, 4-silafluorenyl, 1-germafluorenyl, 2-germafluorenyl, 3-germafluorenyl, 4-germafluorenyl, 1-dibenzoselenophenyl, 2-dibenzoselenophenyl, 3-dibenzoselenophenyl, 4-dibenzoselenophenyl, etc. The “(3- to 30 membered)heteroaryl(ene)” can be classified into heteroaryl(ene) with electronic properties and heteroaryl(ene) with hole properties. Heteroaryl(ene) with electronic properties is a substituent that is relatively rich in electrons in the parent nucleus, for example, a substituted or unsubstituted pyridinyl, a substituted or unsubstituted pyrimidinyl, a substituted or unsubstituted triazinyl, a substituted or unsubstituted quinazolinyl, a substituted or unsubstituted quinoxalinyl, a substituted or unsubstituted quinolyl, etc. Heteroaryl(ene) with hole properties is a substituent that is relatively electron-deficient in the parent nucleus, for example, a substituted or unsubstituted carbazolyl, a substituted or unsubstituted dibenzofuranyl, a substituted or unsubstituted dibenzothiophenyl, etc. In the present disclosure, the “halogen” includes F, Cl, Br, and I.

In addition, “ortho-” (“o-”), “meta-” (“m-”), and “para-” (“p-”) are prefixes which each represent the relative positions of substituents. The prefix “ortho-” indicates that two substituents are adjacent to each other, and for example, when two substituents in a benzene derivative occupy positions 1 and 2 or positions 2 and 3, this is called an “ortho-” configuration. The prefix “meta-” indicates that two substituents are at positions 1 and 3, and for example, when two substituents in a benzene derivative occupy positions 1 and 3, this is called a “meta-” configuration. The prefix “para-” indicates that two substituents are at positions 1 and 4, and for example, when two substituents in a benzene derivative occupy positions 1 and 4, this is called a “para-” configuration.

In the term “substituted or unsubstituted” described herein, “substituted” means that a hydrogen atom in a functional group is replaced by another atom or another functional group (i.e., a substituent). Unless otherwise specified, the substituent may replace hydrogen at a position where the substituent can be substituted without limitation, and when two or more hydrogen atoms in a certain functional group are each replaced with a substituent, each substituent may be the same as or different from each other. The maximum number of substituents that can be substituted for a certain functional group may be the total number of valences that can be substituted for each atom forming the functional group. Herein, the substituted alkyl, the substituted aryl, the substituted arylene, the substituted heteroaryl, the substituted heteroarylene, the substituted alkenyl, the substituted mono- or di-alkylamino, the substituted mono- or di-arylamino, the substituted alkylarylamino, the substituted mono- or di-heteroarylamino, the substituted heteroarene, the substituted cycloalkyl, the substituted cycloalkylene, the substituted cycloalkenyl, the substituted heterocycloalkyl, the substituted alkoxy, the substituted trialkylsilyl, the substituted dialkylarylsilyl, the substituted alkyldiarylsilyl, the substituted triarylsilyl, and the fused ring group of the substituted aliphatic ring and aromatic ring each independently are substituted with at least one selected from the group consisting of deuterium; a halogen; a cyano; a carboxyl; a nitro; a hydroxyl; a (C₁-C₃₀)alkyl; a halo(C₁-C₃₀)alkyl; a (C₂-C₃₀)alkenyl; a (C₂-C₃₀)alkynyl; a (C₁-C₃₀)alkoxy; a (C₁-C₃₀)alkylthio; a (C₃-C₃₀)cycloalkyl; a (C₃-C₃₀)cycloalkenyl; a (3- to 7-membered)heterocycloalkyl; a (C₆-C₃₀)aryloxy; a (C₆-C₃₀)arylthio; a (3- to 30-membered)heteroaryl unsubstituted or substituted with at least one of a (C₁-C₃₀)alkyl(s), a (C₆-C₃₀)aryl(s), a (3- to 30-membered)heteroaryl(s), and a di(C₆-C₃₀)arylamino(s); a (C₆-C₃₀)aryl unsubstituted or substituted with deuterium, a cyano(s), a (C₁-C₃₀)alkyl(s), a (3- to 50-membered)heteroaryl(s), a mono- or di-(C₆-C₃₀)arylamino(s), and a tri(C₆-C₃₀)arylsilyl(s); a tri(C₁-C₃₀)alkylsilyl; a tri(C₆-C₃₀)arylsilyl; a di(C₁-C₃₀)alkyl(C₆-C₃₀)arylsilyl; a (C₁-C₃₀)alkyldi(C₆-C₃₀)arylsilyl; an amino; a mono- or di-(C₁-C₃₀)alkylamino; a mono- or di-(C₂-C₃₀)alkenylamino; a mono- or di-(C₆-C₃₀)arylamino; a mono- or di-(3- to 30-membered)heteroarylamino; a (C₁-C₃₀)alkyl(C₂-C₃₀)alkenylamino; a (C₁-C₃₀)alkyl(C₆-C₃₀)arylamino; a (C₁-C₃₀)alkyl(3- to 30-membered)heteroarylamino; a (C₂-C₃₀)alkenyl(C₆-C₃₀)arylamino; a (C₂-C₃₀)alkenyl(3- to 30-membered)heteroarylamino; a (C₆-C₃₀)aryl(3- to 30-membered)heteroarylamino; a (C₁-C₃₀)alkylcarbonyl; a (C₁-C₃₀)alkoxycarbonyl; a (C₆-C₃₀)arylcarbonyl; a di(C₆-C₃₀)arylboronyl; a di(C₁-C₃₀)alkylboronyl; a (C₁-C₃₀)alkyl(C₆-C₃₀)arylboronyl; a (C₆-C₃₀)aryl(C₁-C₃₀)alkyl; and a (C₁-C₃₀)alkyl(C₆-C₃₀)aryl. According to another embodiment of the present disclosure, the substituted alkyl, etc. may each be independently substituted by at least one selected from the group consisting of deuterium; a (C₁-C₁₀)alkyl; a substituted or unsubstituted (3- to 20-membered)heteroaryl; and a substituted or unsubstituted (C₆-C₂₀)aryl. For example, the substituted alkyl, etc. may each be independently substituted by at least one selected from the group consisting of deuterium, a phenyl, a naphthyl, a naphthyl unsubstituted or substituted with a phenyl(s), a phenanthrenyl, a biphenyl, a dibenzofuranyl, a carbazolyl, and a methyl, which may be further substituted by deuterium.

In the present disclosure, if a substituent is not indicated in the formula or compound structure, this may mean that all possible positions for the substituent are hydrogen or deuterium. That is, in the case of deuterium, it is an isotope of hydrogen, and some hydrogen atoms may be the isotope deuterium, and in this case, the content of deuterium may be 0% to 100%. In the present disclosure, in cases where a substituent is not indicated in the formula or compound structure, if the substituent is not explicitly excluded, such as 0% deuterium, 100% hydrogen, and all substituents are hydrogen, hydrogen and deuterium may be used intermixed in a compound. Deuterium is one of the isotopes of hydrogen and an element with a deuteron, consisting of one proton and one neutron, as its nucleus. It can be represented as hydrogen-2, whose element symbol can also be written as D or 2H. The isotopes are atoms with the same atomic number (Z) but different mass numbers (A), and can also be interpreted as elements with the same number of protons but different numbers of neutrons.

In the present disclosure, “a combination thereof” refers to a combination of one or more elements from the corresponding list to form a known or chemically stable arrangement that can be envisioned by one skilled in the art from the corresponding list. For example, alkyl and deuterium can be combined to form a partially or fully deuterated alkyl group; halogen and alkyl can be combined to form a halogenated alkyl substituent; and halogen, alkyl, and aryl can be combined to form a halogenated arylalkyl. For example, a preferred combination of substituents includes up to 50 atoms excluding hydrogen or deuterium, up to 40 atoms excluding hydrogen or deuterium, up to 30 atoms excluding hydrogen or deuterium, or in many cases, a preferred combination of substituents may comprise up to 20 atoms excluding hydrogen or deuterium.

In the formula of the present disclosure, when forming a ring by linked to adjacent substituents, the ring may be linked to an adjacent two or more substituent(s) to form a substituted or unsubstituted, mono- or polycyclic, (3- to 30-membered) alicyclic or aromatic ring, or a combination thereof. In addition, the formed ring may contain at least one heteroatom selected from B, N, O, S, Si, and P, preferably at least one heteroatom selected from N, O, and S. According to one embodiment of the present disclosure, the number of ring backbone atoms is 5 to 20, and according to another embodiment of the present disclosure, the number of ring backbone atoms is 5 to 15.

The present disclosure provides a plurality of host materials comprising at least one first host compound and at least one second host compound, wherein the first host compound comprises a compound represented by the following Formula 1 and the second host compound comprises a compound represented by the following Formula 2.

The compound represented by Formula 1 is described in more detail as follows.

In Formula 1, X₁ represents O, S, or CR₁₃R₁₄. For example, X₁ may be O or S.

In Formula 1, R₁₃ and R₁₄ each independently represent a substituted or unsubstituted (C₁-C₃₀)alkyl, a substituted or unsubstituted (C₆-C₃₀)aryl, or a substituted or unsubstituted (3- to 30-membered)heteroaryl, or R₁₃ and R₁₄ may be linked to each other to form a ring(s).

In Formula 1, R₁ to R₁₂ each independently represent hydrogen, deuterium, a halogen, a cyano, a substituted or unsubstituted (C₁-C₃₀)alkyl, a substituted or unsubstituted (C₂-C₃₀)alkenyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₃-C₃₀)cycloalkenyl, a substituted or unsubstituted (3- to 7-membered)heterocycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted fused ring of (C₃-C₃₀) aliphatic ring(s) and (C₆-C₃₀) aromatic ring(s), a substituted or unsubstituted mono- or di-(C₁-C₃₀)alkylamino, a substituted or unsubstituted mono- or di-(C₆-C₃₀)arylamino, a substituted or unsubstituted (C₁-C₃₀)alkyl(C₆-C₃₀)arylamino, a substituted or unsubstituted mono- or di-(3- to 30-membered)heteroarylamino, or a substituted or unsubstituted (C₆-C₃₀)aryl(3- to 30-membered)heteroarylamino; or may be linked to the adjacent substituent(s) to form a ring(s); with a proviso that at least one of R₁ to R₁₂ represents the following Formula 1-a. According to one embodiment of the present disclosure, R₁ to R₁₂ each independently represent hydrogen, deuterium, a substituted or unsubstituted (C₁-C₃₀)alkyl, a substituted or unsubstituted (C₂-C₃₀)alkenyl, a substituted or unsubstituted (C₆-C₃₀)aryl, or a substituted or unsubstituted (3- to 30-membered)heteroaryl, with a proviso that at least one of R₁ to R₁₂ represents the following Formula 1-a. According to another embodiment of the present disclosure, R₁ to R₁₂ each independently represent hydrogen, deuterium, or a substituted or unsubstituted (C₆-C₁₂)aryl, with a proviso that at least one of R₁ to R₁₂ represents the following Formula 1-a. For example, R₁ to R₁₂ each independently may be hydrogen, a phenyl, a naphthyl, a biphenyl, or the following Formula 1-a, with a proviso that at least one of R₁ to R₁₂ may be the following Formula 1-a.

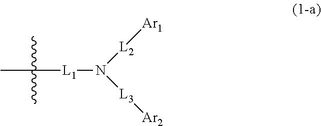

In Formula 1-a,

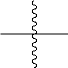

is a site linked to at least one of R₁ to R₁₂.

In Formula 1-a, L₁ to L₃ each independently represent a single bond, a substituted or unsubstituted (C₆-C₃₀)arylene, a substituted or unsubstituted (3- to 30-membered)heteroarylene, or a substituted or unsubstituted (C₃-C₃₀)cycloalkylene. According to one embodiment of the present disclosure, L₁ to L₃ each independently represent a single bond, a substituted or unsubstituted (C₆-C₁₈)arylene, or a substituted or unsubstituted (3- to 15-membered)heteroarylene. For example, L₁ to L₃ each independently may be a single bond; a phenylene unsubstituted or substituted with a naphthyl(s), a dibenzofuranyl(s), a carbazolyl(s), and a phenanthrenyl(s); a biphenylene; a terphenylene; a naphthylene; a phenanthrenylene; a dibenzofuranylene unsubstituted or substituted with a phenyl(s); or a carbazolylene unsubstituted or substituted with a phenyl(s), etc.

In Formula 1-a, Ar₁ and Ar₂ each independently represent a substituted or unsubstituted (C₆-C₃₀)aryl, a substituted or unsubstituted (3- to 30-membered)heteroaryl, or a substituted or unsubstituted (C₃-C₃₀)cycloalkyl. According to one embodiment of the present disclosure, Ar₁ and Ar₂ each independently represent a substituted or unsubstituted (C₆-C₁₈)aryl or a substituted or unsubstituted (3- to 15-membered)heteroaryl. For example, Ar₁ and Ar₂ each independently may be a phenyl unsubstituted or substituted with a naphthyl(s), a phenanthrenyl(s), a dibenzofuranyl(s), or a carbazolyl(s); a biphenyl; a terphenyl; a naphthyl; a phenanthrenyl; a dimethylfluorenyl; a diphenylfluorenyl; a dibenzofuranyl unsubstituted or substituted with a phenyl(s); a dibenzothiophenyl; or a carbazolyl unsubstituted or substituted with a phenyl(s).

According to one embodiment of the present disclosure, the compound represented by Formula 1 may be represented by any one of the following Formulas 1-1 to 1-12.

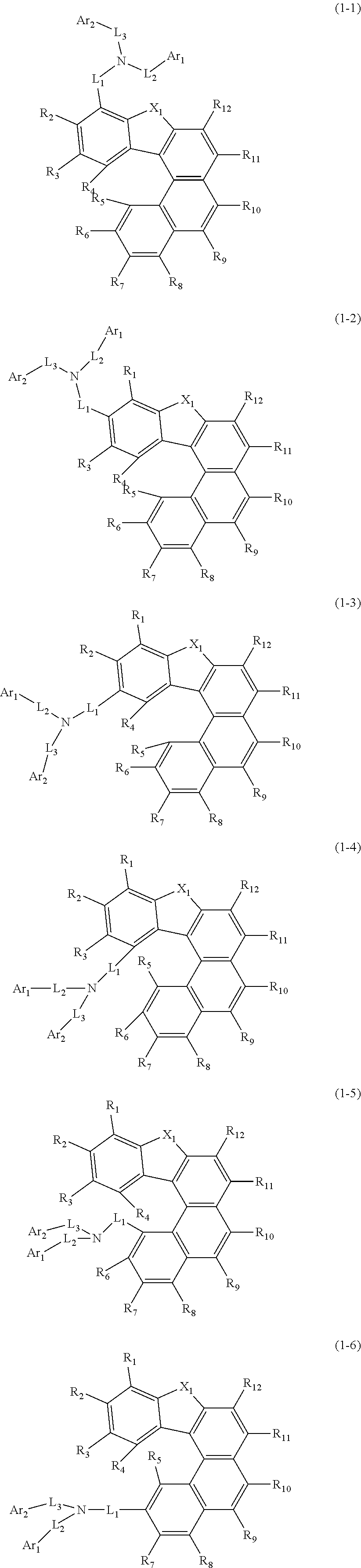

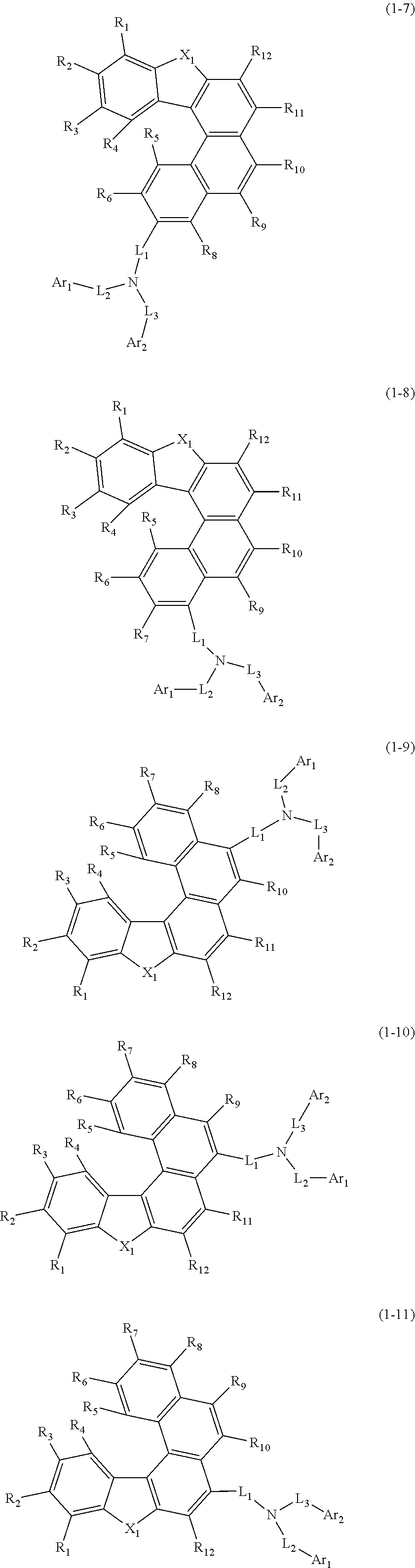

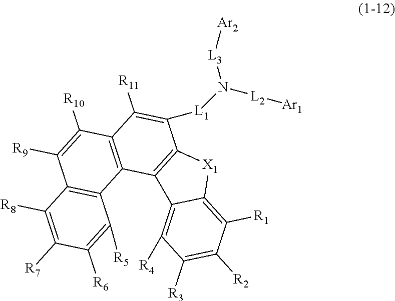

According to one embodiment of the present disclosure, the compound represented by Formula 1 may be at least one selected from the following compounds, but is not limited thereto.

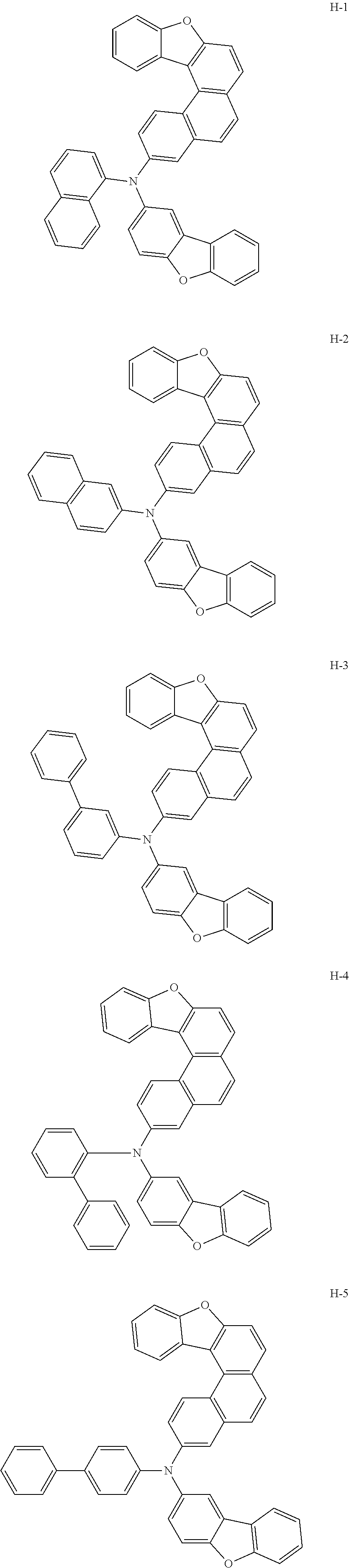 [SMILES: c1ccc2c(N(c3ccc4c(ccc5ccc6oc7ccccc7c6c54)c3)c3ccc4oc5ccccc5c4c3)cccc2c1 ; c1ccc2cc(N(c3ccc4c(ccc5ccc6oc7ccccc7c6c54)c3)c3ccc4oc5ccccc5c4c3)ccc2c1 ; c1ccc(-c2cccc(N(c3ccc4c(ccc5ccc6oc7ccccc7c6c54)c3)c3ccc4oc5ccccc5c4c3)c2)cc1 ; c1ccc(-c2ccccc2N(c2ccc3c(ccc4ccc5oc6ccccc6c5c43)c2)c2ccc3oc4ccccc4c3c2)cc1 ; c1ccc(-c2ccc(N(c3ccc4c(ccc5ccc6oc7ccccc7c6c54)c3)c3ccc4oc5ccccc5c4c3)cc2)cc1]

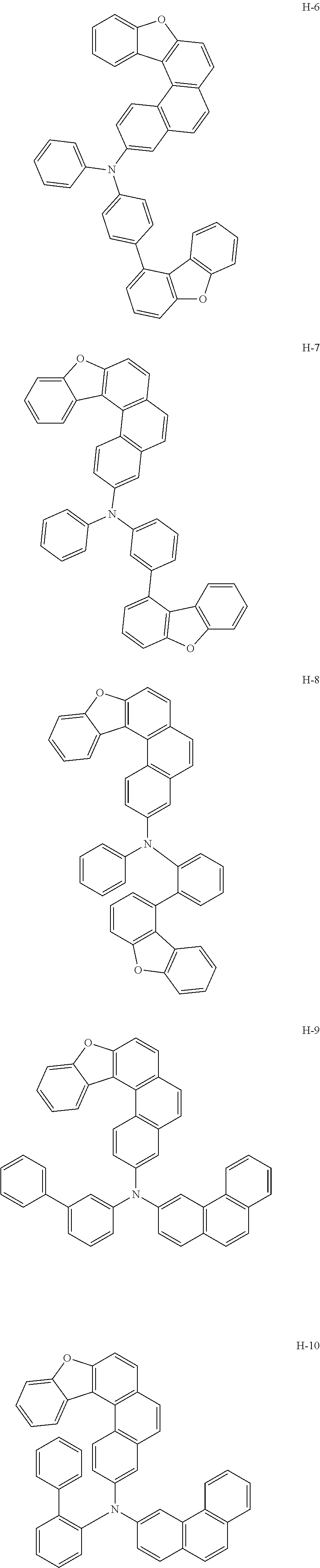 [SMILES: c1ccc(N(c2ccc(-c3cccc4oc5ccccc5c34)cc2)c2ccc3c(ccc4ccc5oc6ccccc6c5c43)c2)cc1 ; c1ccc(N(c2cccc(-c3cccc4oc5ccccc5c34)c2)c2ccc3c(ccc4ccc5oc6ccccc6c5c43)c2)cc1 ; c1ccc(N(c2ccc3c(ccc4ccc5oc6ccccc6c5c43)c2)c2ccccc2-c2cccc3oc4ccccc4c23)cc1 ; c1ccc(-c2cccc(N(c3ccc4c(ccc5ccc6oc7ccccc7c6c54)c3)c3ccc4ccc5ccccc5c4c3)c2)cc1 ; c1ccc(-c2ccccc2N(c2ccc3c(ccc4ccc5oc6ccccc6c5c43)c2)c2ccc3ccc4ccccc4c3c2)cc1]

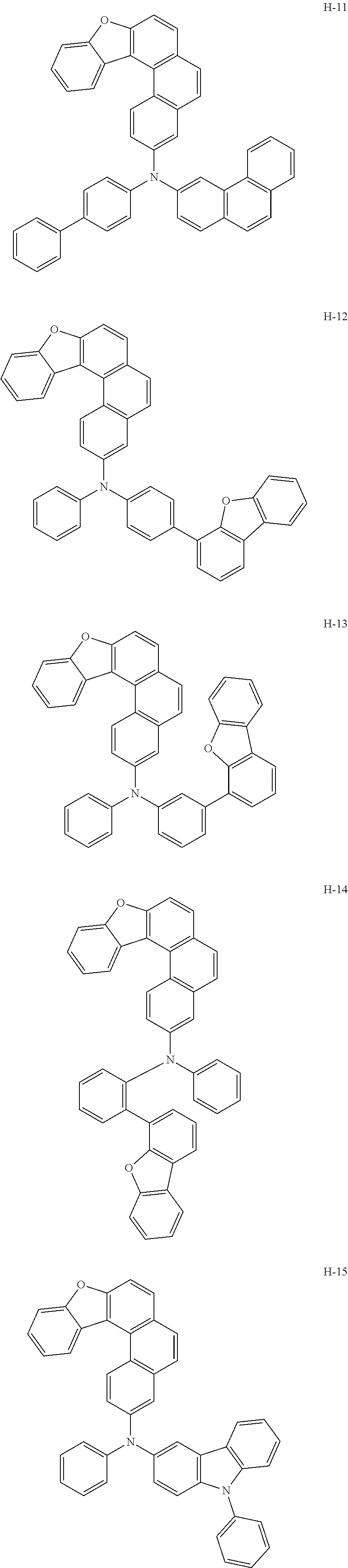 [SMILES: c1ccc(-c2ccc(N(c3ccc4c(ccc5ccc6oc7ccccc7c6c54)c3)c3ccc4ccc5ccccc5c4c3)cc2)cc1 ; c1ccc(N(c2ccc(-c3cccc4c3oc3ccccc34)cc2)c2ccc3c(ccc4ccc5oc6ccccc6c5c43)c2)cc1 ; c1ccc(N(c2cccc(-c3cccc4c3oc3ccccc34)c2)c2ccc3c(ccc4ccc5oc6ccccc6c5c43)c2)cc1 ; c1ccc(N(c2ccc3c(ccc4ccc5oc6ccccc6c5c43)c2)c2ccccc2-c2cccc3c2oc2ccccc23)cc1 ; c1ccc(N(c2ccc3c(ccc4ccc5oc6ccccc6c5c43)c2)c2ccc3c(c2)c2ccccc2n3-c2ccccc2)cc1]

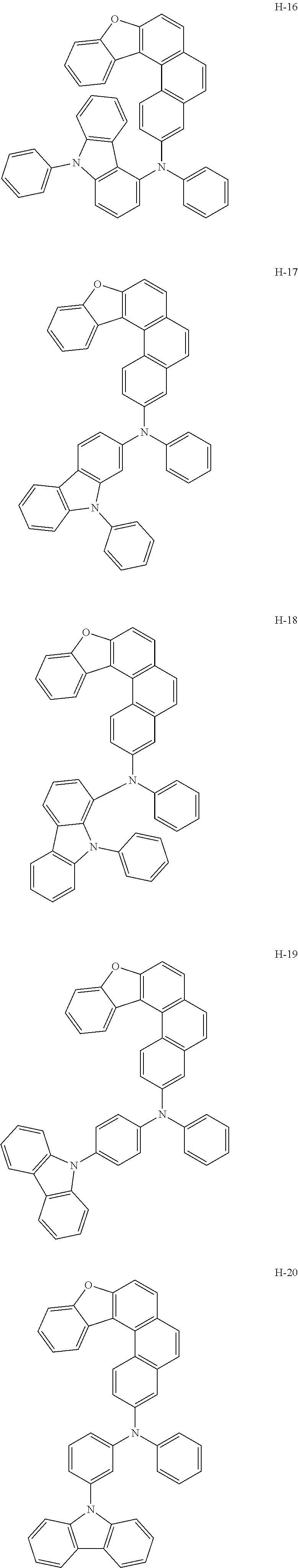 [SMILES: c1ccc(N(c2ccc3c(ccc4ccc5oc6ccccc6c5c43)c2)c2cccc3c2c2ccccc2n3-c2ccccc2)cc1 ; c1ccc(N(c2ccc3c(ccc4ccc5oc6ccccc6c5c43)c2)c2ccc3c4ccccc4n(-c4ccccc4)c3c2)cc1 ; c1ccc(N(c2ccc3c(ccc4ccc5oc6ccccc6c5c43)c2)c2cccc3c4ccccc4n(-c4ccccc4)c23)cc1 ; c1ccc(N(c2ccc(-n3c4ccccc4c4ccccc43)cc2)c2ccc3c(ccc4ccc5oc6ccccc6c5c43)c2)cc1 ; c1ccc(N(c2cccc(-n3c4ccccc4c4ccccc43)c2)c2ccc3c(ccc4ccc5oc6ccccc6c5c43)c2)cc1]

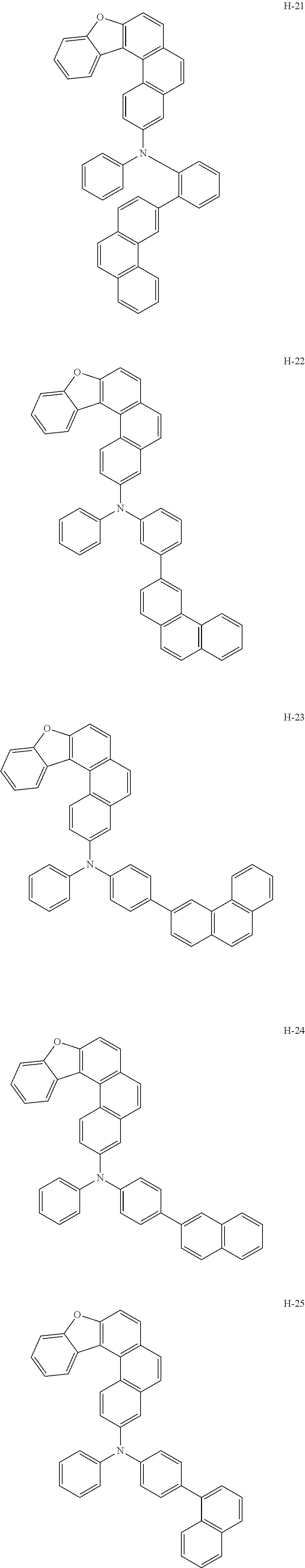 [SMILES: c1ccc(N(c2ccc3c(ccc4ccc5oc6ccccc6c5c43)c2)c2ccccc2-c2ccc3ccc4ccccc4c3c2)cc1 ; c1ccc(N(c2cccc(-c3ccc4ccc5ccccc5c4c3)c2)c2ccc3c(ccc4ccc5oc6ccccc6c5c43)c2)cc1 ; c1ccc(N(c2ccc(-c3ccc4ccc5ccccc5c4c3)cc2)c2ccc3c(ccc4ccc5oc6ccccc6c5c43)c2)cc1 ; c1ccc(N(c2ccc(-c3ccc4ccccc4c3)cc2)c2ccc3c(ccc4ccc5oc6ccccc6c5c43)c2)cc1 ; c1ccc(N(c2ccc(-c3cccc4ccccc34)cc2)c2ccc3c(ccc4ccc5oc6ccccc6c5c43)c2)cc1]

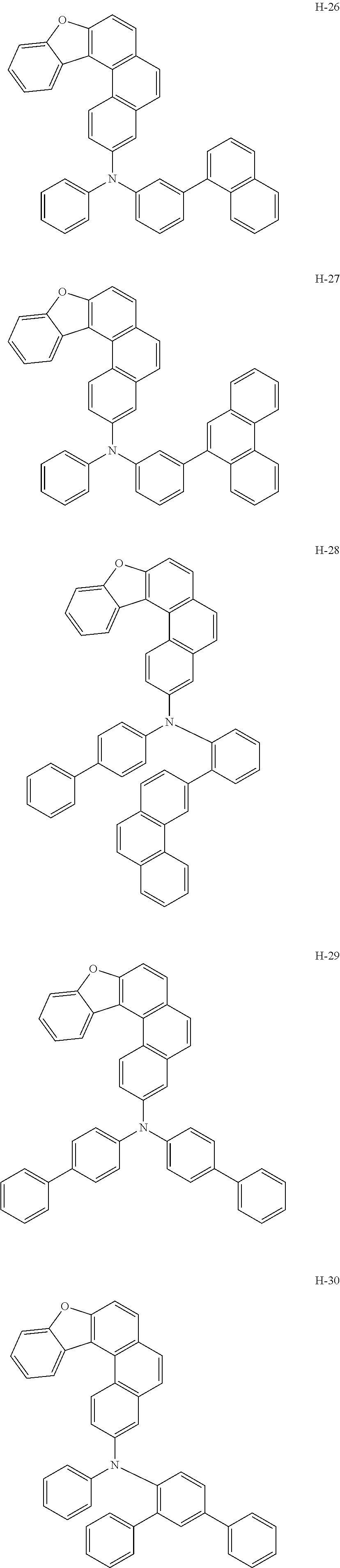 [SMILES: c1ccc(N(c2cccc(-c3cccc4ccccc34)c2)c2ccc3c(ccc4ccc5oc6ccccc6c5c43)c2)cc1 ; c1ccc(N(c2cccc(-c3cc4ccccc4c4ccccc34)c2)c2ccc3c(ccc4ccc5oc6ccccc6c5c43)c2)cc1 ; c1ccc(-c2ccc(N(c3ccc4c(ccc5ccc6oc7ccccc7c6c54)c3)c3ccccc3-c3ccc4ccc5ccccc5c4c3)cc2)cc1 ; c1ccc(-c2ccc(N(c3ccc(-c4ccccc4)cc3)c3ccc4c(ccc5ccc6oc7ccccc7c6c54)c3)cc2)cc1 ; c1ccc(-c2ccc(N(c3ccccc3)c3ccc4c(ccc5ccc6oc7ccccc7c6c54)c3)c(-c3ccccc3)c2)cc1]

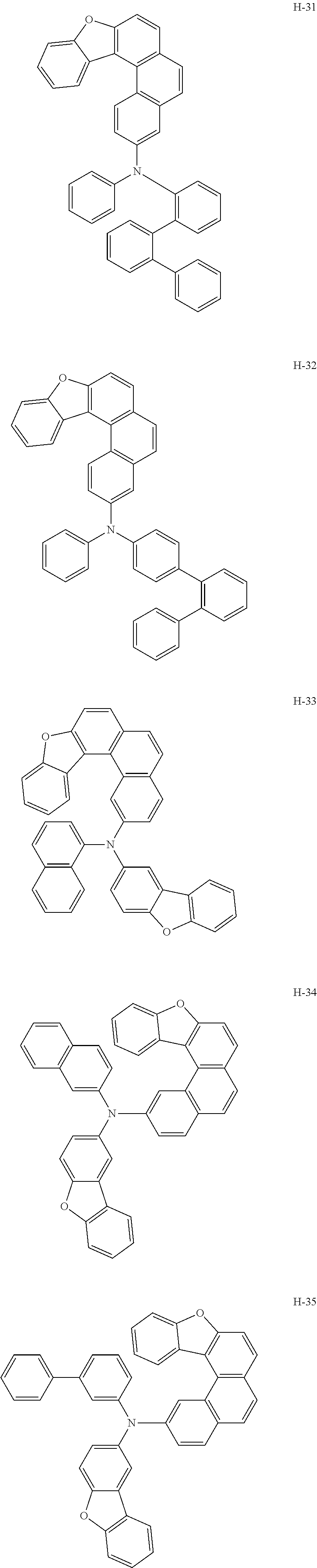 [SMILES: c1ccc(-c2ccccc2-c2ccccc2N(c2ccccc2)c2ccc3c(ccc4ccc5oc6ccccc6c5c43)c2)cc1 ; c1ccc(-c2ccccc2-c2ccc(N(c3ccccc3)c3ccc4c(ccc5ccc6oc7ccccc7c6c54)c3)cc2)cc1 ; c1ccc2c(N(c3ccc4oc5ccccc5c4c3)c3ccc4ccc5ccc6oc7ccccc7c6c5c4c3)cccc2c1 ; c1ccc2cc(N(c3ccc4oc5ccccc5c4c3)c3ccc4ccc5ccc6oc7ccccc7c6c5c4c3)ccc2c1 ; c1ccc(-c2cccc(N(c3ccc4oc5ccccc5c4c3)c3ccc4ccc5ccc6oc7ccccc7c6c5c4c3)c2)cc1]

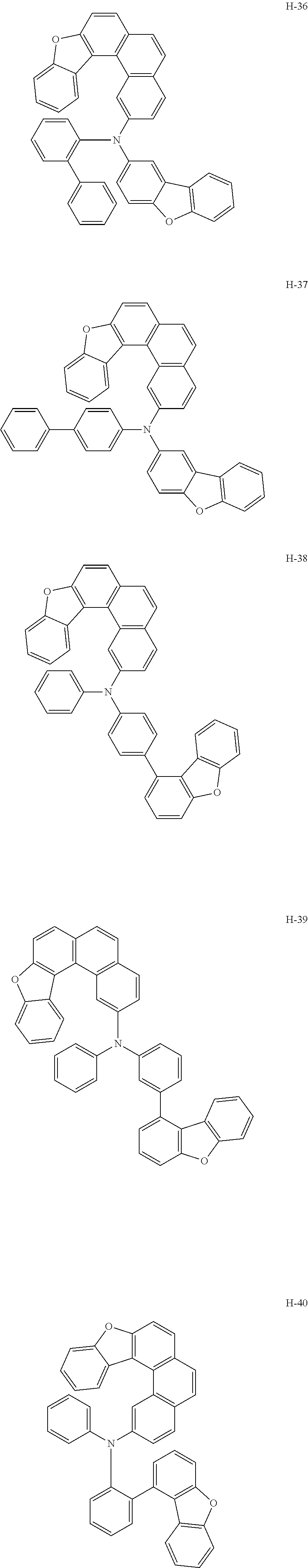 [SMILES: c1ccc(-c2ccccc2N(c2ccc3oc4ccccc4c3c2)c2ccc3ccc4ccc5oc6ccccc6c5c4c3c2)cc1 ; c1ccc(-c2ccc(N(c3ccc4oc5ccccc5c4c3)c3ccc4ccc5ccc6oc7ccccc7c6c5c4c3)cc2)cc1 ; c1ccc(N(c2ccc(-c3cccc4oc5ccccc5c34)cc2)c2ccc3ccc4ccc5oc6ccccc6c5c4c3c2)cc1 ; c1ccc(N(c2cccc(-c3cccc4oc5ccccc5c34)c2)c2ccc3ccc4ccc5oc6ccccc6c5c4c3c2)cc1 ; c1ccc(N(c2ccc3ccc4ccc5oc6ccccc6c5c4c3c2)c2ccccc2-c2cccc3oc4ccccc4c23)cc1]

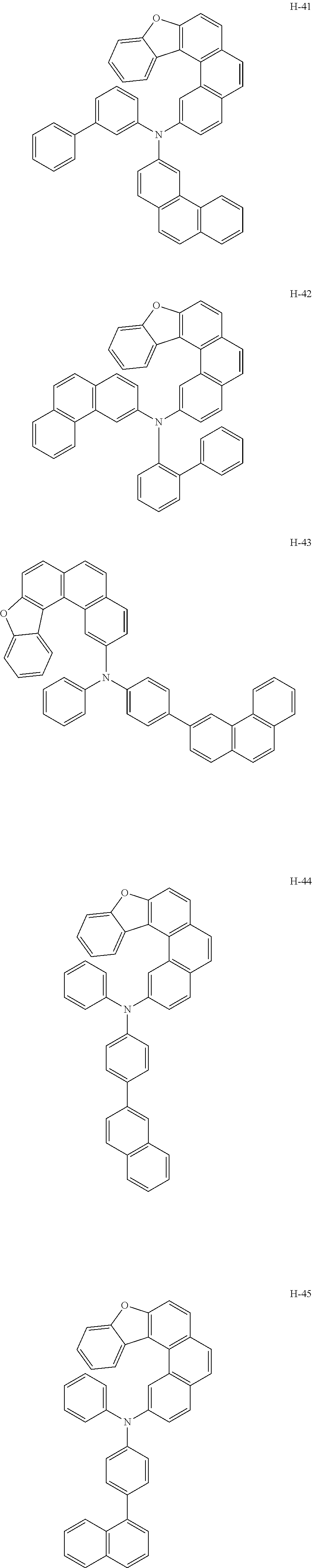 [SMILES: c1ccc(-c2cccc(N(c3ccc4ccc5ccccc5c4c3)c3ccc4ccc5ccc6oc7ccccc7c6c5c4c3)c2)cc1 ; c1ccc(-c2ccccc2N(c2ccc3ccc4ccccc4c3c2)c2ccc3ccc4ccc5oc6ccccc6c5c4c3c2)cc1 ; c1ccc(N(c2ccc(-c3ccc4ccc5ccccc5c4c3)cc2)c2ccc3ccc4ccc5oc6ccccc6c5c4c3c2)cc1 ; c1ccc(N(c2ccc(-c3ccc4ccccc4c3)cc2)c2ccc3ccc4ccc5oc6ccccc6c5c4c3c2)cc1 ; c1ccc(N(c2ccc(-c3cccc4ccccc34)cc2)c2ccc3ccc4ccc5oc6ccccc6c5c4c3c2)cc1]

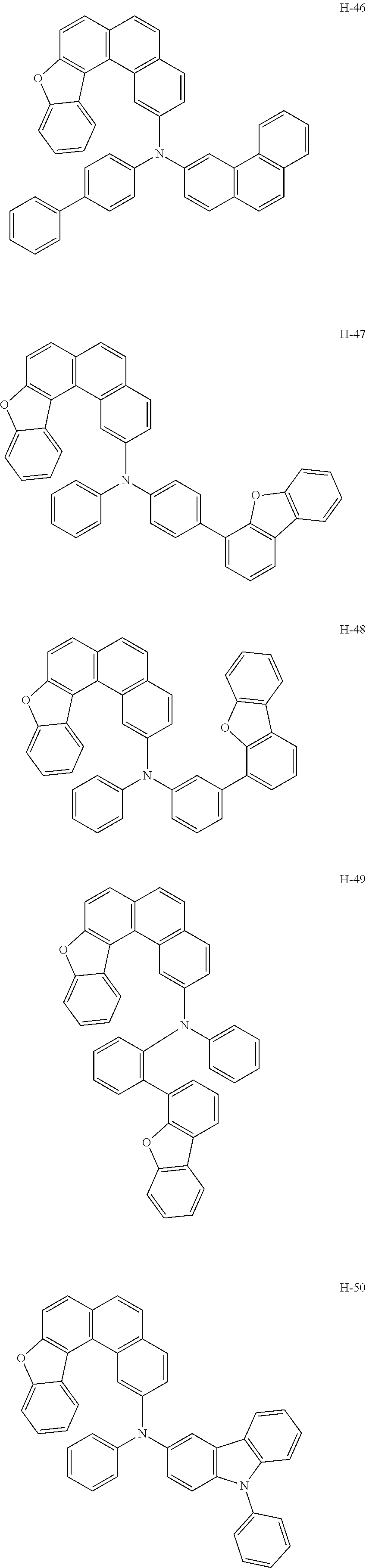 [SMILES: c1ccc(-c2ccc(N(c3ccc4ccc5ccccc5c4c3)c3ccc4ccc5ccc6oc7ccccc7c6c5c4c3)cc2)cc1 ; c1ccc(N(c2ccc(-c3cccc4c3oc3ccccc34)cc2)c2ccc3ccc4ccc5oc6ccccc6c5c4c3c2)cc1 ; c1ccc(N(c2cccc(-c3cccc4c3oc3ccccc34)c2)c2ccc3ccc4ccc5oc6ccccc6c5c4c3c2)cc1 ; c1ccc(N(c2ccc3ccc4ccc5oc6ccccc6c5c4c3c2)c2ccccc2-c2cccc3c2oc2ccccc23)cc1 ; c1ccc(N(c2ccc3ccc4ccc5oc6ccccc6c5c4c3c2)c2ccc3c(c2)c2ccccc2n3-c2ccccc2)cc1]

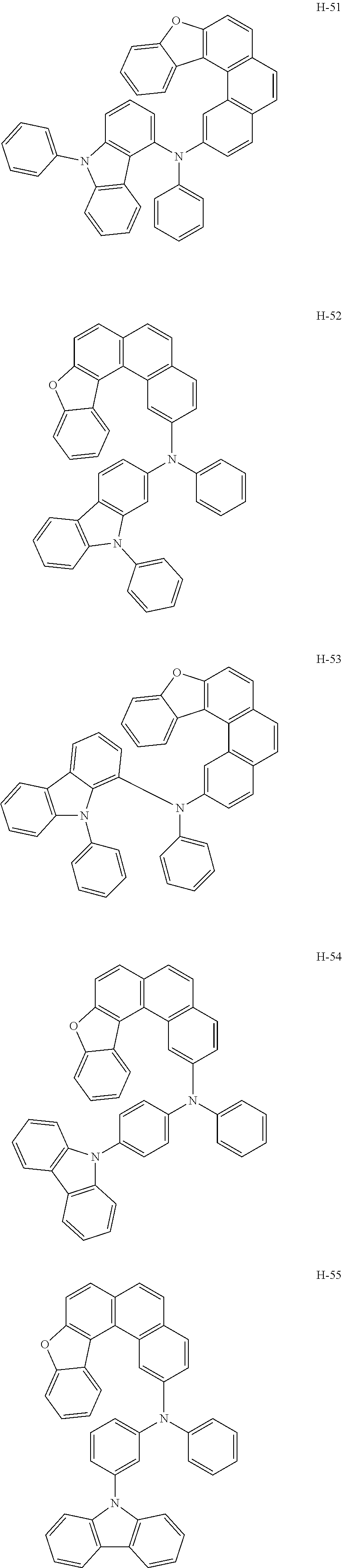 [SMILES: c1ccc(N(c2ccc3ccc4ccc5oc6ccccc6c5c4c3c2)c2cccc3c2c2ccccc2n3-c2ccccc2)cc1 ; c1ccc(N(c2ccc3ccc4ccc5oc6ccccc6c5c4c3c2)c2ccc3c4ccccc4n(-c4ccccc4)c3c2)cc1 ; c1ccc(N(c2ccc3ccc4ccc5oc6ccccc6c5c4c3c2)c2cccc3c4ccccc4n(-c4ccccc4)c23)cc1 ; c1ccc(N(c2ccc(-n3c4ccccc4c4ccccc43)cc2)c2ccc3ccc4ccc5oc6ccccc6c5c4c3c2)cc1 ; c1ccc(N(c2cccc(-n3c4ccccc4c4ccccc43)c2)c2ccc3ccc4ccc5oc6ccccc6c5c4c3c2)cc1]

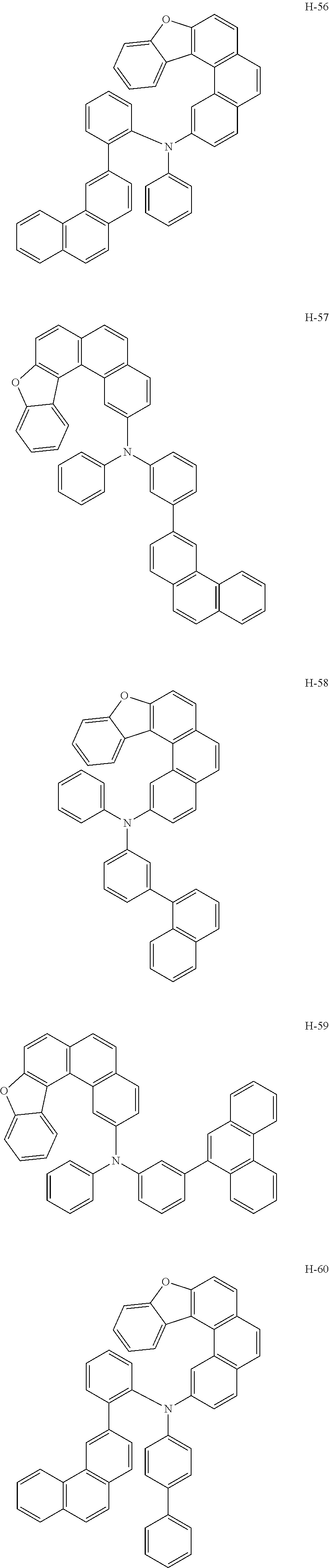 [SMILES: c1ccc(N(c2ccc3ccc4ccc5oc6ccccc6c5c4c3c2)c2ccccc2-c2ccc3ccc4ccccc4c3c2)cc1 ; c1ccc(N(c2cccc(-c3ccc4ccc5ccccc5c4c3)c2)c2ccc3ccc4ccc5oc6ccccc6c5c4c3c2)cc1 ; c1ccc(N(c2cccc(-c3cccc4ccccc34)c2)c2ccc3ccc4ccc5oc6ccccc6c5c4c3c2)cc1 ; c1ccc(N(c2cccc(-c3cc4ccccc4c4ccccc34)c2)c2ccc3ccc4ccc5oc6ccccc6c5c4c3c2)cc1 ; c1ccc(-c2ccc(N(c3ccc4ccc5ccc6oc7ccccc7c6c5c4c3)c3ccccc3-c3ccc4ccc5ccccc5c4c3)cc2)cc1]

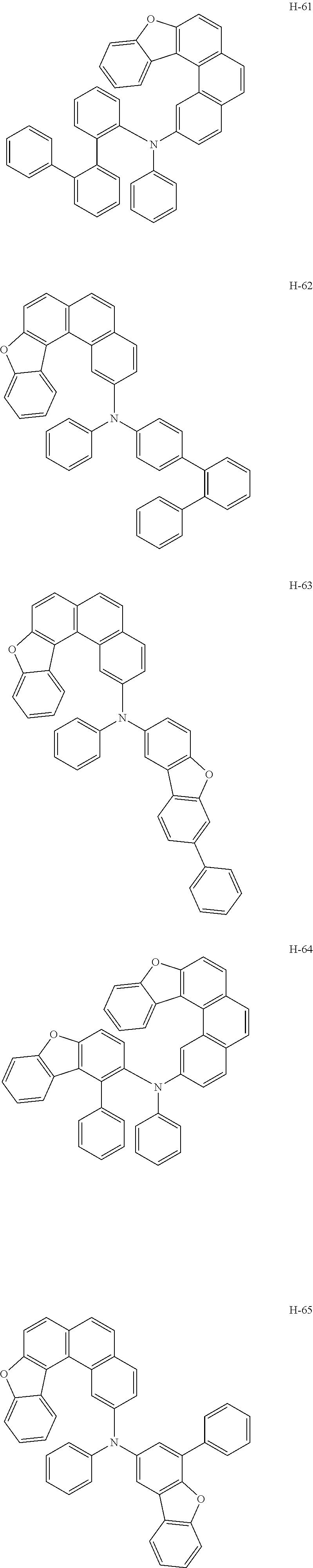 [SMILES: c1ccc(-c2ccccc2-c2ccccc2N(c2ccccc2)c2ccc3ccc4ccc5oc6ccccc6c5c4c3c2)cc1 ; c1ccc(-c2ccccc2-c2ccc(N(c3ccccc3)c3ccc4ccc5ccc6oc7ccccc7c6c5c4c3)cc2)cc1 ; c1ccc(-c2ccc3c(c2)oc2ccc(N(c4ccccc4)c4ccc5ccc6ccc7oc8ccccc8c7c6c5c4)cc23)cc1 ; c1ccc(-c2c(N(c3ccccc3)c3ccc4ccc5ccc6oc7ccccc7c6c5c4c3)ccc3oc4ccccc4c23)cc1 ; c1ccc(-c2cc(N(c3ccccc3)c3ccc4ccc5ccc6oc7ccccc7c6c5c4c3)cc3c2oc2ccccc23)cc1]

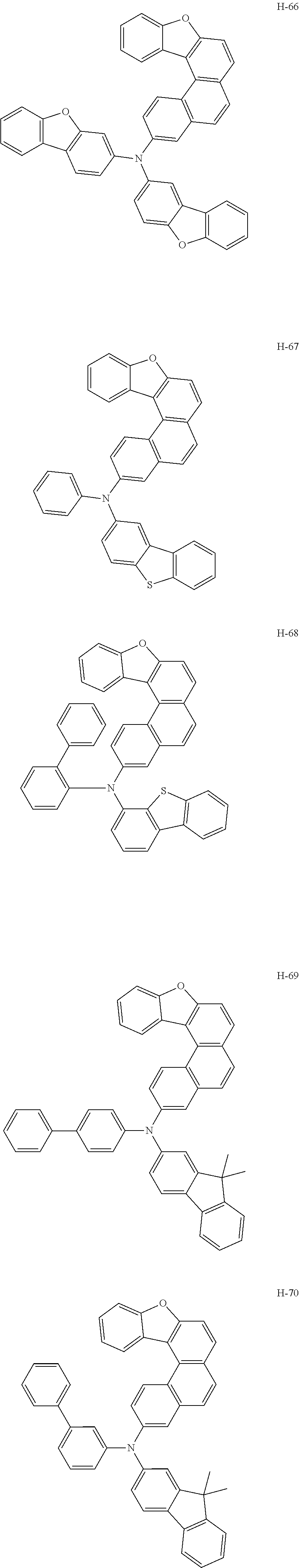 [SMILES: c1ccc2c(c1)oc1cc(N(c3ccc4c(ccc5ccc6oc7ccccc7c6c54)c3)c3ccc4oc5ccccc5c4c3)ccc12 ; c1ccc(N(c2ccc3c(ccc4ccc5oc6ccccc6c5c43)c2)c2ccc3sc4ccccc4c3c2)cc1 ; c1ccc(-c2ccccc2N(c2ccc3c(ccc4ccc5oc6ccccc6c5c43)c2)c2cccc3c2sc2ccccc23)cc1 ; CC1(C)c2ccccc2-c2ccc(N(c3ccc(-c4ccccc4)cc3)c3ccc4c(ccc5ccc6oc7ccccc7c6c54)c3)cc21 ; CC1(C)c2ccccc2-c2ccc(N(c3cccc(-c4ccccc4)c3)c3ccc4c(ccc5ccc6oc7ccccc7c6c54)c3)cc21]

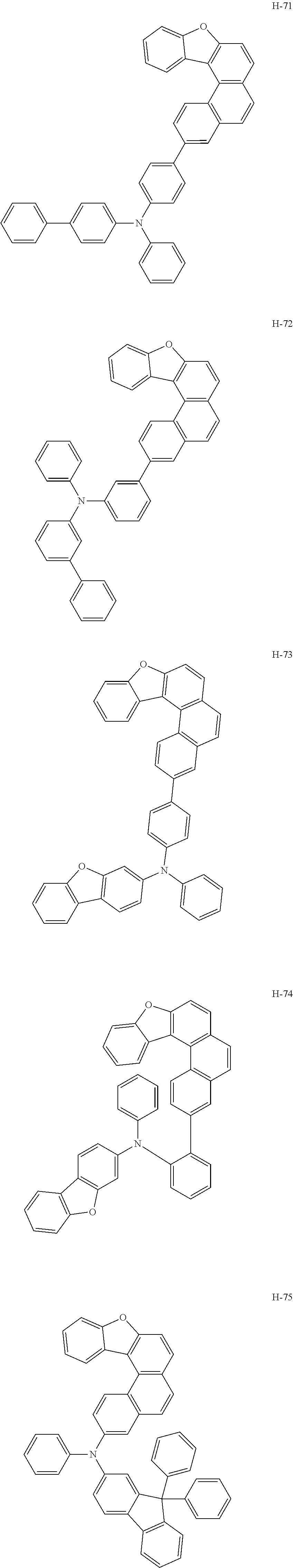 [SMILES: c1ccc(-c2ccc(N(c3ccccc3)c3ccc(-c4ccc5c(ccc6ccc7oc8ccccc8c7c65)c4)cc3)cc2)cc1 ; c1ccc(-c2cccc(N(c3ccccc3)c3cccc(-c4ccc5c(ccc6ccc7oc8ccccc8c7c65)c4)c3)c2)cc1 ; c1ccc(N(c2ccc(-c3ccc4c(ccc5ccc6oc7ccccc7c6c54)c3)cc2)c2ccc3c(c2)oc2ccccc23)cc1 ; c1ccc(N(c2ccc3c(c2)oc2ccccc23)c2ccccc2-c2ccc3c(ccc4ccc5oc6ccccc6c5c43)c2)cc1 ; c1ccc(N(c2ccc3c(c2)C(c2ccccc2)(c2ccccc2)c2ccccc2-3)c2ccc3c(ccc4ccc5oc6ccccc6c5c43)c2)cc1]

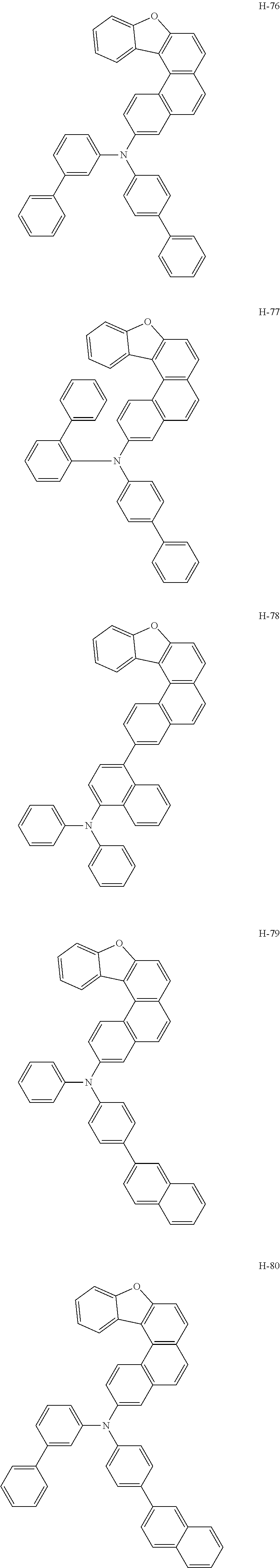 [SMILES: c1ccc(-c2ccc(N(c3cccc(-c4ccccc4)c3)c3ccc4c(ccc5ccc6oc7ccccc7c6c54)c3)cc2)cc1 ; c1ccc(-c2ccc(N(c3ccc4c(ccc5ccc6oc7ccccc7c6c54)c3)c3ccccc3-c3ccccc3)cc2)cc1 ; c1ccc(N(c2ccccc2)c2ccc(-c3ccc4c(ccc5ccc6oc7ccccc7c6c54)c3)c3ccccc23)cc1 ; c1ccc(N(c2ccc(-c3ccc4ccccc4c3)cc2)c2ccc3c(ccc4ccc5oc6ccccc6c5c43)c2)cc1 ; c1ccc(-c2cccc(N(c3ccc(-c4ccc5ccccc5c4)cc3)c3ccc4c(ccc5ccc6oc7ccccc7c6c54)c3)c2)cc1]

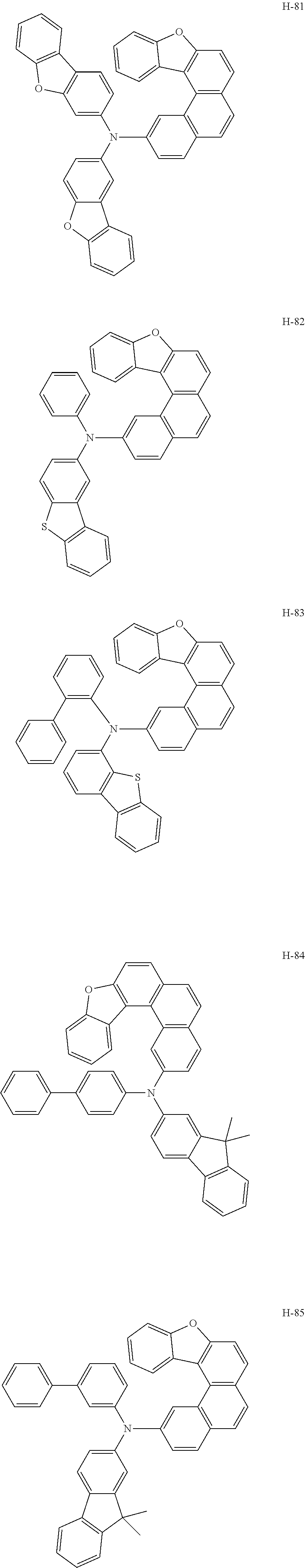 [SMILES: c1ccc2c(c1)oc1cc(N(c3ccc4oc5ccccc5c4c3)c3ccc4ccc5ccc6oc7ccccc7c6c5c4c3)ccc12 ; c1ccc(N(c2ccc3sc4ccccc4c3c2)c2ccc3ccc4ccc5oc6ccccc6c5c4c3c2)cc1 ; c1ccc(-c2ccccc2N(c2ccc3ccc4ccc5oc6ccccc6c5c4c3c2)c2cccc3c2sc2ccccc23)cc1 ; CC1(C)c2ccccc2-c2ccc(N(c3ccc(-c4ccccc4)cc3)c3ccc4ccc5ccc6oc7ccccc7c6c5c4c3)cc21 ; CC1(C)c2ccccc2-c2ccc(N(c3cccc(-c4ccccc4)c3)c3ccc4ccc5ccc6oc7ccccc7c6c5c4c3)cc21]

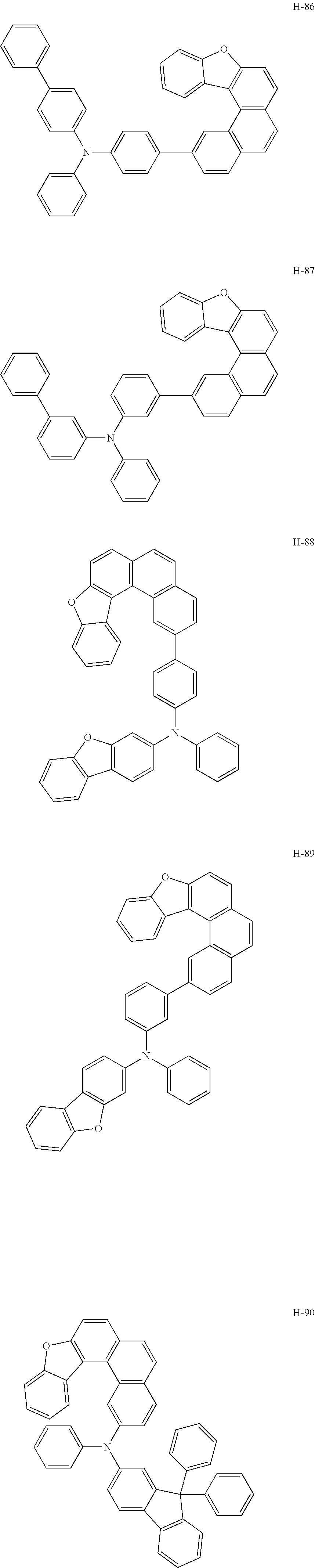 [SMILES: c1ccc(-c2ccc(N(c3ccccc3)c3ccc(-c4ccc5ccc6ccc7oc8ccccc8c7c6c5c4)cc3)cc2)cc1 ; c1ccc(-c2cccc(N(c3ccccc3)c3cccc(-c4ccc5ccc6ccc7oc8ccccc8c7c6c5c4)c3)c2)cc1 ; c1ccc(N(c2ccc(-c3ccc4ccc5ccc6oc7ccccc7c6c5c4c3)cc2)c2ccc3c(c2)oc2ccccc23)cc1 ; c1ccc(N(c2cccc(-c3ccc4ccc5ccc6oc7ccccc7c6c5c4c3)c2)c2ccc3c(c2)oc2ccccc23)cc1 ; c1ccc(N(c2ccc3c(c2)C(c2ccccc2)(c2ccccc2)c2ccccc2-3)c2ccc3ccc4ccc5oc6ccccc6c5c4c3c2)cc1]

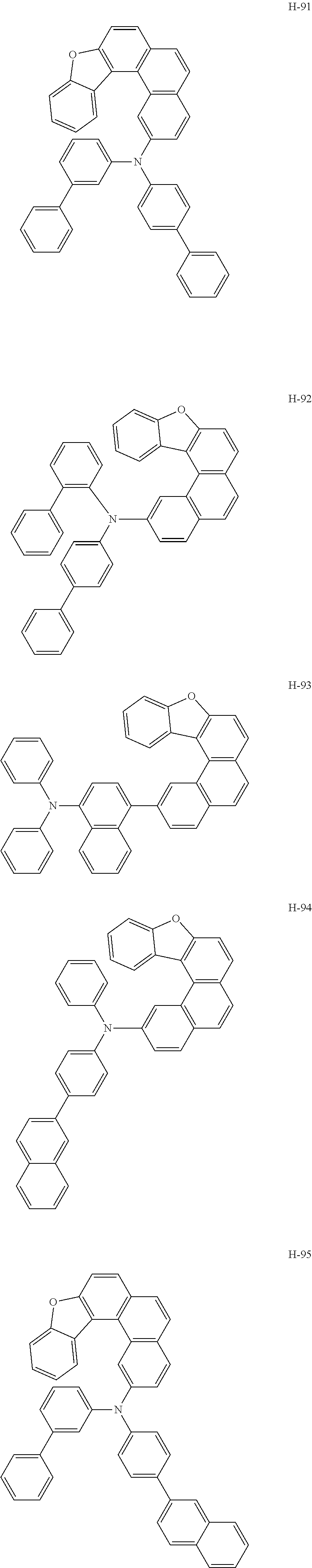 [SMILES: c1ccc(-c2ccc(N(c3cccc(-c4ccccc4)c3)c3ccc4ccc5ccc6oc7ccccc7c6c5c4c3)cc2)cc1 ; c1ccc(-c2ccc(N(c3ccc4ccc5ccc6oc7ccccc7c6c5c4c3)c3ccccc3-c3ccccc3)cc2)cc1 ; c1ccc(N(c2ccccc2)c2ccc(-c3ccc4ccc5ccc6oc7ccccc7c6c5c4c3)c3ccccc23)cc1 ; c1ccc(N(c2ccc(-c3ccc4ccccc4c3)cc2)c2ccc3ccc4ccc5oc6ccccc6c5c4c3c2)cc1 ; c1ccc(-c2cccc(N(c3ccc(-c4ccc5ccccc5c4)cc3)c3ccc4ccc5ccc6oc7ccccc7c6c5c4c3)c2)cc1]

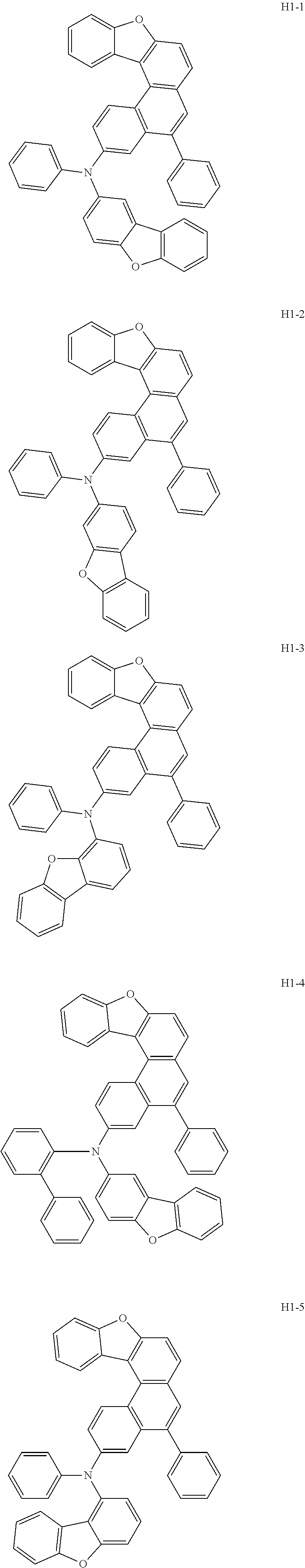

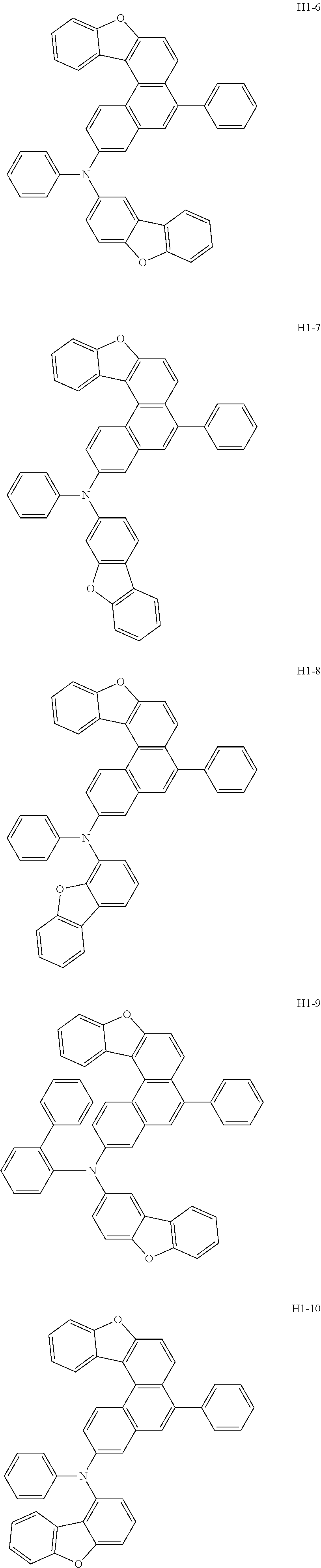 [SMILES: c1ccc(-c2cc3cc(N(c4ccccc4)c4ccc5oc6ccccc6c5c4)ccc3c3c2ccc2oc4ccccc4c23)cc1 ; c1ccc(-c2cc3cc(N(c4ccccc4)c4ccc5c(c4)oc4ccccc45)ccc3c3c2ccc2oc4ccccc4c23)cc1 ; c1ccc(-c2cc3cc(N(c4ccccc4)c4cccc5c4oc4ccccc45)ccc3c3c2ccc2oc4ccccc4c23)cc1 ; c1ccc(-c2ccccc2N(c2ccc3c(c2)cc(-c2ccccc2)c2ccc4oc5ccccc5c4c23)c2ccc3oc4ccccc4c3c2)cc1 ; c1ccc(-c2cc3cc(N(c4ccccc4)c4cccc5oc6ccccc6c45)ccc3c3c2ccc2oc4ccccc4c23)cc1]

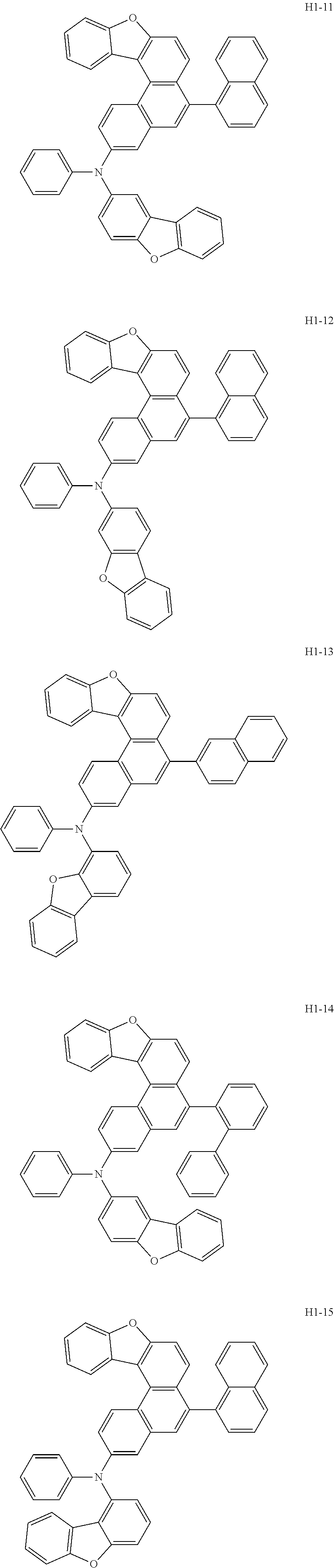 [SMILES: c1ccc(N(c2ccc3c(c2)cc(-c2cccc4ccccc24)c2ccc4oc5ccccc5c4c23)c2ccc3oc4ccccc4c3c2)cc1 ; c1ccc(N(c2ccc3c(c2)cc(-c2cccc4ccccc24)c2ccc4oc5ccccc5c4c23)c2ccc3c(c2)oc2ccccc23)cc1 ; c1ccc(N(c2ccc3c(c2)cc(-c2ccc4ccccc4c2)c2ccc4oc5ccccc5c4c23)c2cccc3c2oc2ccccc23)cc1 ; c1ccc(-c2ccccc2-c2cc3cc(N(c4ccccc4)c4ccc5oc6ccccc6c5c4)ccc3c3c2ccc2oc4ccccc4c23)cc1 ; c1ccc(N(c2ccc3c(c2)cc(-c2cccc4ccccc24)c2ccc4oc5ccccc5c4c23)c2cccc3oc4ccccc4c23)cc1]

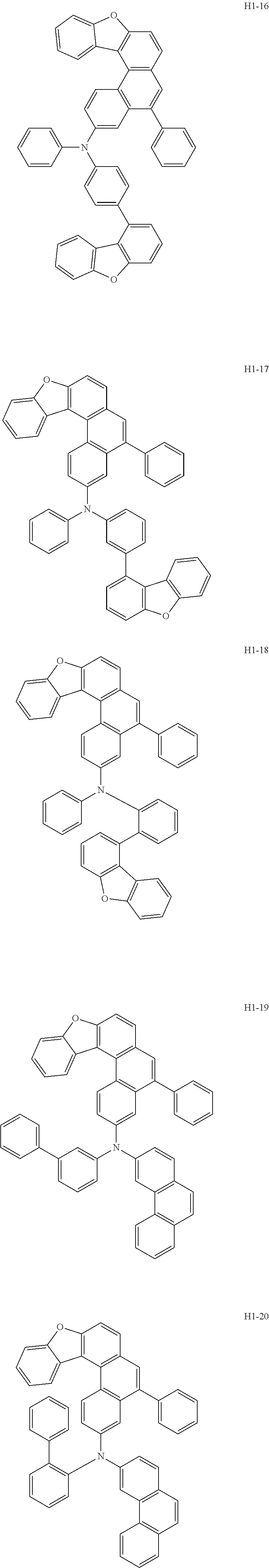 [SMILES: c1ccc(-c2cc3ccc4oc5ccccc5c4c3c3ccc(N(c4ccccc4)c4ccc(-c5cccc6oc7ccccc7c56)cc4)cc23)cc1 ; c1ccc(-c2cc3ccc4oc5ccccc5c4c3c3ccc(N(c4ccccc4)c4cccc(-c5cccc6oc7ccccc7c56)c4)cc23)cc1 ; c1ccc(-c2cc3ccc4oc5ccccc5c4c3c3ccc(N(c4ccccc4)c4ccccc4-c4cccc5oc6ccccc6c45)cc23)cc1 ; c1ccc(-c2cccc(N(c3ccc4c(c3)c(-c3ccccc3)cc3ccc5oc6ccccc6c5c34)c3ccc4ccc5ccccc5c4c3)c2)cc1 ; c1ccc(-c2ccccc2N(c2ccc3c(c2)c(-c2ccccc2)cc2ccc4oc5ccccc5c4c23)c2ccc3ccc4ccccc4c3c2)cc1]

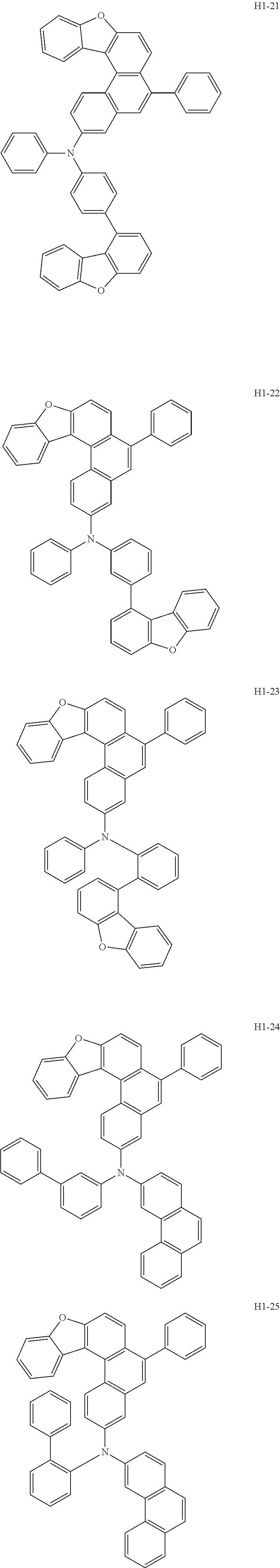 [SMILES: c1ccc(-c2cc3cc(N(c4ccccc4)c4ccc(-c5cccc6oc7ccccc7c56)cc4)ccc3c3c2ccc2oc4ccccc4c23)cc1 ; c1ccc(-c2cc3cc(N(c4ccccc4)c4cccc(-c5cccc6oc7ccccc7c56)c4)ccc3c3c2ccc2oc4ccccc4c23)cc1 ; c1ccc(-c2cc3cc(N(c4ccccc4)c4ccccc4-c4cccc5oc6ccccc6c45)ccc3c3c2ccc2oc4ccccc4c23)cc1 ; c1ccc(-c2cccc(N(c3ccc4c(c3)cc(-c3ccccc3)c3ccc5oc6ccccc6c5c34)c3ccc4ccc5ccccc5c4c3)c2)cc1 ; c1ccc(-c2ccccc2N(c2ccc3c(c2)cc(-c2ccccc2)c2ccc4oc5ccccc5c4c23)c2ccc3ccc4ccccc4c3c2)cc1]

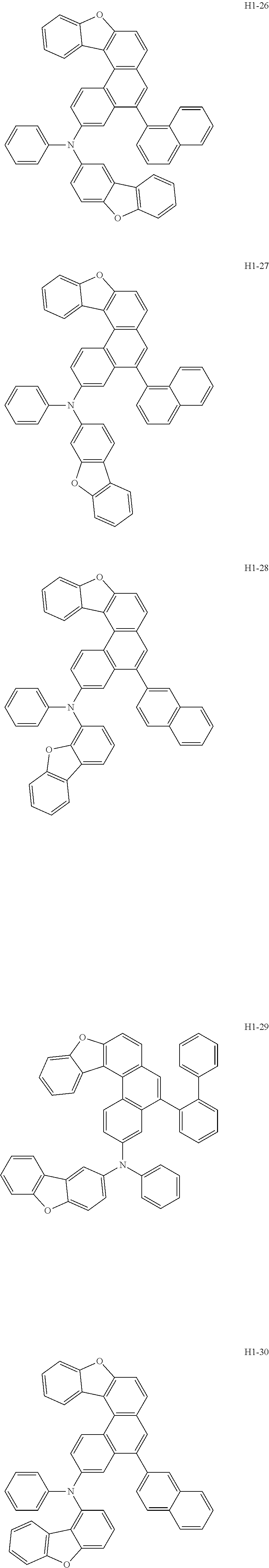 [SMILES: c1ccc(N(c2ccc3c(c2)c(-c2cccc4ccccc24)cc2ccc4oc5ccccc5c4c23)c2ccc3oc4ccccc4c3c2)cc1 ; c1ccc(N(c2ccc3c(c2)oc2ccccc23)c2ccc3c(c2)c(-c2cccc4ccccc24)cc2ccc4oc5ccccc5c4c23)cc1 ; c1ccc(N(c2ccc3c(c2)c(-c2ccc4ccccc4c2)cc2ccc4oc5ccccc5c4c23)c2cccc3c2oc2ccccc23)cc1 ; c1ccc(-c2ccccc2-c2cc3ccc4oc5ccccc5c4c3c3ccc(N(c4ccccc4)c4ccc5oc6ccccc6c5c4)cc23)cc1 ; c1ccc(N(c2ccc3c(c2)c(-c2ccc4ccccc4c2)cc2ccc4oc5ccccc5c4c23)c2cccc3oc4ccccc4c23)cc1]

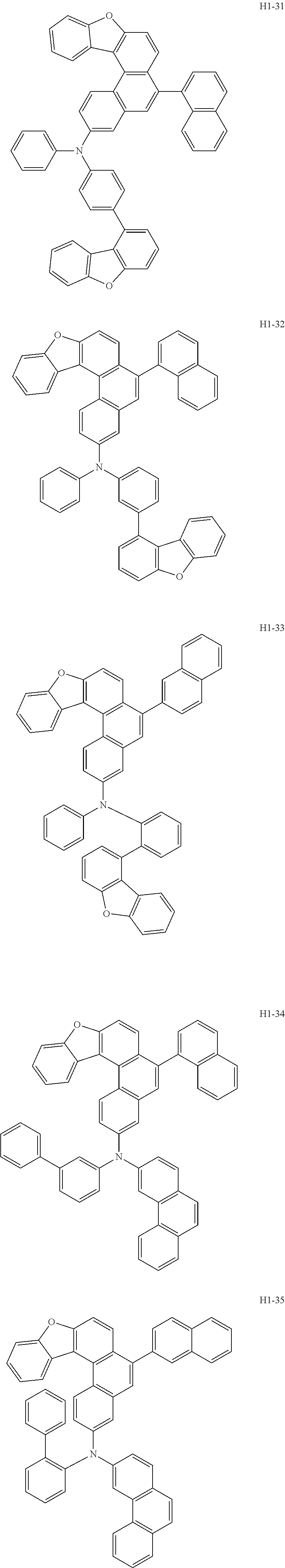 [SMILES: c1ccc(N(c2ccc(-c3cccc4oc5ccccc5c34)cc2)c2ccc3c(c2)cc(-c2cccc4ccccc24)c2ccc4oc5ccccc5c4c23)cc1 ; c1ccc(N(c2cccc(-c3cccc4oc5ccccc5c34)c2)c2ccc3c(c2)cc(-c2cccc4ccccc24)c2ccc4oc5ccccc5c4c23)cc1 ; c1ccc(N(c2ccc3c(c2)cc(-c2ccc4ccccc4c2)c2ccc4oc5ccccc5c4c23)c2ccccc2-c2cccc3oc4ccccc4c23)cc1 ; c1ccc(-c2cccc(N(c3ccc4c(c3)cc(-c3cccc5ccccc35)c3ccc5oc6ccccc6c5c34)c3ccc4ccc5ccccc5c4c3)c2)cc1 ; c1ccc(-c2ccccc2N(c2ccc3c(c2)cc(-c2ccc4ccccc4c2)c2ccc4oc5ccccc5c4c23)c2ccc3ccc4ccccc4c3c2)cc1]

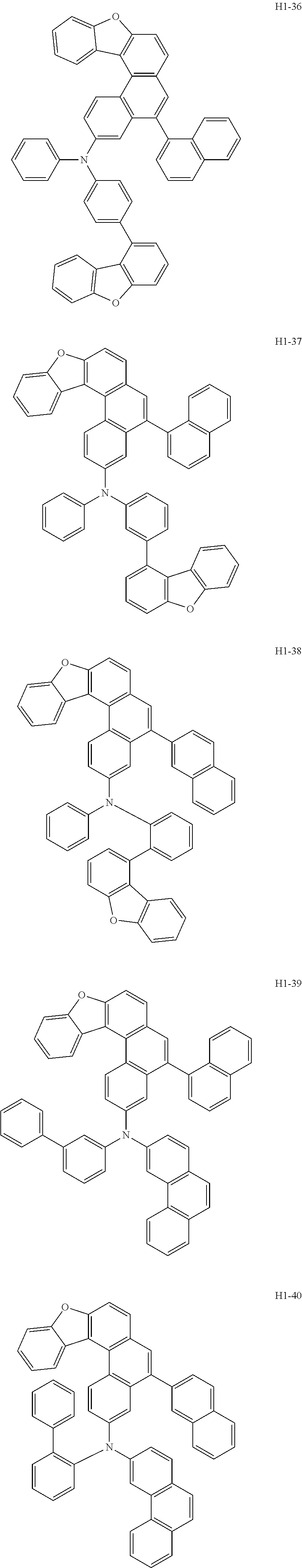 [SMILES: c1ccc(N(c2ccc(-c3cccc4oc5ccccc5c34)cc2)c2ccc3c(c2)c(-c2cccc4ccccc24)cc2ccc4oc5ccccc5c4c23)cc1 ; c1ccc(N(c2cccc(-c3cccc4oc5ccccc5c34)c2)c2ccc3c(c2)c(-c2cccc4ccccc24)cc2ccc4oc5ccccc5c4c23)cc1 ; c1ccc(N(c2ccc3c(c2)c(-c2ccc4ccccc4c2)cc2ccc4oc5ccccc5c4c23)c2ccccc2-c2cccc3oc4ccccc4c23)cc1 ; c1ccc(-c2cccc(N(c3ccc4c(c3)c(-c3cccc5ccccc35)cc3ccc5oc6ccccc6c5c34)c3ccc4ccc5ccccc5c4c3)c2)cc1 ; c1ccc(-c2ccccc2N(c2ccc3c(c2)c(-c2ccc4ccccc4c2)cc2ccc4oc5ccccc5c4c23)c2ccc3ccc4ccccc4c3c2)cc1]

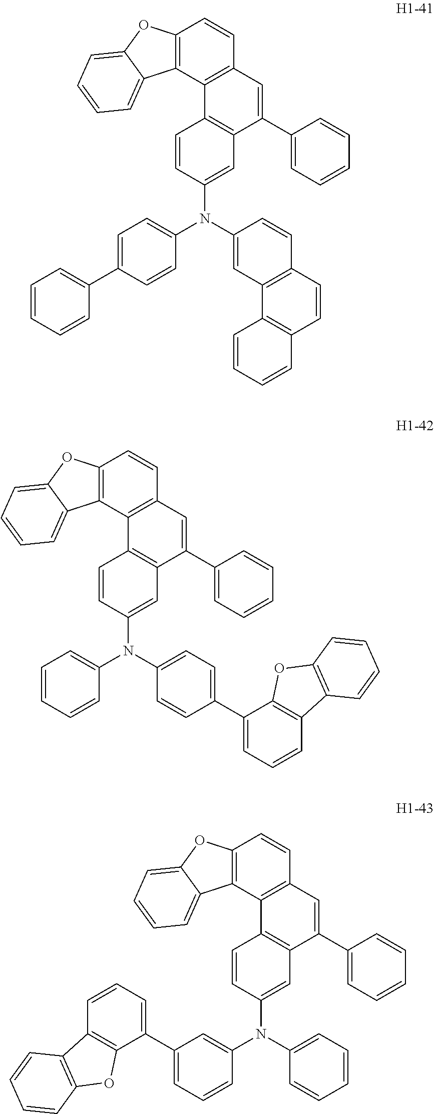 [SMILES: c1ccc(-c2ccc(N(c3ccc4c(c3)c(-c3ccccc3)cc3ccc5oc6ccccc6c5c34)c3ccc4ccc5ccccc5c4c3)cc2)cc1 ; c1ccc(-c2cc3ccc4oc5ccccc5c4c3c3ccc(N(c4ccccc4)c4ccc(-c5cccc6c5oc5ccccc56)cc4)cc23)cc1 ; c1ccc(-c2cc3ccc4oc5ccccc5c4c3c3ccc(N(c4ccccc4)c4cccc(-c5cccc6c5oc5ccccc56)c4)cc23)cc1]

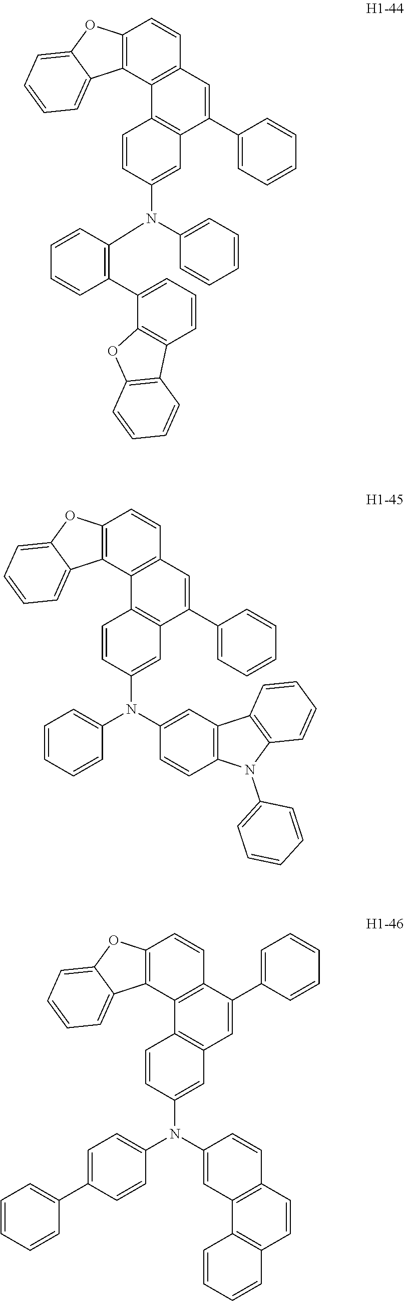 [SMILES: c1ccc(-c2cc3ccc4oc5ccccc5c4c3c3ccc(N(c4ccccc4)c4ccccc4-c4cccc5c4oc4ccccc45)cc23)cc1 ; c1ccc(-c2cc3ccc4oc5ccccc5c4c3c3ccc(N(c4ccccc4)c4ccc5c(c4)c4ccccc4n5-c4ccccc4)cc23)cc1 ; c1ccc(-c2ccc(N(c3ccc4c(c3)cc(-c3ccccc3)c3ccc5oc6ccccc6c5c34)c3ccc4ccc5ccccc5c4c3)cc2)cc1]

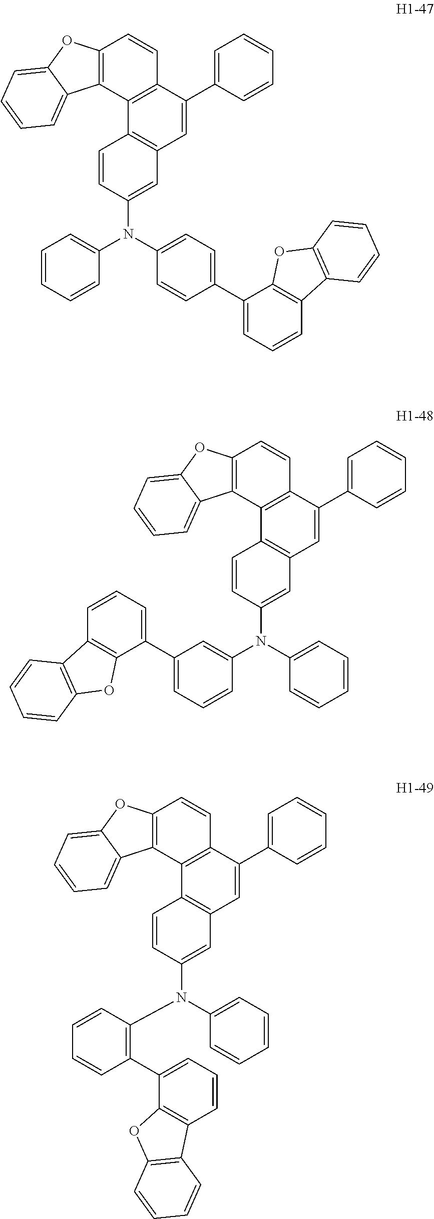 [SMILES: c1ccc(-c2cc3cc(N(c4ccccc4)c4ccc(-c5cccc6c5oc5ccccc56)cc4)ccc3c3c2ccc2oc4ccccc4c23)cc1 ; c1ccc(-c2cc3cc(N(c4ccccc4)c4cccc(-c5cccc6c5oc5ccccc56)c4)ccc3c3c2ccc2oc4ccccc4c23)cc1 ; c1ccc(-c2cc3cc(N(c4ccccc4)c4ccccc4-c4cccc5c4oc4ccccc45)ccc3c3c2ccc2oc4ccccc4c23)cc1]

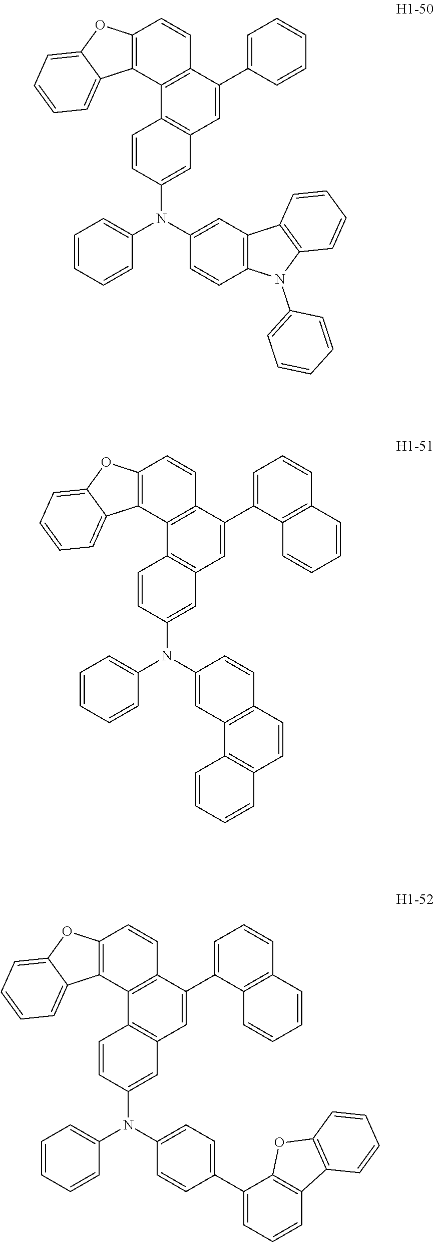 [SMILES: c1ccc(-c2cc3cc(N(c4ccccc4)c4ccc5c(c4)c4ccccc4n5-c4ccccc4)ccc3c3c2ccc2oc4ccccc4c23)cc1 ; c1ccc(N(c2ccc3c(c2)cc(-c2cccc4ccccc24)c2ccc4oc5ccccc5c4c23)c2ccc3ccc4ccccc4c3c2)cc1 ; c1ccc(N(c2ccc(-c3cccc4c3oc3ccccc34)cc2)c2ccc3c(c2)cc(-c2cccc4ccccc24)c2ccc4oc5ccccc5c4c23)cc1]

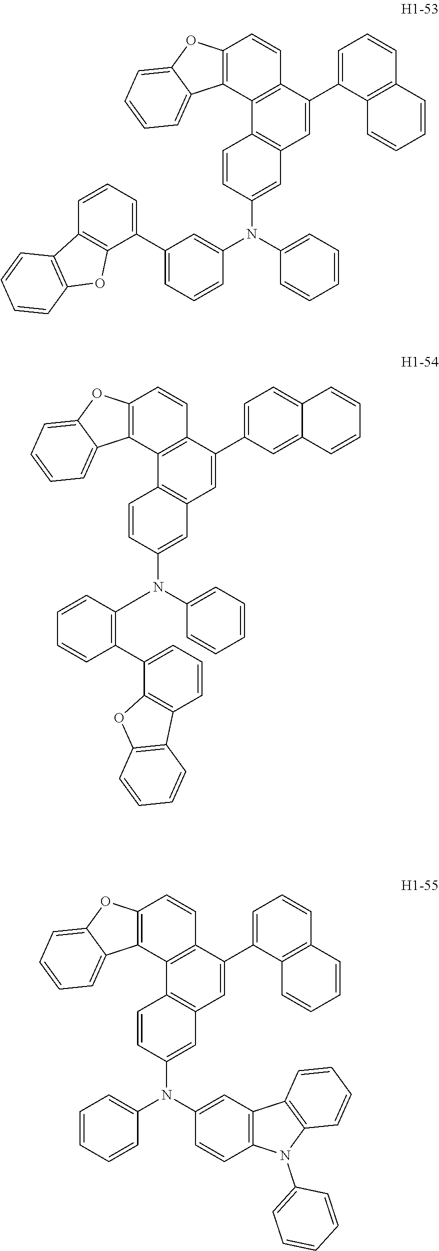 [SMILES: c1ccc(N(c2cccc(-c3cccc4c3oc3ccccc34)c2)c2ccc3c(c2)cc(-c2cccc4ccccc24)c2ccc4oc5ccccc5c4c23)cc1 ; c1ccc(N(c2ccc3c(c2)cc(-c2ccc4ccccc4c2)c2ccc4oc5ccccc5c4c23)c2ccccc2-c2cccc3c2oc2ccccc23)cc1 ; c1ccc(N(c2ccc3c(c2)cc(-c2cccc4ccccc24)c2ccc4oc5ccccc5c4c23)c2ccc3c(c2)c2ccccc2n3-c2ccccc2)cc1]

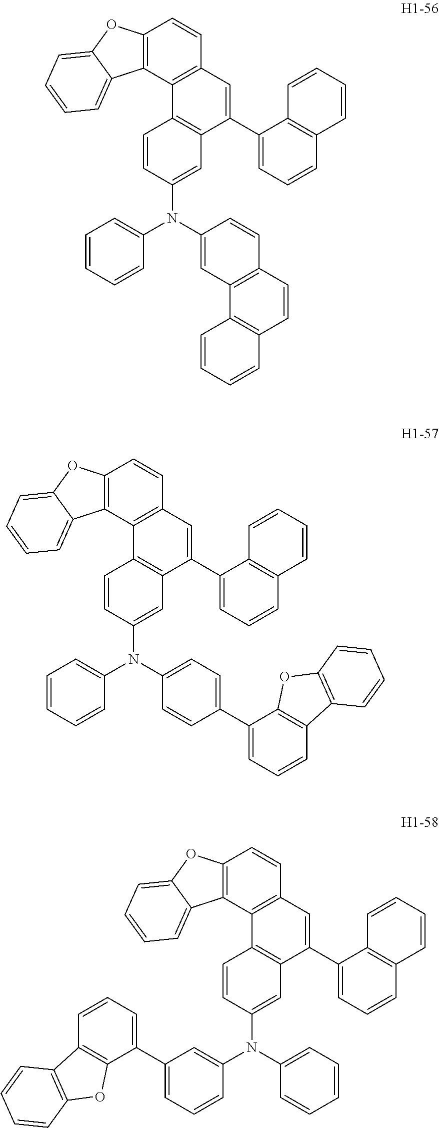 [SMILES: c1ccc(N(c2ccc3c(c2)c(-c2cccc4ccccc24)cc2ccc4oc5ccccc5c4c23)c2ccc3ccc4ccccc4c3c2)cc1 ; c1ccc(N(c2ccc(-c3cccc4c3oc3ccccc34)cc2)c2ccc3c(c2)c(-c2cccc4ccccc24)cc2ccc4oc5ccccc5c4c23)cc1 ; c1ccc(N(c2cccc(-c3cccc4c3oc3ccccc34)c2)c2ccc3c(c2)c(-c2cccc4ccccc24)cc2ccc4oc5ccccc5c4c23)cc1]

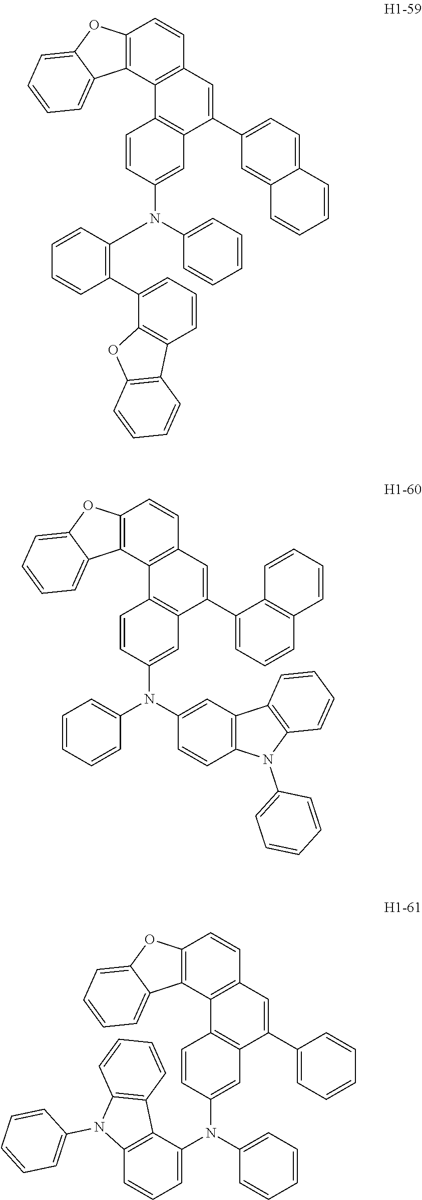 [SMILES: c1ccc(N(c2ccc3c(c2)c(-c2ccc4ccccc4c2)cc2ccc4oc5ccccc5c4c23)c2ccccc2-c2cccc3c2oc2ccccc23)cc1 ; c1ccc(N(c2ccc3c(c2)c(-c2cccc4ccccc24)cc2ccc4oc5ccccc5c4c23)c2ccc3c(c2)c2ccccc2n3-c2ccccc2)cc1 ; c1ccc(-c2cc3ccc4oc5ccccc5c4c3c3ccc(N(c4ccccc4)c4cccc5c4c4ccccc4n5-c4ccccc4)cc23)cc1]

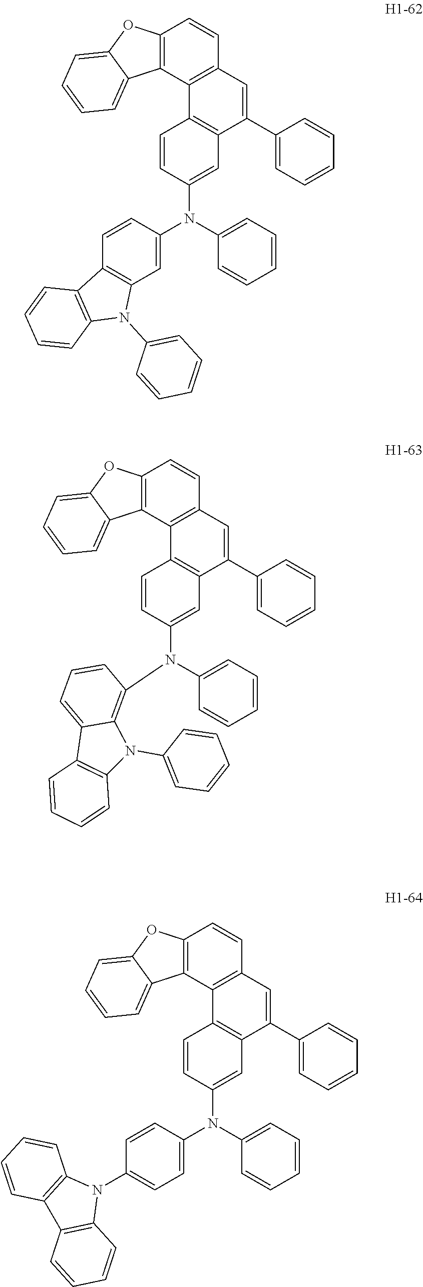 [SMILES: c1ccc(-c2cc3ccc4oc5ccccc5c4c3c3ccc(N(c4ccccc4)c4ccc5c6ccccc6n(-c6ccccc6)c5c4)cc23)cc1 ; c1ccc(-c2cc3ccc4oc5ccccc5c4c3c3ccc(N(c4ccccc4)c4cccc5c6ccccc6n(-c6ccccc6)c45)cc23)cc1 ; c1ccc(-c2cc3ccc4oc5ccccc5c4c3c3ccc(N(c4ccccc4)c4ccc(-n5c6ccccc6c6ccccc65)cc4)cc23)cc1]

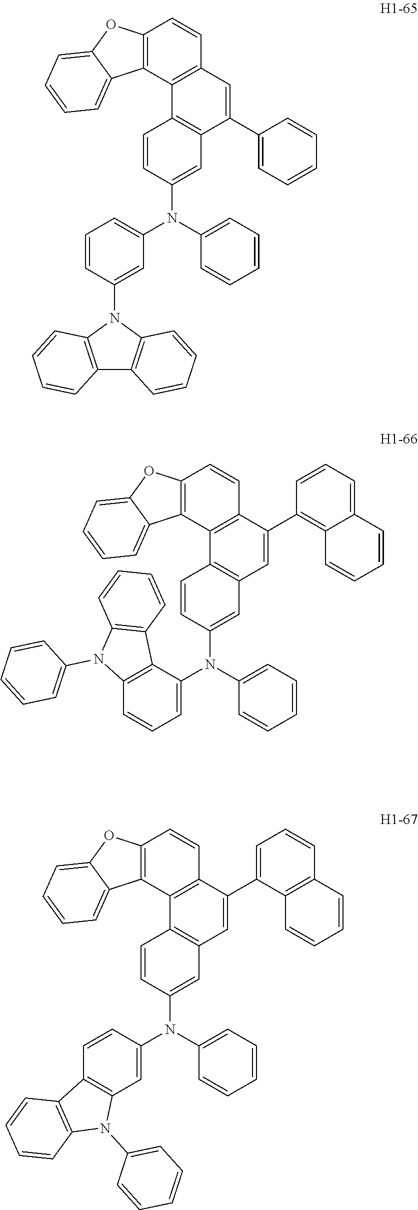 [SMILES: c1ccc(-c2cc3ccc4oc5ccccc5c4c3c3ccc(N(c4ccccc4)c4cccc(-n5c6ccccc6c6ccccc65)c4)cc23)cc1 ; c1ccc(N(c2ccc3c(c2)cc(-c2cccc4ccccc24)c2ccc4oc5ccccc5c4c23)c2cccc3c2c2ccccc2n3-c2ccccc2)cc1 ; c1ccc(N(c2ccc3c(c2)cc(-c2cccc4ccccc24)c2ccc4oc5ccccc5c4c23)c2ccc3c4ccccc4n(-c4ccccc4)c3c2)cc1]

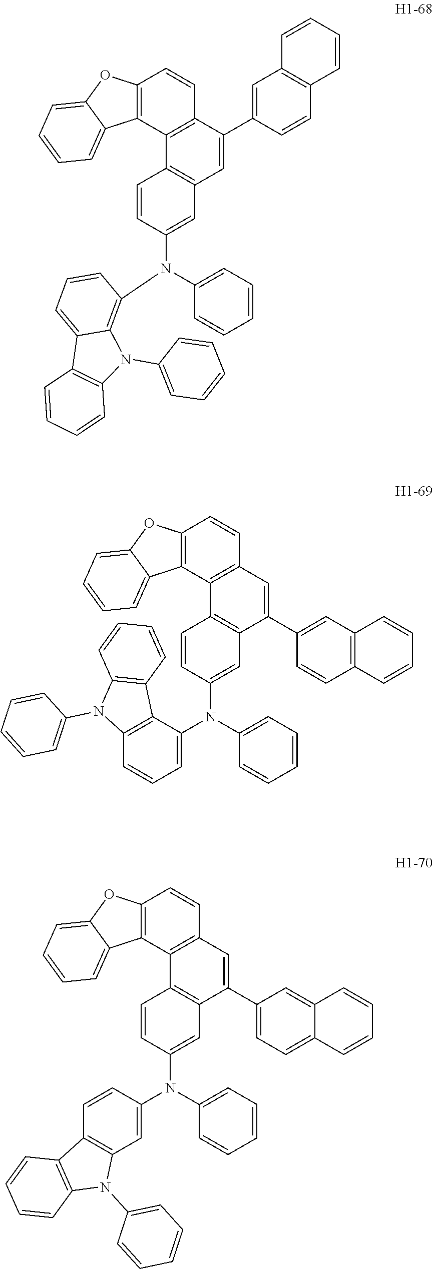 [SMILES: c1ccc(N(c2ccc3c(c2)cc(-c2ccc4ccccc4c2)c2ccc4oc5ccccc5c4c23)c2cccc3c4ccccc4n(-c4ccccc4)c23)cc1 ; c1ccc(N(c2ccc3c(c2)c(-c2ccc4ccccc4c2)cc2ccc4oc5ccccc5c4c23)c2cccc3c2c2ccccc2n3-c2ccccc2)cc1 ; c1ccc(N(c2ccc3c(c2)c(-c2ccc4ccccc4c2)cc2ccc4oc5ccccc5c4c23)c2ccc3c4ccccc4n(-c4ccccc4)c3c2)cc1]

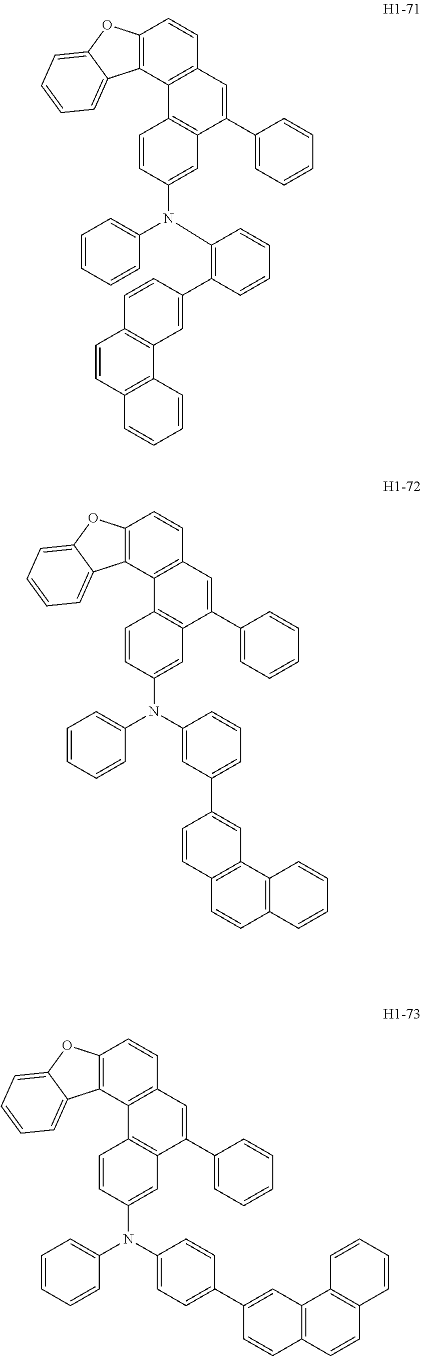 [SMILES: c1ccc(-c2cc3ccc4oc5ccccc5c4c3c3ccc(N(c4ccccc4)c4ccccc4-c4ccc5ccc6ccccc6c5c4)cc23)cc1 ; c1ccc(-c2cc3ccc4oc5ccccc5c4c3c3ccc(N(c4ccccc4)c4cccc(-c5ccc6ccc7ccccc7c6c5)c4)cc23)cc1 ; c1ccc(-c2cc3ccc4oc5ccccc5c4c3c3ccc(N(c4ccccc4)c4ccc(-c5ccc6ccc7ccccc7c6c5)cc4)cc23)cc1]

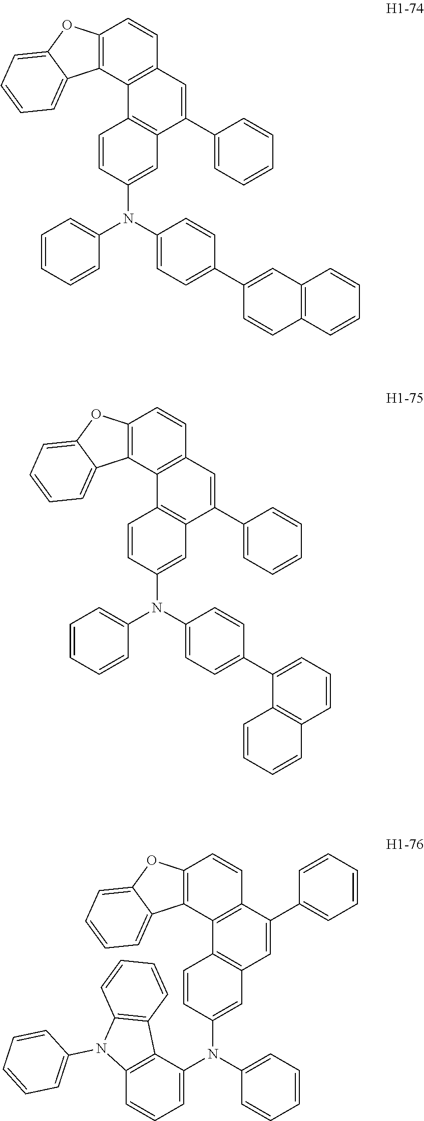 [SMILES: c1ccc(-c2cc3ccc4oc5ccccc5c4c3c3ccc(N(c4ccccc4)c4ccc(-c5ccc6ccccc6c5)cc4)cc23)cc1 ; c1ccc(-c2cc3ccc4oc5ccccc5c4c3c3ccc(N(c4ccccc4)c4ccc(-c5cccc6ccccc56)cc4)cc23)cc1 ; c1ccc(-c2cc3cc(N(c4ccccc4)c4cccc5c4c4ccccc4n5-c4ccccc4)ccc3c3c2ccc2oc4ccccc4c23)cc1]

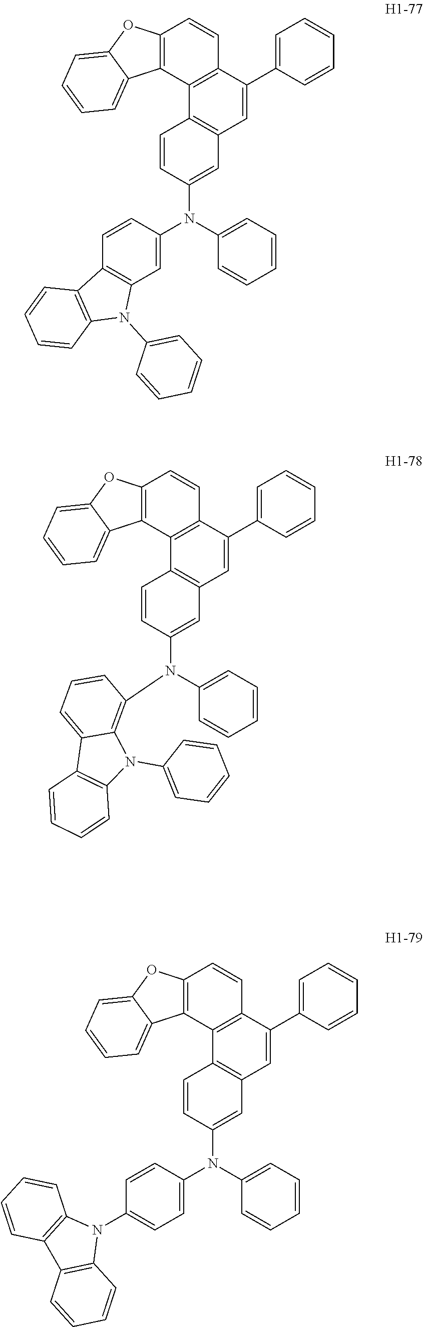 [SMILES: c1ccc(-c2cc3cc(N(c4ccccc4)c4ccc5c6ccccc6n(-c6ccccc6)c5c4)ccc3c3c2ccc2oc4ccccc4c23)cc1 ; c1ccc(-c2cc3cc(N(c4ccccc4)c4cccc5c6ccccc6n(-c6ccccc6)c45)ccc3c3c2ccc2oc4ccccc4c23)cc1 ; c1ccc(-c2cc3cc(N(c4ccccc4)c4ccc(-n5c6ccccc6c6ccccc65)cc4)ccc3c3c2ccc2oc4ccccc4c23)cc1]

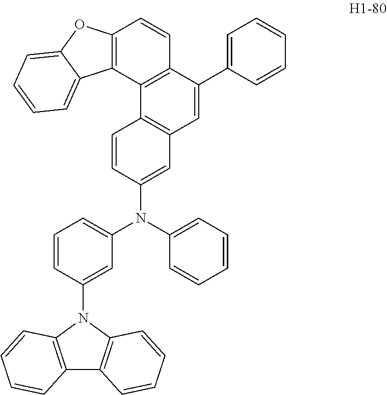 [SMILES: c1ccc(-c2cc3cc(N(c4ccccc4)c4cccc(-n5c6ccccc6c6ccccc65)c4)ccc3c3c2ccc2oc4ccccc4c23)cc1]

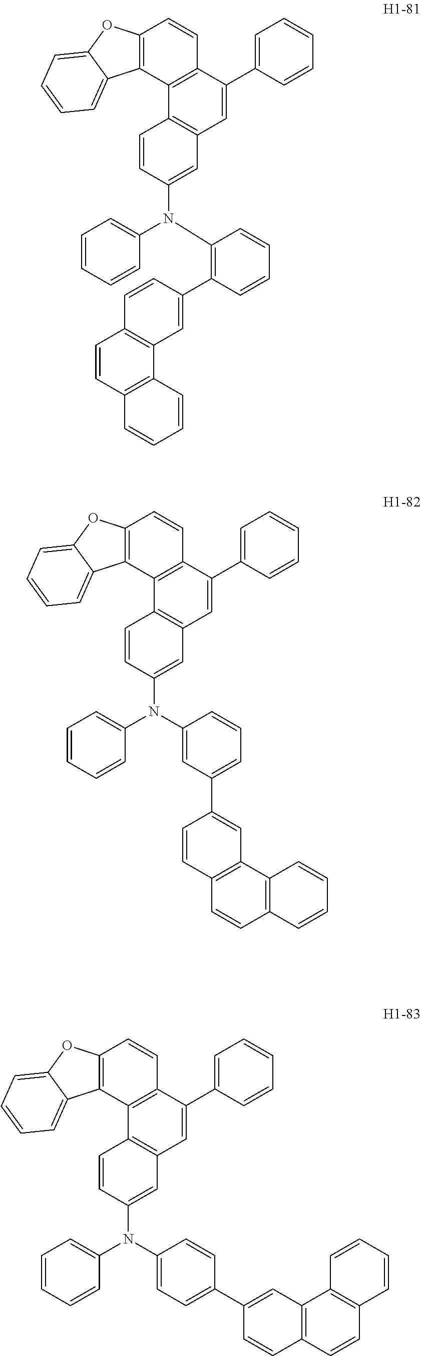 [SMILES: c1ccc(-c2cc3cc(N(c4ccccc4)c4ccccc4-c4ccc5ccc6ccccc6c5c4)ccc3c3c2ccc2oc4ccccc4c23)cc1 ; c1ccc(-c2cc3cc(N(c4ccccc4)c4cccc(-c5ccc6ccc7ccccc7c6c5)c4)ccc3c3c2ccc2oc4ccccc4c23)cc1 ; c1ccc(-c2cc3cc(N(c4ccccc4)c4ccc(-c5ccc6ccc7ccccc7c6c5)cc4)ccc3c3c2ccc2oc4ccccc4c23)cc1]

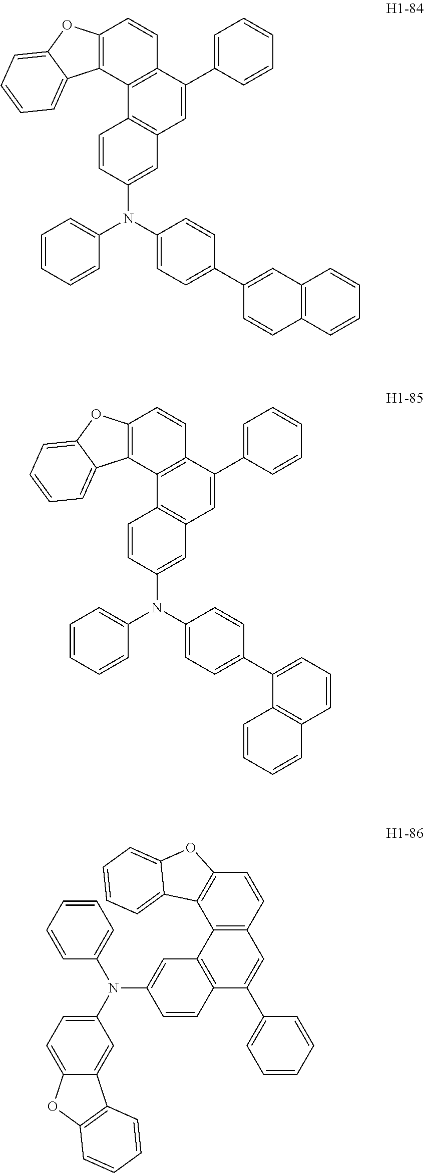 [SMILES: c1ccc(-c2cc3cc(N(c4ccccc4)c4ccc(-c5ccc6ccccc6c5)cc4)ccc3c3c2ccc2oc4ccccc4c23)cc1 ; c1ccc(-c2cc3cc(N(c4ccccc4)c4ccc(-c5cccc6ccccc56)cc4)ccc3c3c2ccc2oc4ccccc4c23)cc1 ; c1ccc(-c2cc3ccc4oc5ccccc5c4c3c3cc(N(c4ccccc4)c4ccc5oc6ccccc6c5c4)ccc23)cc1]

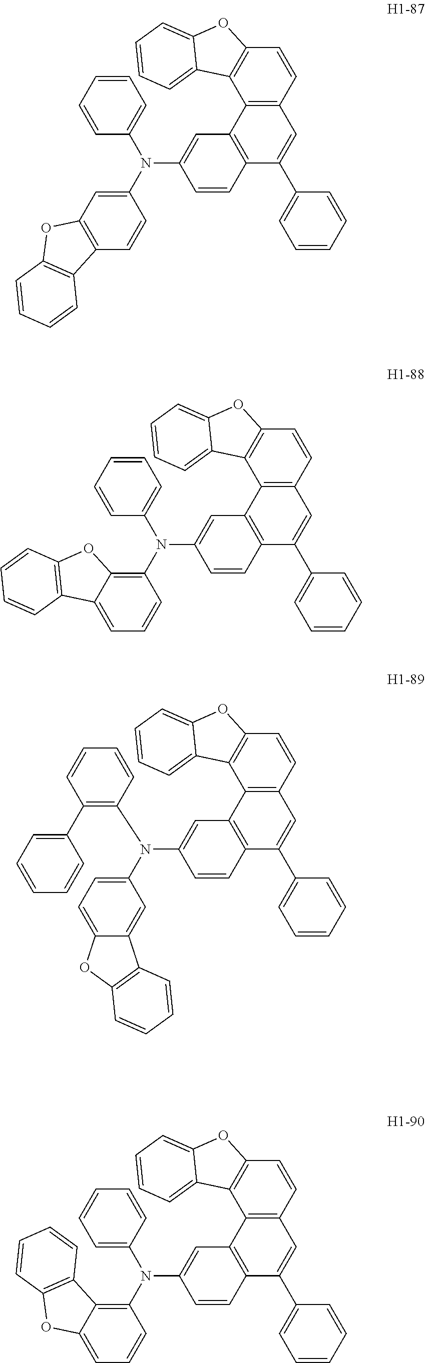 [SMILES: c1ccc(-c2cc3ccc4oc5ccccc5c4c3c3cc(N(c4ccccc4)c4ccc5c(c4)oc4ccccc45)ccc23)cc1 ; c1ccc(-c2cc3ccc4oc5ccccc5c4c3c3cc(N(c4ccccc4)c4cccc5c4oc4ccccc45)ccc23)cc1 ; c1ccc(-c2ccccc2N(c2ccc3oc4ccccc4c3c2)c2ccc3c(-c4ccccc4)cc4ccc5oc6ccccc6c5c4c3c2)cc1 ; c1ccc(-c2cc3ccc4oc5ccccc5c4c3c3cc(N(c4ccccc4)c4cccc5oc6ccccc6c45)ccc23)cc1]

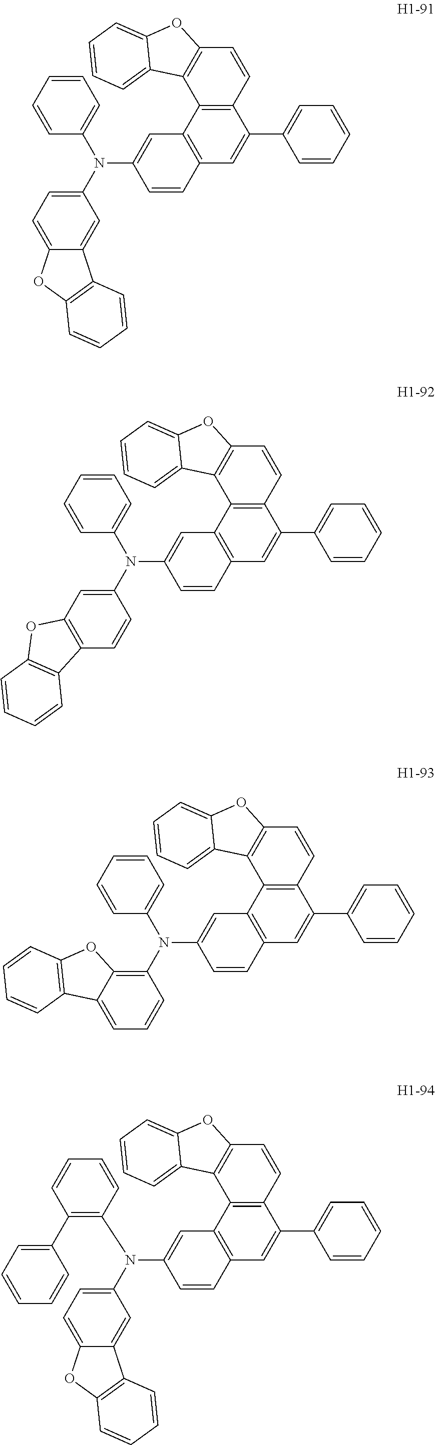 [SMILES: c1ccc(-c2cc3ccc(N(c4ccccc4)c4ccc5oc6ccccc6c5c4)cc3c3c2ccc2oc4ccccc4c23)cc1 ; c1ccc(-c2cc3ccc(N(c4ccccc4)c4ccc5c(c4)oc4ccccc45)cc3c3c2ccc2oc4ccccc4c23)cc1 ; c1ccc(-c2cc3ccc(N(c4ccccc4)c4cccc5c4oc4ccccc45)cc3c3c2ccc2oc4ccccc4c23)cc1 ; c1ccc(-c2ccccc2N(c2ccc3oc4ccccc4c3c2)c2ccc3cc(-c4ccccc4)c4ccc5oc6ccccc6c5c4c3c2)cc1]

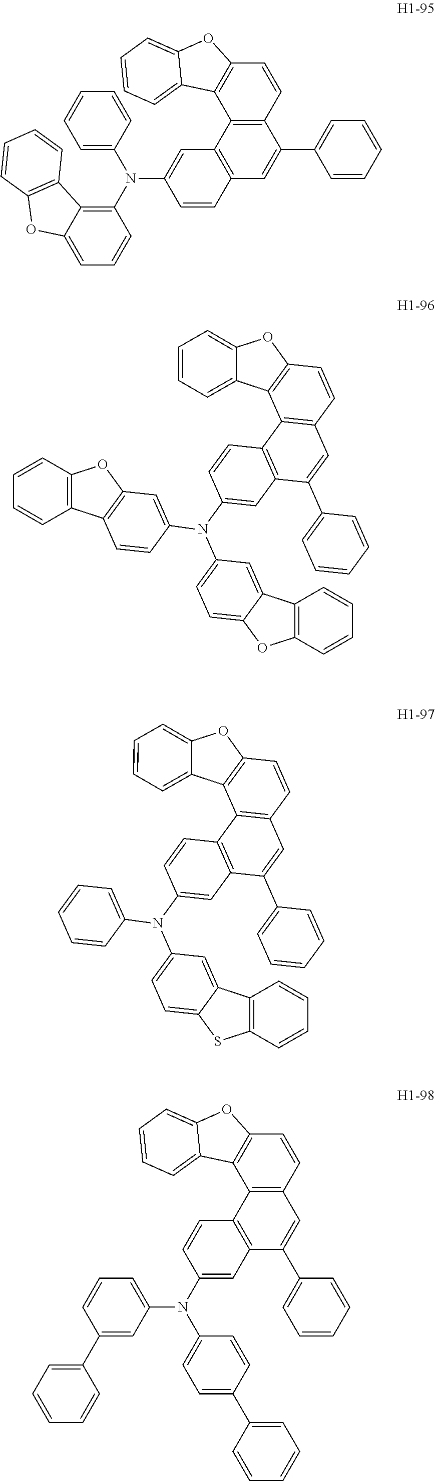 [SMILES: c1ccc(-c2cc3ccc(N(c4ccccc4)c4cccc5oc6ccccc6c45)cc3c3c2ccc2oc4ccccc4c23)cc1 ; c1ccc(-c2cc3ccc4oc5ccccc5c4c3c3ccc(N(c4ccc5c(c4)oc4ccccc45)c4ccc5oc6ccccc6c5c4)cc23)cc1 ; c1ccc(-c2cc3ccc4oc5ccccc5c4c3c3ccc(N(c4ccccc4)c4ccc5sc6ccccc6c5c4)cc23)cc1 ; c1ccc(-c2ccc(N(c3cccc(-c4ccccc4)c3)c3ccc4c(c3)c(-c3ccccc3)cc3ccc5oc6ccccc6c5c34)cc2)cc1]

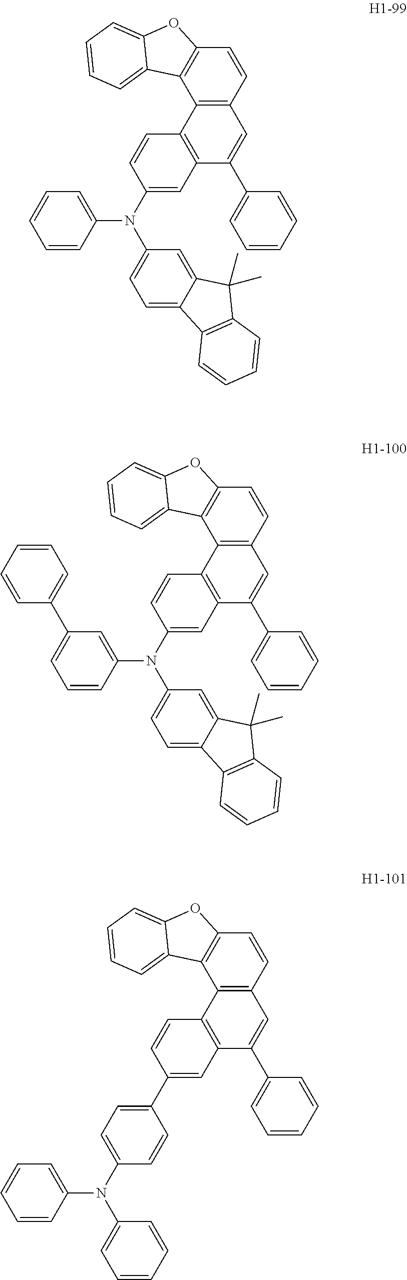 [SMILES: CC1(C)c2ccccc2-c2ccc(N(c3ccccc3)c3ccc4c(c3)c(-c3ccccc3)cc3ccc5oc6ccccc6c5c34)cc21 ; CC1(C)c2ccccc2-c2ccc(N(c3cccc(-c4ccccc4)c3)c3ccc4c(c3)c(-c3ccccc3)cc3ccc5oc6ccccc6c5c34)cc21 ; c1ccc(-c2cc3ccc4oc5ccccc5c4c3c3ccc(-c4ccc(N(c5ccccc5)c5ccccc5)cc4)cc23)cc1]

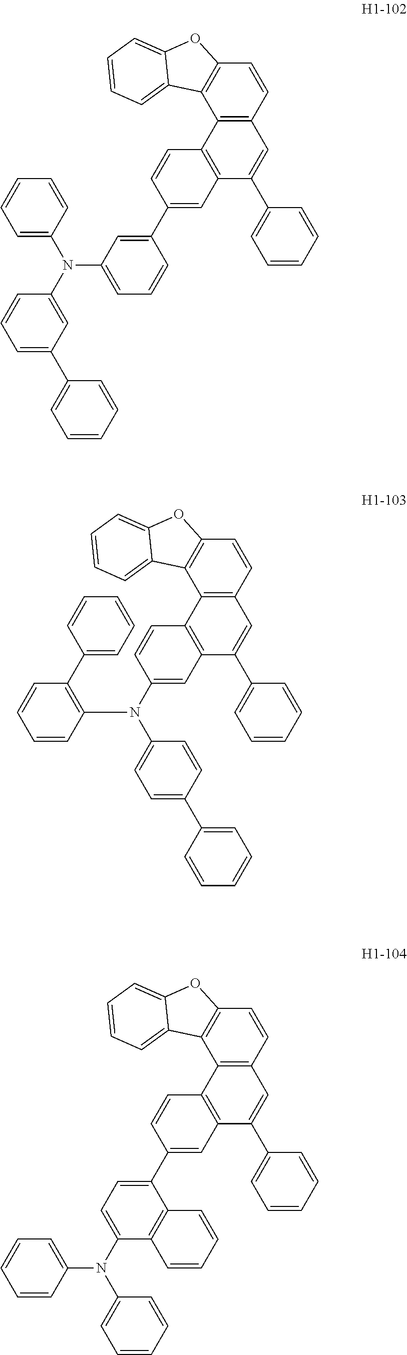 [SMILES: c1ccc(-c2cccc(N(c3ccccc3)c3cccc(-c4ccc5c(c4)c(-c4ccccc4)cc4ccc6oc7ccccc7c6c45)c3)c2)cc1 ; c1ccc(-c2ccc(N(c3ccc4c(c3)c(-c3ccccc3)cc3ccc5oc6ccccc6c5c34)c3ccccc3-c3ccccc3)cc2)cc1 ; c1ccc(-c2cc3ccc4oc5ccccc5c4c3c3ccc(-c4ccc(N(c5ccccc5)c5ccccc5)c5ccccc45)cc23)cc1]

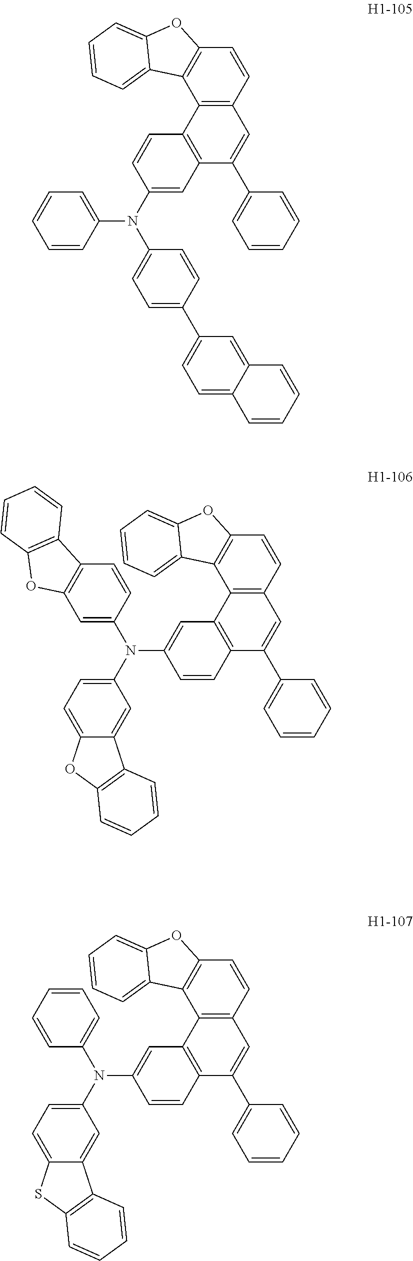 [SMILES: c1ccc(-c2cc3ccc4oc5ccccc5c4c3c3ccc(N(c4ccccc4)c4ccc(-c5ccc6ccccc6c5)cc4)cc23)cc1 ; c1ccc(-c2cc3ccc4oc5ccccc5c4c3c3cc(N(c4ccc5c(c4)oc4ccccc45)c4ccc5oc6ccccc6c5c4)ccc23)cc1 ; c1ccc(-c2cc3ccc4oc5ccccc5c4c3c3cc(N(c4ccccc4)c4ccc5sc6ccccc6c5c4)ccc23)cc1]

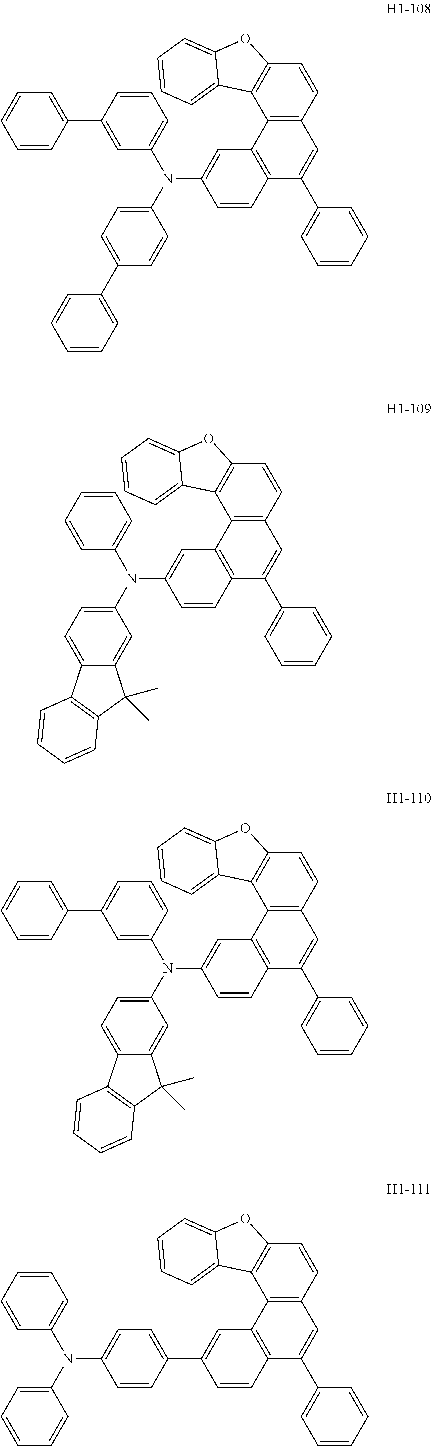 [SMILES: c1ccc(-c2ccc(N(c3cccc(-c4ccccc4)c3)c3ccc4c(-c5ccccc5)cc5ccc6oc7ccccc7c6c5c4c3)cc2)cc1 ; CC1(C)c2ccccc2-c2ccc(N(c3ccccc3)c3ccc4c(-c5ccccc5)cc5ccc6oc7ccccc7c6c5c4c3)cc21 ; CC1(C)c2ccccc2-c2ccc(N(c3cccc(-c4ccccc4)c3)c3ccc4c(-c5ccccc5)cc5ccc6oc7ccccc7c6c5c4c3)cc21 ; c1ccc(-c2cc3ccc4oc5ccccc5c4c3c3cc(-c4ccc(N(c5ccccc5)c5ccccc5)cc4)ccc23)cc1]

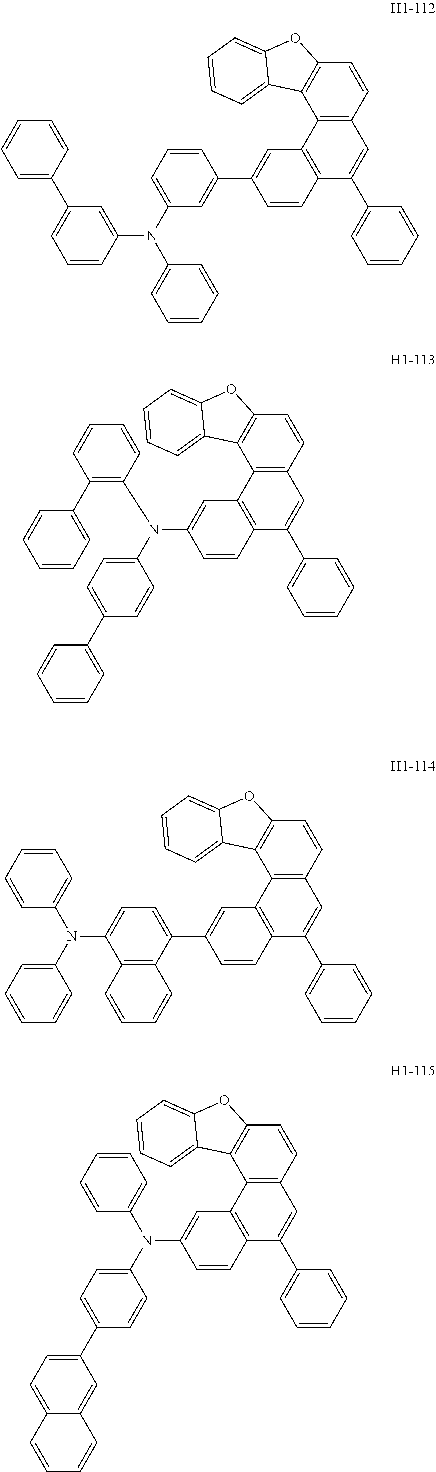 [SMILES: c1ccc(-c2cccc(N(c3ccccc3)c3cccc(-c4ccc5c(-c6ccccc6)cc6ccc7oc8ccccc8c7c6c5c4)c3)c2)cc1 ; c1ccc(-c2ccc(N(c3ccc4c(-c5ccccc5)cc5ccc6oc7ccccc7c6c5c4c3)c3ccccc3-c3ccccc3)cc2)cc1 ; c1ccc(-c2cc3ccc4oc5ccccc5c4c3c3cc(-c4ccc(N(c5ccccc5)c5ccccc5)c5ccccc45)ccc23)cc1 ; c1ccc(-c2cc3ccc4oc5ccccc5c4c3c3cc(N(c4ccccc4)c4ccc(-c5ccc6ccccc6c5)cc4)ccc23)cc1]

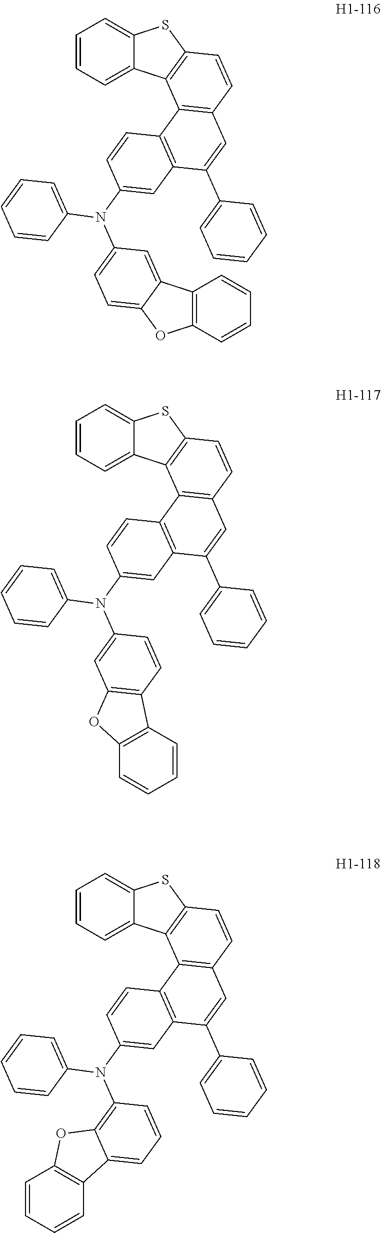 [SMILES: c1ccc(-c2cc3ccc4sc5ccccc5c4c3c3ccc(N(c4ccccc4)c4ccc5oc6ccccc6c5c4)cc23)cc1 ; c1ccc(-c2cc3ccc4sc5ccccc5c4c3c3ccc(N(c4ccccc4)c4ccc5c(c4)oc4ccccc45)cc23)cc1 ; c1ccc(-c2cc3ccc4sc5ccccc5c4c3c3ccc(N(c4ccccc4)c4cccc5c4oc4ccccc45)cc23)cc1]

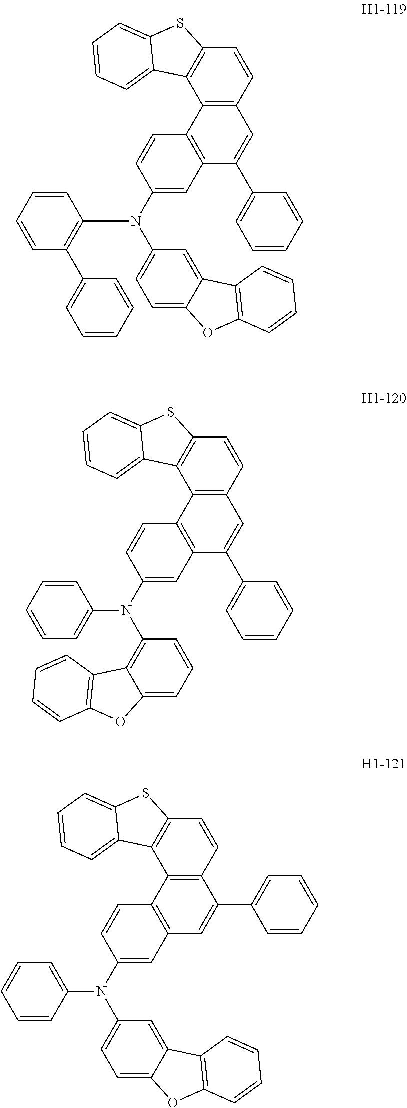 [SMILES: c1ccc(-c2ccccc2N(c2ccc3c(c2)c(-c2ccccc2)cc2ccc4sc5ccccc5c4c23)c2ccc3oc4ccccc4c3c2)cc1 ; c1ccc(-c2cc3ccc4sc5ccccc5c4c3c3ccc(N(c4ccccc4)c4cccc5oc6ccccc6c45)cc23)cc1 ; c1ccc(-c2cc3cc(N(c4ccccc4)c4ccc5oc6ccccc6c5c4)ccc3c3c2ccc2sc4ccccc4c23)cc1]

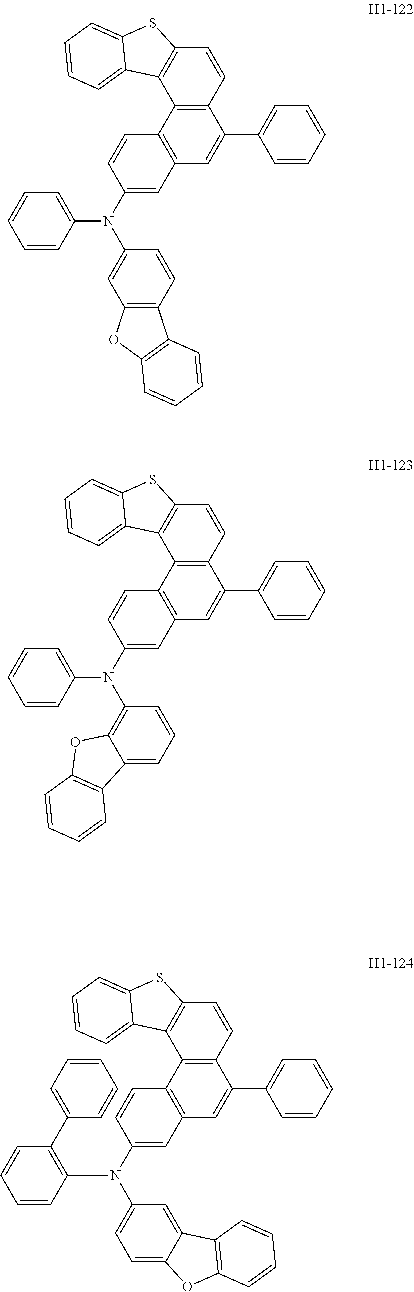 [SMILES: c1ccc(-c2cc3cc(N(c4ccccc4)c4ccc5c(c4)oc4ccccc45)ccc3c3c2ccc2sc4ccccc4c23)cc1 ; c1ccc(-c2cc3cc(N(c4ccccc4)c4cccc5c4oc4ccccc45)ccc3c3c2ccc2sc4ccccc4c23)cc1 ; c1ccc(-c2ccccc2N(c2ccc3c(c2)cc(-c2ccccc2)c2ccc4sc5ccccc5c4c23)c2ccc3oc4ccccc4c3c2)cc1]

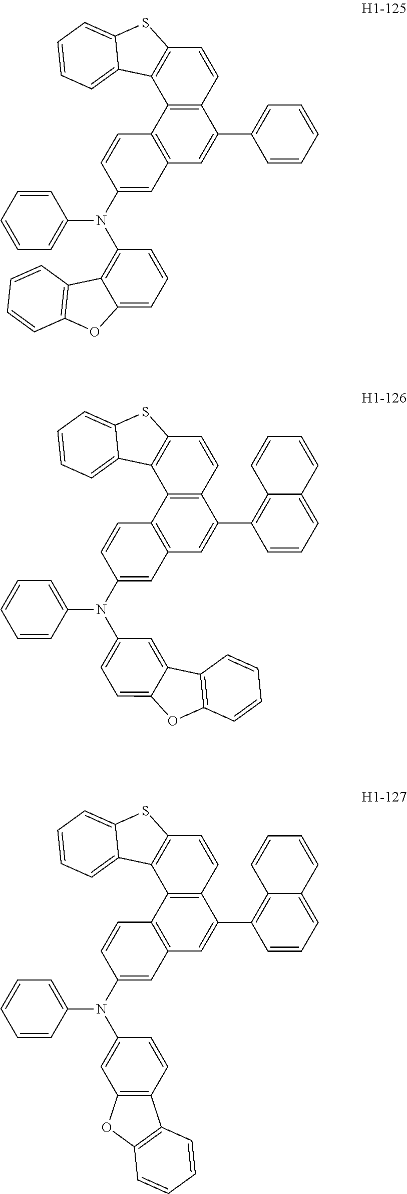 [SMILES: c1ccc(-c2cc3cc(N(c4ccccc4)c4cccc5oc6ccccc6c45)ccc3c3c2ccc2sc4ccccc4c23)cc1 ; c1ccc(N(c2ccc3c(c2)cc(-c2cccc4ccccc24)c2ccc4sc5ccccc5c4c23)c2ccc3oc4ccccc4c3c2)cc1 ; c1ccc(N(c2ccc3c(c2)cc(-c2cccc4ccccc24)c2ccc4sc5ccccc5c4c23)c2ccc3c(c2)oc2ccccc23)cc1]

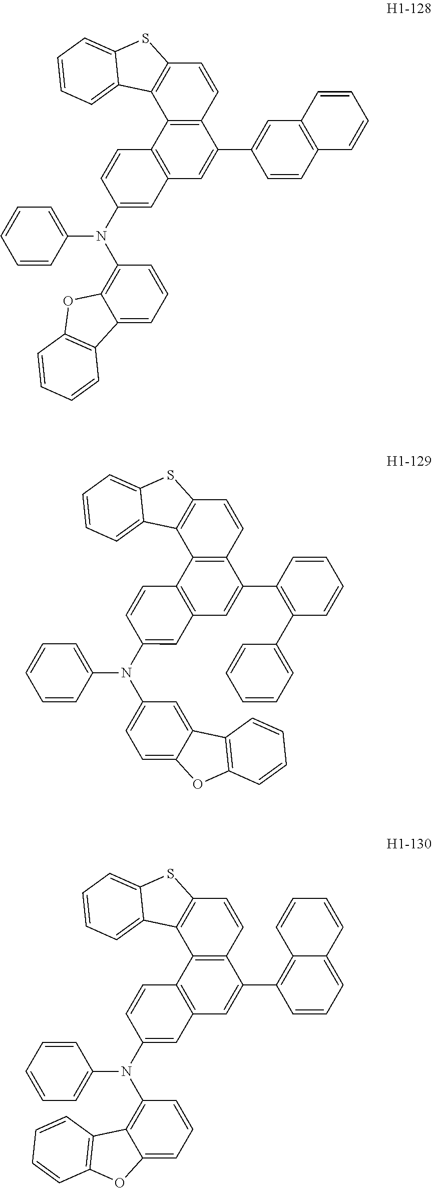 [SMILES: c1ccc(N(c2ccc3c(c2)cc(-c2ccc4ccccc4c2)c2ccc4sc5ccccc5c4c23)c2cccc3c2oc2ccccc23)cc1 ; c1ccc(-c2ccccc2-c2cc3cc(N(c4ccccc4)c4ccc5oc6ccccc6c5c4)ccc3c3c2ccc2sc4ccccc4c23)cc1 ; c1ccc(N(c2ccc3c(c2)cc(-c2cccc4ccccc24)c2ccc4sc5ccccc5c4c23)c2cccc3oc4ccccc4c23)cc1]

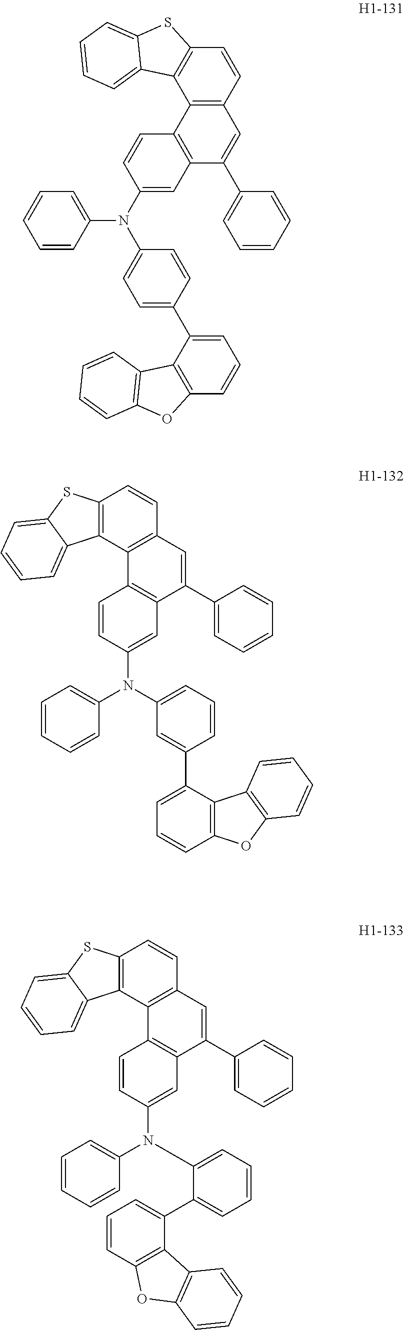 [SMILES: c1ccc(-c2cc3ccc4sc5ccccc5c4c3c3ccc(N(c4ccccc4)c4ccc(-c5cccc6oc7ccccc7c56)cc4)cc23)cc1 ; c1ccc(-c2cc3ccc4sc5ccccc5c4c3c3ccc(N(c4ccccc4)c4cccc(-c5cccc6oc7ccccc7c56)c4)cc23)cc1 ; c1ccc(-c2cc3ccc4sc5ccccc5c4c3c3ccc(N(c4ccccc4)c4ccccc4-c4cccc5oc6ccccc6c45)cc23)cc1]

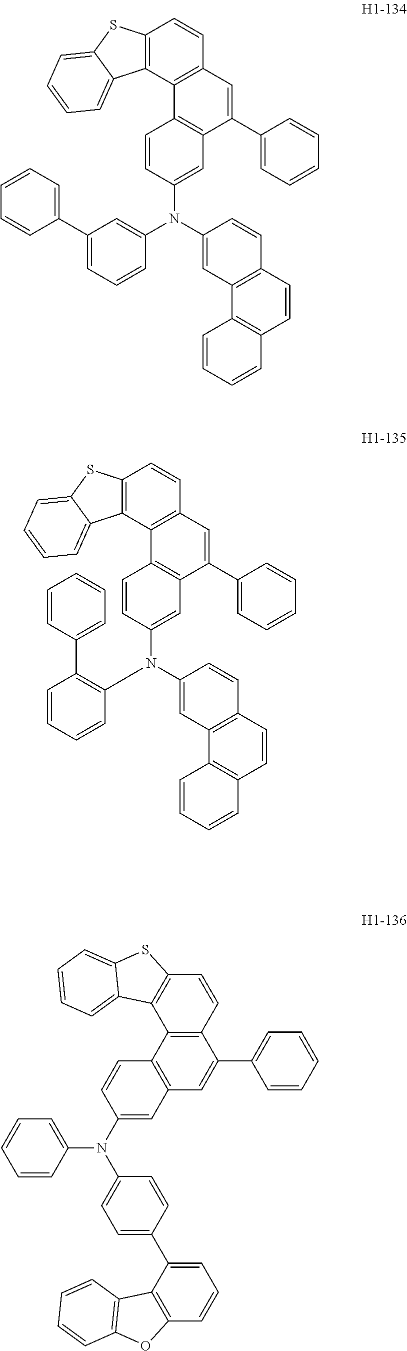 [SMILES: c1ccc(-c2cccc(N(c3ccc4c(c3)c(-c3ccccc3)cc3ccc5sc6ccccc6c5c34)c3ccc4ccc5ccccc5c4c3)c2)cc1 ; c1ccc(-c2ccccc2N(c2ccc3c(c2)c(-c2ccccc2)cc2ccc4sc5ccccc5c4c23)c2ccc3ccc4ccccc4c3c2)cc1 ; c1ccc(-c2cc3cc(N(c4ccccc4)c4ccc(-c5cccc6oc7ccccc7c56)cc4)ccc3c3c2ccc2sc4ccccc4c23)cc1]

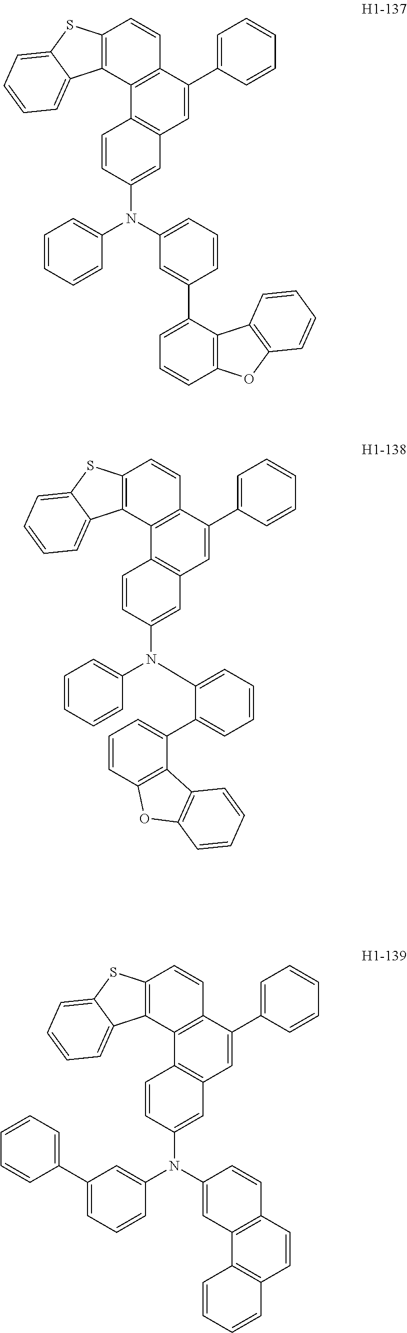 [SMILES: c1ccc(-c2cc3cc(N(c4ccccc4)c4cccc(-c5cccc6oc7ccccc7c56)c4)ccc3c3c2ccc2sc4ccccc4c23)cc1 ; c1ccc(-c2cc3cc(N(c4ccccc4)c4ccccc4-c4cccc5oc6ccccc6c45)ccc3c3c2ccc2sc4ccccc4c23)cc1 ; c1ccc(-c2cccc(N(c3ccc4c(c3)cc(-c3ccccc3)c3ccc5sc6ccccc6c5c34)c3ccc4ccc5ccccc5c4c3)c2)cc1]

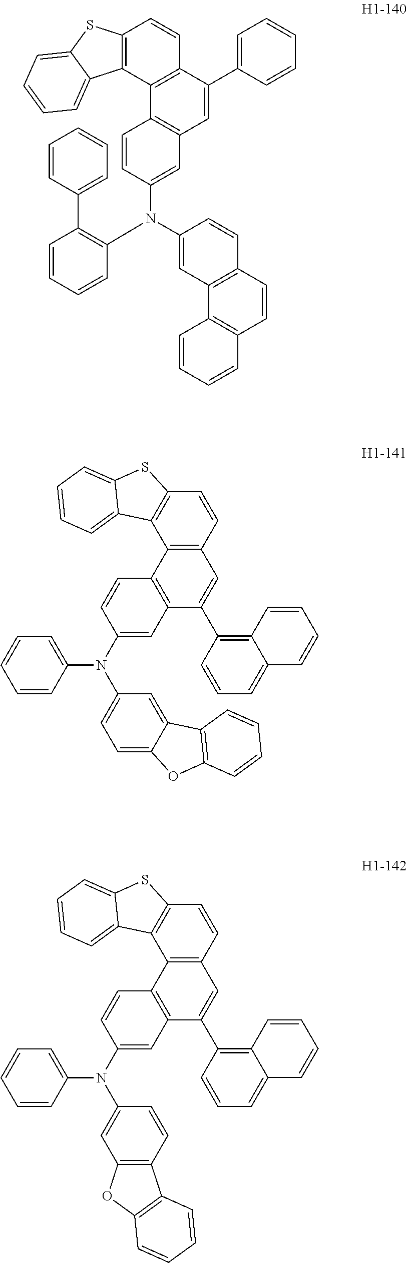 [SMILES: c1ccc(-c2ccccc2N(c2ccc3c(c2)cc(-c2ccccc2)c2ccc4sc5ccccc5c4c23)c2ccc3ccc4ccccc4c3c2)cc1 ; c1ccc(N(c2ccc3c(c2)c(-c2cccc4ccccc24)cc2ccc4sc5ccccc5c4c23)c2ccc3oc4ccccc4c3c2)cc1 ; c1ccc(N(c2ccc3c(c2)oc2ccccc23)c2ccc3c(c2)c(-c2cccc4ccccc24)cc2ccc4sc5ccccc5c4c23)cc1]

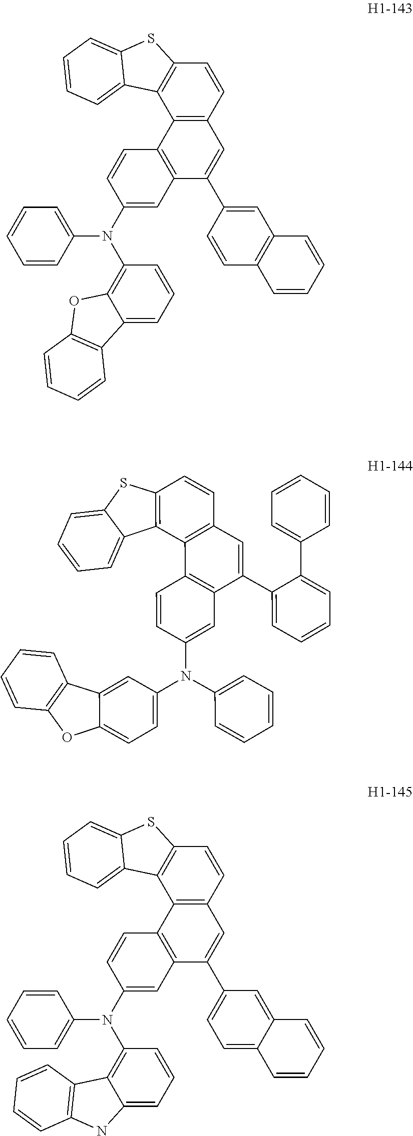 [SMILES: c1ccc(N(c2ccc3c(c2)c(-c2ccc4ccccc4c2)cc2ccc4sc5ccccc5c4c23)c2cccc3c2oc2ccccc23)cc1 ; c1ccc(-c2ccccc2-c2cc3ccc4sc5ccccc5c4c3c3ccc(N(c4ccccc4)c4ccc5oc6ccccc6c5c4)cc23)cc1 ; c1ccc(N(c2ccc3c(c2)c(-c2ccc4ccccc4c2)cc2ccc4sc5ccccc5c4c23)c2cccc3[nH]c4ccccc4c23)cc1]

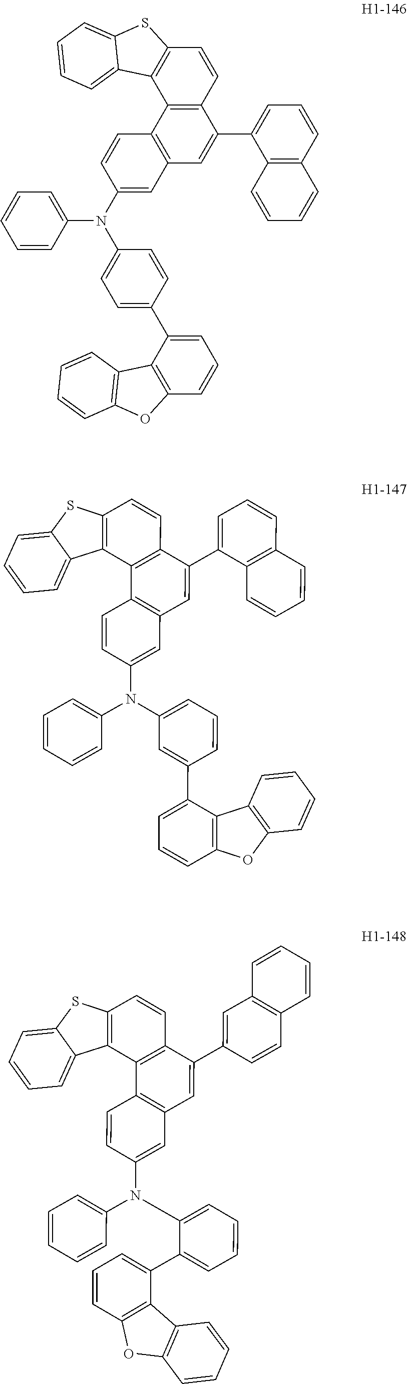 [SMILES: c1ccc(N(c2ccc(-c3cccc4oc5ccccc5c34)cc2)c2ccc3c(c2)cc(-c2cccc4ccccc24)c2ccc4sc5ccccc5c4c23)cc1 ; c1ccc(N(c2cccc(-c3cccc4oc5ccccc5c34)c2)c2ccc3c(c2)cc(-c2cccc4ccccc24)c2ccc4sc5ccccc5c4c23)cc1 ; c1ccc(N(c2ccc3c(c2)cc(-c2ccc4ccccc4c2)c2ccc4sc5ccccc5c4c23)c2ccccc2-c2cccc3oc4ccccc4c23)cc1]

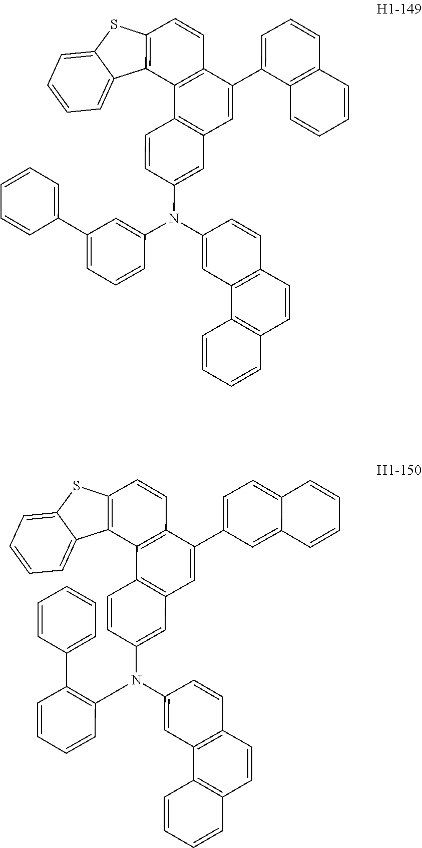 [SMILES: c1ccc(-c2cccc(N(c3ccc4c(c3)cc(-c3cccc5ccccc35)c3ccc5sc6ccccc6c5c34)c3ccc4ccc5ccccc5c4c3)c2)cc1 ; c1ccc(-c2ccccc2N(c2ccc3c(c2)cc(-c2ccc4ccccc4c2)c2ccc4sc5ccccc5c4c23)c2ccc3ccc4ccccc4c3c2)cc1]

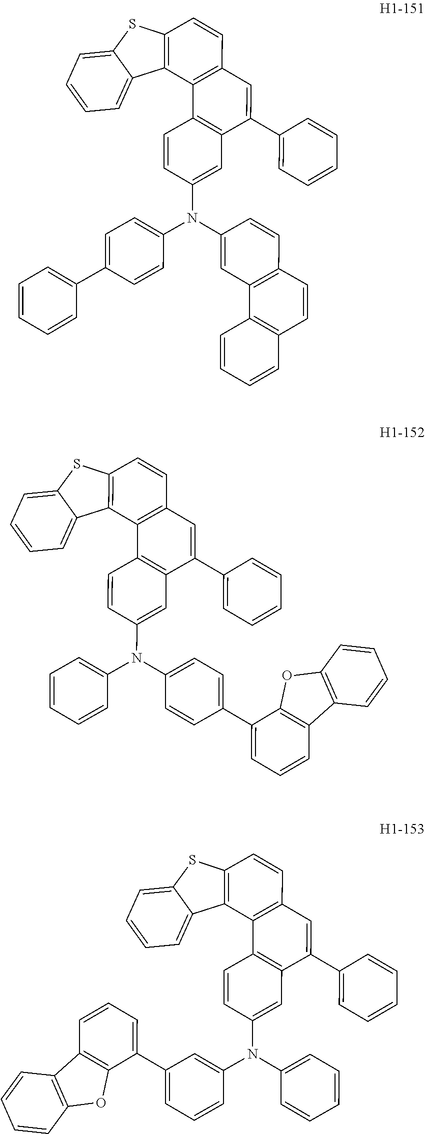 [SMILES: c1ccc(-c2ccc(N(c3ccc4c(c3)c(-c3ccccc3)cc3ccc5sc6ccccc6c5c34)c3ccc4ccc5ccccc5c4c3)cc2)cc1 ; c1ccc(-c2cc3ccc4sc5ccccc5c4c3c3ccc(N(c4ccccc4)c4ccc(-c5cccc6c5oc5ccccc56)cc4)cc23)cc1 ; c1ccc(-c2cc3ccc4sc5ccccc5c4c3c3ccc(N(c4ccccc4)c4cccc(-c5cccc6c5oc5ccccc56)c4)cc23)cc1]

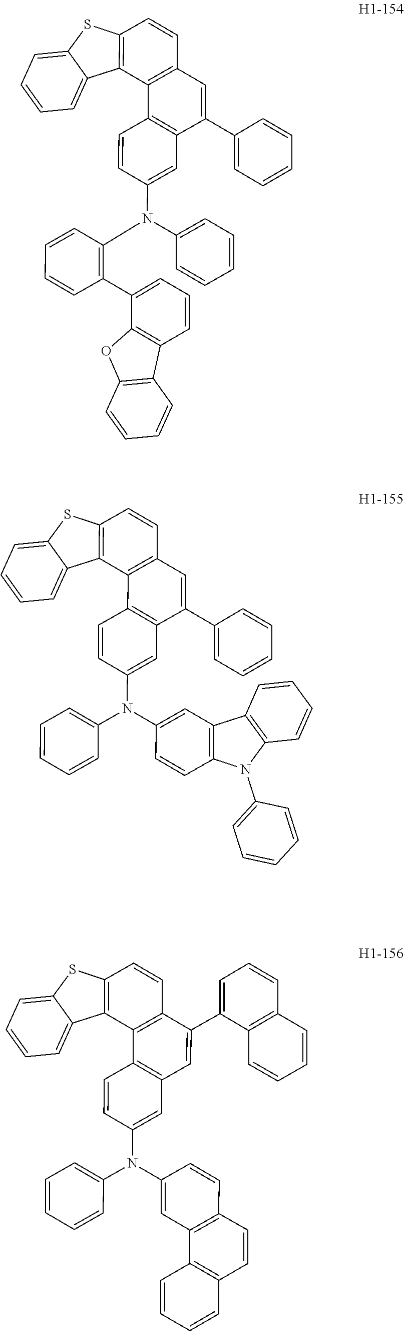 [SMILES: c1ccc(-c2cc3ccc4sc5ccccc5c4c3c3ccc(N(c4ccccc4)c4ccccc4-c4cccc5c4oc4ccccc45)cc23)cc1 ; c1ccc(-c2cc3ccc4sc5ccccc5c4c3c3ccc(N(c4ccccc4)c4ccc5c(c4)c4ccccc4n5-c4ccccc4)cc23)cc1 ; c1ccc(N(c2ccc3c(c2)cc(-c2cccc4ccccc24)c2ccc4sc5ccccc5c4c23)c2ccc3ccc4ccccc4c3c2)cc1]

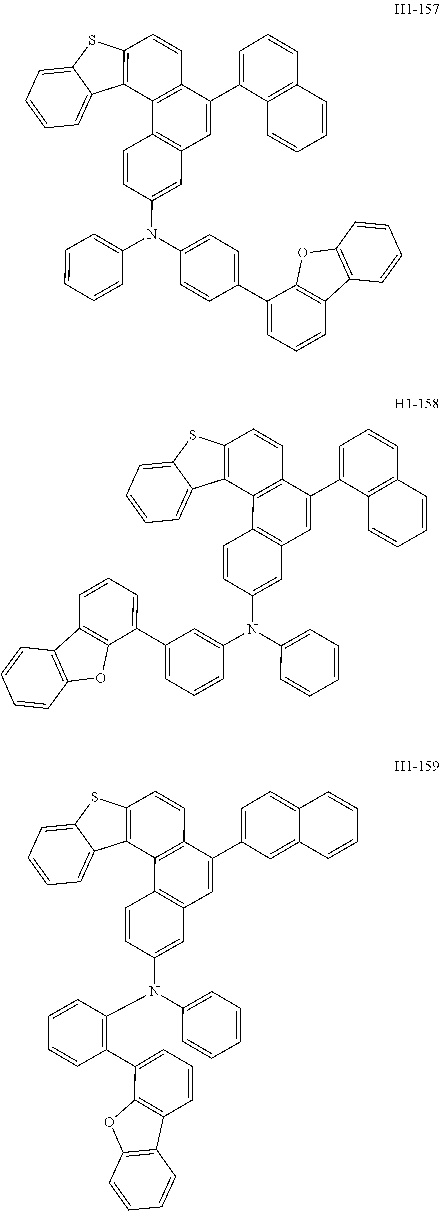 [SMILES: c1ccc(N(c2ccc(-c3cccc4c3oc3ccccc34)cc2)c2ccc3c(c2)cc(-c2cccc4ccccc24)c2ccc4sc5ccccc5c4c23)cc1 ; c1ccc(N(c2cccc(-c3cccc4c3oc3ccccc34)c2)c2ccc3c(c2)cc(-c2cccc4ccccc24)c2ccc4sc5ccccc5c4c23)cc1 ; c1ccc(N(c2ccc3c(c2)cc(-c2ccc4ccccc4c2)c2ccc4sc5ccccc5c4c23)c2ccccc2-c2cccc3c2oc2ccccc23)cc1]

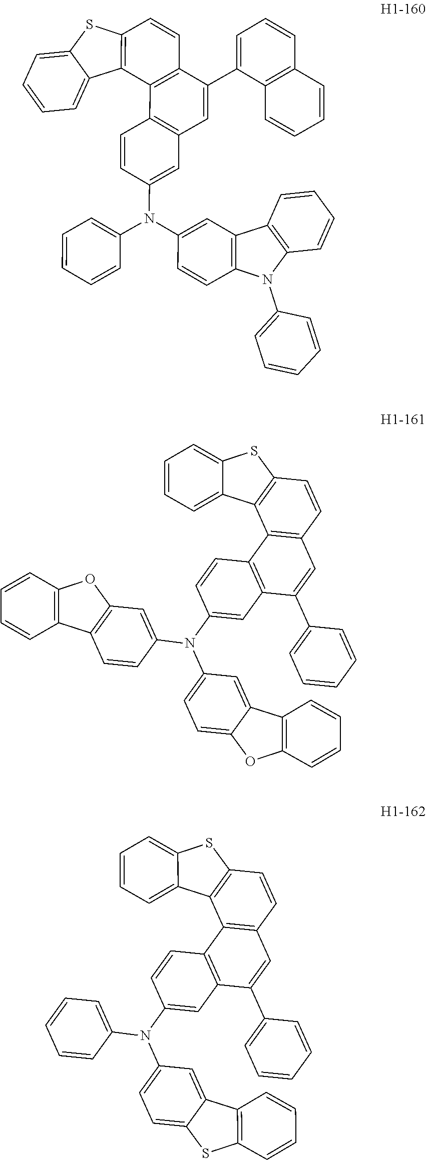 [SMILES: c1ccc(N(c2ccc3c(c2)cc(-c2cccc4ccccc24)c2ccc4sc5ccccc5c4c23)c2ccc3c(c2)c2ccccc2n3-c2ccccc2)cc1 ; c1ccc(-c2cc3ccc4sc5ccccc5c4c3c3ccc(N(c4ccc5c(c4)oc4ccccc45)c4ccc5oc6ccccc6c5c4)cc23)cc1 ; c1ccc(-c2cc3ccc4sc5ccccc5c4c3c3ccc(N(c4ccccc4)c4ccc5sc6ccccc6c5c4)cc23)cc1]

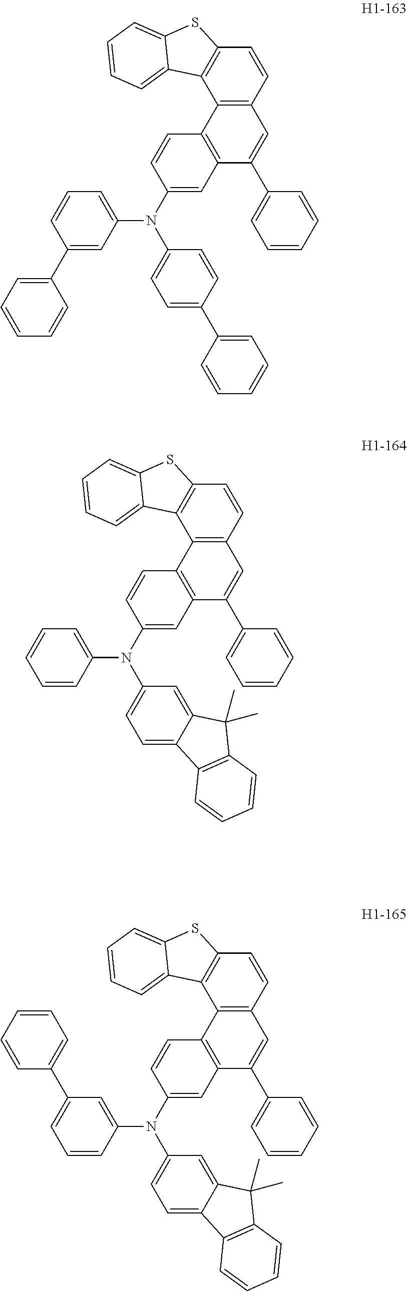 [SMILES: c1ccc(-c2ccc(N(c3cccc(-c4ccccc4)c3)c3ccc4c(c3)c(-c3ccccc3)cc3ccc5sc6ccccc6c5c34)cc2)cc1 ; CC1(C)c2ccccc2-c2ccc(N(c3ccccc3)c3ccc4c(c3)c(-c3ccccc3)cc3ccc5sc6ccccc6c5c34)cc21 ; CC1(C)c2ccccc2-c2ccc(N(c3cccc(-c4ccccc4)c3)c3ccc4c(c3)c(-c3ccccc3)cc3ccc5sc6ccccc6c5c34)cc21]

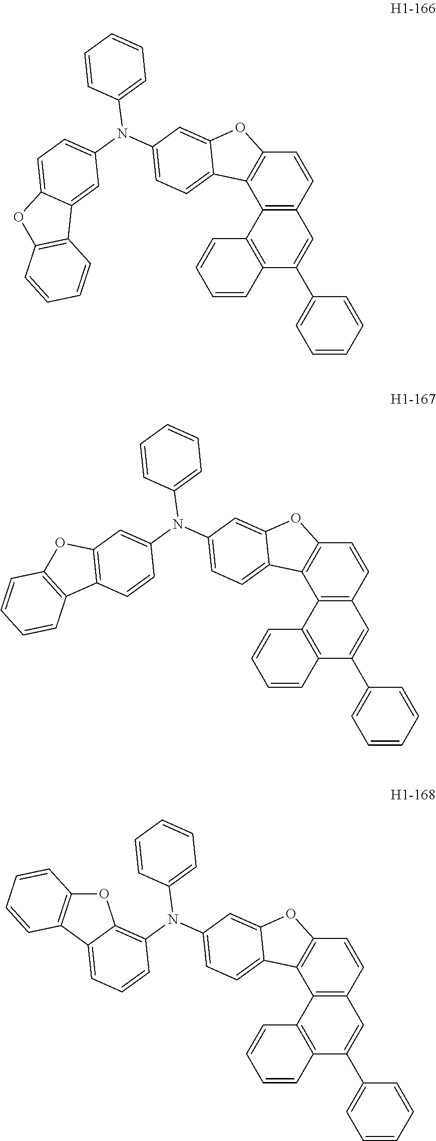 [SMILES: c1ccc(-c2cc3ccc4oc5cc(N(c6ccccc6)c6ccc7oc8ccccc8c7c6)ccc5c4c3c3ccccc23)cc1 ; c1ccc(-c2cc3ccc4oc5cc(N(c6ccccc6)c6ccc7c(c6)oc6ccccc67)ccc5c4c3c3ccccc23)cc1 ; c1ccc(-c2cc3ccc4oc5cc(N(c6ccccc6)c6cccc7c6oc6ccccc67)ccc5c4c3c3ccccc23)cc1]

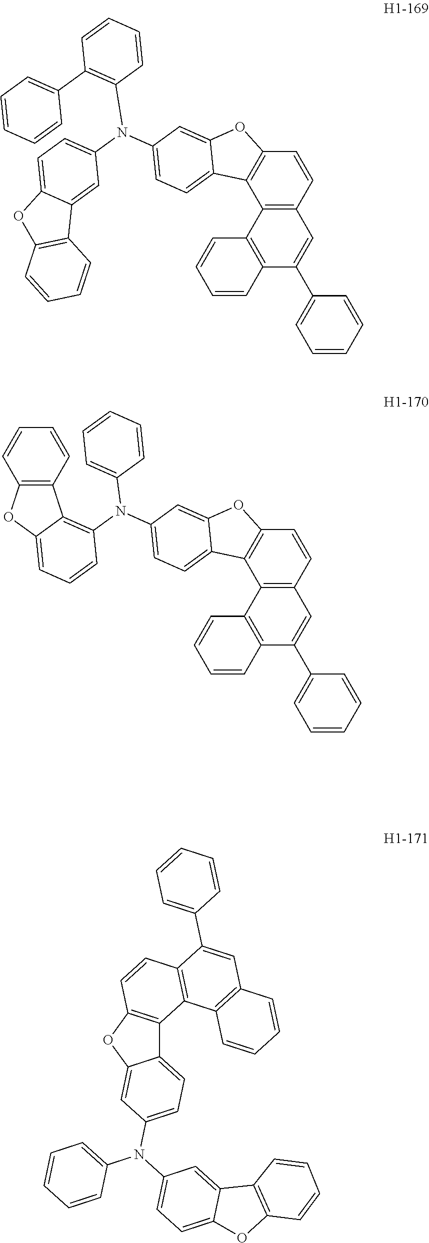 [SMILES: c1ccc(-c2ccccc2N(c2ccc3c(c2)oc2ccc4cc(-c5ccccc5)c5ccccc5c4c23)c2ccc3oc4ccccc4c3c2)cc1 ; c1ccc(-c2cc3ccc4oc5cc(N(c6ccccc6)c6cccc7oc8ccccc8c67)ccc5c4c3c3ccccc23)cc1 ; c1ccc(-c2cc3ccccc3c3c2ccc2oc4cc(N(c5ccccc5)c5ccc6oc7ccccc7c6c5)ccc4c23)cc1]

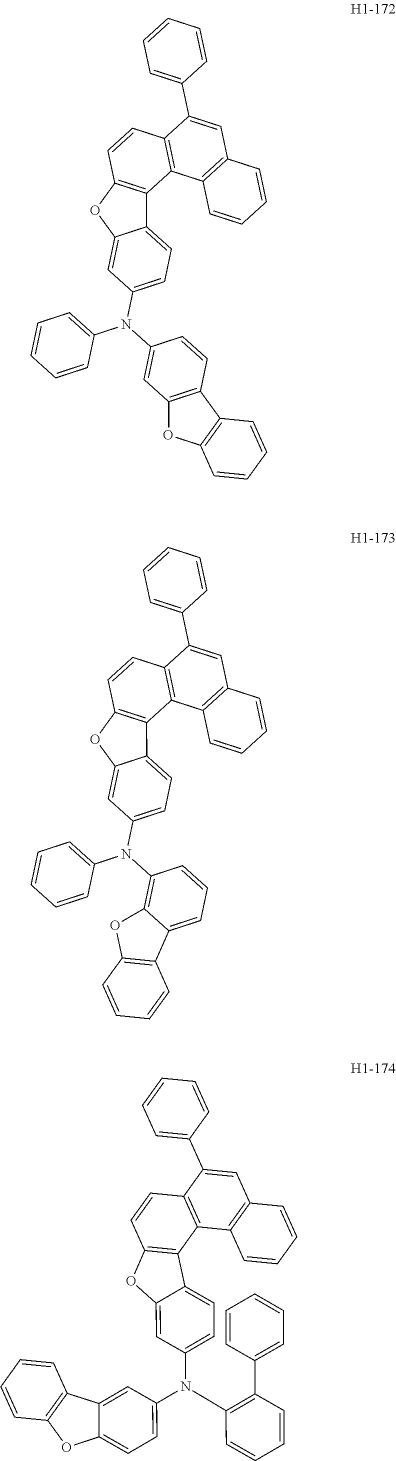 [SMILES: c1ccc(-c2cc3ccccc3c3c2ccc2oc4cc(N(c5ccccc5)c5ccc6c(c5)oc5ccccc56)ccc4c23)cc1 ; c1ccc(-c2cc3ccccc3c3c2ccc2oc4cc(N(c5ccccc5)c5cccc6c5oc5ccccc56)ccc4c23)cc1 ; c1ccc(-c2ccccc2N(c2ccc3c(c2)oc2ccc4c(-c5ccccc5)cc5ccccc5c4c23)c2ccc3oc4ccccc4c3c2)cc1]

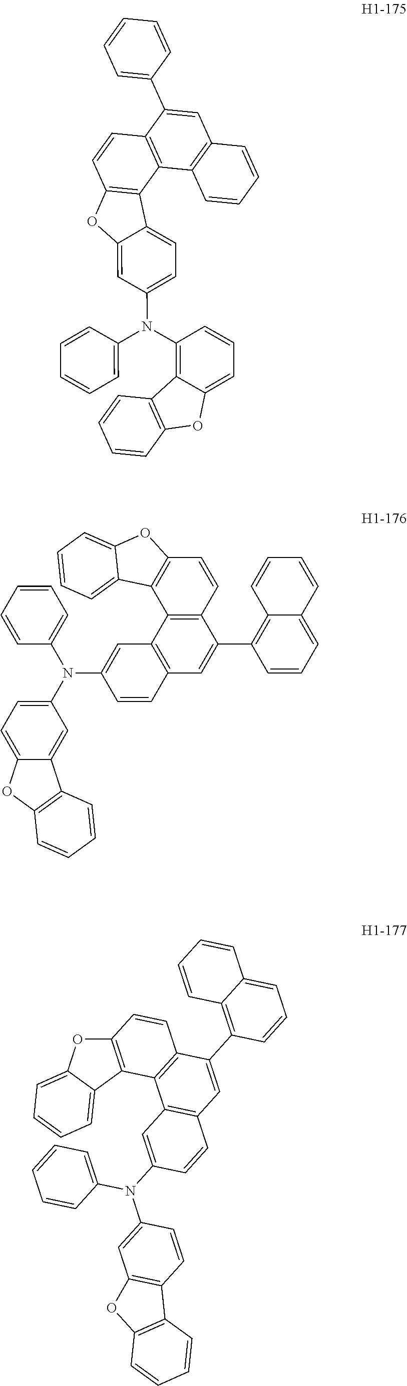 [SMILES: c1ccc(-c2cc3ccccc3c3c2ccc2oc4cc(N(c5ccccc5)c5cccc6oc7ccccc7c56)ccc4c23)cc1 ; c1ccc(N(c2ccc3oc4ccccc4c3c2)c2ccc3cc(-c4cccc5ccccc45)c4ccc5oc6ccccc6c5c4c3c2)cc1 ; c1ccc(N(c2ccc3c(c2)oc2ccccc23)c2ccc3cc(-c4cccc5ccccc45)c4ccc5oc6ccccc6c5c4c3c2)cc1]

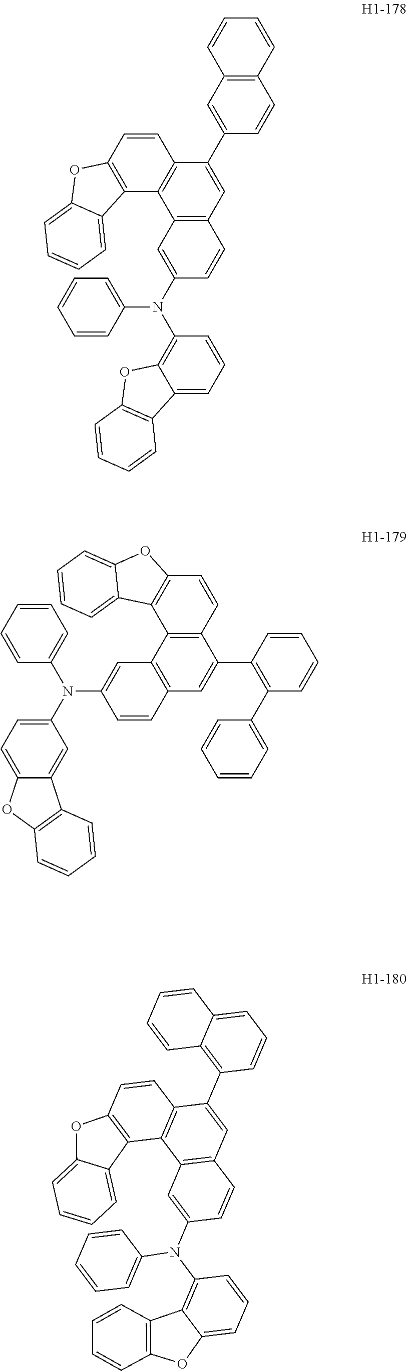 [SMILES: c1ccc(N(c2ccc3cc(-c4ccc5ccccc5c4)c4ccc5oc6ccccc6c5c4c3c2)c2cccc3c2oc2ccccc23)cc1 ; c1ccc(-c2ccccc2-c2cc3ccc(N(c4ccccc4)c4ccc5oc6ccccc6c5c4)cc3c3c2ccc2oc4ccccc4c23)cc1 ; c1ccc(N(c2ccc3cc(-c4cccc5ccccc45)c4ccc5oc6ccccc6c5c4c3c2)c2cccc3oc4ccccc4c23)cc1]

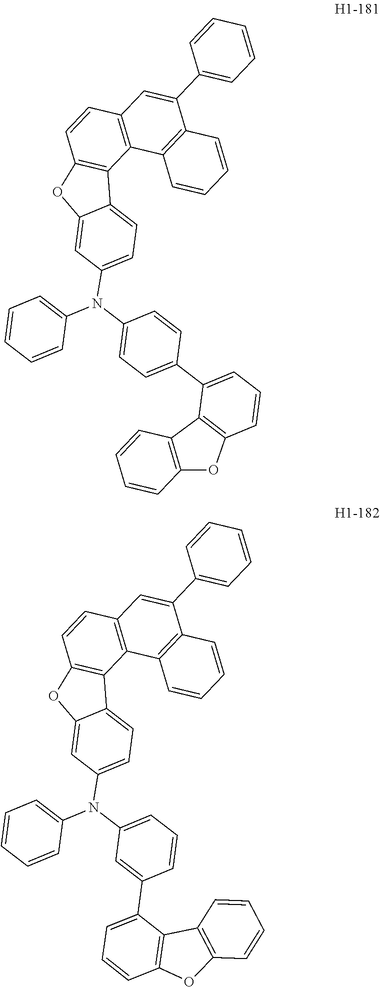 [SMILES: c1ccc(-c2cc3ccc4oc5cc(N(c6ccccc6)c6ccc(-c7cccc8oc9ccccc9c78)cc6)ccc5c4c3c3ccccc23)cc1 ; c1ccc(-c2cc3ccc4oc5cc(N(c6ccccc6)c6cccc(-c7cccc8oc9ccccc9c78)c6)ccc5c4c3c3ccccc23)cc1]

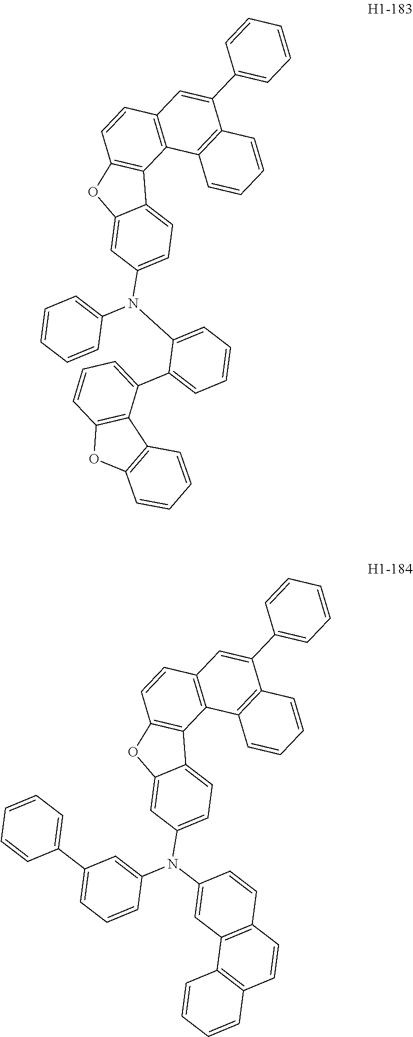 [SMILES: c1ccc(-c2cc3ccc4oc5cc(N(c6ccccc6)c6ccccc6-c6cccc7oc8ccccc8c67)ccc5c4c3c3ccccc23)cc1 ; c1ccc(-c2cccc(N(c3ccc4c(c3)oc3ccc5cc(-c6ccccc6)c6ccccc6c5c34)c3ccc4ccc5ccccc5c4c3)c2)cc1]

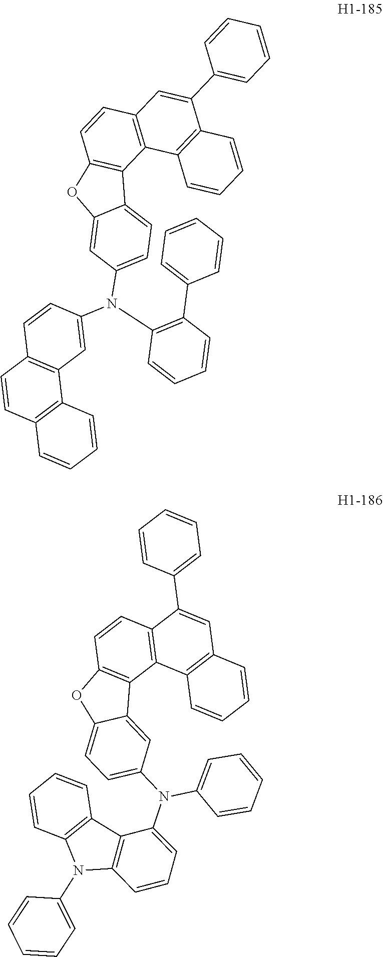 [SMILES: c1ccc(-c2ccccc2N(c2ccc3c(c2)oc2ccc4cc(-c5ccccc5)c5ccccc5c4c23)c2ccc3ccc4ccccc4c3c2)cc1 ; c1ccc(-c2cc3ccccc3c3c2ccc2oc4ccc(N(c5ccccc5)c5cccc6c5c5ccccc5n6-c5ccccc5)cc4c23)cc1]

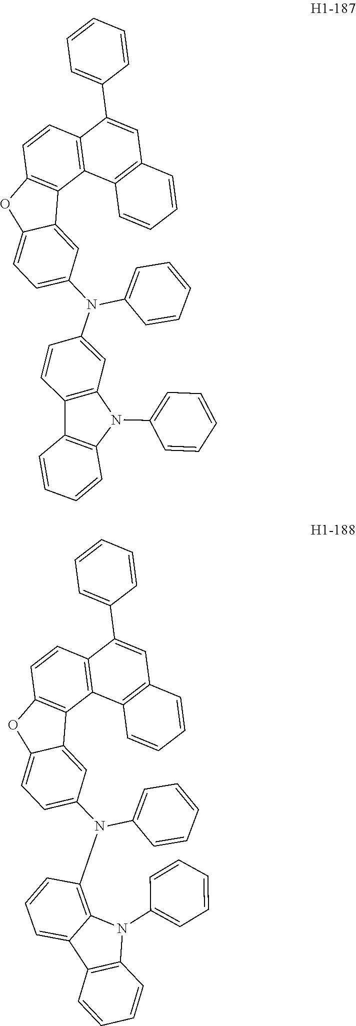

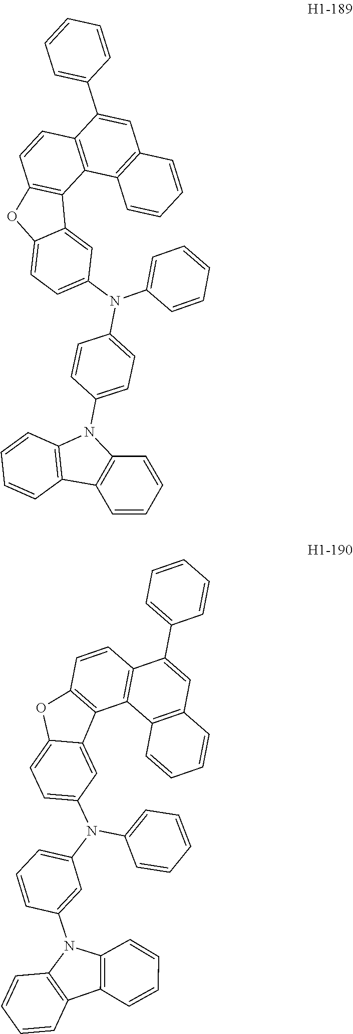 [SMILES: c1ccc(-c2cc3ccccc3c3c2ccc2oc4ccc(N(c5ccccc5)c5ccc(-n6c7ccccc7c7ccccc76)cc5)cc4c23)cc1 ; c1ccc(-c2cc3ccccc3c3c2ccc2oc4ccc(N(c5ccccc5)c5cccc(-n6c7ccccc7c7ccccc76)c5)cc4c23)cc1]

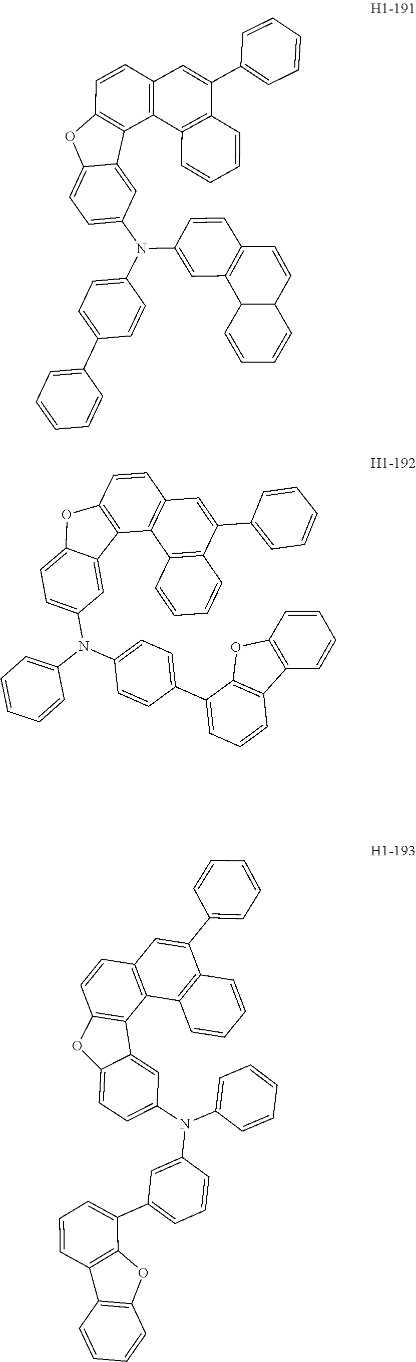 [SMILES: C1=CC2C=Cc3ccc(N(c4ccc(-c5ccccc5)cc4)c4ccc5oc6ccc7cc(-c8ccccc8)c8ccccc8c7c6c5c4)cc3C2C=C1 ; c1ccc(-c2cc3ccc4oc5ccc(N(c6ccccc6)c6ccc(-c7cccc8c7oc7ccccc78)cc6)cc5c4c3c3ccccc23)cc1 ; c1ccc(-c2cc3ccc4oc5ccc(N(c6ccccc6)c6cccc(-c7cccc8c7oc7ccccc78)c6)cc5c4c3c3ccccc23)cc1]

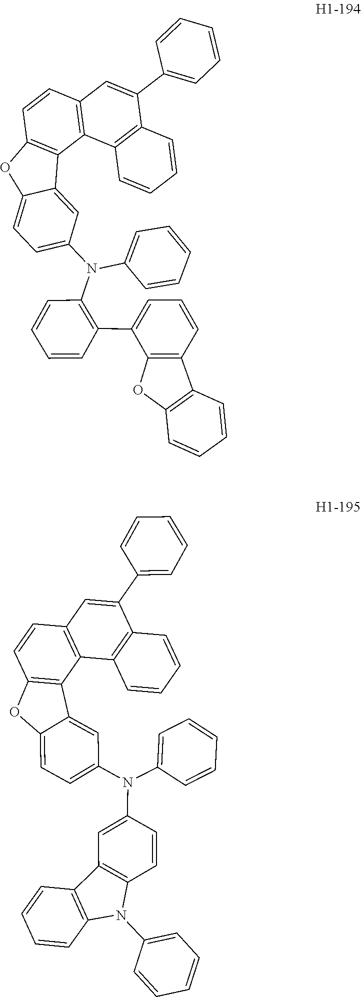 [SMILES: c1ccc(-c2cc3ccc4oc5ccc(N(c6ccccc6)c6ccccc6-c6cccc7c6oc6ccccc67)cc5c4c3c3ccccc23)cc1 ; c1ccc(-c2cc3ccc4oc5ccc(N(c6ccccc6)c6ccc7c(c6)c6ccccc6n7-c6ccccc6)cc5c4c3c3ccccc23)cc1]

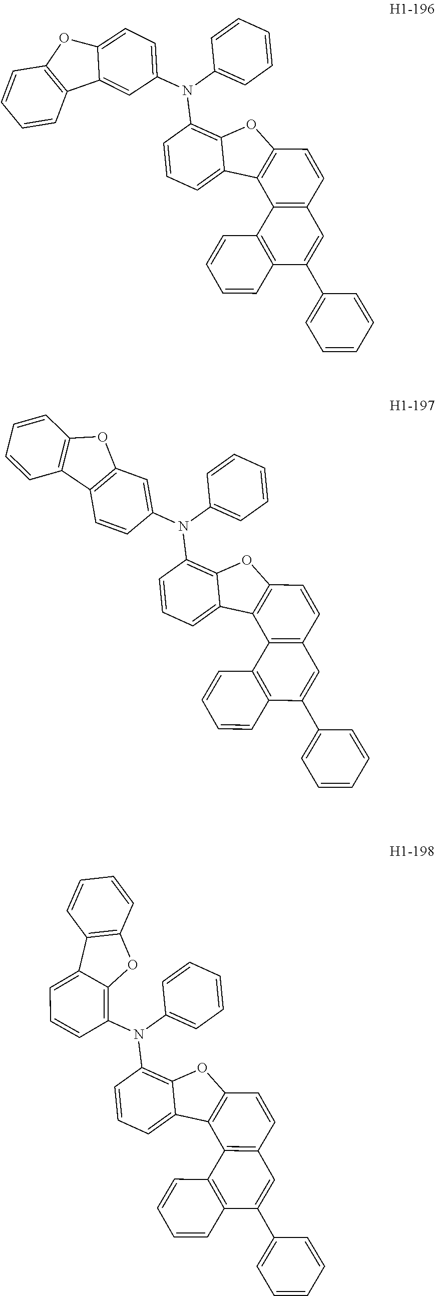 [SMILES: c1ccc(-c2cc3ccc4oc5c(N(c6ccccc6)c6ccc7oc8ccccc8c7c6)cccc5c4c3c3ccccc23)cc1 ; c1ccc(-c2cc3ccc4oc5c(N(c6ccccc6)c6ccc7c(c6)oc6ccccc67)cccc5c4c3c3ccccc23)cc1 ; c1ccc(-c2cc3ccc4oc5c(N(c6ccccc6)c6cccc7c6oc6ccccc67)cccc5c4c3c3ccccc23)cc1]

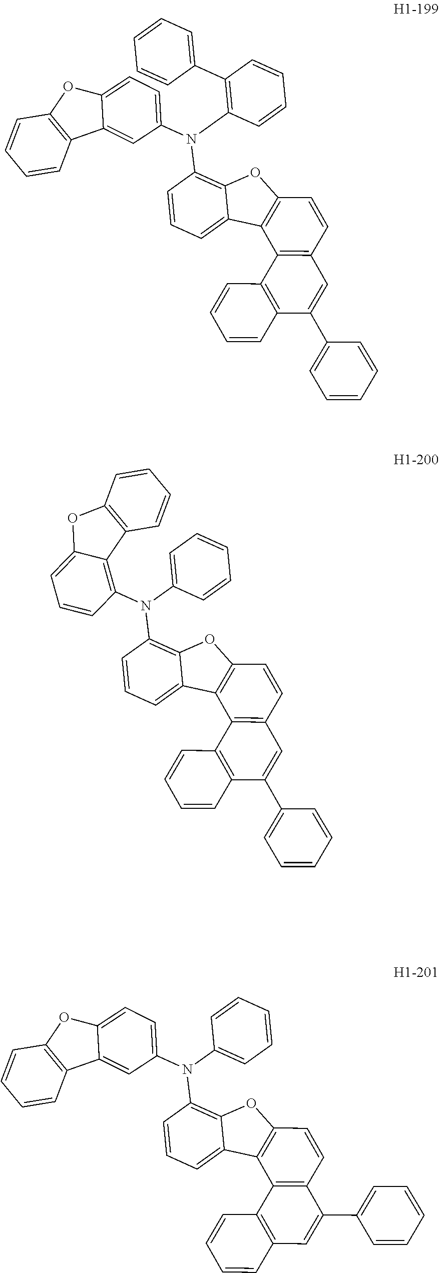 [SMILES: c1ccc(-c2ccccc2N(c2ccc3oc4ccccc4c3c2)c2cccc3c2oc2ccc4cc(-c5ccccc5)c5ccccc5c4c23)cc1 ; c1ccc(-c2cc3ccc4oc5c(N(c6ccccc6)c6cccc7oc8ccccc8c67)cccc5c4c3c3ccccc23)cc1 ; c1ccc(-c2cc3ccccc3c3c2ccc2oc4c(N(c5ccccc5)c5ccc6oc7ccccc7c6c5)cccc4c23)cc1]

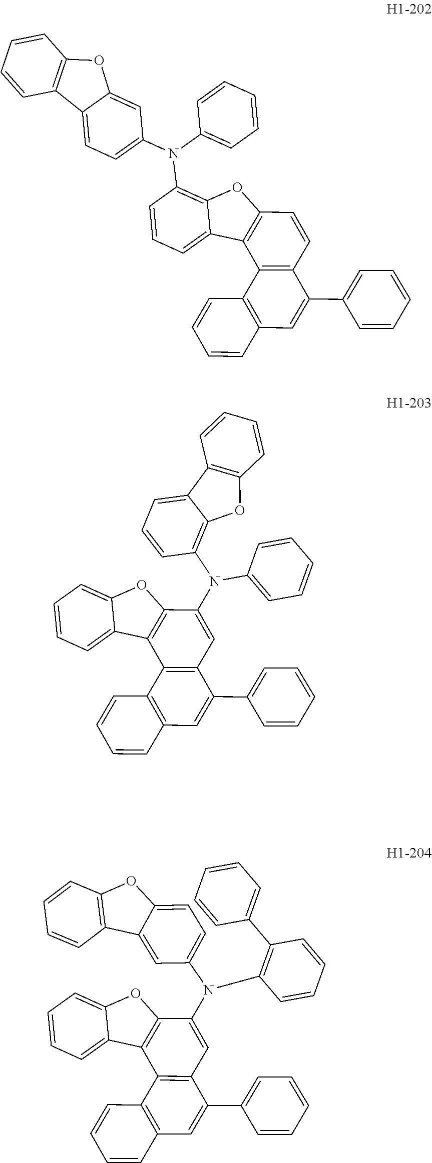 [SMILES: c1ccc(-c2cc3ccccc3c3c2ccc2oc4c(N(c5ccccc5)c5ccc6c(c5)oc5ccccc56)cccc4c23)cc1 ; c1ccc(-c2cc3ccccc3c3c2cc(N(c2ccccc2)c2cccc4c2oc2ccccc24)c2oc4ccccc4c23)cc1 ; c1ccc(-c2ccccc2N(c2ccc3oc4ccccc4c3c2)c2cc3c(-c4ccccc4)cc4ccccc4c3c3c2oc2ccccc23)cc1]

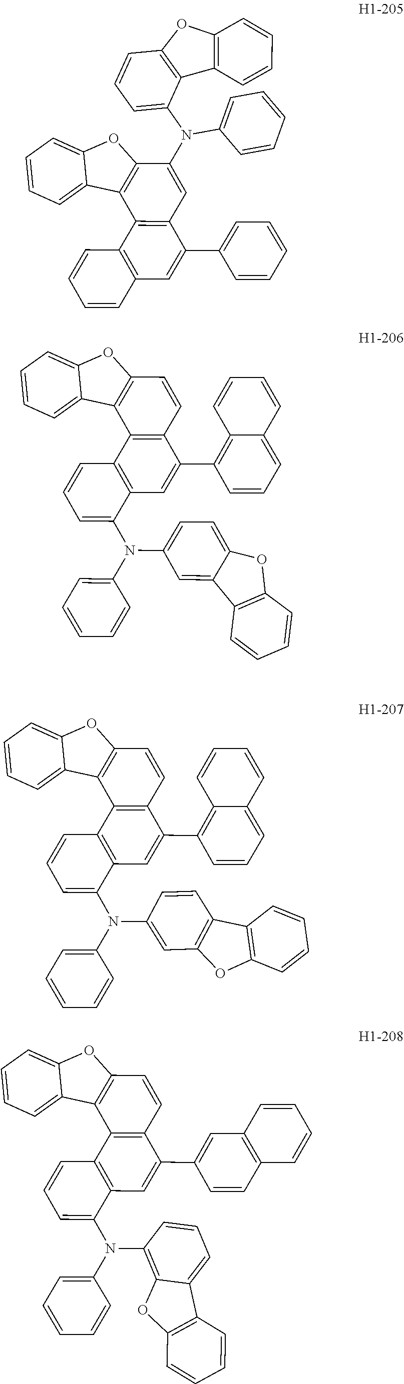

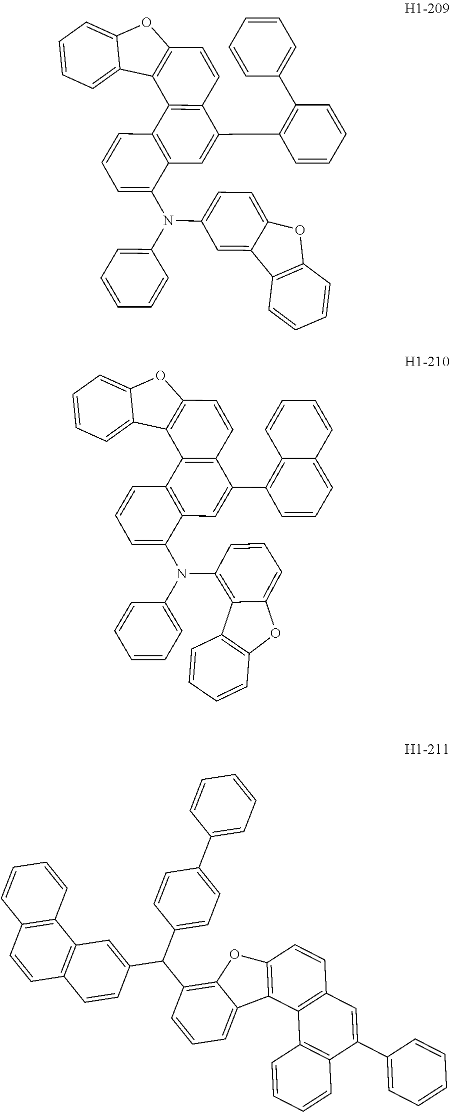 [SMILES: c1ccc(-c2ccccc2-c2cc3c(N(c4ccccc4)c4ccc5oc6ccccc6c5c4)cccc3c3c2ccc2oc4ccccc4c23)cc1 ; c1ccc(N(c2cccc3c2cc(-c2cccc4ccccc24)c2ccc4oc5ccccc5c4c23)c2cccc3oc4ccccc4c23)cc1 ; c1ccc(-c2ccc(C(c3ccc4ccc5ccccc5c4c3)c3cccc4c3oc3ccc5cc(-c6ccccc6)c6ccccc6c5c34)cc2)cc1]

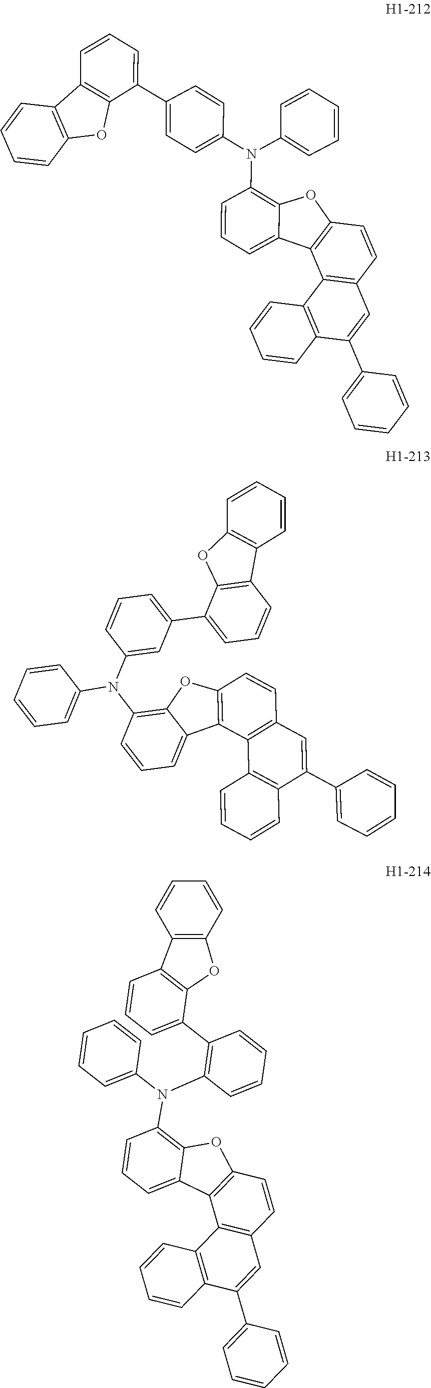 [SMILES: c1ccc(-c2cc3ccc4oc5c(N(c6ccccc6)c6ccc(-c7cccc8c7oc7ccccc78)cc6)cccc5c4c3c3ccccc23)cc1 ; c1ccc(-c2cc3ccc4oc5c(N(c6ccccc6)c6cccc(-c7cccc8c7oc7ccccc78)c6)cccc5c4c3c3ccccc23)cc1 ; c1ccc(-c2cc3ccc4oc5c(N(c6ccccc6)c6ccccc6-c6cccc7c6oc6ccccc67)cccc5c4c3c3ccccc23)cc1]

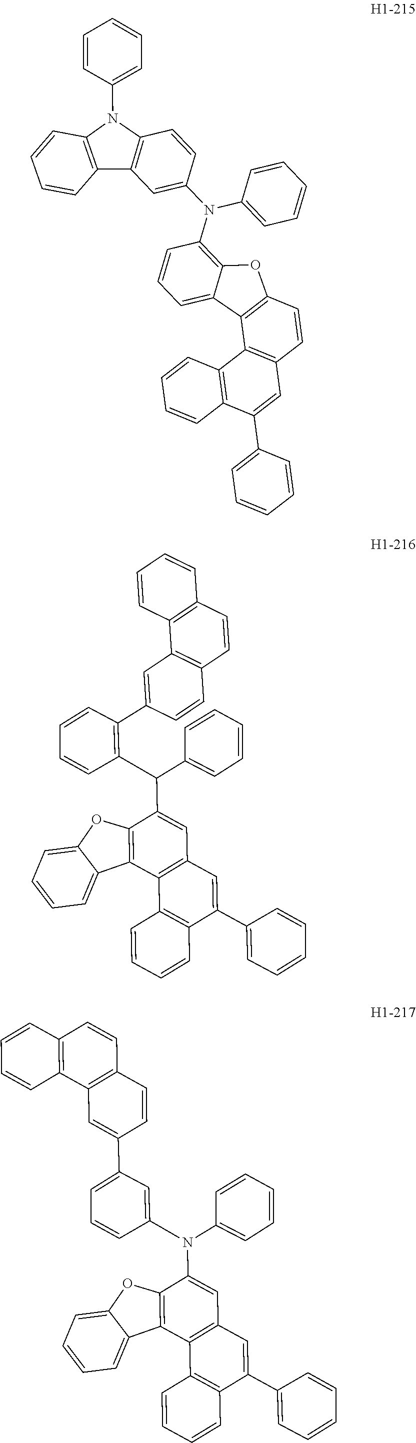 [SMILES: c1ccc(-c2cc3ccc4oc5c(N(c6ccccc6)c6ccc7c(c6)c6ccccc6n7-c6ccccc6)cccc5c4c3c3ccccc23)cc1 ; c1ccc(-c2cc3cc(C(c4ccccc4)c4ccccc4-c4ccc5ccc6ccccc6c5c4)c4oc5ccccc5c4c3c3ccccc23)cc1 ; c1ccc(-c2cc3cc(N(c4ccccc4)c4cccc(-c5ccc6ccc7ccccc7c6c5)c4)c4oc5ccccc5c4c3c3ccccc23)cc1]

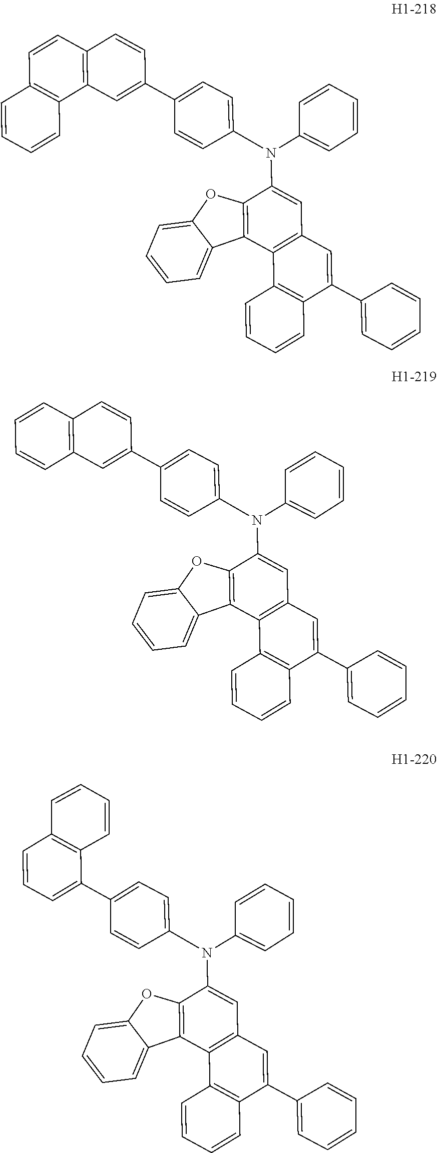 [SMILES: c1ccc(-c2cc3cc(N(c4ccccc4)c4ccc(-c5ccc6ccc7ccccc7c6c5)cc4)c4oc5ccccc5c4c3c3ccccc23)cc1 ; c1ccc(-c2cc3cc(N(c4ccccc4)c4ccc(-c5ccc6ccccc6c5)cc4)c4oc5ccccc5c4c3c3ccccc23)cc1 ; c1ccc(-c2cc3cc(N(c4ccccc4)c4ccc(-c5cccc6ccccc56)cc4)c4oc5ccccc5c4c3c3ccccc23)cc1]

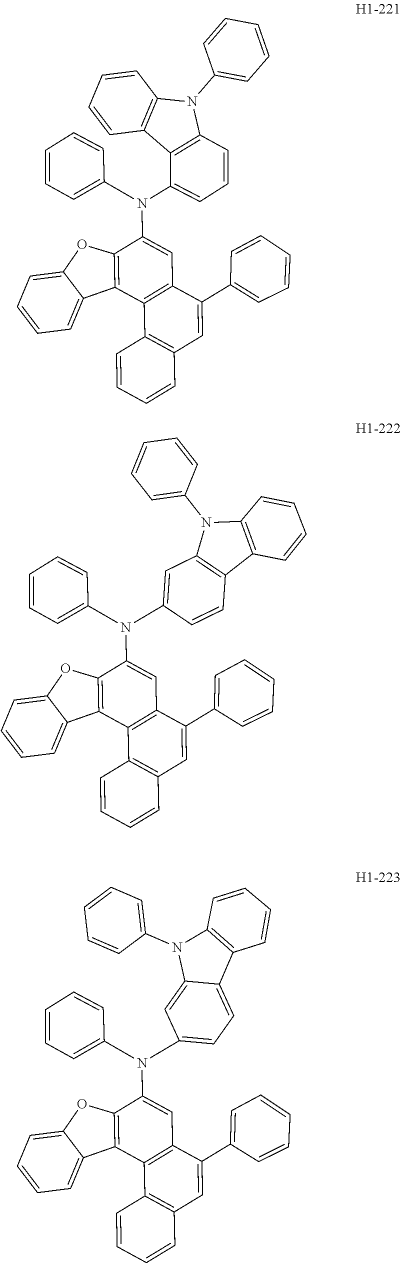

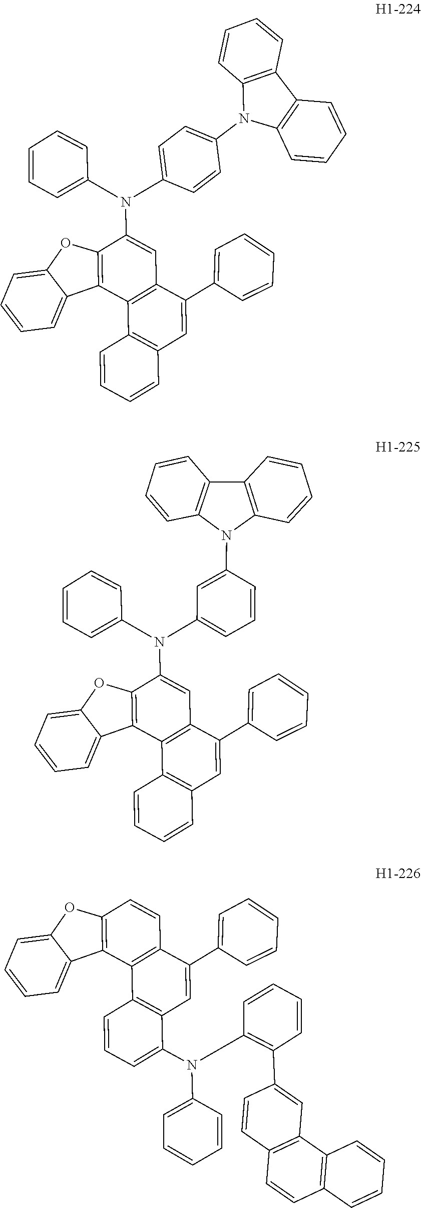 [SMILES: c1ccc(-c2cc3ccccc3c3c2cc(N(c2ccccc2)c2ccc(-n4c5ccccc5c5ccccc54)cc2)c2oc4ccccc4c23)cc1 ; c1ccc(-c2cc3ccccc3c3c2cc(N(c2ccccc2)c2cccc(-n4c5ccccc5c5ccccc54)c2)c2oc4ccccc4c23)cc1 ; c1ccc(-c2cc3c(N(c4ccccc4)c4ccccc4-c4ccc5ccc6ccccc6c5c4)cccc3c3c2ccc2oc4ccccc4c23)cc1]

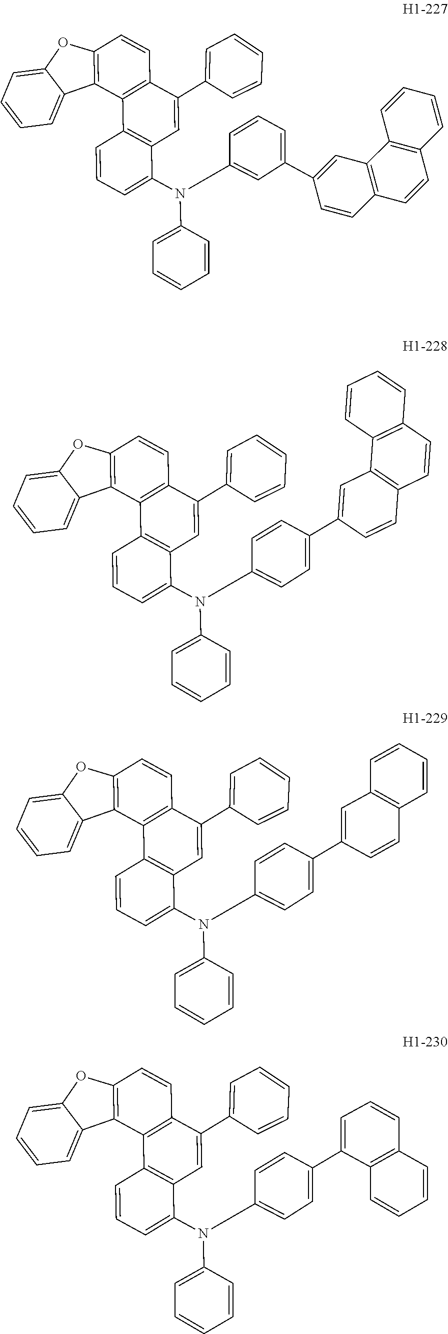 [SMILES: c1ccc(-c2cc3c(N(c4ccccc4)c4cccc(-c5ccc6ccc7ccccc7c6c5)c4)cccc3c3c2ccc2oc4ccccc4c23)cc1 ; c1ccc(-c2cc3c(N(c4ccccc4)c4ccc(-c5ccc6ccc7ccccc7c6c5)cc4)cccc3c3c2ccc2oc4ccccc4c23)cc1 ; c1ccc(-c2cc3c(N(c4ccccc4)c4ccc(-c5ccc6ccccc6c5)cc4)cccc3c3c2ccc2oc4ccccc4c23)cc1 ; c1ccc(-c2cc3c(N(c4ccccc4)c4ccc(-c5cccc6ccccc56)cc4)cccc3c3c2ccc2oc4ccccc4c23)cc1]

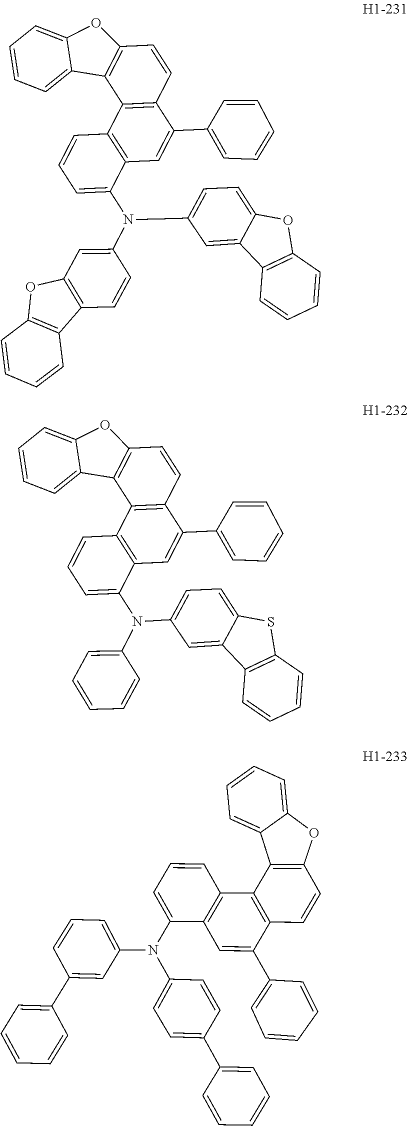

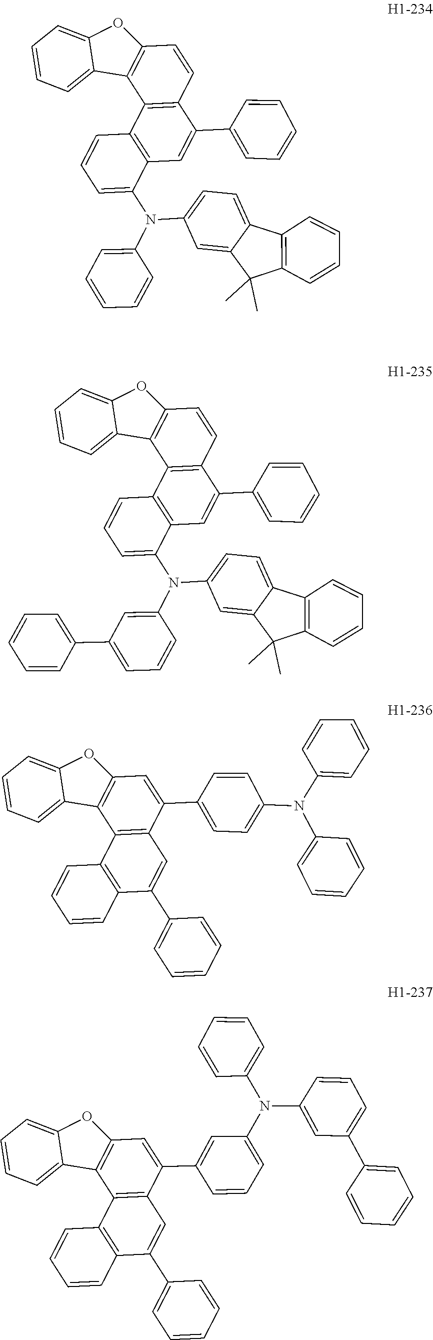

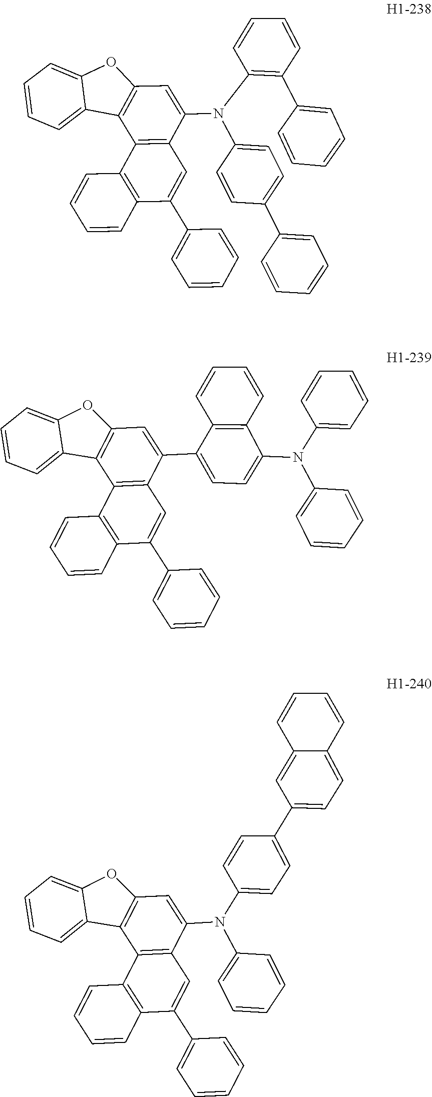 [SMILES: c1ccc(-c2ccc(N(c3ccccc3-c3ccccc3)c3cc4oc5ccccc5c4c4c3cc(-c3ccccc3)c3ccccc34)cc2)cc1 ; c1ccc(-c2cc3c(-c4ccc(N(c5ccccc5)c5ccccc5)c5ccccc45)cc4oc5ccccc5c4c3c3ccccc23)cc1 ; c1ccc(-c2cc3c(N(c4ccccc4)c4ccc(-c5ccc6ccccc6c5)cc4)cc4oc5ccccc5c4c3c3ccccc23)cc1]

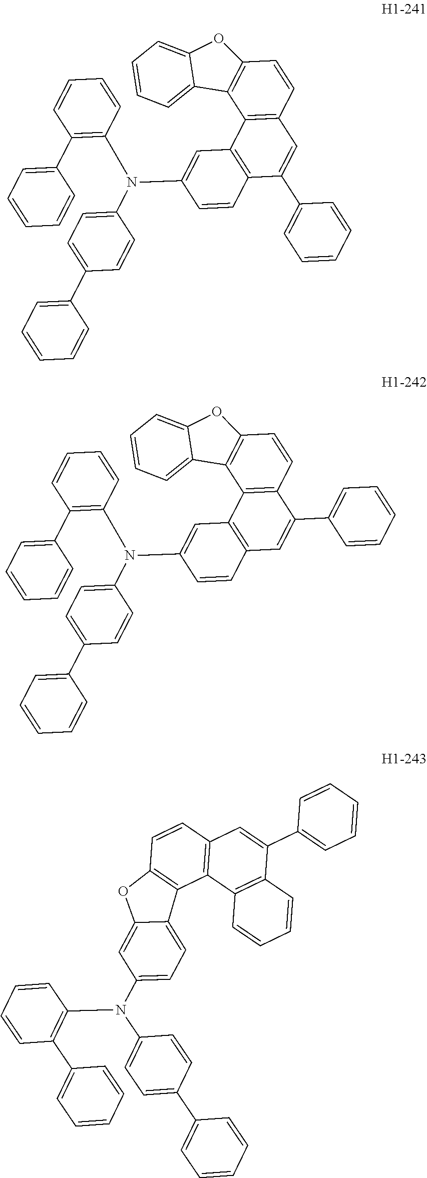 [SMILES: c1ccc(-c2ccc(N(c3ccc4c(-c5ccccc5)cc5ccc6oc7ccccc7c6c5c4c3)c3ccccc3-c3ccccc3)cc2)cc1 ; c1ccc(-c2ccc(N(c3ccc4cc(-c5ccccc5)c5ccc6oc7ccccc7c6c5c4c3)c3ccccc3-c3ccccc3)cc2)cc1 ; c1ccc(-c2ccc(N(c3ccc4c(c3)oc3ccc5cc(-c6ccccc6)c6ccccc6c5c34)c3ccccc3-c3ccccc3)cc2)cc1]

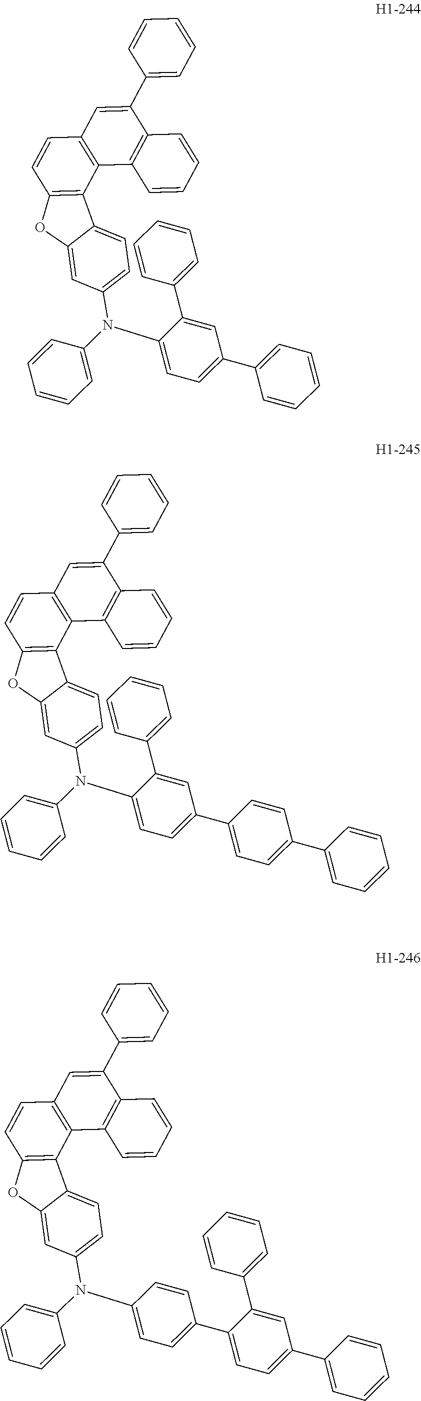 [SMILES: c1ccc(-c2ccc(N(c3ccccc3)c3ccc4c(c3)oc3ccc5cc(-c6ccccc6)c6ccccc6c5c34)c(-c3ccccc3)c2)cc1 ; c1ccc(-c2ccc(-c3ccc(N(c4ccccc4)c4ccc5c(c4)oc4ccc6cc(-c7ccccc7)c7ccccc7c6c45)c(-c4ccccc4)c3)cc2)cc1 ; c1ccc(-c2ccc(-c3ccc(N(c4ccccc4)c4ccc5c(c4)oc4ccc6cc(-c7ccccc7)c7ccccc7c6c45)cc3)c(-c3ccccc3)c2)cc1]

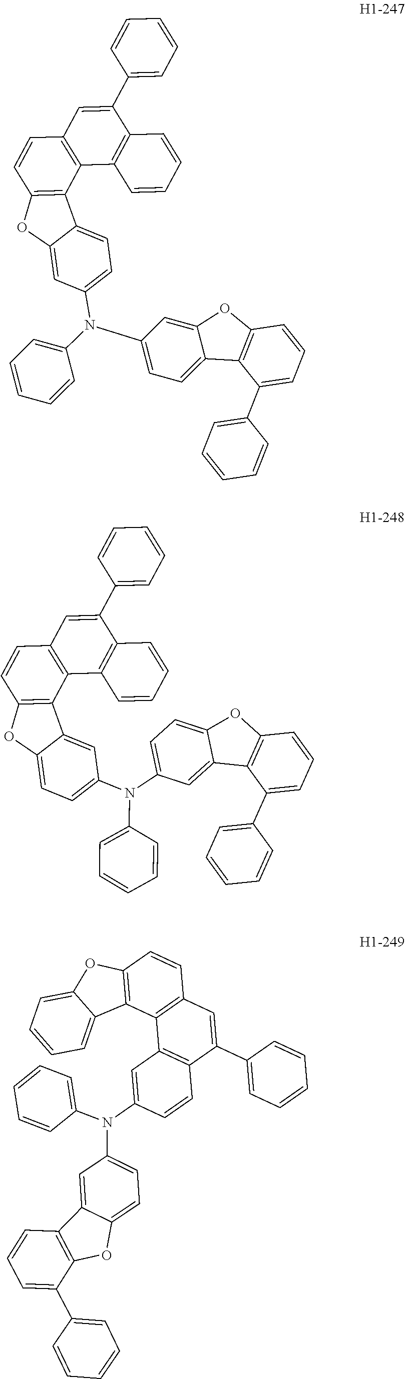 [SMILES: c1ccc(-c2cc3ccc4oc5cc(N(c6ccccc6)c6ccc7c(c6)oc6cccc(-c8ccccc8)c67)ccc5c4c3c3ccccc23)cc1 ; c1ccc(-c2cc3ccc4oc5ccc(N(c6ccccc6)c6ccc7oc8cccc(-c9ccccc9)c8c7c6)cc5c4c3c3ccccc23)cc1 ; c1ccc(-c2cc3ccc4oc5ccccc5c4c3c3cc(N(c4ccccc4)c4ccc5oc6c(-c7ccccc7)cccc6c5c4)ccc23)cc1]

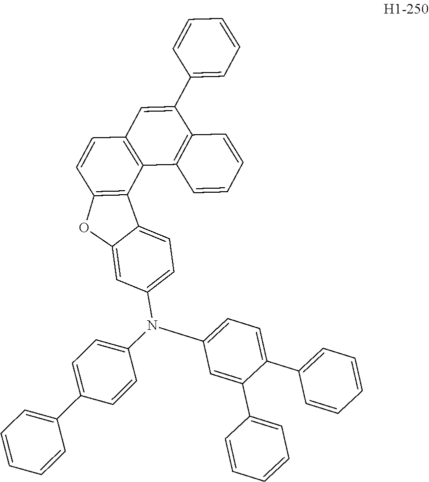 [SMILES: c1ccc(-c2ccc(N(c3ccc(-c4ccccc4)c(-c4ccccc4)c3)c3ccc4c(c3)oc3ccc5cc(-c6ccccc6)c6ccccc6c5c34)cc2)cc1]

The compound represented by Formula 2 is described in more detail as follows.

In Formula 2, X₂ represents O, S, or Se. For example, X₂ may be O or S.

In Formula 2, L₄ and L₅ each independently represent a single bond, a substituted or unsubstituted (C₆-C₃₀)arylene, or a substituted or unsubstituted (3- to 30-membered)heteroarylene. According to one embodiment of the present disclosure, L₄ and L₅ each independently represent a single bond or a substituted or unsubstituted (C₆-C₃₀)arylene. According to another embodiment of the present disclosure, L₄ and L₅ each independently represent a single bond or a substituted or unsubstituted (C₆-C₁₈)arylene. For example, L₄ and L₅ each independently may be a single bond, a phenylene unsubstituted or substituted with naphthyl(s), a naphthylene unsubstituted or substituted with a phenyl(s), a biphenylene, a terphenylene, or a phenanthrenylene, etc.

In Formula 2, Ar₃ and Ar₄ each independently represent a substituted or unsubstituted (C₆-C₃₀)aryl or a substituted or unsubstituted (3- to 30-membered)heteroaryl. According to one embodiment of the present disclosure, Ar₃ and Ar₄ each independently represent a substituted or unsubstituted (C₆-C₂₄)aryl or a substituted or unsubstituted (3- to 20-membered)heteroaryl. For example, Ar₃ and Ar₄ each independently may be a phenyl unsubstituted or substituted with a naphthyl(s) unsubstituted or substituted with phenyl or a phenanthrenyl(s); a biphenyl unsubstituted or substituted with a naphthyl(s); a terphenyl; a quaterphenyl; a naphthyl unsubstituted or substituted with a phenyl(s), a biphenyl(s), or a naphthyl(s); a phenanthrenyl unsubstituted or substituted with a phenyl(s) or a naphthyl(s); a chrysenyl; a fluoranthenyl; a triphenylenyl; a dibenzothiophenyl; a dibenzofuranyl unsubstituted or substituted with a phenyl(s), a biphenyl(s), or a naphthyl(s); or a benzonaphthofuranyl, etc.

In Formula 2, R₁₅ and R₁₆ each independently represent hydrogen, deuterium, a halogen, a cyano, a substituted or unsubstituted (C₁-C₃₀)alkyl, a substituted or unsubstituted (C₂-C₃₀)alkenyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₃-C₃₀)cycloalkenyl, a substituted or unsubstituted (3- to 7-membered)heterocycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted fused ring of (C₃-C₃₀) aliphatic ring(s) and (C₆-C₃₀) aromatic ring(s), a substituted or unsubstituted mono- or di(C₁-C₃₀)alkylamino, a substituted or unsubstituted mono- or di(C₆-C₃₀)arylamino, a substituted or unsubstituted (C₁-C₃₀)alkyl(C₆-C₃₀)arylamino, a substituted or unsubstituted mono- or di-(3- to 30-membered)heteroarylamino, or a substituted or unsubstituted (C₆-C₃₀)aryl(3- to 30-membered)heteroarylamino; or may be linked to the adjacent substituent(s) to form a ring(s). According to one embodiment of the present disclosure, R₁₅ and R₁₆ each independently represent hydrogen, deuterium, a substituted or unsubstituted (C₆-C₃₀)aryl, or a substituted or unsubstituted (3- to 30-membered)heteroaryl, or may be linked to the adjacent substituent(s) to form a ring(s). According to another embodiment of the present disclosure, R₁₅ and R₁₆ each independently represent hydrogen, deuterium, or a substituted or unsubstituted (C₆-C₁₄)aryl, or may be linked to the adjacent substituent(s) to form a ring(s). For example, R₁₅ and R₁₆ each independently may be hydrogen; a phenyl unsubstituted or substituted with a naphthyl(s) or deuterium; a biphenyl; a naphthyl unsubstituted or substituted with a phenyl(s); or a phenanthrenyl, or may be linked to adjacent substituents to form a benzene ring.

In Formula 2, a represents an integer of 1 to 4, b represents an integer of 1 to 3, and when each a and b are an integer of 2 or more, each of R₁₅ and each of R₁₆ may be the same or different.

With a proviso that when both R₁₅ and R₁₆ of Formula 2 are hydrogen or deuterium, at least one of R₁ to R₁₂ of Formula 1 represents Formula 1-a and at least one of the others represents a substituted or unsubstituted (C₆-C₃₀)aryl or a substituted or unsubstituted (3- to 30-membered)heteroaryl.

According to one embodiment of the present disclosure, the compound represented by Formula 2 may be represented by any one of the following Formulas 2-1 to 2-4.

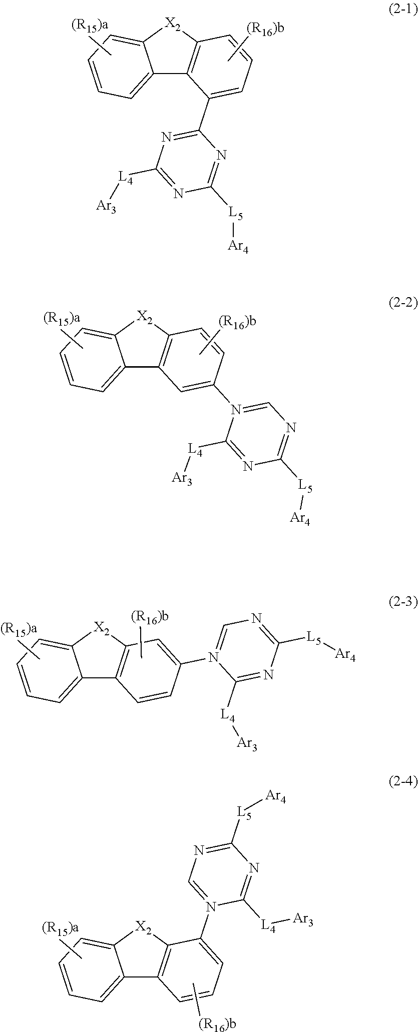

According to one embodiment of the present disclosure, the compound represented by Formula 2 may be at least one selected from the following compounds, but is not limited thereto.

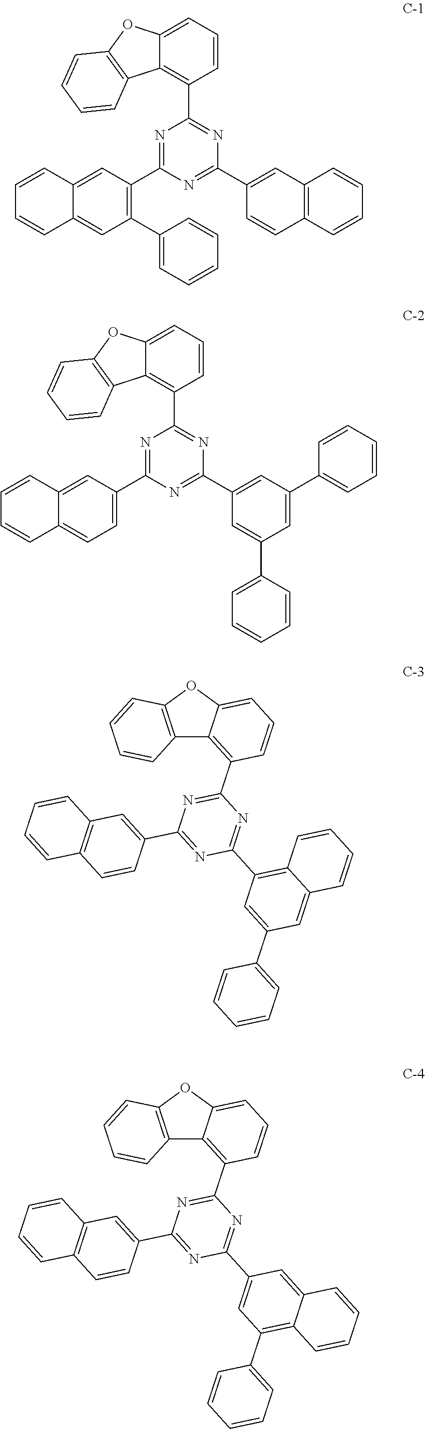

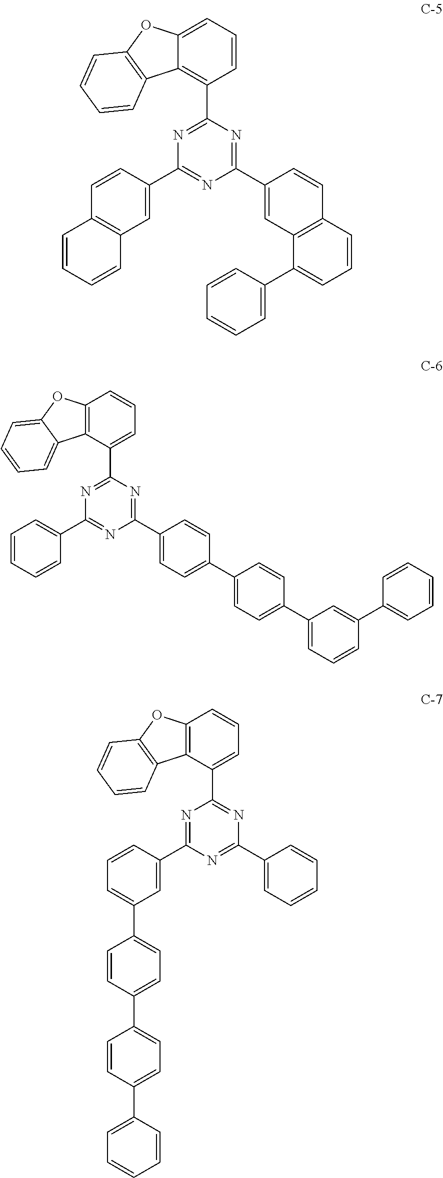 [SMILES: c1ccc(-c2cccc3ccc(-c4nc(-c5ccc6ccccc6c5)nc(-c5cccc6oc7ccccc7c56)n4)cc23)cc1 ; c1ccc(-c2cccc(-c3ccc(-c4ccc(-c5nc(-c6ccccc6)nc(-c6cccc7oc8ccccc8c67)n5)cc4)cc3)c2)cc1 ; c1ccc(-c2ccc(-c3ccc(-c4cccc(-c5nc(-c6ccccc6)nc(-c6cccc7oc8ccccc8c67)n5)c4)cc3)cc2)cc1]

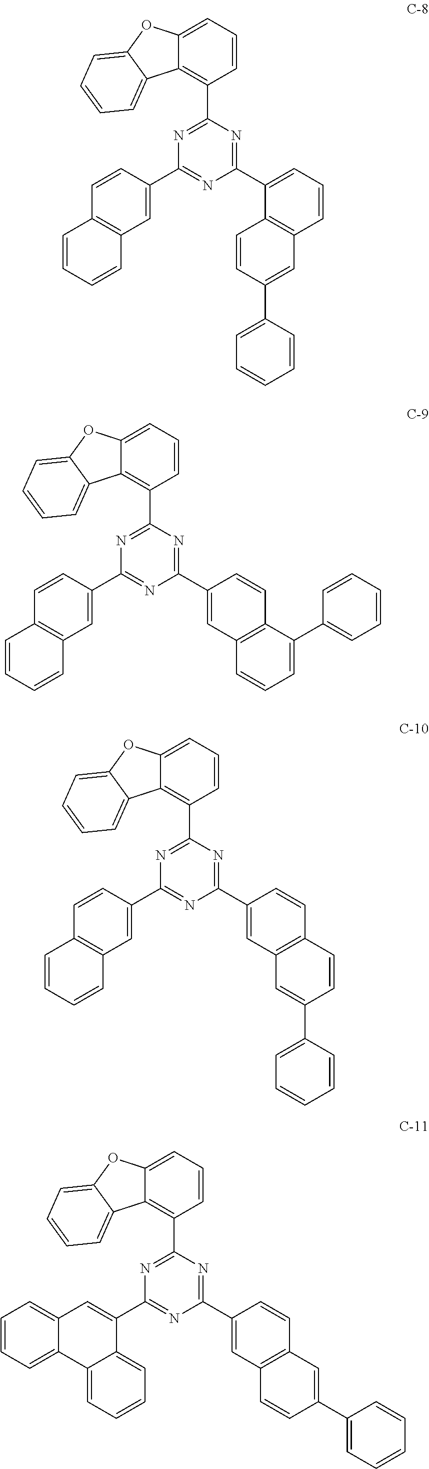 [SMILES: c1ccc(-c2ccc3c(-c4nc(-c5ccc6ccccc6c5)nc(-c5cccc6oc7ccccc7c56)n4)cccc3c2)cc1 ; c1ccc(-c2cccc3cc(-c4nc(-c5ccc6ccccc6c5)nc(-c5cccc6oc7ccccc7c56)n4)ccc23)cc1 ; c1ccc(-c2ccc3ccc(-c4nc(-c5ccc6ccccc6c5)nc(-c5cccc6oc7ccccc7c56)n4)cc3c2)cc1 ; c1ccc(-c2ccc3cc(-c4nc(-c5cc6ccccc6c6ccccc56)nc(-c5cccc6oc7ccccc7c56)n4)ccc3c2)cc1]

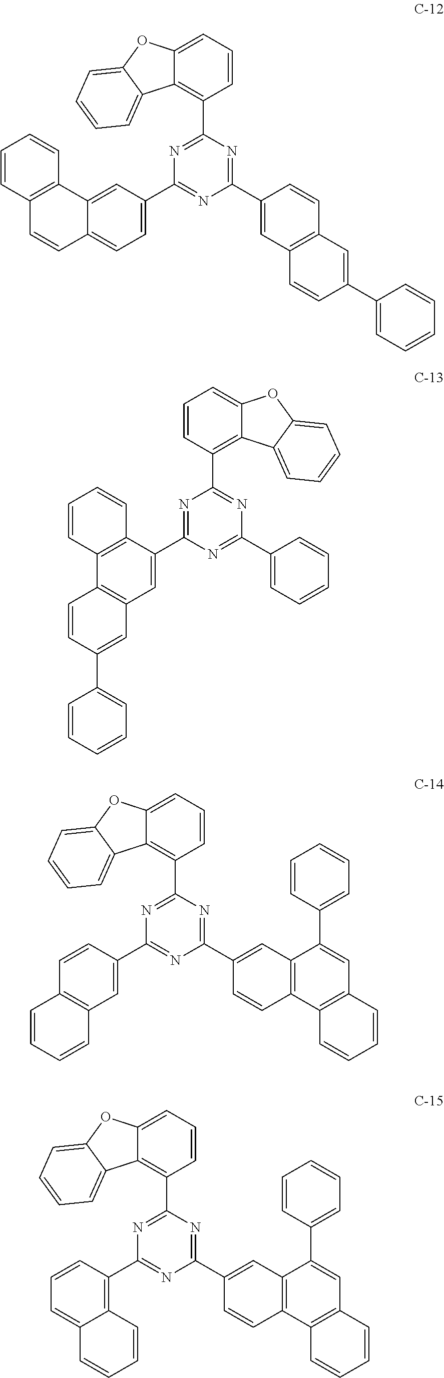 [SMILES: c1ccc(-c2ccc3cc(-c4nc(-c5ccc6ccc7ccccc7c6c5)nc(-c5cccc6oc7ccccc7c56)n4)ccc3c2)cc1 ; c1ccc(-c2ccc3c(c2)cc(-c2nc(-c4ccccc4)nc(-c4cccc5oc6ccccc6c45)n2)c2ccccc23)cc1 ; c1ccc(-c2cc3ccccc3c3ccc(-c4nc(-c5ccc6ccccc6c5)nc(-c5cccc6oc7ccccc7c56)n4)cc23)cc1 ; c1ccc(-c2cc3ccccc3c3ccc(-c4nc(-c5cccc6ccccc56)nc(-c5cccc6oc7ccccc7c56)n4)cc23)cc1]

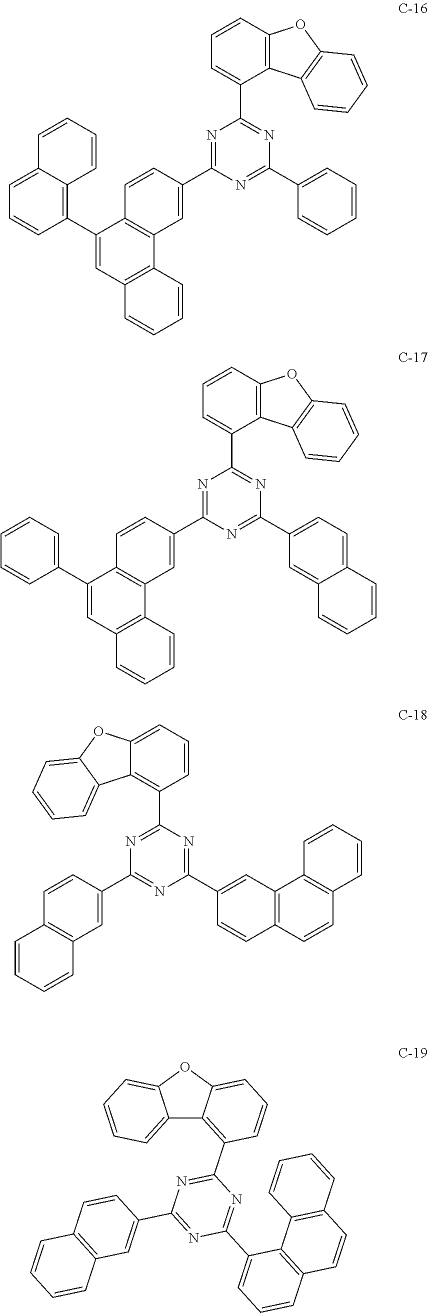

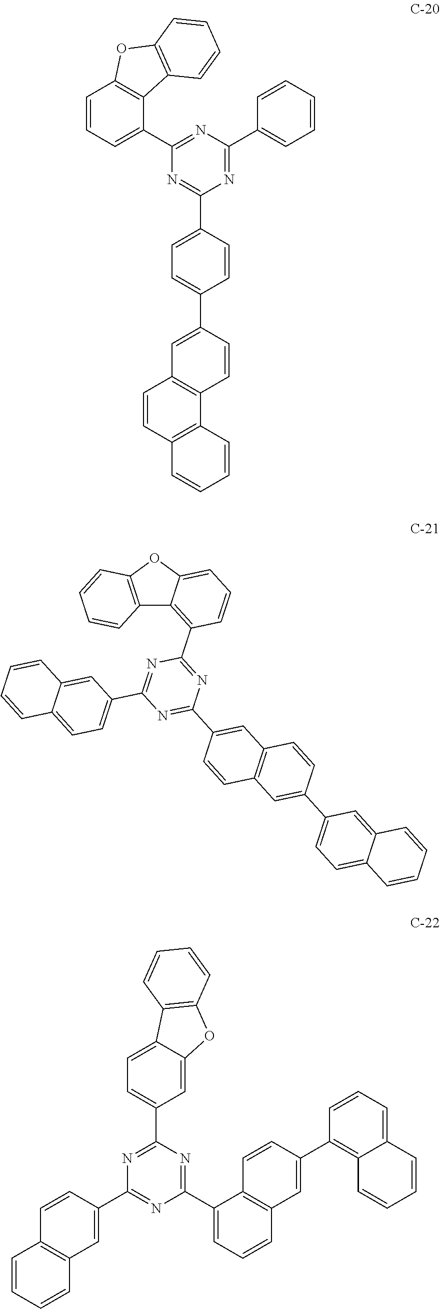 [SMILES: c1ccc(-c2nc(-c3ccc(-c4ccc5c(ccc6ccccc65)c4)cc3)nc(-c3cccc4oc5ccccc5c34)n2)cc1 ; c1ccc2cc(-c3ccc4cc(-c5nc(-c6ccc7ccccc7c6)nc(-c6cccc7oc8ccccc8c67)n5)ccc4c3)ccc2c1 ; c1ccc2cc(-c3nc(-c4ccc5c(c4)oc4ccccc45)nc(-c4cccc5cc(-c6cccc7ccccc67)ccc45)n3)ccc2c1]

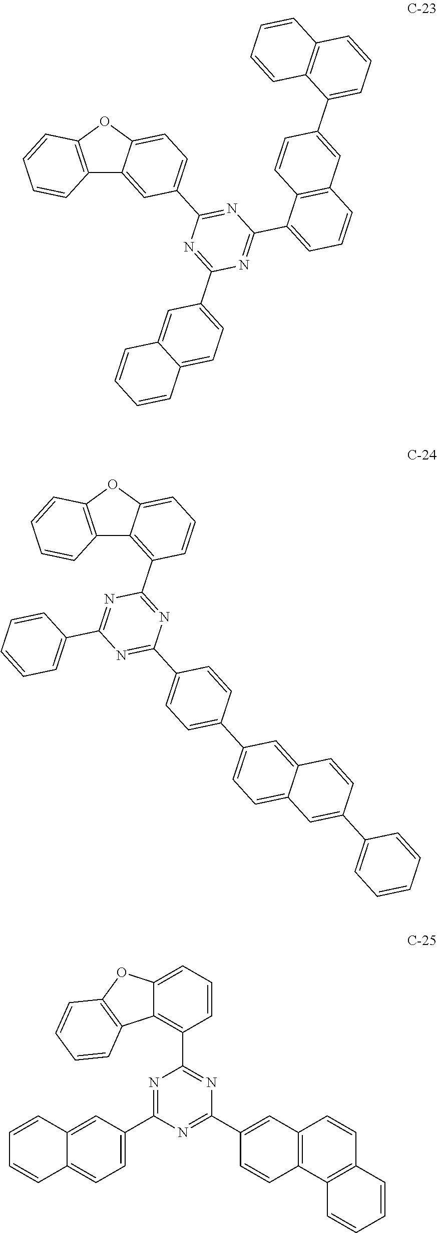 [SMILES: c1ccc2cc(-c3nc(-c4ccc5oc6ccccc6c5c4)nc(-c4cccc5cc(-c6cccc7ccccc67)ccc45)n3)ccc2c1 ; c1ccc(-c2ccc3cc(-c4ccc(-c5nc(-c6ccccc6)nc(-c6cccc7oc8ccccc8c67)n5)cc4)ccc3c2)cc1 ; c1ccc2cc(-c3nc(-c4ccc5c(ccc6ccccc65)c4)nc(-c4cccc5oc6ccccc6c45)n3)ccc2c1]

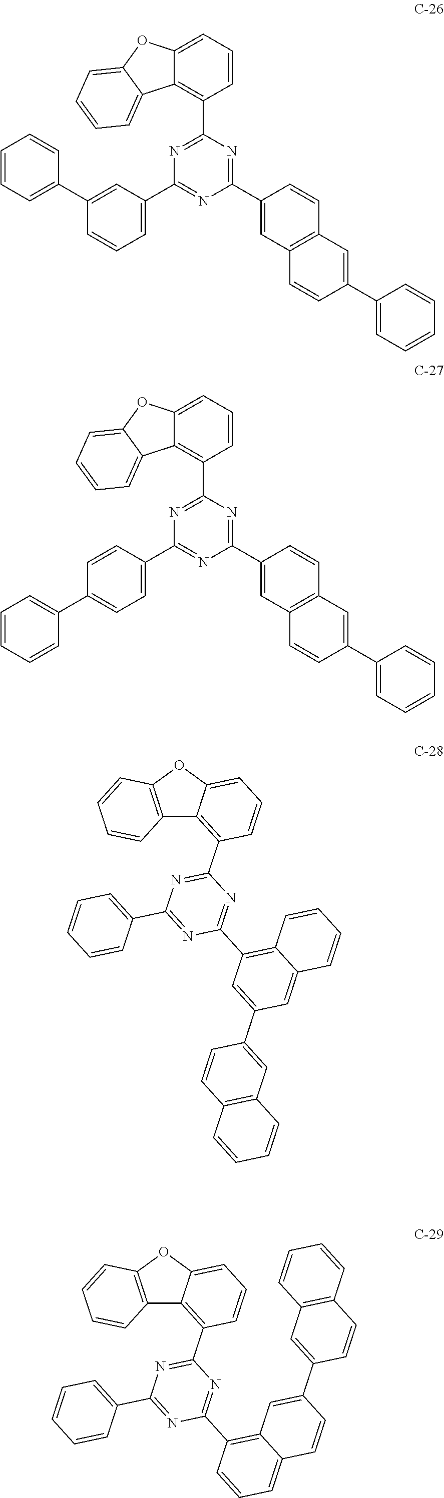 [SMILES: c1ccc(-c2cccc(-c3nc(-c4ccc5cc(-c6ccccc6)ccc5c4)nc(-c4cccc5oc6ccccc6c45)n3)c2)cc1 ; c1ccc(-c2ccc(-c3nc(-c4ccc5cc(-c6ccccc6)ccc5c4)nc(-c4cccc5oc6ccccc6c45)n3)cc2)cc1 ; c1ccc(-c2nc(-c3cc(-c4ccc5ccccc5c4)cc4ccccc34)nc(-c3cccc4oc5ccccc5c34)n2)cc1 ; c1ccc(-c2nc(-c3cccc4ccc(-c5ccc6ccccc6c5)cc34)nc(-c3cccc4oc5ccccc5c34)n2)cc1]

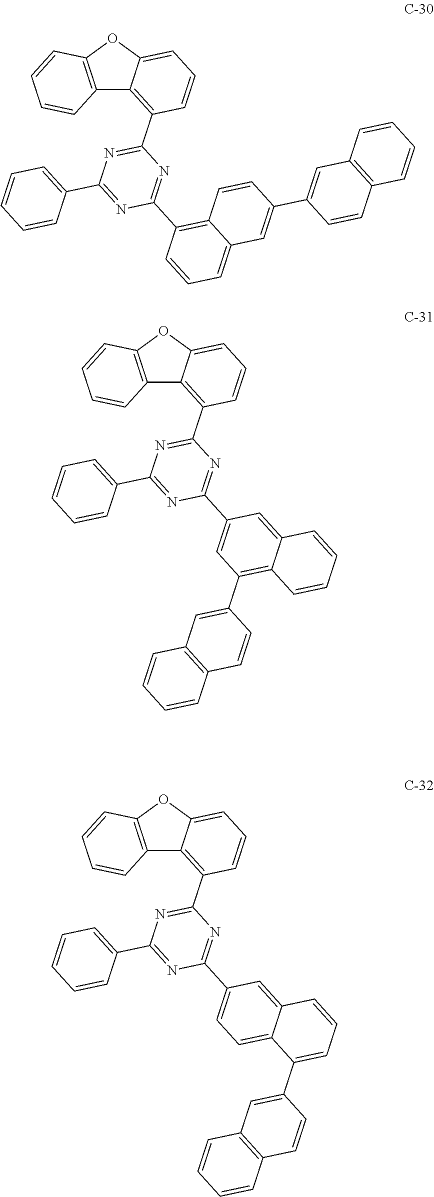 [SMILES: c1ccc(-c2nc(-c3cccc4cc(-c5ccc6ccccc6c5)ccc34)nc(-c3cccc4oc5ccccc5c34)n2)cc1 ; c1ccc(-c2nc(-c3cc(-c4ccc5ccccc5c4)c4ccccc4c3)nc(-c3cccc4oc5ccccc5c34)n2)cc1 ; c1ccc(-c2nc(-c3ccc4c(-c5ccc6ccccc6c5)cccc4c3)nc(-c3cccc4oc5ccccc5c34)n2)cc1]

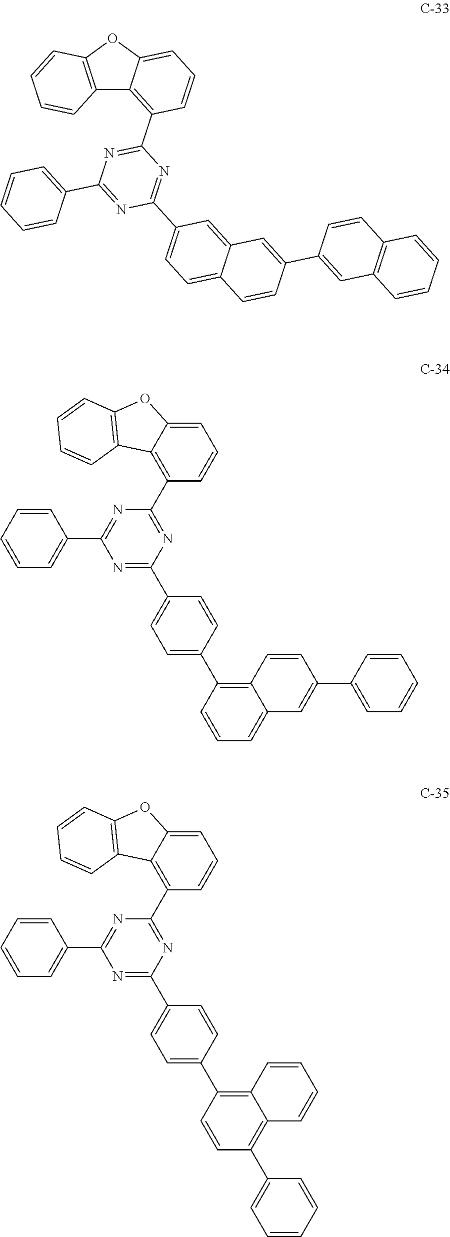 [SMILES: c1ccc(-c2nc(-c3ccc4ccc(-c5ccc6ccccc6c5)cc4c3)nc(-c3cccc4oc5ccccc5c34)n2)cc1 ; c1ccc(-c2ccc3c(-c4ccc(-c5nc(-c6ccccc6)nc(-c6cccc7oc8ccccc8c67)n5)cc4)cccc3c2)cc1 ; c1ccc(-c2nc(-c3ccc(-c4ccc(-c5ccccc5)c5ccccc45)cc3)nc(-c3cccc4oc5ccccc5c34)n2)cc1]

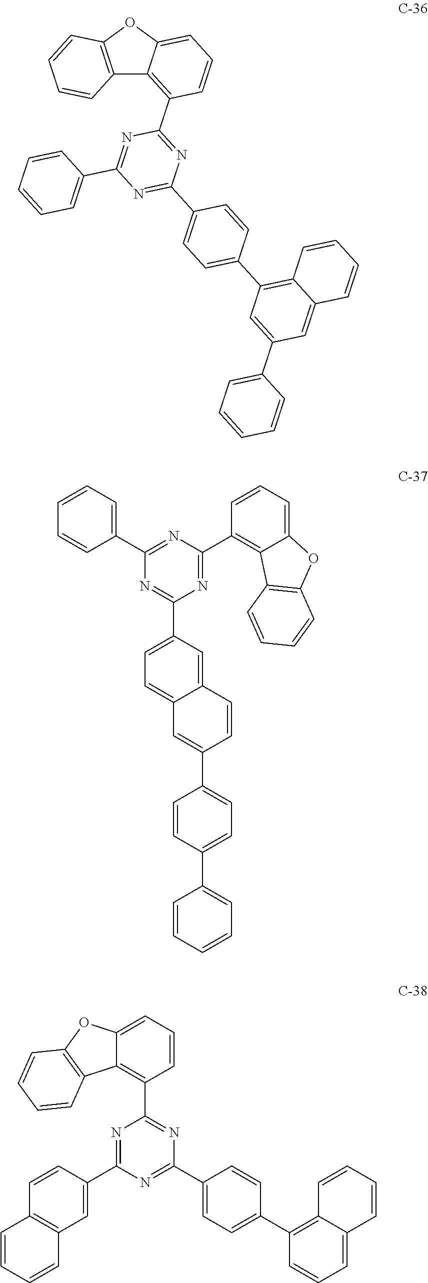 [SMILES: c1ccc(-c2cc(-c3ccc(-c4nc(-c5ccccc5)nc(-c5cccc6oc7ccccc7c56)n4)cc3)c3ccccc3c2)cc1 ; c1ccc(-c2ccc(-c3ccc4cc(-c5nc(-c6ccccc6)nc(-c6cccc7oc8ccccc8c67)n5)ccc4c3)cc2)cc1 ; c1ccc2cc(-c3nc(-c4ccc(-c5cccc6ccccc56)cc4)nc(-c4cccc5oc6ccccc6c45)n3)ccc2c1]

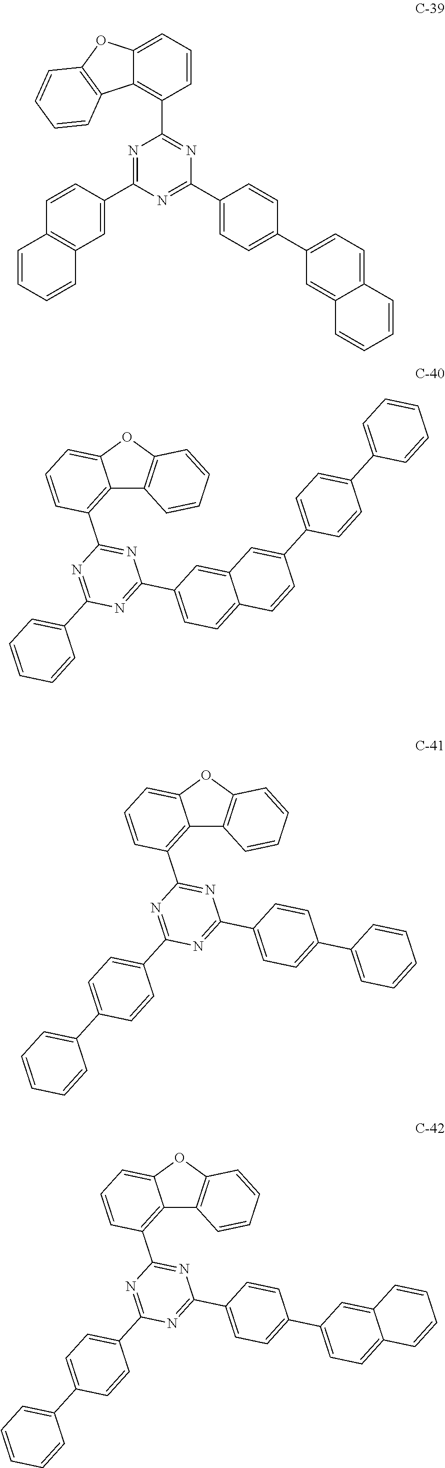 [SMILES: c1ccc2cc(-c3ccc(-c4nc(-c5ccc6ccccc6c5)nc(-c5cccc6oc7ccccc7c56)n4)cc3)ccc2c1 ; c1ccc(-c2ccc(-c3ccc4ccc(-c5nc(-c6ccccc6)nc(-c6cccc7oc8ccccc8c67)n5)cc4c3)cc2)cc1 ; c1ccc(-c2ccc(-c3nc(-c4ccc(-c5ccccc5)cc4)nc(-c4cccc5oc6ccccc6c45)n3)cc2)cc1 ; c1ccc(-c2ccc(-c3nc(-c4ccc(-c5ccc6ccccc6c5)cc4)nc(-c4cccc5oc6ccccc6c45)n3)cc2)cc1]

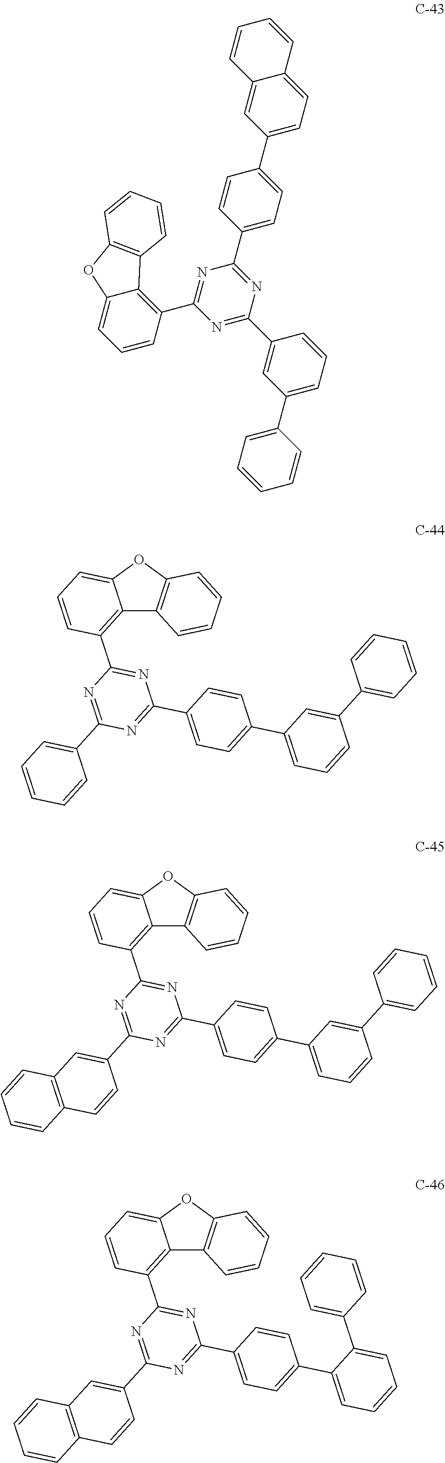 [SMILES: c1ccc(-c2cccc(-c3nc(-c4ccc(-c5ccc6ccccc6c5)cc4)nc(-c4cccc5oc6ccccc6c45)n3)c2)cc1 ; c1ccc(-c2cccc(-c3ccc(-c4nc(-c5ccccc5)nc(-c5cccc6oc7ccccc7c56)n4)cc3)c2)cc1 ; c1ccc(-c2cccc(-c3ccc(-c4nc(-c5ccc6ccccc6c5)nc(-c5cccc6oc7ccccc7c56)n4)cc3)c2)cc1 ; c1ccc(-c2ccccc2-c2ccc(-c3nc(-c4ccc5ccccc5c4)nc(-c4cccc5oc6ccccc6c45)n3)cc2)cc1]

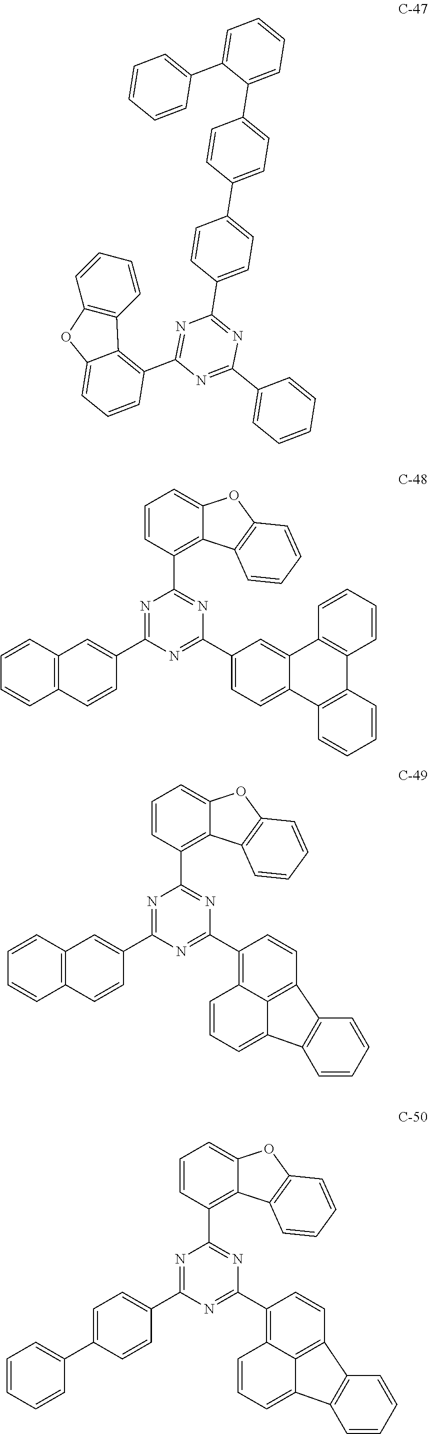 [SMILES: c1ccc(-c2nc(-c3ccc(-c4ccc(-c5ccccc5-c5ccccc5)cc4)cc3)nc(-c3cccc4oc5ccccc5c34)n2)cc1 ; c1ccc2cc(-c3nc(-c4ccc5c6ccccc6c6ccccc6c5c4)nc(-c4cccc5oc6ccccc6c45)n3)ccc2c1 ; c1ccc2c(c1)-c1cccc3c(-c4nc(-c5ccc6ccccc6c5)nc(-c5cccc6oc7ccccc7c56)n4)ccc-2c13 ; c1ccc(-c2ccc(-c3nc(-c4ccc5c6c(cccc46)-c4ccccc4-5)nc(-c4cccc5oc6ccccc6c45)n3)cc2)cc1]

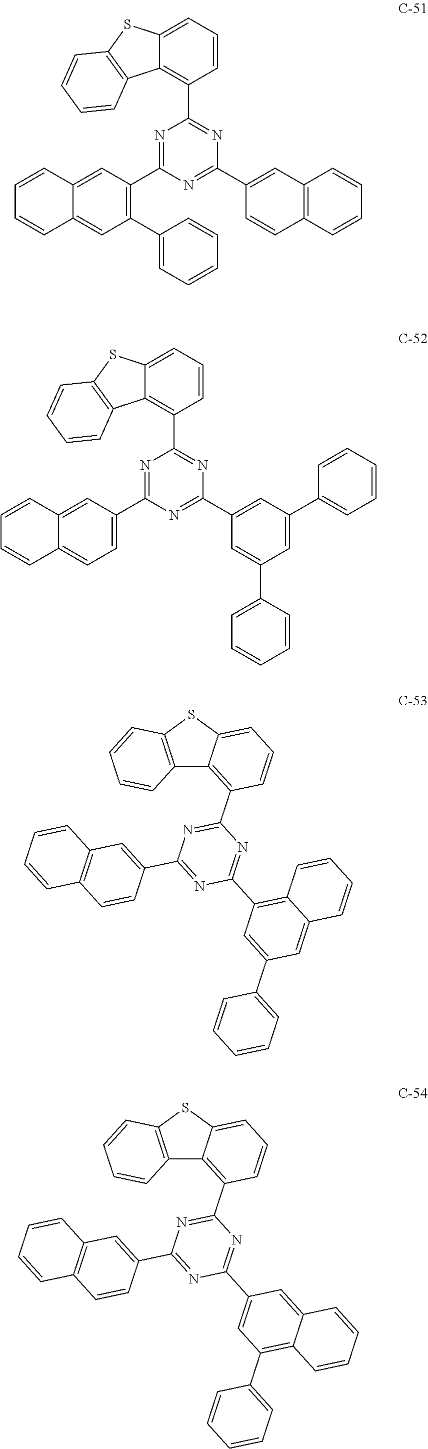 [SMILES: c1ccc(-c2cc3ccccc3cc2-c2nc(-c3ccc4ccccc4c3)nc(-c3cccc4sc5ccccc5c34)n2)cc1 ; c1ccc(-c2cc(-c3ccccc3)cc(-c3nc(-c4ccc5ccccc5c4)nc(-c4cccc5sc6ccccc6c45)n3)c2)cc1 ; c1ccc(-c2cc(-c3nc(-c4ccc5ccccc5c4)nc(-c4cccc5sc6ccccc6c45)n3)c3ccccc3c2)cc1 ; c1ccc(-c2cc(-c3nc(-c4ccc5ccccc5c4)nc(-c4cccc5sc6ccccc6c45)n3)cc3ccccc23)cc1]

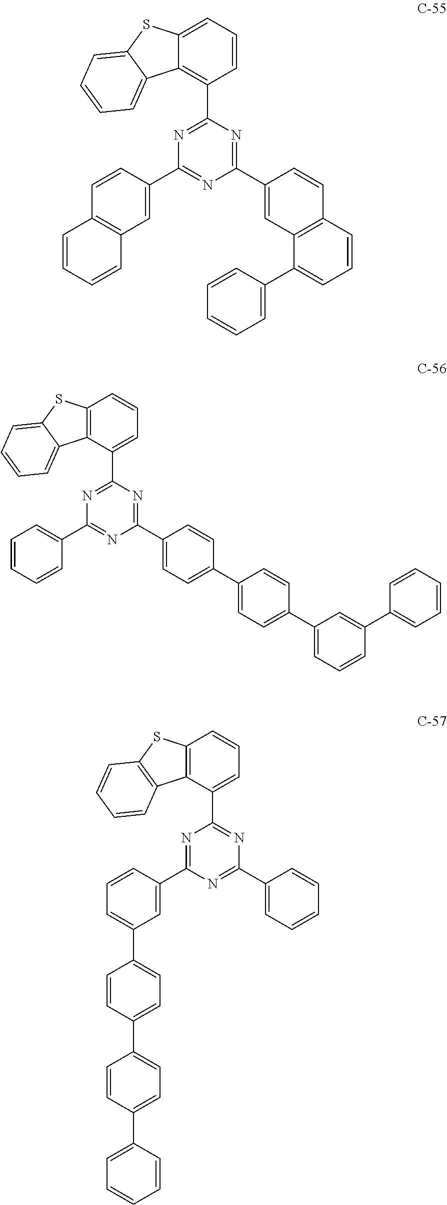 [SMILES: c1ccc(-c2cccc3ccc(-c4nc(-c5ccc6ccccc6c5)nc(-c5cccc6sc7ccccc7c56)n4)cc23)cc1 ; c1ccc(-c2cccc(-c3ccc(-c4ccc(-c5nc(-c6ccccc6)nc(-c6cccc7sc8ccccc8c67)n5)cc4)cc3)c2)cc1 ; c1ccc(-c2ccc(-c3ccc(-c4cccc(-c5nc(-c6ccccc6)nc(-c6cccc7sc8ccccc8c67)n5)c4)cc3)cc2)cc1]

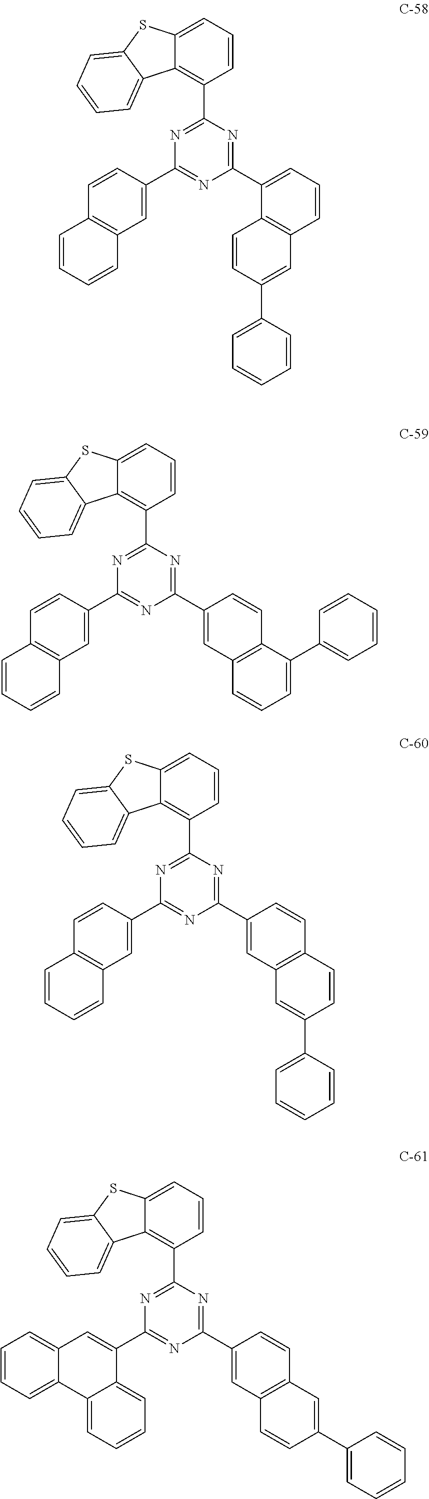 [SMILES: c1ccc(-c2ccc3c(-c4nc(-c5ccc6ccccc6c5)nc(-c5cccc6sc7ccccc7c56)n4)cccc3c2)cc1 ; c1ccc(-c2cccc3cc(-c4nc(-c5ccc6ccccc6c5)nc(-c5cccc6sc7ccccc7c56)n4)ccc23)cc1 ; c1ccc(-c2ccc3ccc(-c4nc(-c5ccc6ccccc6c5)nc(-c5cccc6sc7ccccc7c56)n4)cc3c2)cc1 ; c1ccc(-c2ccc3cc(-c4nc(-c5cc6ccccc6c6ccccc56)nc(-c5cccc6sc7ccccc7c56)n4)ccc3c2)cc1]

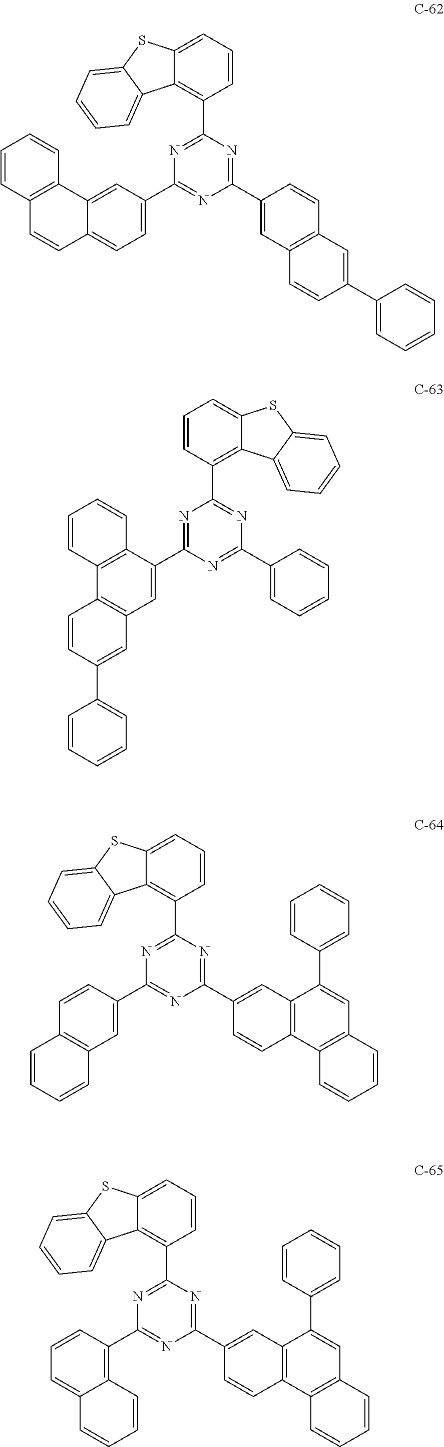 [SMILES: c1ccc(-c2ccc3cc(-c4nc(-c5ccc6ccc7ccccc7c6c5)nc(-c5cccc6sc7ccccc7c56)n4)ccc3c2)cc1 ; c1ccc(-c2ccc3c(c2)cc(-c2nc(-c4ccccc4)nc(-c4cccc5sc6ccccc6c45)n2)c2ccccc23)cc1 ; c1ccc(-c2cc3ccccc3c3ccc(-c4nc(-c5ccc6ccccc6c5)nc(-c5cccc6sc7ccccc7c56)n4)cc23)cc1 ; c1ccc(-c2cc3ccccc3c3ccc(-c4nc(-c5cccc6ccccc56)nc(-c5cccc6sc7ccccc7c56)n4)cc23)cc1]

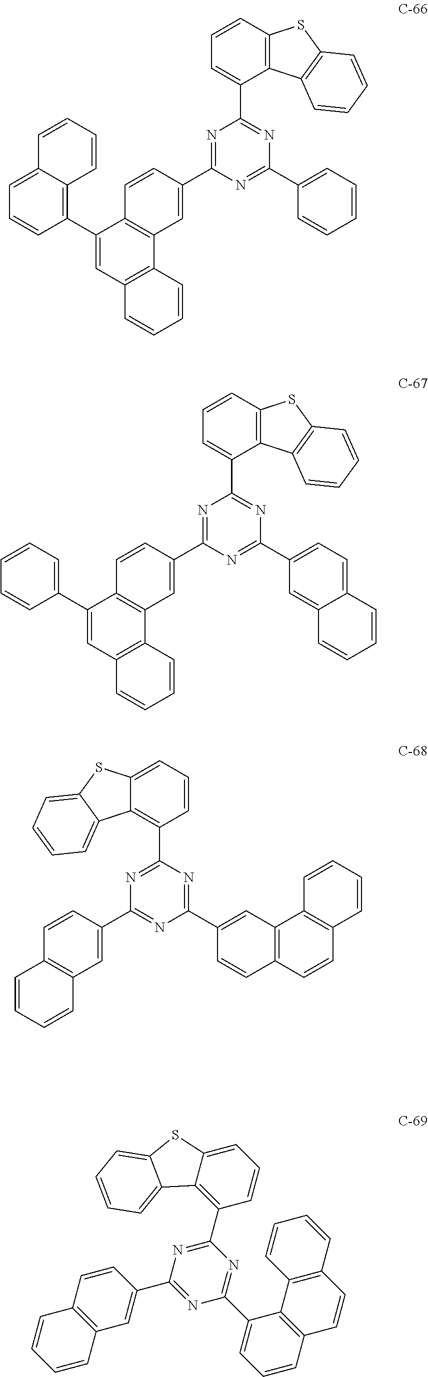 [SMILES: c1ccc(-c2nc(-c3ccc4c(-c5cccc6ccccc56)cc5ccccc5c4c3)nc(-c3cccc4sc5ccccc5c34)n2)cc1 ; c1ccc(-c2cc3ccccc3c3cc(-c4nc(-c5ccc6ccccc6c5)nc(-c5cccc6sc7ccccc7c56)n4)ccc23)cc1 ; c1ccc2cc(-c3nc(-c4ccc5ccc6ccccc6c5c4)nc(-c4cccc5sc6ccccc6c45)n3)ccc2c1 ; c1ccc2cc(-c3nc(-c4cccc5ccc6ccccc6c45)nc(-c4cccc5sc6ccccc6c45)n3)ccc2c1]

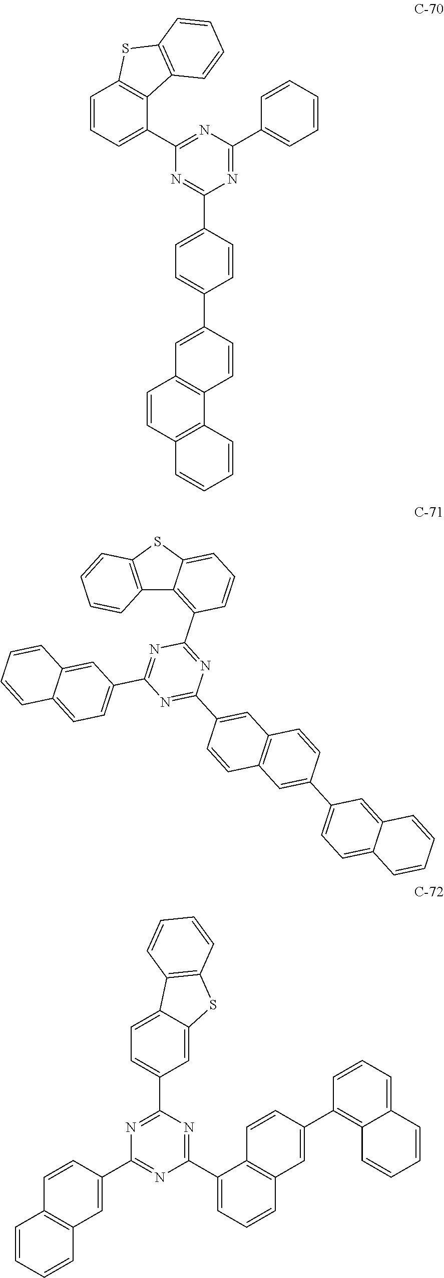 [SMILES: c1ccc(-c2nc(-c3ccc(-c4ccc5c(ccc6ccccc65)c4)cc3)nc(-c3cccc4sc5ccccc5c34)n2)cc1 ; c1ccc2cc(-c3ccc4cc(-c5nc(-c6ccc7ccccc7c6)nc(-c6cccc7sc8ccccc8c67)n5)ccc4c3)ccc2c1 ; c1ccc2cc(-c3nc(-c4ccc5c(c4)sc4ccccc45)nc(-c4cccc5cc(-c6cccc7ccccc67)ccc45)n3)ccc2c1]

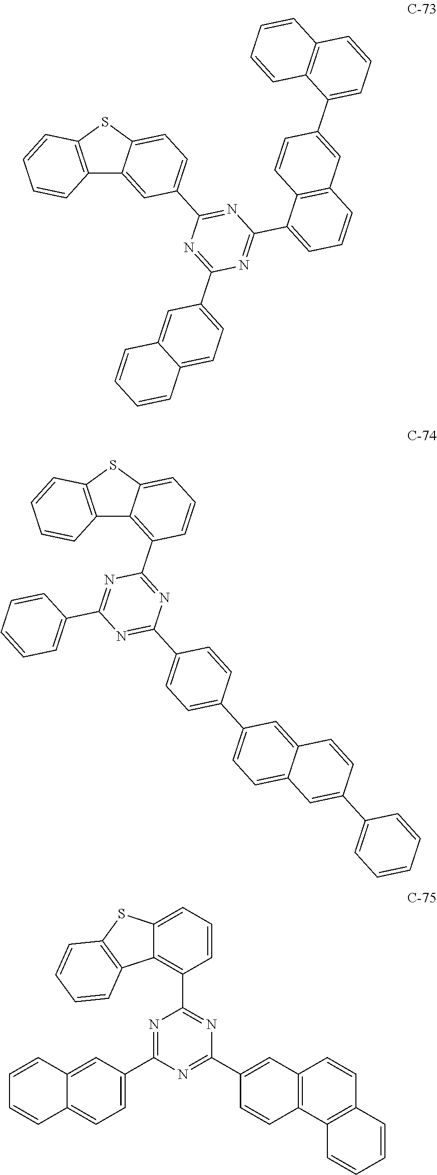 [SMILES: c1ccc2cc(-c3nc(-c4ccc5sc6ccccc6c5c4)nc(-c4cccc5cc(-c6cccc7ccccc67)ccc45)n3)ccc2c1 ; c1ccc(-c2ccc3cc(-c4ccc(-c5nc(-c6ccccc6)nc(-c6cccc7sc8ccccc8c67)n5)cc4)ccc3c2)cc1 ; c1ccc2cc(-c3nc(-c4ccc5c(ccc6ccccc65)c4)nc(-c4cccc5sc6ccccc6c45)n3)ccc2c1]

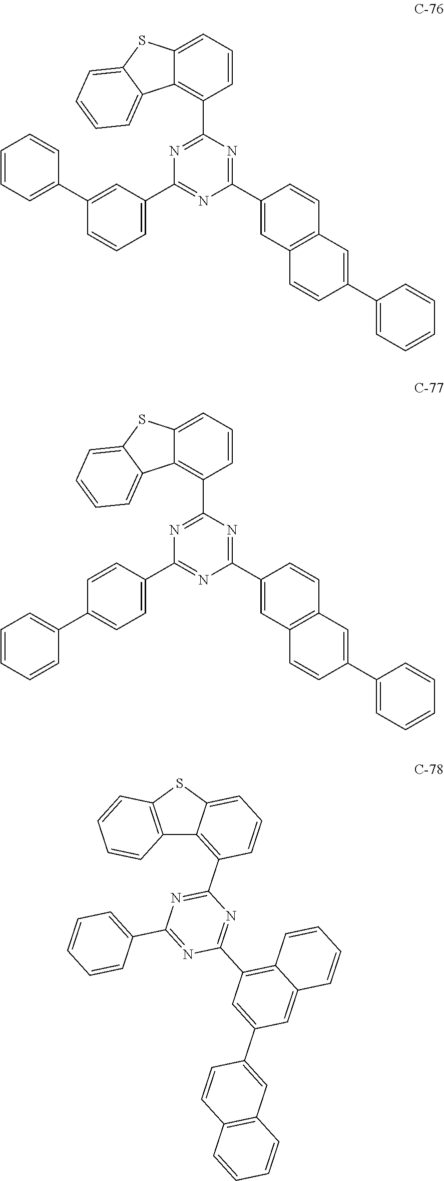 [SMILES: c1ccc(-c2cccc(-c3nc(-c4ccc5cc(-c6ccccc6)ccc5c4)nc(-c4cccc5sc6ccccc6c45)n3)c2)cc1 ; c1ccc(-c2ccc(-c3nc(-c4ccc5cc(-c6ccccc6)ccc5c4)nc(-c4cccc5sc6ccccc6c45)n3)cc2)cc1 ; c1ccc(-c2nc(-c3cc(-c4ccc5ccccc5c4)cc4ccccc34)nc(-c3cccc4sc5ccccc5c34)n2)cc1]

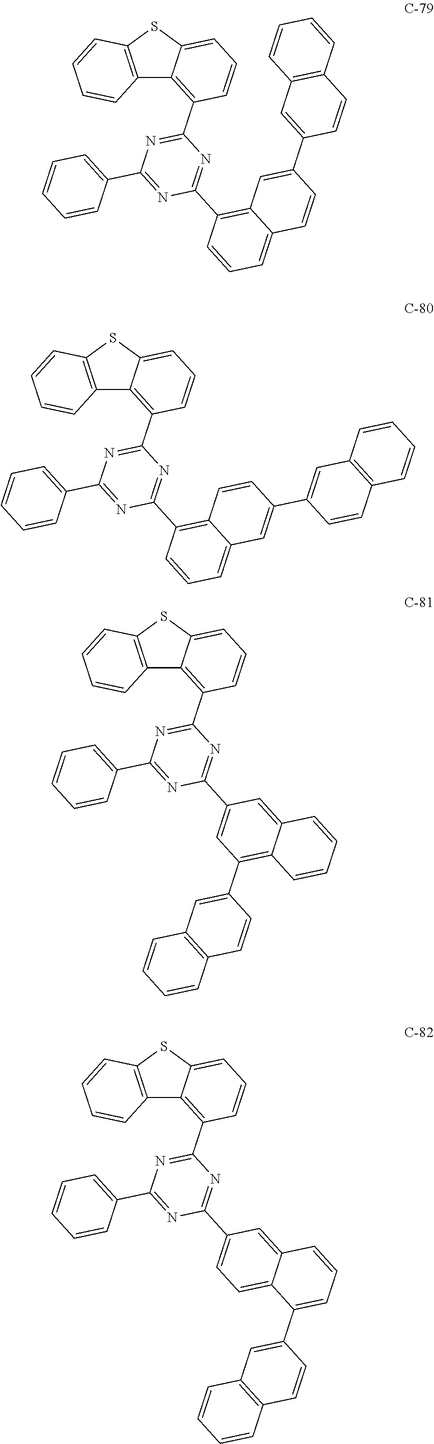

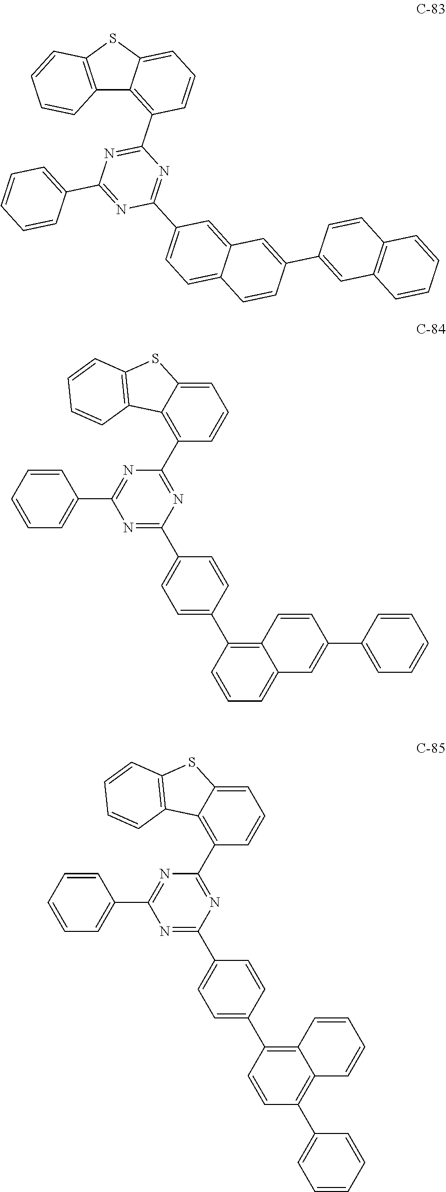 [SMILES: c1ccc(-c2nc(-c3ccc4ccc(-c5ccc6ccccc6c5)cc4c3)nc(-c3cccc4sc5ccccc5c34)n2)cc1 ; c1ccc(-c2ccc3c(-c4ccc(-c5nc(-c6ccccc6)nc(-c6cccc7sc8ccccc8c67)n5)cc4)cccc3c2)cc1 ; c1ccc(-c2nc(-c3ccc(-c4ccc(-c5ccccc5)c5ccccc45)cc3)nc(-c3cccc4sc5ccccc5c34)n2)cc1]

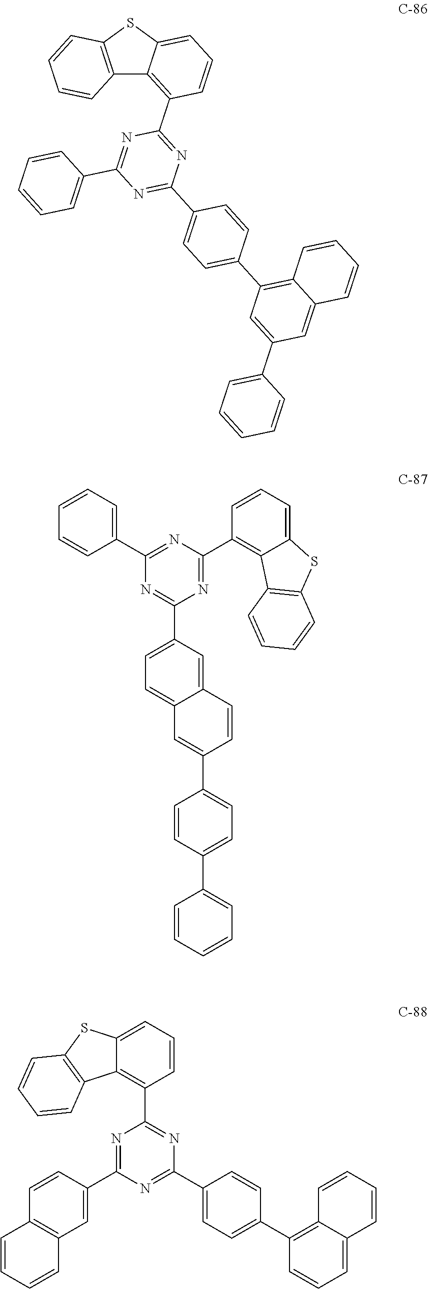 [SMILES: c1ccc(-c2cc(-c3ccc(-c4nc(-c5ccccc5)nc(-c5cccc6sc7ccccc7c56)n4)cc3)c3ccccc3c2)cc1 ; c1ccc(-c2ccc(-c3ccc4cc(-c5nc(-c6ccccc6)nc(-c6cccc7sc8ccccc8c67)n5)ccc4c3)cc2)cc1 ; c1ccc2cc(-c3nc(-c4ccc(-c5cccc6ccccc56)cc4)nc(-c4cccc5sc6ccccc6c45)n3)ccc2c1]

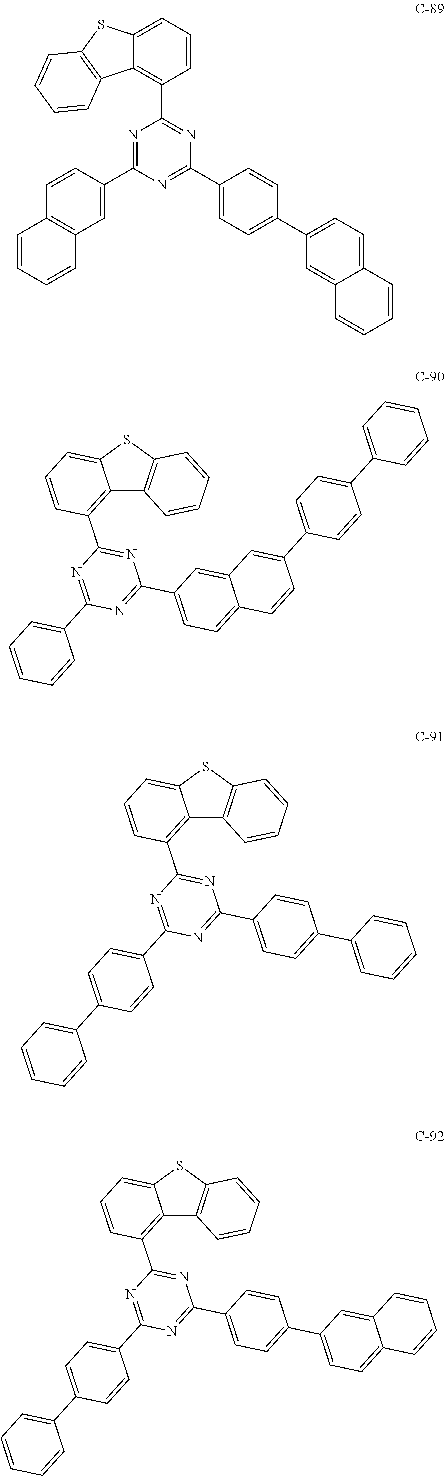 [SMILES: c1ccc2cc(-c3ccc(-c4nc(-c5ccc6ccccc6c5)nc(-c5cccc6sc7ccccc7c56)n4)cc3)ccc2c1 ; c1ccc(-c2ccc(-c3ccc4ccc(-c5nc(-c6ccccc6)nc(-c6cccc7sc8ccccc8c67)n5)cc4c3)cc2)cc1 ; c1ccc(-c2ccc(-c3nc(-c4ccc(-c5ccccc5)cc4)nc(-c4cccc5sc6ccccc6c45)n3)cc2)cc1 ; c1ccc(-c2ccc(-c3nc(-c4ccc(-c5ccc6ccccc6c5)cc4)nc(-c4cccc5sc6ccccc6c45)n3)cc2)cc1]

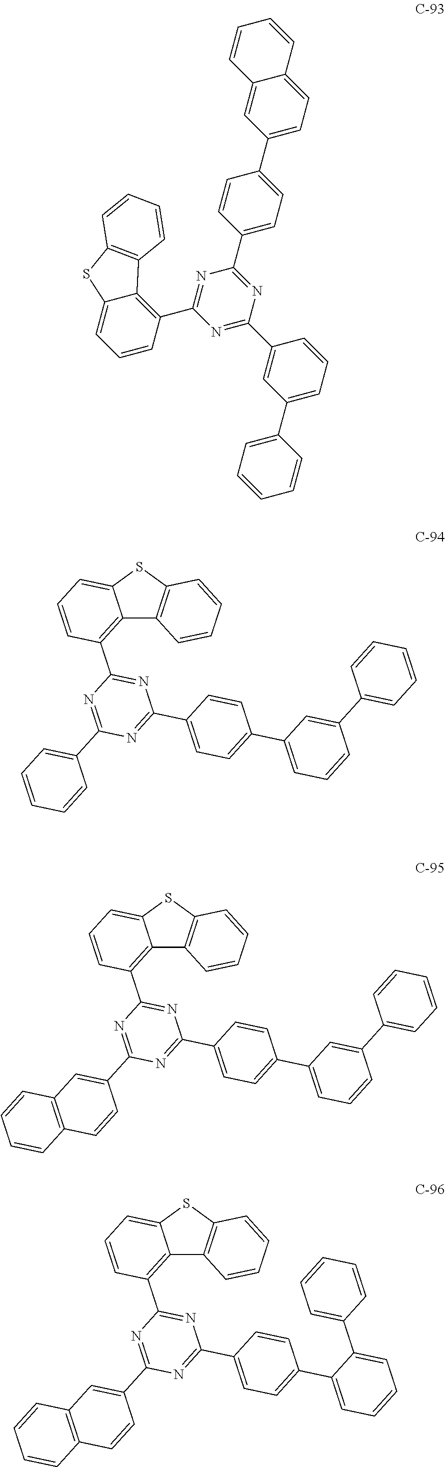 [SMILES: c1ccc(-c2cccc(-c3nc(-c4ccc(-c5ccc6ccccc6c5)cc4)nc(-c4cccc5sc6ccccc6c45)n3)c2)cc1 ; c1ccc(-c2cccc(-c3ccc(-c4nc(-c5ccccc5)nc(-c5cccc6sc7ccccc7c56)n4)cc3)c2)cc1 ; c1ccc(-c2cccc(-c3ccc(-c4nc(-c5ccc6ccccc6c5)nc(-c5cccc6sc7ccccc7c56)n4)cc3)c2)cc1 ; c1ccc(-c2ccccc2-c2ccc(-c3nc(-c4ccc5ccccc5c4)nc(-c4cccc5sc6ccccc6c45)n3)cc2)cc1]

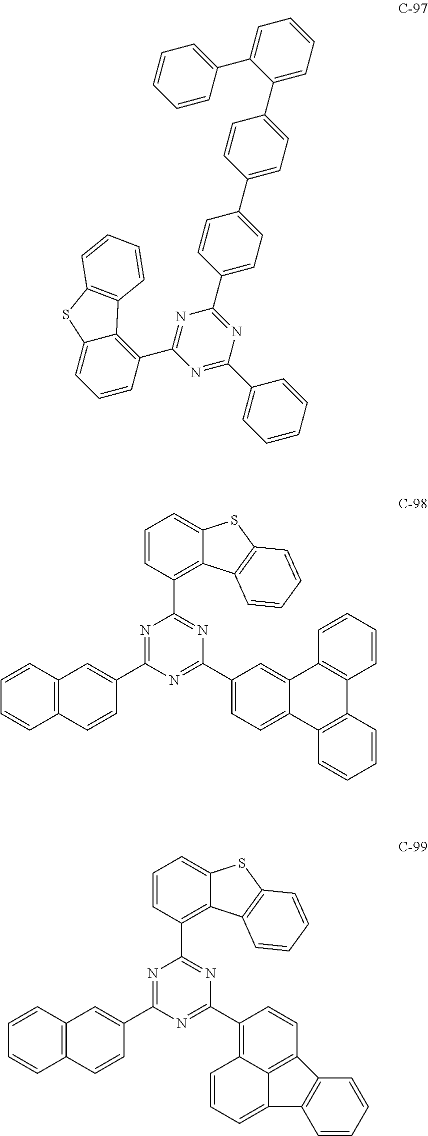 [SMILES: c1ccc(-c2nc(-c3ccc(-c4ccc(-c5ccccc5-c5ccccc5)cc4)cc3)nc(-c3cccc4sc5ccccc5c34)n2)cc1 ; c1ccc2cc(-c3nc(-c4ccc5c6ccccc6c6ccccc6c5c4)nc(-c4cccc5sc6ccccc6c45)n3)ccc2c1 ; c1ccc2c(c1)-c1cccc3c(-c4nc(-c5ccc6ccccc6c5)nc(-c5cccc6sc7ccccc7c56)n4)ccc-2c13]

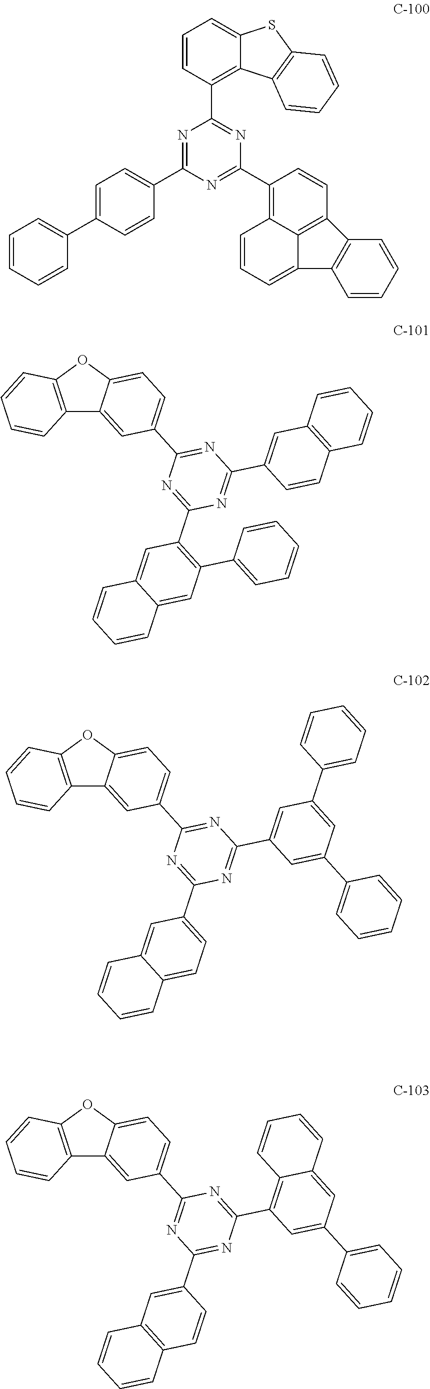 [SMILES: c1ccc(-c2ccc(-c3nc(-c4ccc5c6c(cccc46)-c4ccccc4-5)nc(-c4cccc5sc6ccccc6c45)n3)cc2)cc1 ; c1ccc(-c2cc3ccccc3cc2-c2nc(-c3ccc4ccccc4c3)nc(-c3ccc4oc5ccccc5c4c3)n2)cc1 ; c1ccc(-c2cc(-c3ccccc3)cc(-c3nc(-c4ccc5ccccc5c4)nc(-c4ccc5oc6ccccc6c5c4)n3)c2)cc1 ; c1ccc(-c2cc(-c3nc(-c4ccc5ccccc5c4)nc(-c4ccc5oc6ccccc6c5c4)n3)c3ccccc3c2)cc1]

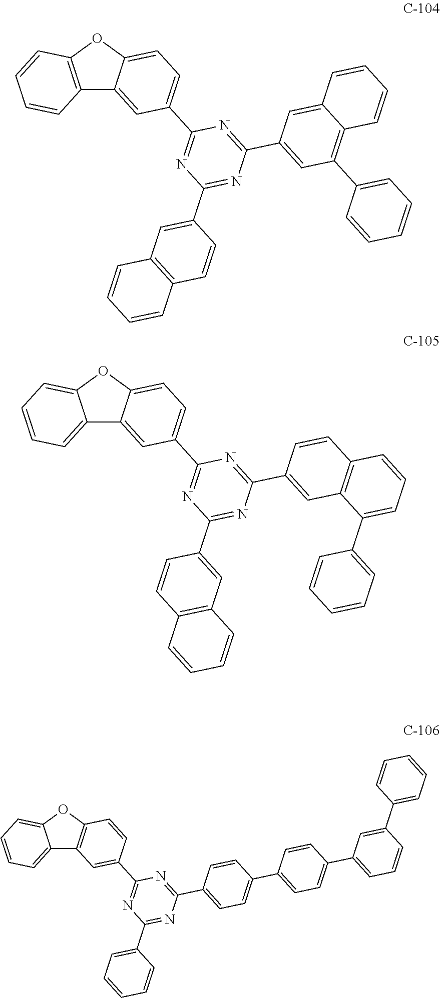 [SMILES: c1ccc(-c2cc(-c3nc(-c4ccc5ccccc5c4)nc(-c4ccc5oc6ccccc6c5c4)n3)cc3ccccc23)cc1 ; c1ccc(-c2cccc3ccc(-c4nc(-c5ccc6ccccc6c5)nc(-c5ccc6oc7ccccc7c6c5)n4)cc23)cc1 ; c1ccc(-c2cccc(-c3ccc(-c4ccc(-c5nc(-c6ccccc6)nc(-c6ccc7oc8ccccc8c7c6)n5)cc4)cc3)c2)cc1]

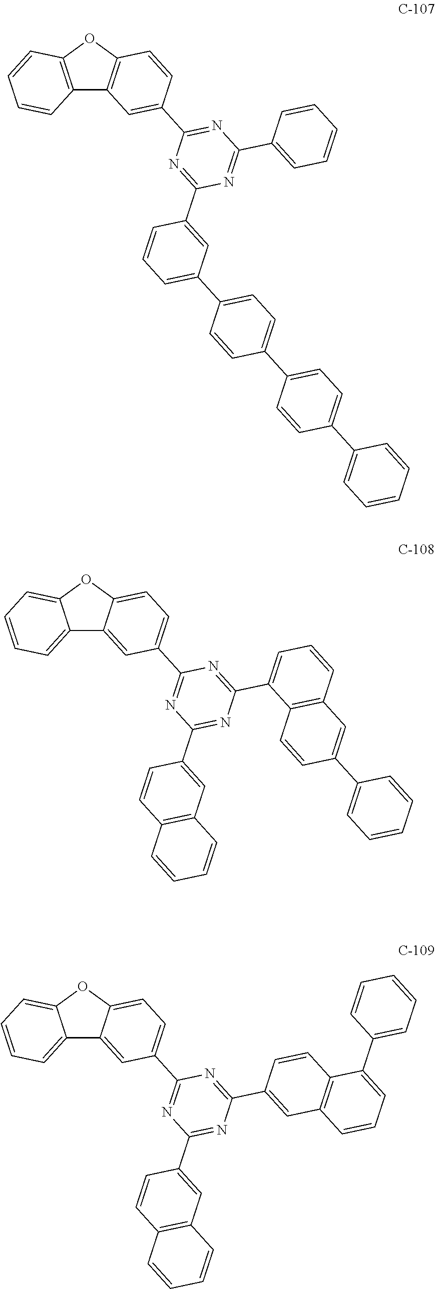 [SMILES: c1ccc(-c2ccc(-c3ccc(-c4cccc(-c5nc(-c6ccccc6)nc(-c6ccc7oc8ccccc8c7c6)n5)c4)cc3)cc2)cc1 ; c1ccc(-c2ccc3c(-c4nc(-c5ccc6ccccc6c5)nc(-c5ccc6oc7ccccc7c6c5)n4)cccc3c2)cc1 ; c1ccc(-c2cccc3cc(-c4nc(-c5ccc6ccccc6c5)nc(-c5ccc6oc7ccccc7c6c5)n4)ccc23)cc1]

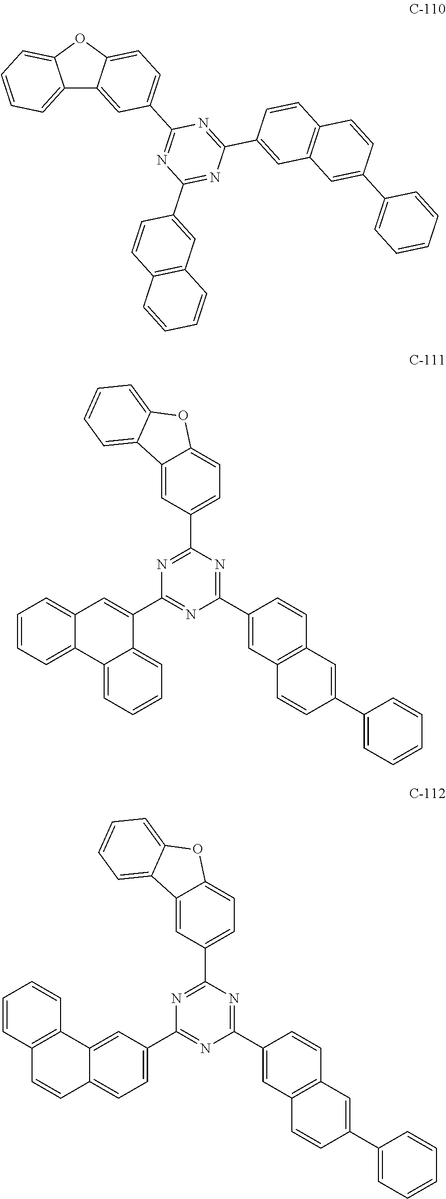 [SMILES: c1ccc(-c2ccc3ccc(-c4nc(-c5ccc6ccccc6c5)nc(-c5ccc6oc7ccccc7c6c5)n4)cc3c2)cc1 ; c1ccc(-c2ccc3cc(-c4nc(-c5ccc6oc7ccccc7c6c5)nc(-c5cc6ccccc6c6ccccc56)n4)ccc3c2)cc1 ; c1ccc(-c2ccc3cc(-c4nc(-c5ccc6ccc7ccccc7c6c5)nc(-c5ccc6oc7ccccc7c6c5)n4)ccc3c2)cc1]

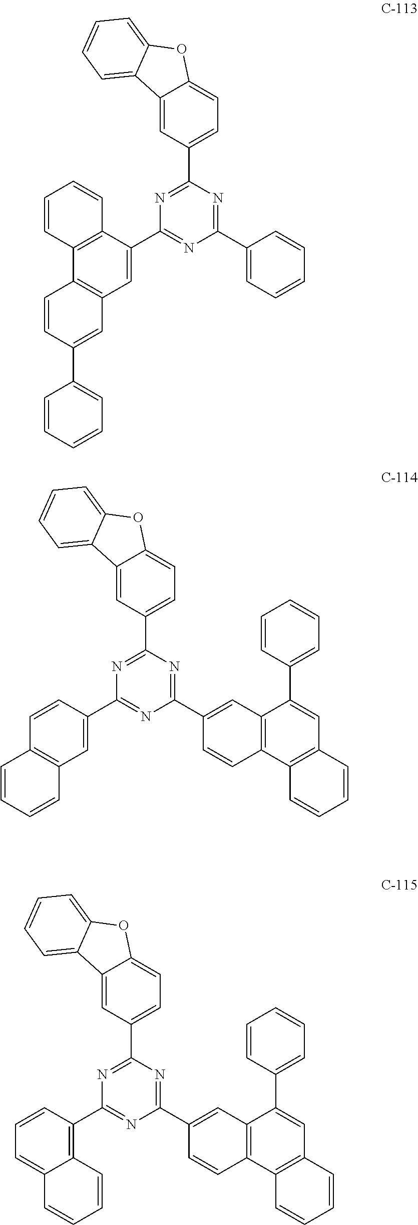

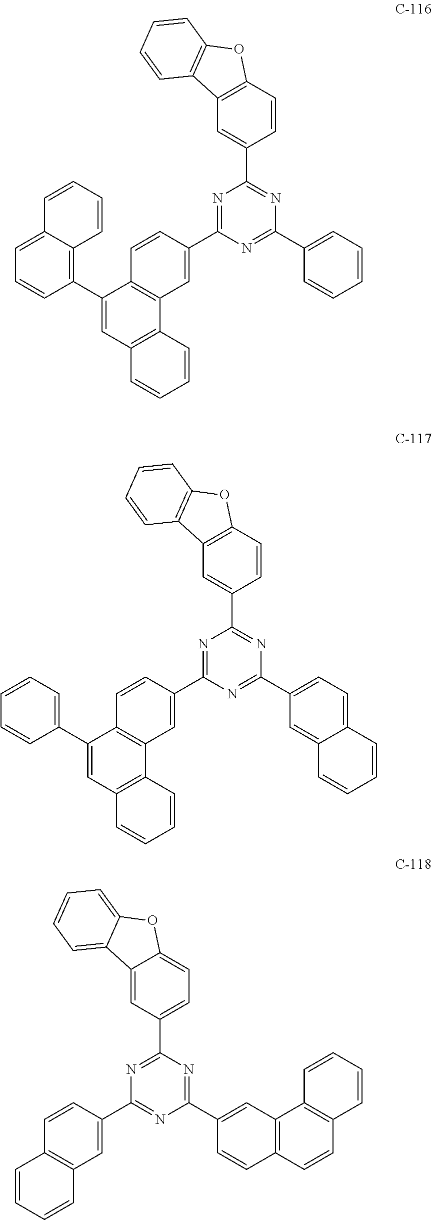 [SMILES: c1ccc(-c2nc(-c3ccc4oc5ccccc5c4c3)nc(-c3ccc4c(-c5cccc6ccccc56)cc5ccccc5c4c3)n2)cc1 ; c1ccc(-c2cc3ccccc3c3cc(-c4nc(-c5ccc6ccccc6c5)nc(-c5ccc6oc7ccccc7c6c5)n4)ccc23)cc1 ; c1ccc2cc(-c3nc(-c4ccc5ccc6ccccc6c5c4)nc(-c4ccc5oc6ccccc6c5c4)n3)ccc2c1]

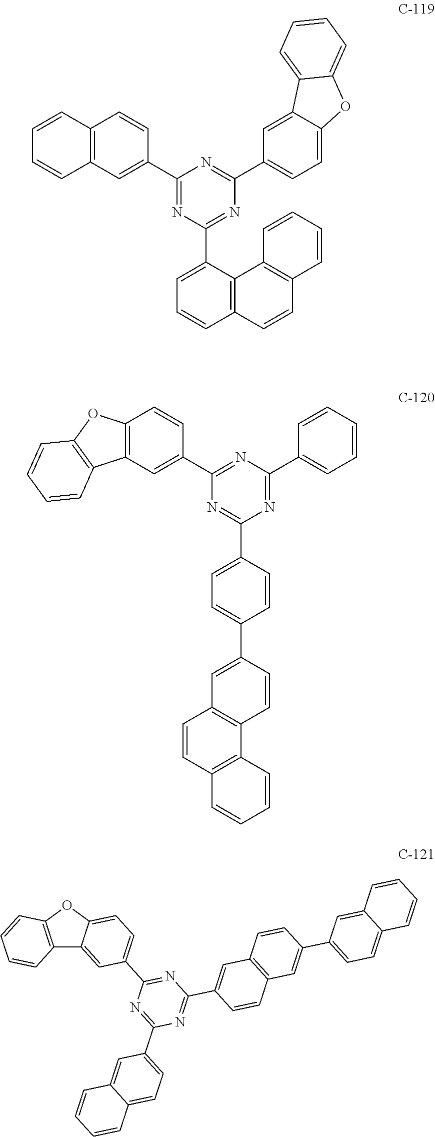 [SMILES: c1ccc2cc(-c3nc(-c4ccc5oc6ccccc6c5c4)nc(-c4cccc5ccc6ccccc6c45)n3)ccc2c1 ; c1ccc(-c2nc(-c3ccc(-c4ccc5c(ccc6ccccc65)c4)cc3)nc(-c3ccc4oc5ccccc5c4c3)n2)cc1 ; c1ccc2cc(-c3ccc4cc(-c5nc(-c6ccc7ccccc7c6)nc(-c6ccc7oc8ccccc8c7c6)n5)ccc4c3)ccc2c1]

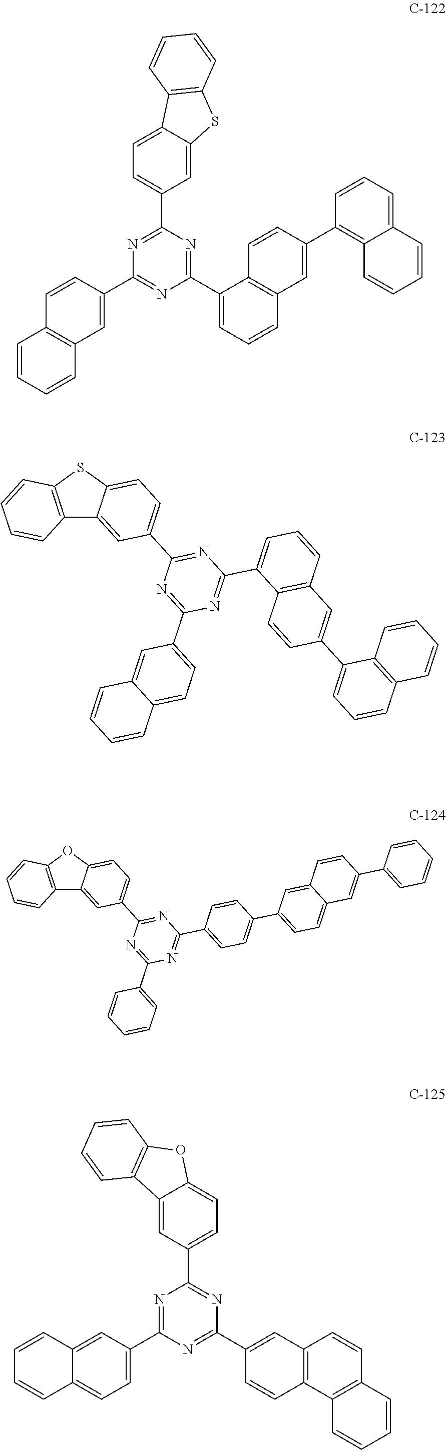 [SMILES: c1ccc2cc(-c3nc(-c4ccc5c(c4)sc4ccccc45)nc(-c4cccc5cc(-c6cccc7ccccc67)ccc45)n3)ccc2c1 ; c1ccc2cc(-c3nc(-c4ccc5sc6ccccc6c5c4)nc(-c4cccc5cc(-c6cccc7ccccc67)ccc45)n3)ccc2c1 ; c1ccc(-c2ccc3cc(-c4ccc(-c5nc(-c6ccccc6)nc(-c6ccc7oc8ccccc8c7c6)n5)cc4)ccc3c2)cc1 ; c1ccc2cc(-c3nc(-c4ccc5c(ccc6ccccc65)c4)nc(-c4ccc5oc6ccccc6c5c4)n3)ccc2c1]

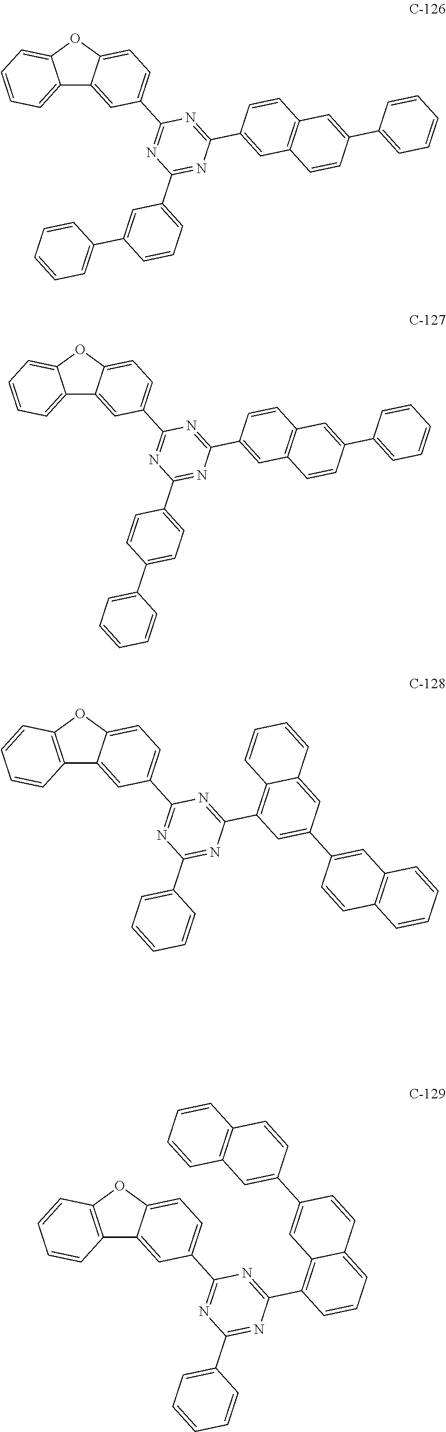 [SMILES: c1ccc(-c2cccc(-c3nc(-c4ccc5cc(-c6ccccc6)ccc5c4)nc(-c4ccc5oc6ccccc6c5c4)n3)c2)cc1 ; c1ccc(-c2ccc(-c3nc(-c4ccc5cc(-c6ccccc6)ccc5c4)nc(-c4ccc5oc6ccccc6c5c4)n3)cc2)cc1 ; c1ccc(-c2nc(-c3ccc4oc5ccccc5c4c3)nc(-c3cc(-c4ccc5ccccc5c4)cc4ccccc34)n2)cc1 ; c1ccc(-c2nc(-c3ccc4oc5ccccc5c4c3)nc(-c3cccc4ccc(-c5ccc6ccccc6c5)cc34)n2)cc1]

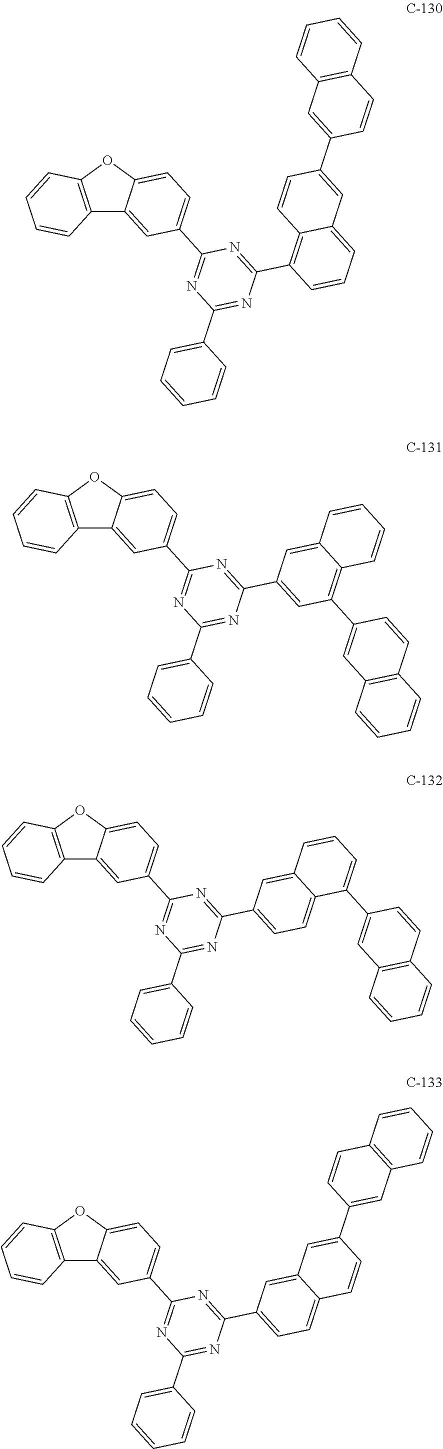 [SMILES: c1ccc(-c2nc(-c3ccc4oc5ccccc5c4c3)nc(-c3cccc4cc(-c5ccc6ccccc6c5)ccc34)n2)cc1 ; c1ccc(-c2nc(-c3cc(-c4ccc5ccccc5c4)c4ccccc4c3)nc(-c3ccc4oc5ccccc5c4c3)n2)cc1 ; c1ccc(-c2nc(-c3ccc4c(-c5ccc6ccccc6c5)cccc4c3)nc(-c3ccc4oc5ccccc5c4c3)n2)cc1 ; c1ccc(-c2nc(-c3ccc4ccc(-c5ccc6ccccc6c5)cc4c3)nc(-c3ccc4oc5ccccc5c4c3)n2)cc1]

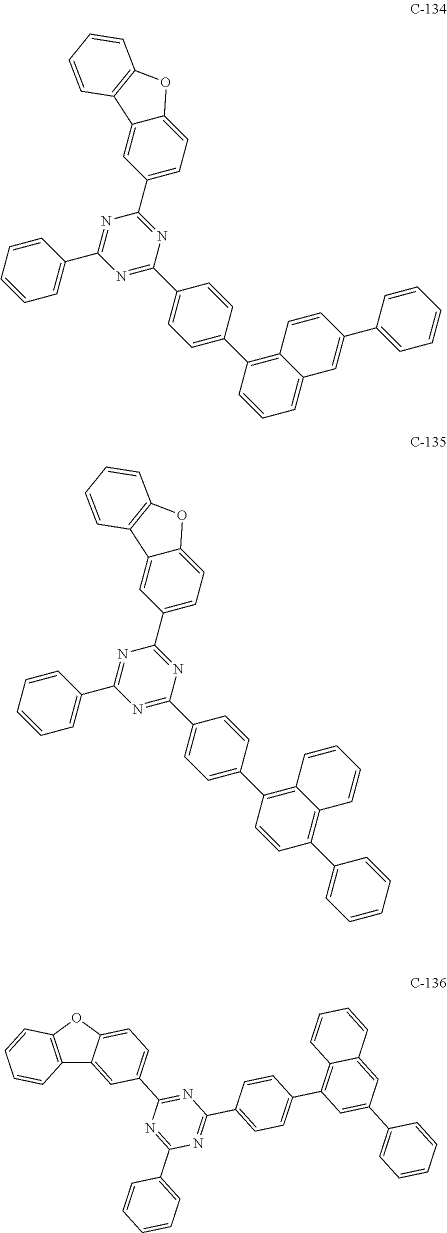 [SMILES: c1ccc(-c2ccc3c(-c4ccc(-c5nc(-c6ccccc6)nc(-c6ccc7oc8ccccc8c7c6)n5)cc4)cccc3c2)cc1 ; c1ccc(-c2nc(-c3ccc(-c4ccc(-c5ccccc5)c5ccccc45)cc3)nc(-c3ccc4oc5ccccc5c4c3)n2)cc1 ; c1ccc(-c2cc(-c3ccc(-c4nc(-c5ccccc5)nc(-c5ccc6oc7ccccc7c6c5)n4)cc3)c3ccccc3c2)cc1]

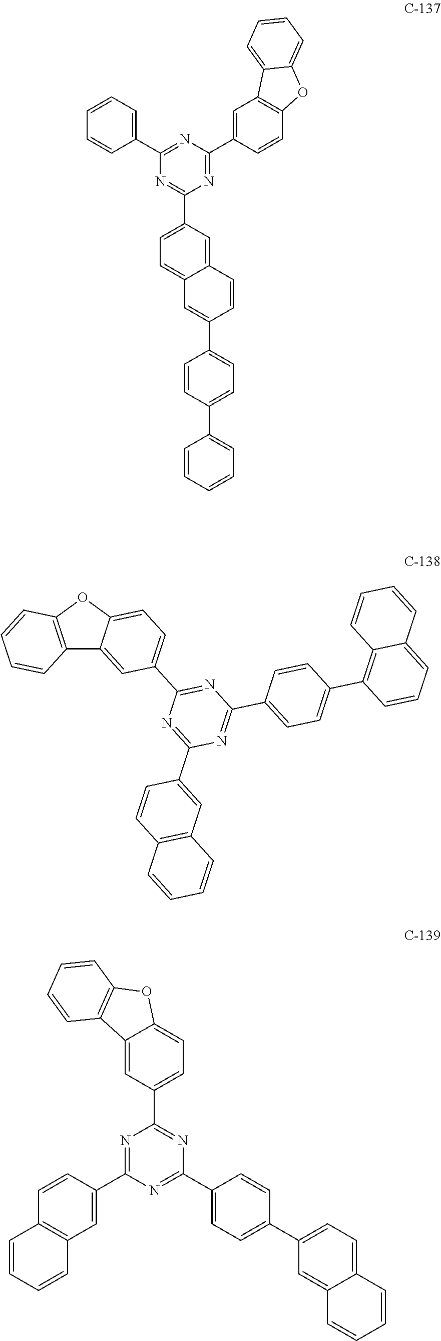 [SMILES: c1ccc(-c2ccc(-c3ccc4cc(-c5nc(-c6ccccc6)nc(-c6ccc7oc8ccccc8c7c6)n5)ccc4c3)cc2)cc1 ; c1ccc2cc(-c3nc(-c4ccc(-c5cccc6ccccc56)cc4)nc(-c4ccc5oc6ccccc6c5c4)n3)ccc2c1 ; c1ccc2cc(-c3ccc(-c4nc(-c5ccc6ccccc6c5)nc(-c5ccc6oc7ccccc7c6c5)n4)cc3)ccc2c1]

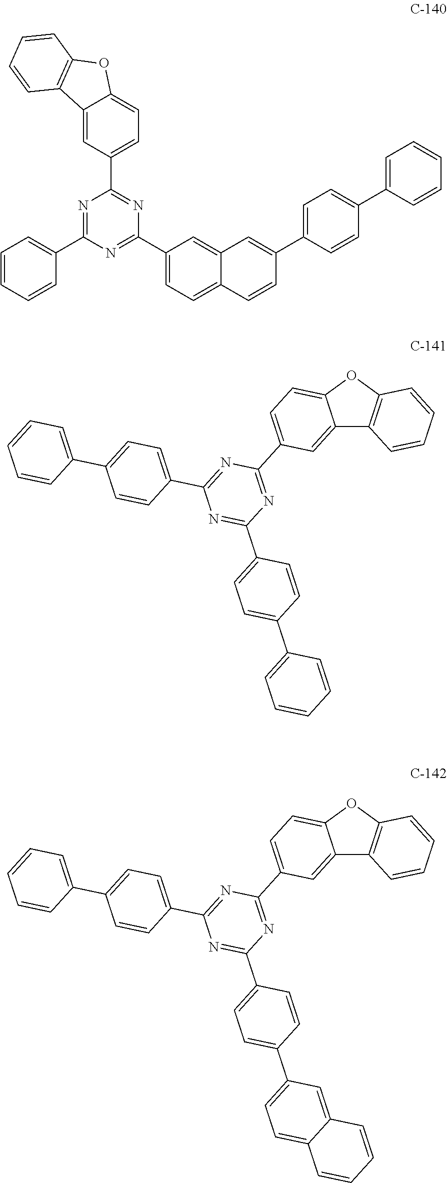 [SMILES: c1ccc(-c2ccc(-c3ccc4ccc(-c5nc(-c6ccccc6)nc(-c6ccc7oc8ccccc8c7c6)n5)cc4c3)cc2)cc1 ; c1ccc(-c2ccc(-c3nc(-c4ccc(-c5ccccc5)cc4)nc(-c4ccc5oc6ccccc6c5c4)n3)cc2)cc1 ; c1ccc(-c2ccc(-c3nc(-c4ccc(-c5ccc6ccccc6c5)cc4)nc(-c4ccc5oc6ccccc6c5c4)n3)cc2)cc1]

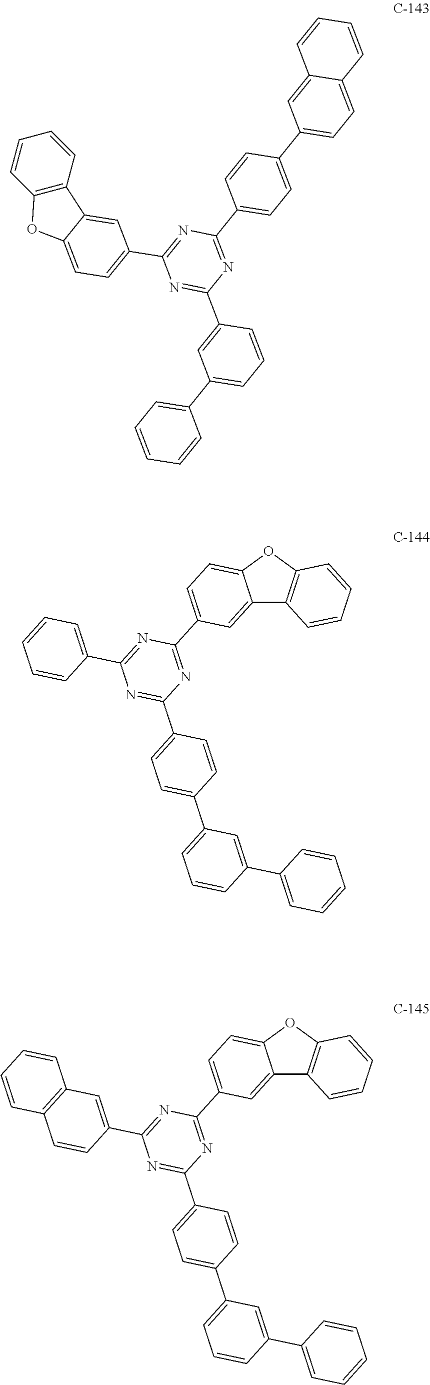 [SMILES: c1ccc(-c2cccc(-c3nc(-c4ccc(-c5ccc6ccccc6c5)cc4)nc(-c4ccc5oc6ccccc6c5c4)n3)c2)cc1 ; c1ccc(-c2cccc(-c3ccc(-c4nc(-c5ccccc5)nc(-c5ccc6oc7ccccc7c6c5)n4)cc3)c2)cc1 ; c1ccc(-c2cccc(-c3ccc(-c4nc(-c5ccc6ccccc6c5)nc(-c5ccc6oc7ccccc7c6c5)n4)cc3)c2)cc1]

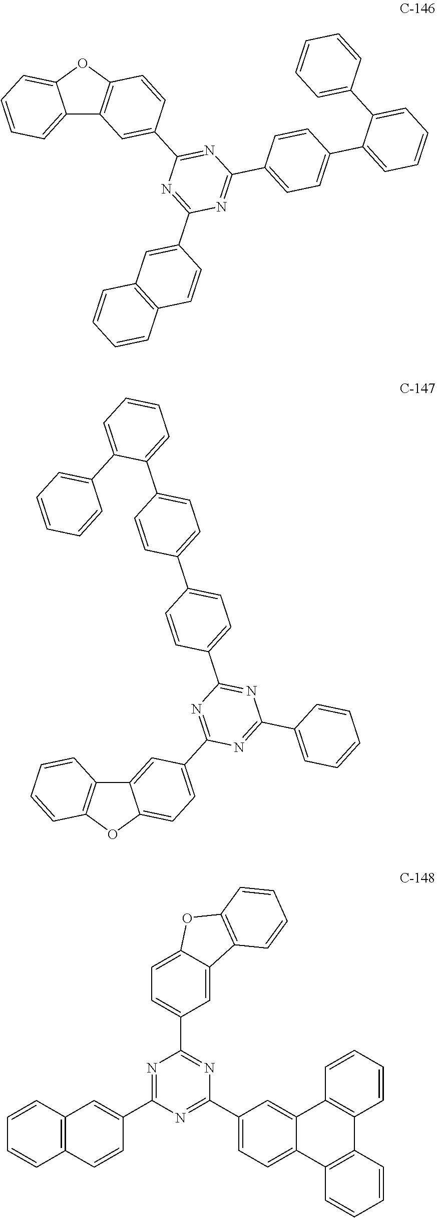 [SMILES: c1ccc(-c2ccccc2-c2ccc(-c3nc(-c4ccc5ccccc5c4)nc(-c4ccc5oc6ccccc6c5c4)n3)cc2)cc1 ; c1ccc(-c2nc(-c3ccc(-c4ccc(-c5ccccc5-c5ccccc5)cc4)cc3)nc(-c3ccc4oc5ccccc5c4c3)n2)cc1 ; c1ccc2cc(-c3nc(-c4ccc5oc6ccccc6c5c4)nc(-c4ccc5c6ccccc6c6ccccc6c5c4)n3)ccc2c1]

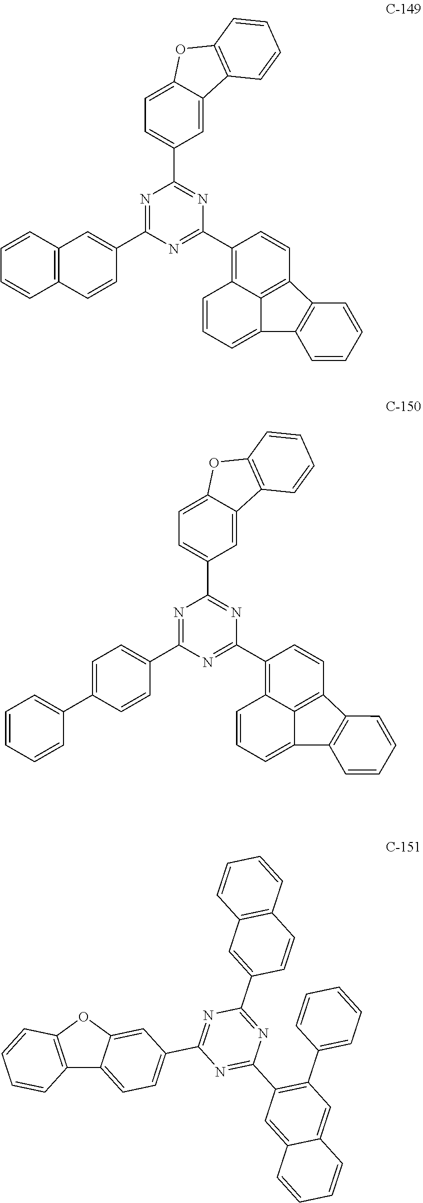 [SMILES: c1ccc2c(c1)-c1cccc3c(-c4nc(-c5ccc6ccccc6c5)nc(-c5ccc6oc7ccccc7c6c5)n4)ccc-2c13 ; c1ccc(-c2ccc(-c3nc(-c4ccc5oc6ccccc6c5c4)nc(-c4ccc5c6c(cccc46)-c4ccccc4-5)n3)cc2)cc1 ; c1ccc(-c2cc3ccccc3cc2-c2nc(-c3ccc4ccccc4c3)nc(-c3ccc4c(c3)oc3ccccc34)n2)cc1]

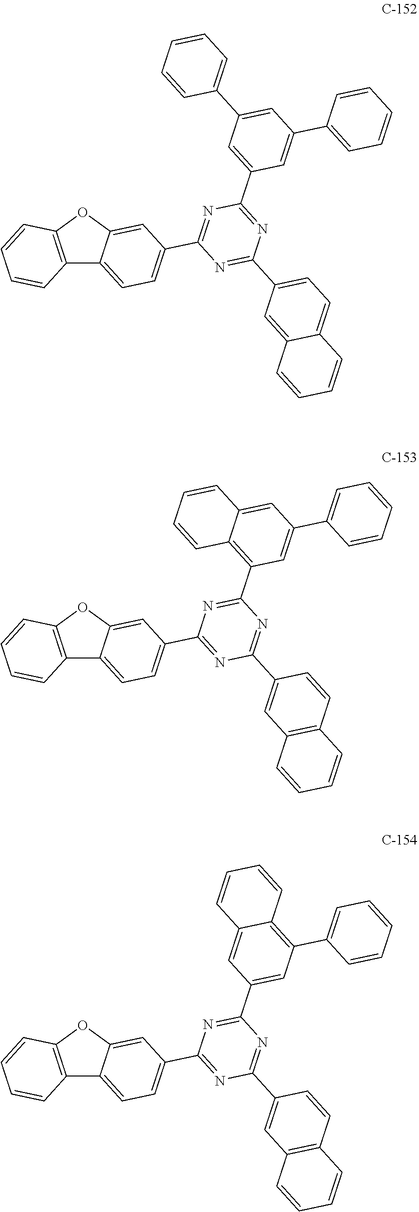 [SMILES: c1ccc(-c2cc(-c3ccccc3)cc(-c3nc(-c4ccc5ccccc5c4)nc(-c4ccc5c(c4)oc4ccccc45)n3)c2)cc1 ; c1ccc(-c2cc(-c3nc(-c4ccc5ccccc5c4)nc(-c4ccc5c(c4)oc4ccccc45)n3)c3ccccc3c2)cc1 ; c1ccc(-c2cc(-c3nc(-c4ccc5ccccc5c4)nc(-c4ccc5c(c4)oc4ccccc45)n3)cc3ccccc23)cc1]

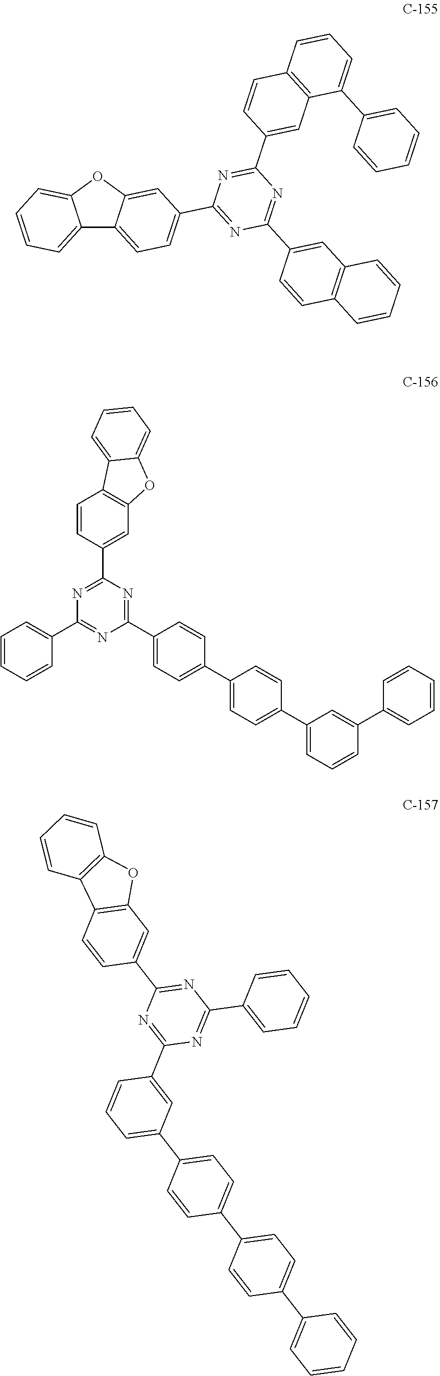 [SMILES: c1ccc(-c2cccc3ccc(-c4nc(-c5ccc6ccccc6c5)nc(-c5ccc6c(c5)oc5ccccc56)n4)cc23)cc1 ; c1ccc(-c2cccc(-c3ccc(-c4ccc(-c5nc(-c6ccccc6)nc(-c6ccc7c(c6)oc6ccccc67)n5)cc4)cc3)c2)cc1 ; c1ccc(-c2ccc(-c3ccc(-c4cccc(-c5nc(-c6ccccc6)nc(-c6ccc7c(c6)oc6ccccc67)n5)c4)cc3)cc2)cc1]

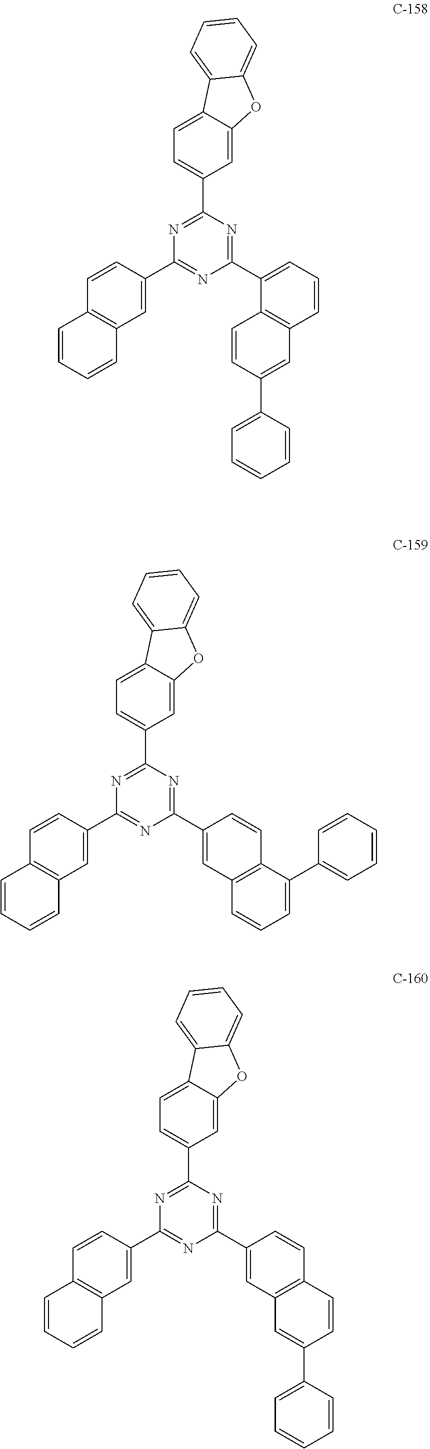 [SMILES: c1ccc(-c2ccc3c(-c4nc(-c5ccc6ccccc6c5)nc(-c5ccc6c(c5)oc5ccccc56)n4)cccc3c2)cc1 ; c1ccc(-c2cccc3cc(-c4nc(-c5ccc6ccccc6c5)nc(-c5ccc6c(c5)oc5ccccc56)n4)ccc23)cc1 ; c1ccc(-c2ccc3ccc(-c4nc(-c5ccc6ccccc6c5)nc(-c5ccc6c(c5)oc5ccccc56)n4)cc3c2)cc1]

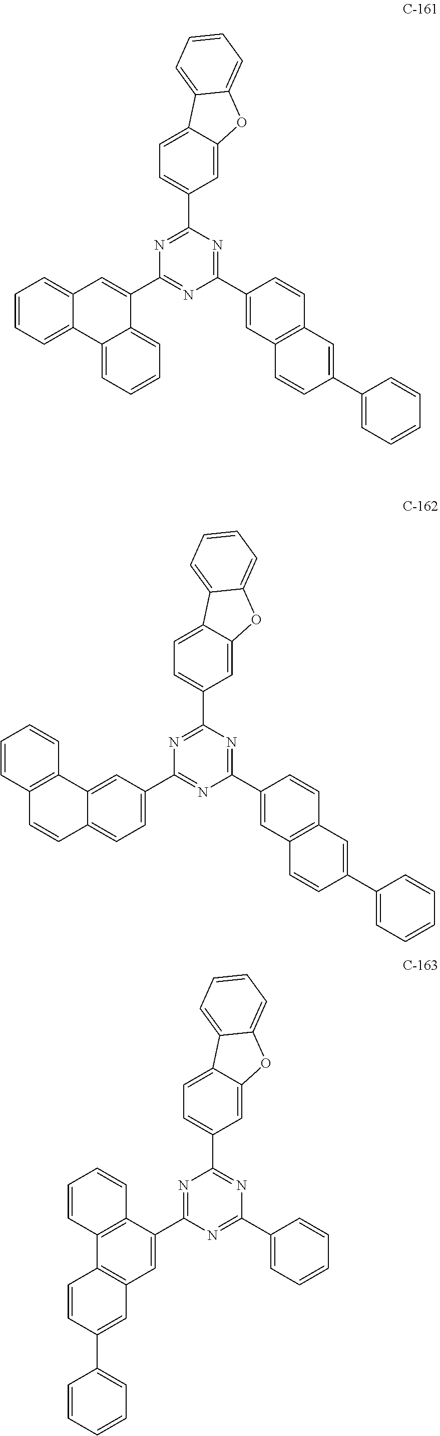 [SMILES: c1ccc(-c2ccc3cc(-c4nc(-c5ccc6c(c5)oc5ccccc56)nc(-c5cc6ccccc6c6ccccc56)n4)ccc3c2)cc1 ; c1ccc(-c2ccc3cc(-c4nc(-c5ccc6c(c5)oc5ccccc56)nc(-c5ccc6ccc7ccccc7c6c5)n4)ccc3c2)cc1 ; c1ccc(-c2ccc3c(c2)cc(-c2nc(-c4ccccc4)nc(-c4ccc5c(c4)oc4ccccc45)n2)c2ccccc23)cc1]

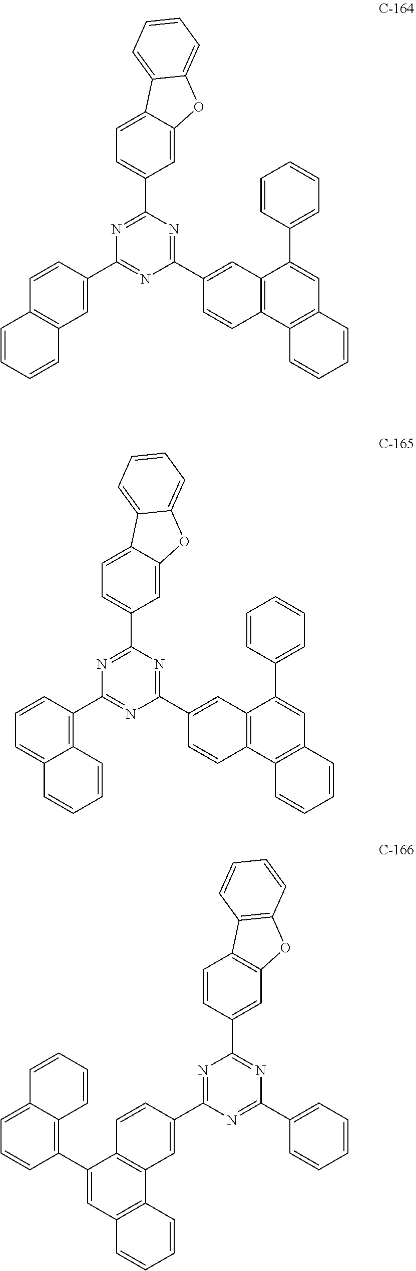 [SMILES: c1ccc(-c2cc3ccccc3c3ccc(-c4nc(-c5ccc6ccccc6c5)nc(-c5ccc6c(c5)oc5ccccc56)n4)cc23)cc1 ; c1ccc(-c2cc3ccccc3c3ccc(-c4nc(-c5ccc6c(c5)oc5ccccc56)nc(-c5cccc6ccccc56)n4)cc23)cc1 ; c1ccc(-c2nc(-c3ccc4c(c3)oc3ccccc34)nc(-c3ccc4c(-c5cccc6ccccc56)cc5ccccc5c4c3)n2)cc1]

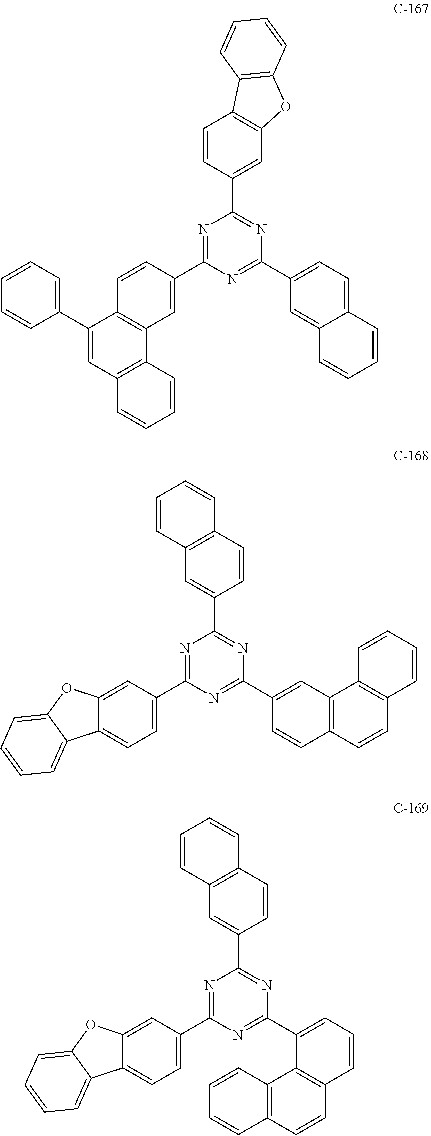 [SMILES: c1ccc(-c2cc3ccccc3c3cc(-c4nc(-c5ccc6ccccc6c5)nc(-c5ccc6c(c5)oc5ccccc56)n4)ccc23)cc1 ; c1ccc2cc(-c3nc(-c4ccc5c(c4)oc4ccccc45)nc(-c4ccc5ccc6ccccc6c5c4)n3)ccc2c1 ; c1ccc2cc(-c3nc(-c4ccc5c(c4)oc4ccccc45)nc(-c4cccc5ccc6ccccc6c45)n3)ccc2c1]

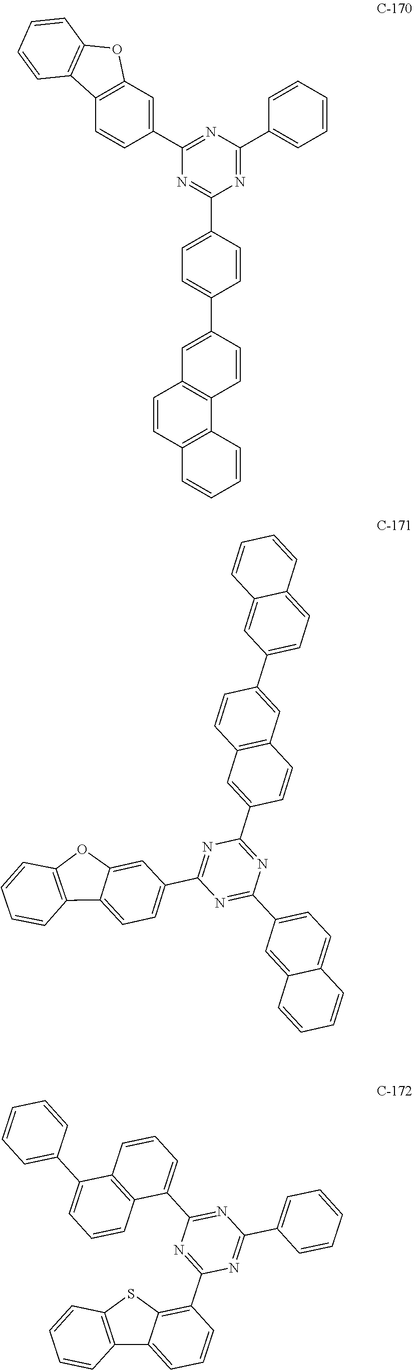 [SMILES: c1ccc(-c2nc(-c3ccc(-c4ccc5c(ccc6ccccc65)c4)cc3)nc(-c3ccc4c(c3)oc3ccccc34)n2)cc1 ; c1ccc2cc(-c3ccc4cc(-c5nc(-c6ccc7ccccc7c6)nc(-c6ccc7c(c6)oc6ccccc67)n5)ccc4c3)ccc2c1 ; c1ccc(-c2nc(-c3cccc4c(-c5ccccc5)cccc34)nc(-c3cccc4c3sc3ccccc34)n2)cc1]

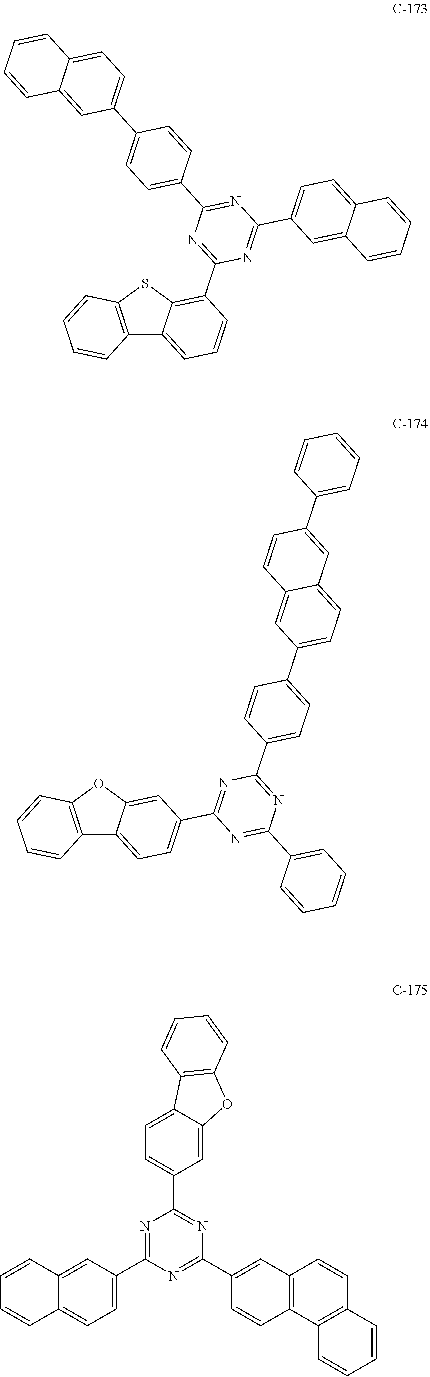 [SMILES: c1ccc2cc(-c3ccc(-c4nc(-c5ccc6ccccc6c5)nc(-c5cccc6c5sc5ccccc56)n4)cc3)ccc2c1 ; c1ccc(-c2ccc3cc(-c4ccc(-c5nc(-c6ccccc6)nc(-c6ccc7c(c6)oc6ccccc67)n5)cc4)ccc3c2)cc1 ; c1ccc2cc(-c3nc(-c4ccc5c(ccc6ccccc65)c4)nc(-c4ccc5c(c4)oc4ccccc45)n3)ccc2c1]

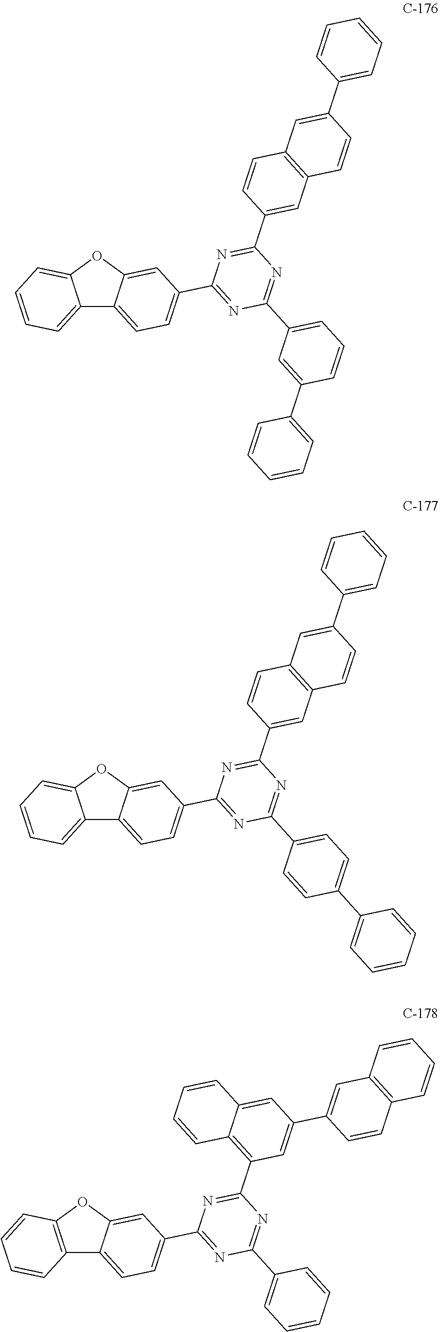 [SMILES: c1ccc(-c2cccc(-c3nc(-c4ccc5cc(-c6ccccc6)ccc5c4)nc(-c4ccc5c(c4)oc4ccccc45)n3)c2)cc1 ; c1ccc(-c2ccc(-c3nc(-c4ccc5cc(-c6ccccc6)ccc5c4)nc(-c4ccc5c(c4)oc4ccccc45)n3)cc2)cc1 ; c1ccc(-c2nc(-c3ccc4c(c3)oc3ccccc34)nc(-c3cc(-c4ccc5ccccc5c4)cc4ccccc34)n2)cc1]

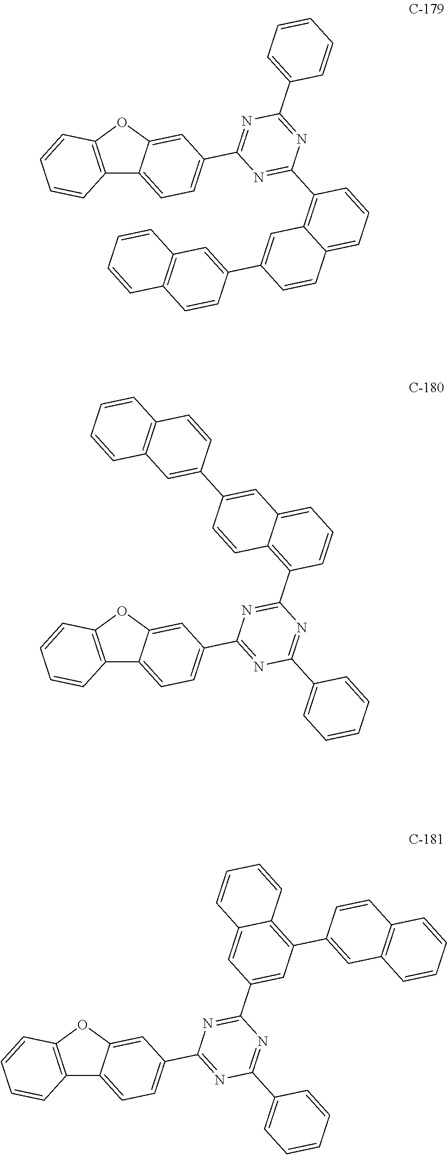 [SMILES: c1ccc(-c2nc(-c3ccc4c(c3)oc3ccccc34)nc(-c3cccc4ccc(-c5ccc6ccccc6c5)cc34)n2)cc1 ; c1ccc(-c2nc(-c3ccc4c(c3)oc3ccccc34)nc(-c3cccc4cc(-c5ccc6ccccc6c5)ccc34)n2)cc1 ; c1ccc(-c2nc(-c3cc(-c4ccc5ccccc5c4)c4ccccc4c3)nc(-c3ccc4c(c3)oc3ccccc34)n2)cc1]

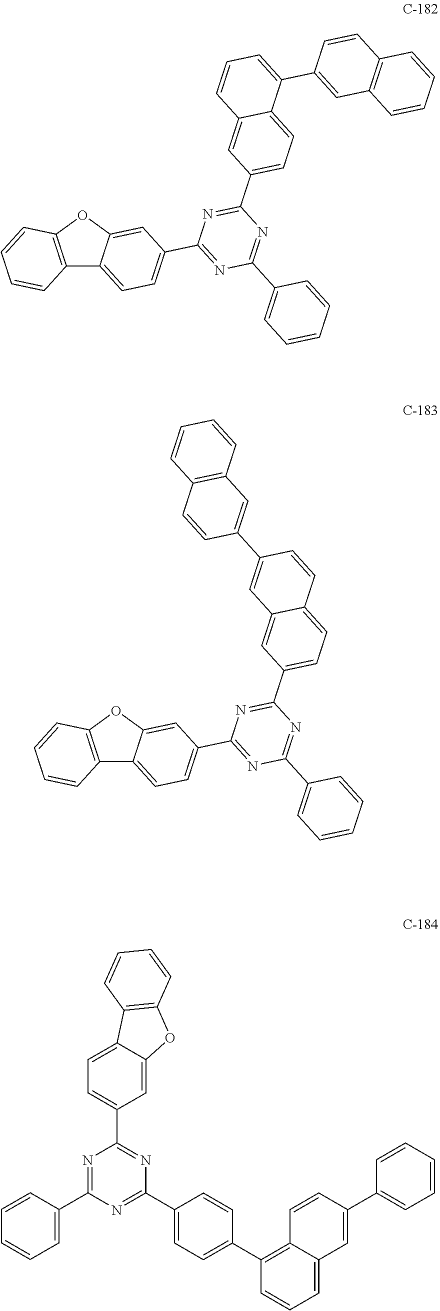 [SMILES: c1ccc(-c2nc(-c3ccc4c(-c5ccc6ccccc6c5)cccc4c3)nc(-c3ccc4c(c3)oc3ccccc34)n2)cc1 ; c1ccc(-c2nc(-c3ccc4ccc(-c5ccc6ccccc6c5)cc4c3)nc(-c3ccc4c(c3)oc3ccccc34)n2)cc1 ; c1ccc(-c2ccc3c(-c4ccc(-c5nc(-c6ccccc6)nc(-c6ccc7c(c6)oc6ccccc67)n5)cc4)cccc3c2)cc1]

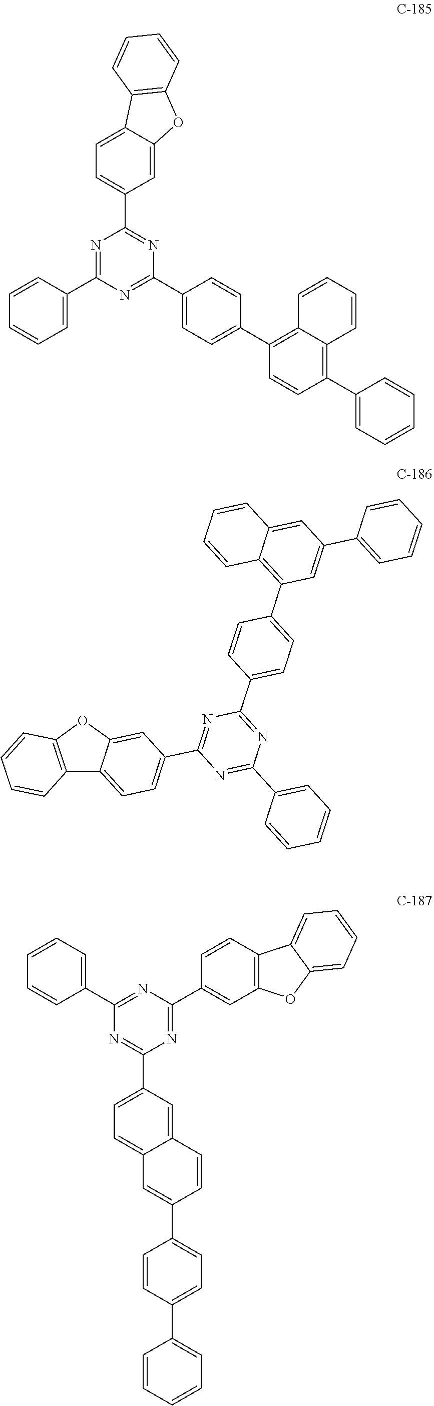 [SMILES: c1ccc(-c2nc(-c3ccc(-c4ccc(-c5ccccc5)c5ccccc45)cc3)nc(-c3ccc4c(c3)oc3ccccc34)n2)cc1 ; c1ccc(-c2cc(-c3ccc(-c4nc(-c5ccccc5)nc(-c5ccc6c(c5)oc5ccccc56)n4)cc3)c3ccccc3c2)cc1 ; c1ccc(-c2ccc(-c3ccc4cc(-c5nc(-c6ccccc6)nc(-c6ccc7c(c6)oc6ccccc67)n5)ccc4c3)cc2)cc1]

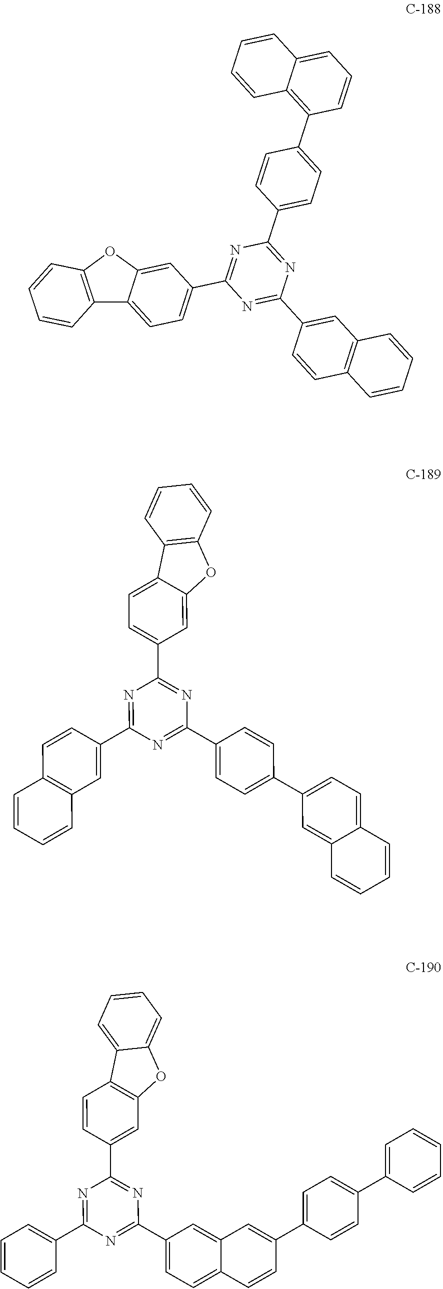 [SMILES: c1ccc2cc(-c3nc(-c4ccc(-c5cccc6ccccc56)cc4)nc(-c4ccc5c(c4)oc4ccccc45)n3)ccc2c1 ; c1ccc2cc(-c3ccc(-c4nc(-c5ccc6ccccc6c5)nc(-c5ccc6c(c5)oc5ccccc56)n4)cc3)ccc2c1 ; c1ccc(-c2ccc(-c3ccc4ccc(-c5nc(-c6ccccc6)nc(-c6ccc7c(c6)oc6ccccc67)n5)cc4c3)cc2)cc1]

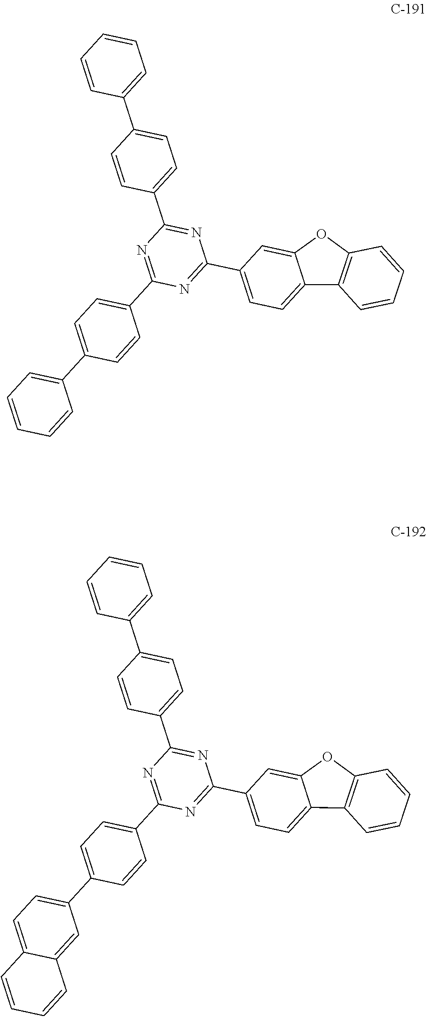 [SMILES: c1ccc(-c2ccc(-c3nc(-c4ccc(-c5ccccc5)cc4)nc(-c4ccc5c(c4)oc4ccccc45)n3)cc2)cc1 ; c1ccc(-c2ccc(-c3nc(-c4ccc(-c5ccc6ccccc6c5)cc4)nc(-c4ccc5c(c4)oc4ccccc45)n3)cc2)cc1]

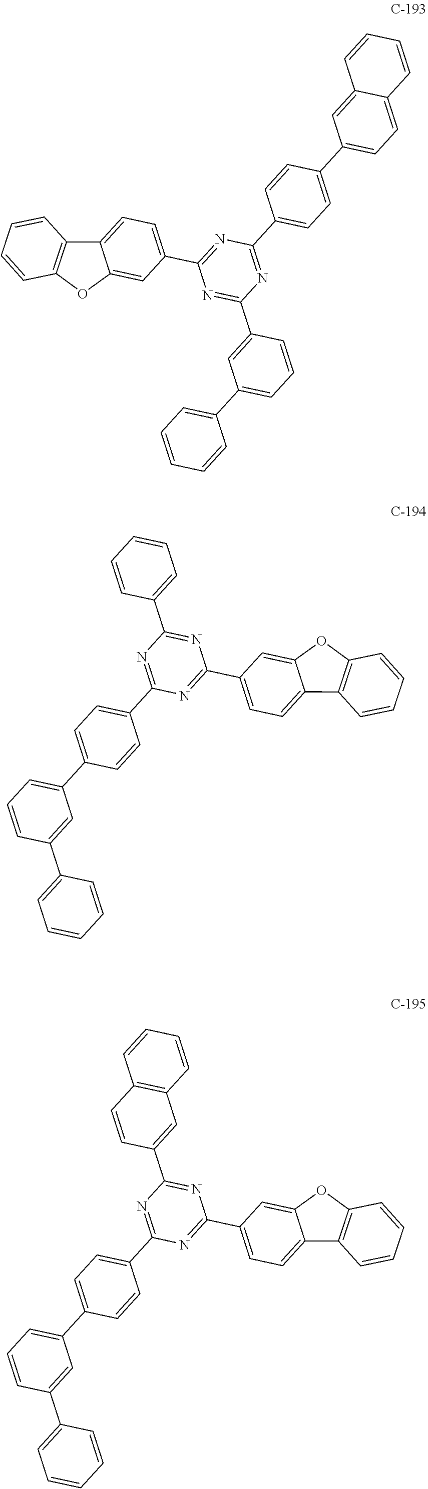 [SMILES: c1ccc(-c2cccc(-c3nc(-c4ccc(-c5ccc6ccccc6c5)cc4)nc(-c4ccc5c(c4)oc4ccccc45)n3)c2)cc1 ; c1ccc(-c2cccc(-c3ccc(-c4nc(-c5ccccc5)nc(-c5ccc6c(c5)oc5ccccc56)n4)cc3)c2)cc1 ; c1ccc(-c2cccc(-c3ccc(-c4nc(-c5ccc6ccccc6c5)nc(-c5ccc6c(c5)oc5ccccc56)n4)cc3)c2)cc1]

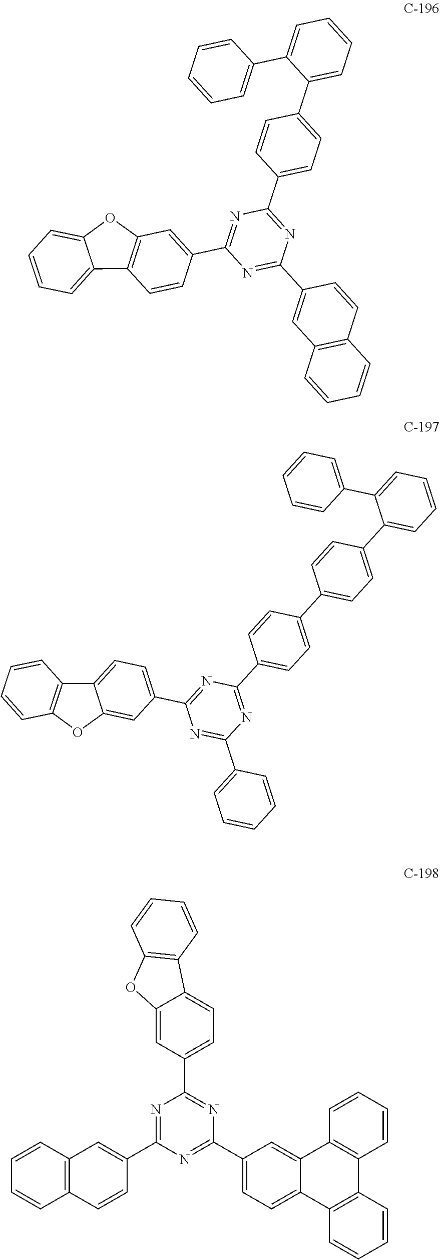 [SMILES: c1ccc(-c2ccccc2-c2ccc(-c3nc(-c4ccc5ccccc5c4)nc(-c4ccc5c(c4)oc4ccccc45)n3)cc2)cc1 ; c1ccc(-c2nc(-c3ccc(-c4ccc(-c5ccccc5-c5ccccc5)cc4)cc3)nc(-c3ccc4c(c3)oc3ccccc34)n2)cc1 ; c1ccc2cc(-c3nc(-c4ccc5c(c4)oc4ccccc45)nc(-c4ccc5c6ccccc6c6ccccc6c5c4)n3)ccc2c1]

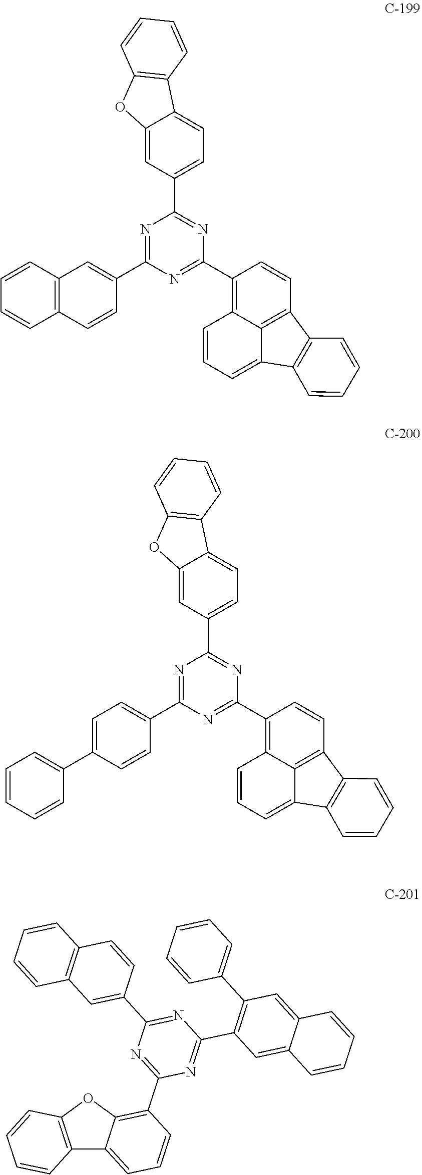 [SMILES: c1ccc2c(c1)-c1cccc3c(-c4nc(-c5ccc6ccccc6c5)nc(-c5ccc6c(c5)oc5ccccc56)n4)ccc-2c13 ; c1ccc(-c2ccc(-c3nc(-c4ccc5c(c4)oc4ccccc45)nc(-c4ccc5c6c(cccc46)-c4ccccc4-5)n3)cc2)cc1 ; c1ccc(-c2cc3ccccc3cc2-c2nc(-c3ccc4ccccc4c3)nc(-c3cccc4c3oc3ccccc34)n2)cc1]

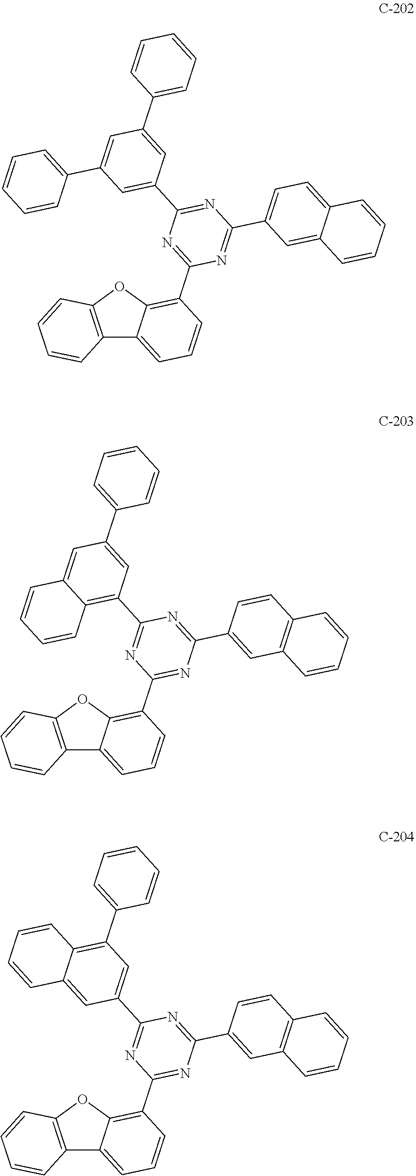 [SMILES: c1ccc(-c2cc(-c3ccccc3)cc(-c3nc(-c4ccc5ccccc5c4)nc(-c4cccc5c4oc4ccccc45)n3)c2)cc1 ; c1ccc(-c2cc(-c3nc(-c4ccc5ccccc5c4)nc(-c4cccc5c4oc4ccccc45)n3)c3ccccc3c2)cc1 ; c1ccc(-c2cc(-c3nc(-c4ccc5ccccc5c4)nc(-c4cccc5c4oc4ccccc45)n3)cc3ccccc23)cc1]

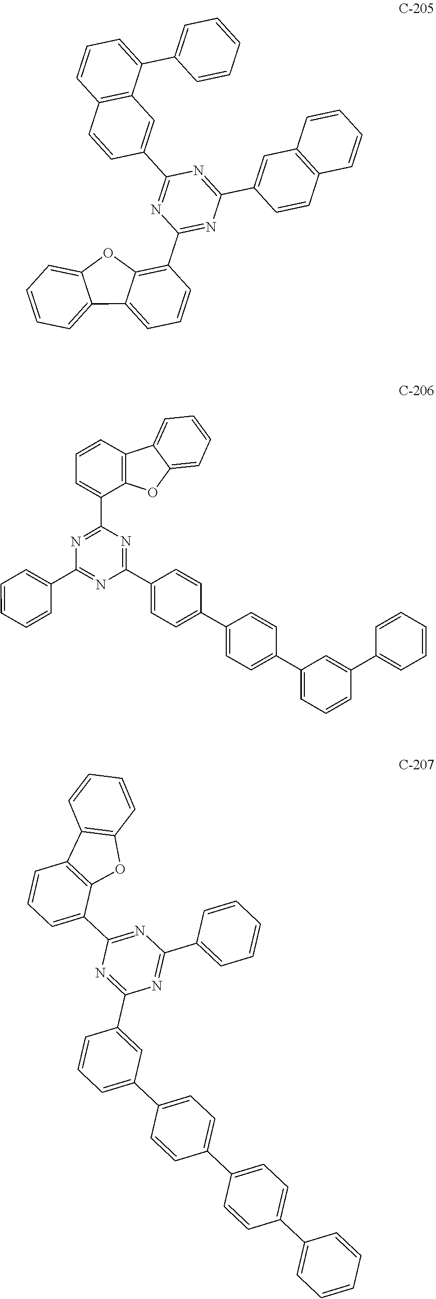 [SMILES: c1ccc(-c2cccc3ccc(-c4nc(-c5ccc6ccccc6c5)nc(-c5cccc6c5oc5ccccc56)n4)cc23)cc1 ; c1ccc(-c2cccc(-c3ccc(-c4ccc(-c5nc(-c6ccccc6)nc(-c6cccc7c6oc6ccccc67)n5)cc4)cc3)c2)cc1 ; c1ccc(-c2ccc(-c3ccc(-c4cccc(-c5nc(-c6ccccc6)nc(-c6cccc7c6oc6ccccc67)n5)c4)cc3)cc2)cc1]

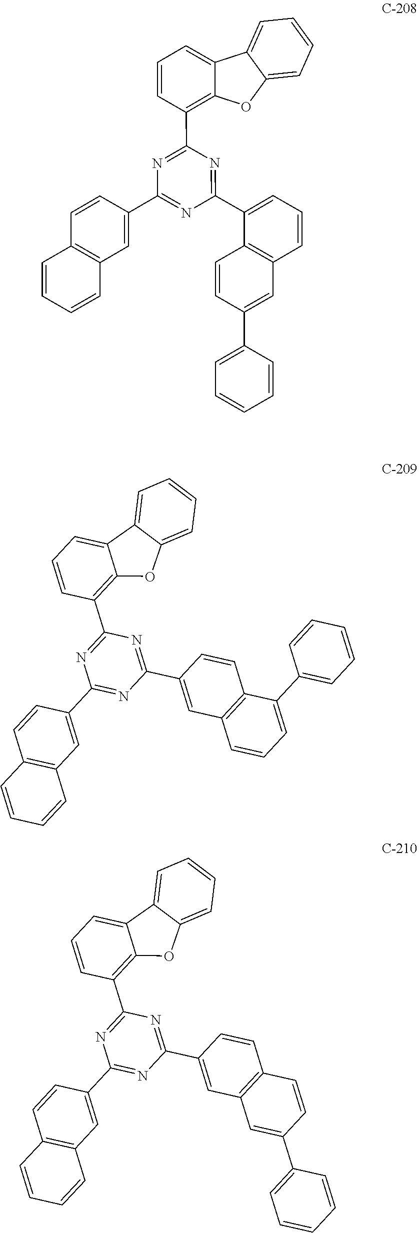 [SMILES: c1ccc(-c2ccc3c(-c4nc(-c5ccc6ccccc6c5)nc(-c5cccc6c5oc5ccccc56)n4)cccc3c2)cc1 ; c1ccc(-c2cccc3cc(-c4nc(-c5ccc6ccccc6c5)nc(-c5cccc6c5oc5ccccc56)n4)ccc23)cc1 ; c1ccc(-c2ccc3ccc(-c4nc(-c5ccc6ccccc6c5)nc(-c5cccc6c5oc5ccccc56)n4)cc3c2)cc1]

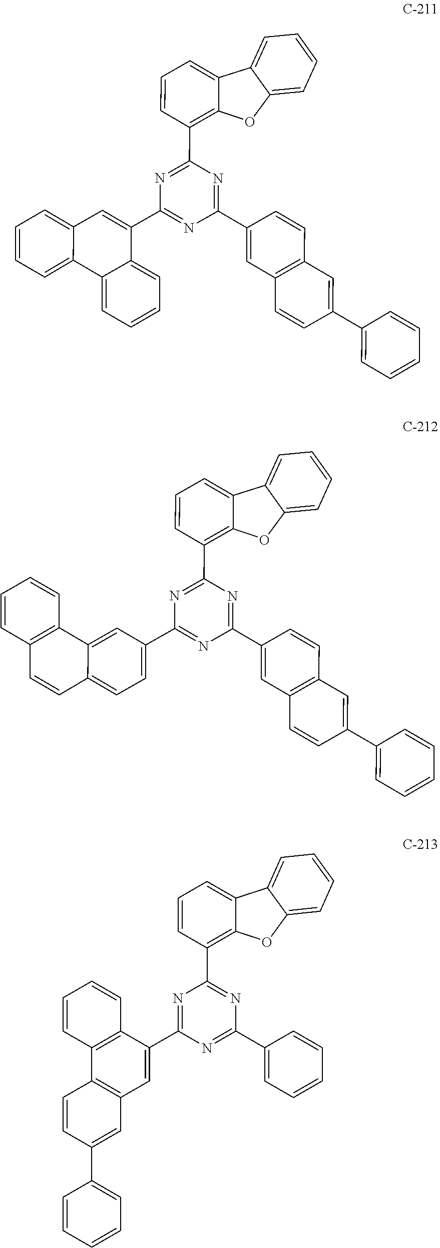 [SMILES: c1ccc(-c2ccc3cc(-c4nc(-c5cc6ccccc6c6ccccc56)nc(-c5cccc6c5oc5ccccc56)n4)ccc3c2)cc1 ; c1ccc(-c2ccc3cc(-c4nc(-c5ccc6ccc7ccccc7c6c5)nc(-c5cccc6c5oc5ccccc56)n4)ccc3c2)cc1 ; c1ccc(-c2ccc3c(c2)cc(-c2nc(-c4ccccc4)nc(-c4cccc5c4oc4ccccc45)n2)c2ccccc23)cc1]

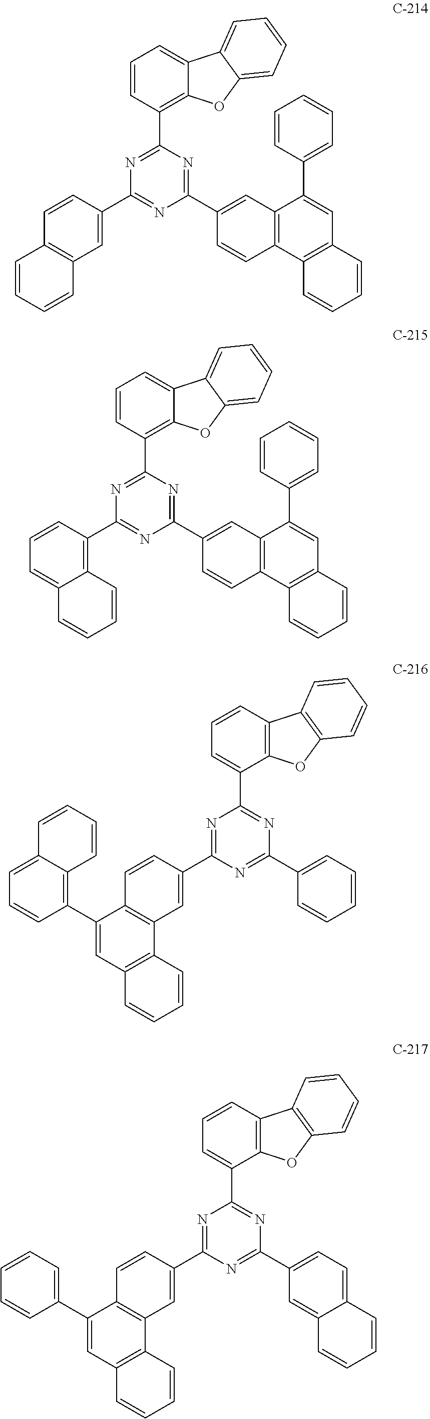

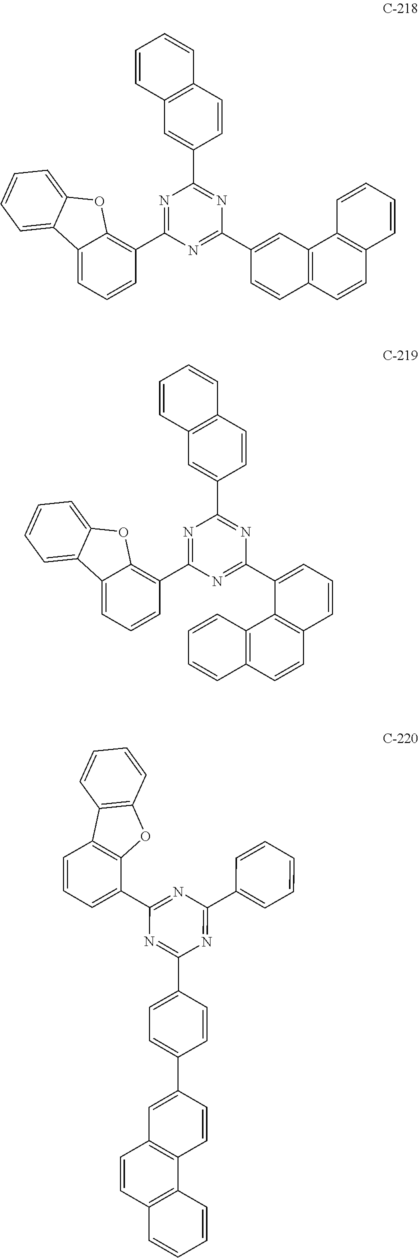 [SMILES: c1ccc2cc(-c3nc(-c4ccc5ccc6ccccc6c5c4)nc(-c4cccc5c4oc4ccccc45)n3)ccc2c1 ; c1ccc2cc(-c3nc(-c4cccc5c4oc4ccccc45)nc(-c4cccc5ccc6ccccc6c45)n3)ccc2c1 ; c1ccc(-c2nc(-c3ccc(-c4ccc5c(ccc6ccccc65)c4)cc3)nc(-c3cccc4c3oc3ccccc34)n2)cc1]

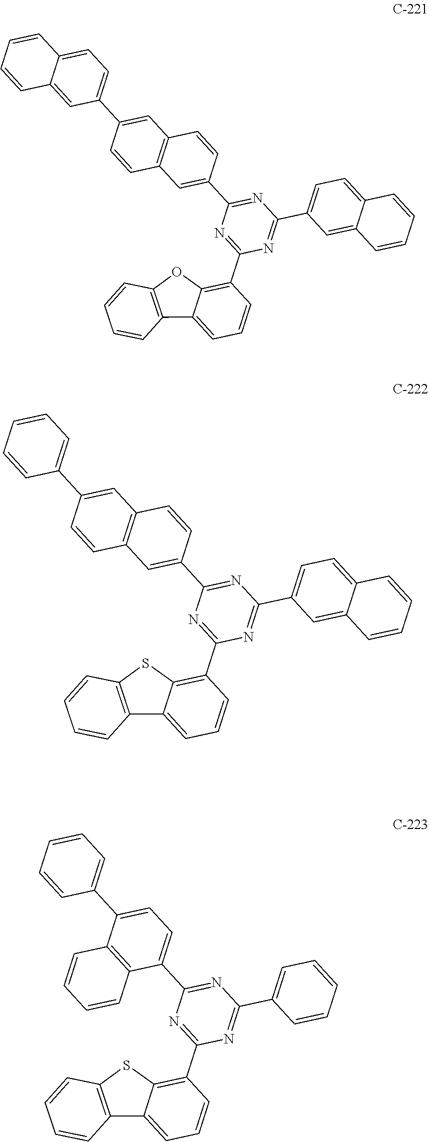 [SMILES: c1ccc2cc(-c3ccc4cc(-c5nc(-c6ccc7ccccc7c6)nc(-c6cccc7c6oc6ccccc67)n5)ccc4c3)ccc2c1 ; c1ccc(-c2ccc3cc(-c4nc(-c5ccc6ccccc6c5)nc(-c5cccc6c5sc5ccccc56)n4)ccc3c2)cc1 ; c1ccc(-c2nc(-c3ccc(-c4ccccc4)c4ccccc34)nc(-c3cccc4c3sc3ccccc34)n2)cc1]

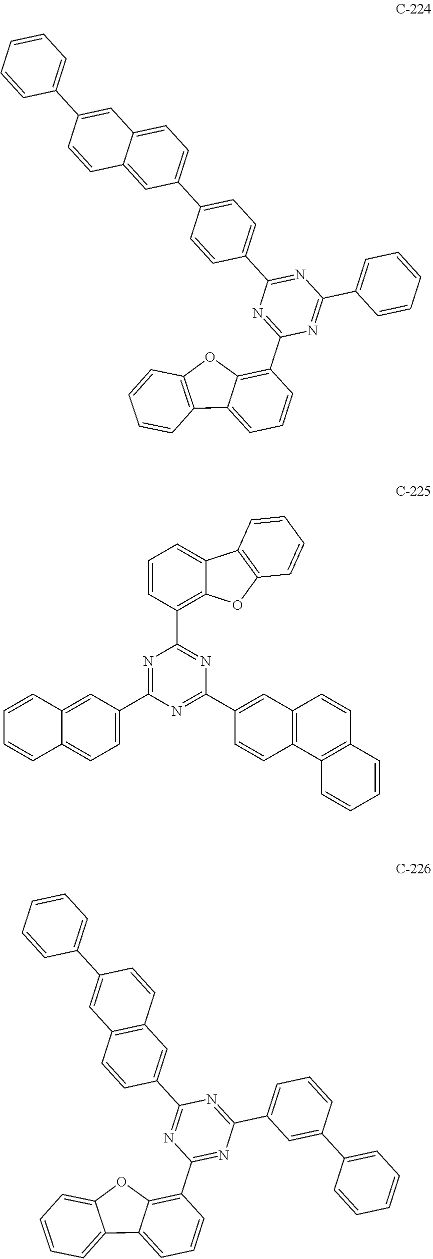 [SMILES: c1ccc(-c2ccc3cc(-c4ccc(-c5nc(-c6ccccc6)nc(-c6cccc7c6oc6ccccc67)n5)cc4)ccc3c2)cc1 ; c1ccc2cc(-c3nc(-c4ccc5c(ccc6ccccc65)c4)nc(-c4cccc5c4oc4ccccc45)n3)ccc2c1 ; c1ccc(-c2cccc(-c3nc(-c4ccc5cc(-c6ccccc6)ccc5c4)nc(-c4cccc5c4oc4ccccc45)n3)c2)cc1]

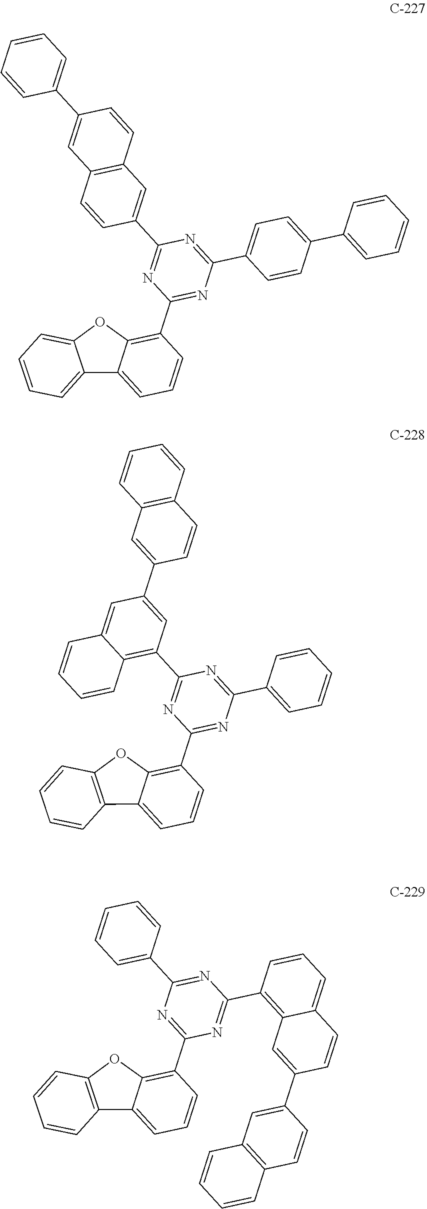 [SMILES: c1ccc(-c2ccc(-c3nc(-c4ccc5cc(-c6ccccc6)ccc5c4)nc(-c4cccc5c4oc4ccccc45)n3)cc2)cc1 ; c1ccc(-c2nc(-c3cc(-c4ccc5ccccc5c4)cc4ccccc34)nc(-c3cccc4c3oc3ccccc34)n2)cc1 ; c1ccc(-c2nc(-c3cccc4ccc(-c5ccc6ccccc6c5)cc34)nc(-c3cccc4c3oc3ccccc34)n2)cc1]

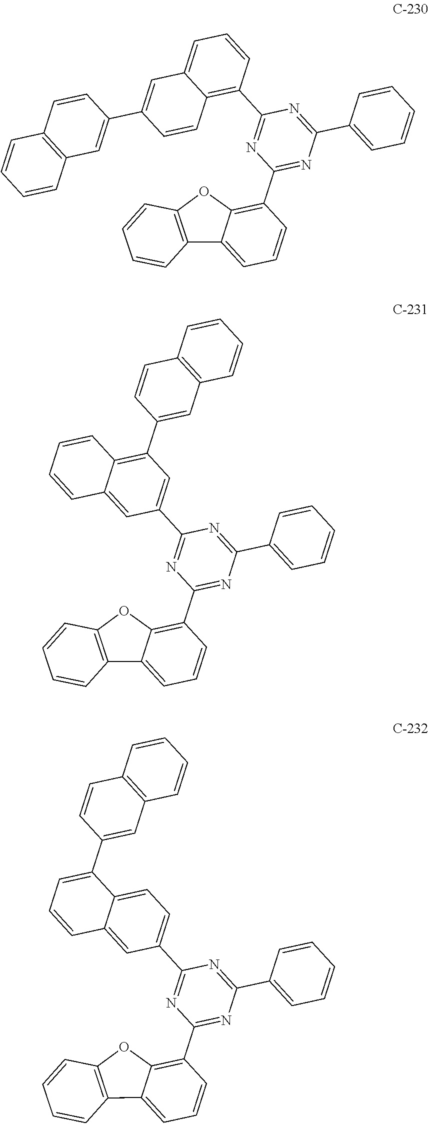 [SMILES: c1ccc(-c2nc(-c3cccc4cc(-c5ccc6ccccc6c5)ccc34)nc(-c3cccc4c3oc3ccccc34)n2)cc1 ; c1ccc(-c2nc(-c3cc(-c4ccc5ccccc5c4)c4ccccc4c3)nc(-c3cccc4c3oc3ccccc34)n2)cc1 ; c1ccc(-c2nc(-c3ccc4c(-c5ccc6ccccc6c5)cccc4c3)nc(-c3cccc4c3oc3ccccc34)n2)cc1]

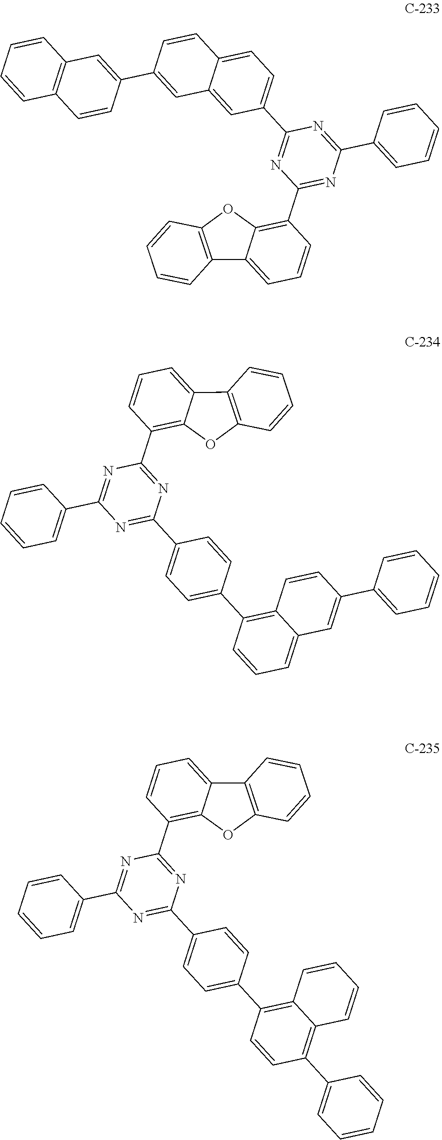 [SMILES: c1ccc(-c2nc(-c3ccc4ccc(-c5ccc6ccccc6c5)cc4c3)nc(-c3cccc4c3oc3ccccc34)n2)cc1 ; c1ccc(-c2ccc3c(-c4ccc(-c5nc(-c6ccccc6)nc(-c6cccc7c6oc6ccccc67)n5)cc4)cccc3c2)cc1 ; c1ccc(-c2nc(-c3ccc(-c4ccc(-c5ccccc5)c5ccccc45)cc3)nc(-c3cccc4c3oc3ccccc34)n2)cc1]

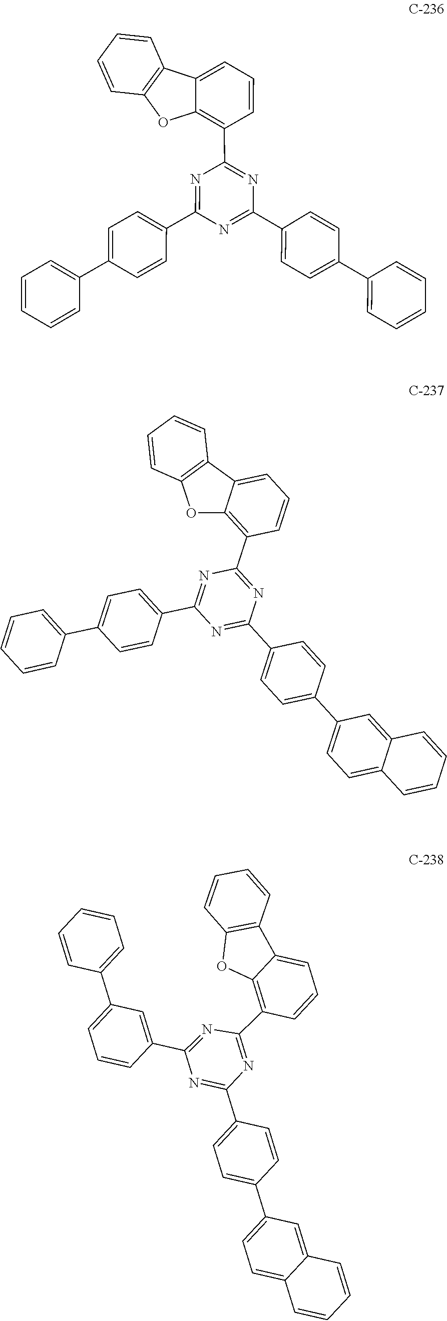 [SMILES: c1ccc(-c2ccc(-c3nc(-c4ccc(-c5ccccc5)cc4)nc(-c4cccc5c4oc4ccccc45)n3)cc2)cc1 ; c1ccc(-c2ccc(-c3nc(-c4ccc(-c5ccc6ccccc6c5)cc4)nc(-c4cccc5c4oc4ccccc45)n3)cc2)cc1 ; c1ccc(-c2cccc(-c3nc(-c4ccc(-c5ccc6ccccc6c5)cc4)nc(-c4cccc5c4oc4ccccc45)n3)c2)cc1]

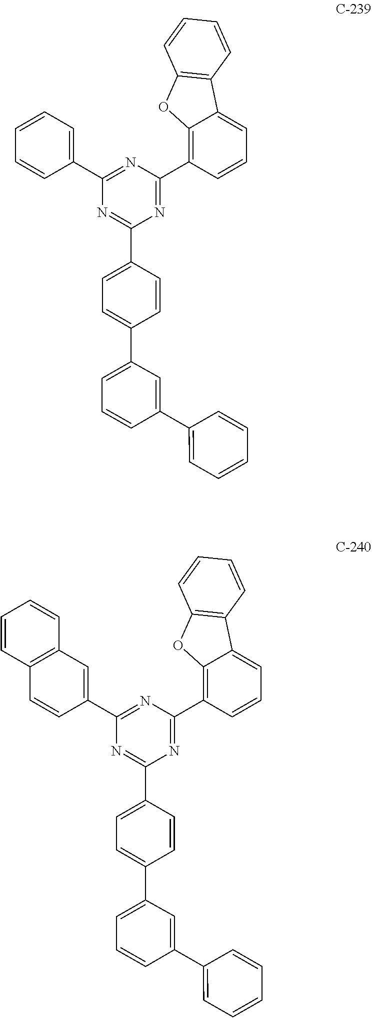 [SMILES: c1ccc(-c2cccc(-c3ccc(-c4nc(-c5ccccc5)nc(-c5cccc6c5oc5ccccc56)n4)cc3)c2)cc1 ; c1ccc(-c2cccc(-c3ccc(-c4nc(-c5ccc6ccccc6c5)nc(-c5cccc6c5oc5ccccc56)n4)cc3)c2)cc1]

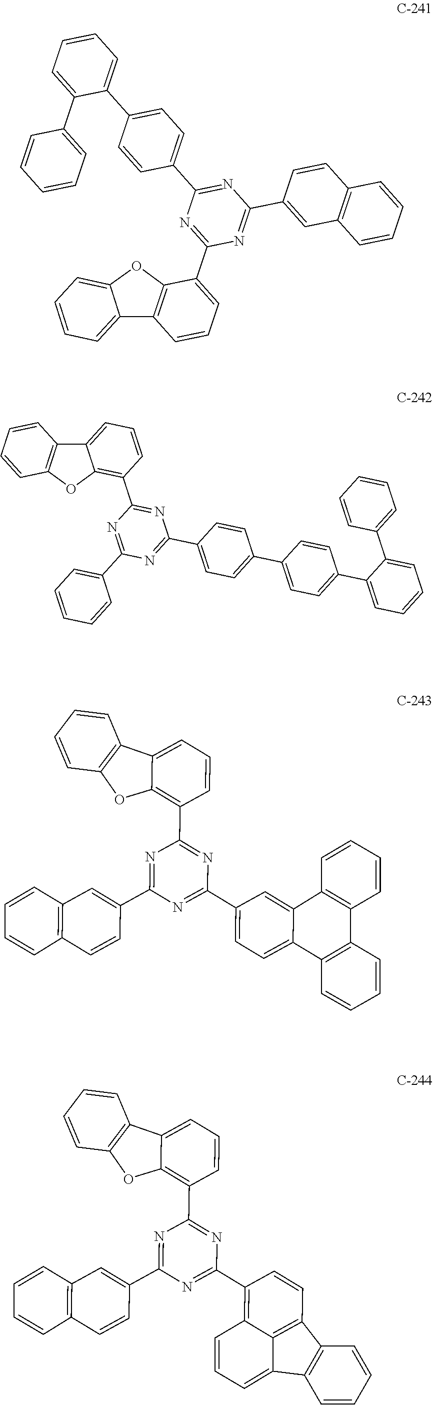 [SMILES: c1ccc(-c2ccccc2-c2ccc(-c3nc(-c4ccc5ccccc5c4)nc(-c4cccc5c4oc4ccccc45)n3)cc2)cc1 ; c1ccc(-c2nc(-c3ccc(-c4ccc(-c5ccccc5-c5ccccc5)cc4)cc3)nc(-c3cccc4c3oc3ccccc34)n2)cc1 ; c1ccc2cc(-c3nc(-c4ccc5c6ccccc6c6ccccc6c5c4)nc(-c4cccc5c4oc4ccccc45)n3)ccc2c1 ; c1ccc2c(c1)-c1cccc3c(-c4nc(-c5ccc6ccccc6c5)nc(-c5cccc6c5oc5ccccc56)n4)ccc-2c13]

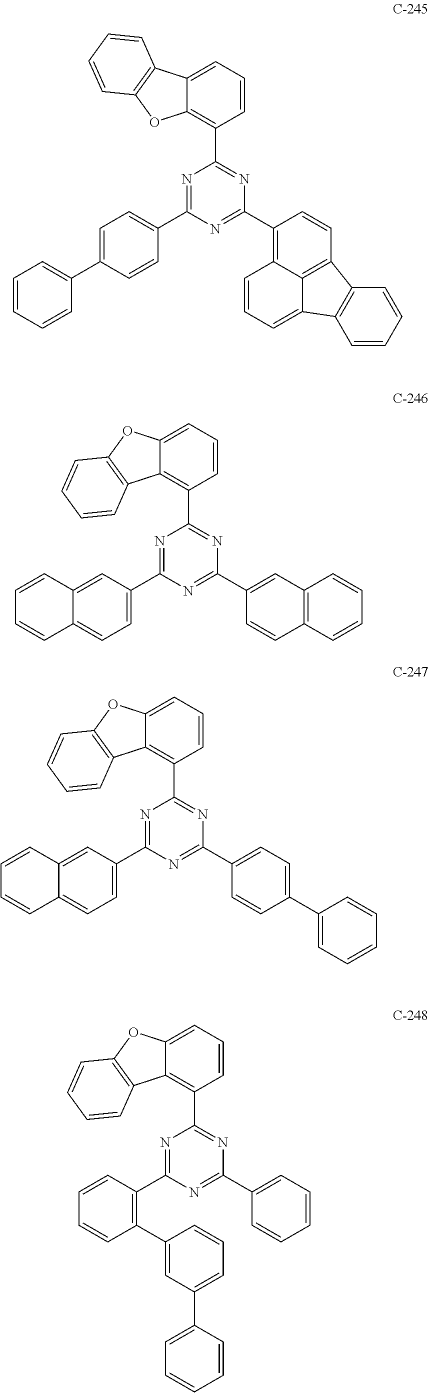 [SMILES: c1ccc(-c2ccc(-c3nc(-c4ccc5c6c(cccc46)-c4ccccc4-5)nc(-c4cccc5c4oc4ccccc45)n3)cc2)cc1 ; c1ccc2cc(-c3nc(-c4ccc5ccccc5c4)nc(-c4cccc5oc6ccccc6c45)n3)ccc2c1 ; c1ccc(-c2ccc(-c3nc(-c4ccc5ccccc5c4)nc(-c4cccc5oc6ccccc6c45)n3)cc2)cc1 ; c1ccc(-c2cccc(-c3ccccc3-c3nc(-c4ccccc4)nc(-c4cccc5oc6ccccc6c45)n3)c2)cc1]

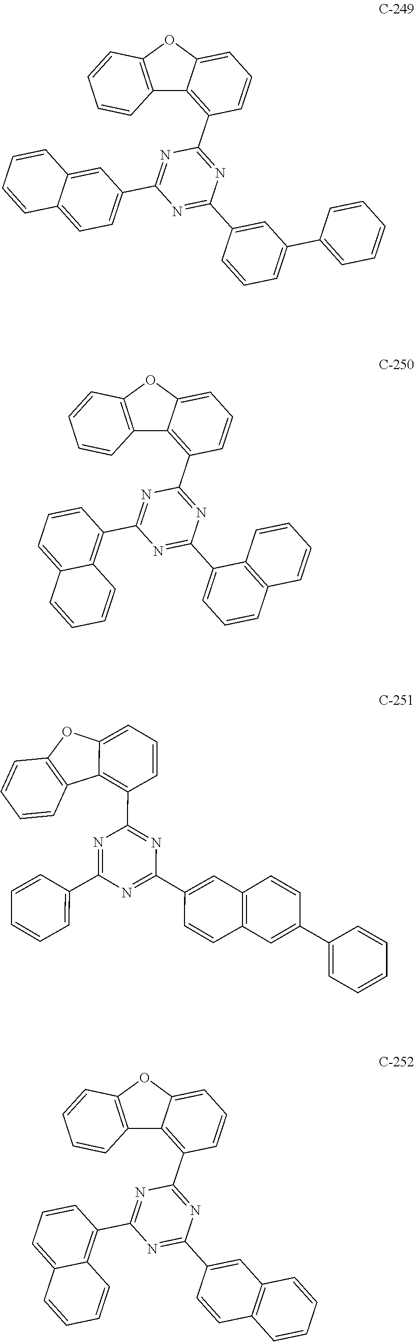 [SMILES: c1ccc(-c2cccc(-c3nc(-c4ccc5ccccc5c4)nc(-c4cccc5oc6ccccc6c45)n3)c2)cc1 ; c1ccc2c(-c3nc(-c4cccc5ccccc45)nc(-c4cccc5oc6ccccc6c45)n3)cccc2c1 ; c1ccc(-c2ccc3cc(-c4nc(-c5ccccc5)nc(-c5cccc6oc7ccccc7c56)n4)ccc3c2)cc1 ; c1ccc2cc(-c3nc(-c4cccc5ccccc45)nc(-c4cccc5oc6ccccc6c45)n3)ccc2c1]

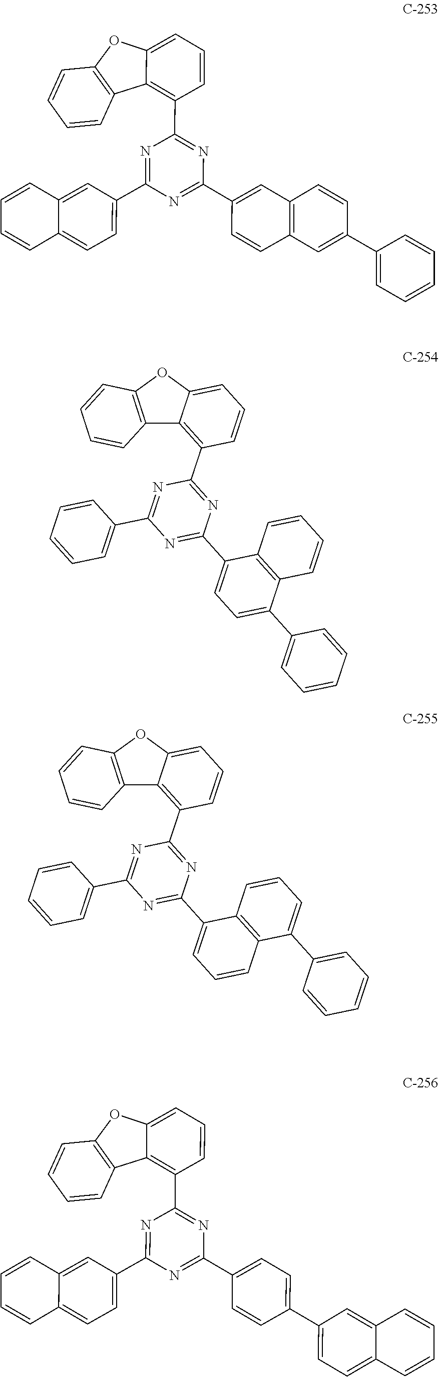 [SMILES: c1ccc(-c2ccc3cc(-c4nc(-c5ccc6ccccc6c5)nc(-c5cccc6oc7ccccc7c56)n4)ccc3c2)cc1 ; c1ccc(-c2nc(-c3ccc(-c4ccccc4)c4ccccc34)nc(-c3cccc4oc5ccccc5c34)n2)cc1 ; c1ccc(-c2nc(-c3cccc4c(-c5ccccc5)cccc34)nc(-c3cccc4oc5ccccc5c34)n2)cc1 ; c1ccc2cc(-c3ccc(-c4nc(-c5ccc6ccccc6c5)nc(-c5cccc6oc7ccccc7c56)n4)cc3)ccc2c1]

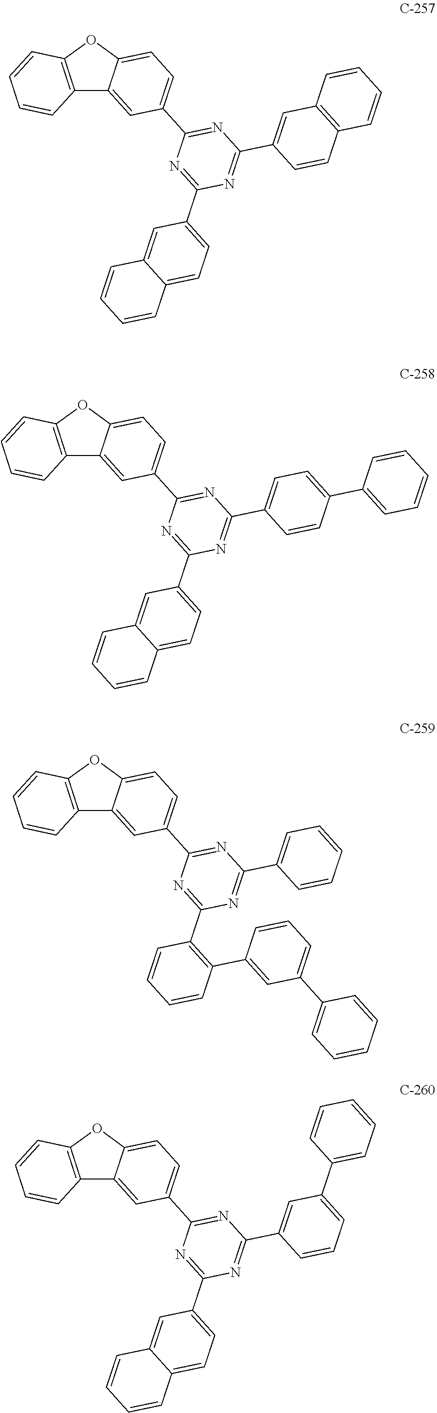

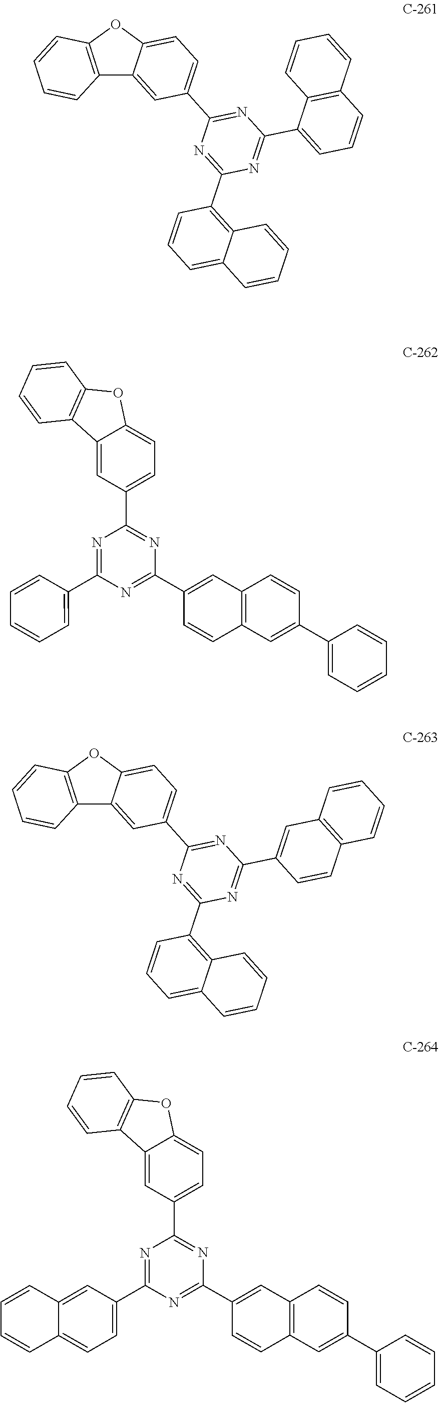 [SMILES: c1ccc2c(-c3nc(-c4ccc5oc6ccccc6c5c4)nc(-c4cccc5ccccc45)n3)cccc2c1 ; c1ccc(-c2ccc3cc(-c4nc(-c5ccccc5)nc(-c5ccc6oc7ccccc7c6c5)n4)ccc3c2)cc1 ; c1ccc2cc(-c3nc(-c4ccc5oc6ccccc6c5c4)nc(-c4cccc5ccccc45)n3)ccc2c1 ; c1ccc(-c2ccc3cc(-c4nc(-c5ccc6ccccc6c5)nc(-c5ccc6oc7ccccc7c6c5)n4)ccc3c2)cc1]

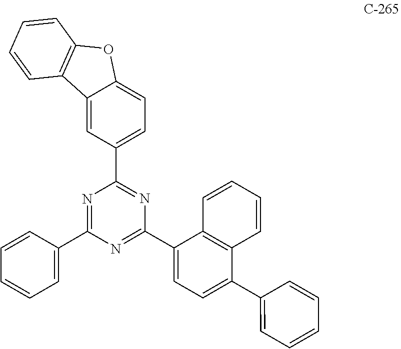 [SMILES: c1ccc(-c2nc(-c3ccc4oc5ccccc5c4c3)nc(-c3ccc(-c4ccccc4)c4ccccc34)n2)cc1]

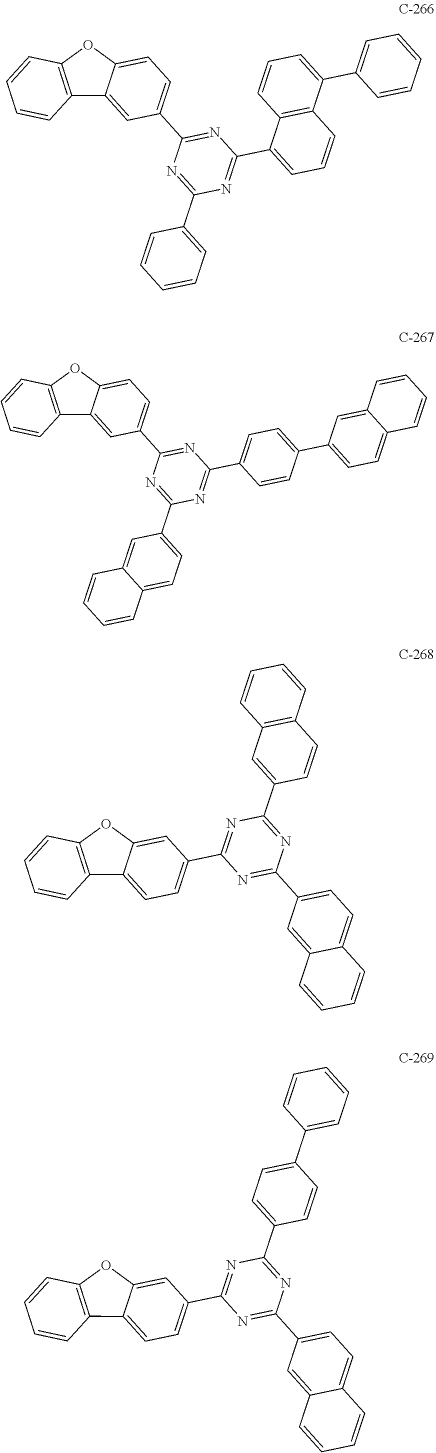 [SMILES: c1ccc(-c2nc(-c3ccc4oc5ccccc5c4c3)nc(-c3cccc4c(-c5ccccc5)cccc34)n2)cc1 ; c1ccc2cc(-c3ccc(-c4nc(-c5ccc6ccccc6c5)nc(-c5ccc6oc7ccccc7c6c5)n4)cc3)ccc2c1 ; c1ccc2cc(-c3nc(-c4ccc5ccccc5c4)nc(-c4ccc5c(c4)oc4ccccc45)n3)ccc2c1 ; c1ccc(-c2ccc(-c3nc(-c4ccc5ccccc5c4)nc(-c4ccc5c(c4)oc4ccccc45)n3)cc2)cc1]

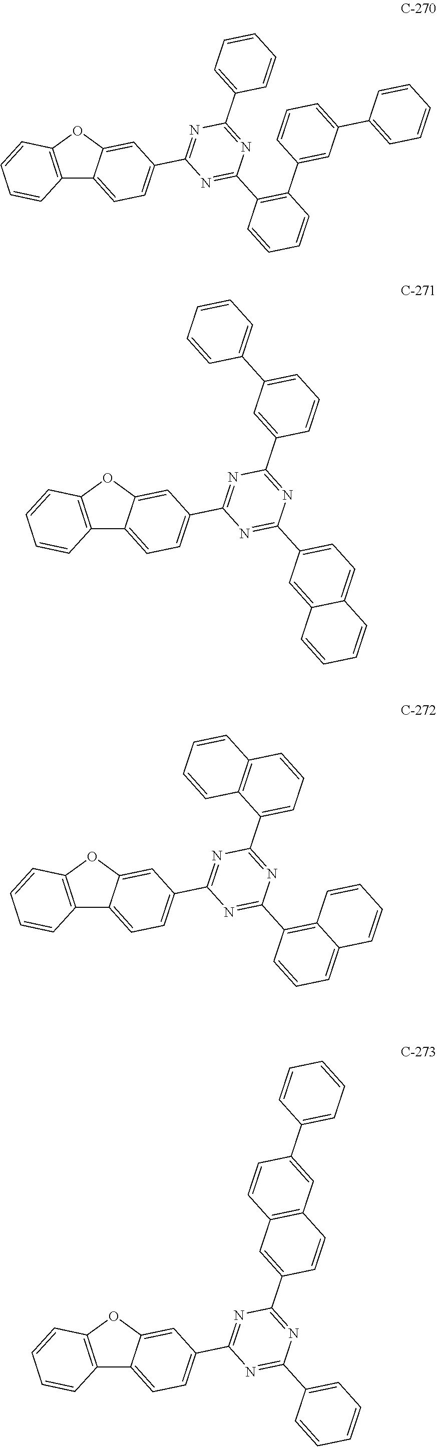 [SMILES: c1ccc(-c2cccc(-c3ccccc3-c3nc(-c4ccccc4)nc(-c4ccc5c(c4)oc4ccccc45)n3)c2)cc1 ; c1ccc(-c2cccc(-c3nc(-c4ccc5ccccc5c4)nc(-c4ccc5c(c4)oc4ccccc45)n3)c2)cc1 ; c1ccc2c(-c3nc(-c4ccc5c(c4)oc4ccccc45)nc(-c4cccc5ccccc45)n3)cccc2c1 ; c1ccc(-c2ccc3cc(-c4nc(-c5ccccc5)nc(-c5ccc6c(c5)oc5ccccc56)n4)ccc3c2)cc1]

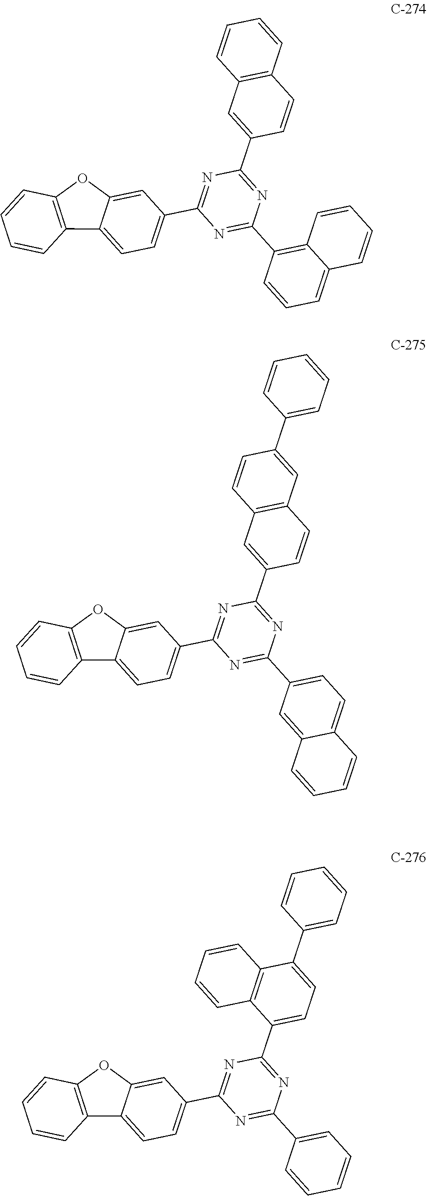 [SMILES: c1ccc2cc(-c3nc(-c4ccc5c(c4)oc4ccccc45)nc(-c4cccc5ccccc45)n3)ccc2c1 ; c1ccc(-c2ccc3cc(-c4nc(-c5ccc6ccccc6c5)nc(-c5ccc6c(c5)oc5ccccc56)n4)ccc3c2)cc1 ; c1ccc(-c2nc(-c3ccc4c(c3)oc3ccccc34)nc(-c3ccc(-c4ccccc4)c4ccccc34)n2)cc1]

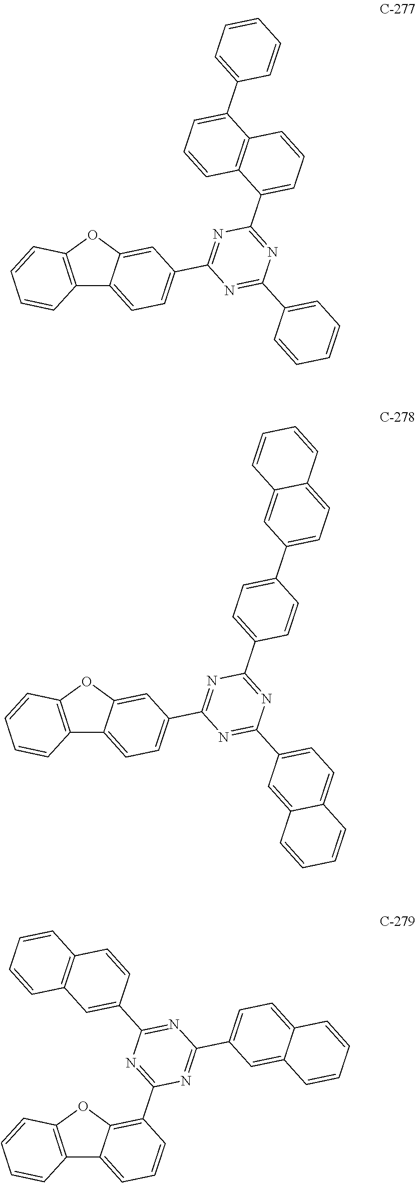 [SMILES: c1ccc(-c2nc(-c3ccc4c(c3)oc3ccccc34)nc(-c3cccc4c(-c5ccccc5)cccc34)n2)cc1 ; c1ccc2cc(-c3ccc(-c4nc(-c5ccc6ccccc6c5)nc(-c5ccc6c(c5)oc5ccccc56)n4)cc3)ccc2c1 ; c1ccc2cc(-c3nc(-c4ccc5ccccc5c4)nc(-c4cccc5c4oc4ccccc45)n3)ccc2c1]

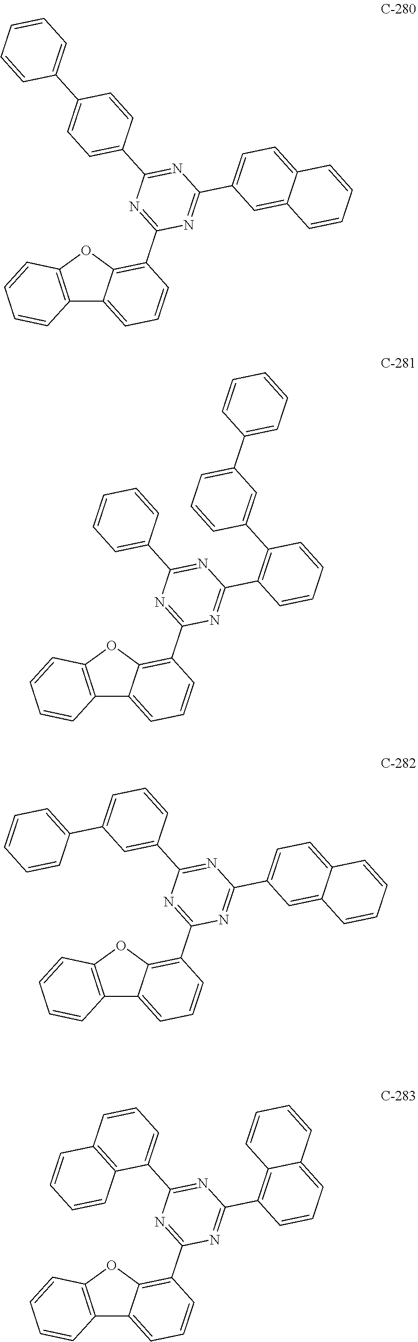 [SMILES: c1ccc(-c2ccc(-c3nc(-c4ccc5ccccc5c4)nc(-c4cccc5c4oc4ccccc45)n3)cc2)cc1 ; c1ccc(-c2cccc(-c3ccccc3-c3nc(-c4ccccc4)nc(-c4cccc5c4oc4ccccc45)n3)c2)cc1 ; c1ccc(-c2cccc(-c3nc(-c4ccc5ccccc5c4)nc(-c4cccc5c4oc4ccccc45)n3)c2)cc1 ; c1ccc2c(-c3nc(-c4cccc5ccccc45)nc(-c4cccc5c4oc4ccccc45)n3)cccc2c1]

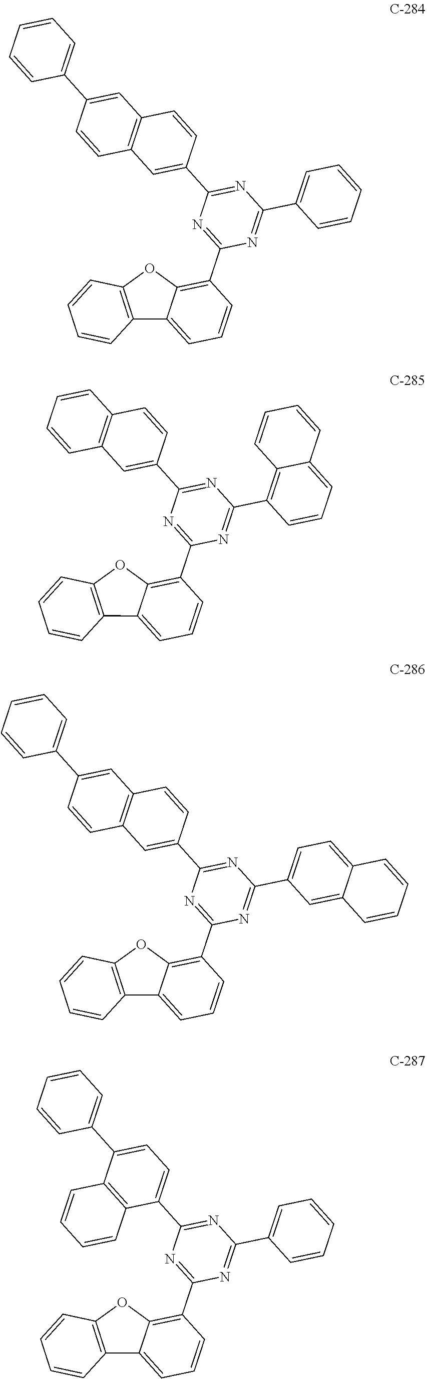 [SMILES: c1ccc(-c2ccc3cc(-c4nc(-c5ccccc5)nc(-c5cccc6c5oc5ccccc56)n4)ccc3c2)cc1 ; c1ccc2cc(-c3nc(-c4cccc5ccccc45)nc(-c4cccc5c4oc4ccccc45)n3)ccc2c1 ; c1ccc(-c2ccc3cc(-c4nc(-c5ccc6ccccc6c5)nc(-c5cccc6c5oc5ccccc56)n4)ccc3c2)cc1 ; c1ccc(-c2nc(-c3ccc(-c4ccccc4)c4ccccc34)nc(-c3cccc4c3oc3ccccc34)n2)cc1]

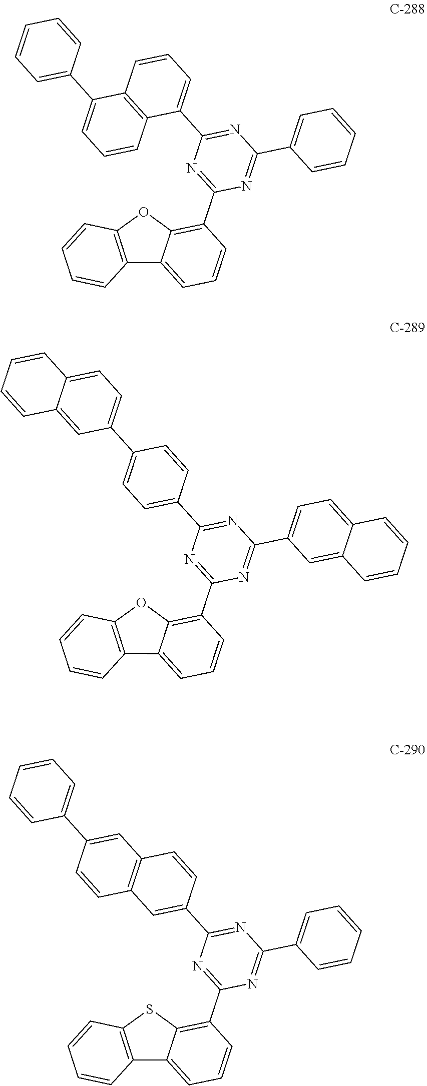 [SMILES: c1ccc(-c2nc(-c3cccc4c(-c5ccccc5)cccc34)nc(-c3cccc4c3oc3ccccc34)n2)cc1 ; c1ccc2cc(-c3ccc(-c4nc(-c5ccc6ccccc6c5)nc(-c5cccc6c5oc5ccccc56)n4)cc3)ccc2c1 ; c1ccc(-c2ccc3cc(-c4nc(-c5ccccc5)nc(-c5cccc6c5sc5ccccc56)n4)ccc3c2)cc1]

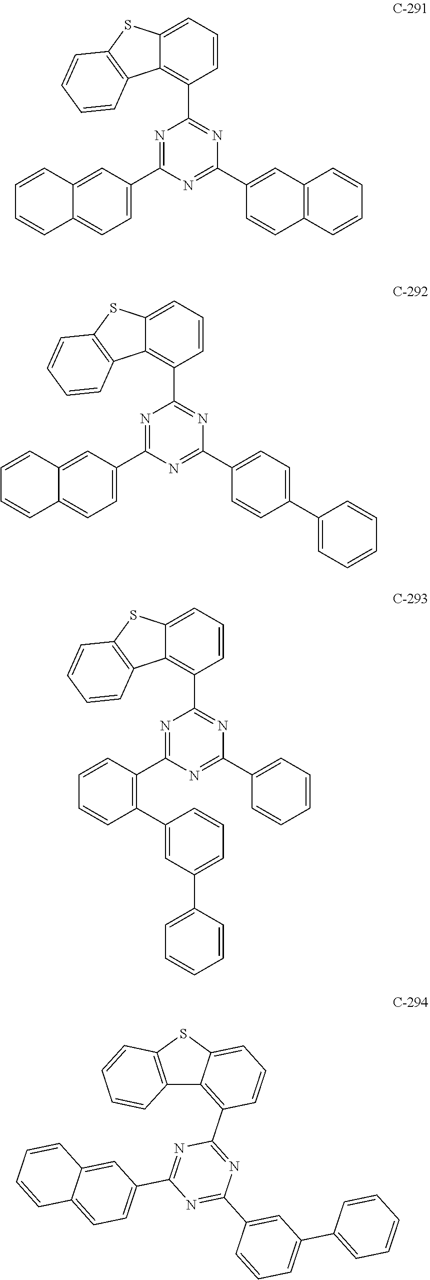 [SMILES: c1ccc2cc(-c3nc(-c4ccc5ccccc5c4)nc(-c4cccc5sc6ccccc6c45)n3)ccc2c1 ; c1ccc(-c2ccc(-c3nc(-c4ccc5ccccc5c4)nc(-c4cccc5sc6ccccc6c45)n3)cc2)cc1 ; c1ccc(-c2cccc(-c3ccccc3-c3nc(-c4ccccc4)nc(-c4cccc5sc6ccccc6c45)n3)c2)cc1 ; c1ccc(-c2cccc(-c3nc(-c4ccc5ccccc5c4)nc(-c4cccc5sc6ccccc6c45)n3)c2)cc1]

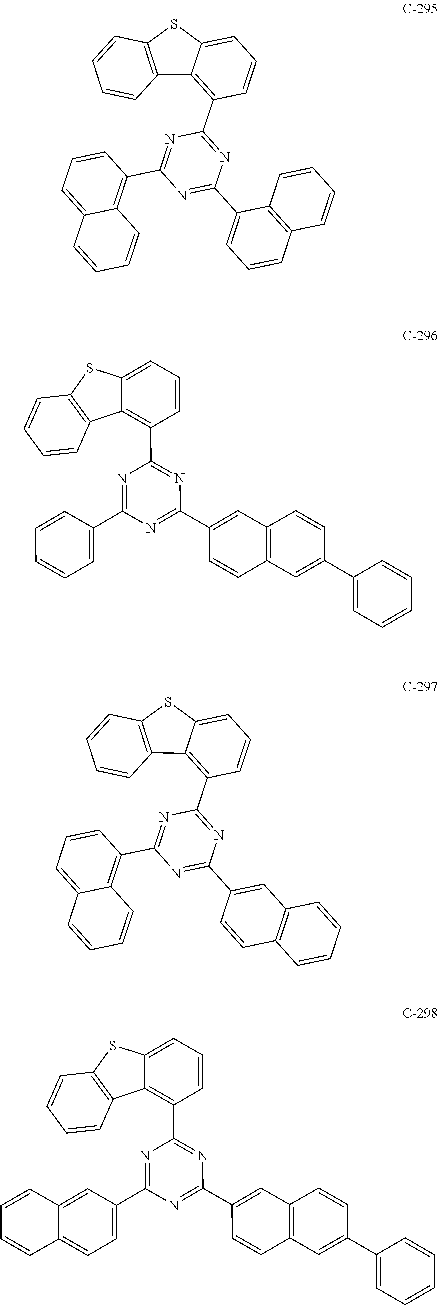 [SMILES: c1ccc2c(-c3nc(-c4cccc5ccccc45)nc(-c4cccc5sc6ccccc6c45)n3)cccc2c1 ; c1ccc(-c2ccc3cc(-c4nc(-c5ccccc5)nc(-c5cccc6sc7ccccc7c56)n4)ccc3c2)cc1 ; c1ccc2cc(-c3nc(-c4cccc5ccccc45)nc(-c4cccc5sc6ccccc6c45)n3)ccc2c1 ; c1ccc(-c2ccc3cc(-c4nc(-c5ccc6ccccc6c5)nc(-c5cccc6sc7ccccc7c56)n4)ccc3c2)cc1]

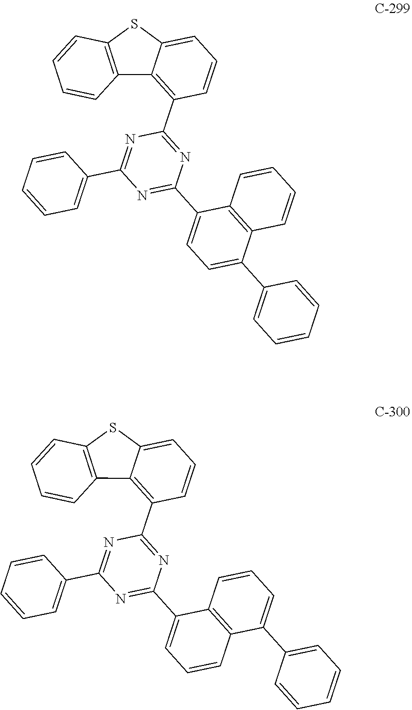 [SMILES: c1ccc(-c2nc(-c3ccc(-c4ccccc4)c4ccccc34)nc(-c3cccc4sc5ccccc5c34)n2)cc1 ; c1ccc(-c2nc(-c3cccc4c(-c5ccccc5)cccc34)nc(-c3cccc4sc5ccccc5c34)n2)cc1]

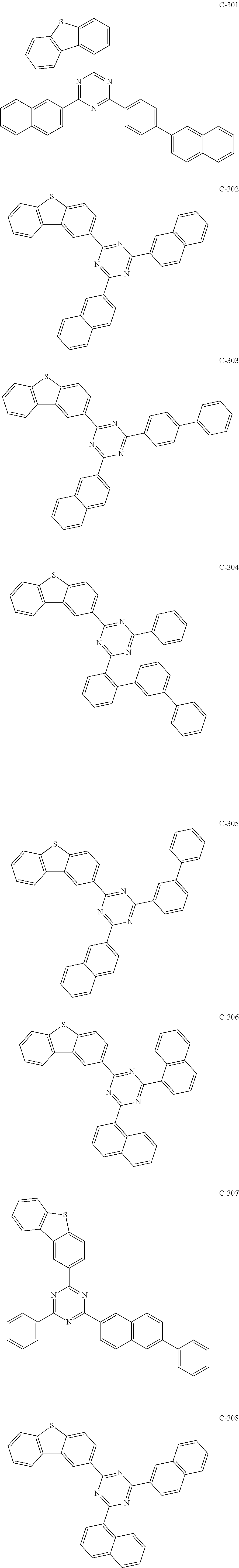

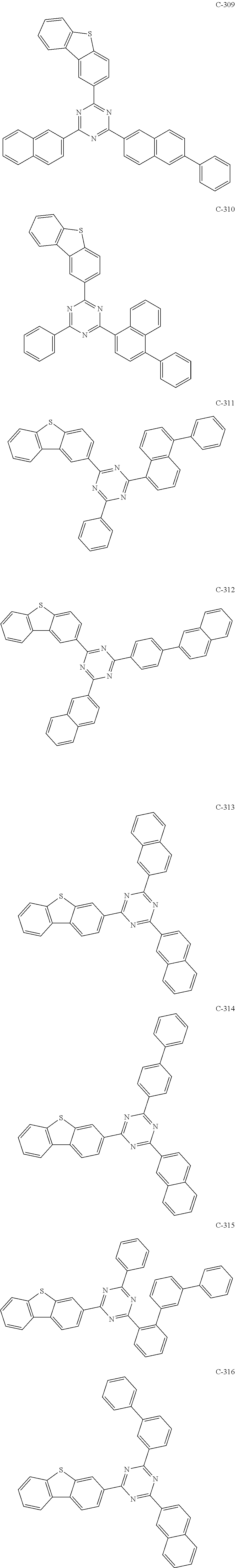

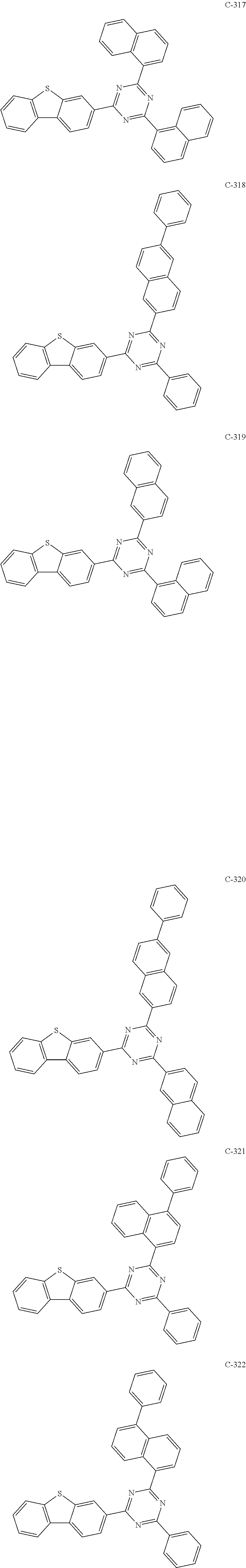

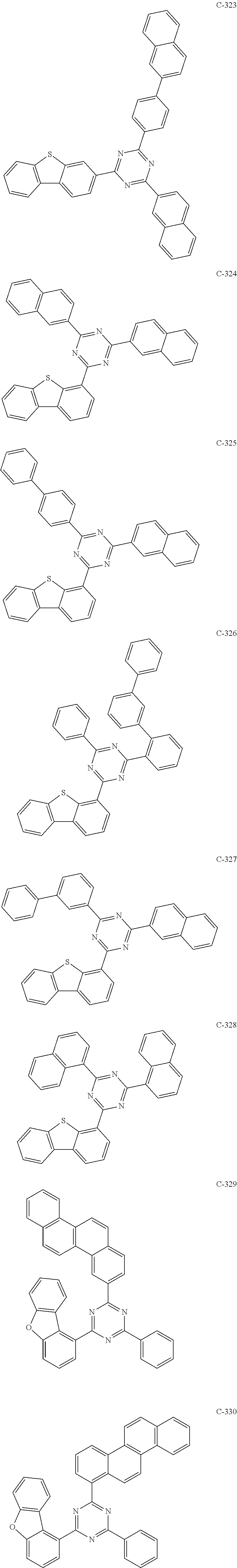

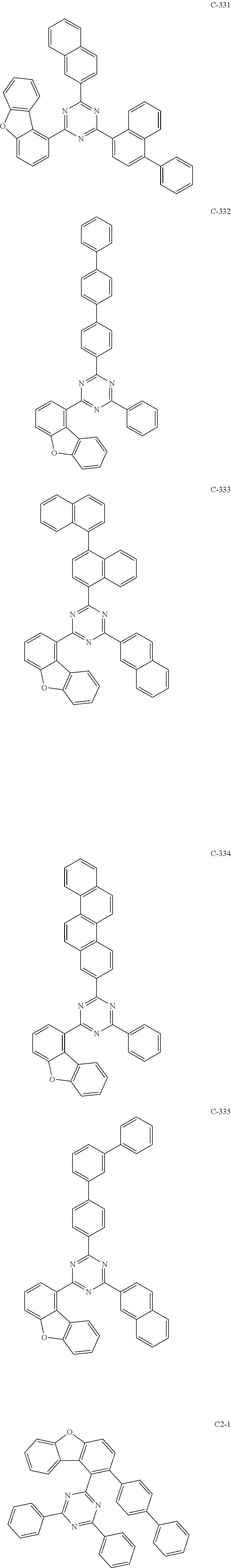 [SMILES: c1ccc(-c2ccc(-c3nc(-c4ccc5ccccc5c4)nc(-c4cccc5oc6ccccc6c45)n3)c3ccccc23)cc1 ; c1ccc(-c2ccc(-c3ccc(-c4nc(-c5ccccc5)nc(-c5cccc6oc7ccccc7c56)n4)cc3)cc2)cc1 ; c1ccc2cc(-c3nc(-c4ccc(-c5cccc6ccccc56)c5ccccc45)nc(-c4cccc5oc6ccccc6c45)n3)ccc2c1 ; c1ccc(-c2nc(-c3ccc4c(ccc5c6ccccc6ccc45)c3)nc(-c3cccc4oc5ccccc5c34)n2)cc1 ; c1ccc(-c2cccc(-c3ccc(-c4nc(-c5ccc6ccccc6c5)nc(-c5cccc6oc7ccccc7c56)n4)cc3)c2)cc1 ; c1ccc(-c2ccc(-c3ccc4oc5ccccc5c4c3-c3nc(-c4ccccc4)nc(-c4ccccc4)n3)cc2)cc1]

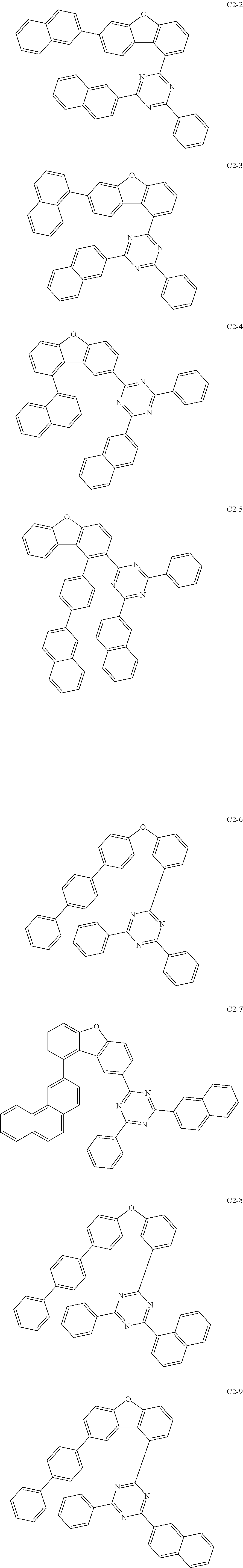

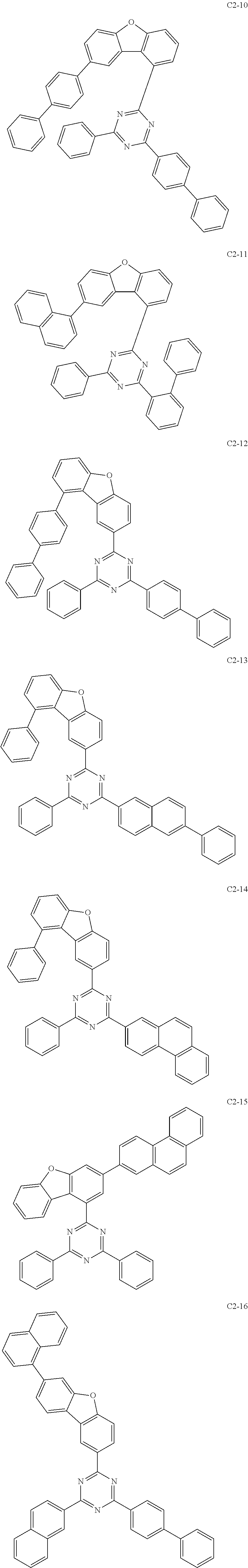

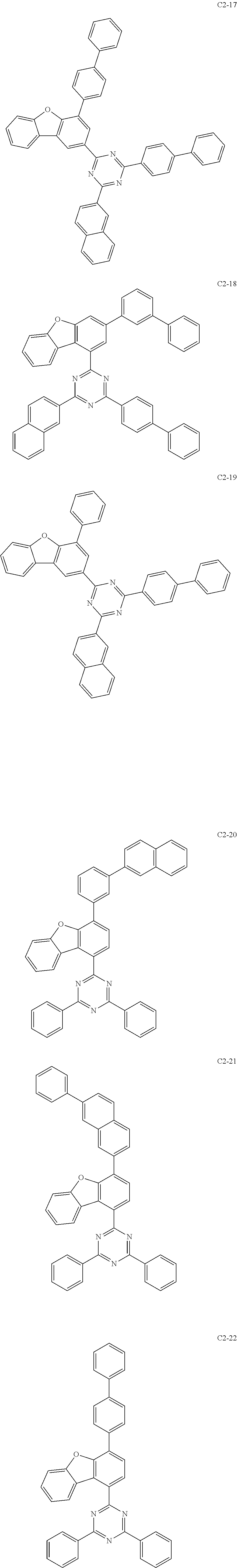

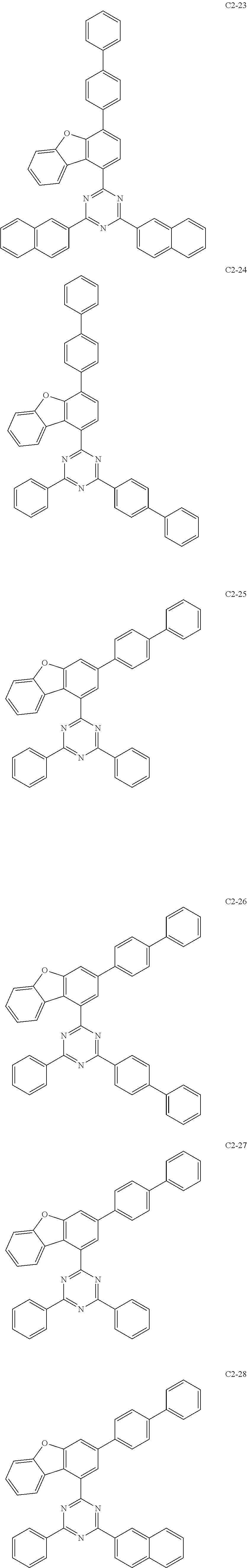

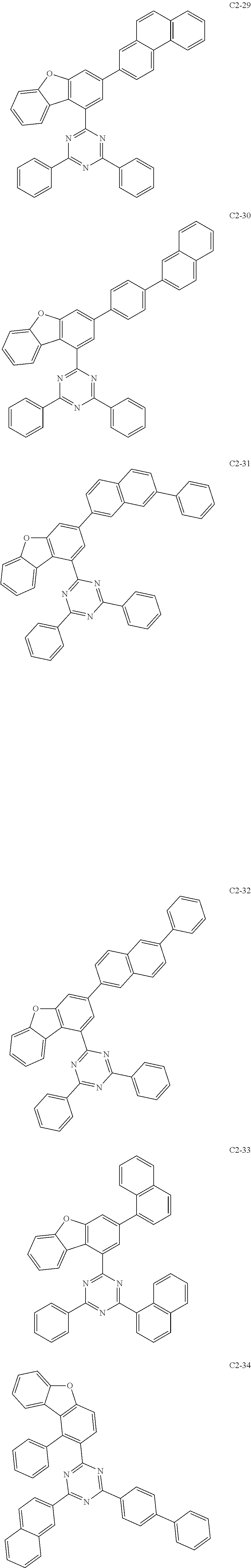 [SMILES: c1ccc(-c2nc(-c3ccccc3)nc(-c3cc(-c4ccc5c(ccc6ccccc65)c4)cc4oc5ccccc5c34)n2)cc1 ; c1ccc(-c2nc(-c3ccccc3)nc(-c3cc(-c4ccc(-c5ccc6ccccc6c5)cc4)cc4oc5ccccc5c34)n2)cc1 ; c1ccc(-c2ccc3ccc(-c4cc(-c5nc(-c6ccccc6)nc(-c6ccccc6)n5)c5c(c4)oc4ccccc45)cc3c2)cc1 ; c1ccc(-c2ccc3cc(-c4cc(-c5nc(-c6ccccc6)nc(-c6ccccc6)n5)c5c(c4)oc4ccccc45)ccc3c2)cc1 ; c1ccc(-c2nc(-c3cccc4ccccc34)nc(-c3cc(-c4cccc5ccccc45)cc4oc5ccccc5c34)n2)cc1 ; c1ccc(-c2ccc(-c3nc(-c4ccc5ccccc5c4)nc(-c4ccc5oc6ccccc6c5c4-c4ccccc4)n3)cc2)cc1]

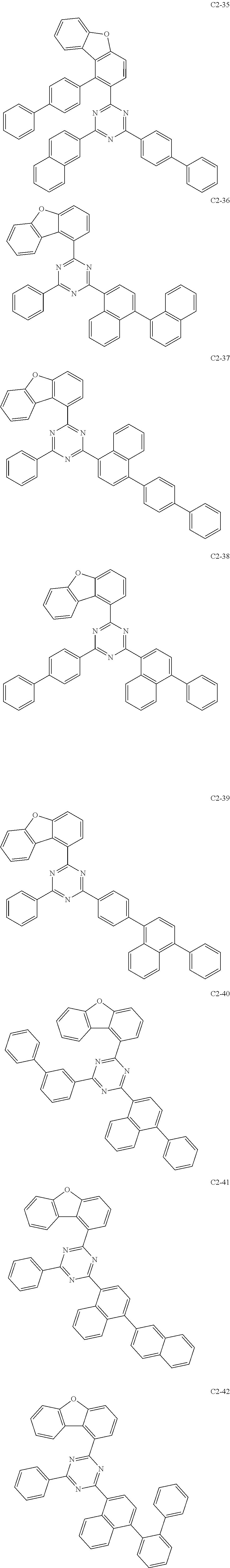

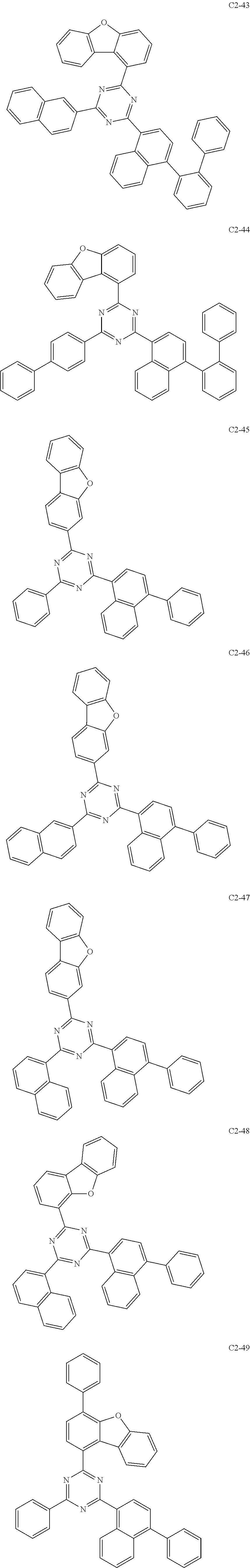

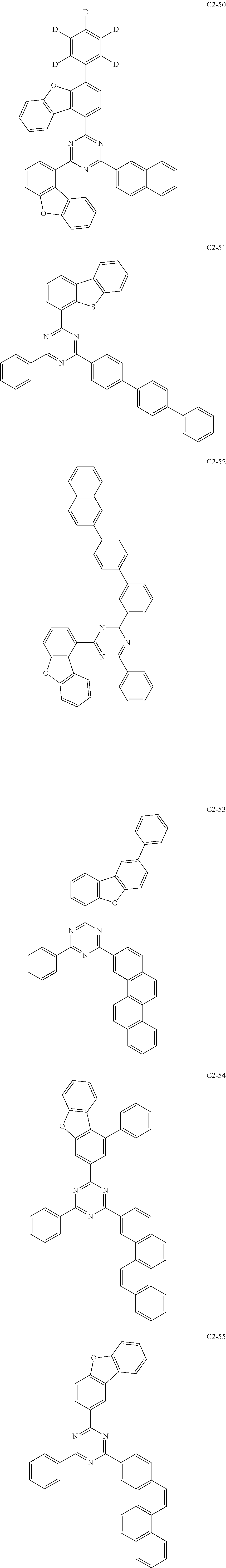

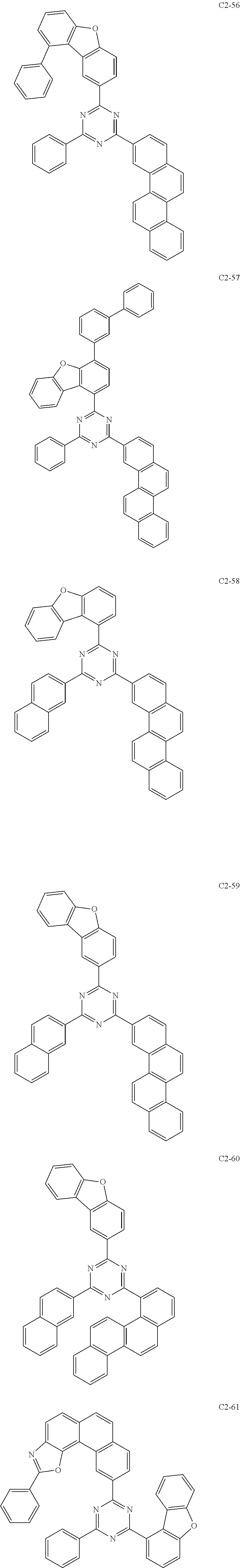 [SMILES: c1ccc(-c2nc(-c3ccc4ccc5c6ccccc6ccc5c4c3)nc(-c3ccc4oc5cccc(-c6ccccc6)c5c4c3)n2)cc1 ; c1ccc(-c2cccc(-c3ccc(-c4nc(-c5ccccc5)nc(-c5ccc6ccc7c8ccccc8ccc7c6c5)n4)c4c3oc3ccccc34)c2)cc1 ; c1ccc2cc(-c3nc(-c4ccc5ccc6c7ccccc7ccc6c5c4)nc(-c4cccc5oc6ccccc6c45)n3)ccc2c1 ; c1ccc2cc(-c3nc(-c4ccc5ccc6c7ccccc7ccc6c5c4)nc(-c4ccc5oc6ccccc6c5c4)n3)ccc2c1 ; c1ccc2cc(-c3nc(-c4ccc5oc6ccccc6c5c4)nc(-c4cccc5ccc6c7ccccc7ccc6c45)n3)ccc2c1 ; c1ccc(-c2nc(-c3ccc4ccc5ccc6nc(-c7ccccc7)oc6c5c4c3)nc(-c3cccc4oc5ccccc5c34)n2)cc1]

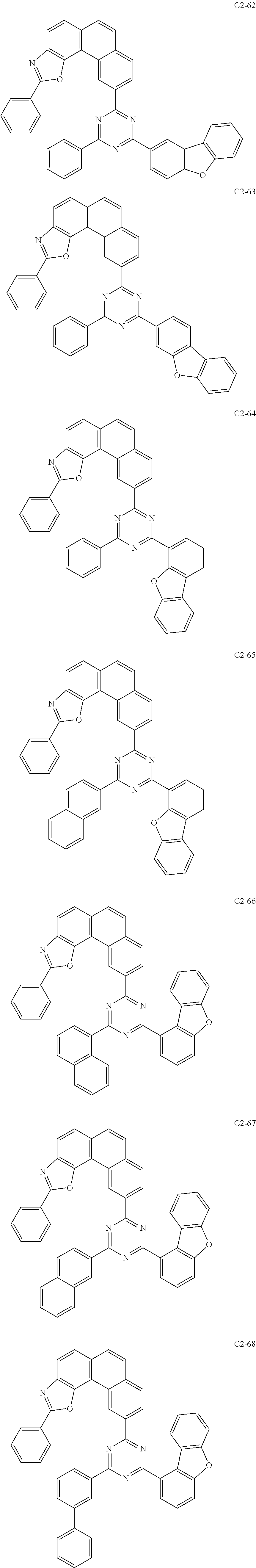

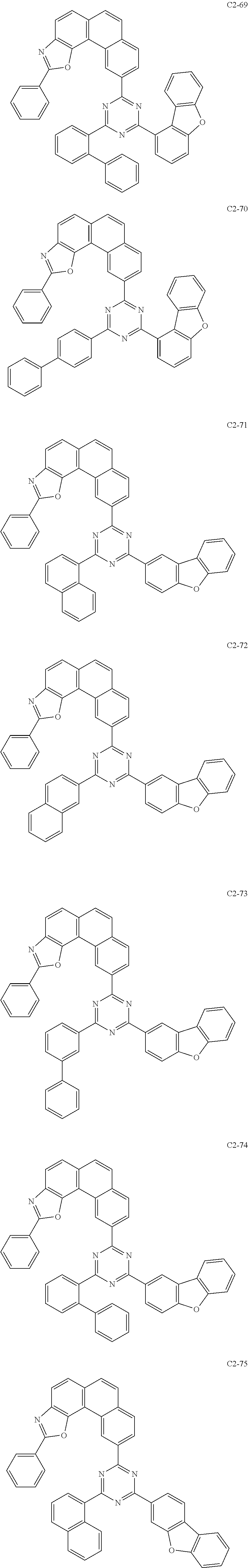

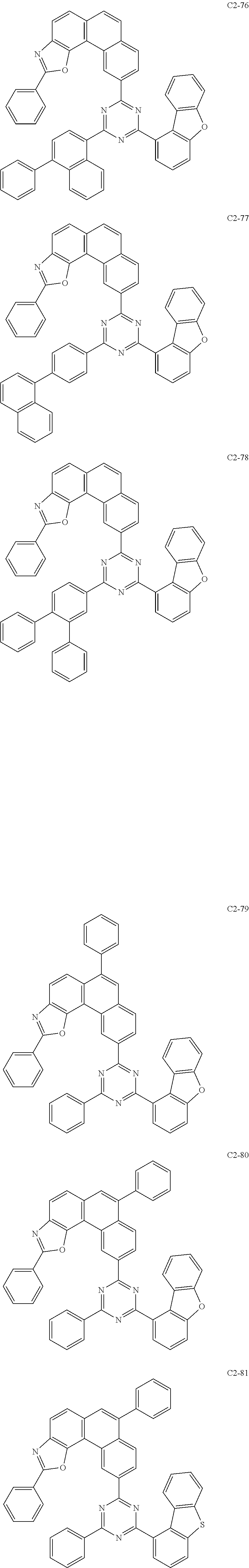

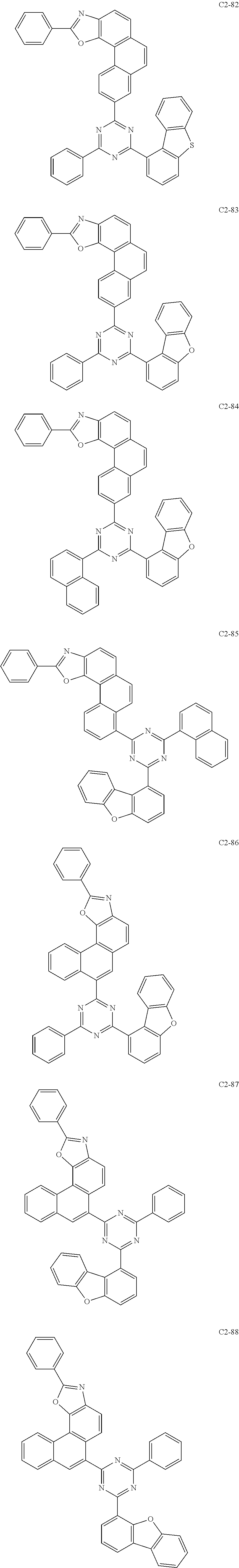

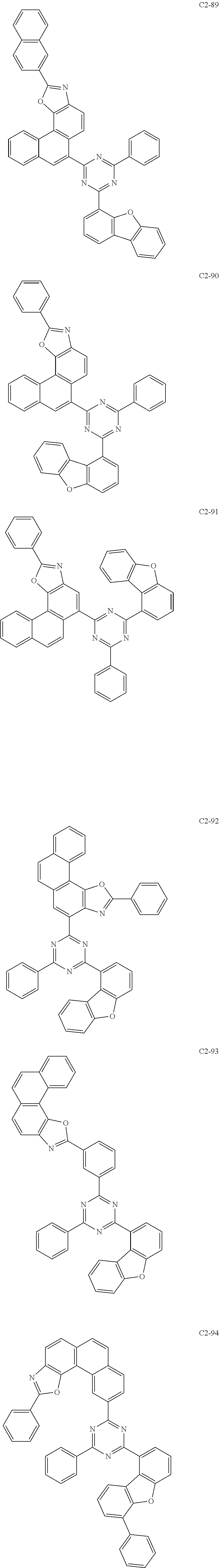

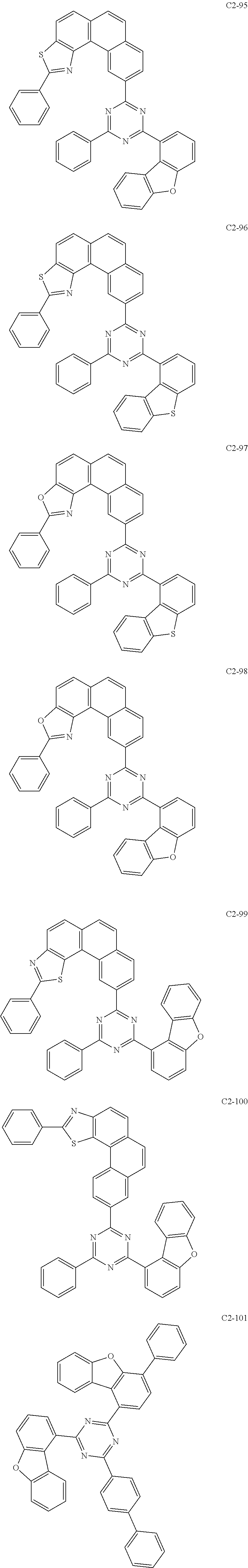

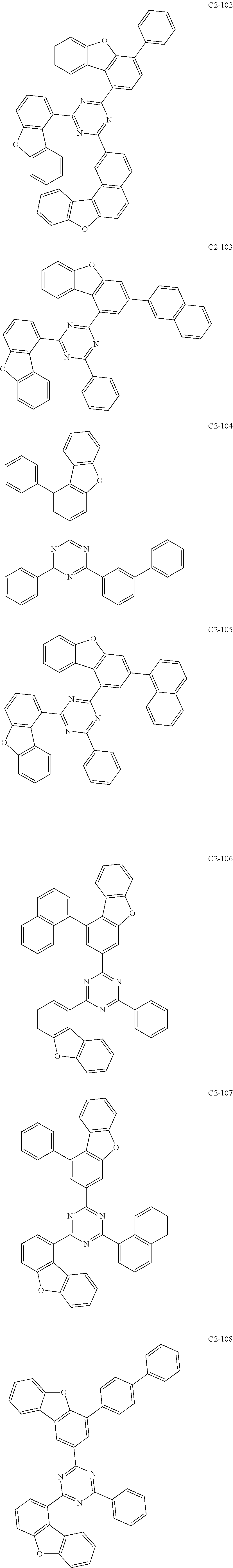

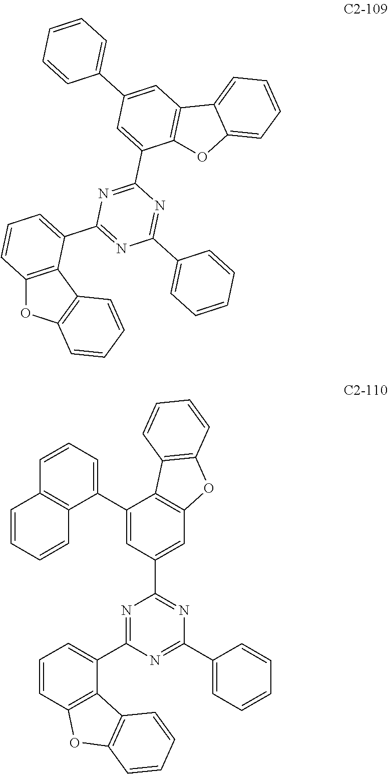 [SMILES: c1ccc(-c2cc(-c3nc(-c4ccccc4)nc(-c4cccc5oc6ccccc6c45)n3)c3oc4ccccc4c3c2)cc1 ; c1ccc(-c2nc(-c3cc(-c4cccc5ccccc45)c4c(c3)oc3ccccc34)nc(-c3cccc4oc5ccccc5c34)n2)cc1]

According to one embodiment of the present disclosure, the present invention provides an organic electroluminescent device comprising an anode, a cathode, and at least one light-emitting layer between the anode and the cathode, wherein the at least one light-emitting layer comprises the plurality of host materials described above.

According to another embodiment of the present disclosure, the present invention provides organic electroluminescent compound represented by the following Formula 1′, and an organic electroluminescent device comprising the same.

In Formula 1′, X₁ represents O, S, or CR₁₃R₁₄. For example, X₁ may be O or S.

In Formula 1′, R₁₃ and R₁₄ each independently represent a substituted or unsubstituted (C₁-C₃₀)alkyl, a substituted or unsubstituted (C₆-C₃₀)aryl, or a substituted or unsubstituted (3- to 30-membered)heteroaryl, or R₁₃ and R₁₄ may be linked to each other to form a ring(s).

In Formula 1′, R₁ to R₁₂ each independently represent hydrogen, deuterium, a halogen, a cyano, a substituted or unsubstituted (C₁-C₃₀)alkyl, a substituted or unsubstituted (C₂-C₃₀)alkenyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₃-C₃₀)cycloalkenyl, a substituted or unsubstituted (3- to 7-membered)heterocycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted fused ring of (C₃-C₃₀) aliphatic ring(s) and (C₆-C₃₀) aromatic ring(s), a substituted or unsubstituted mono- or di-(C₁-C₃₀)alkylamino, a substituted or unsubstituted mono- or di-(C₆-C₃₀)arylamino, a substituted or unsubstituted (C₁-C₃₀)alkyl(C₆-C₃₀)arylamino, a substituted or unsubstituted mono- or di-(3- to 30-membered)heteroarylamino, or a substituted or unsubstituted (C₆-C₃₀)aryl(3- to 30-membered)heteroarylamino; or may be linked to the adjacent substituent(s) to form a ring(s); wherein at least one of R₉ and R₁₀ represents a substituted or unsubstituted (C₆-C₃₀)aryl or a substituted or unsubstituted (C₆-C₃₀)heteroaryl; with a proviso that at least one of R₁ to R₁₂ represents the following Formula 1′-a. According to one embodiment of the present disclosure, R₁ to R₁₂ each independently represent hydrogen, deuterium, a substituted or unsubstituted (C₆-C₃₀)aryl, a substituted or unsubstituted (3- to 30-membered)heteroaryl, wherein at least one of R₉ and R₁₀ represents a substituted or unsubstituted (C₆-C₃₀)aryl, with a proviso that at least one of R₁ to R₁₂ represents the following Formula 1′-a. According to another embodiment of the present disclosure, R₁ to R₁₂ each independently represent hydrogen, deuterium, a substituted or unsubstituted (C₆-C₁₂)aryl, wherein at least one of R₉ and R₁₀ represents a substituted or unsubstituted (C₆-C₁₂)aryl, with a proviso that at least one of R₁ to R₁₂ represents the following Formula 1′-a. For example, R₁ to R₁₂ each independently may be hydrogen, a phenyl, a naphthyl, a biphenyl, or Formula 1′-a, with a proviso that at least one of R₁ to R₁₂ may be the following Formula 1′-a, wherein at least one of R₉ and R₁₀ may be a phenyl, a naphthyl, or a biphenyl.

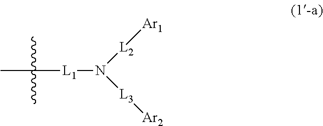

In Formula 1′-a,

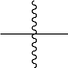

is a site linked to at least one of R₁ to R₁₂.

In Formula 1′-a, L₁ to L₃ each independently represent a single bond, a substituted or unsubstituted (C₆-C₃₀)arylene, a substituted or unsubstituted (3- to 30-membered)heteroarylene, or a substituted or unsubstituted (C₃-C₃₀)cycloalkylene. According to one embodiment of the present disclosure, L₁ to L₃ each independently represent a single bond, a substituted or unsubstituted (C₆-C₃₀)arylene, or a substituted or unsubstituted (3- to 30-membered)heteroarylene. According to another embodiment of the present disclosure, L₁ to L₃ each independently represent a single bond, a substituted or unsubstituted (C₆-C₁₀)arylene, or a substituted or unsubstituted (3- to 13-membered)heteroarylene. For example, L₁ to L₃ each independently may be a single bond, a phenylene, a naphthylene, or a carbazolylene.

In Formula 1′-a, Ar₁ and Ar₂ each independently represent a substituted or unsubstituted (C₆-C₃₀)aryl, a substituted or unsubstituted (3- to 30-membered)heteroaryl, or a substituted or unsubstituted (C₃-C₃₀)cycloalkyl. According to one embodiment of the present disclosure, Ar₁ and Ar₂ each independently represent a substituted or unsubstituted (C₆-C₁₅)aryl or a substituted or unsubstituted (3- to 13-membered)heteroaryl. For example, Ar₁ and Ar₂ each independently may be a phenyl unsubstituted or substituted with a naphthyl(s), a carbazolyl(s), a dibenzofuranyl(s), or a phenanthrenyl(s); a biphenyl; a naphthyl; a phenanthrenyl; a dimethylfluorenyl; a dibenzothiophenyl; a dibenzofuranyl; or a carbazolyl unsubstituted or substituted with a phenyl(s).

According to one embodiment of the present disclosure, the compound represented by Formula 1′ may be represented by any one of the following formulas.

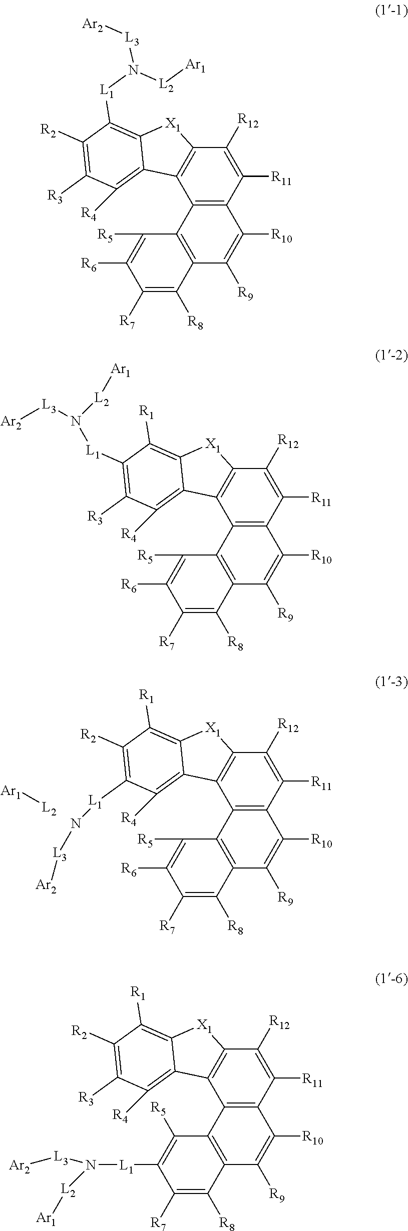

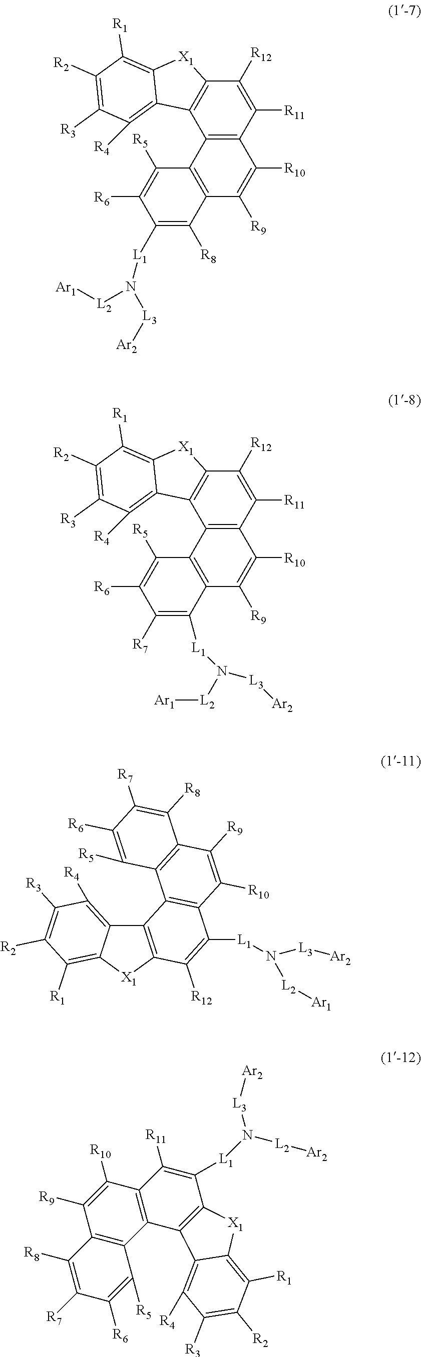

In Formulas 1′-1, 1′-2, 1′-3, 1′-6, 1′-7, 1′-8, 1′-11, and 1′-12, at least one of R₉ and R₁₀ represents a substituted or unsubstituted (C₆-C₃₀)aryl, or a substituted or unsubstituted (C₆-C₃₀)heteroaryl.

According to one embodiment of the present disclosure, the compound represented by Formula 1′ may be selected from the following compounds, but is not limited thereto.

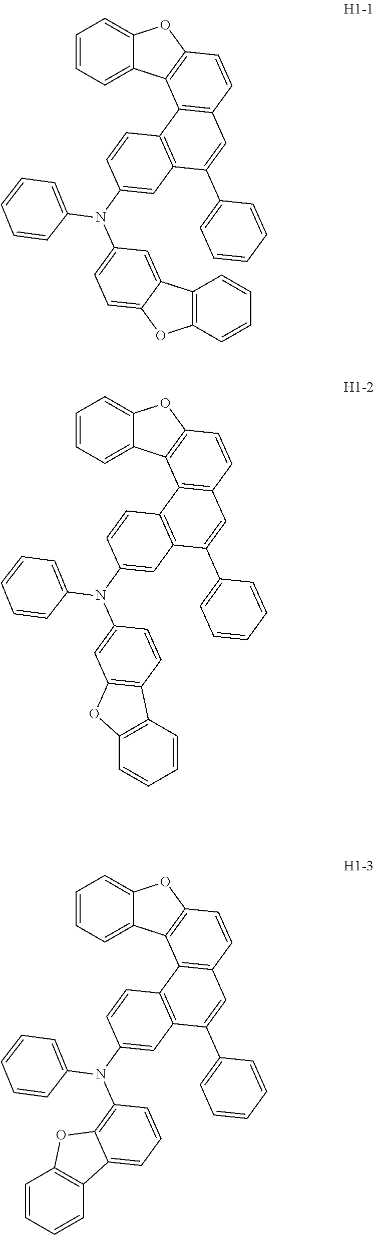 [SMILES: c1ccc(-c2cc3ccc4oc5ccccc5c4c3c3ccc(N(c4ccccc4)c4ccc5oc6ccccc6c5c4)cc23)cc1 ; c1ccc(-c2cc3ccc4oc5ccccc5c4c3c3ccc(N(c4ccccc4)c4ccc5c(c4)oc4ccccc45)cc23)cc1 ; c1ccc(-c2cc3ccc4oc5ccccc5c4c3c3ccc(N(c4ccccc4)c4cccc5c4oc4ccccc45)cc23)cc1]

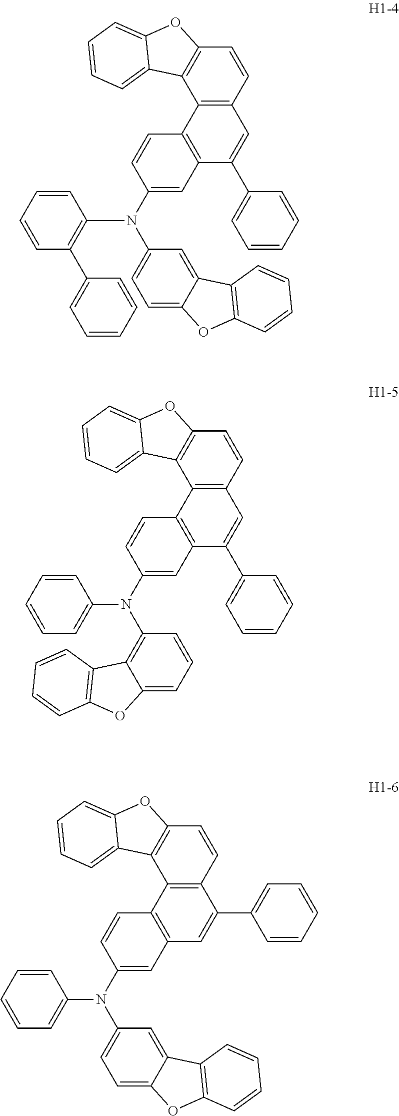 [SMILES: c1ccc(-c2ccccc2N(c2ccc3c(c2)c(-c2ccccc2)cc2ccc4oc5ccccc5c4c23)c2ccc3oc4ccccc4c3c2)cc1 ; c1ccc(-c2cc3ccc4oc5ccccc5c4c3c3ccc(N(c4ccccc4)c4cccc5oc6ccccc6c45)cc23)cc1 ; c1ccc(-c2cc3cc(N(c4ccccc4)c4ccc5oc6ccccc6c5c4)ccc3c3c2ccc2oc4ccccc4c23)cc1]

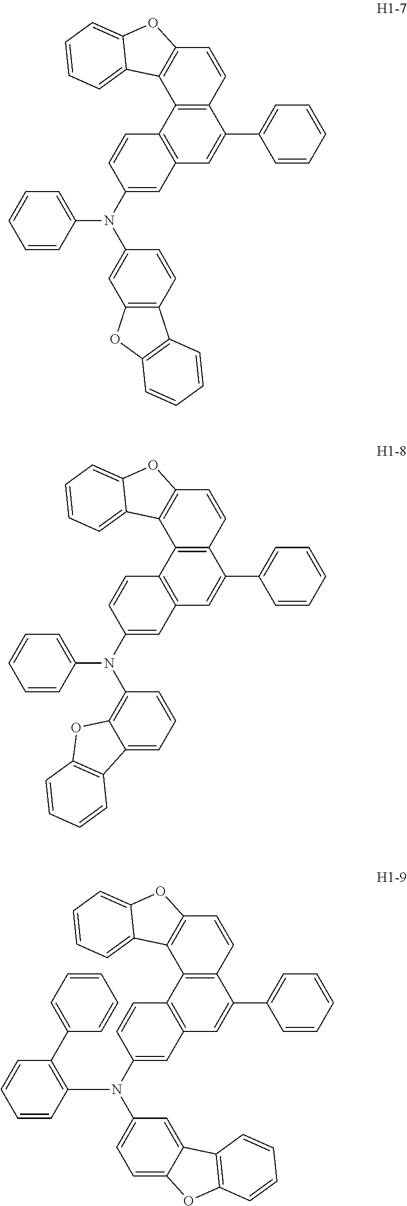 [SMILES: c1ccc(-c2cc3cc(N(c4ccccc4)c4ccc5c(c4)oc4ccccc45)ccc3c3c2ccc2oc4ccccc4c23)cc1 ; c1ccc(-c2cc3cc(N(c4ccccc4)c4cccc5c4oc4ccccc45)ccc3c3c2ccc2oc4ccccc4c23)cc1 ; c1ccc(-c2ccccc2N(c2ccc3c(c2)cc(-c2ccccc2)c2ccc4oc5ccccc5c4c23)c2ccc3oc4ccccc4c3c2)cc1]

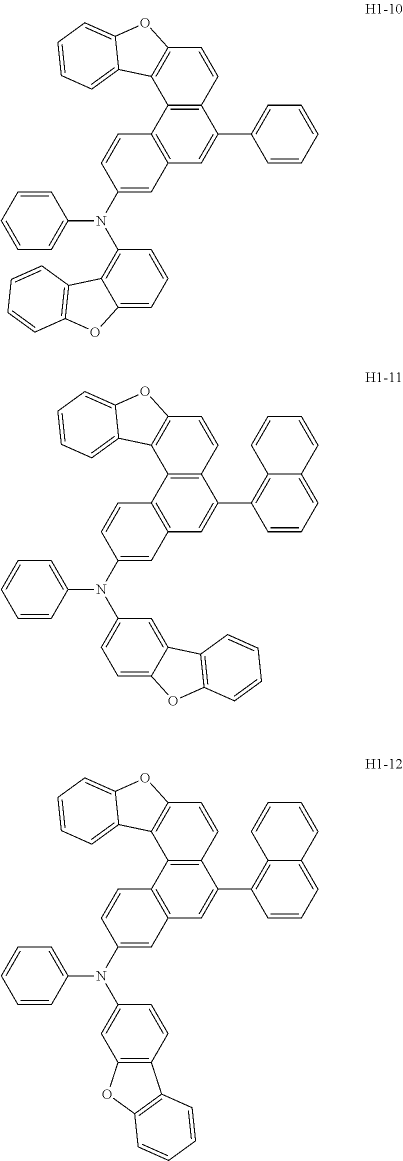 [SMILES: c1ccc(-c2cc3cc(N(c4ccccc4)c4cccc5oc6ccccc6c45)ccc3c3c2ccc2oc4ccccc4c23)cc1 ; c1ccc(N(c2ccc3c(c2)cc(-c2cccc4ccccc24)c2ccc4oc5ccccc5c4c23)c2ccc3oc4ccccc4c3c2)cc1 ; c1ccc(N(c2ccc3c(c2)cc(-c2cccc4ccccc24)c2ccc4oc5ccccc5c4c23)c2ccc3c(c2)oc2ccccc23)cc1]

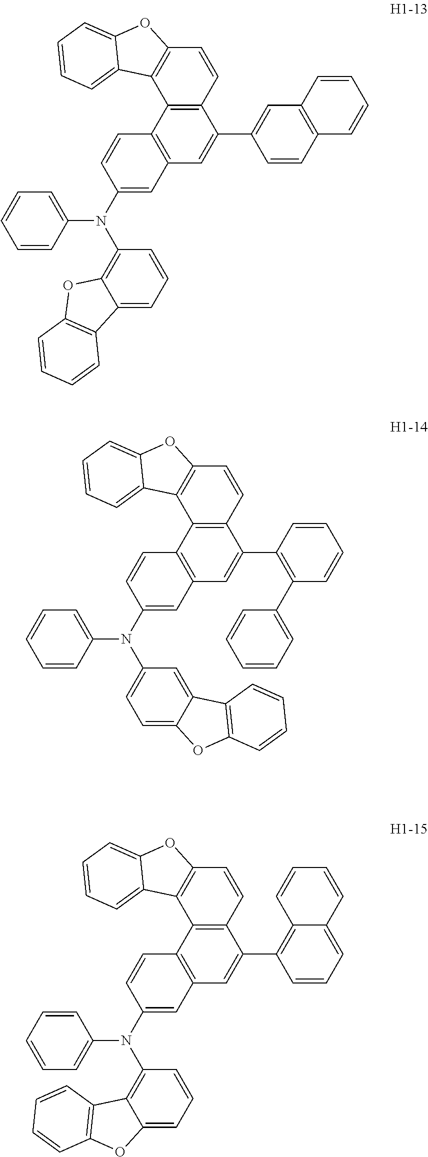 [SMILES: c1ccc(N(c2ccc3c(c2)cc(-c2ccc4ccccc4c2)c2ccc4oc5ccccc5c4c23)c2cccc3c2oc2ccccc23)cc1 ; c1ccc(-c2ccccc2-c2cc3cc(N(c4ccccc4)c4ccc5oc6ccccc6c5c4)ccc3c3c2ccc2oc4ccccc4c23)cc1 ; c1ccc(N(c2ccc3c(c2)cc(-c2cccc4ccccc24)c2ccc4oc5ccccc5c4c23)c2cccc3oc4ccccc4c23)cc1]

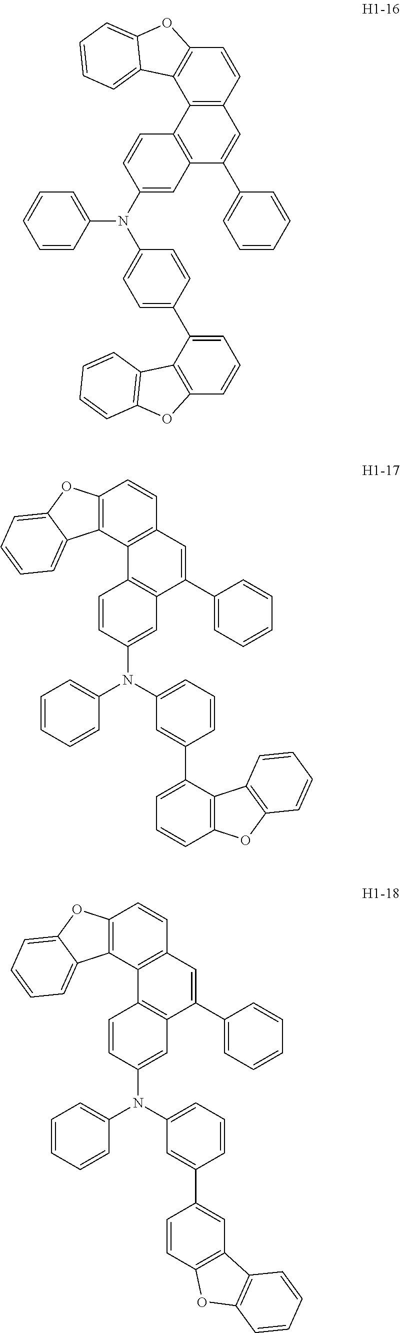 [SMILES: c1ccc(-c2cc3ccc4oc5ccccc5c4c3c3ccc(N(c4ccccc4)c4ccc(-c5cccc6oc7ccccc7c56)cc4)cc23)cc1 ; c1ccc(-c2cc3ccc4oc5ccccc5c4c3c3ccc(N(c4ccccc4)c4cccc(-c5cccc6oc7ccccc7c56)c4)cc23)cc1 ; c1ccc(-c2cc3ccc4oc5ccccc5c4c3c3ccc(N(c4ccccc4)c4cccc(-c5ccc6oc7ccccc7c6c5)c4)cc23)cc1]

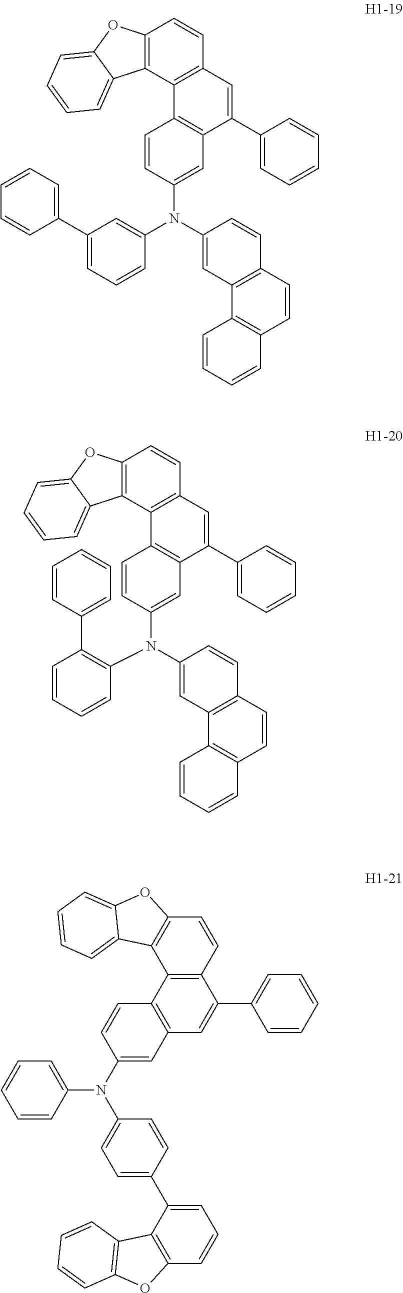 [SMILES: c1ccc(-c2cccc(N(c3ccc4c(c3)c(-c3ccccc3)cc3ccc5oc6ccccc6c5c34)c3ccc4ccc5ccccc5c4c3)c2)cc1 ; c1ccc(-c2ccccc2N(c2ccc3c(c2)c(-c2ccccc2)cc2ccc4oc5ccccc5c4c23)c2ccc3ccc4ccccc4c3c2)cc1 ; c1ccc(-c2cc3cc(N(c4ccccc4)c4ccc(-c5cccc6oc7ccccc7c56)cc4)ccc3c3c2ccc2oc4ccccc4c23)cc1]

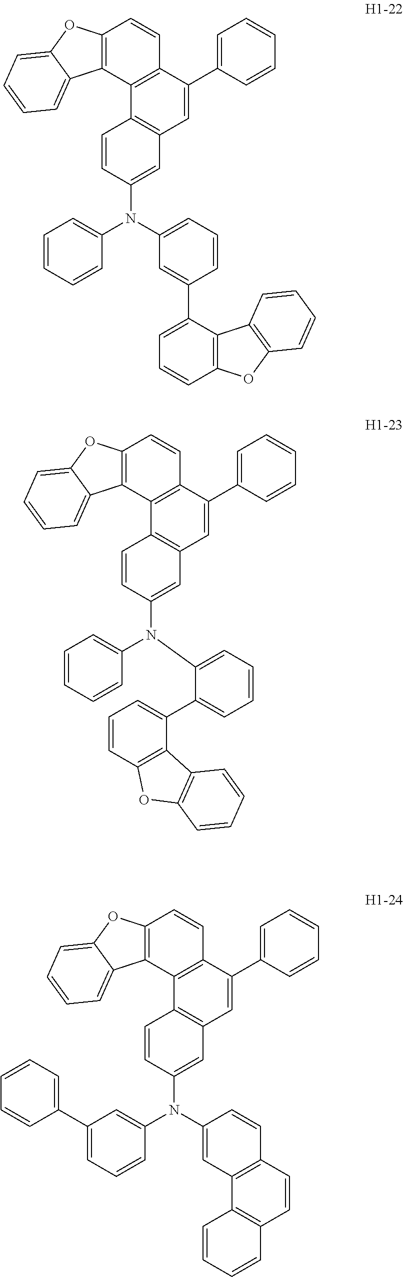 [SMILES: c1ccc(-c2cc3cc(N(c4ccccc4)c4cccc(-c5cccc6oc7ccccc7c56)c4)ccc3c3c2ccc2oc4ccccc4c23)cc1 ; c1ccc(-c2cc3cc(N(c4ccccc4)c4ccccc4-c4cccc5oc6ccccc6c45)ccc3c3c2ccc2oc4ccccc4c23)cc1 ; c1ccc(-c2cccc(N(c3ccc4c(c3)cc(-c3ccccc3)c3ccc5oc6ccccc6c5c34)c3ccc4ccc5ccccc5c4c3)c2)cc1]

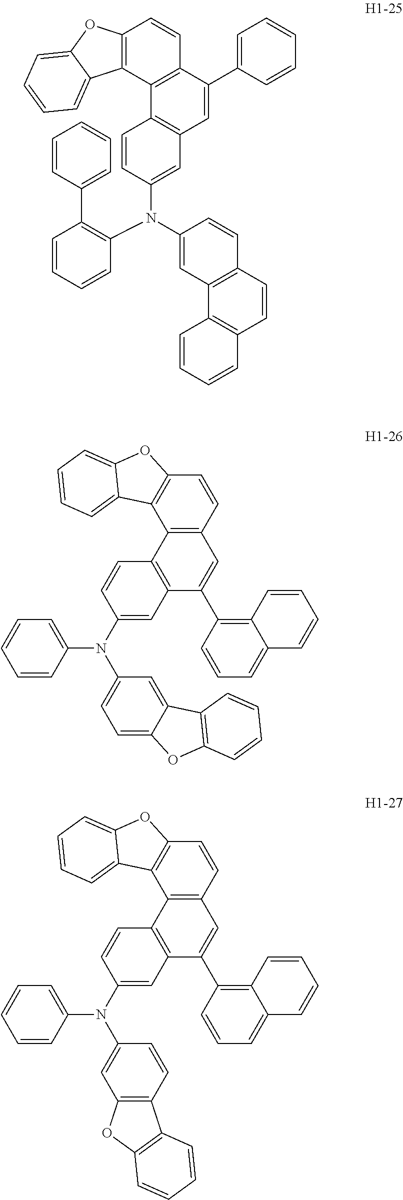 [SMILES: c1ccc(-c2ccccc2N(c2ccc3c(c2)cc(-c2ccccc2)c2ccc4oc5ccccc5c4c23)c2ccc3ccc4ccccc4c3c2)cc1 ; c1ccc(N(c2ccc3c(c2)c(-c2cccc4ccccc24)cc2ccc4oc5ccccc5c4c23)c2ccc3oc4ccccc4c3c2)cc1 ; c1ccc(N(c2ccc3c(c2)oc2ccccc23)c2ccc3c(c2)c(-c2cccc4ccccc24)cc2ccc4oc5ccccc5c4c23)cc1]

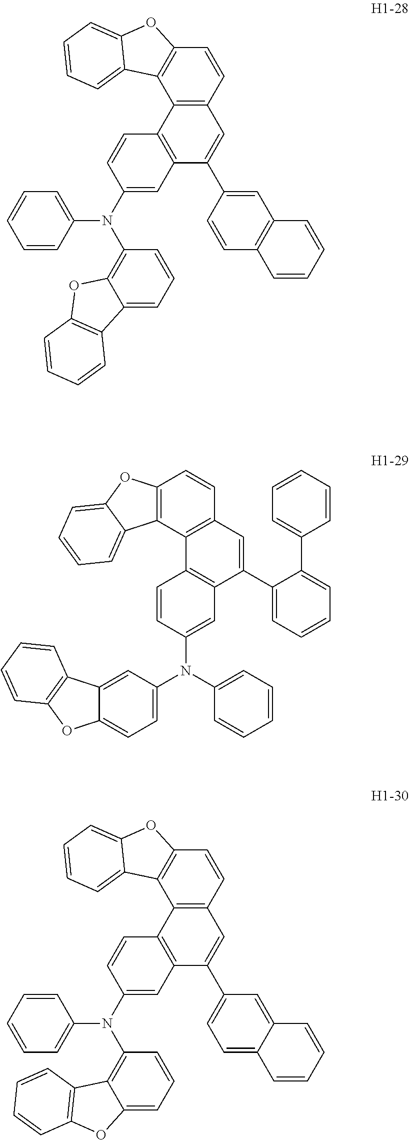 [SMILES: c1ccc(N(c2ccc3c(c2)c(-c2ccc4ccccc4c2)cc2ccc4oc5ccccc5c4c23)c2cccc3c2oc2ccccc23)cc1 ; c1ccc(-c2ccccc2-c2cc3ccc4oc5ccccc5c4c3c3ccc(N(c4ccccc4)c4ccc5oc6ccccc6c5c4)cc23)cc1 ; c1ccc(N(c2ccc3c(c2)c(-c2ccc4ccccc4c2)cc2ccc4oc5ccccc5c4c23)c2cccc3oc4ccccc4c23)cc1]

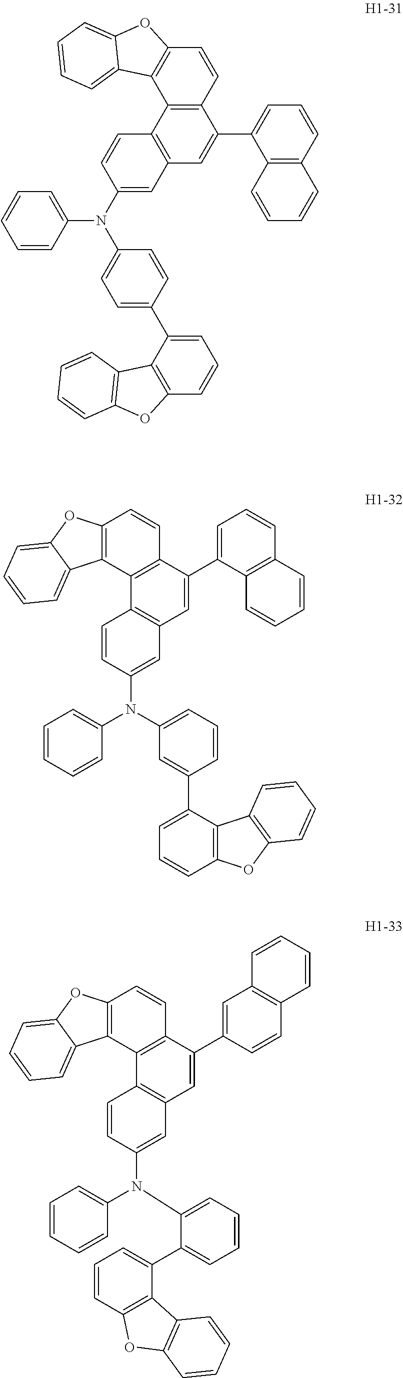 [SMILES: c1ccc(N(c2ccc(-c3cccc4oc5ccccc5c34)cc2)c2ccc3c(c2)cc(-c2cccc4ccccc24)c2ccc4oc5ccccc5c4c23)cc1 ; c1ccc(N(c2cccc(-c3cccc4oc5ccccc5c34)c2)c2ccc3c(c2)cc(-c2cccc4ccccc24)c2ccc4oc5ccccc5c4c23)cc1 ; c1ccc(N(c2ccc3c(c2)cc(-c2ccc4ccccc4c2)c2ccc4oc5ccccc5c4c23)c2ccccc2-c2cccc3oc4ccccc4c23)cc1]

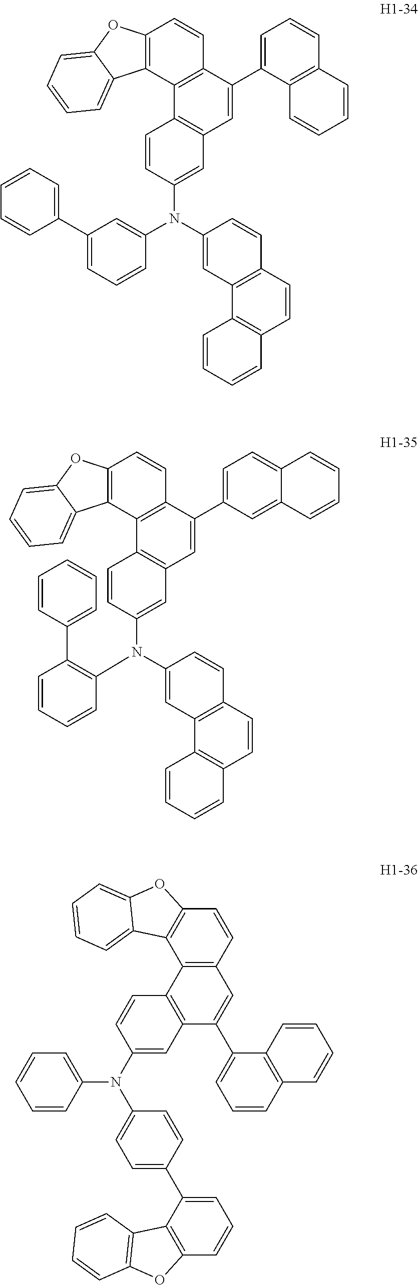 [SMILES: c1ccc(-c2cccc(N(c3ccc4c(c3)cc(-c3cccc5ccccc35)c3ccc5oc6ccccc6c5c34)c3ccc4ccc5ccccc5c4c3)c2)cc1 ; c1ccc(-c2ccccc2N(c2ccc3c(c2)cc(-c2ccc4ccccc4c2)c2ccc4oc5ccccc5c4c23)c2ccc3ccc4ccccc4c3c2)cc1 ; c1ccc(N(c2ccc(-c3cccc4oc5ccccc5c34)cc2)c2ccc3c(c2)c(-c2cccc4ccccc24)cc2ccc4oc5ccccc5c4c23)cc1]

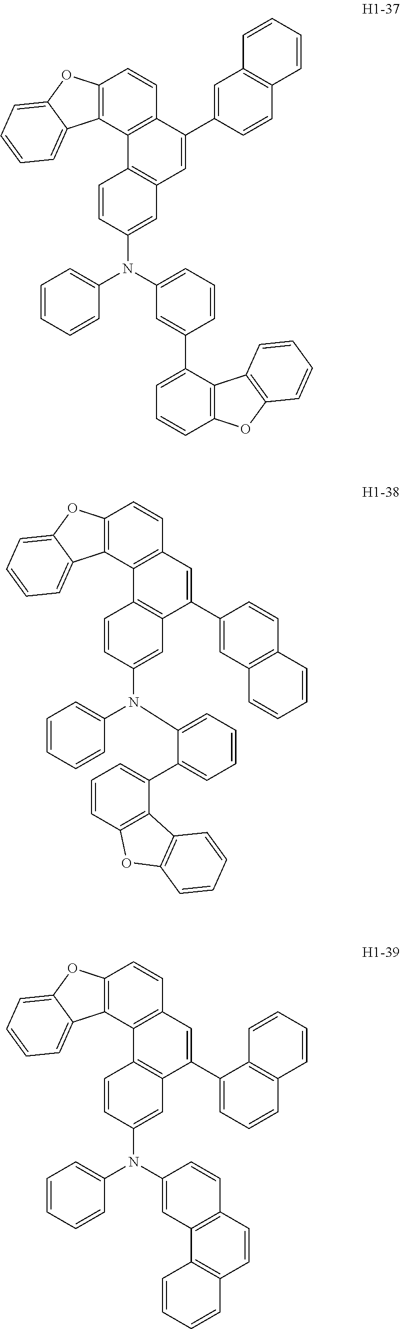 [SMILES: c1ccc(N(c2cccc(-c3cccc4oc5ccccc5c34)c2)c2ccc3c(c2)cc(-c2ccc4ccccc4c2)c2ccc4oc5ccccc5c4c23)cc1 ; c1ccc(N(c2ccc3c(c2)c(-c2ccc4ccccc4c2)cc2ccc4oc5ccccc5c4c23)c2ccccc2-c2cccc3oc4ccccc4c23)cc1 ; c1ccc(N(c2ccc3c(c2)c(-c2cccc4ccccc24)cc2ccc4oc5ccccc5c4c23)c2ccc3ccc4ccccc4c3c2)cc1]

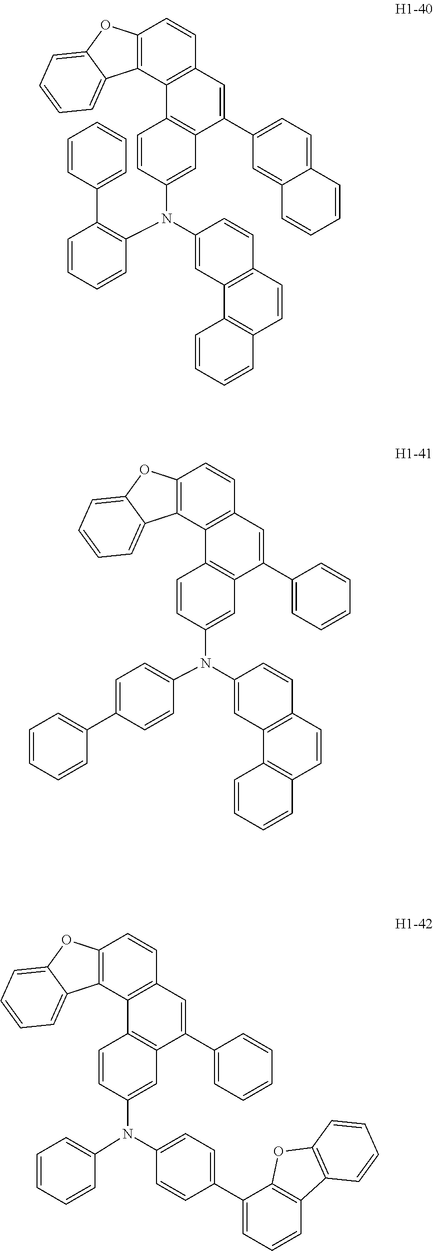 [SMILES: c1ccc(-c2ccccc2N(c2ccc3c(c2)c(-c2ccc4ccccc4c2)cc2ccc4oc5ccccc5c4c23)c2ccc3ccc4ccccc4c3c2)cc1 ; c1ccc(-c2ccc(N(c3ccc4c(c3)c(-c3ccccc3)cc3ccc5oc6ccccc6c5c34)c3ccc4ccc5ccccc5c4c3)cc2)cc1 ; c1ccc(-c2cc3ccc4oc5ccccc5c4c3c3ccc(N(c4ccccc4)c4ccc(-c5cccc6c5oc5ccccc56)cc4)cc23)cc1]

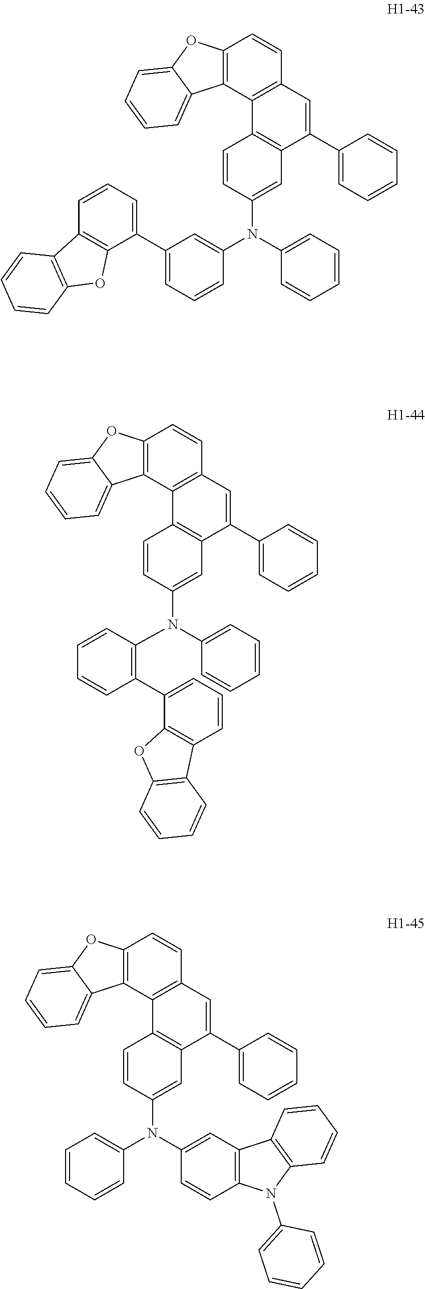 [SMILES: c1ccc(-c2cc3ccc4oc5ccccc5c4c3c3ccc(N(c4ccccc4)c4cccc(-c5cccc6c5oc5ccccc56)c4)cc23)cc1 ; c1ccc(-c2cc3ccc4oc5ccccc5c4c3c3ccc(N(c4ccccc4)c4ccccc4-c4cccc5c4oc4ccccc45)cc23)cc1 ; c1ccc(-c2cc3ccc4oc5ccccc5c4c3c3ccc(N(c4ccccc4)c4ccc5c(c4)c4ccccc4n5-c4ccccc4)cc23)cc1]

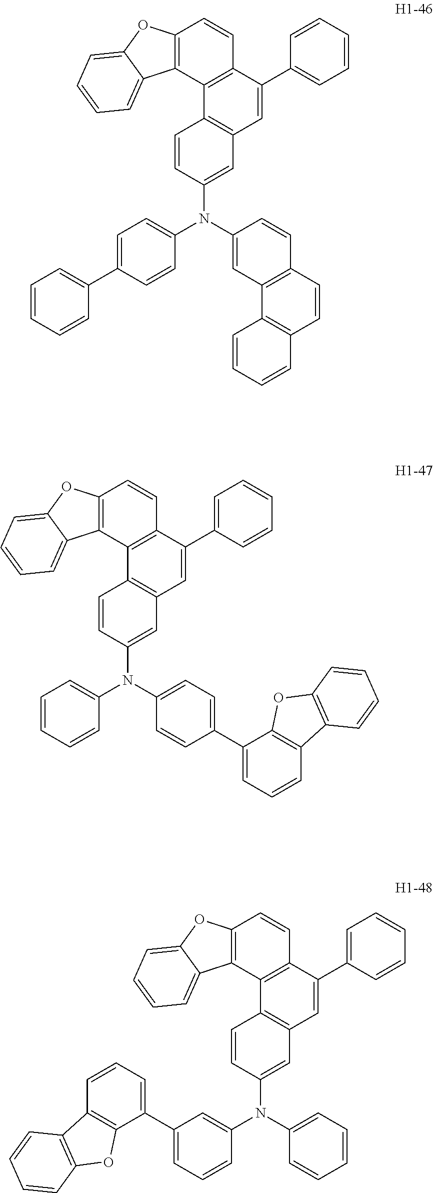 [SMILES: c1ccc(-c2ccc(N(c3ccc4c(c3)cc(-c3ccccc3)c3ccc5oc6ccccc6c5c34)c3ccc4ccc5ccccc5c4c3)cc2)cc1 ; c1ccc(-c2cc3cc(N(c4ccccc4)c4ccc(-c5cccc6c5oc5ccccc56)cc4)ccc3c3c2ccc2oc4ccccc4c23)cc1 ; c1ccc(-c2cc3cc(N(c4ccccc4)c4cccc(-c5cccc6c5oc5ccccc56)c4)ccc3c3c2ccc2oc4ccccc4c23)cc1]

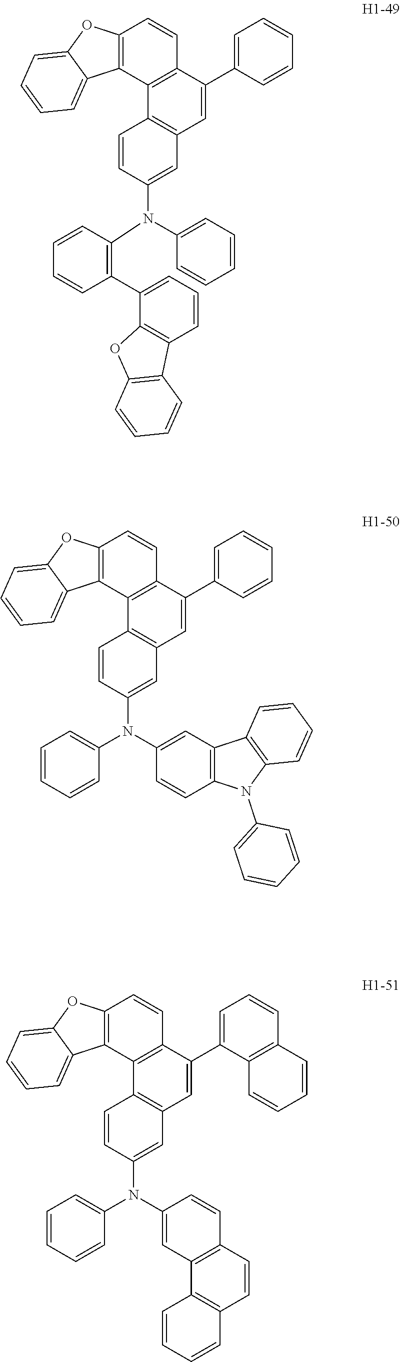 [SMILES: c1ccc(-c2cc3cc(N(c4ccccc4)c4ccccc4-c4cccc5c4oc4ccccc45)ccc3c3c2ccc2oc4ccccc4c23)cc1 ; c1ccc(-c2cc3cc(N(c4ccccc4)c4ccc5c(c4)c4ccccc4n5-c4ccccc4)ccc3c3c2ccc2oc4ccccc4c23)cc1 ; c1ccc(N(c2ccc3c(c2)cc(-c2cccc4ccccc24)c2ccc4oc5ccccc5c4c23)c2ccc3ccc4ccccc4c3c2)cc1]

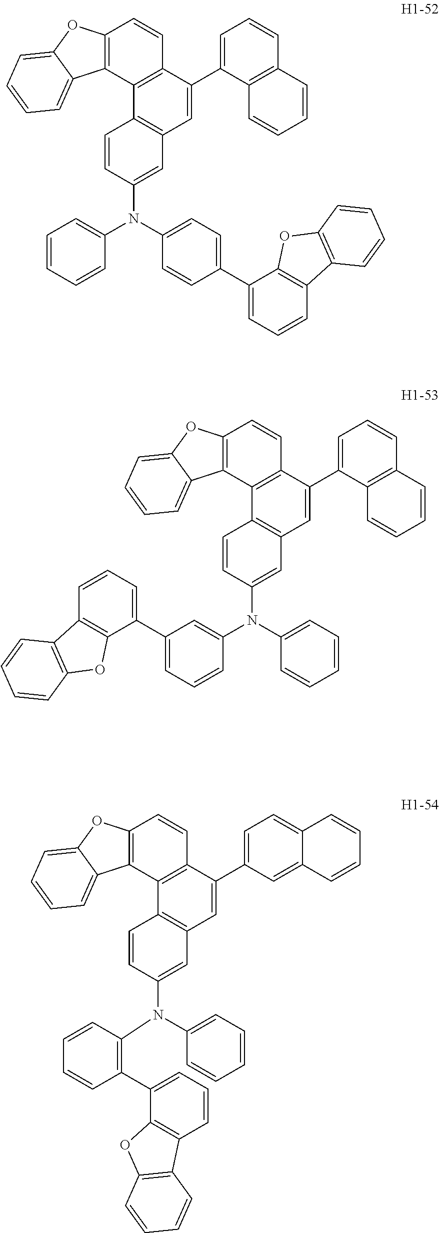 [SMILES: c1ccc(N(c2ccc(-c3cccc4c3oc3ccccc34)cc2)c2ccc3c(c2)cc(-c2cccc4ccccc24)c2ccc4oc5ccccc5c4c23)cc1 ; c1ccc(N(c2cccc(-c3cccc4c3oc3ccccc34)c2)c2ccc3c(c2)cc(-c2cccc4ccccc24)c2ccc4oc5ccccc5c4c23)cc1 ; c1ccc(N(c2ccc3c(c2)cc(-c2ccc4ccccc4c2)c2ccc4oc5ccccc5c4c23)c2ccccc2-c2cccc3c2oc2ccccc23)cc1]

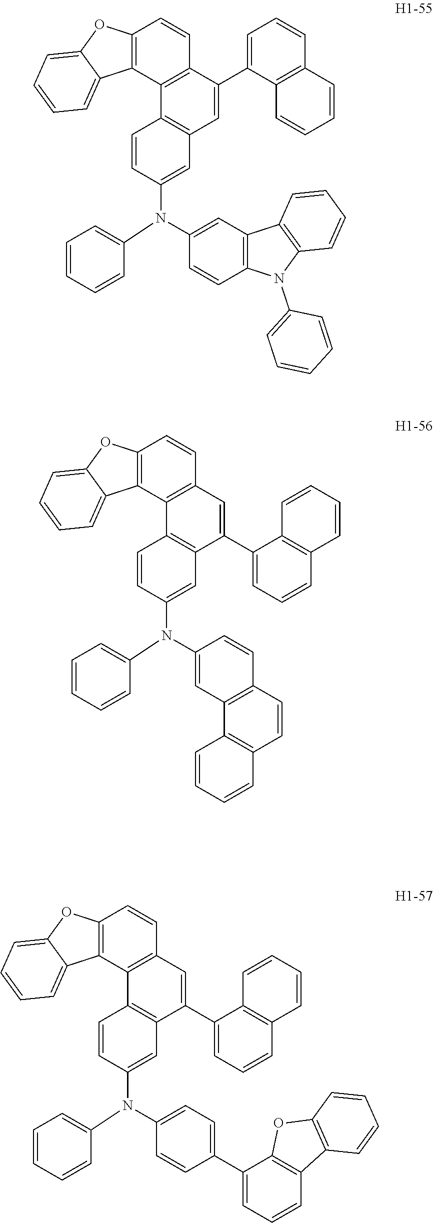 [SMILES: c1ccc(N(c2ccc3c(c2)cc(-c2cccc4ccccc24)c2ccc4oc5ccccc5c4c23)c2ccc3c(c2)c2ccccc2n3-c2ccccc2)cc1 ; c1ccc(N(c2ccc3c(c2)c(-c2cccc4ccccc24)cc2ccc4oc5ccccc5c4c23)c2ccc3ccc4ccccc4c3c2)cc1 ; c1ccc(N(c2ccc(-c3cccc4c3oc3ccccc34)cc2)c2ccc3c(c2)c(-c2cccc4ccccc24)cc2ccc4oc5ccccc5c4c23)cc1]

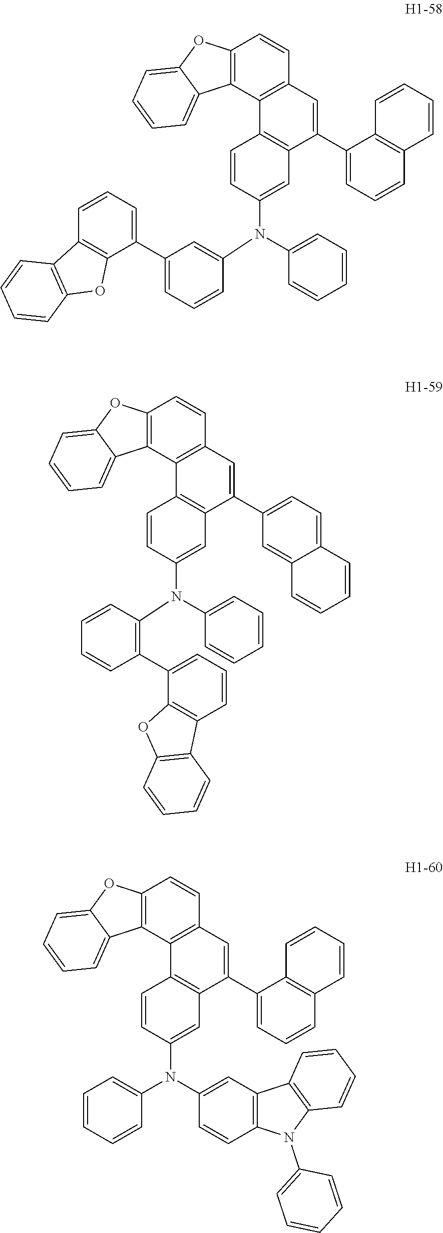 [SMILES: c1ccc(N(c2cccc(-c3cccc4c3oc3ccccc34)c2)c2ccc3c(c2)c(-c2cccc4ccccc24)cc2ccc4oc5ccccc5c4c23)cc1 ; c1ccc(N(c2ccc3c(c2)c(-c2ccc4ccccc4c2)cc2ccc4oc5ccccc5c4c23)c2ccccc2-c2cccc3c2oc2ccccc23)cc1 ; c1ccc(N(c2ccc3c(c2)c(-c2cccc4ccccc24)cc2ccc4oc5ccccc5c4c23)c2ccc3c(c2)c2ccccc2n3-c2ccccc2)cc1]

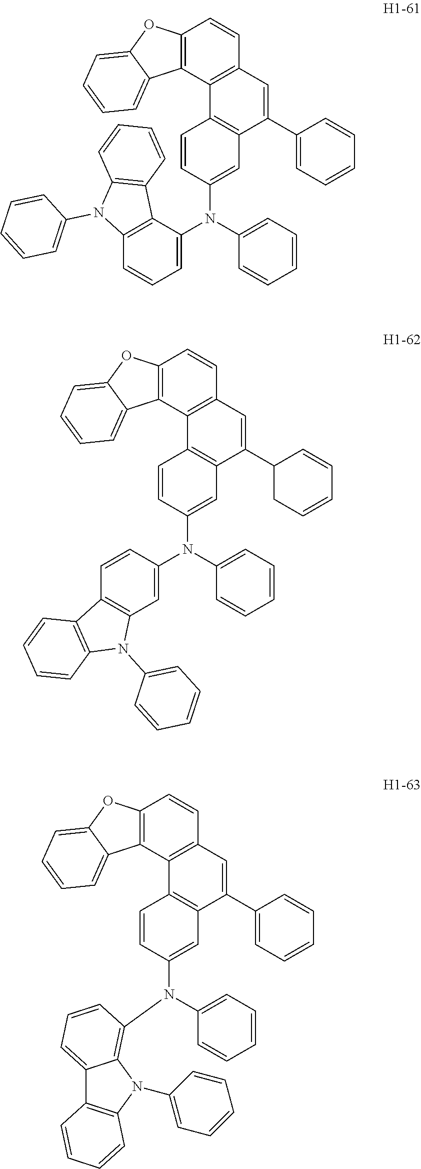 [SMILES: c1ccc(-c2cc3ccc4oc5ccccc5c4c3c3ccc(N(c4ccccc4)c4cccc5c4c4ccccc4n5-c4ccccc4)cc23)cc1 ; C1=CCC(c2cc3ccc4oc5ccccc5c4c3c3ccc(N(c4ccccc4)c4ccc5c6ccccc6n(-c6ccccc6)c5c4)cc23)C=C1 ; c1ccc(-c2cc3ccc4oc5ccccc5c4c3c3ccc(N(c4ccccc4)c4cccc5c6ccccc6n(-c6ccccc6)c45)cc23)cc1]

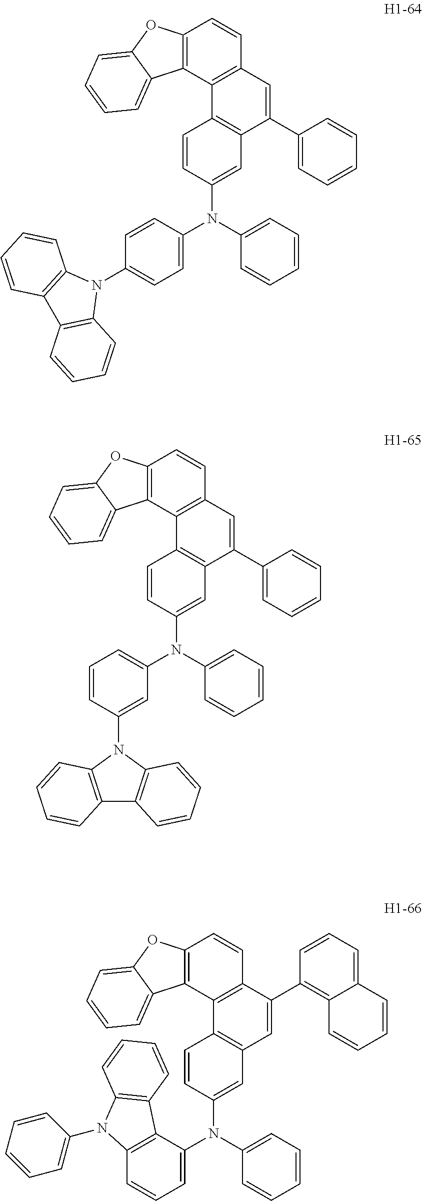 [SMILES: c1ccc(-c2cc3ccc4oc5ccccc5c4c3c3ccc(N(c4ccccc4)c4ccc(-n5c6ccccc6c6ccccc65)cc4)cc23)cc1 ; c1ccc(-c2cc3ccc4oc5ccccc5c4c3c3ccc(N(c4ccccc4)c4cccc(-n5c6ccccc6c6ccccc65)c4)cc23)cc1 ; c1ccc(N(c2ccc3c(c2)cc(-c2cccc4ccccc24)c2ccc4oc5ccccc5c4c23)c2cccc3c2c2ccccc2n3-c2ccccc2)cc1]

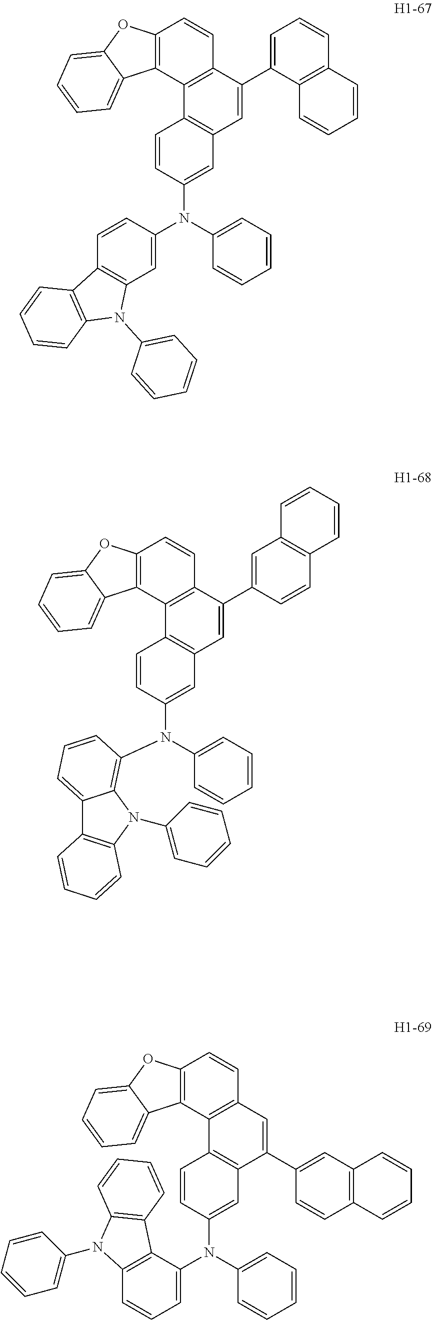 [SMILES: c1ccc(N(c2ccc3c(c2)cc(-c2cccc4ccccc24)c2ccc4oc5ccccc5c4c23)c2ccc3c4ccccc4n(-c4ccccc4)c3c2)cc1 ; c1ccc(N(c2ccc3c(c2)cc(-c2ccc4ccccc4c2)c2ccc4oc5ccccc5c4c23)c2cccc3c4ccccc4n(-c4ccccc4)c23)cc1 ; c1ccc(N(c2ccc3c(c2)c(-c2ccc4ccccc4c2)cc2ccc4oc5ccccc5c4c23)c2cccc3c2c2ccccc2n3-c2ccccc2)cc1]

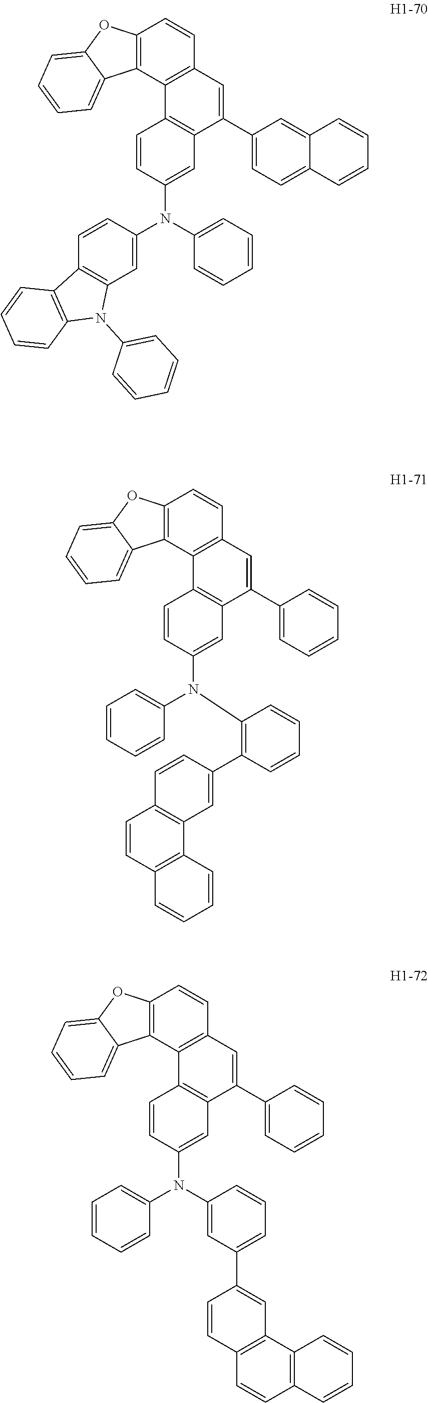 [SMILES: c1ccc(N(c2ccc3c(c2)c(-c2ccc4ccccc4c2)cc2ccc4oc5ccccc5c4c23)c2ccc3c4ccccc4n(-c4ccccc4)c3c2)cc1 ; c1ccc(-c2cc3ccc4oc5ccccc5c4c3c3ccc(N(c4ccccc4)c4ccccc4-c4ccc5ccc6ccccc6c5c4)cc23)cc1 ; c1ccc(-c2cc3ccc4oc5ccccc5c4c3c3ccc(N(c4ccccc4)c4cccc(-c5ccc6ccc7ccccc7c6c5)c4)cc23)cc1]

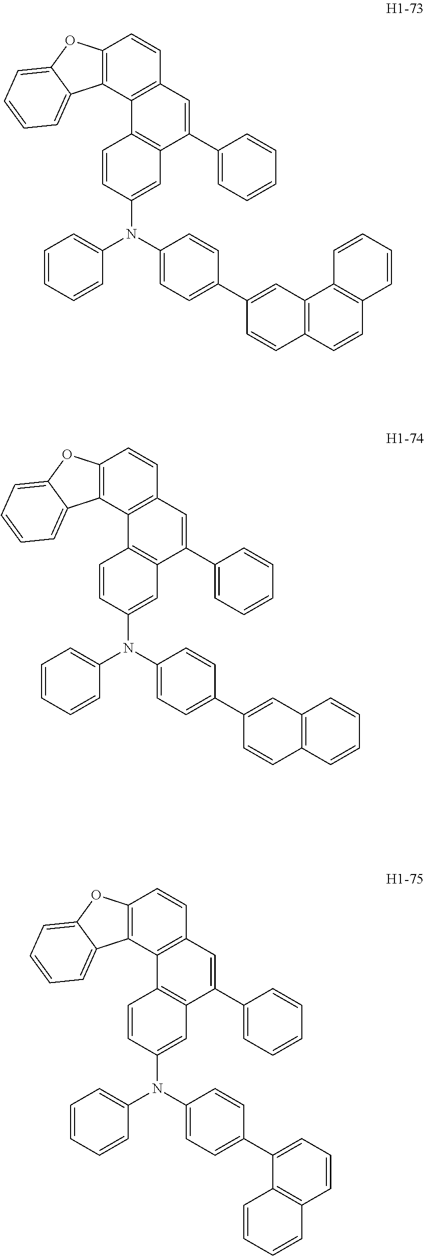 [SMILES: c1ccc(-c2cc3ccc4oc5ccccc5c4c3c3ccc(N(c4ccccc4)c4ccc(-c5ccc6ccc7ccccc7c6c5)cc4)cc23)cc1 ; c1ccc(-c2cc3ccc4oc5ccccc5c4c3c3ccc(N(c4ccccc4)c4ccc(-c5ccc6ccccc6c5)cc4)cc23)cc1 ; c1ccc(-c2cc3ccc4oc5ccccc5c4c3c3ccc(N(c4ccccc4)c4ccc(-c5cccc6ccccc56)cc4)cc23)cc1]

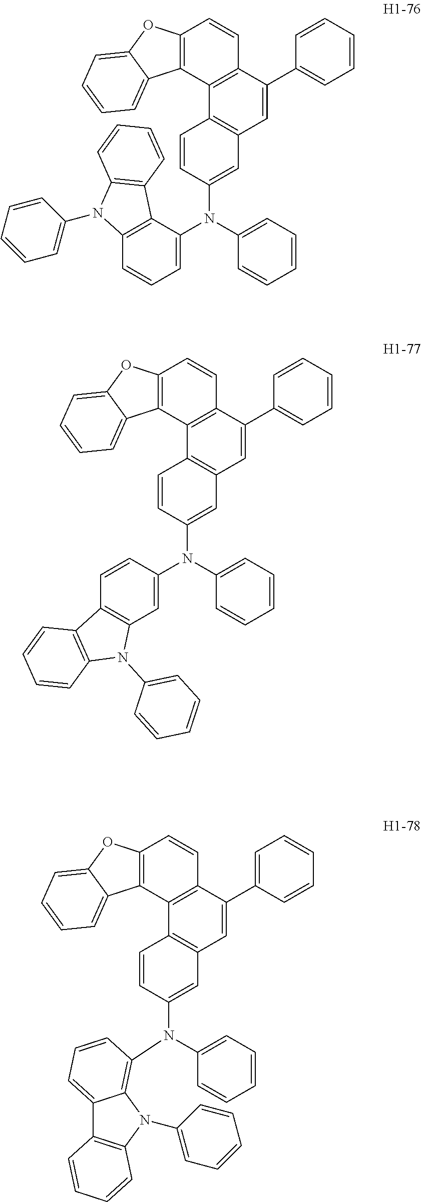 [SMILES: c1ccc(-c2cc3cc(N(c4ccccc4)c4cccc5c4c4ccccc4n5-c4ccccc4)ccc3c3c2ccc2oc4ccccc4c23)cc1 ; c1ccc(-c2cc3cc(N(c4ccccc4)c4ccc5c6ccccc6n(-c6ccccc6)c5c4)ccc3c3c2ccc2oc4ccccc4c23)cc1 ; c1ccc(-c2cc3cc(N(c4ccccc4)c4cccc5c6ccccc6n(-c6ccccc6)c45)ccc3c3c2ccc2oc4ccccc4c23)cc1]

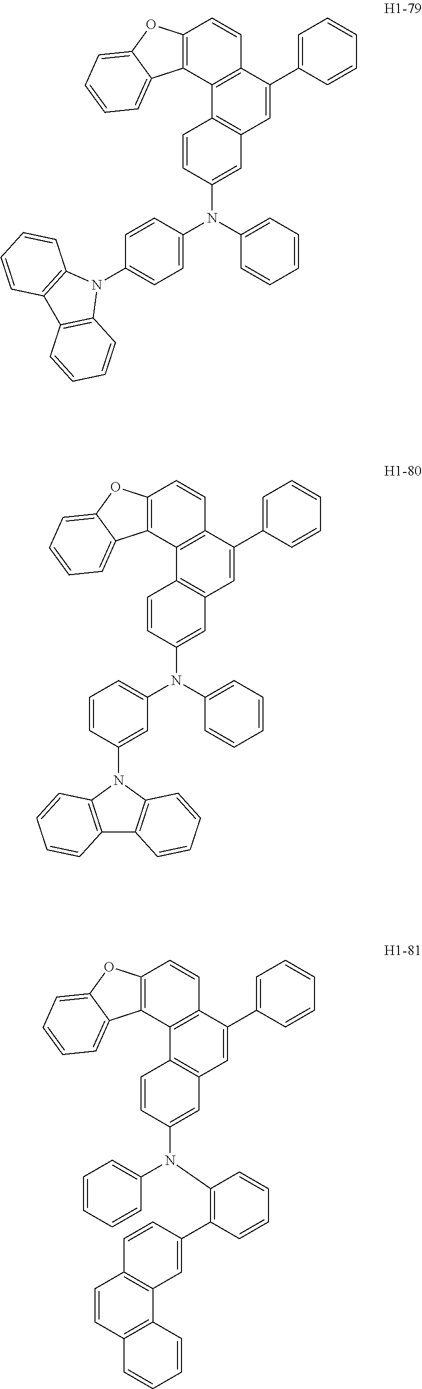 [SMILES: c1ccc(-c2cc3cc(N(c4ccccc4)c4ccc(-n5c6ccccc6c6ccccc65)cc4)ccc3c3c2ccc2oc4ccccc4c23)cc1 ; c1ccc(-c2cc3cc(N(c4ccccc4)c4cccc(-n5c6ccccc6c6ccccc65)c4)ccc3c3c2ccc2oc4ccccc4c23)cc1 ; c1ccc(-c2cc3cc(N(c4ccccc4)c4ccccc4-c4ccc5ccc6ccccc6c5c4)ccc3c3c2ccc2oc4ccccc4c23)cc1]

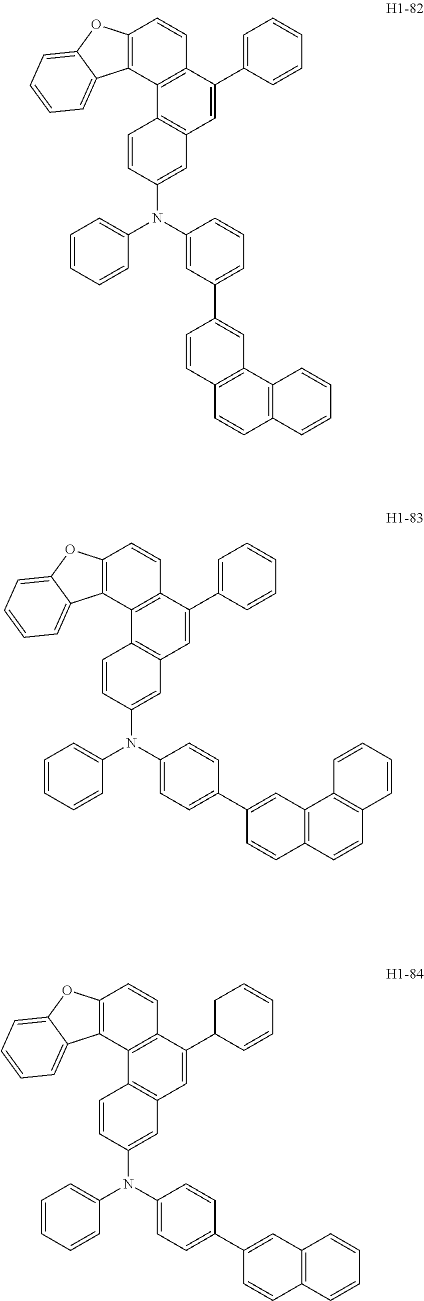 [SMILES: c1ccc(-c2cc3cc(N(c4ccccc4)c4cccc(-c5ccc6ccc7ccccc7c6c5)c4)ccc3c3c2ccc2oc4ccccc4c23)cc1 ; c1ccc(-c2cc3cc(N(c4ccccc4)c4ccc(-c5ccc6ccc7ccccc7c6c5)cc4)ccc3c3c2ccc2oc4ccccc4c23)cc1 ; C1=CCC(c2cc3cc(N(c4ccccc4)c4ccc(-c5ccc6ccccc6c5)cc4)ccc3c3c2ccc2oc4ccccc4c23)C=C1]

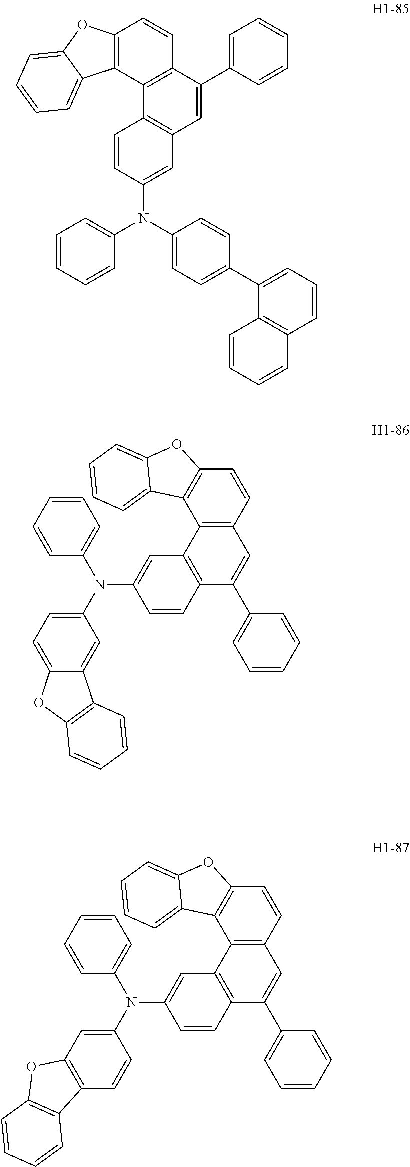 [SMILES: c1ccc(-c2cc3cc(N(c4ccccc4)c4ccc(-c5cccc6ccccc56)cc4)ccc3c3c2ccc2oc4ccccc4c23)cc1 ; c1ccc(-c2cc3ccc4oc5ccccc5c4c3c3cc(N(c4ccccc4)c4ccc5oc6ccccc6c5c4)ccc23)cc1 ; c1ccc(-c2cc3ccc4oc5ccccc5c4c3c3cc(N(c4ccccc4)c4ccc5c(c4)oc4ccccc45)ccc23)cc1]

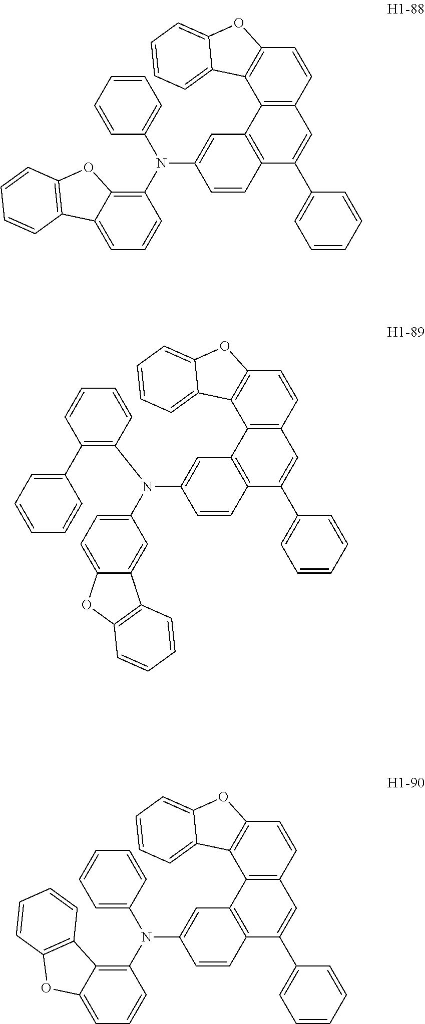 [SMILES: c1ccc(-c2cc3ccc4oc5ccccc5c4c3c3cc(N(c4ccccc4)c4cccc5c4oc4ccccc45)ccc23)cc1 ; c1ccc(-c2ccccc2N(c2ccc3oc4ccccc4c3c2)c2ccc3c(-c4ccccc4)cc4ccc5oc6ccccc6c5c4c3c2)cc1 ; c1ccc(-c2cc3ccc4oc5ccccc5c4c3c3cc(N(c4ccccc4)c4cccc5oc6ccccc6c45)ccc23)cc1]

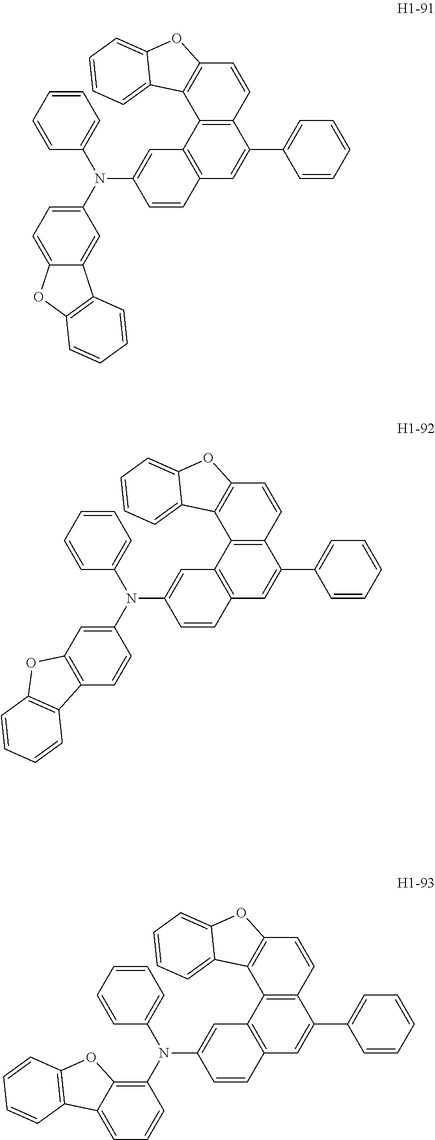 [SMILES: c1ccc(-c2cc3ccc(N(c4ccccc4)c4ccc5oc6ccccc6c5c4)cc3c3c2ccc2oc4ccccc4c23)cc1 ; c1ccc(-c2cc3ccc(N(c4ccccc4)c4ccc5c(c4)oc4ccccc45)cc3c3c2ccc2oc4ccccc4c23)cc1 ; c1ccc(-c2cc3ccc(N(c4ccccc4)c4cccc5c4oc4ccccc45)cc3c3c2ccc2oc4ccccc4c23)cc1]

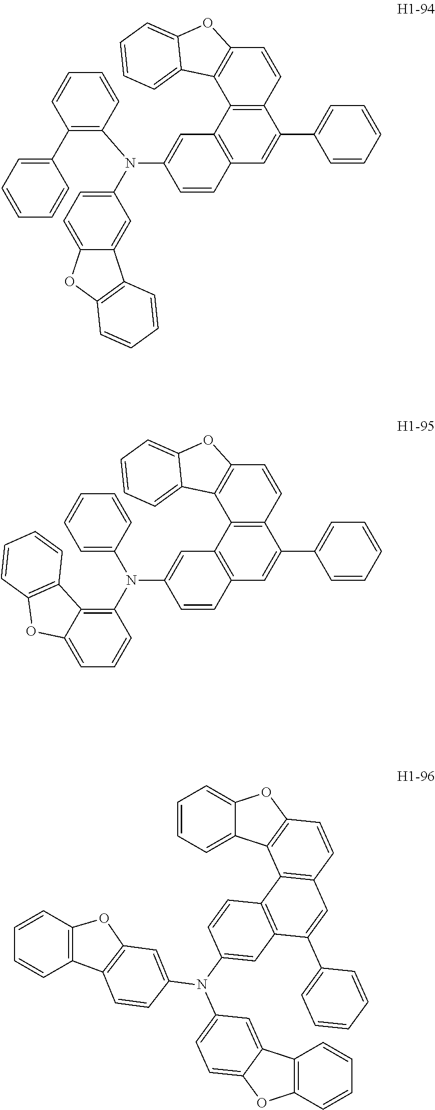 [SMILES: c1ccc(-c2ccccc2N(c2ccc3oc4ccccc4c3c2)c2ccc3cc(-c4ccccc4)c4ccc5oc6ccccc6c5c4c3c2)cc1 ; c1ccc(-c2cc3ccc(N(c4ccccc4)c4cccc5oc6ccccc6c45)cc3c3c2ccc2oc4ccccc4c23)cc1 ; c1ccc(-c2cc3ccc4oc5ccccc5c4c3c3ccc(N(c4ccc5c(c4)oc4ccccc45)c4ccc5oc6ccccc6c5c4)cc23)cc1]

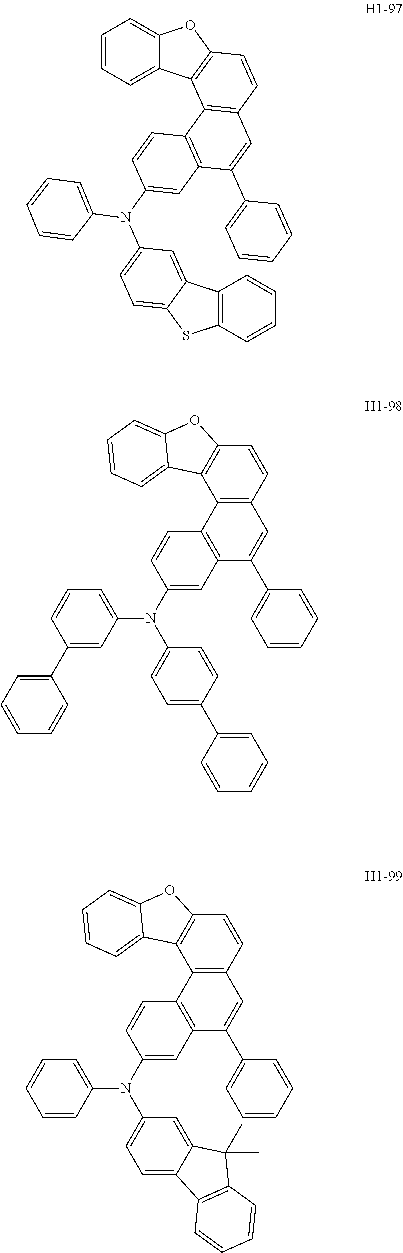 [SMILES: c1ccc(-c2cc3ccc4oc5ccccc5c4c3c3ccc(N(c4ccccc4)c4ccc5sc6ccccc6c5c4)cc23)cc1 ; c1ccc(-c2ccc(N(c3cccc(-c4ccccc4)c3)c3ccc4c(c3)c(-c3ccccc3)cc3ccc5oc6ccccc6c5c34)cc2)cc1 ; CC1(C)c2ccccc2-c2ccc(N(c3ccccc3)c3ccc4c(c3)c(-c3ccccc3)cc3ccc5oc6ccccc6c5c34)cc21]

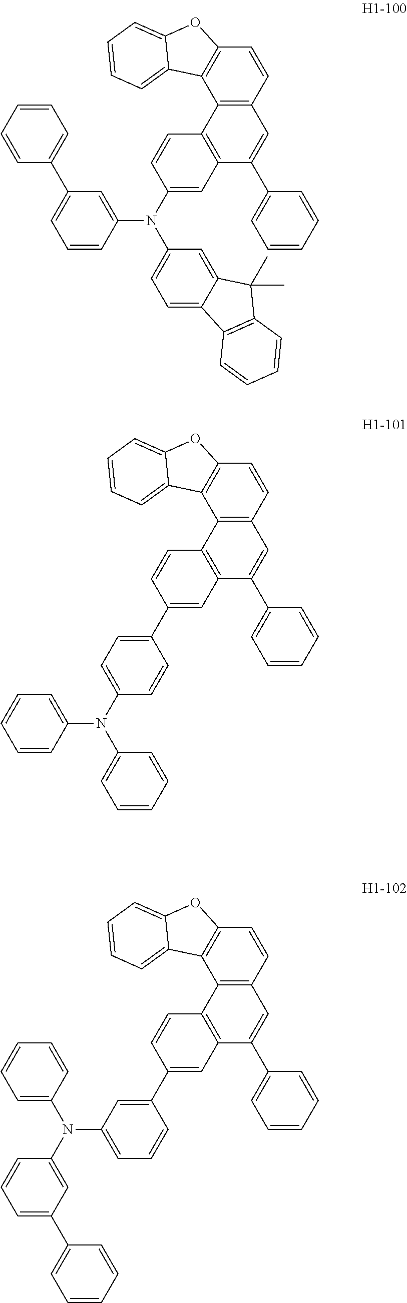 [SMILES: CC1(C)c2ccccc2-c2ccc(N(c3cccc(-c4ccccc4)c3)c3ccc4c(c3)c(-c3ccccc3)cc3ccc5oc6ccccc6c5c34)cc21 ; c1ccc(-c2cc3ccc4oc5ccccc5c4c3c3ccc(-c4ccc(N(c5ccccc5)c5ccccc5)cc4)cc23)cc1 ; c1ccc(-c2cccc(N(c3ccccc3)c3cccc(-c4ccc5c(c4)c(-c4ccccc4)cc4ccc6oc7ccccc7c6c45)c3)c2)cc1]

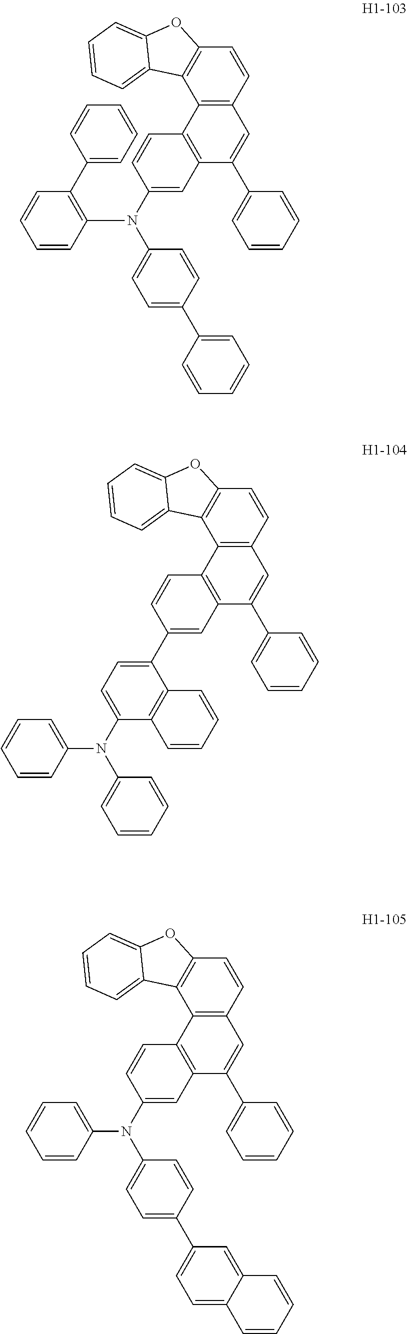 [SMILES: c1ccc(-c2ccc(N(c3ccc4c(c3)c(-c3ccccc3)cc3ccc5oc6ccccc6c5c34)c3ccccc3-c3ccccc3)cc2)cc1 ; c1ccc(-c2cc3ccc4oc5ccccc5c4c3c3ccc(-c4ccc(N(c5ccccc5)c5ccccc5)c5ccccc45)cc23)cc1 ; c1ccc(-c2cc3ccc4oc5ccccc5c4c3c3ccc(N(c4ccccc4)c4ccc(-c5ccc6ccccc6c5)cc4)cc23)cc1]

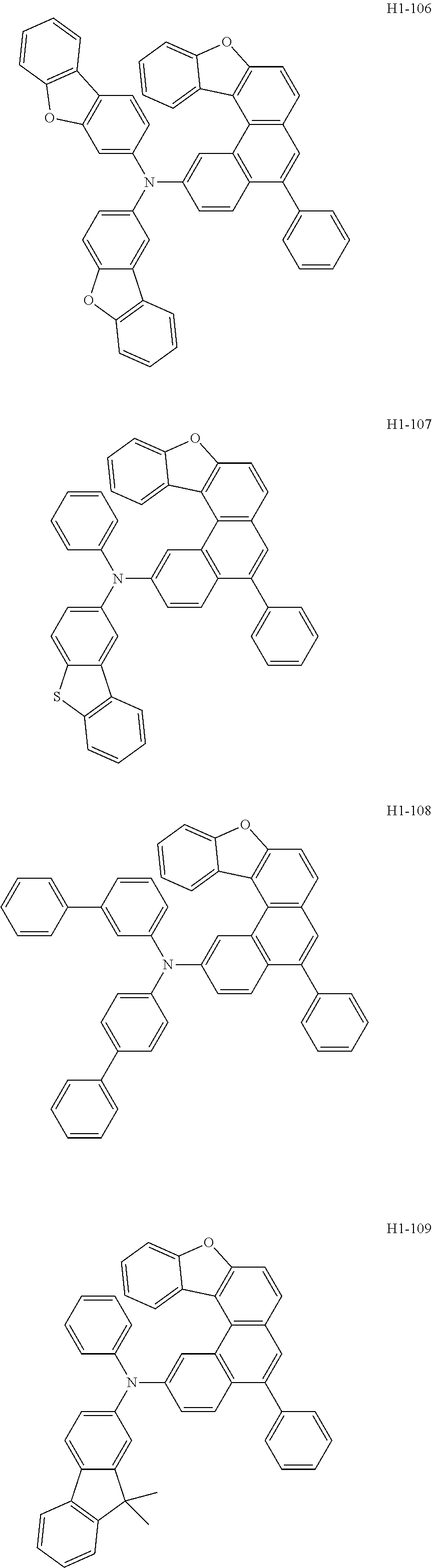 [SMILES: c1ccc(-c2cc3ccc4oc5ccccc5c4c3c3cc(N(c4ccc5c(c4)oc4ccccc45)c4ccc5oc6ccccc6c5c4)ccc23)cc1 ; c1ccc(-c2cc3ccc4oc5ccccc5c4c3c3cc(N(c4ccccc4)c4ccc5sc6ccccc6c5c4)ccc23)cc1 ; c1ccc(-c2ccc(N(c3cccc(-c4ccccc4)c3)c3ccc4c(-c5ccccc5)cc5ccc6oc7ccccc7c6c5c4c3)cc2)cc1 ; CC1(C)c2ccccc2-c2ccc(N(c3ccccc3)c3ccc4c(-c5ccccc5)cc5ccc6oc7ccccc7c6c5c4c3)cc21]

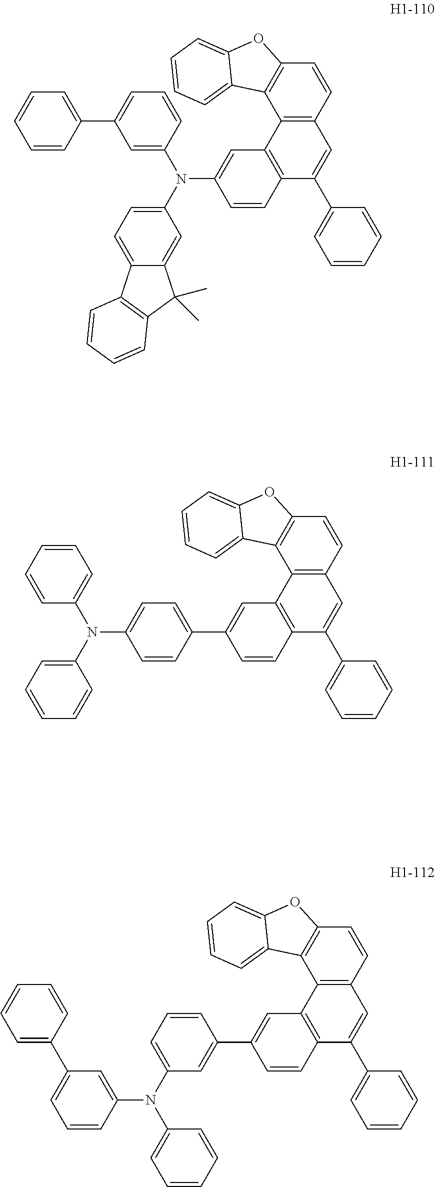 [SMILES: CC1(C)c2ccccc2-c2ccc(N(c3cccc(-c4ccccc4)c3)c3ccc4c(-c5ccccc5)cc5ccc6oc7ccccc7c6c5c4c3)cc21 ; c1ccc(-c2cc3ccc4oc5ccccc5c4c3c3cc(-c4ccc(N(c5ccccc5)c5ccccc5)cc4)ccc23)cc1 ; c1ccc(-c2cccc(N(c3ccccc3)c3cccc(-c4ccc5c(-c6ccccc6)cc6ccc7oc8ccccc8c7c6c5c4)c3)c2)cc1]

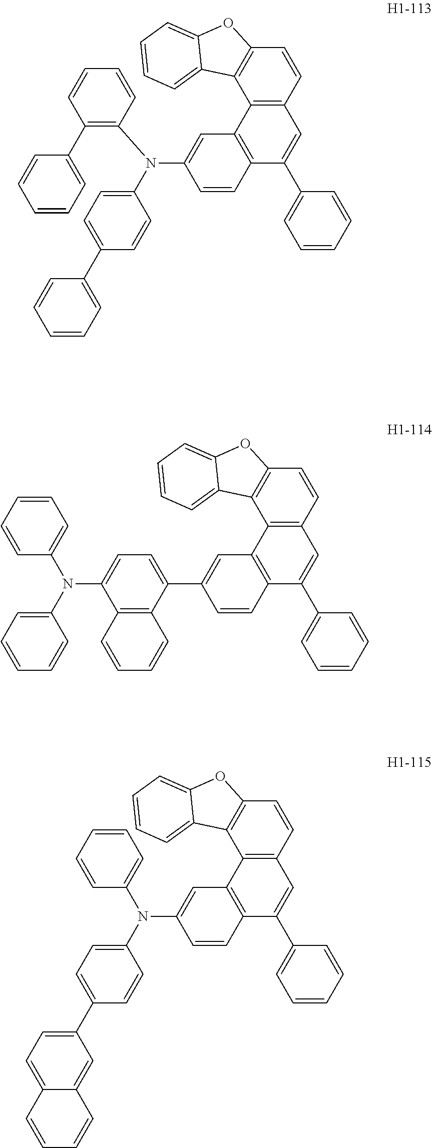 [SMILES: c1ccc(-c2ccc(N(c3ccc4c(-c5ccccc5)cc5ccc6oc7ccccc7c6c5c4c3)c3ccccc3-c3ccccc3)cc2)cc1 ; c1ccc(-c2cc3ccc4oc5ccccc5c4c3c3cc(-c4ccc(N(c5ccccc5)c5ccccc5)c5ccccc45)ccc23)cc1 ; c1ccc(-c2cc3ccc4oc5ccccc5c4c3c3cc(N(c4ccccc4)c4ccc(-c5ccc6ccccc6c5)cc4)ccc23)cc1]

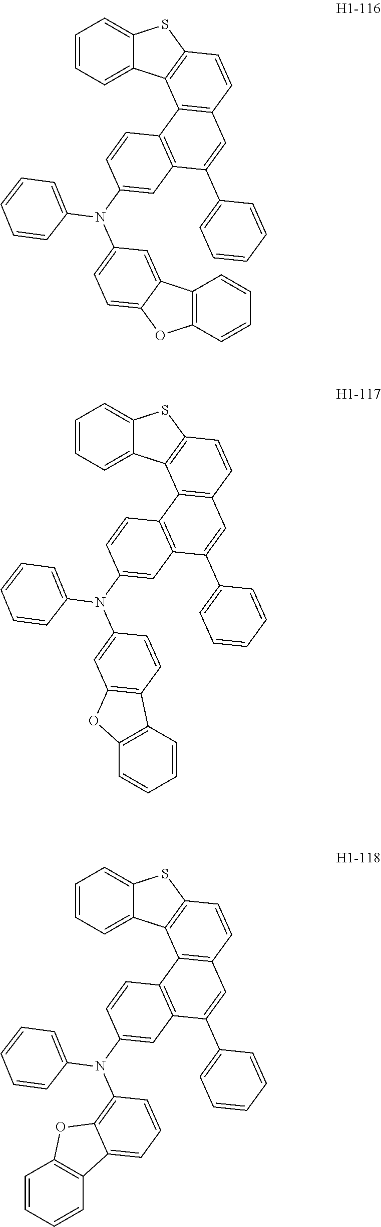 [SMILES: c1ccc(-c2cc3ccc4sc5ccccc5c4c3c3ccc(N(c4ccccc4)c4ccc5oc6ccccc6c5c4)cc23)cc1 ; c1ccc(-c2cc3ccc4sc5ccccc5c4c3c3ccc(N(c4ccccc4)c4ccc5c(c4)oc4ccccc45)cc23)cc1 ; c1ccc(-c2cc3ccc4sc5ccccc5c4c3c3ccc(N(c4ccccc4)c4cccc5c4oc4ccccc45)cc23)cc1]

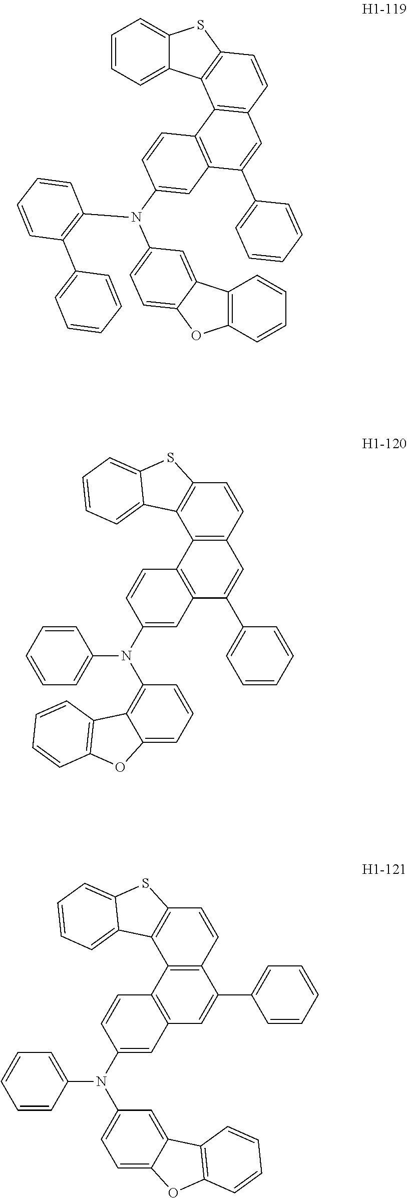 [SMILES: c1ccc(-c2ccccc2N(c2ccc3c(c2)c(-c2ccccc2)cc2ccc4sc5ccccc5c4c23)c2ccc3oc4ccccc4c3c2)cc1 ; c1ccc(-c2cc3ccc4sc5ccccc5c4c3c3ccc(N(c4ccccc4)c4cccc5oc6ccccc6c45)cc23)cc1 ; c1ccc(-c2cc3cc(N(c4ccccc4)c4ccc5oc6ccccc6c5c4)ccc3c3c2ccc2sc4ccccc4c23)cc1]

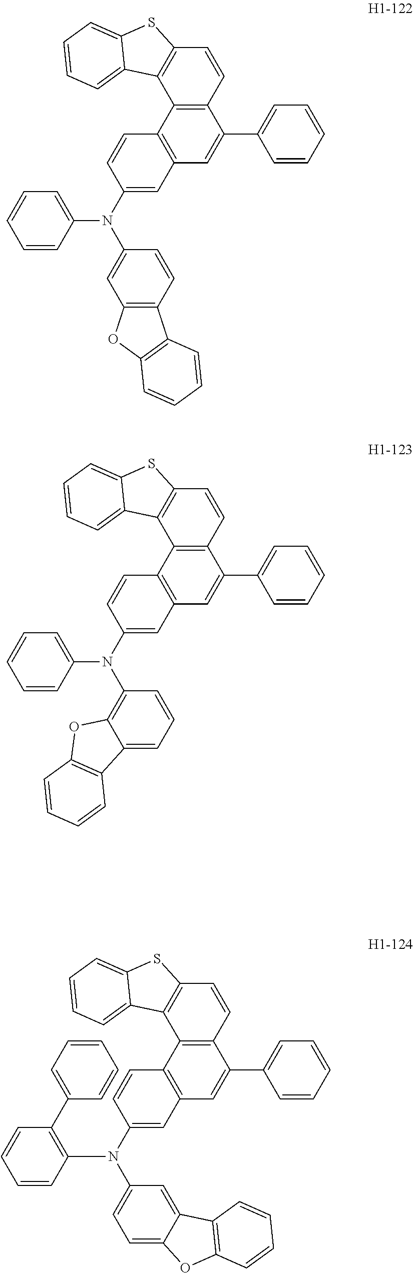 [SMILES: c1ccc(-c2cc3cc(N(c4ccccc4)c4ccc5c(c4)oc4ccccc45)ccc3c3c2ccc2sc4ccccc4c23)cc1 ; c1ccc(-c2cc3cc(N(c4ccccc4)c4cccc5c4oc4ccccc45)ccc3c3c2ccc2sc4ccccc4c23)cc1 ; c1ccc(-c2ccccc2N(c2ccc3c(c2)cc(-c2ccccc2)c2ccc4sc5ccccc5c4c23)c2ccc3oc4ccccc4c3c2)cc1]

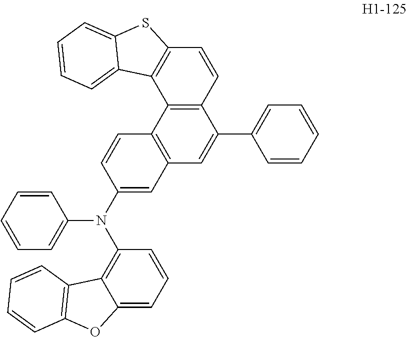 [SMILES: c1ccc(-c2cc3cc(N(c4ccccc4)c4cccc5oc6ccccc6c45)ccc3c3c2ccc2sc4ccccc4c23)cc1]

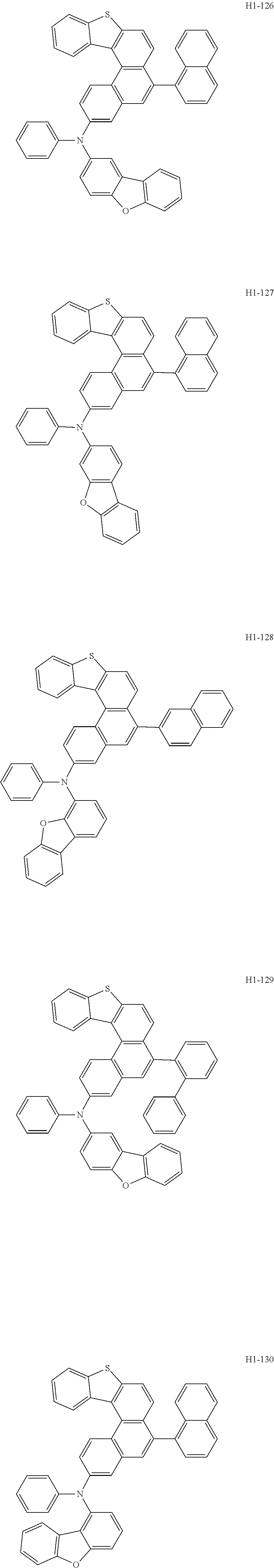 [SMILES: c1ccc(N(c2ccc3c(c2)cc(-c2cccc4ccccc24)c2ccc4sc5ccccc5c4c23)c2ccc3oc4ccccc4c3c2)cc1 ; c1ccc(N(c2ccc3c(c2)cc(-c2cccc4ccccc24)c2ccc4sc5ccccc5c4c23)c2ccc3c(c2)oc2ccccc23)cc1 ; c1ccc(N(c2ccc3c(c2)cc(-c2ccc4ccccc4c2)c2ccc4sc5ccccc5c4c23)c2cccc3c2oc2ccccc23)cc1 ; c1ccc(-c2ccccc2-c2cc3cc(N(c4ccccc4)c4ccc5oc6ccccc6c5c4)ccc3c3c2ccc2sc4ccccc4c23)cc1 ; c1ccc(N(c2ccc3c(c2)cc(-c2cccc4ccccc24)c2ccc4sc5ccccc5c4c23)c2cccc3oc4ccccc4c23)cc1]

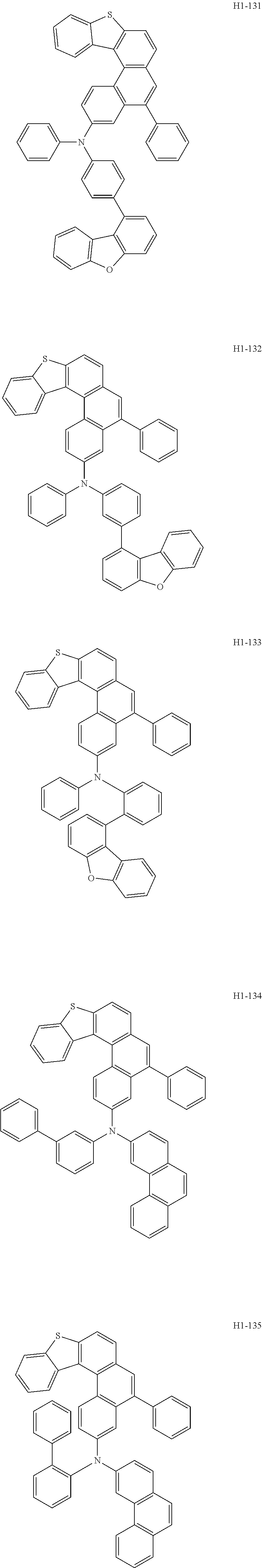 [SMILES: c1ccc(-c2cc3ccc4sc5ccccc5c4c3c3ccc(N(c4ccccc4)c4ccc(-c5cccc6oc7ccccc7c56)cc4)cc23)cc1 ; c1ccc(-c2cc3ccc4sc5ccccc5c4c3c3ccc(N(c4ccccc4)c4cccc(-c5cccc6oc7ccccc7c56)c4)cc23)cc1 ; c1ccc(-c2cc3ccc4sc5ccccc5c4c3c3ccc(N(c4ccccc4)c4ccccc4-c4cccc5oc6ccccc6c45)cc23)cc1 ; c1ccc(-c2cccc(N(c3ccc4c(c3)c(-c3ccccc3)cc3ccc5sc6ccccc6c5c34)c3ccc4ccc5ccccc5c4c3)c2)cc1 ; c1ccc(-c2ccccc2N(c2ccc3c(c2)c(-c2ccccc2)cc2ccc4sc5ccccc5c4c23)c2ccc3ccc4ccccc4c3c2)cc1]

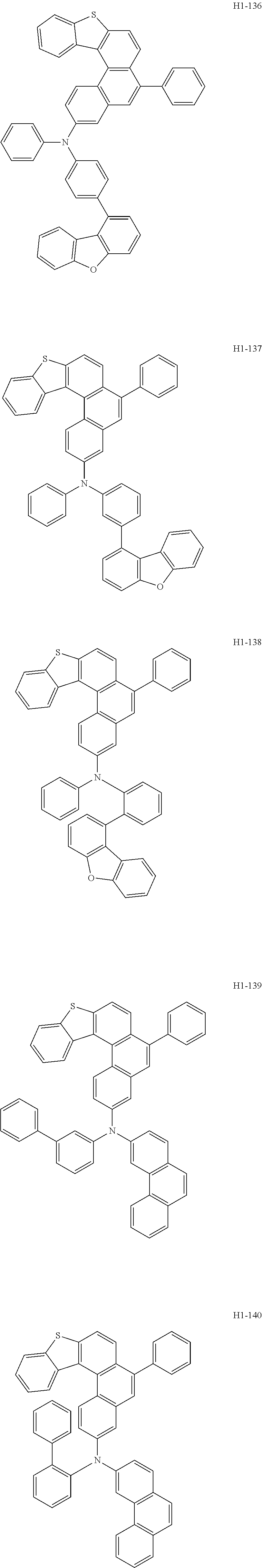 [SMILES: c1ccc(-c2cc3cc(N(c4ccccc4)c4ccc(-c5cccc6oc7ccccc7c56)cc4)ccc3c3c2ccc2sc4ccccc4c23)cc1 ; c1ccc(-c2cc3cc(N(c4ccccc4)c4cccc(-c5cccc6oc7ccccc7c56)c4)ccc3c3c2ccc2sc4ccccc4c23)cc1 ; c1ccc(-c2cc3cc(N(c4ccccc4)c4ccccc4-c4cccc5oc6ccccc6c45)ccc3c3c2ccc2sc4ccccc4c23)cc1 ; c1ccc(-c2cccc(N(c3ccc4c(c3)cc(-c3ccccc3)c3ccc5sc6ccccc6c5c34)c3ccc4ccc5ccccc5c4c3)c2)cc1 ; c1ccc(-c2ccccc2N(c2ccc3c(c2)cc(-c2ccccc2)c2ccc4sc5ccccc5c4c23)c2ccc3ccc4ccccc4c3c2)cc1]

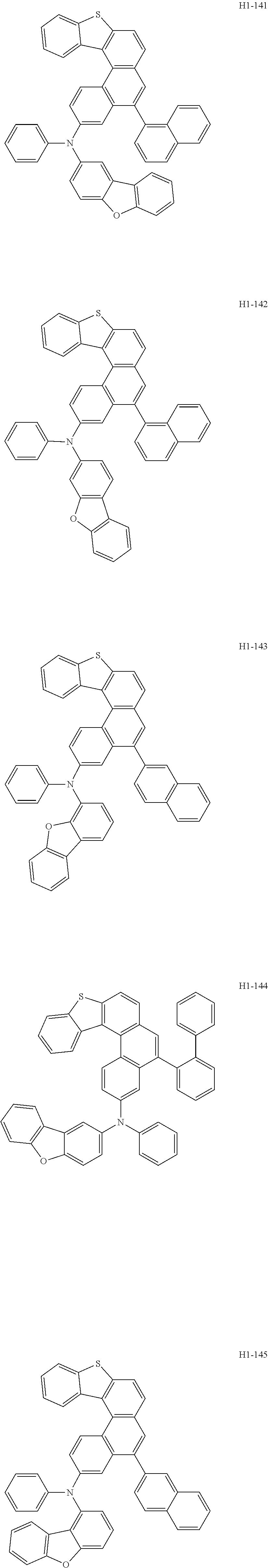 [SMILES: c1ccc(N(c2ccc3c(c2)c(-c2cccc4ccccc24)cc2ccc4sc5ccccc5c4c23)c2ccc3oc4ccccc4c3c2)cc1 ; c1ccc(N(c2ccc3c(c2)oc2ccccc23)c2ccc3c(c2)c(-c2cccc4ccccc24)cc2ccc4sc5ccccc5c4c23)cc1 ; c1ccc(N(c2ccc3c(c2)c(-c2ccc4ccccc4c2)cc2ccc4sc5ccccc5c4c23)c2cccc3c2oc2ccccc23)cc1 ; c1ccc(-c2ccccc2-c2cc3ccc4sc5ccccc5c4c3c3ccc(N(c4ccccc4)c4ccc5oc6ccccc6c5c4)cc23)cc1 ; c1ccc(N(c2ccc3c(c2)c(-c2ccc4ccccc4c2)cc2ccc4sc5ccccc5c4c23)c2cccc3oc4ccccc4c23)cc1]

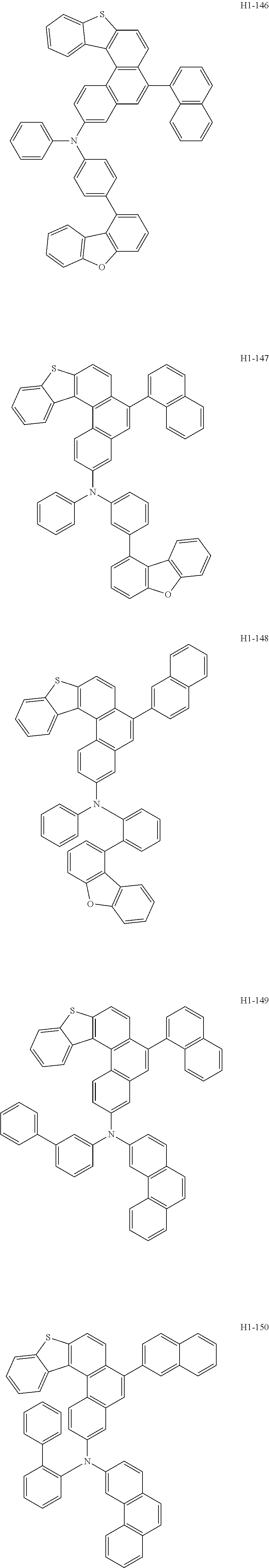 [SMILES: c1ccc(N(c2ccc(-c3cccc4oc5ccccc5c34)cc2)c2ccc3c(c2)cc(-c2cccc4ccccc24)c2ccc4sc5ccccc5c4c23)cc1 ; c1ccc(N(c2cccc(-c3cccc4oc5ccccc5c34)c2)c2ccc3c(c2)cc(-c2cccc4ccccc24)c2ccc4sc5ccccc5c4c23)cc1 ; c1ccc(N(c2ccc3c(c2)cc(-c2ccc4ccccc4c2)c2ccc4sc5ccccc5c4c23)c2ccccc2-c2cccc3oc4ccccc4c23)cc1 ; c1ccc(-c2cccc(N(c3ccc4c(c3)cc(-c3cccc5ccccc35)c3ccc5sc6ccccc6c5c34)c3ccc4ccc5ccccc5c4c3)c2)cc1 ; c1ccc(-c2ccccc2N(c2ccc3c(c2)cc(-c2ccc4ccccc4c2)c2ccc4sc5ccccc5c4c23)c2ccc3ccc4ccccc4c3c2)cc1]

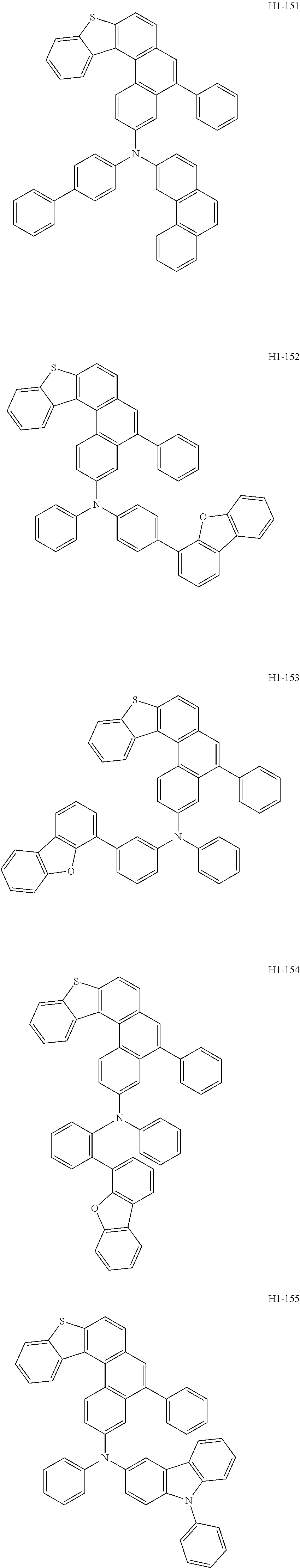 [SMILES: c1ccc(-c2ccc(N(c3ccc4c(c3)c(-c3ccccc3)cc3ccc5sc6ccccc6c5c34)c3ccc4ccc5ccccc5c4c3)cc2)cc1 ; c1ccc(-c2cc3ccc4sc5ccccc5c4c3c3ccc(N(c4ccccc4)c4ccc(-c5cccc6c5oc5ccccc56)cc4)cc23)cc1 ; c1ccc(-c2cc3ccc4sc5ccccc5c4c3c3ccc(N(c4ccccc4)c4cccc(-c5cccc6c5oc5ccccc56)c4)cc23)cc1 ; c1ccc(-c2cc3ccc4sc5ccccc5c4c3c3ccc(N(c4ccccc4)c4ccccc4-c4cccc5c4oc4ccccc45)cc23)cc1 ; c1ccc(-c2cc3ccc4sc5ccccc5c4c3c3ccc(N(c4ccccc4)c4ccc5c(c4)c4ccccc4n5-c4ccccc4)cc23)cc1]

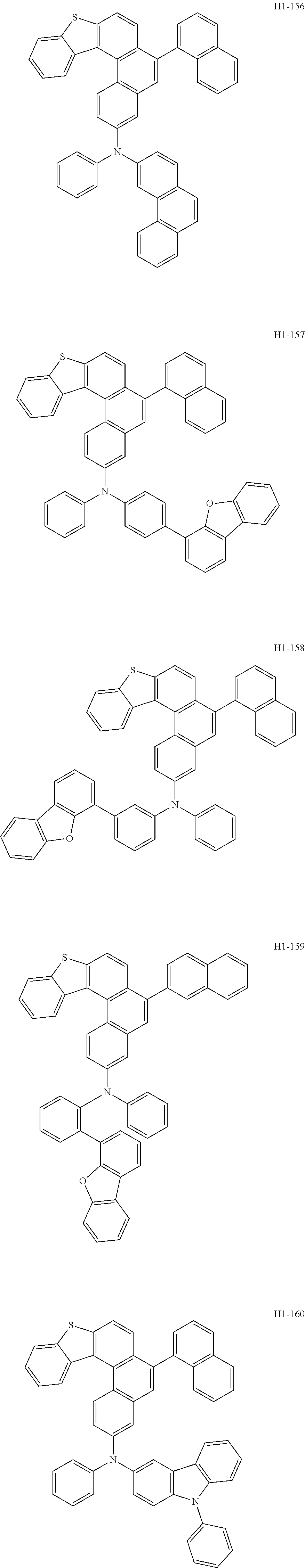 [SMILES: c1ccc(N(c2ccc3c(c2)cc(-c2cccc4ccccc24)c2ccc4sc5ccccc5c4c23)c2ccc3ccc4ccccc4c3c2)cc1 ; c1ccc(N(c2ccc(-c3cccc4c3oc3ccccc34)cc2)c2ccc3c(c2)cc(-c2cccc4ccccc24)c2ccc4sc5ccccc5c4c23)cc1 ; c1ccc(N(c2cccc(-c3cccc4c3oc3ccccc34)c2)c2ccc3c(c2)cc(-c2cccc4ccccc24)c2ccc4sc5ccccc5c4c23)cc1 ; c1ccc(N(c2ccc3c(c2)cc(-c2ccc4ccccc4c2)c2ccc4sc5ccccc5c4c23)c2ccccc2-c2cccc3c2oc2ccccc23)cc1 ; c1ccc(N(c2ccc3c(c2)cc(-c2cccc4ccccc24)c2ccc4sc5ccccc5c4c23)c2ccc3c(c2)c2ccccc2n3-c2ccccc2)cc1]

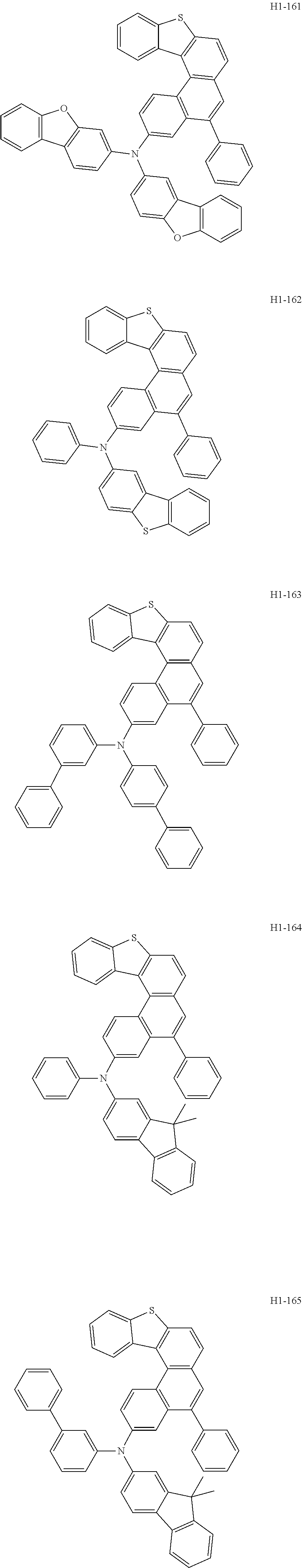 [SMILES: c1ccc(-c2cc3ccc4sc5ccccc5c4c3c3ccc(N(c4ccc5c(c4)oc4ccccc45)c4ccc5oc6ccccc6c5c4)cc23)cc1 ; c1ccc(-c2cc3ccc4sc5ccccc5c4c3c3ccc(N(c4ccccc4)c4ccc5sc6ccccc6c5c4)cc23)cc1 ; c1ccc(-c2ccc(N(c3cccc(-c4ccccc4)c3)c3ccc4c(c3)c(-c3ccccc3)cc3ccc5sc6ccccc6c5c34)cc2)cc1 ; CC1(C)c2ccccc2-c2ccc(N(c3ccccc3)c3ccc4c(c3)c(-c3ccccc3)cc3ccc5sc6ccccc6c5c34)cc21 ; CC1(C)c2ccccc2-c2ccc(N(c3cccc(-c4ccccc4)c3)c3ccc4c(c3)c(-c3ccccc3)cc3ccc5sc6ccccc6c5c34)cc21]

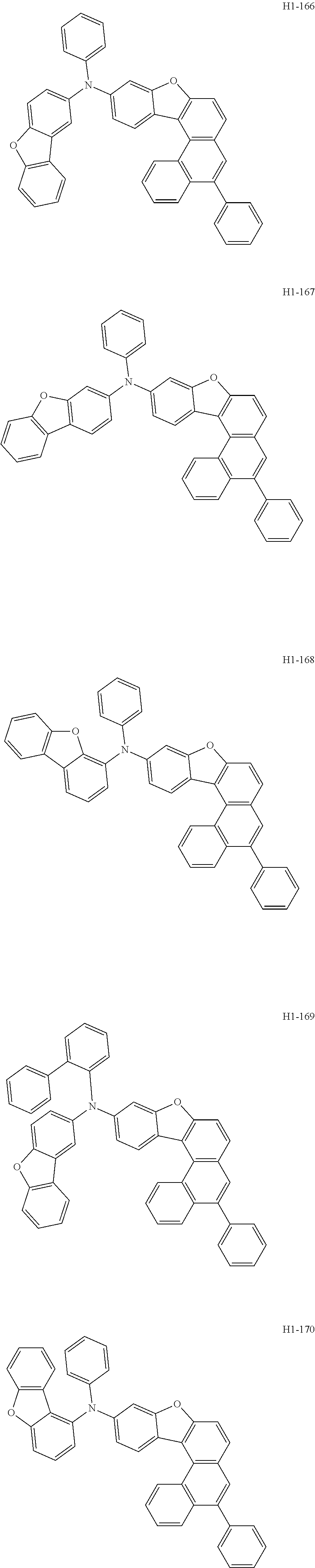 [SMILES: c1ccc(-c2cc3ccc4oc5cc(N(c6ccccc6)c6ccc7oc8ccccc8c7c6)ccc5c4c3c3ccccc23)cc1 ; c1ccc(-c2cc3ccc4oc5cc(N(c6ccccc6)c6ccc7c(c6)oc6ccccc67)ccc5c4c3c3ccccc23)cc1 ; c1ccc(-c2cc3ccc4oc5cc(N(c6ccccc6)c6cccc7c6oc6ccccc67)ccc5c4c3c3ccccc23)cc1 ; c1ccc(-c2ccccc2N(c2ccc3c(c2)oc2ccc4cc(-c5ccccc5)c5ccccc5c4c23)c2ccc3oc4ccccc4c3c2)cc1 ; c1ccc(-c2cc3ccc4oc5cc(N(c6ccccc6)c6cccc7oc8ccccc8c67)ccc5c4c3c3ccccc23)cc1]

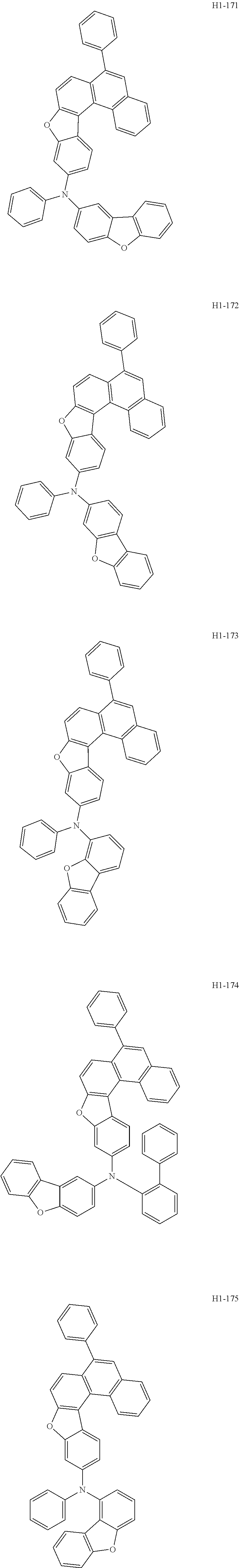 [SMILES: c1ccc(-c2cc3ccccc3c3c2ccc2oc4cc(N(c5ccccc5)c5ccc6oc7ccccc7c6c5)ccc4c23)cc1 ; c1ccc(-c2cc3ccccc3c3c2ccc2oc4cc(N(c5ccccc5)c5ccc6c(c5)oc5ccccc56)ccc4c23)cc1 ; c1ccc(-c2cc3ccccc3c3c2ccc2oc4cc(N(c5ccccc5)c5cccc6c5oc5ccccc56)ccc4c23)cc1 ; c1ccc(-c2ccccc2N(c2ccc3c(c2)oc2ccc4c(-c5ccccc5)cc5ccccc5c4c23)c2ccc3oc4ccccc4c3c2)cc1 ; c1ccc(-c2cc3ccccc3c3c2ccc2oc4cc(N(c5ccccc5)c5cccc6oc7ccccc7c56)ccc4c23)cc1]

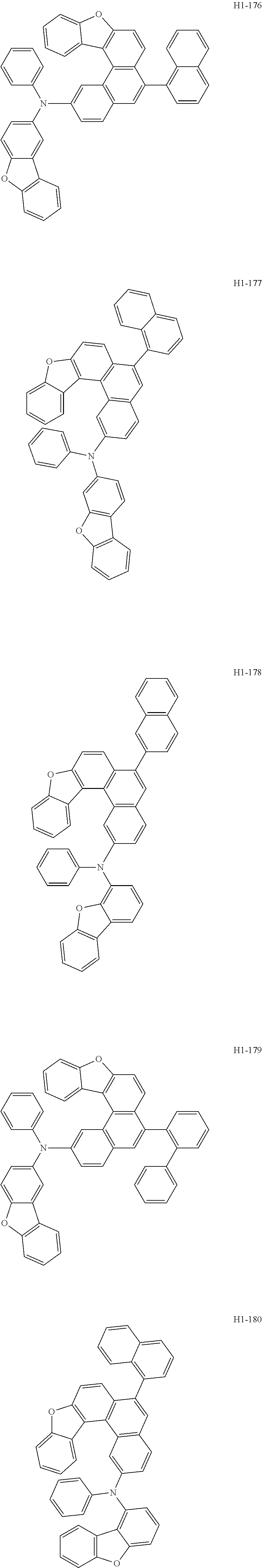 [SMILES: c1ccc(N(c2ccc3oc4ccccc4c3c2)c2ccc3cc(-c4cccc5ccccc45)c4ccc5oc6ccccc6c5c4c3c2)cc1 ; c1ccc(N(c2ccc3c(c2)oc2ccccc23)c2ccc3cc(-c4cccc5ccccc45)c4ccc5oc6ccccc6c5c4c3c2)cc1 ; c1ccc(N(c2ccc3cc(-c4ccc5ccccc5c4)c4ccc5oc6ccccc6c5c4c3c2)c2cccc3c2oc2ccccc23)cc1 ; c1ccc(-c2ccccc2-c2cc3ccc(N(c4ccccc4)c4ccc5oc6ccccc6c5c4)cc3c3c2ccc2oc4ccccc4c23)cc1 ; c1ccc(N(c2ccc3cc(-c4cccc5ccccc45)c4ccc5oc6ccccc6c5c4c3c2)c2cccc3oc4ccccc4c23)cc1]

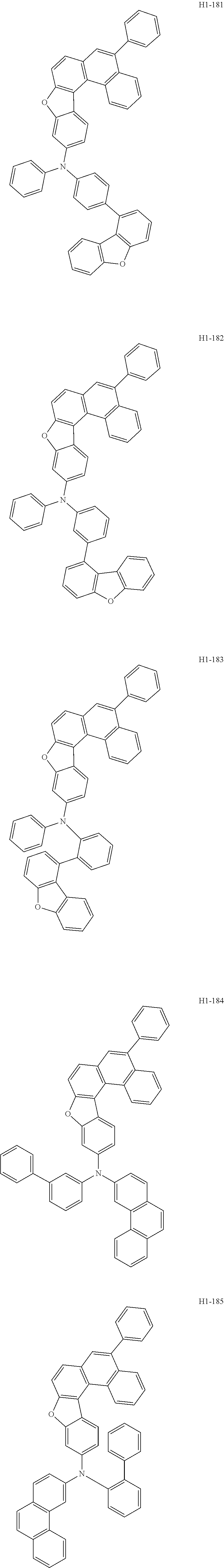 [SMILES: c1ccc(-c2cc3ccc4oc5cc(N(c6ccccc6)c6ccc(-c7cccc8oc9ccccc9c78)cc6)ccc5c4c3c3ccccc23)cc1 ; c1ccc(-c2cc3ccc4oc5cc(N(c6ccccc6)c6cccc(-c7cccc8oc9ccccc9c78)c6)ccc5c4c3c3ccccc23)cc1 ; c1ccc(-c2cc3ccc4oc5cc(N(c6ccccc6)c6ccccc6-c6cccc7oc8ccccc8c67)ccc5c4c3c3ccccc23)cc1 ; c1ccc(-c2cccc(N(c3ccc4c(c3)oc3ccc5cc(-c6ccccc6)c6ccccc6c5c34)c3ccc4ccc5ccccc5c4c3)c2)cc1 ; c1ccc(-c2ccccc2N(c2ccc3c(c2)oc2ccc4cc(-c5ccccc5)c5ccccc5c4c23)c2ccc3ccc4ccccc4c3c2)cc1]

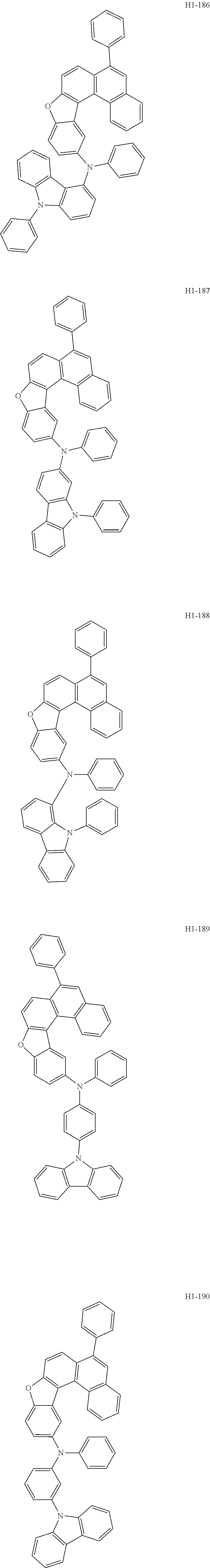 [SMILES: c1ccc(-c2cc3ccccc3c3c2ccc2oc4ccc(N(c5ccccc5)c5cccc6c5c5ccccc5n6-c5ccccc5)cc4c23)cc1 ; c1ccc(-c2cc3ccccc3c3c2ccc2oc4ccc(N(c5ccccc5)c5ccc6c7ccccc7n(-c7ccccc7)c6c5)cc4c23)cc1 ; c1ccc(-c2cc3ccccc3c3c2ccc2oc4ccc(N(c5ccccc5)c5cccc6c7ccccc7n(-c7ccccc7)c56)cc4c23)cc1 ; c1ccc(-c2cc3ccccc3c3c2ccc2oc4ccc(N(c5ccccc5)c5ccc(-n6c7ccccc7c7ccccc76)cc5)cc4c23)cc1 ; c1ccc(-c2cc3ccccc3c3c2ccc2oc4ccc(N(c5ccccc5)c5cccc(-n6c7ccccc7c7ccccc76)c5)cc4c23)cc1]

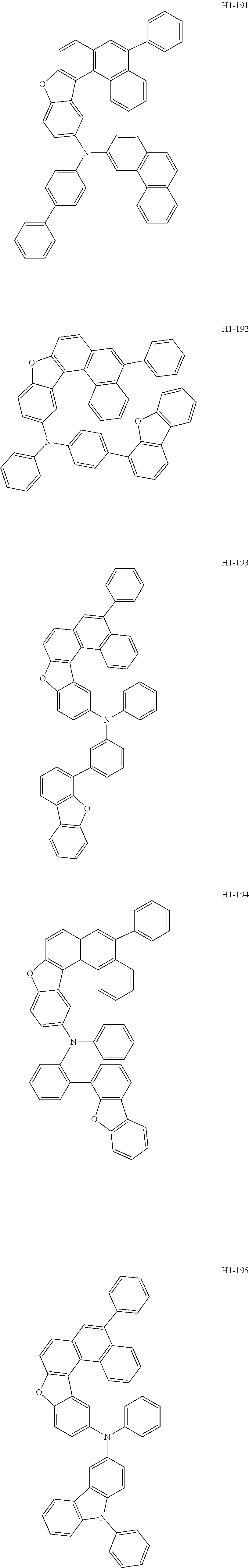 [SMILES: c1ccc(-c2ccc(N(c3ccc4ccc5ccccc5c4c3)c3ccc4oc5ccc6cc(-c7ccccc7)c7ccccc7c6c5c4c3)cc2)cc1 ; c1ccc(-c2cc3ccc4oc5ccc(N(c6ccccc6)c6ccc(-c7cccc8c7oc7ccccc78)cc6)cc5c4c3c3ccccc23)cc1 ; c1ccc(-c2cc3ccc4oc5ccc(N(c6ccccc6)c6cccc(-c7cccc8c7oc7ccccc78)c6)cc5c4c3c3ccccc23)cc1 ; c1ccc(-c2cc3ccc4oc5ccc(N(c6ccccc6)c6ccccc6-c6cccc7c6oc6ccccc67)cc5c4c3c3ccccc23)cc1 ; c1ccc(-c2cc3ccc4oc5ccc(N(c6ccccc6)c6ccc7c(c6)c6ccccc6n7-c6ccccc6)cc5c4c3c3ccccc23)cc1]

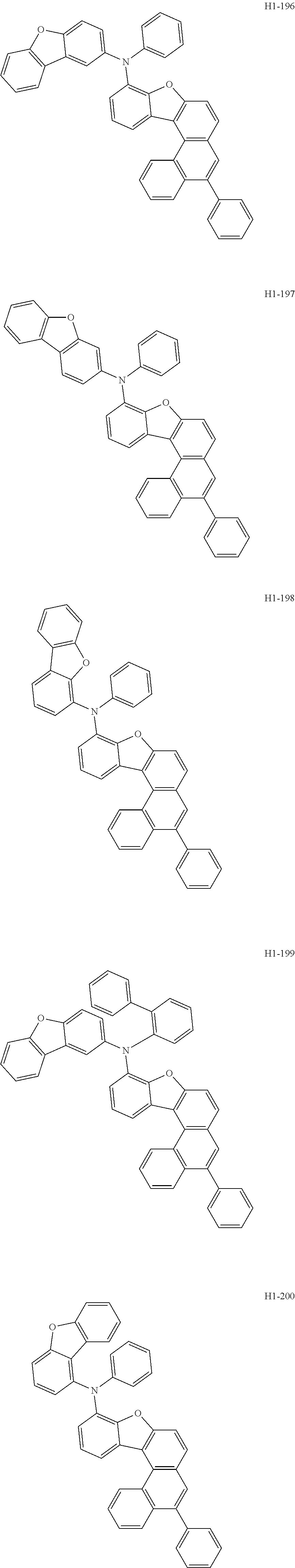 [SMILES: c1ccc(-c2cc3ccc4oc5c(N(c6ccccc6)c6ccc7oc8ccccc8c7c6)cccc5c4c3c3ccccc23)cc1 ; c1ccc(-c2cc3ccc4oc5c(N(c6ccccc6)c6ccc7c(c6)oc6ccccc67)cccc5c4c3c3ccccc23)cc1 ; c1ccc(-c2cc3ccc4oc5c(N(c6ccccc6)c6cccc7c6oc6ccccc67)cccc5c4c3c3ccccc23)cc1 ; c1ccc(-c2ccccc2N(c2ccc3oc4ccccc4c3c2)c2cccc3c2oc2ccc4cc(-c5ccccc5)c5ccccc5c4c23)cc1 ; c1ccc(-c2cc3ccc4oc5c(N(c6ccccc6)c6cccc7oc8ccccc8c67)cccc5c4c3c3ccccc23)cc1]

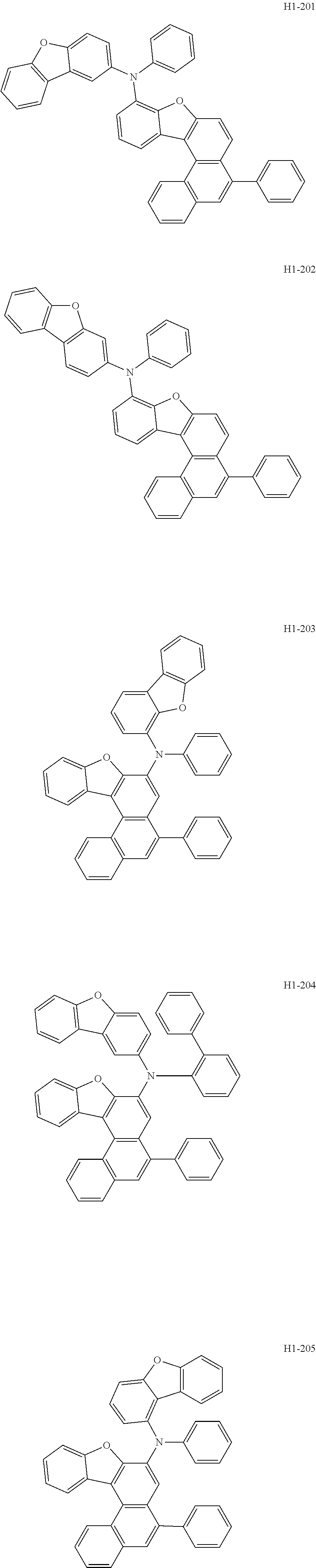 [SMILES: c1ccc(-c2cc3ccccc3c3c2ccc2oc4c(N(c5ccccc5)c5ccc6oc7ccccc7c6c5)cccc4c23)cc1 ; c1ccc(-c2cc3ccccc3c3c2ccc2oc4c(N(c5ccccc5)c5ccc6c(c5)oc5ccccc56)cccc4c23)cc1 ; c1ccc(-c2cc3ccccc3c3c2cc(N(c2ccccc2)c2cccc4c2oc2ccccc24)c2oc4ccccc4c23)cc1 ; c1ccc(-c2ccccc2N(c2ccc3oc4ccccc4c3c2)c2cc3c(-c4ccccc4)cc4ccccc4c3c3c2oc2ccccc23)cc1 ; c1ccc(-c2cc3ccccc3c3c2cc(N(c2ccccc2)c2cccc4oc5ccccc5c24)c2oc4ccccc4c23)cc1]

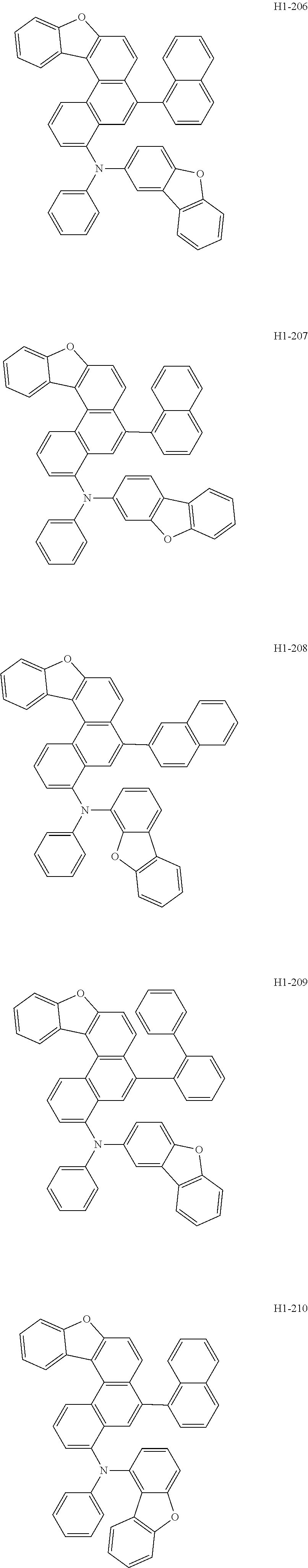 [SMILES: c1ccc(N(c2ccc3oc4ccccc4c3c2)c2cccc3c2cc(-c2cccc4ccccc24)c2ccc4oc5ccccc5c4c23)cc1 ; c1ccc(N(c2ccc3c(c2)oc2ccccc23)c2cccc3c2cc(-c2cccc4ccccc24)c2ccc4oc5ccccc5c4c23)cc1 ; c1ccc(N(c2cccc3c2cc(-c2ccc4ccccc4c2)c2ccc4oc5ccccc5c4c23)c2cccc3c2oc2ccccc23)cc1 ; c1ccc(-c2ccccc2-c2cc3c(N(c4ccccc4)c4ccc5oc6ccccc6c5c4)cccc3c3c2ccc2oc4ccccc4c23)cc1 ; c1ccc(N(c2cccc3c2cc(-c2cccc4ccccc24)c2ccc4oc5ccccc5c4c23)c2cccc3oc4ccccc4c23)cc1]

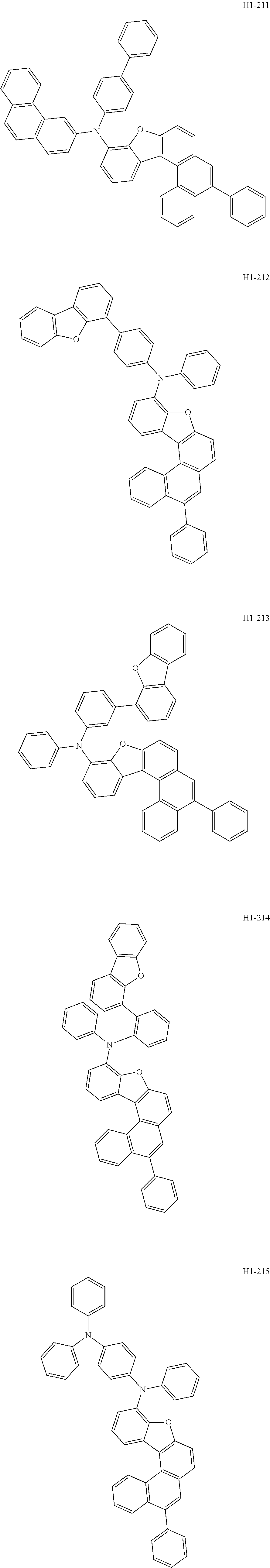 [SMILES: c1ccc(-c2ccc(N(c3ccc4ccc5ccccc5c4c3)c3cccc4c3oc3ccc5cc(-c6ccccc6)c6ccccc6c5c34)cc2)cc1 ; c1ccc(-c2cc3ccc4oc5c(N(c6ccccc6)c6ccc(-c7cccc8c7oc7ccccc78)cc6)cccc5c4c3c3ccccc23)cc1 ; c1ccc(-c2cc3ccc4oc5c(N(c6ccccc6)c6cccc(-c7cccc8c7oc7ccccc78)c6)cccc5c4c3c3ccccc23)cc1 ; c1ccc(-c2cc3ccc4oc5c(N(c6ccccc6)c6ccccc6-c6cccc7c6oc6ccccc67)cccc5c4c3c3ccccc23)cc1 ; c1ccc(-c2cc3ccc4oc5c(N(c6ccccc6)c6ccc7c(c6)c6ccccc6n7-c6ccccc6)cccc5c4c3c3ccccc23)cc1]

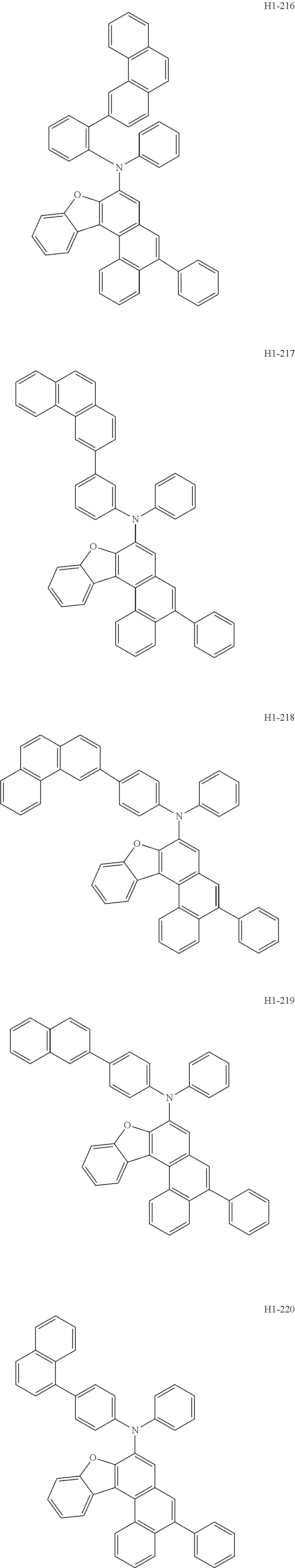 [SMILES: c1ccc(-c2cc3cc(N(c4ccccc4)c4ccccc4-c4ccc5ccc6ccccc6c5c4)c4oc5ccccc5c4c3c3ccccc23)cc1 ; c1ccc(-c2cc3cc(N(c4ccccc4)c4cccc(-c5ccc6ccc7ccccc7c6c5)c4)c4oc5ccccc5c4c3c3ccccc23)cc1 ; c1ccc(-c2cc3cc(N(c4ccccc4)c4ccc(-c5ccc6ccc7ccccc7c6c5)cc4)c4oc5ccccc5c4c3c3ccccc23)cc1 ; c1ccc(-c2cc3cc(N(c4ccccc4)c4ccc(-c5ccc6ccccc6c5)cc4)c4oc5ccccc5c4c3c3ccccc23)cc1 ; c1ccc(-c2cc3cc(N(c4ccccc4)c4ccc(-c5cccc6ccccc56)cc4)c4oc5ccccc5c4c3c3ccccc23)cc1]

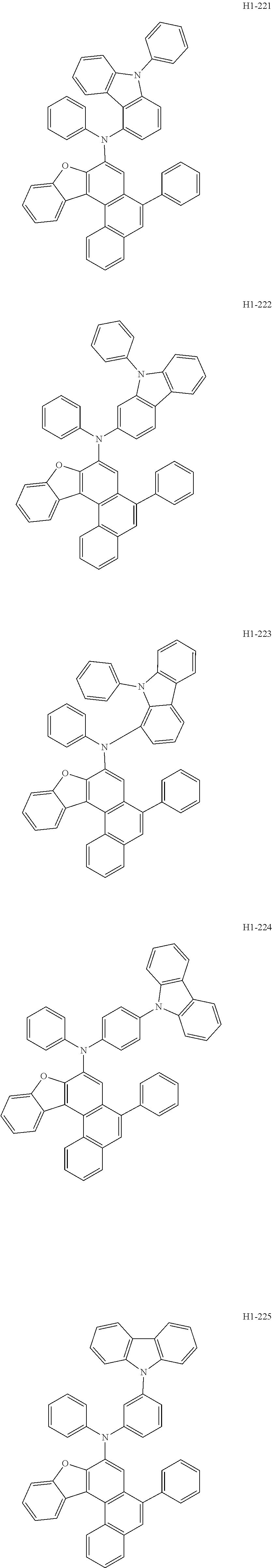 [SMILES: c1ccc(-c2cc3ccccc3c3c2cc(N(c2ccccc2)c2cccc4c2c2ccccc2n4-c2ccccc2)c2oc4ccccc4c23)cc1 ; c1ccc(-c2cc3ccccc3c3c2cc(N(c2ccccc2)c2ccc4c5ccccc5n(-c5ccccc5)c4c2)c2oc4ccccc4c23)cc1 ; c1ccc(-c2cc3ccccc3c3c2cc(N(c2ccccc2)c2cccc4c5ccccc5n(-c5ccccc5)c24)c2oc4ccccc4c23)cc1 ; c1ccc(-c2cc3ccccc3c3c2cc(N(c2ccccc2)c2ccc(-n4c5ccccc5c5ccccc54)cc2)c2oc4ccccc4c23)cc1 ; c1ccc(-c2cc3ccccc3c3c2cc(N(c2ccccc2)c2cccc(-n4c5ccccc5c5ccccc54)c2)c2oc4ccccc4c23)cc1]

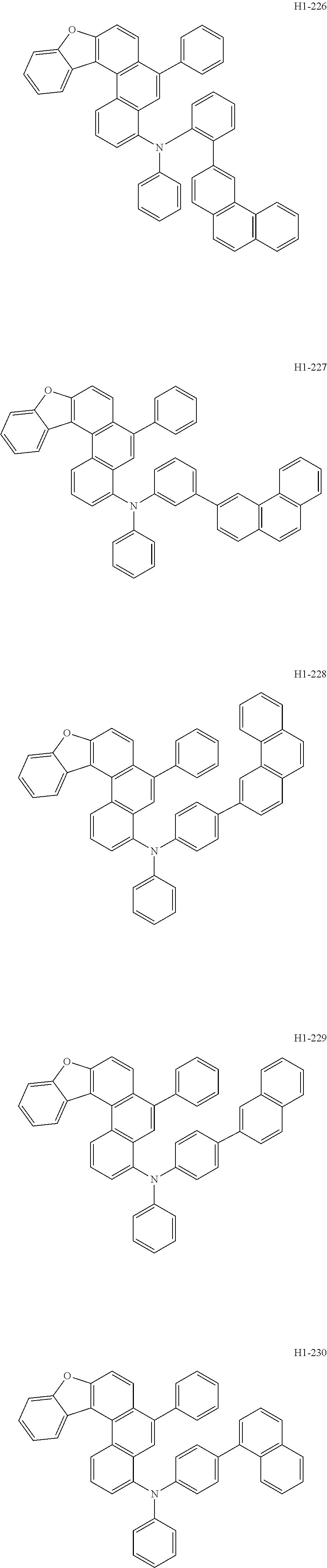 [SMILES: c1ccc(-c2cc3c(N(c4ccccc4)c4ccccc4-c4ccc5ccc6ccccc6c5c4)cccc3c3c2ccc2oc4ccccc4c23)cc1 ; c1ccc(-c2cc3c(N(c4ccccc4)c4cccc(-c5ccc6ccc7ccccc7c6c5)c4)cccc3c3c2ccc2oc4ccccc4c23)cc1 ; c1ccc(-c2cc3c(N(c4ccccc4)c4ccc(-c5ccc6ccc7ccccc7c6c5)cc4)cccc3c3c2ccc2oc4ccccc4c23)cc1 ; c1ccc(-c2cc3c(N(c4ccccc4)c4ccc(-c5ccc6ccccc6c5)cc4)cccc3c3c2ccc2oc4ccccc4c23)cc1 ; c1ccc(-c2cc3c(N(c4ccccc4)c4ccc(-c5cccc6ccccc56)cc4)cccc3c3c2ccc2oc4ccccc4c23)cc1]

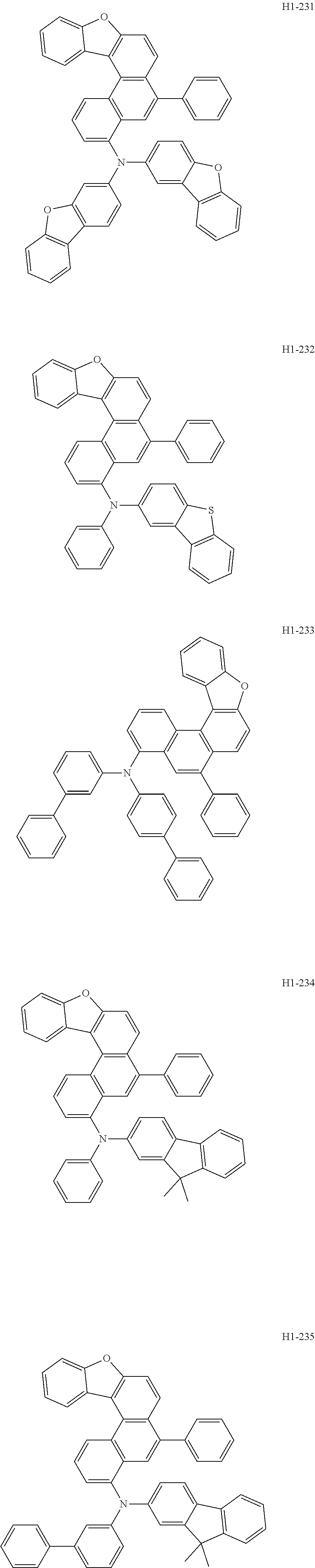 [SMILES: c1ccc(-c2cc3c(N(c4ccc5c(c4)oc4ccccc45)c4ccc5oc6ccccc6c5c4)cccc3c3c2ccc2oc4ccccc4c23)cc1 ; c1ccc(-c2cc3c(N(c4ccccc4)c4ccc5sc6ccccc6c5c4)cccc3c3c2ccc2oc4ccccc4c23)cc1 ; c1ccc(-c2ccc(N(c3cccc(-c4ccccc4)c3)c3cccc4c3cc(-c3ccccc3)c3ccc5oc6ccccc6c5c34)cc2)cc1 ; CC1(C)c2ccccc2-c2ccc(N(c3ccccc3)c3cccc4c3cc(-c3ccccc3)c3ccc5oc6ccccc6c5c34)cc21 ; CC1(C)c2ccccc2-c2ccc(N(c3cccc(-c4ccccc4)c3)c3cccc4c3cc(-c3ccccc3)c3ccc5oc6ccccc6c5c34)cc21]

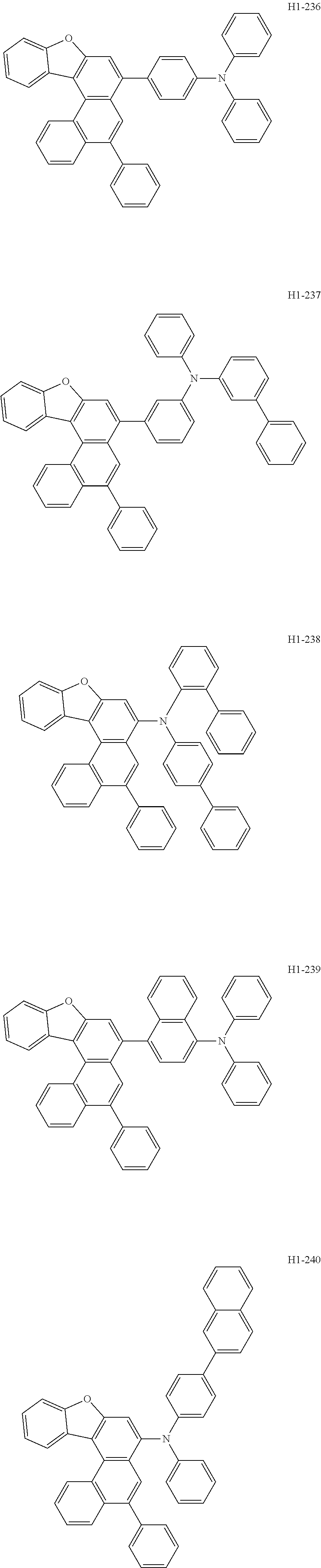 [SMILES: c1ccc(-c2cc3c(-c4ccc(N(c5ccccc5)c5ccccc5)cc4)cc4oc5ccccc5c4c3c3ccccc23)cc1 ; c1ccc(-c2cccc(N(c3ccccc3)c3cccc(-c4cc5oc6ccccc6c5c5c4cc(-c4ccccc4)c4ccccc45)c3)c2)cc1 ; c1ccc(-c2ccc(N(c3ccccc3-c3ccccc3)c3cc4oc5ccccc5c4c4c3cc(-c3ccccc3)c3ccccc34)cc2)cc1 ; c1ccc(-c2cc3c(-c4ccc(N(c5ccccc5)c5ccccc5)c5ccccc45)cc4oc5ccccc5c4c3c3ccccc23)cc1 ; c1ccc(-c2cc3c(N(c4ccccc4)c4ccc(-c5ccc6ccccc6c5)cc4)cc4oc5ccccc5c4c3c3ccccc23)cc1]

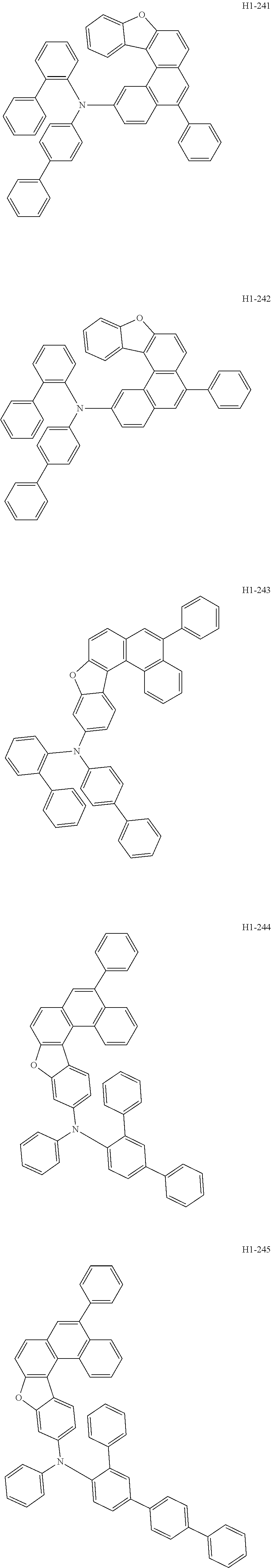 [SMILES: c1ccc(-c2ccc(N(c3ccc4c(-c5ccccc5)cc5ccc6oc7ccccc7c6c5c4c3)c3ccccc3-c3ccccc3)cc2)cc1 ; c1ccc(-c2ccc(N(c3ccc4cc(-c5ccccc5)c5ccc6oc7ccccc7c6c5c4c3)c3ccccc3-c3ccccc3)cc2)cc1 ; c1ccc(-c2ccc(N(c3ccc4c(c3)oc3ccc5cc(-c6ccccc6)c6ccccc6c5c34)c3ccccc3-c3ccccc3)cc2)cc1 ; c1ccc(-c2ccc(N(c3ccccc3)c3ccc4c(c3)oc3ccc5cc(-c6ccccc6)c6ccccc6c5c34)c(-c3ccccc3)c2)cc1 ; c1ccc(-c2ccc(-c3ccc(N(c4ccccc4)c4ccc5c(c4)oc4ccc6cc(-c7ccccc7)c7ccccc7c6c45)c(-c4ccccc4)c3)cc2)cc1]

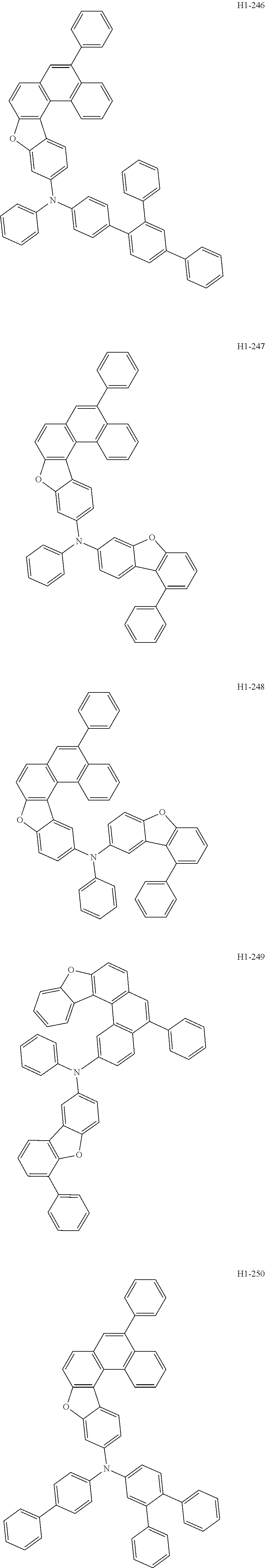 [SMILES: c1ccc(-c2ccc(-c3ccc(N(c4ccccc4)c4ccc5c(c4)oc4ccc6cc(-c7ccccc7)c7ccccc7c6c45)cc3)c(-c3ccccc3)c2)cc1 ; c1ccc(-c2cc3ccc4oc5cc(N(c6ccccc6)c6ccc7c(c6)oc6cccc(-c8ccccc8)c67)ccc5c4c3c3ccccc23)cc1 ; c1ccc(-c2cc3ccc4oc5ccc(N(c6ccccc6)c6ccc7oc8cccc(-c9ccccc9)c8c7c6)cc5c4c3c3ccccc23)cc1 ; c1ccc(-c2cc3ccc4oc5ccccc5c4c3c3cc(N(c4ccccc4)c4ccc5oc6c(-c7ccccc7)cccc6c5c4)ccc23)cc1 ; c1ccc(-c2ccc(N(c3ccc(-c4ccccc4)c(-c4ccccc4)c3)c3ccc4c(c3)oc3ccc5cc(-c6ccccc6)c6ccccc6c5c34)cc2)cc1]

The compound represented by Formula 1 according to the present disclosure may be synthesized by referring to synthetic methods known to one skilled in the art, and in particular, a synthetic method disclosed in a number of patent documents can be used. For example, it may be synthesized by referring to synthetic methods disclosed in Korean Patent Application Laid-Open No. 2017-0043439, etc., but is not limited thereto.

The compound represented by Formula 2 according to the present disclosure may be synthesized by referring to synthetic methods known to one skilled in the art, and in particular, a synthetic method disclosed in a number of patent documents can be used. For example, it may be synthesized by referring to synthetic methods disclosed in Korean Patent Application Laid-Open Nos. 2021-0124018, 2021-0098316, and 2021-0109436, etc., but is not limited thereto.

The compound represented by Formula 1′ according to the present disclosure may be produced by referring to the following Reaction Scheme 1.

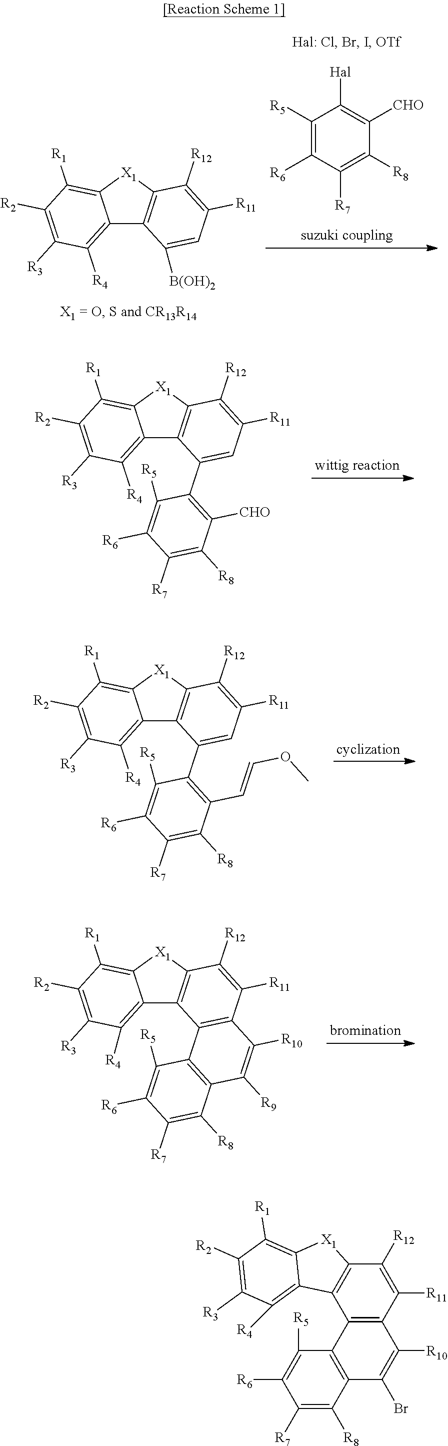

Although illustrative synthesis examples of the compounds represented by Formulas 1, 2, and 1′ are described above, one skilled in the art will be able to readily understand that all of these are based on a Buchwald-Hartwig cross-coupling reaction, a N-arylation reaction, an H-mont-mediated etherification reaction, a Miyaura borylation reaction, a Suzuki cross-coupling reaction, an intramolecular acid-induced cyclization reaction, a Pd(II)-catalyzed oxidative cyclization reaction, a Grignard reaction, a Heck reaction, a cyclic dehydration reaction, an S_{N}1 substitution reaction, an S_{N}2 substitution reaction, a phosphine-mediated reductive cyclization reaction, etc., and the above reactions proceed even when substituents defined in Formulas 1, 2, and 1′ other than the substituents specified in the specific synthesis examples are bonded.

An organic electroluminescent device according to the present disclosure comprises an anode, a cathode, and at least one light-emitting layer between the anode and the cathode, wherein at least one layer of the light-emitting layer comprises a plurality of host materials comprising at least one first host compound represented by Formula 1 and at least one second host compound represented by Formula 2. Here, the weight ratio of the first host compound to the second host compound may be included in the light-emitting layer in a range of about 1:99 to about 99:1, preferably about 10:90 to about 90:10, more preferably about 30:70 to about 70:30, more preferably about 40:60 to about 60:40, and even more preferably about 50:50. For example, the plurality of host materials of the present disclosure may comprise at least one compound among the first host Compounds H-1 to H-95 and H1-1 to H1-250, and at least one compound among the second host Compounds C-1 to C-335 and C2-1 to C2-110, and this plurality of host materials may be included in the same organic layer, for example, the light-emitting layer, or may each be included in different light-emitting layers.

The organic electroluminescent compound of the present disclosure of Formula 1′ may be comprised in at least one layer of a light-emitting layer, a hole injection layer, a hole transport layer, a hole auxiliary layer, a light-emitting auxiliary layer, an electron transport layer, an electron buffer layer, an electron injection layer, an interlayer, a hole-blocking layer, and an electron-blocking layer, and preferably may be comprised in at least one layer of a light-emitting layer, a hole transport layer, a hole auxiliary layer, a light-emitting auxiliary layer, an electron transport layer, an electron buffer layer, a hole-blocking layer, and an electron-blocking layer. When used in a light-emitting layer, the organic electroluminescent compound of the present disclosure of Formula 1′ may be comprised as a host material. The organic electroluminescent compound of the present disclosure can be used as a co-host material.

In addition to the hole transport layer and the light-emitting layer, the organic layer may further include at least one layer selected from a hole injection layer, a hole auxiliary layer, an light-emitting auxiliary layer, an electron transport layer, an electron injection layer, an interlayer, a hole-blocking layer, an electron-blocking layer, and an electron buffer layer. The organic layer may further comprise an amine-based compound and/or an azine-based compound in addition to the light-emitting material of the present disclosure. Specifically, the hole injection layer, the hole transport layer, the hole auxiliary layer, the light-emitting layer, the light-emitting auxiliary layer, or the electron-blocking layer may comprise an amine-based compound, for example, an arylamine-based compound, a styrylarylamine-based compound, etc., as a hole injection material, a hole transport material, a hole auxiliary material, a light-emitting material, a light-emitting auxiliary material, or an electron-blocking material. In addition, the electron transport layer, the electron injection layer, the electron buffer layer, and the hole-blocking layer may comprise an azine-based compound as an electron transport material, an electron injection material, an electron buffer material, or a hole-blocking material. In addition, the organic layer may further comprise at least one metal selected from the group consisting of metals of Group 1, metals of Group 2, transition metals of the 4th period, transition metals of the 5th period, lanthanides, and organic metals of the d-transition elements of the Periodic Table, or at least one complex compound comprising the metal thereof.

The anode and the cathode may each be formed of a transparent conductive material or a semi-transparent or reflective conductive material. Depending on the type of material forming the first electrode and second electrode, the organic electroluminescent device can be a front emitting type, a back emitting type, or a double-sided emitting type.

A hole injection layer, a hole transport layer, an electron-blocking layer, or a combination thereof may be used between the anode and the light-emitting layer. The hole injection layer may be composed of multiple layers for the purpose of lowering the hole injection barrier (or hole injection voltage) from the anode to the hole transport layer or electron-blocking layer, and each layer may use two compounds simultaneously. In addition, the hole injection layer may be doped with a p-type dopant. The electron-blocking layer may be placed between the hole transport layer (or hole injection layer) and the light-emitting layer, and may block the overflow of electrons from the light-emitting layer and confine the excitons in the light-emitting layer to prevent light leakage. The hole transport layer or electron-blocking layer may use multiple layers, and multiple compounds may be used in each layer.

An electron buffer layer, a hole-blocking layer, an electron transport layer, an electron injection layer, or a combination thereof can be used between the light-emitting layer and the cathode. The electron buffer layer may be a multi-layer in order to control the injection of the electron and improve the interfacial properties between the light-emitting layer and the electron injection layer, wherein each multi-layer may use two compounds simultaneously. The hole-blocking layer is located between the electron transport layer (or electron injection layer) and the light-emitting layer and is a layer that blocks holes from reaching the cathode, thereby improving the probability of recombination of electrons and holes in the light-emitting layer. The hole-blocking layer or electron transport layer may also be multiple layers, and multiple compounds may be used in each layer. In addition, the electron injection layer may be doped with an n-type dopant.

The light-emitting auxiliary layer, the hole auxiliary layer, or the electron-blocking layer may have an effect of improving the efficiency and/or lifetime of the organic electroluminescent device.

The light-emitting auxiliary layer may be a layer placed between an anode and a light-emitting layer, or between a cathode and a light-emitting layer. When the light-emitting auxiliary layer is placed between the anode and the light-emitting layer, the light-emitting auxiliary layer may be used to facilitate hole injection and/or hole transport or to block the overflow of electrons. When the light-emitting auxiliary layer is placed between the cathode and the light-emitting layer, the light-emitting auxiliary layer may be used to facilitate electron injection and/or electron transport or to block the overflow of holes.

In addition, the hole auxiliary layer may be placed between the hole transport layer (or hole injection layer) and the light-emitting layer, and may exhibit an effect of facilitating or blocking the hole transport rate (or hole injection rate), and accordingly may adjust the charge balance. When an organic electroluminescent device includes two or more hole transport layers, the hole transport layer, which is further included, may be used as a hole auxiliary layer or an electron-blocking layer.

In the organic electroluminescent device of the present disclosure, it is preferable to dispose at least one layer selected from a chalcogenide layer, a metal halide layer, and a metal oxide layer (hereinafter referred to as a “surface layer”) on at least one inner surface of a pair of electrodes. Specifically, a chalcogenide (including oxide) layer of silicon and aluminum is preferably placed on an anode surface of an electroluminescent medium layer side, and a metal halide layer or a metal oxide layer is preferably placed on a cathode surface of an electroluminescent medium layer side. Driving stabilization of the organic electroluminescent device can be obtained by the surface layer. Preferred examples of the chalcogenide include SiO_{X} (1≤X≤2), AlO_{X} (1≤X≤1.5), SiON, SiAlON, etc.; preferred examples of the metal halide include LiF, MgF₂, CaF₂, a rare earth metal fluoride, etc.; and preferred examples of the metal oxide include Cs₂O, Li₂O, MgO, SrO, BaO, CaO, etc.

In addition, in an organic electroluminescent device of the present disclosure, a mixed region of an electron transport compound and a reductive dopant, or a mixed region of a hole transport compound and an oxidative dopant, may be placed on at least one surface of a pair of electrodes. In this case, the electron transport compound is reduced to an anion, and thus it becomes easier to inject and transport electrons from the mixed region to the light-emitting medium. Furthermore, the hole transport compound is oxidized to a cation, and thus it becomes easier to inject and transport holes from the mixed region to the light-emitting medium. Preferred oxidative dopants include various Lewis acids and acceptor compounds, and preferred reductive dopants include alkali metals, alkali metal compounds, alkaline earth metals, rare earth metals, and mixtures thereof. In addition, an organic electroluminescent device having at least two light-emitting layers and emitting white light may be manufactured by using the reductive dopant layer as a charge-generating layer.

An organic electroluminescent device according to the present disclosure may be an organic electroluminescent device having a tandem structure. In the case of the tandem organic electroluminescent device according to one embodiment, a single light-emitting unit (light-emitting part) may be formed in a structure in which two or more units are connected by a charge generation layer. The organic electroluminescent device may include a plurality of two or more light-emitting units, for example, a plurality of three or more light-emitting units, having first and second electrodes opposed to each other on a substrate and a light-emitting layer stacked between the first and second electrodes, and emits light in a specific wavelength range. It may include a plurality of light-emitting units, and each of the light-emitting units may include a hole transport zone, a light-emitting layer, and an electron transport zone, and the hole transport zone may include a hole injection layer and a hole transport layer, and the electron transport zone may include an electron transport layer and an electron injection layer. According to one embodiment of the present disclosure, three or more light-emitting layers may be included in the light-emitting unit. A plurality of light-emitting units may emit the same color or different colors. Additionally, one light-emitting unit may include one or more light-emitting layers, and the plurality of light-emitting layers may be light-emitting layers of the same or different colors. It may include one or more charge generation layers located between each light-emitting unit. The charge generation layer refers to the layer in which holes and electrons are generated when voltage is applied. When there are three or more light-emitting units, a charge generation layer may be located between each light-emitting unit. At this time, the plurality of charge generation layers may be the same as or different from each other. By disposing the charge generating layer between light-emitting units, current efficiency is increased in each light-emitting unit, and charges can be smoothly distributed. Specifically, the charge generation layer is provided between two adjacent stacks and can serve to drive a tandem organic electroluminescent device using only a pair of anodes and cathodes without a separate internal electrode located between the stacks.

The charge generation layer may be composed of an N-type charge generation layer and a P-type charge generation layer, and the N-type charge generation layer may be doped with an alkali metal, an alkaline earth metal, or a compound of an alkali metal and an alkaline earth metal. The alkali metal may include one selected from the group consisting of Li, Na, K, Rb, Cs, Fr, Yb, and combinations thereof, and the alkaline earth metal may include one selected from the group consisting of Be, Mg, Ca, Sr, Ba, Ra, and combinations thereof. The P-type charge generation layer may be made of a metal or an organic material doped with a P-type dopant. For example, the metal may be made of one or two or more alloys selected from the group consisting of Al, Cu, Fe, Pb, Zn, Au, Pt, W, In, Mo, Ni, and Ti. Additionally, commonly used materials may be used as the P-type dopant and host materials used in the P-type doped organic material.

The manufacturing method of the organic electroluminescent device of the present disclosure is not limited, and the manufacturing method of the Device Example as described below is only an example and is not limited thereto. One skilled in the art can reasonably modify the manufacturing method of the Device Examples as described below by relying on existing technology. For example, there is no particular limitation on the mixing ratio of the first compound and the second compound, and thus one skilled in the art can reasonably select the same within a certain range by depending on existing technology. For example, based on the total weight of the light-emitting layer material, the total weight of the first compound and the second compound accounts for 99.5-80.0% of the total weight of the light-emitting layer, the weight ratio of the first compound and the second compound is between 1:99 and 99:1, the weight ratio of the first compound and the second compound may be between 20:80 and 99:1, or the weight ratio of the first compound and the second compound may be between 50:50 and 90:10. In the manufacture of devices, when forming a light-emitting layer by co-depositing two or more host materials and a light-emitting material, the two or more host materials and the light-emitting material may each be placed in different evaporation sources and co-deposited to form a light-emitting layer, or a pre-mixed mixture of two or more host materials may be placed on the same evaporation source and then co-deposited with a light-emitting material placed on another evaporation source to form a light-emitting layer. This premixing method can further save evaporation sources. According to one embodiment, the first compound, the second compound, and the light-emitting material of the present disclosure may each be placed in different evaporation sources and co-deposited to form a light-emitting layer, or a pre-mixed mixture of the first compound and the second compound may be placed in the same evaporation source and then co-deposited with a light-emitting material placed in another evaporation source to form a light-emitting layer. The light-emitting layer of another organic electroluminescent device according to one embodiment may be a single layer in which light is emitted, or may be a plurality of layers in which two or more layers are laminated. The light-emitting layer may further include one or more dopants, and the doping concentration of the dopant compound with respect to the host compound of the light-emitting layer may be less than 20 wt %, preferably less than 10 wt %.

The dopant comprised in the organic electroluminescent device of the present disclosure may be at least one phosphorescent or fluorescent dopant, and is preferably a phosphorescent dopant. The phosphorescent dopant material applied to the organic electroluminescent device of the present disclosure is not particularly limited, but may be preferably selected from the group consisting of the metallated complex compounds of iridium (Ir), osmium (Os), copper (Cu), and platinum (Pt), more preferably selected from the group consisting of ortho-metallated complex compounds of iridium (Ir), osmium (Os), copper (Cu), and platinum (Pt), and even more preferably ortho-metallated iridium complex compounds.

The dopant comprised in the organic electroluminescent device of the present disclosure may be a compound represented by the following Formula 101, but is not limited thereto.

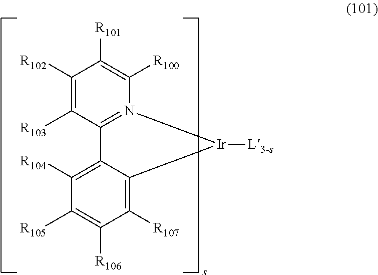

In Formula 101,
L is any one selected from the following Structures 1 to 3:

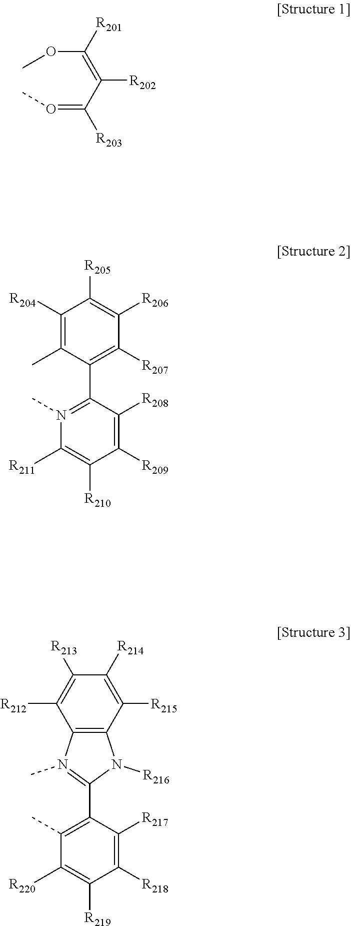

R₁₀₀ to R₁₀₃ each independently represent hydrogen, deuterium, a halogen, a (C₁-C₃₀)alkyl unsubstituted or substituted with deuterium and/or a halogen(s), a substituted or unsubstituted (C₃-C₃₀)cycloalkyl, a substituted or unsubstituted (C₆-C₃₀)aryl, a cyano, a substituted or unsubstituted (3- to 30-membered)heteroaryl, or a substituted or unsubstituted (C₁-C₃₀)alkoxy; or may be linked to an adjacent substituent(s) to form a ring(s), for example, to form a ring(s) with a pyridine, e.g., a substituted or unsubstituted quinoline, a substituted or unsubstituted isoquinoline a substituted or unsubstituted benzofuropyridine, a substituted or unsubstituted benzothienopyridine, a substituted or unsubstituted indenopyridine, a substituted or unsubstituted benzofuroquinoline, a substituted or unsubstituted benzothienoquinoline, or a substituted or unsubstituted indenoquinoline;
R₁₀₄ to R₁₀₇ each independently represent, hydrogen, deuterium, halogen, deuterium- and/or halogen-substituted or unsubstituted (C₁-C₃₀)alkyl, a substituted or unsubstituted (C₃-C₃₀)cycloalkyl, a substituted or unsubstituted (C₆-C₃₀)aryl, a substituted or unsubstituted (3- to 30-membered)heteroaryl, cyano, or a substituted or unsubstituted (C₁-C₃₀)alkoxy; or may be linked to an adjacent substituent(s) to form a ring(s), for example, to form a ring(s) with a benzene, e.g., a substituted or unsubstituted naphthalene, a substituted or unsubstituted fluoren, a substituted or unsubstituted dibenzothiophene, a substituted or unsubstituted dibenzofuran, a substituted or unsubstituted indenopyridine, a substituted or unsubstituted benzofuropyridine, or a substituted or unsubstituted benzothienopyridine;
R₂₀₁ to R₂₂₀ each independently represent, hydrogen, deuterium, halogen, deuterium- and/or halogen-substituted or unsubstituted (C₁-C₃₀)alkyl, a substituted or unsubstituted (C₃-C₃₀)cycloalkyl, or a substituted or unsubstituted (C₆-C₃₀)aryl; or may be linked to an adjacent substituent(s) to form a ring(s); and
s represents an integer of 1 to 3.

Specifically, the specific examples of the dopant compound include the following, but are not limited thereto.

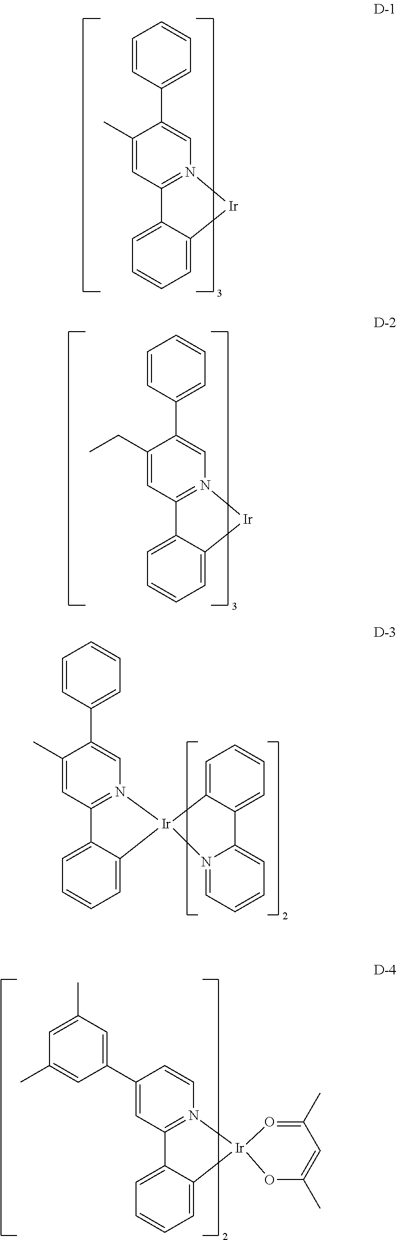

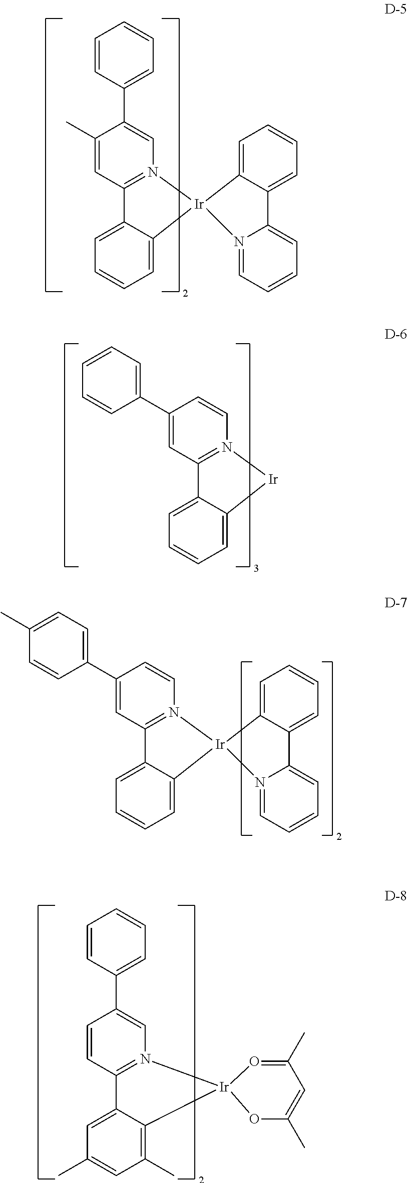

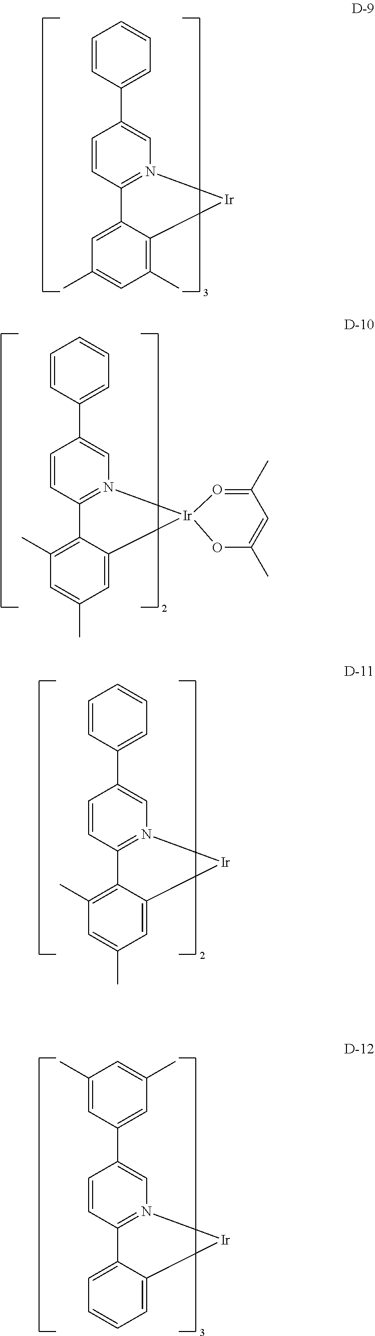

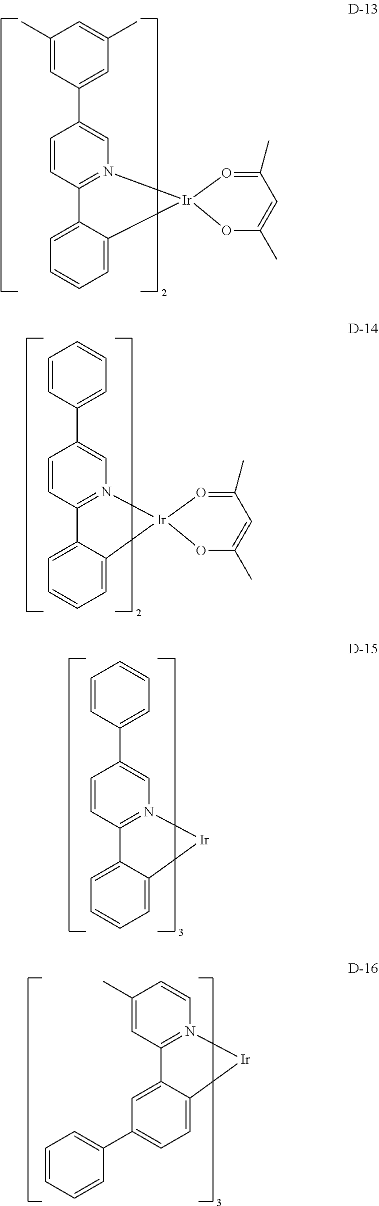

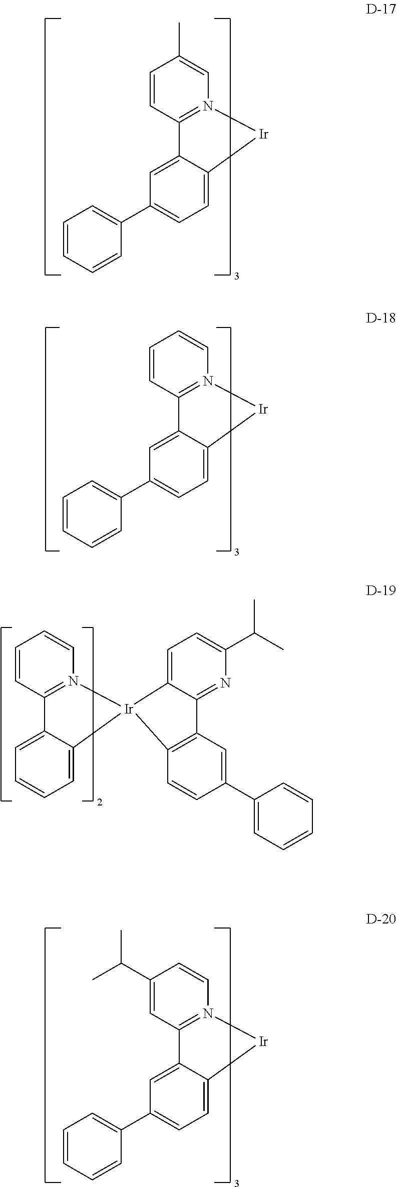

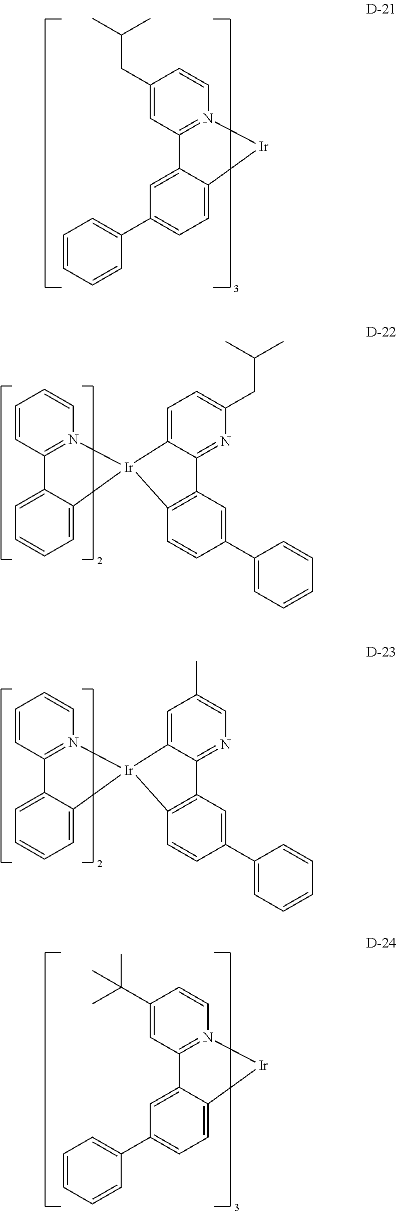

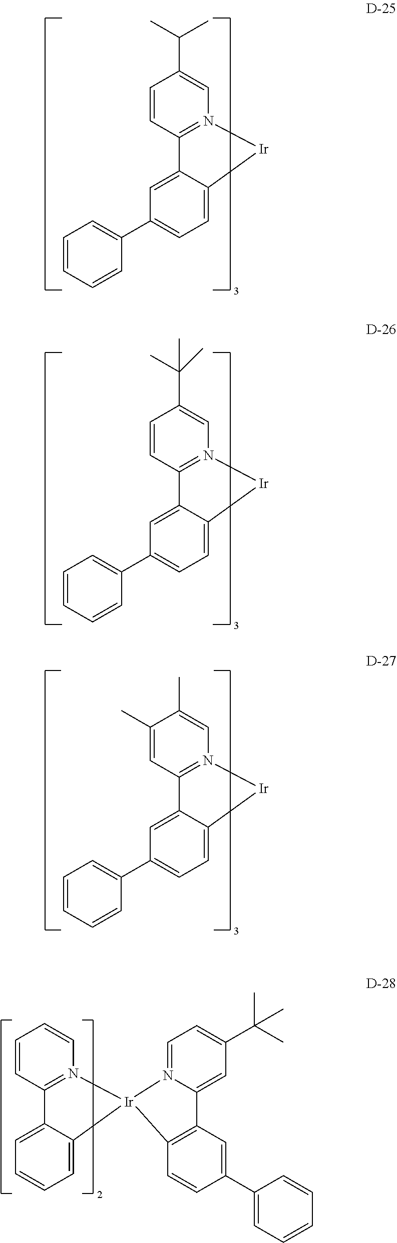

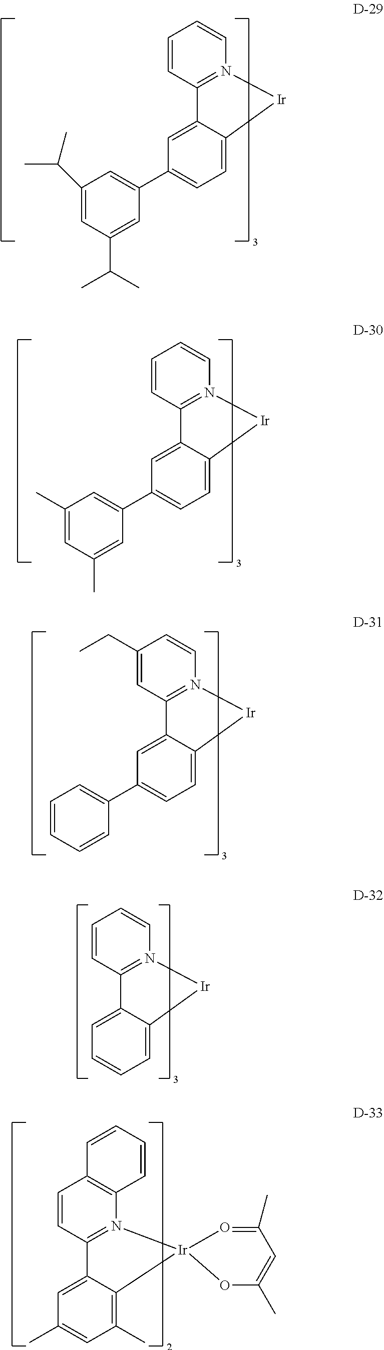

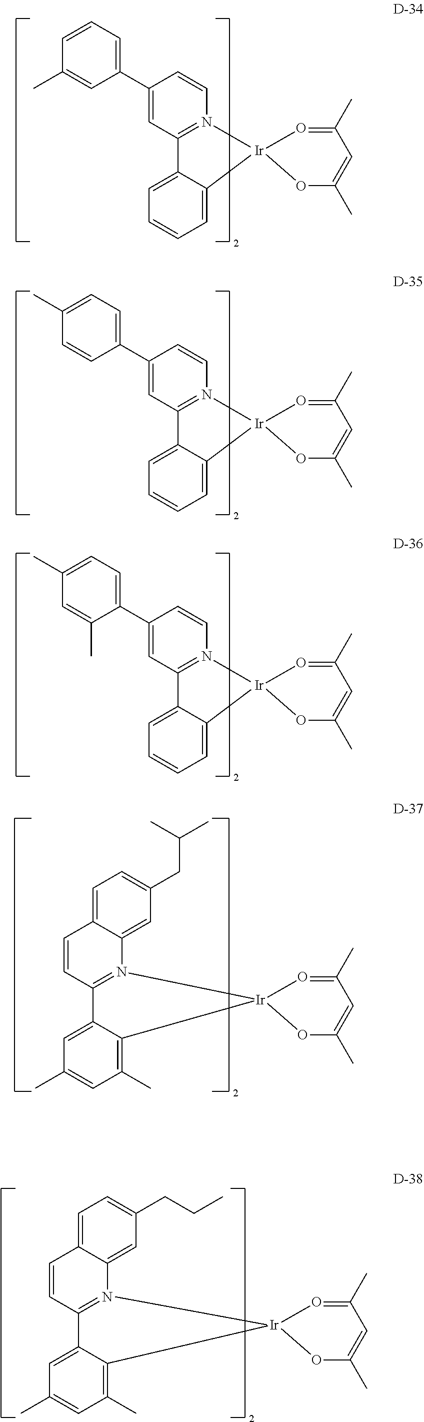

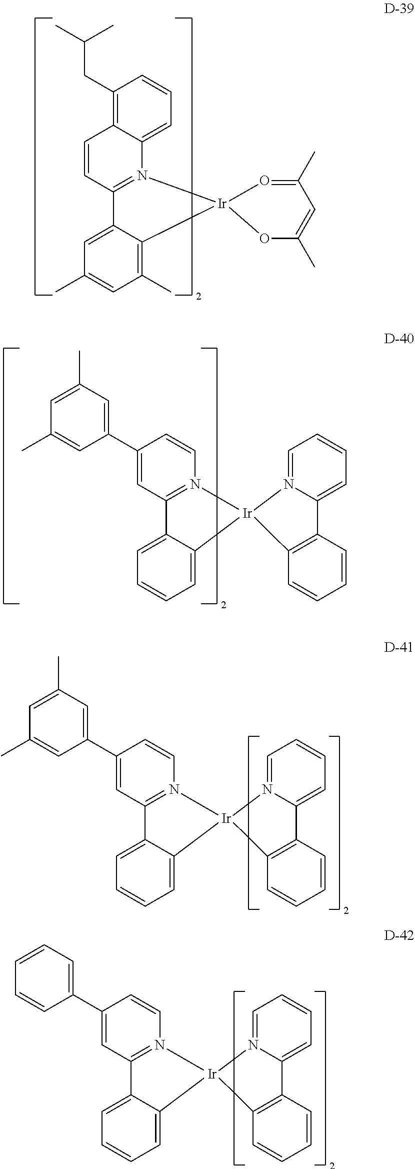

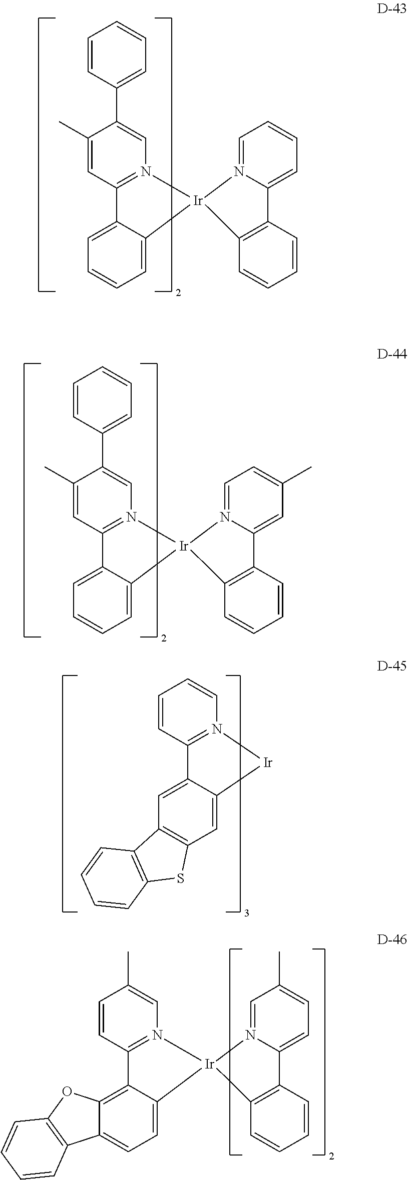

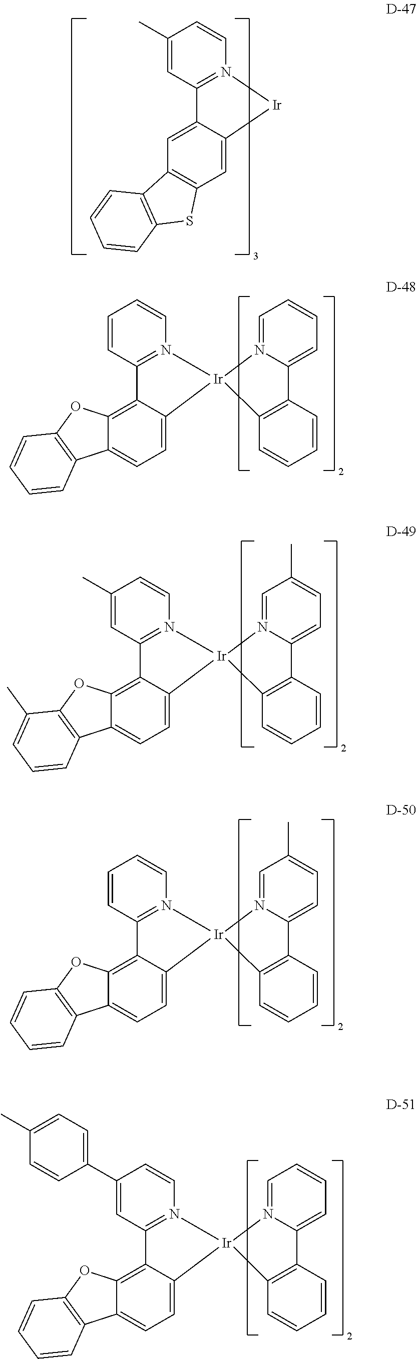

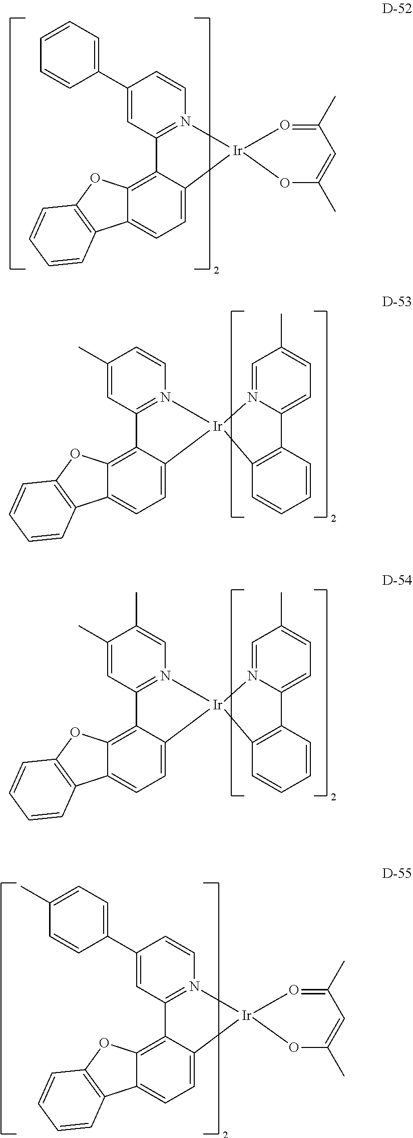

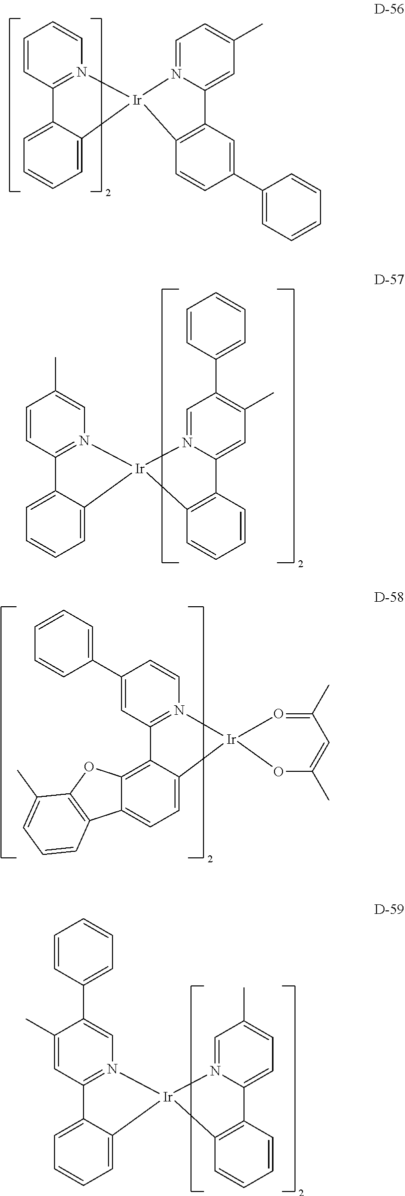

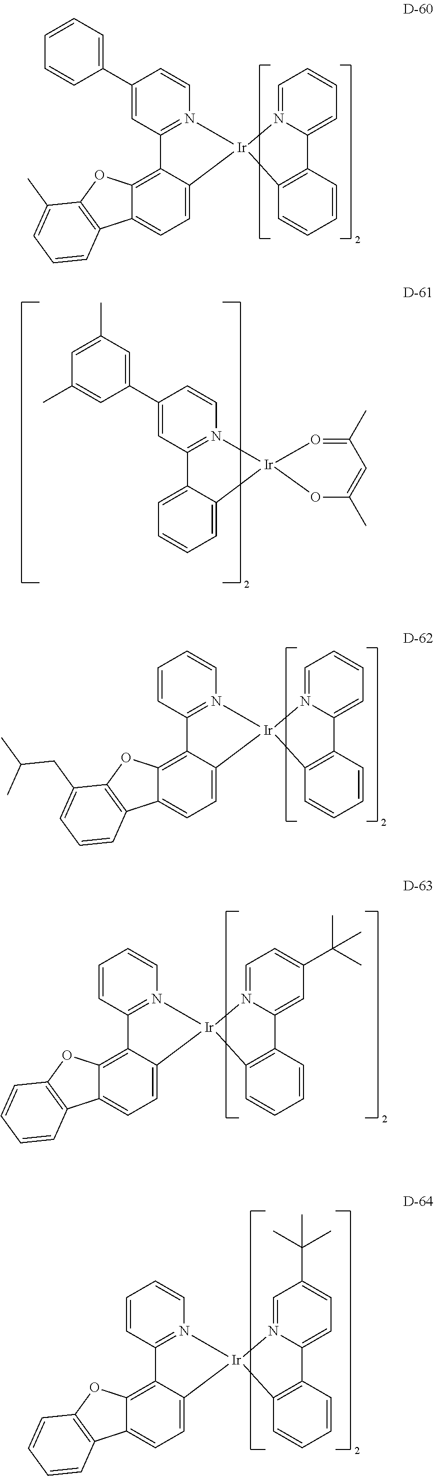

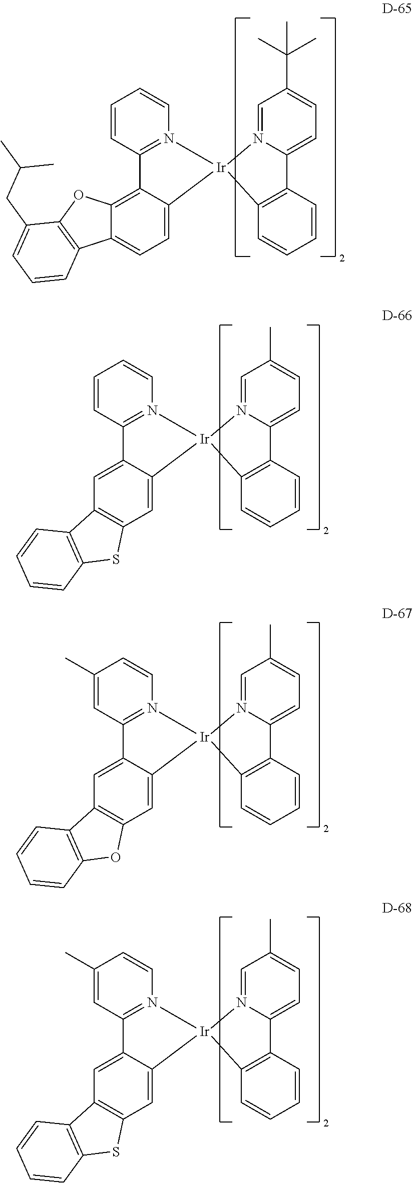

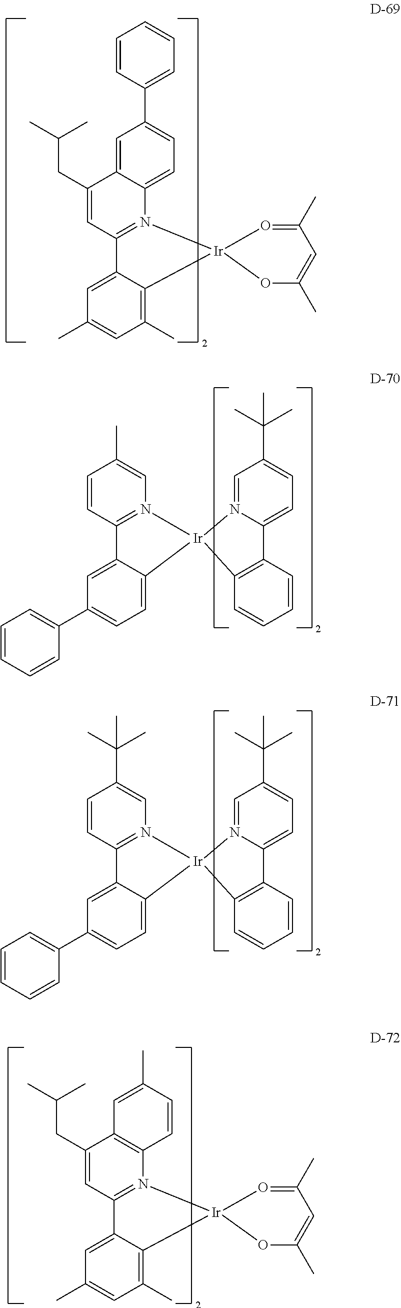

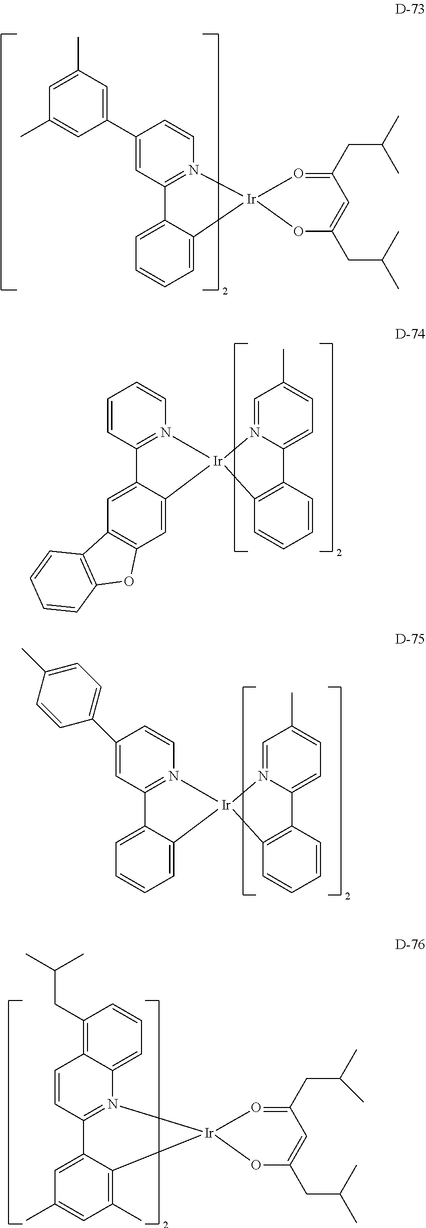

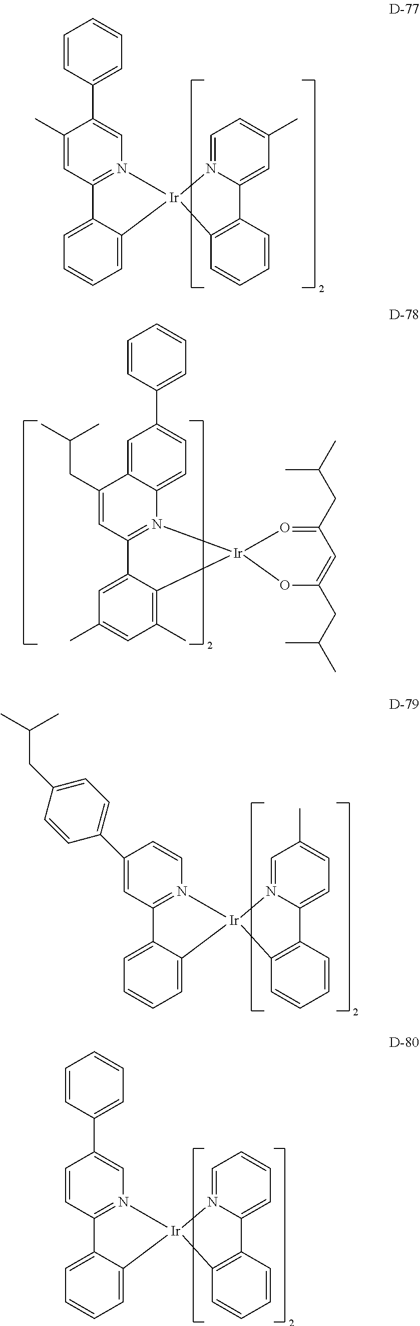

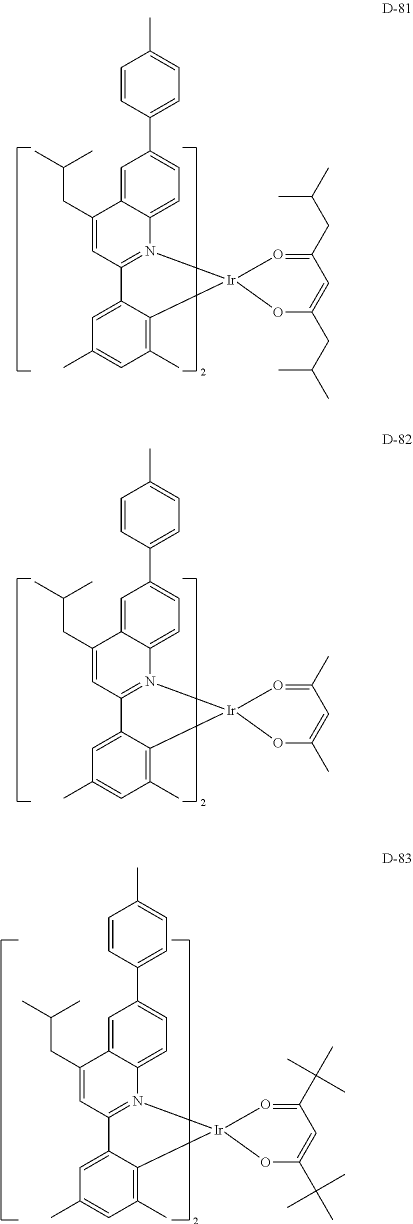

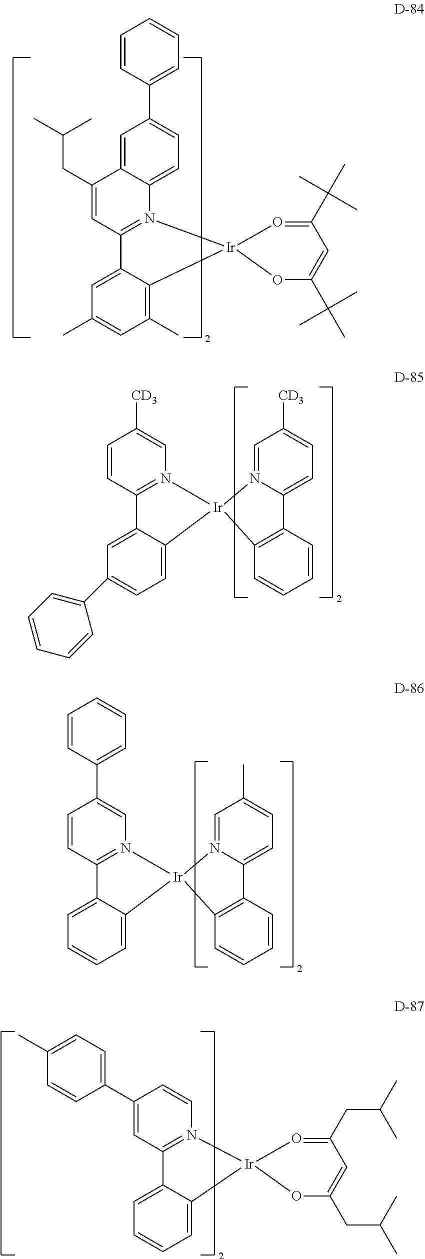

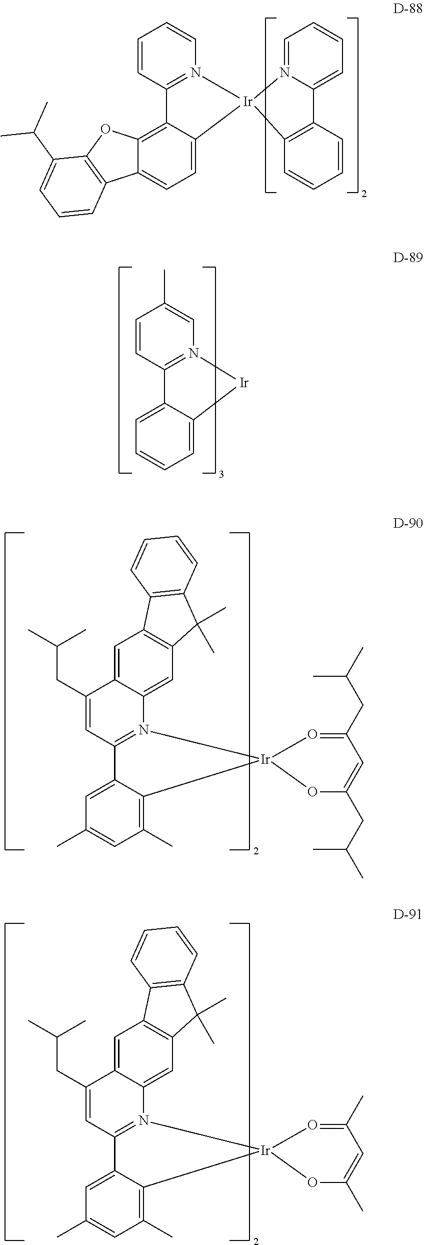

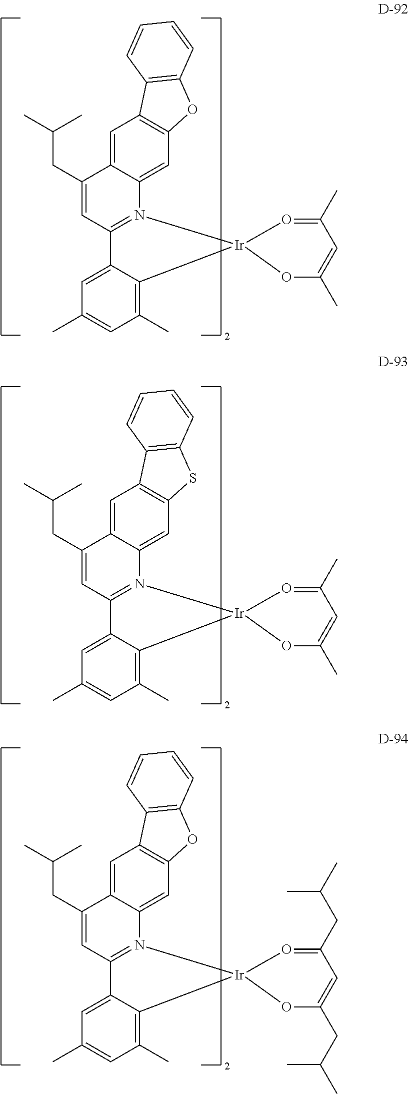

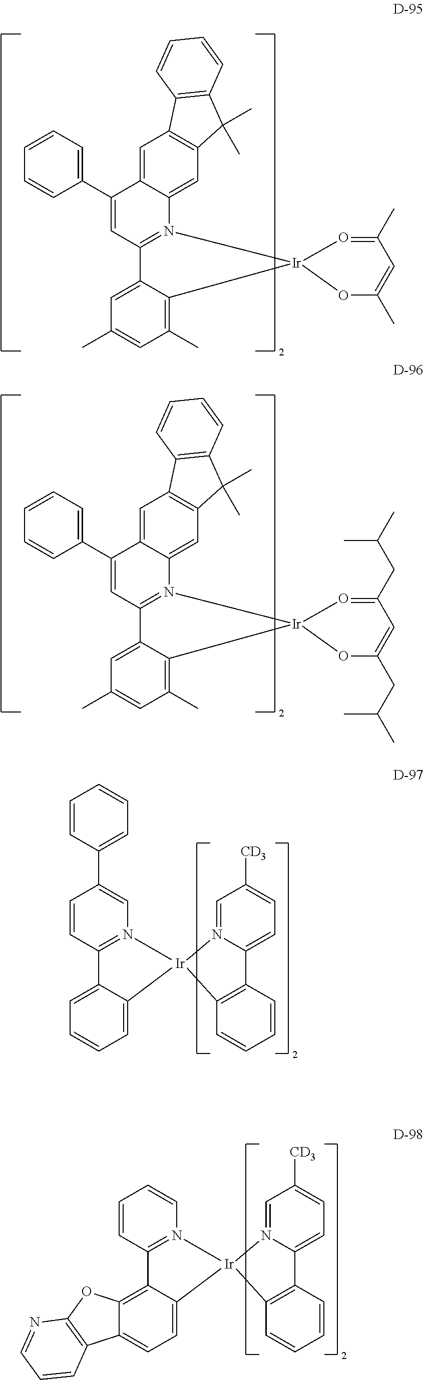

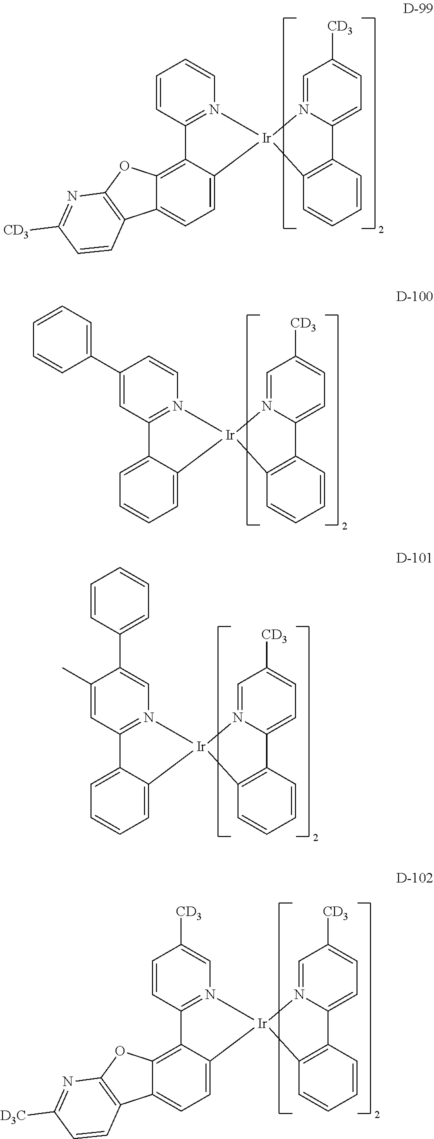

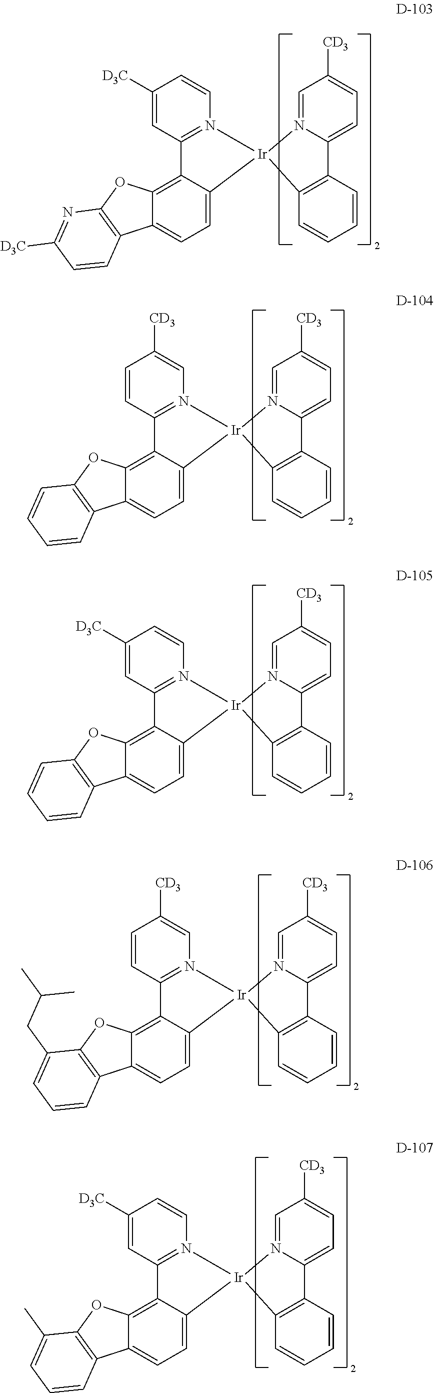

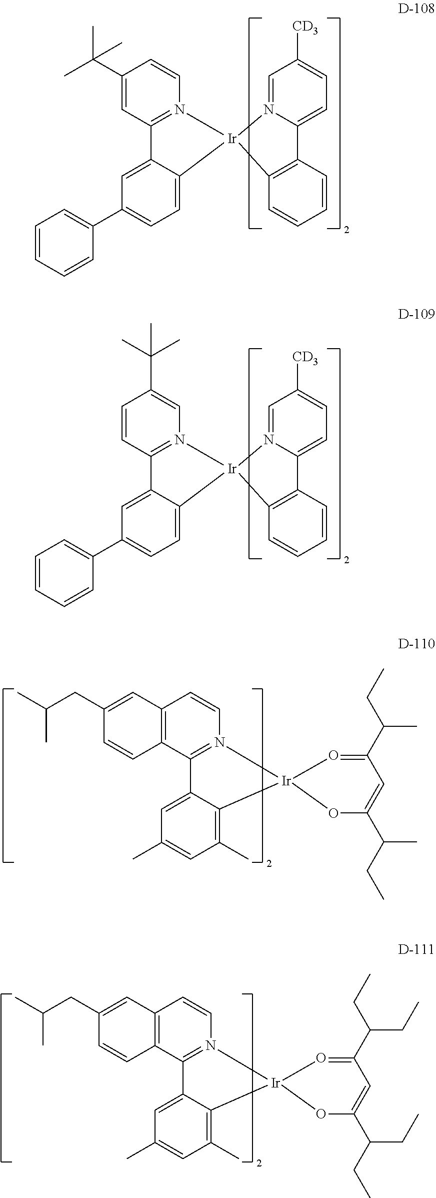

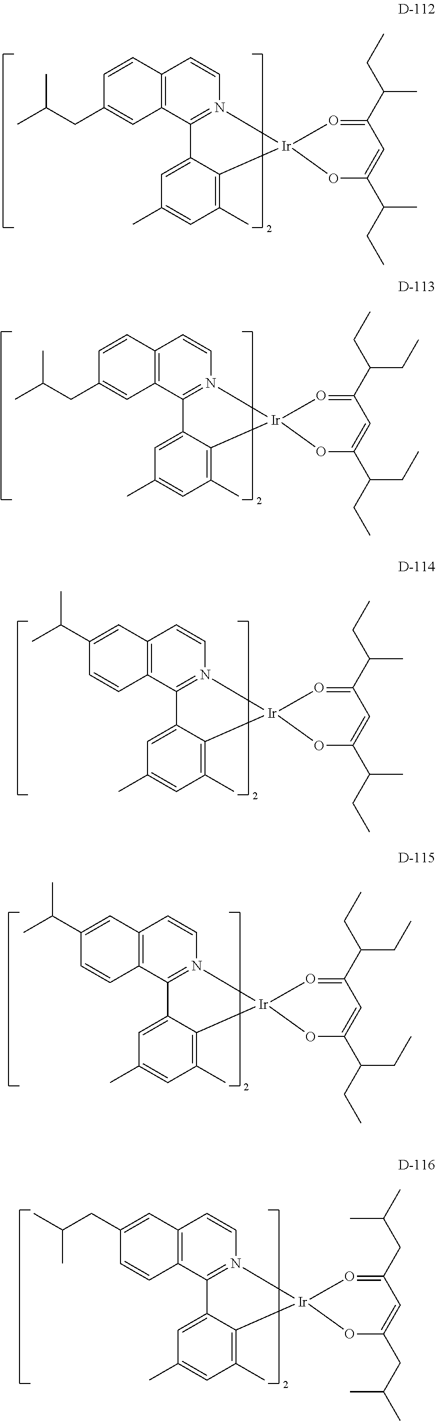

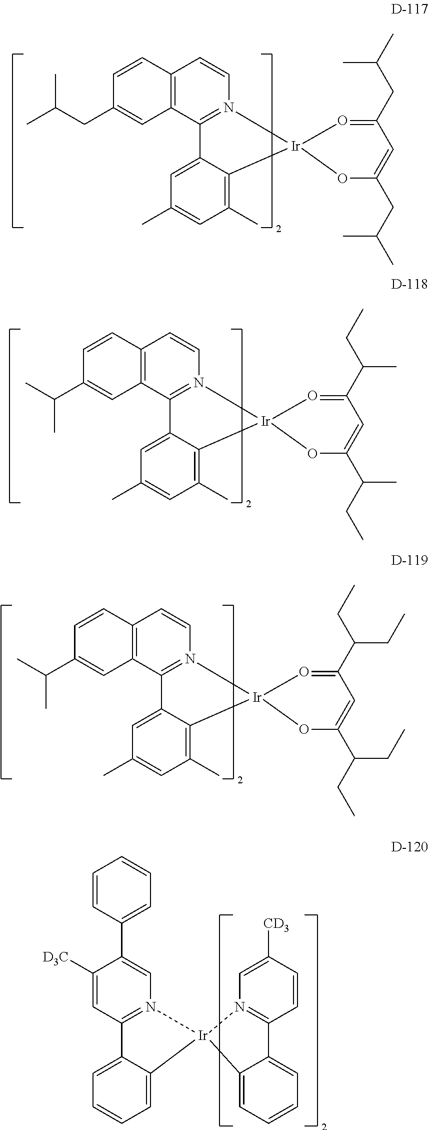

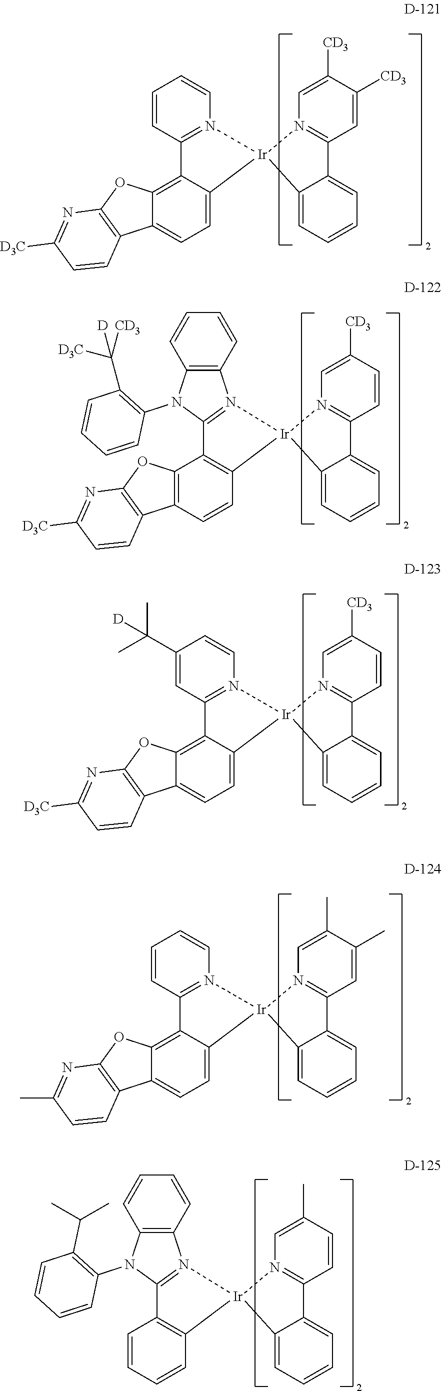

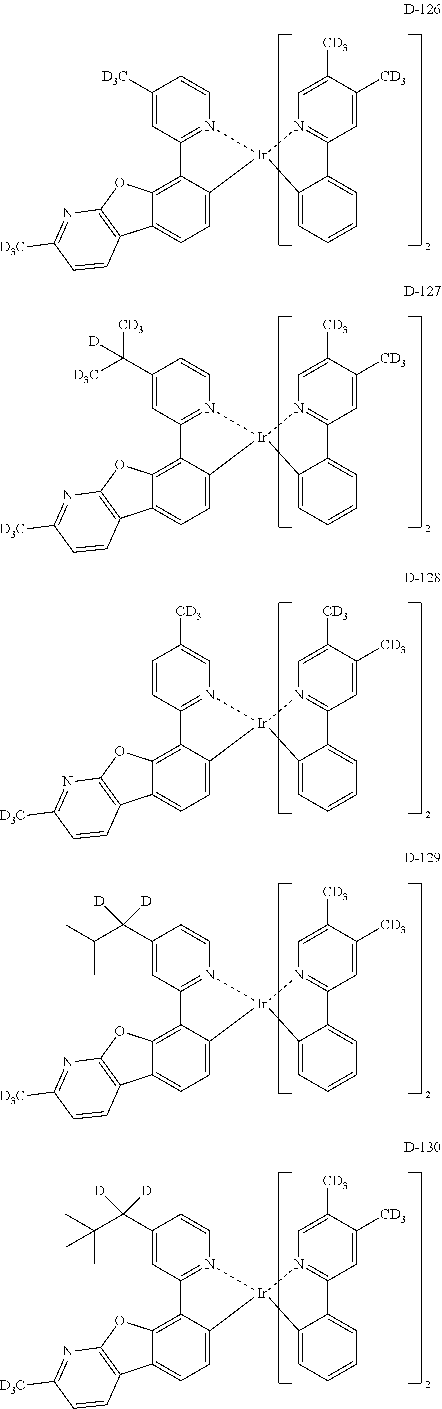

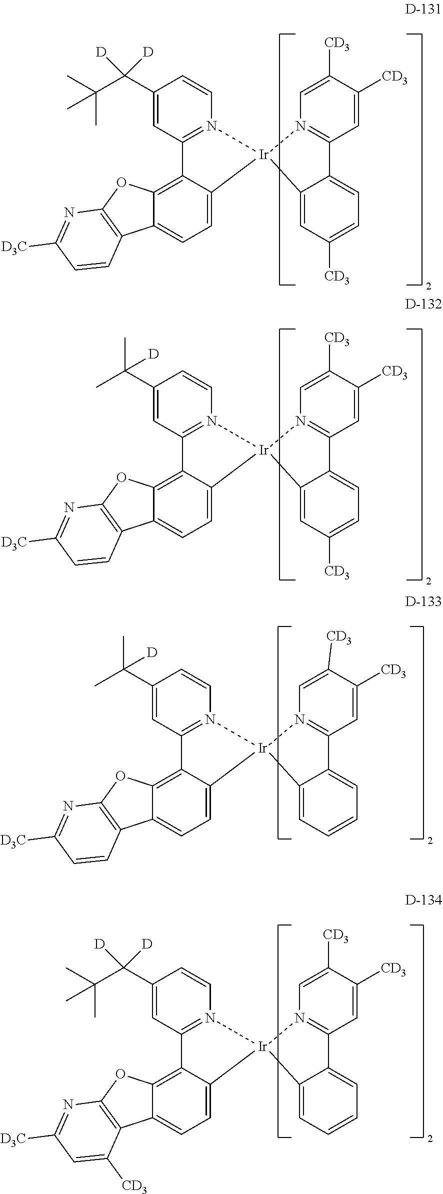

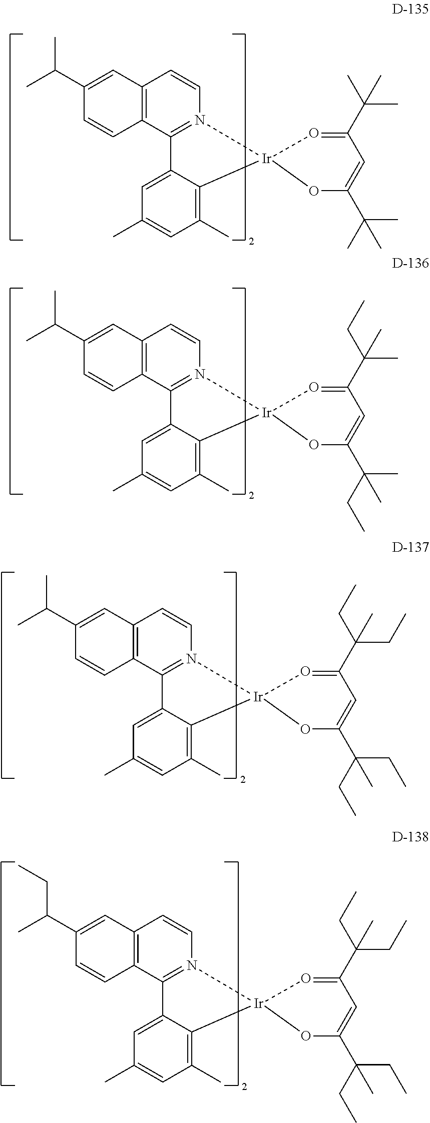

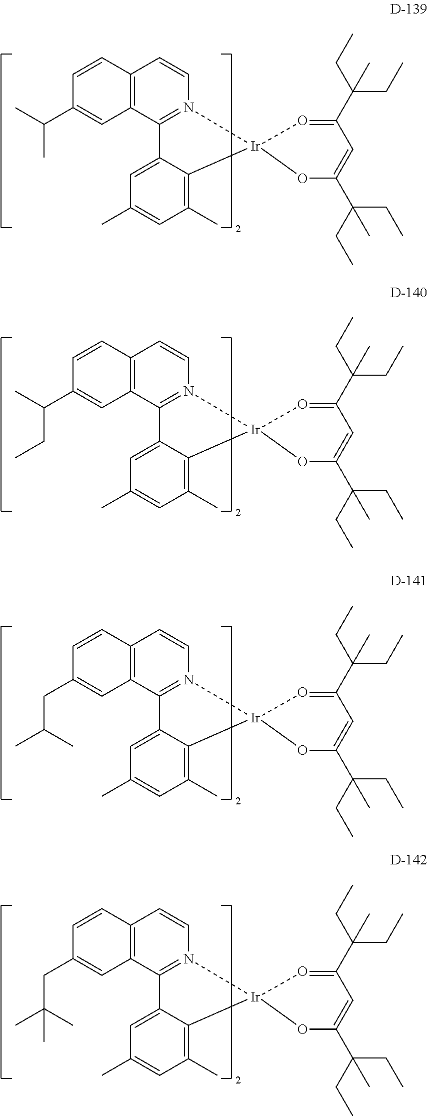

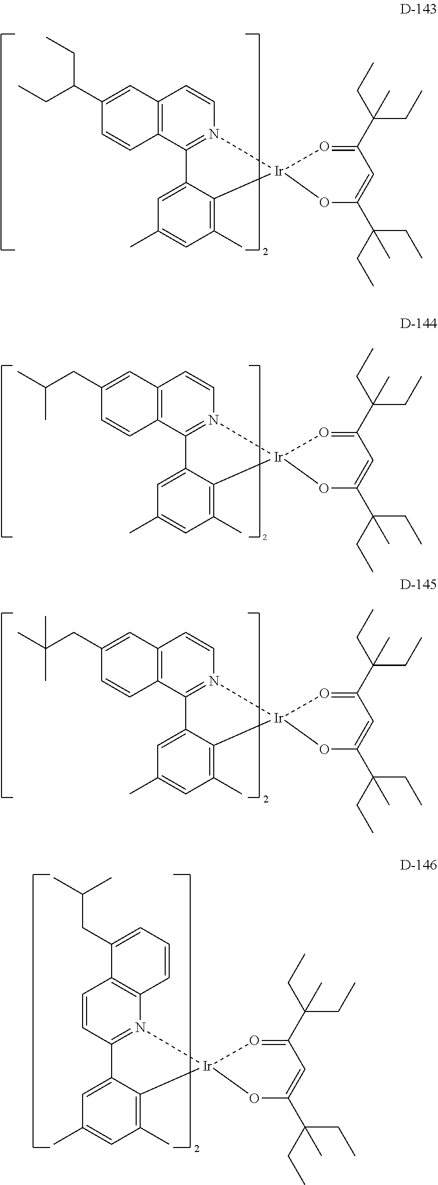

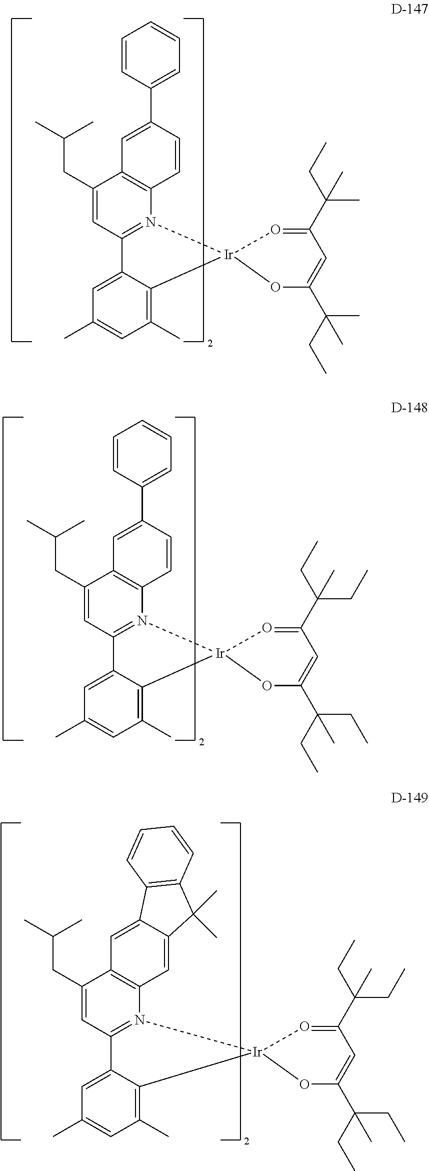

In order to form each layer of the organic electroluminescent device of the present disclosure, dry film-forming methods such as vacuum evaporation, sputtering, plasma, ion plating methods, etc. or wet film-forming methods such as spin coating, dip coating, flow coating methods, etc. can be used.

When using a wet film-forming method, a thin film may be formed by dissolving or diffusing materials forming each layer into any suitable solvent such as ethanol, chloroform, tetrahydrofuran, dioxane, etc. The solvent may be any solvent where the materials forming each layer can be dissolved or diffused, and where there are no problems in film formation capability.

According to one embodiment of the present disclosure, when forming a film of the first host compound and the second host compound of the present invention, the film can be formed by the above-listed methods, and can be formed commonly by a co-deposition or mixed deposition process. The co-deposition is a method of mixing and depositing two or more materials by placing them in separate crucible sources and applying current to two cells simultaneously to evaporate the materials, and the mixed deposition is a method of mixing two or more materials in one crucible source before deposition and then applying current to one cell to evaporate the materials.

According to one embodiment of the present disclosure, when the first host material and the second host material exist in the same layer or different layers in the organic electroluminescent device, the layers by the two host compounds may be separately formed. For example, after depositing the first host material, a second host material may be deposited.

The organic electroluminescent material according to one embodiment of the present disclosure may be used as a light-emitting material for a white organic light-emitting device. The white organic light-emitting device has been suggested to have various structures such as a side-by-side structure or a stacking structure depending on the arrangement of R (red), G (green) or YG (yellowish green), and B (blue) light-emitting parts, or a color conversion material (CCM) method, etc. In addition, the compound or the organic electroluminescent material according to one embodiment of the present disclosure may also be used in an organic electroluminescent device comprising a quantum dot (QD). In addition, it is possible to produce a display system, e.g., a display system for smartphones, tablets, notebooks, PCs, TVs, or cars; or a lighting system, e.g., an outdoor or indoor lighting system, using a plurality of host materials according to the present disclosure.

Hereinafter, for a detailed understanding of the present disclosure, representative compounds of the present disclosure will be used to examine the preparation method of the compound according to the present disclosure and its physical properties and the luminescence characteristics of an OLED comprising an organic electroluminescent compound according to the present disclosure or a plurality of host materials. However, the following examples are only provided to explain the characteristics of an OLED including an organic electroluminescent compound according to the present disclosure or a plurality of host materials for a detailed understanding of the present disclosure, and the present disclosure is not limited to the following examples.

### Example 1: Preparation of Compound A

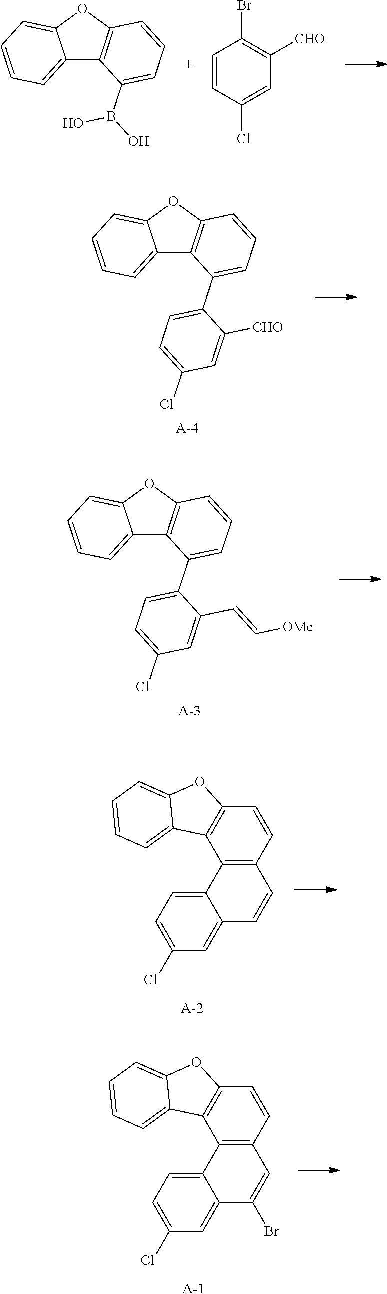

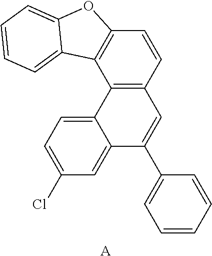

### 1) Synthesis of Compound A-4

In a flask, dibenzo[b,d]furan-1-ylboronic acid (50 g, 235.84 mmol), 2-bromo-5-chlorobenzaldehyde (56.9 g, 259.4 mmol), tetrakis(triphenylphosphine) palladium (0) (Pd(PPh₃)₄) (8.18 g, 7.08 mmol), K₂CO₃ (81.4 g, 589.6 mmol), 1,179 mL of toluene, 294 mL of ethanol, and 294 mL of water were dissolved in a flask, and the mixture was refluxed at 120° C. for 5 hours. After completion of the reaction, the organic layer was extracted with ethyl acetate, and the remaining moisture was removed with magnesium sulfate. Thereafter, the organic layer was dried and separated by column chromatography to obtain Compound A-4 (64.8 g, yield: 89%).

### 2) Synthesis of Compound A-3

Compound A-4 (64.8 g, 211 mmol) and (methoxymethyl)triphenylphosphonium chloride (108 g, 315 mmol) were added to a flask and dissolved in 1.4 L of THF, and 316 mL of 1 M potassium tert-butoxide was slowly added at 0° C. After stirring for 1 hour, the organic layer was extracted with ethyl acetate, and the remaining moisture was removed with magnesium sulfate. Thereafter, the organic layer was dried and separated by column chromatography to obtain Compound A-3 (69 g, yield: 98%).

### 3) Synthesis of Compound A-2

Compound A-3 (69 g, 206 mmol) was added to the flask and dissolved in 1.3 L of dichloromethane, and 18 mL of triflic acid was slowly added at 0° C. After stirring for 1 hour, the organic layer was extracted with ethyl acetate, and the remaining moisture was removed with magnesium sulfate. Thereafter, the organic layer was dried and separated by column chromatography to obtain Compound A-2 (30 g, yield: 48%).

### 4) Synthesis of Compound A-1

Compound A-2 (20 g, 66 mmol) was added to a flask, N-bromo succinimide (12.3 g, 69.1 mmol) was added, and these were dissolves in 330 mL of N,N′-dimethylformamide and stirred at room temperature for 24 hours. After completion of the reaction, the organic layer was extracted with ethyl acetate, and the remaining moisture was removed with magnesium sulfate. Thereafter, the organic layer was dried and separated by column chromatography to obtain Compound A-1 (17 g, yield: 68%).

### 5) Synthesis of Compound A

Compound A-1 (7 g, 18.34 mmol), phenyl boronic acid (2.68 g, 22.01 mmol), Pd(PPh₃)₄ (1.06 g, 0.92 mmol), and K₂CO₃ (5.07 g, 36.68 mmol) were placed in a flask, and 91.71 mL of toluene, 22.93 mL of ethanol, and 22.93 ml of water were added to dissolve these, and the mixture was then refluxed at 120° C. for 2 hours. After completion of the reaction, the organic layer was extracted with ethyl acetate, and the remaining moisture was removed with magnesium sulfate. Thereafter, the organic layer was dried and separated by column chromatography to obtain Compound A (6.7 g, yield: 96%).

### Example 2: Preparation of Compound H1-62

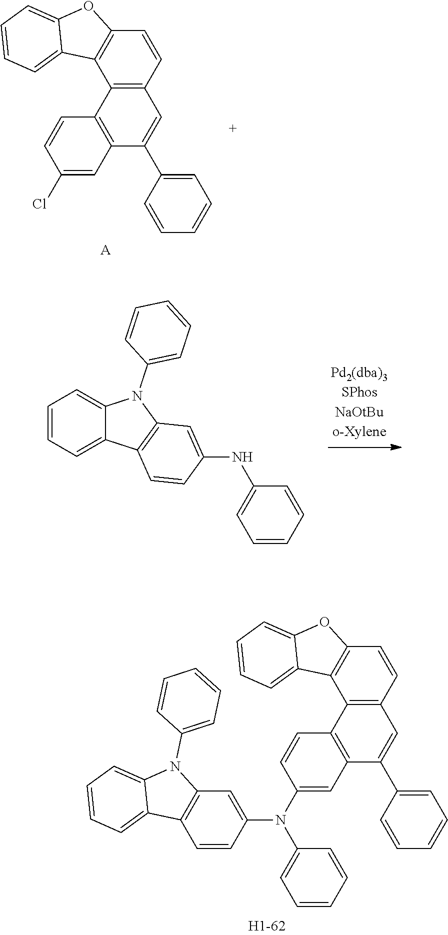

Compound A (3-chloro-5-phenylphenanthro[3,4-b]benzofuran (6 g, 15.84 mmol)), N,9-diphenyl-9H-carbazol-2-amine (5.83 g, 17.42 mmol), tris(dibenzylideneacetone)dipalladium(0) (730 mg, 0.79 mmol), dicyclohexyl[2′,6′-dimethoxy[1,1′-biphenyl]-2-yl]phosphane (SPhos) (650 mg, 1.58 mmol), sodium tert-butoxide (2.28 g, 23.76 mmol), and 79 mL of o-xylene were dissolved in a flask and refluxed at 160° C. for 1 hour. After completion of the reaction, the organic layer was extracted with ethyl acetate, and the remaining moisture was removed with magnesium sulfate. Thereafter, the organic layer was dried and separated by column chromatography to obtain Compound H1-62 (4.6 g, yield: 42.9%).

| | M.W. | M.P. |
|---|---|---|
| H1-62 | 676.82 | 157° C. |

### Example 3: Preparation of Compound H1-20

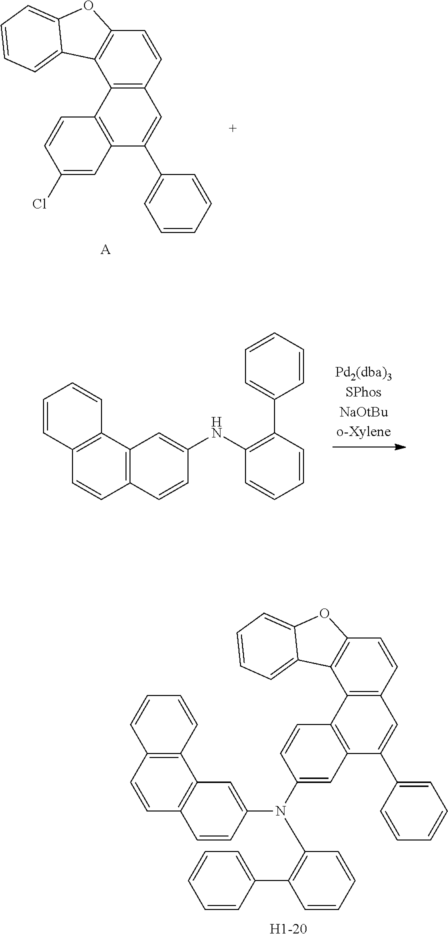

Compound A (3-chloro-5-phenylphenanthro[3,4-b]benzofuran (6 g, 15.84 mmol)), N-([1,1′-biphenyl]-2-yl)phenanthren-3-amine (6.0 g, 17.42 mmol), tris(dibenzylideneacetone)dipalladium(0) (730 mg, 0.79 mmol), dicyclohexyl[2′,6′-dimethoxy[1,1′-biphenyl]-2-yl]phosphane (SPhos) (650 mg, 1.58 mmol), sodium tert-butoxide (3.04 g, 31.67 mmol), and 79 mL of o-xylene were dissolved in a flask and refluxed at 160° C. for 1 hour. After completion of the reaction, the organic layer was extracted with ethyl acetate, and the remaining moisture was removed with magnesium sulfate. Thereafter, the organic layer was dried and separated by column chromatography to obtain Compound H1-20 (6.6 g, yield: 60.1%).

| | M.W. | M.P. |
|---|---|---|
| H1-20 | 687.84 | 204.4° C. |

### Example 4: Preparation of Compound H1-4

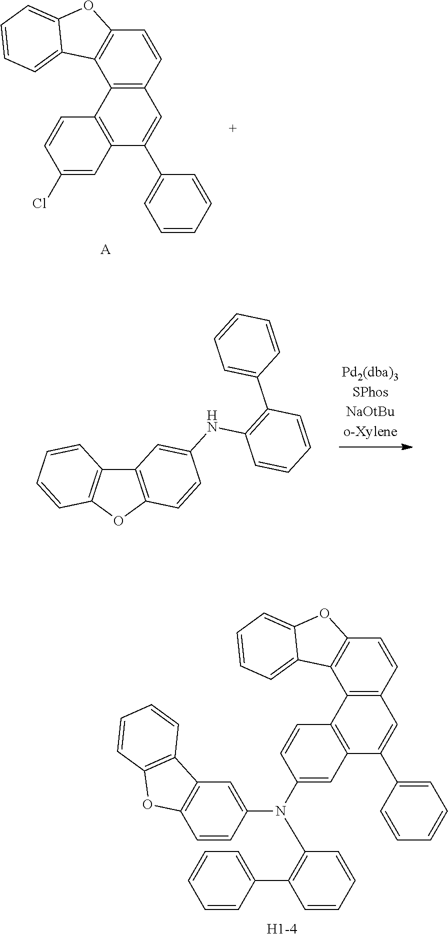

Compound A (3-chloro-5-phenylphenanthro[3,4-b]benzofuran (8.89 g, 23.47 mmol)), N-([1,1′-biphenyl]-2-yl)phenanthren-3-amine (9.44 g, 28.16 mmol), tris(dibenzylideneacetone)dipalladium(0) (2.15 g, 2.35 mmol), dicyclohexyl[2′,6′-dimethoxy[1,1′-biphenyl]-2-yl]phosphane (SPhos) (1.93 g, 4.69 mmol), sodium tert-butoxide (4.51 g, 46.93 mmol), and 117 mL of o-xylene were dissolved in a flask and refluxed at 160° C. for 1 hour. After completion of the reaction, the organic layer was extracted with ethyl acetate, and the remaining moisture was removed with magnesium sulfate. Thereafter, the organic layer was dried and separated by column chromatography to obtain Compound H1-4 (4.4 g, yield: 27.6%).

| | M.W. | M.P. |
|---|---|---|
| H1-4 | 677.80 | 205° C. |

### Device Examples 1 and 2: Producing OLEDs Comprising a Plurality of Host Materials According to the Present Disclosure

An OLED according to the present disclosure was produced. First, a transparent electrode indium tin oxide (ITO) thin film (10 Ω/sq) on a glass substrate for an OLED (GEOMATEC CO., LTD., Japan) was subjected to an ultrasonic washing with acetone and isopropyl alcohol, sequentially, and was then stored in isopropyl alcohol. The ITO substrate was mounted on a substrate holder of a vacuum vapor deposition apparatus. Compound HI-1 was introduced into a cell of the vacuum vapor deposition apparatus, and Compound HT-1 was introduced into another cell. The two materials were evaporated at different rates, and Compound HI-1 was deposited in a doping amount of 3 wt % based to the total amount of Compound HI-1 and Compound HT-1 to form a hole injection layer with a thickness of 10 nm. Subsequently, Compound HT-1 was deposited on the hole injection layer to form a first hole transport layer with a thickness of 80 nm. Next, Compound HT-2 was introduced into another cell of the vacuum vapor deposition apparatus and was evaporated by applying an electric current to the cell to thereby deposit a second hole transport layer with a thickness of 55 nm on the first hole transport layer. Compound EB-1 was then added as an electron-blocking layer material, and an electron-blocking layer with a thickness of 5 nm was deposited on the second hole transport layer. Each of the first host compound and the second host compound shown in Table 1 below were introduced into two cells of the vacuum vapor deposition apparatus as hosts, and Compound D-39 was introduced into another cell as a dopant. The two host materials were evaporated at a rate of 1:1, the dopant material was simultaneously evaporated at a different rate, and the dopant was deposited in a doping amount of 3 wt % based on the total amount of the hosts and dopant to form a light-emitting layer with a thickness of 40 nm on the second hole transport layer. Then, Compound ET-1 and Compound EI-1 were evaporated at a weight ratio of 50:50 as an electron transport layer to form an electron transport layer having a thickness of 35 nm on the light-emitting layer. After depositing Compound EI-1 as an electron injection layer with a thickness of 2 nm on the electron transport layer, an Al cathode was deposited with a thickness of 80 nm on the electron injection layer by using another vacuum vapor deposition apparatus to thereby produce an OLED. All of the materials used for producing the OLED were purified by vacuum sublimation at 10⁻⁶ Torr.

### Comparative Example 1: Producing an OLED Comprising a Plurality of Host Materials not According to the Present Disclosure

An OLED was produced in the same manner as in Device Examples 1 and 2, except that the host compound shown in Table 1 below was used.

The following Table 1 shows the driving voltage, luminous efficiency, light-emitting color at a luminance of 1,000 nit, and time taken for luminance to reduce from 100% to 95% at a luminance of 15,000 nit (lifetime: 795) for the OLEDs of Device Examples 1 to 3 and Comparative Example 1 produced as described above.

TABLE 1

| | | | | | | Life- |
|---|---|---|---|---|---|---|
| | | | Driving | Luminous | Light- | time |
| | First | Second | Voltage | Efficiency | Emitting | T₉₅ |
| | Host | Host | [V] | [cd/A] | Color | [hr] |
| Comparative | H-37 | C2-61 | 3.4 | 21.7 | Red | 12 |
| Example 1 | | | | | | |
| Device | H1-62 | C-253 | 2.9 | 30.3 | Red | 142 |
| Example 1 | | | | | | |
| Device | H1-62 | C-330 | 3.0 | 30.4 | Red | 136 |
| Example 2 | | | | | | |

From Table 1 above, it can be confirmed that the organic electroluminescent device comprising a plurality of host materials according to the present disclosure has lower driving voltage, higher luminous efficiency, and significantly improved lifetime characteristics compared to the organic electroluminescent device comprising a plurality of host materials not according to the present disclosure.

The compounds used in the above device examples and device comparative example are specifically shown in Table 2 below.

TABLE 2
Compounds used in comparative example of OLED and examples of OLED.

| | |
|---|---|
| Hole Injection Layer/ Hole Transport Layer | 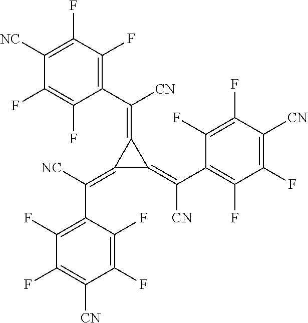 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F] HI-1 |
| | 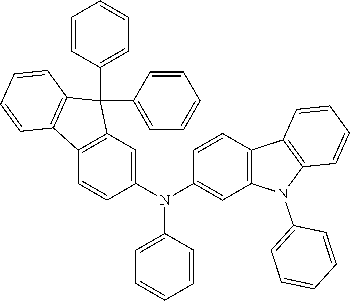 [SMILES: c1ccc(N(c2ccc3c(c2)C(c2ccccc2)(c2ccccc2)c2ccccc2-3)c2ccc3c4ccccc4n(-c4ccccc4)c3c2)cc1] |
| | HT-1 |
| | 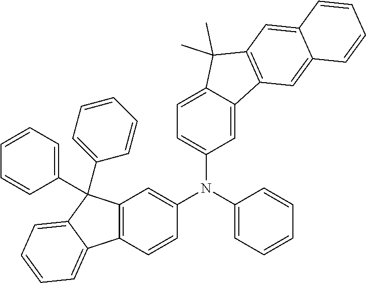 [SMILES: CC1(C)c2ccc(N(c3ccccc3)c3ccc4c(c3)C(c3ccccc3)(c3ccccc3)c3ccccc3-4)cc2-c2cc3ccccc3cc21] |
| | HT-2 |
| Electron- Blocking Layer | 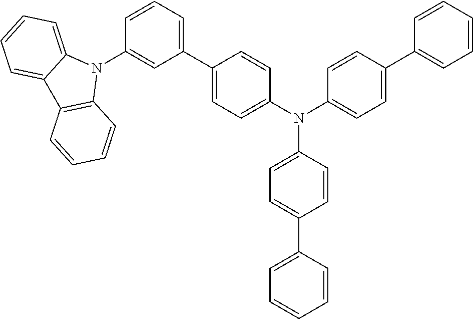 [SMILES: c1ccc(-c2ccc(N(c3ccc(-c4ccccc4)cc3)c3ccc(-c4cccc(-n5c6ccccc6c6ccccc65)c4)cc3)cc2)cc1] EB-1 |
| Light- Emitting Layer | 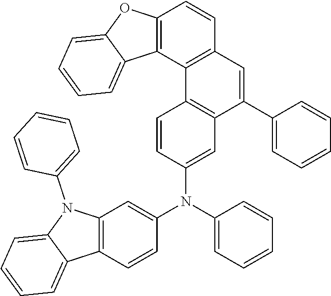 [SMILES: c1ccc(-c2cc3ccc4oc5ccccc5c4c3c3ccc(N(c4ccccc4)c4ccc5c6ccccc6n(-c6ccccc6)c5c4)cc23)cc1] H1-62 |
| | 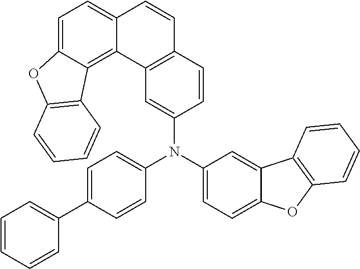 [SMILES: c1ccc(-c2ccc(N(c3ccc4oc5ccccc5c4c3)c3ccc4ccc5ccc6oc7ccccc7c6c5c4c3)cc2)cc1] |
| | H-37 |
| | 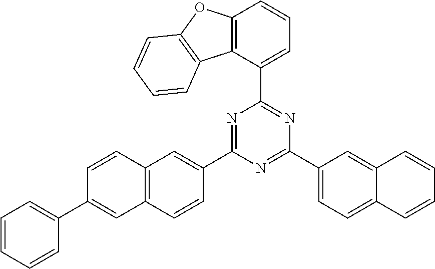 [SMILES: c1ccc(-c2ccc3cc(-c4nc(-c5ccc6ccccc6c5)nc(-c5cccc6oc7ccccc7c56)n4)ccc3c2)cc1] |
| | C-253 |
| | 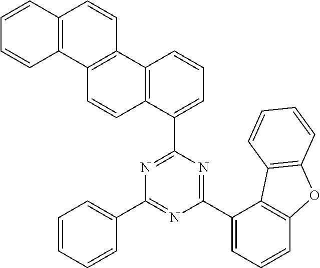 [SMILES: c1ccc(-c2nc(-c3cccc4c3ccc3c5ccccc5ccc43)nc(-c3cccc4oc5ccccc5c34)n2)cc1] |
| | C-330 |
| | 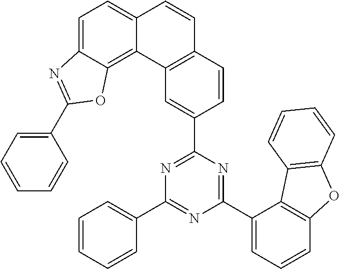 [SMILES: c1ccc(-c2nc(-c3ccc4ccc5ccc6nc(-c7ccccc7)oc6c5c4c3)nc(-c3cccc4oc5ccccc5c34)n2)cc1] |
| | C2-61 |
| | 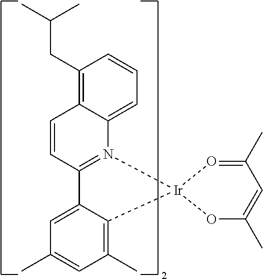 |
| | D-39 |
| Electron Transport Layer/ Electron Injection Layer | 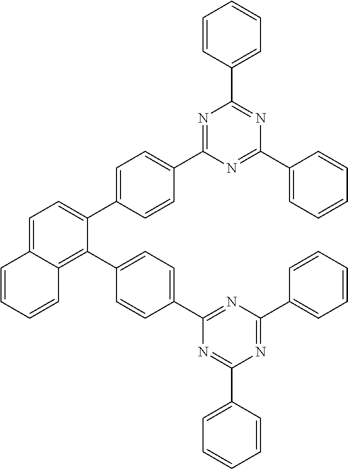 [SMILES: c1ccc(-c2nc(-c3ccccc3)nc(-c3ccc(-c4ccc5ccccc5c4-c4ccc(-c5nc(-c6ccccc6)nc(-c6ccccc6)n5)cc4)cc3)n2)cc1] ET-1 |
| | 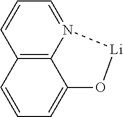 |
| | EI-1 |

1. A plurality of host materials comprising at least one first host compound and at least one second host compound, wherein the first host compound comprises a compound represented by the following Formula 1 and the second host compound comprises a compound represented by the following Formula 2: 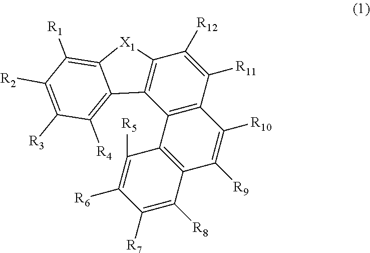
wherein in Formula 1,
X₁ represents O, S, or CR₁₃R₁₄;
R₁₃ and R₁₄ each independently represent a substituted or unsubstituted (C₁-C₃₀)alkyl, a substituted or unsubstituted (C₆-C₃₀)aryl, a substituted or unsubstituted (3- to 30-membered)heteroaryl, or R₁₃ and R₁₄ may be linked to each other to form a ring(s);
R₁ to R₁₂ each independently represent hydrogen, deuterium, a halogen, a cyano, a substituted or unsubstituted (C₁-C₃₀)alkyl, a substituted or unsubstituted (C₂-C₃₀)alkenyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₃-C₃₀)cycloalkenyl, a substituted or unsubstituted (3- to 7-membered)heterocycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted fused ring of (C₃-C₃₀) aliphatic ring(s) and (C₆-C₃₀) aromatic ring(s), a substituted or unsubstituted mono- or di-(C₁-C₃₀)alkylamino, a substituted or unsubstituted mono- or di-(C₆-C₃₀)arylamino, a substituted or unsubstituted (C₁-C₃₀)alkyl(C₆-C₃₀)arylamino, a substituted or unsubstituted mono- or di-(3- to 30-membered)heteroarylamino, or a substituted or unsubstituted (C₆-C₃₀)aryl(3- to 30-membered)heteroarylamino; or may be linked to the adjacent substituent(s) to form a ring(s);
with a proviso that at least one of R₁ to R₁₂ represents the following Formula 1-a: 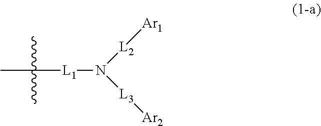
wherein in Formula 1-a, 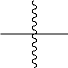
is a site linked to at least one of R₁ to R₁₂;
L₁ to L₃ each independently represent a single bond, a substituted or unsubstituted (C₆-C₃₀)arylene, a substituted or unsubstituted (3- to 30-membered)heteroarylene, or a substituted or unsubstituted (C₃-C₃₀)cycloalkylene;
Ar₁ and Ar₂ each independently represent a substituted or unsubstituted (C₆-C₃₀)aryl, a substituted or unsubstituted (3- to 30-membered)heteroaryl, or a substituted or unsubstituted (C₃-C₃₀)cycloalkyl; 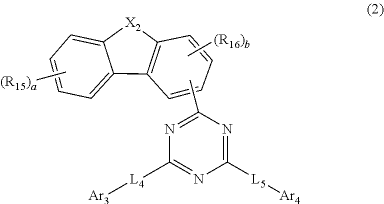
wherein in Formula 2,
X₂ represents O, S, or Se;
L₄ and L₅ each independently represent a single bond, a substituted or unsubstituted (C₆-C₃₀)arylene, or a substituted or unsubstituted (3- to 30-membered)heteroarylene;
Ar₃ and Ar₄ each independently represent a substituted or unsubstituted (C₆-C₃₀)aryl or a substituted or unsubstituted (3- to 30-membered)heteroaryl;
R₁₅ and R₁₆ each independently represent hydrogen, deuterium, a halogen, a cyano, a substituted or unsubstituted (C₁-C₃₀)alkyl, a substituted or unsubstituted (C₂-C₃₀)alkenyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₃-C₃₀)cycloalkenyl, a substituted or unsubstituted (3- to 7-membered)heterocycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted fused ring of (C₃-C₃₀) aliphatic ring(s) and (C₆-C₃₀) aromatic ring(s), a substituted or unsubstituted mono- or di-(C₁-C₃₀)alkylamino, a substituted or unsubstituted mono- or di-(C₆-C₃₀)arylamino, a substituted or unsubstituted (C₁-C₃₀)alkyl(C₆-C₃₀)arylamino, a substituted or unsubstituted mono- or di-(3- to 30-membered)heteroarylamino, or a substituted or unsubstituted (C₆-C₃₀)aryl(3- to 30-membered)heteroarylamino; or may be linked to the adjacent substituent(s) to form a ring(s);
a represents an integer of 1 to 4, b represents an integer of 1 to 3, and when each a and b are an integer of 2 or more, each of R₁₅ and each of R₁₆ may be the same or different;
with a proviso that when both R₁₅ and R₁₆ of Formula 2 are hydrogen or deuterium, at least one of R₁ to R₁₂ of Formula 1 represents Formula 1-a and at least one of the others represents a substituted or unsubstituted (C₆-C₃₀)aryl or a substituted or unsubstituted (3- to 30-membered)heteroaryl.

2. The plurality of host materials according to claim 1, wherein the compound represented by Formula 1 is represented by any one of the following Formulas 1-1 to 1-12: 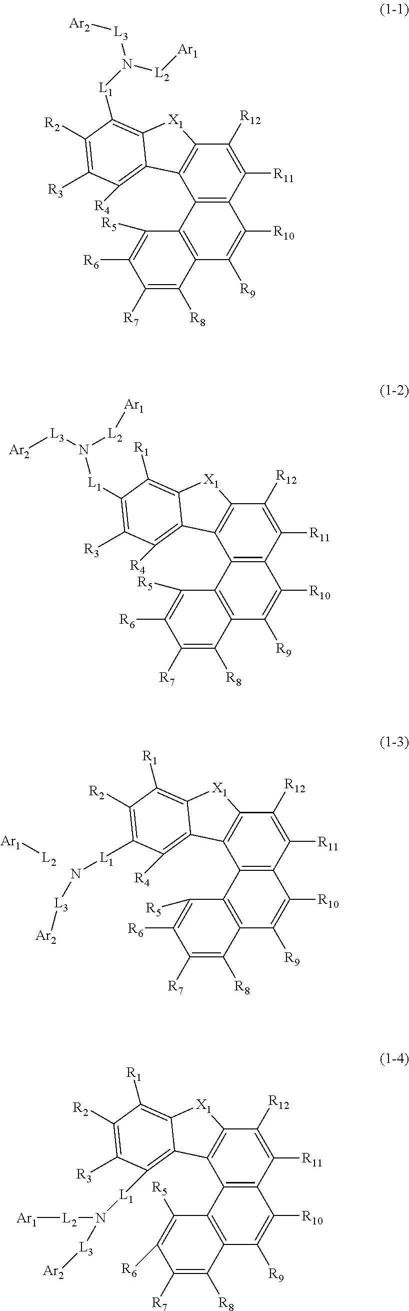 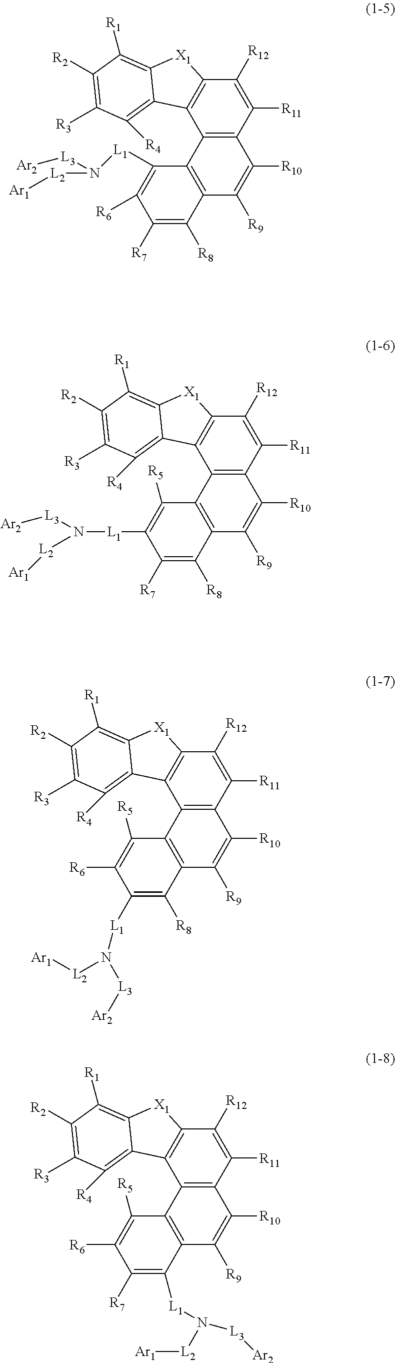 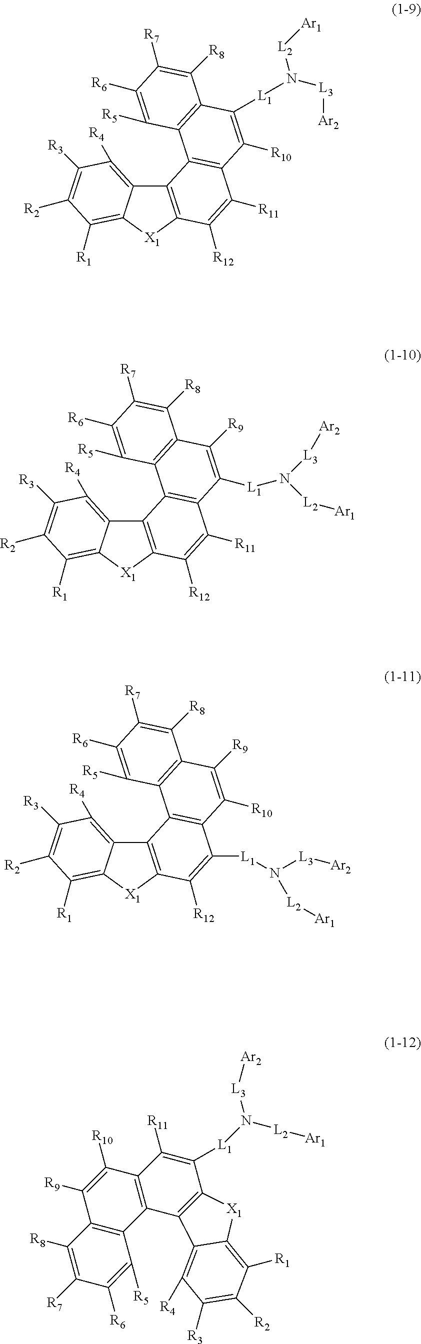
wherein in Formulas 1-1 to 1-12,
X₁, L₁ to L₃, Ar₁, Ar₂, and R₁ to R₁₂ are as defined in claim 1.

3. The plurality of host materials according to claim 1, wherein the compound represented by Formula 2 is represented by any one of the following Formulas 2-1 to 2-4: 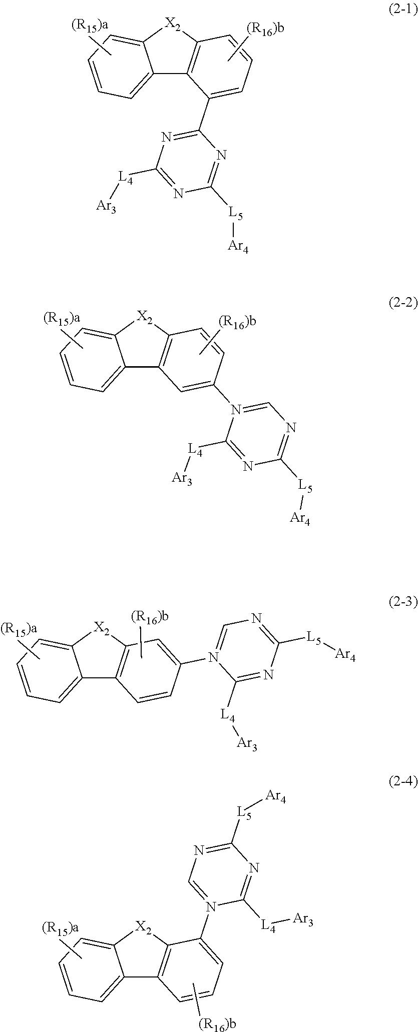
wherein in Formulas 2-1 to 2-4,
X₂, R₁₅, R₁₆, L₄, L₅, Ar₃, Ar₄, a, and b are as defined in claim 1.

4. The plurality of host materials according to claim 1, wherein the substituted alkyl, the substituted aryl, the substituted arylene, the substituted heteroaryl, the substituted heteroarylene, the substituted alkenyl, the substituted mono- or di-alkylamino, the substituted mono- or di-arylamino, the substituted alkylarylamino, the substituted mono- or di-heteroarylamino, the substituted heteroarene, the substituted cycloalkyl, the substituted cycloalkylene, the substituted cycloalkenyl, the substituted heterocycloalkyl, the substituted alkoxy, the substituted trialkylsilyl, the substituted dialkylarylsilyl, the substituted alkyldiarylsilyl, the substituted triarylsilyl, and the fused ring group of the substituted aliphatic ring and aromatic ring each independently are substituted with at least one selected from the group consisting of deuterium; a halogen; a cyano; a carboxyl; a nitro; a hydroxyl; a (C₁-C₃₀)alkyl; a halo(C₁-C₃₀)alkyl; a (C₂-C₃₀)alkenyl; a (C₂-C₃₀)alkynyl; a (C₁-C₃₀)alkoxy; a (C₁-C₃₀)alkylthio; a (C₃-C₃₀)cycloalkyl; a (C₃-C₃₀)cycloalkenyl; a (3- to 7-membered)heterocycloalkyl; a (C₆-C₃₀)aryloxy; a (C₆-C₃₀)arylthio; a (3- to 30-membered)heteroaryl unsubstituted or substituted with at least one of a (C₁-C₃₀)alkyl(s), a (C₆-C₃₀)aryl(s), a (3- to 30-membered)heteroaryl(s), and a di(C₆-C₃₀)arylamino(s); a (C₆-C₃₀)aryl unsubstituted or substituted with deuterium, a cyano(s), a (C₁-C₃₀)alkyl(s), a (3- to 50-membered)heteroaryl(s), a mono- or di(C₆-C₃₀)arylamino(s), and a tri(C₆-C₃₀)arylsilyl(s); a tri(C₁-C₃₀)alkylsilyl; a tri(C₆-C₃₀)arylsilyl; a di(C₁-C₃₀)alkyl(C₆-C₃₀)arylsilyl; a (C₁-C₃₀)alkyldi(C₆-C₃₀)arylsilyl; an amino; a mono- or di-(C₁-C₃₀)alkylamino; a mono- or di-(C₂-C₃₀)alkenylamino; a mono- or di-(C₆-C₃₀)arylamino; a mono- or di-(3- to 30-membered)heteroarylamino; a (C₁-C₃₀)alkyl(C₂-C₃₀)alkenylamino; a (C₁-C₃₀)alkyl(C₆-C₃₀)arylamino; a (C₁-C₃₀)alkyl(3- to 30-membered)heteroarylamino; a (C₂-C₃₀)alkenyl(C₆-C₃₀)arylamino; a (C₂-C₃₀)alkenyl(3- to 30-membered)heteroarylamino; a (C₆-C₃₀)aryl(3- to 30-membered)heteroarylamino; a (C₁-C₃₀)alkylcarbonyl; a (C₁-C₃₀)alkoxycarbonyl; a (C₆-C₃₀)arylcarbonyl; a di(C₆-C₃₀)arylboronyl; a di(C₁-C₃₀)alkylboronyl; a (C₁-C₃₀)alkyl(C₆-C₃₀)arylboronyl; a (C₆-C₃₀)aryl(C₁-C₃₀)alkyl; and a (C₁-C₃₀)alkyl(C₆-C₃₀)aryl.

5. The plurality of host materials according to claim 1, wherein the compound represented by Formula 1 is selected from the following compounds:

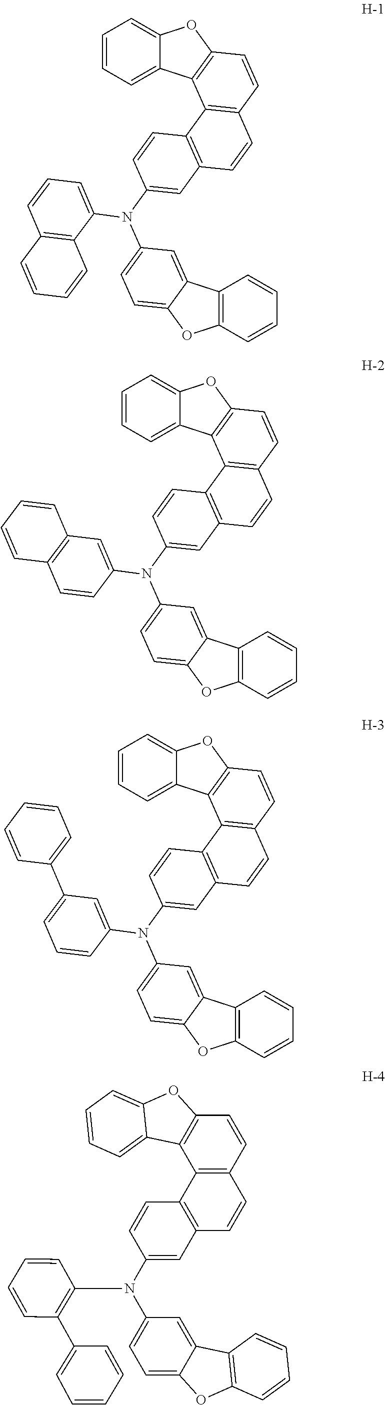 [SMILES: c1ccc2c(N(c3ccc4c(ccc5ccc6oc7ccccc7c6c54)c3)c3ccc4oc5ccccc5c4c3)cccc2c1 ; c1ccc2cc(N(c3ccc4c(ccc5ccc6oc7ccccc7c6c54)c3)c3ccc4oc5ccccc5c4c3)ccc2c1 ; c1ccc(-c2cccc(N(c3ccc4c(ccc5ccc6oc7ccccc7c6c54)c3)c3ccc4oc5ccccc5c4c3)c2)cc1 ; c1ccc(-c2ccccc2N(c2ccc3c(ccc4ccc5oc6ccccc6c5c43)c2)c2ccc3oc4ccccc4c3c2)cc1]

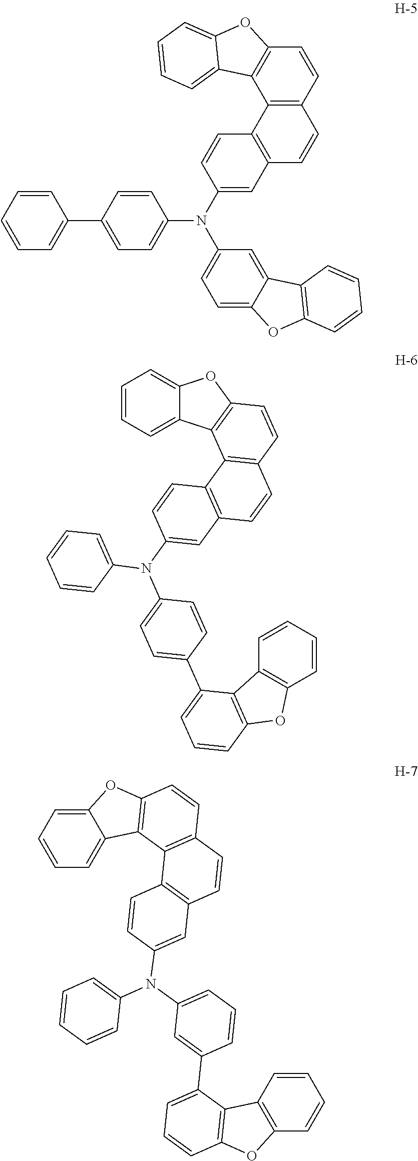

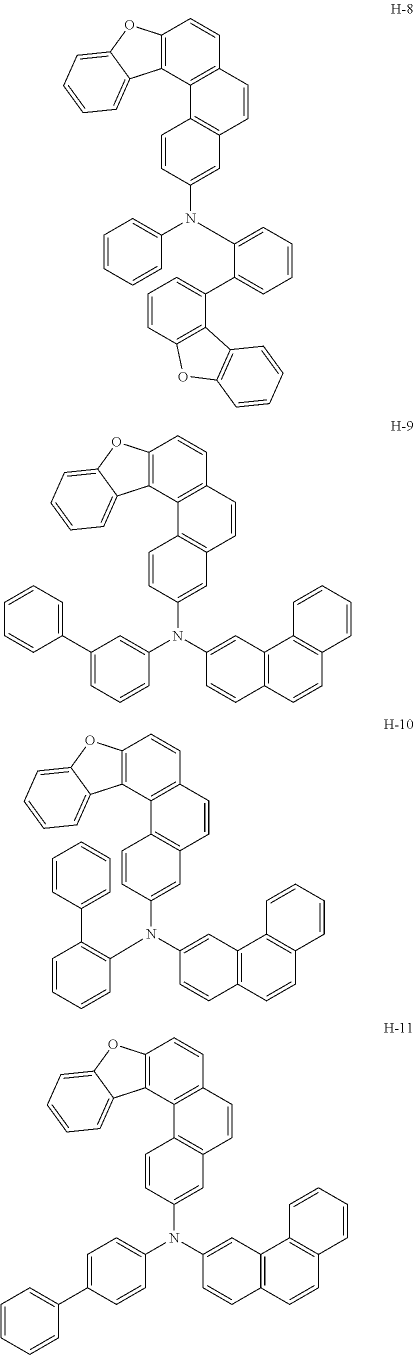

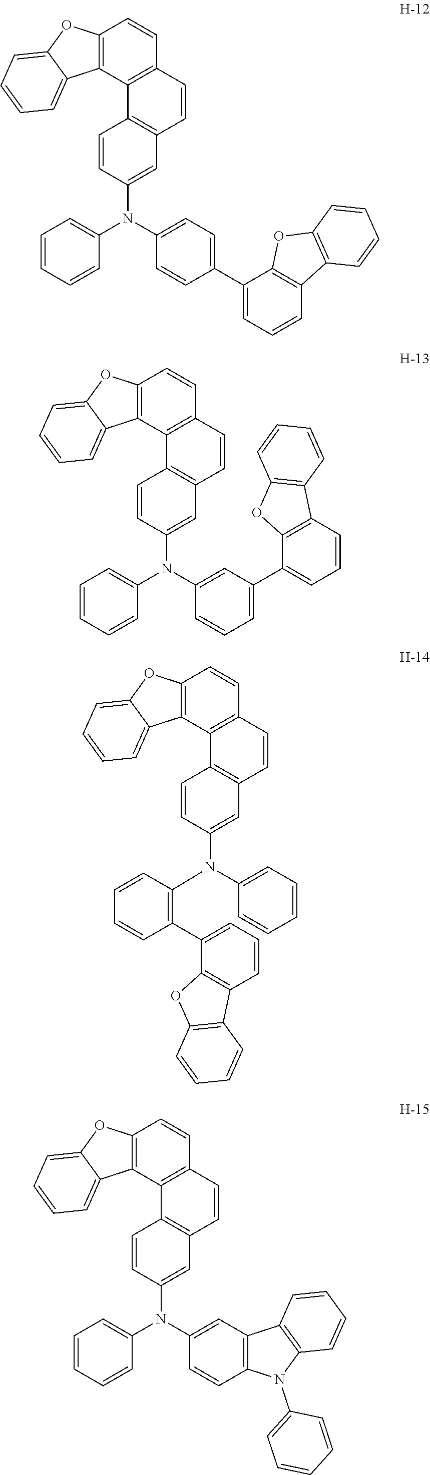

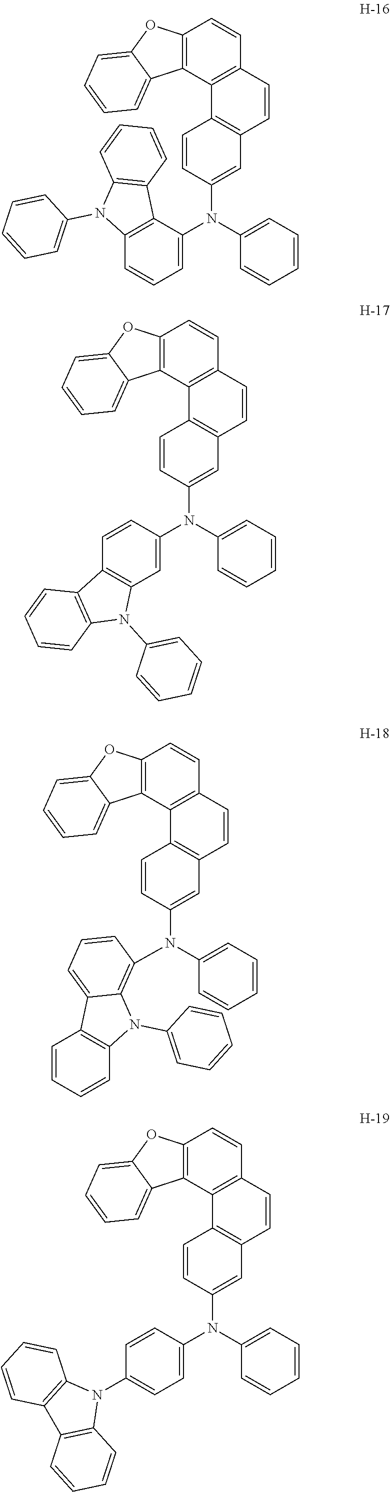

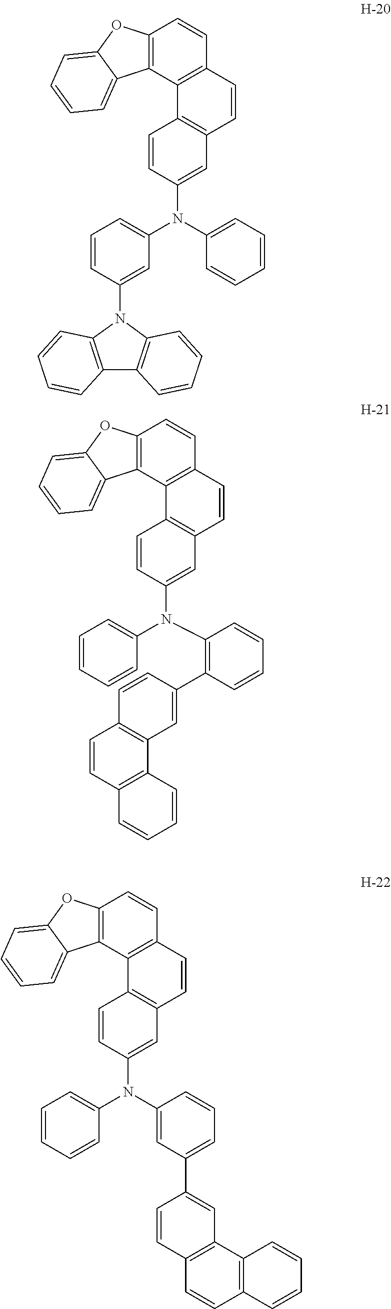

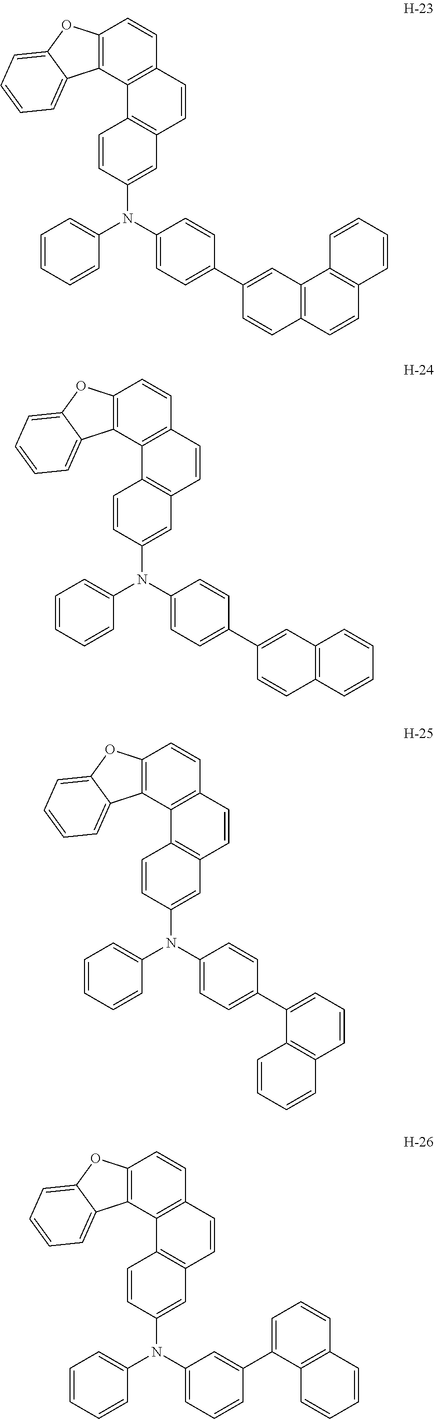 [SMILES: c1ccc(N(c2ccc(-c3ccc4ccc5ccccc5c4c3)cc2)c2ccc3c(ccc4ccc5oc6ccccc6c5c43)c2)cc1 ; c1ccc(N(c2ccc(-c3ccc4ccccc4c3)cc2)c2ccc3c(ccc4ccc5oc6ccccc6c5c43)c2)cc1 ; c1ccc(N(c2ccc(-c3cccc4ccccc34)cc2)c2ccc3c(ccc4ccc5oc6ccccc6c5c43)c2)cc1 ; c1ccc(N(c2cccc(-c3cccc4ccccc34)c2)c2ccc3c(ccc4ccc5oc6ccccc6c5c43)c2)cc1]

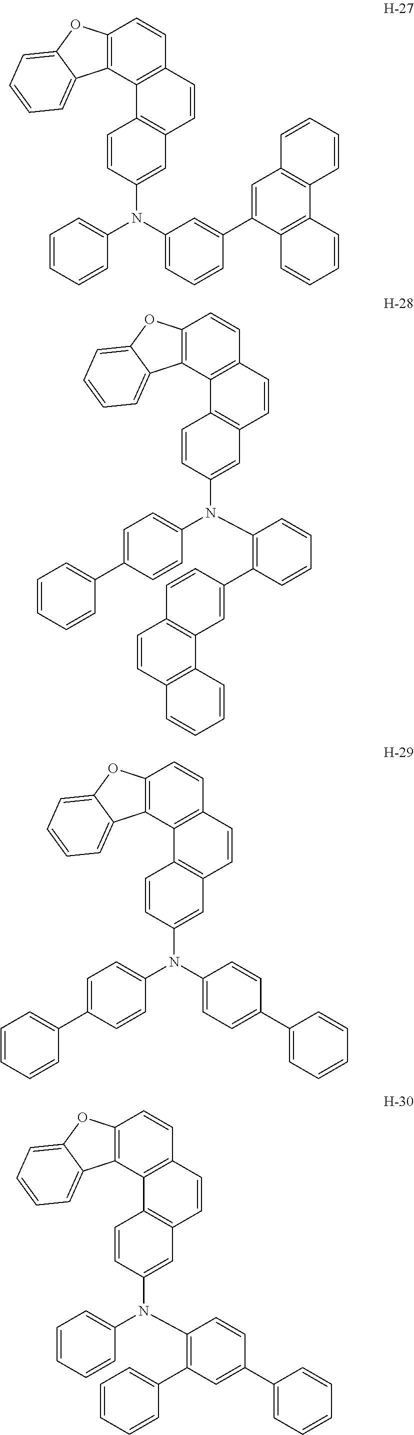

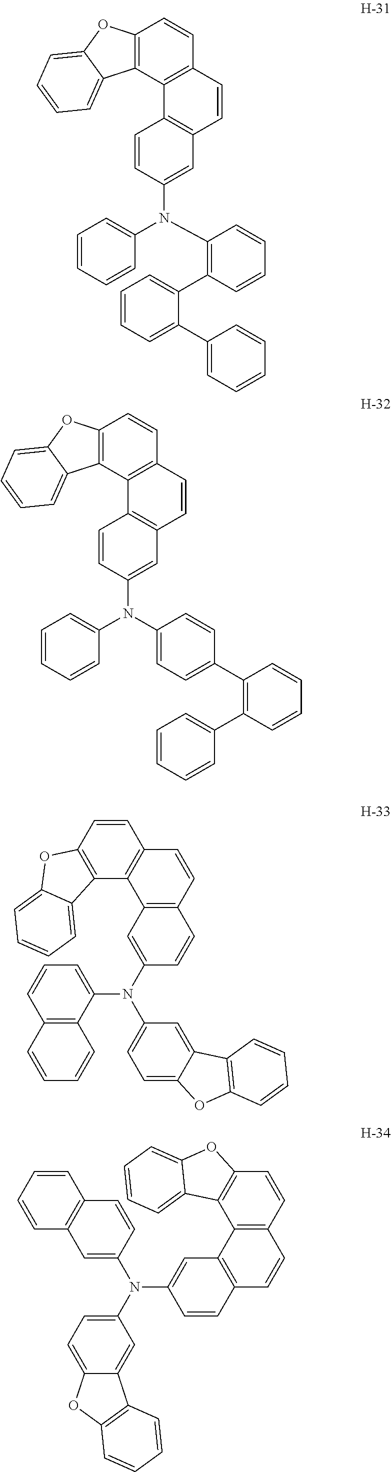

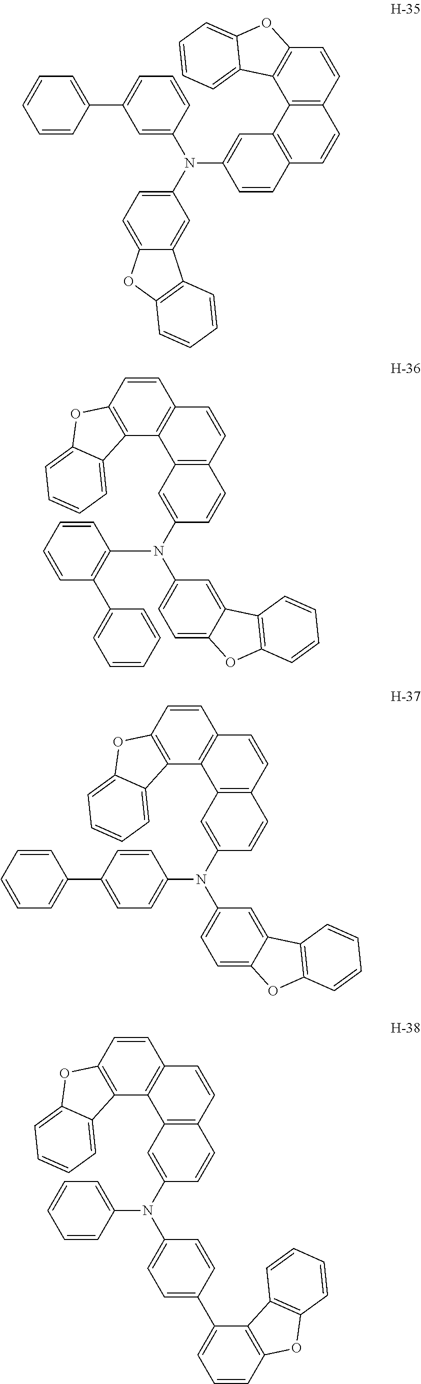

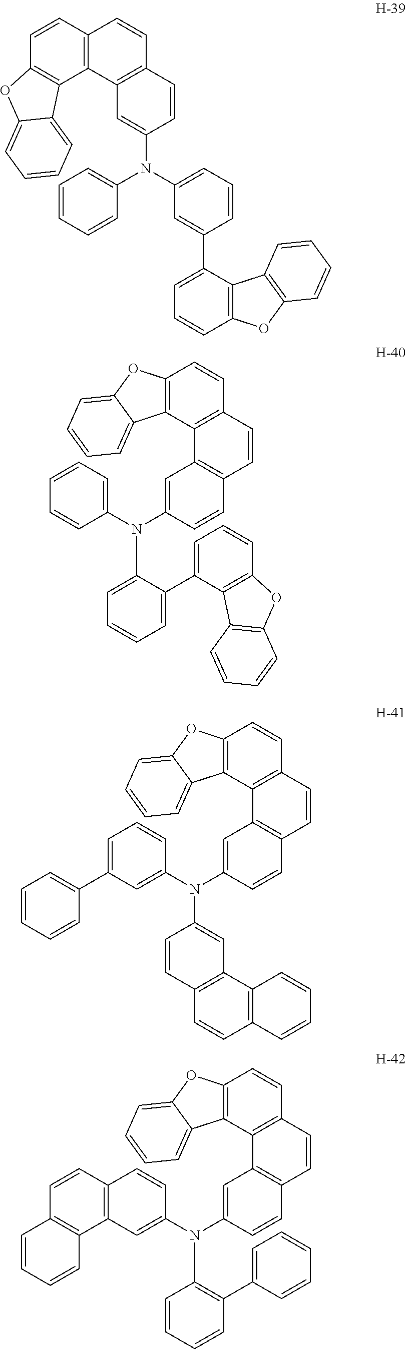

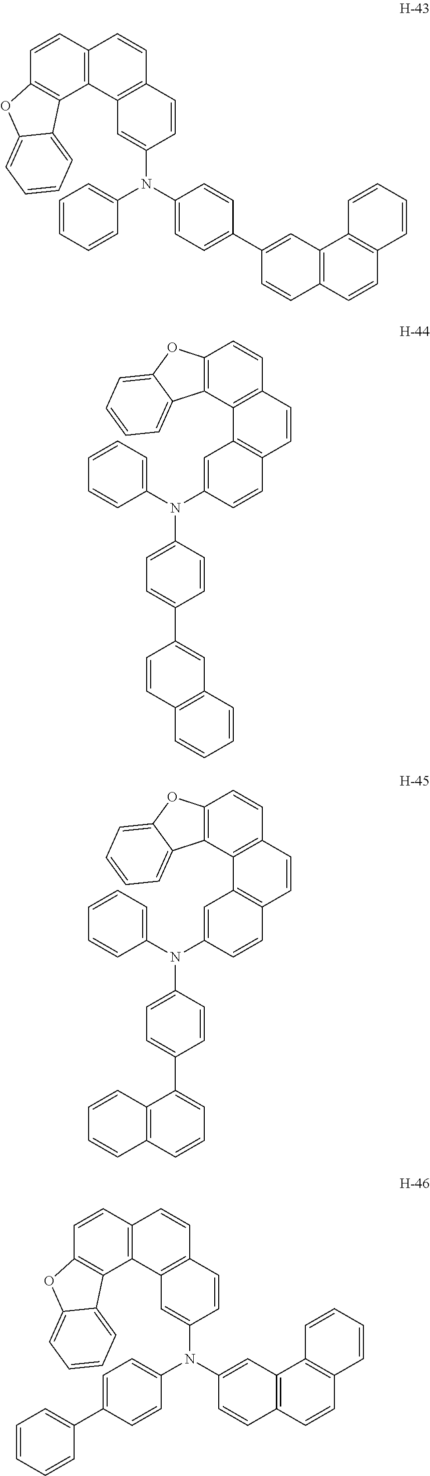

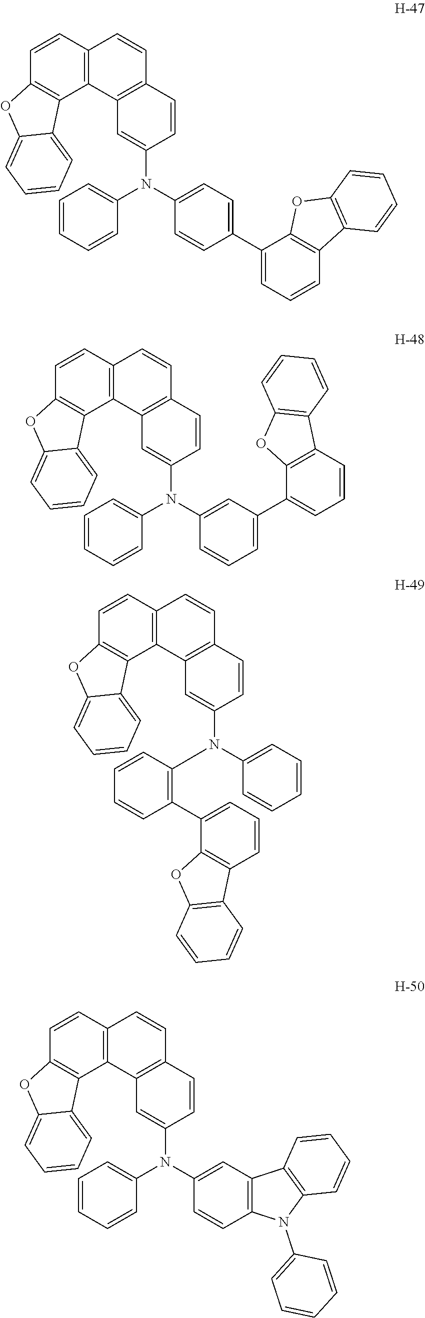

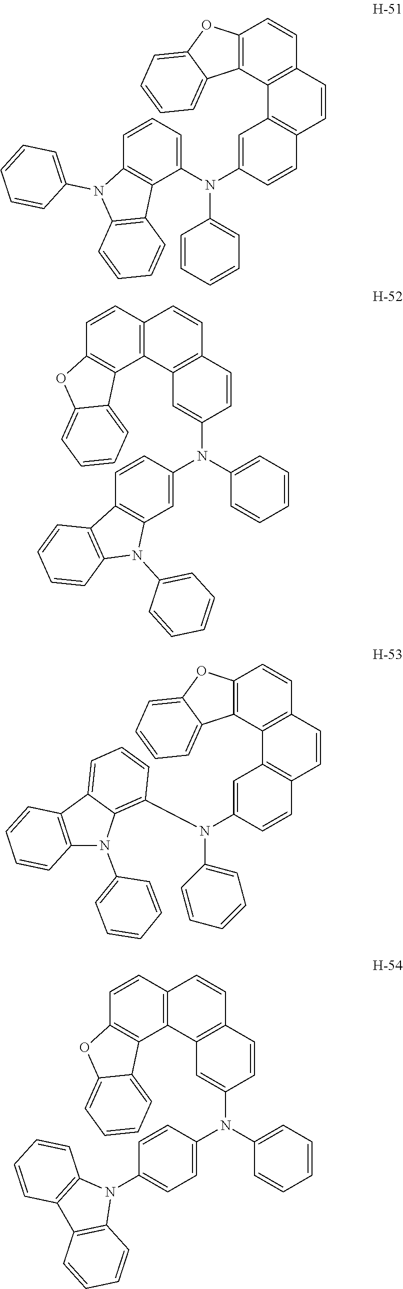

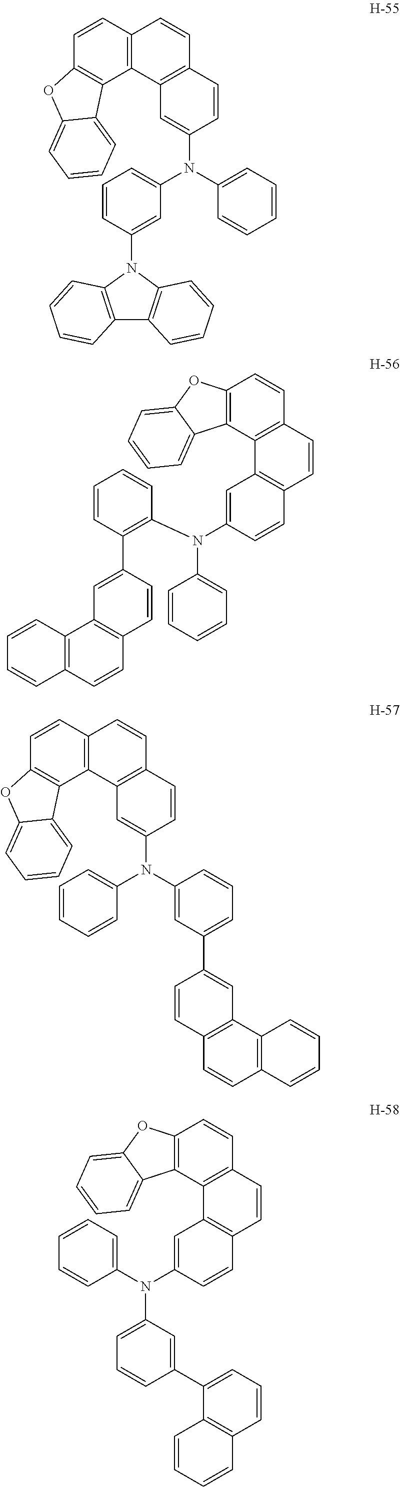

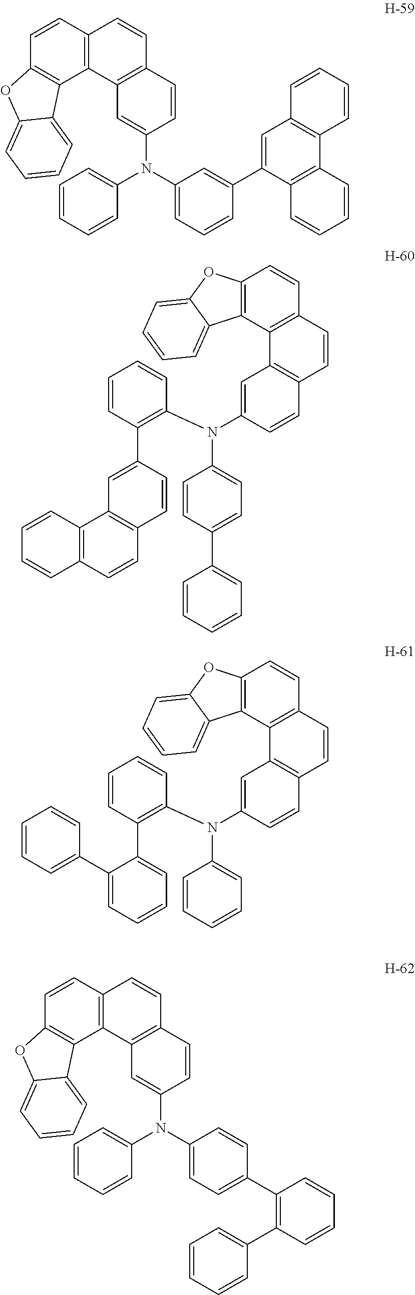

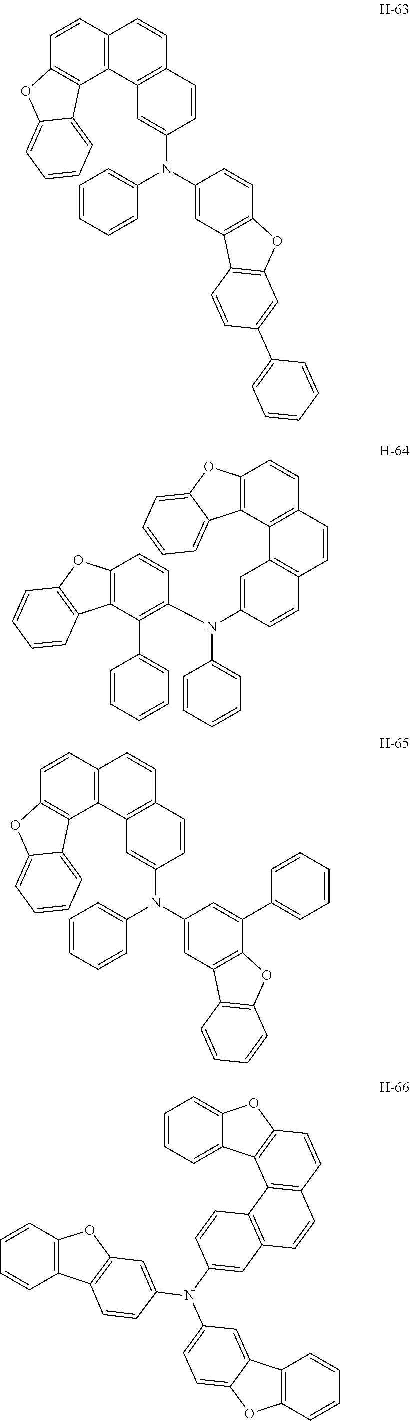

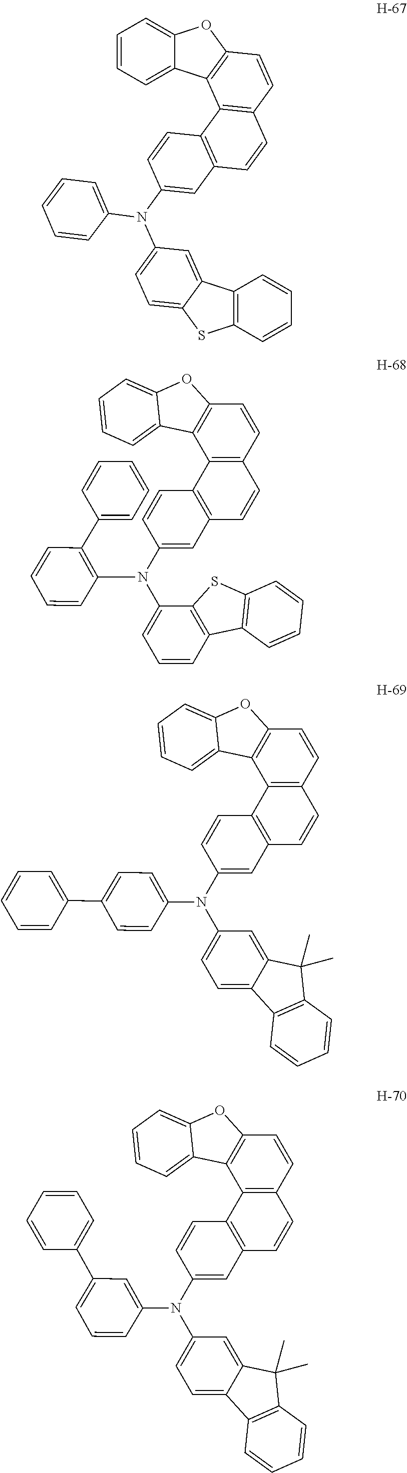

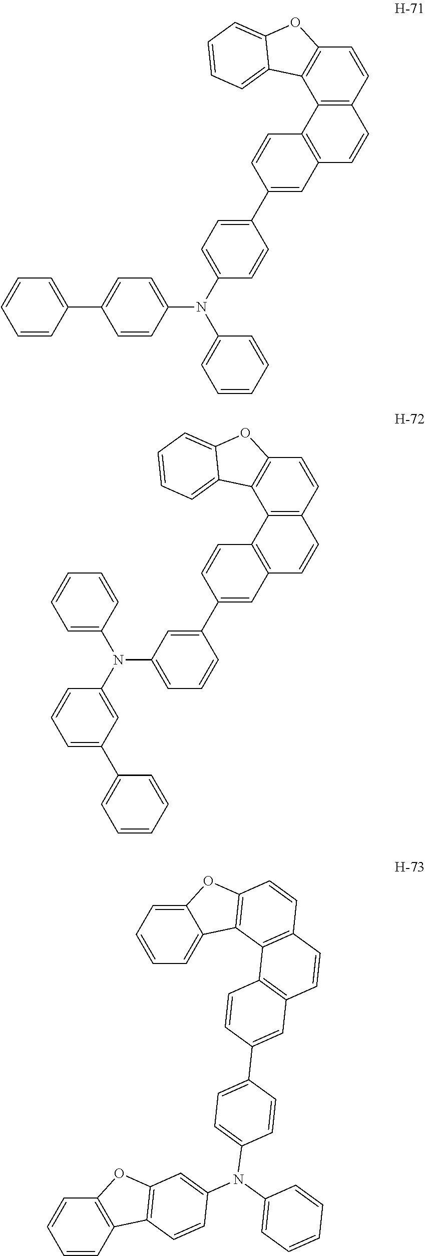

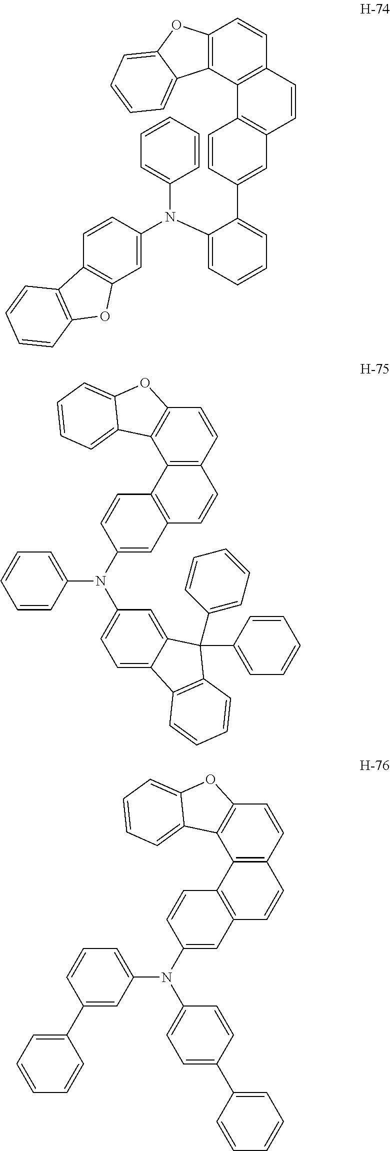

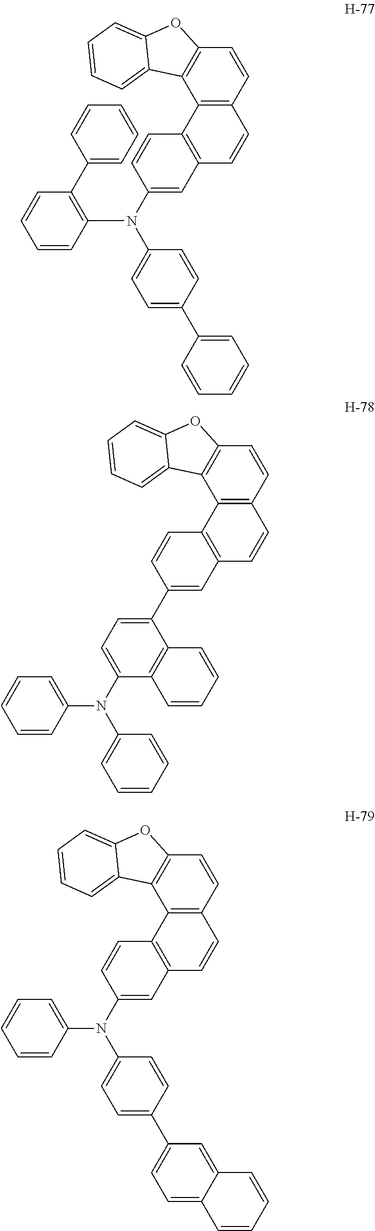

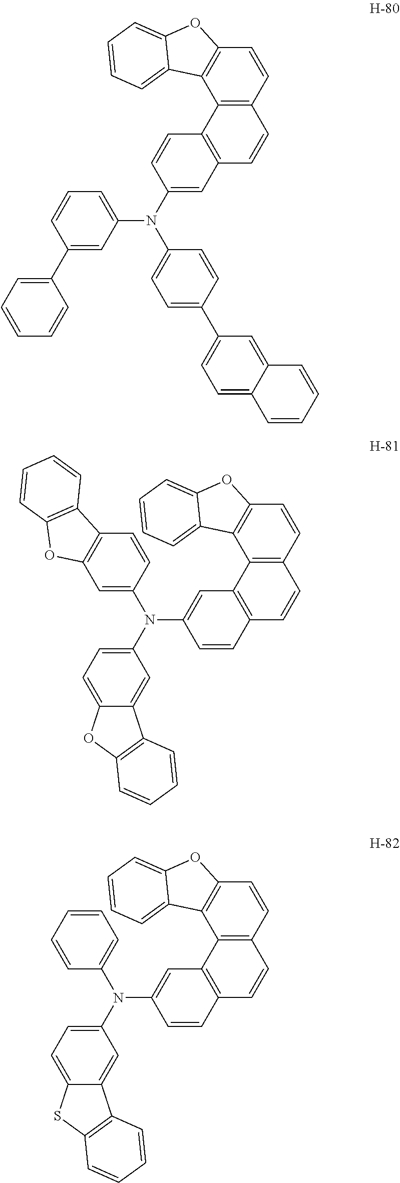 [SMILES: c1ccc(-c2cccc(N(c3ccc(-c4ccc5ccccc5c4)cc3)c3ccc4c(ccc5ccc6oc7ccccc7c6c54)c3)c2)cc1 ; c1ccc2c(c1)oc1cc(N(c3ccc4oc5ccccc5c4c3)c3ccc4ccc5ccc6oc7ccccc7c6c5c4c3)ccc12 ; c1ccc(N(c2ccc3sc4ccccc4c3c2)c2ccc3ccc4ccc5oc6ccccc6c5c4c3c2)cc1]

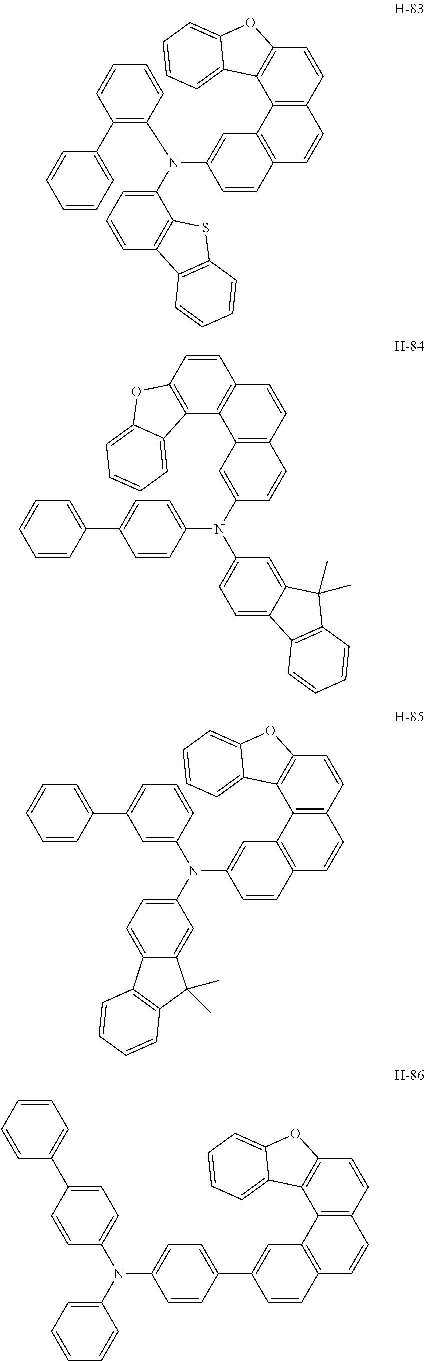

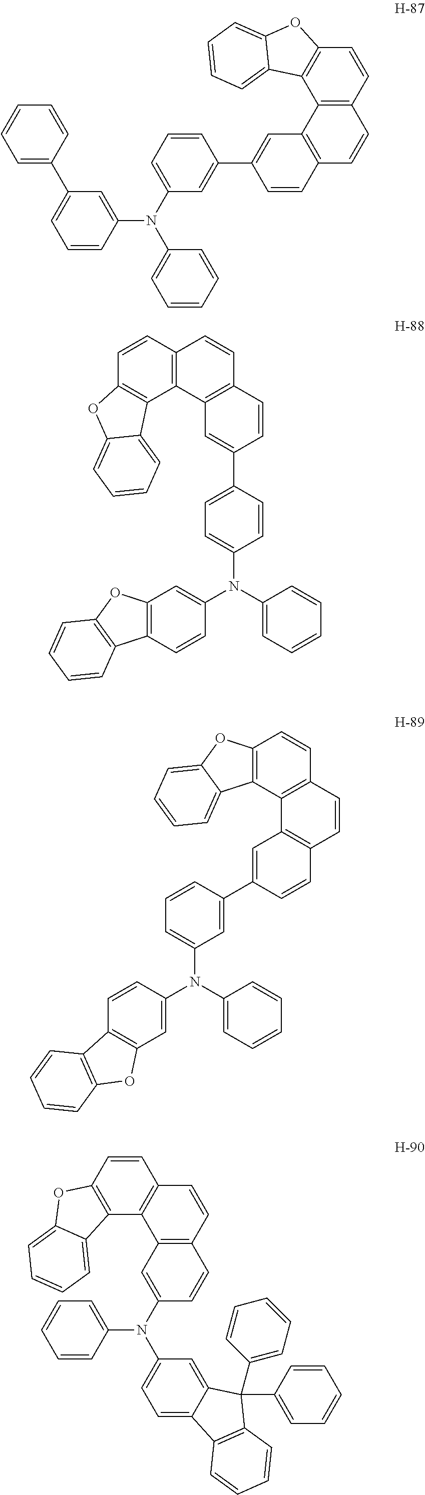

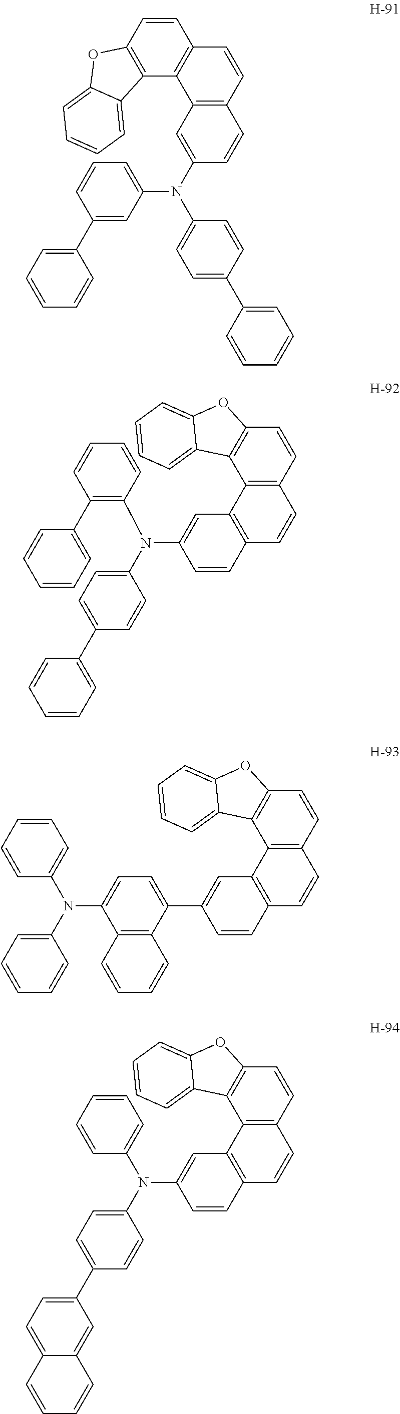

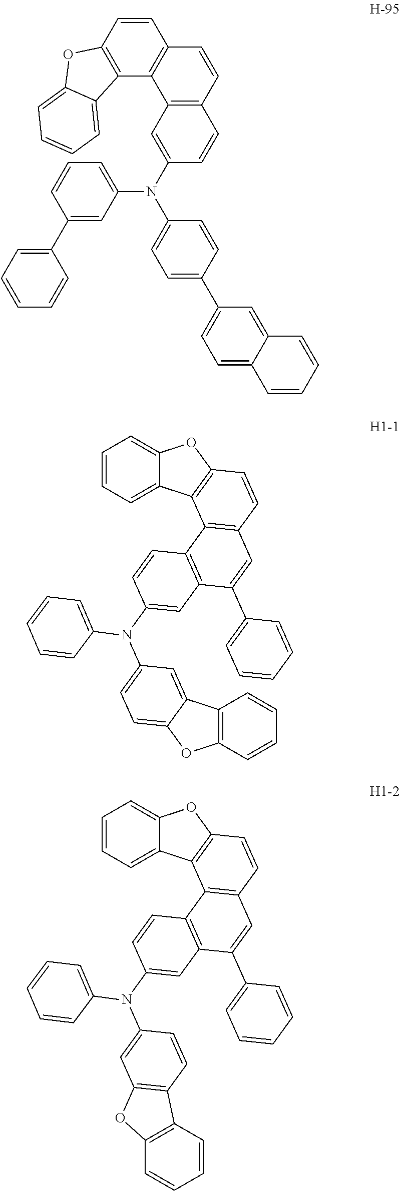 [SMILES: c1ccc(-c2cccc(N(c3ccc(-c4ccc5ccccc5c4)cc3)c3ccc4ccc5ccc6oc7ccccc7c6c5c4c3)c2)cc1 ; c1ccc(-c2cc3ccc4oc5ccccc5c4c3c3ccc(N(c4ccccc4)c4ccc5oc6ccccc6c5c4)cc23)cc1 ; c1ccc(-c2cc3ccc4oc5ccccc5c4c3c3ccc(N(c4ccccc4)c4ccc5c(c4)oc4ccccc45)cc23)cc1]

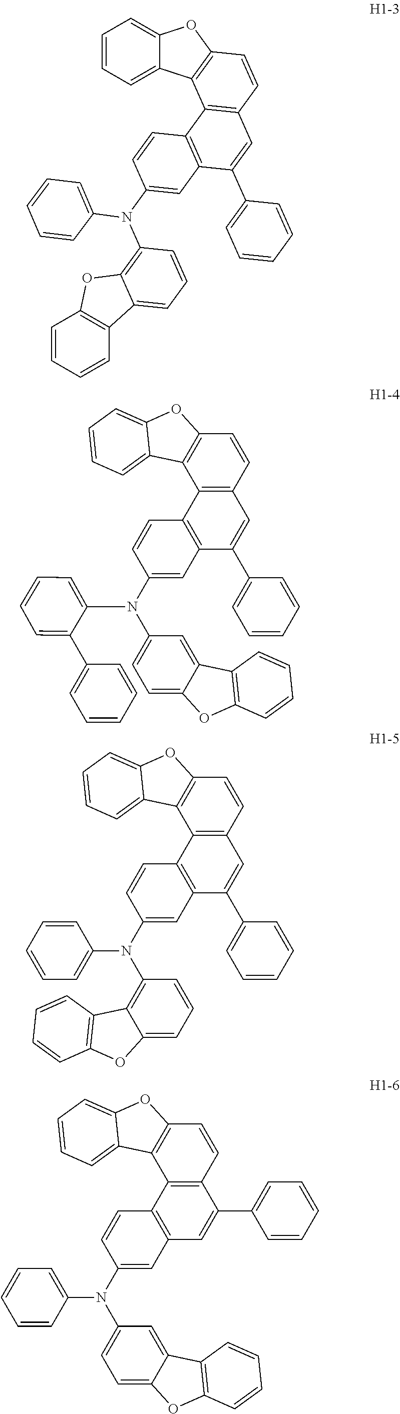

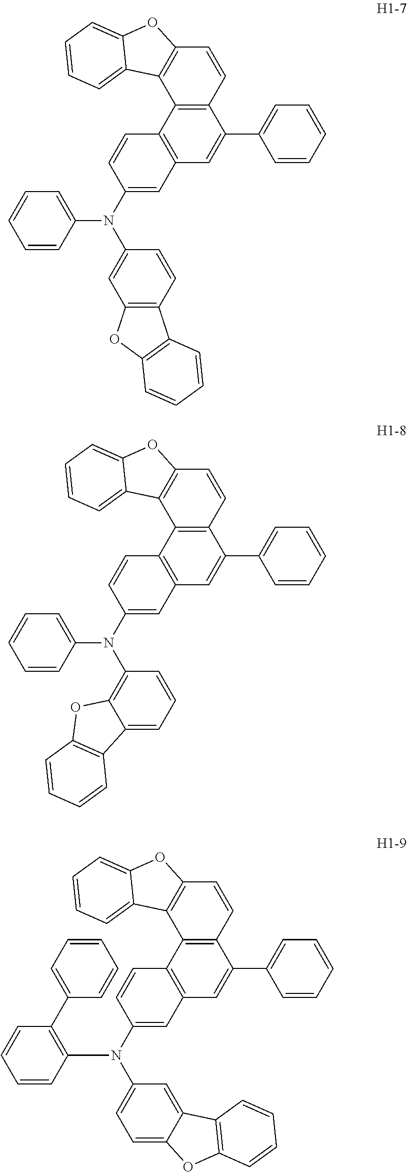

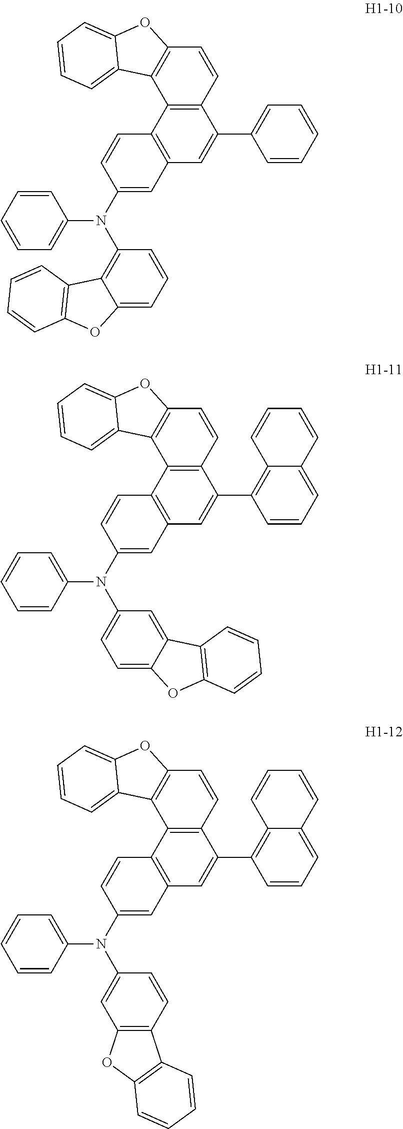 [SMILES: c1ccc(-c2cc3cc(N(c4ccccc4)c4cccc5oc6ccccc6c45)ccc3c3c2ccc2oc4ccccc4c23)cc1 ; c1ccc(N(c2ccc3c(c2)cc(-c2cccc4ccccc24)c2ccc4oc5ccccc5c4c23)c2ccc3oc4ccccc4c3c2)cc1 ; c1ccc(N(c2ccc3c(c2)cc(-c2cccc4ccccc24)c2ccc4oc5ccccc5c4c23)c2ccc3c(c2)oc2ccccc23)cc1]

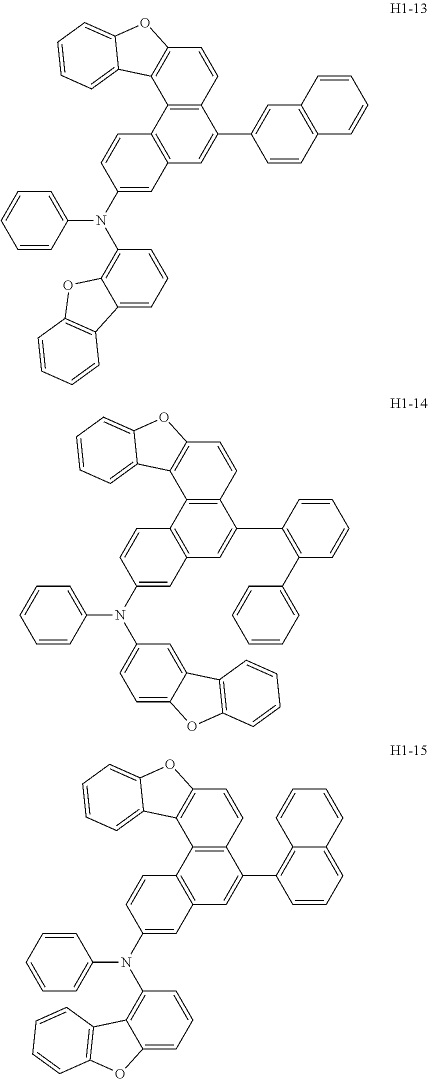

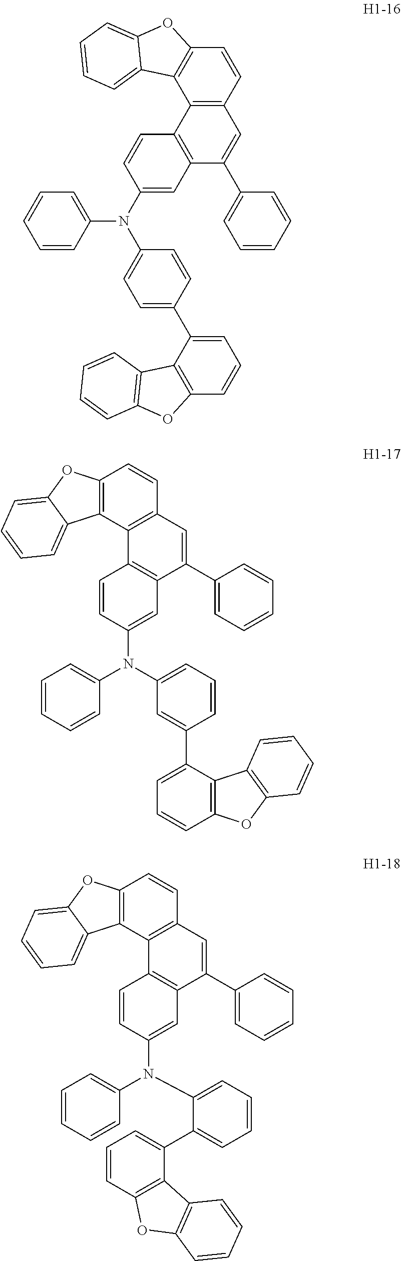 [SMILES: c1ccc(-c2cc3ccc4oc5ccccc5c4c3c3ccc(N(c4ccccc4)c4ccc(-c5cccc6oc7ccccc7c56)cc4)cc23)cc1 ; c1ccc(-c2cc3ccc4oc5ccccc5c4c3c3ccc(N(c4ccccc4)c4cccc(-c5cccc6oc7ccccc7c56)c4)cc23)cc1 ; c1ccc(-c2cc3ccc4oc5ccccc5c4c3c3ccc(N(c4ccccc4)c4ccccc4-c4cccc5oc6ccccc6c45)cc23)cc1]

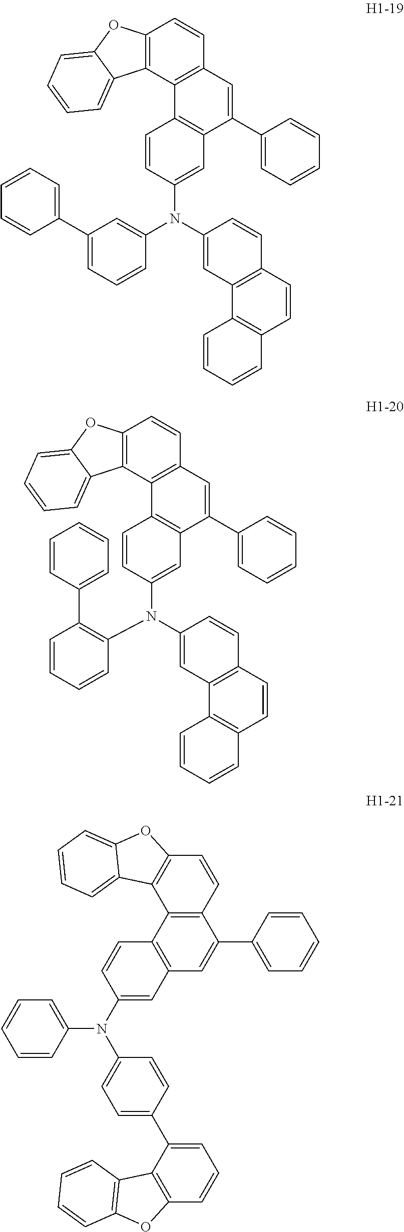 [SMILES: c1ccc(-c2cccc(N(c3ccc4c(c3)c(-c3ccccc3)cc3ccc5oc6ccccc6c5c34)c3ccc4ccc5ccccc5c4c3)c2)cc1 ; c1ccc(-c2ccccc2N(c2ccc3c(c2)c(-c2ccccc2)cc2ccc4oc5ccccc5c4c23)c2ccc3ccc4ccccc4c3c2)cc1 ; c1ccc(-c2cc3cc(N(c4ccccc4)c4ccc(-c5cccc6oc7ccccc7c56)cc4)ccc3c3c2ccc2oc4ccccc4c23)cc1]

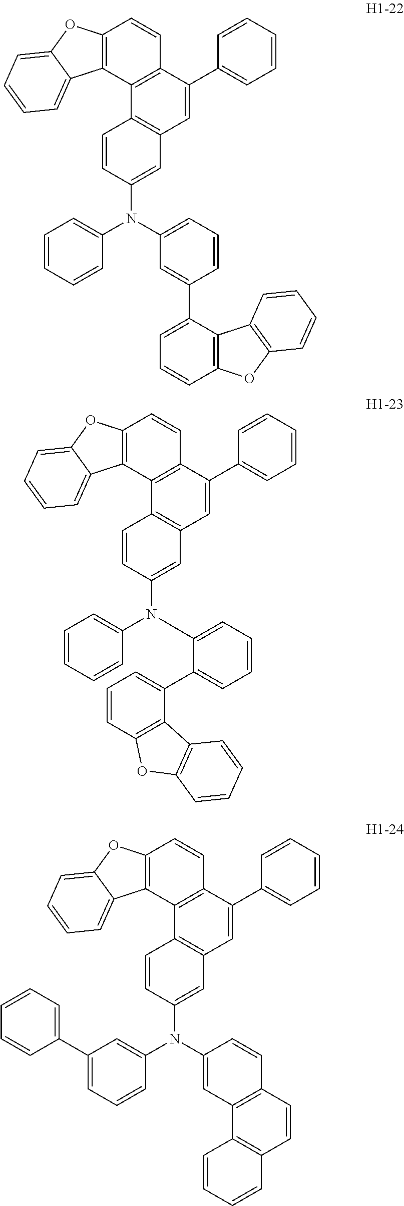

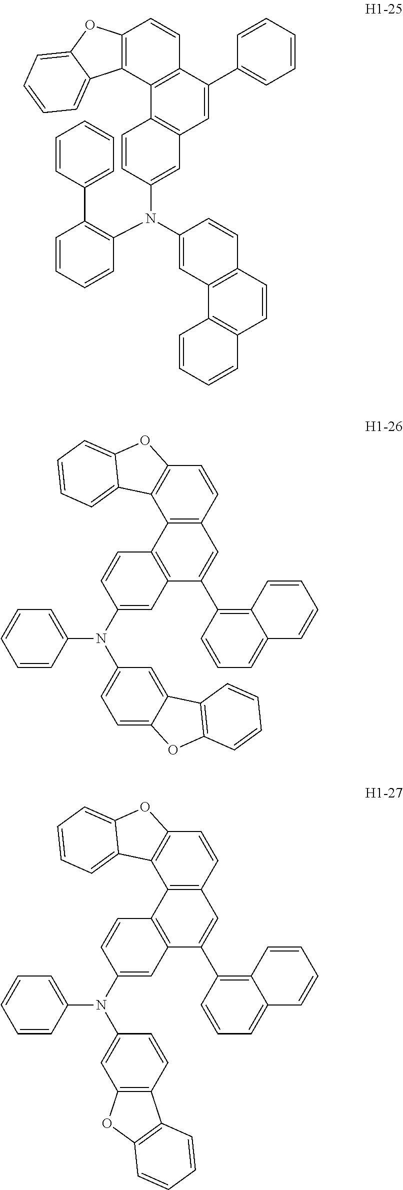 [SMILES: c1ccc(-c2ccccc2N(c2ccc3c(c2)cc(-c2ccccc2)c2ccc4oc5ccccc5c4c23)c2ccc3ccc4ccccc4c3c2)cc1 ; c1ccc(N(c2ccc3c(c2)c(-c2cccc4ccccc24)cc2ccc4oc5ccccc5c4c23)c2ccc3oc4ccccc4c3c2)cc1 ; c1ccc(N(c2ccc3c(c2)oc2ccccc23)c2ccc3c(c2)c(-c2cccc4ccccc24)cc2ccc4oc5ccccc5c4c23)cc1]

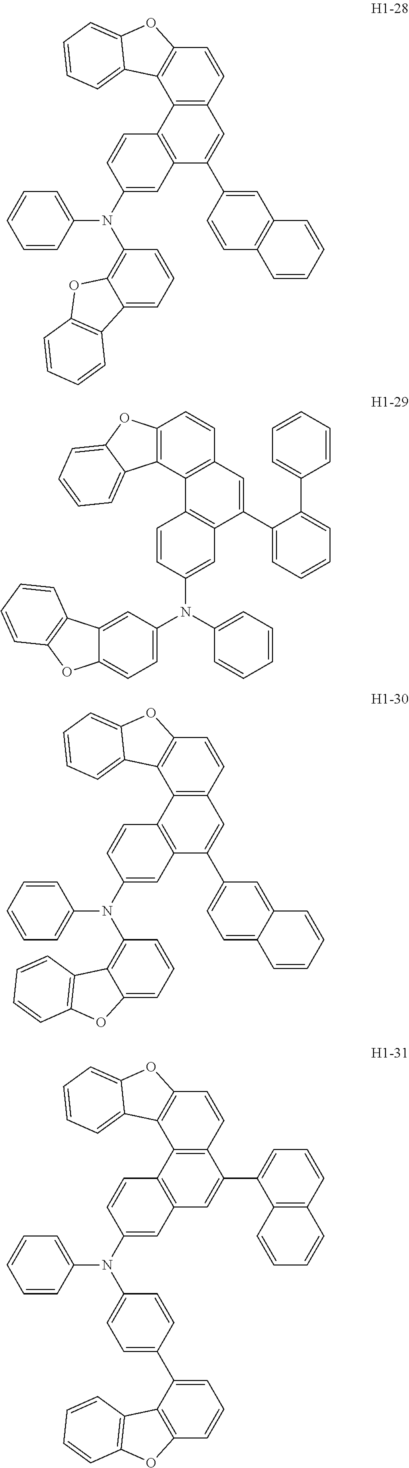

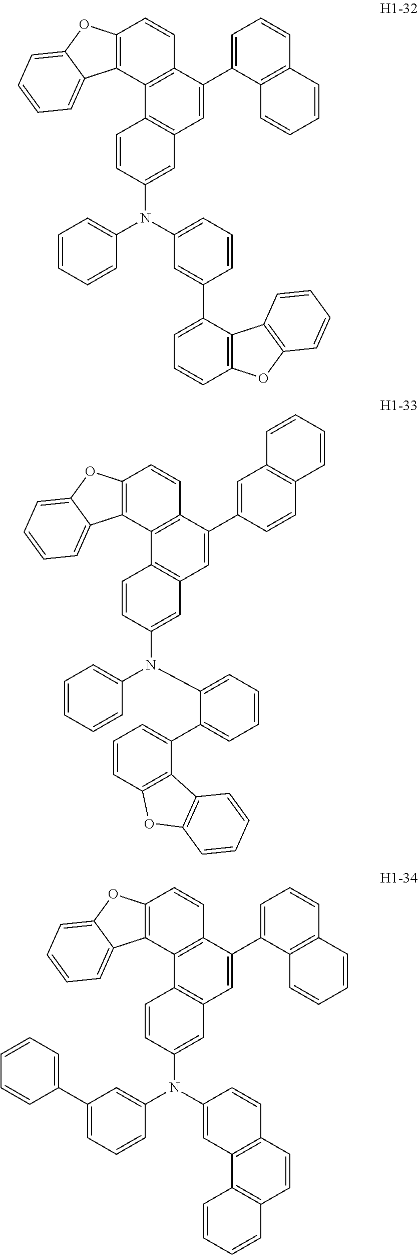

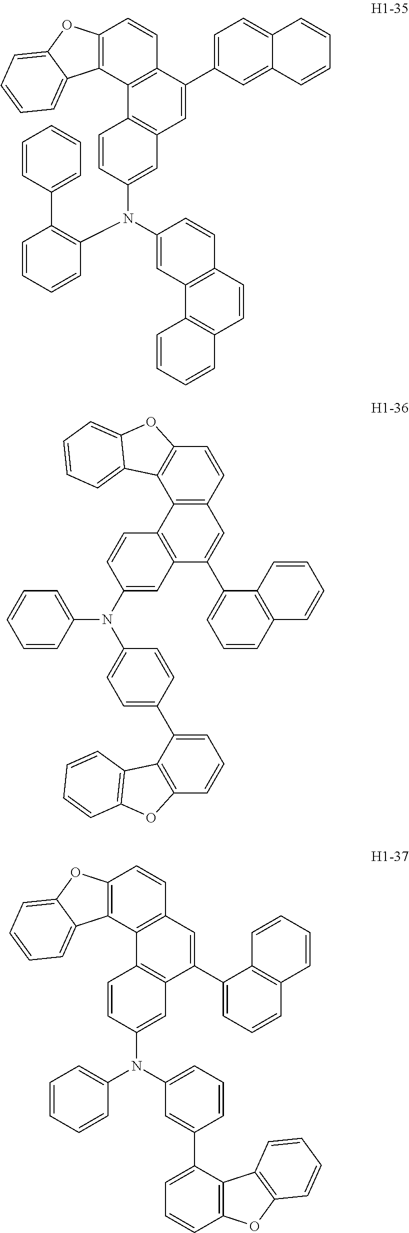 [SMILES: c1ccc(-c2ccccc2N(c2ccc3c(c2)cc(-c2ccc4ccccc4c2)c2ccc4oc5ccccc5c4c23)c2ccc3ccc4ccccc4c3c2)cc1 ; c1ccc(N(c2ccc(-c3cccc4oc5ccccc5c34)cc2)c2ccc3c(c2)c(-c2cccc4ccccc24)cc2ccc4oc5ccccc5c4c23)cc1 ; c1ccc(N(c2cccc(-c3cccc4oc5ccccc5c34)c2)c2ccc3c(c2)c(-c2cccc4ccccc24)cc2ccc4oc5ccccc5c4c23)cc1]

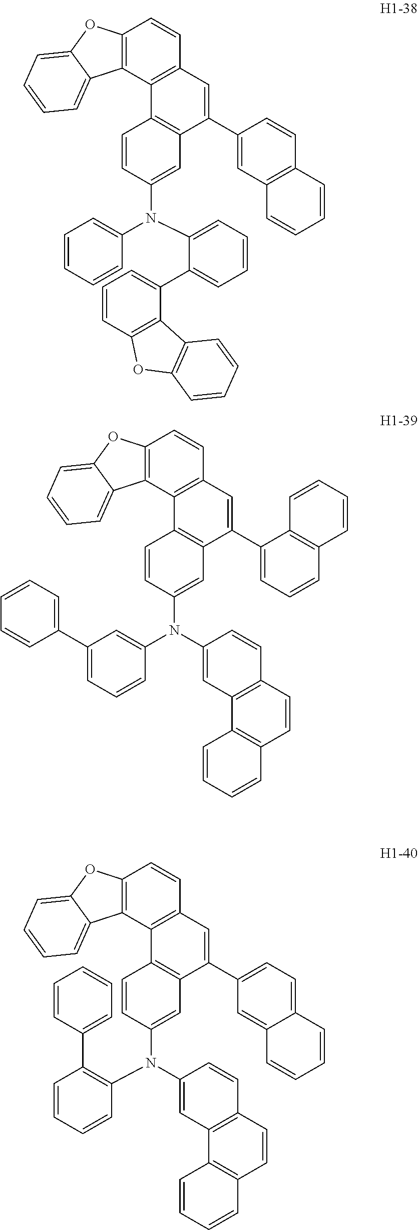

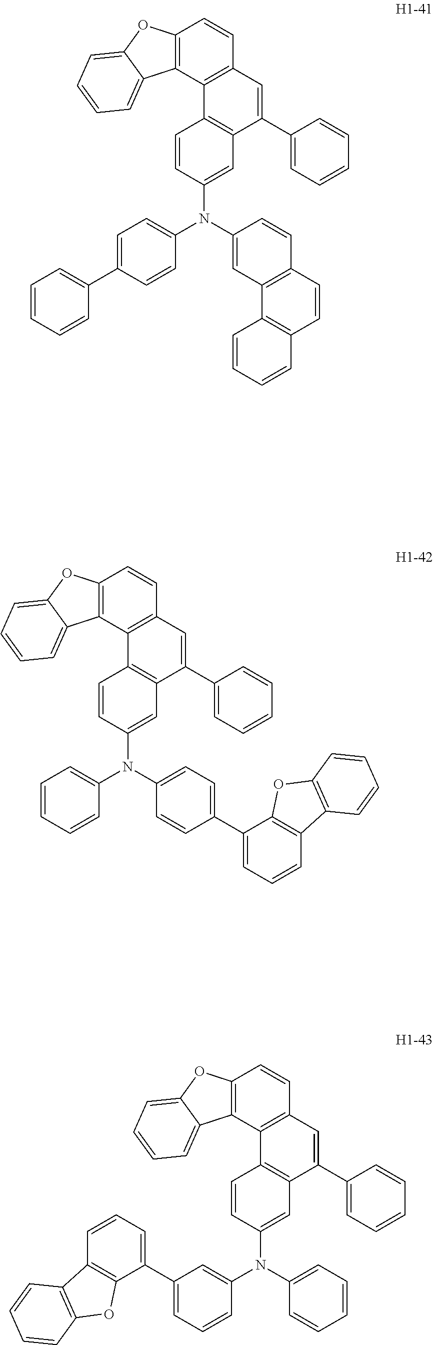 [SMILES: c1ccc(-c2ccc(N(c3ccc4c(c3)c(-c3ccccc3)cc3ccc5oc6ccccc6c5c34)c3ccc4ccc5ccccc5c4c3)cc2)cc1 ; c1ccc(-c2cc3ccc4oc5ccccc5c4c3c3ccc(N(c4ccccc4)c4ccc(-c5cccc6c5oc5ccccc56)cc4)cc23)cc1 ; c1ccc(-c2cc3ccc4oc5ccccc5c4c3c3ccc(N(c4ccccc4)c4cccc(-c5cccc6c5oc5ccccc56)c4)cc23)cc1]

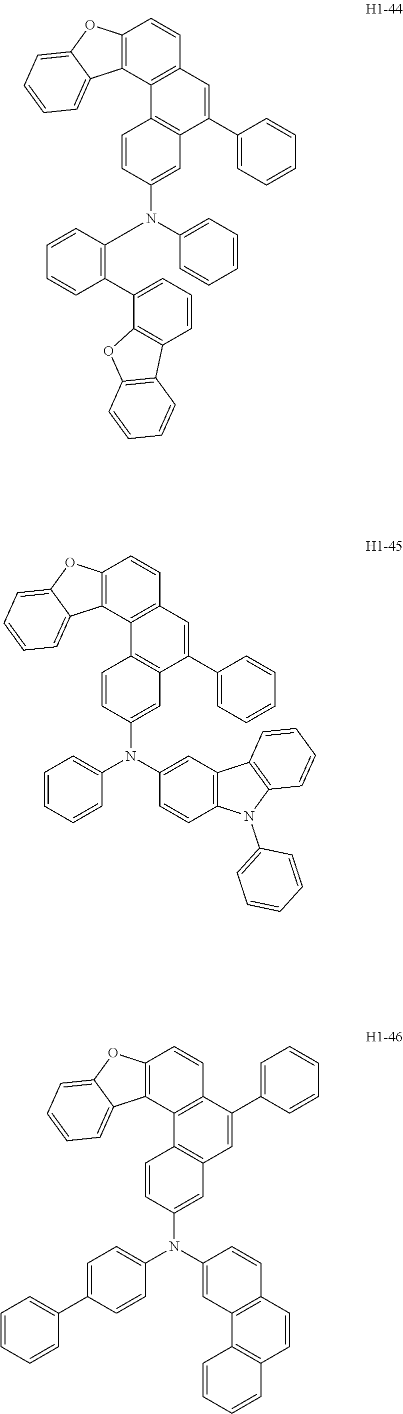 [SMILES: c1ccc(-c2cc3ccc4oc5ccccc5c4c3c3ccc(N(c4ccccc4)c4ccccc4-c4cccc5c4oc4ccccc45)cc23)cc1 ; c1ccc(-c2cc3ccc4oc5ccccc5c4c3c3ccc(N(c4ccccc4)c4ccc5c(c4)c4ccccc4n5-c4ccccc4)cc23)cc1 ; c1ccc(-c2ccc(N(c3ccc4c(c3)cc(-c3ccccc3)c3ccc5oc6ccccc6c5c34)c3ccc4ccc5ccccc5c4c3)cc2)cc1]

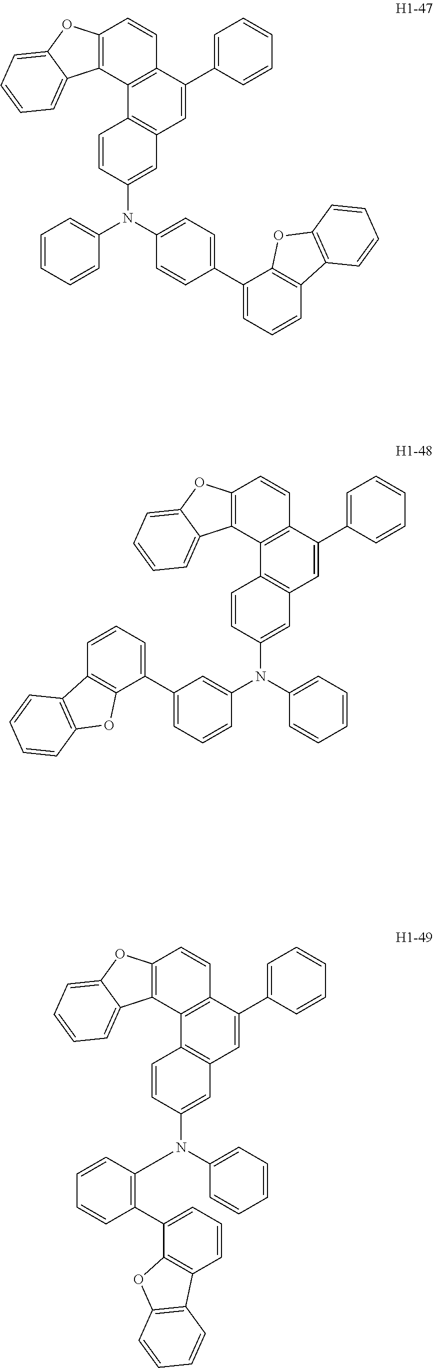 [SMILES: c1ccc(-c2cc3cc(N(c4ccccc4)c4ccc(-c5cccc6c5oc5ccccc56)cc4)ccc3c3c2ccc2oc4ccccc4c23)cc1 ; c1ccc(-c2cc3cc(N(c4ccccc4)c4cccc(-c5cccc6c5oc5ccccc56)c4)ccc3c3c2ccc2oc4ccccc4c23)cc1 ; c1ccc(-c2cc3cc(N(c4ccccc4)c4ccccc4-c4cccc5c4oc4ccccc45)ccc3c3c2ccc2oc4ccccc4c23)cc1]

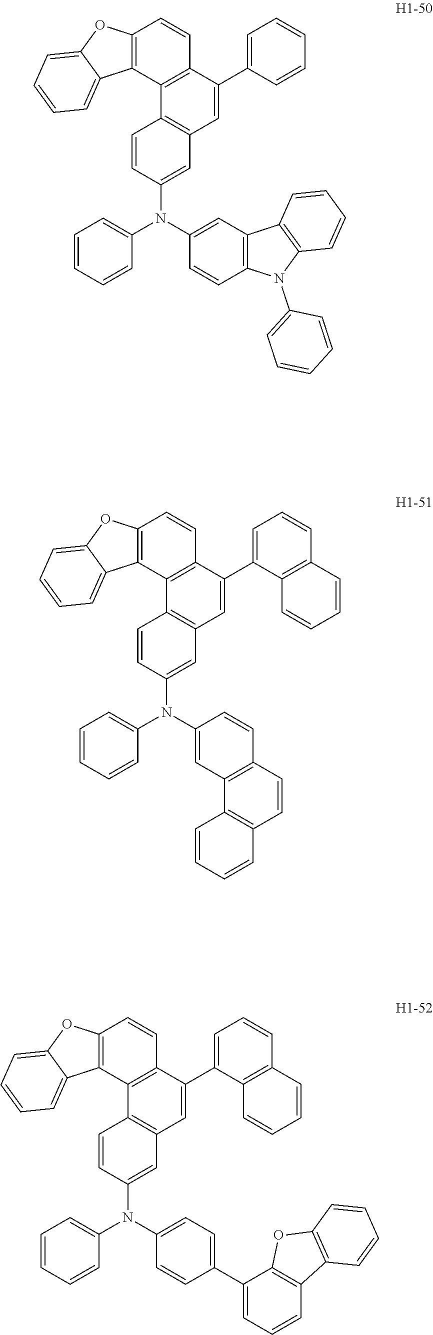 [SMILES: c1ccc(-c2cc3cc(N(c4ccccc4)c4ccc5c(c4)c4ccccc4n5-c4ccccc4)ccc3c3c2ccc2oc4ccccc4c23)cc1 ; c1ccc(N(c2ccc3c(c2)cc(-c2cccc4ccccc24)c2ccc4oc5ccccc5c4c23)c2ccc3ccc4ccccc4c3c2)cc1 ; c1ccc(N(c2ccc(-c3cccc4c3oc3ccccc34)cc2)c2ccc3c(c2)cc(-c2cccc4ccccc24)c2ccc4oc5ccccc5c4c23)cc1]

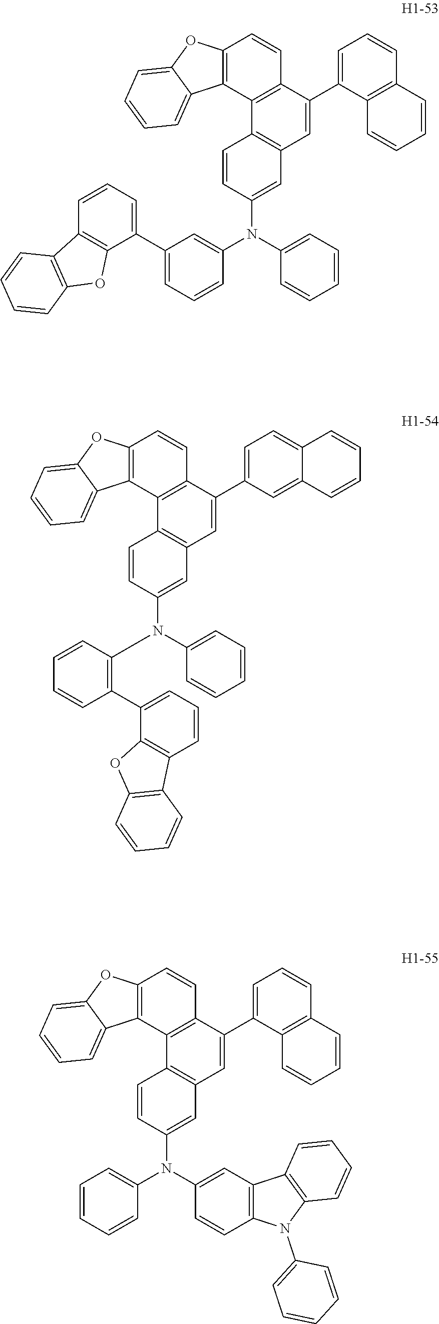 [SMILES: c1ccc(N(c2cccc(-c3cccc4c3oc3ccccc34)c2)c2ccc3c(c2)cc(-c2cccc4ccccc24)c2ccc4oc5ccccc5c4c23)cc1 ; c1ccc(N(c2ccc3c(c2)cc(-c2ccc4ccccc4c2)c2ccc4oc5ccccc5c4c23)c2ccccc2-c2cccc3c2oc2ccccc23)cc1 ; c1ccc(N(c2ccc3c(c2)cc(-c2cccc4ccccc24)c2ccc4oc5ccccc5c4c23)c2ccc3c(c2)c2ccccc2n3-c2ccccc2)cc1]

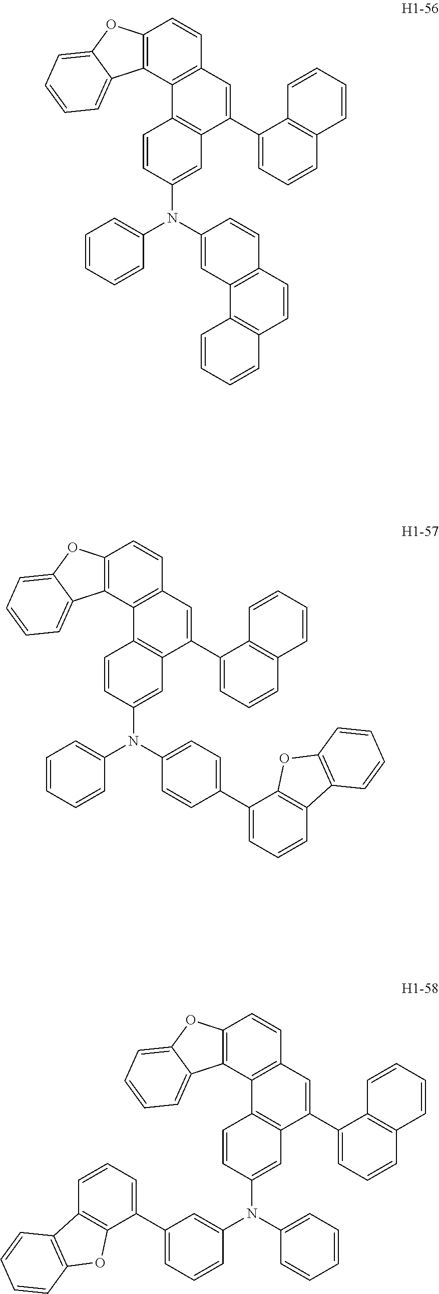 [SMILES: c1ccc(N(c2ccc3c(c2)c(-c2cccc4ccccc24)cc2ccc4oc5ccccc5c4c23)c2ccc3ccc4ccccc4c3c2)cc1 ; c1ccc(N(c2ccc(-c3cccc4c3oc3ccccc34)cc2)c2ccc3c(c2)c(-c2cccc4ccccc24)cc2ccc4oc5ccccc5c4c23)cc1 ; c1ccc(N(c2cccc(-c3cccc4c3oc3ccccc34)c2)c2ccc3c(c2)c(-c2cccc4ccccc24)cc2ccc4oc5ccccc5c4c23)cc1]

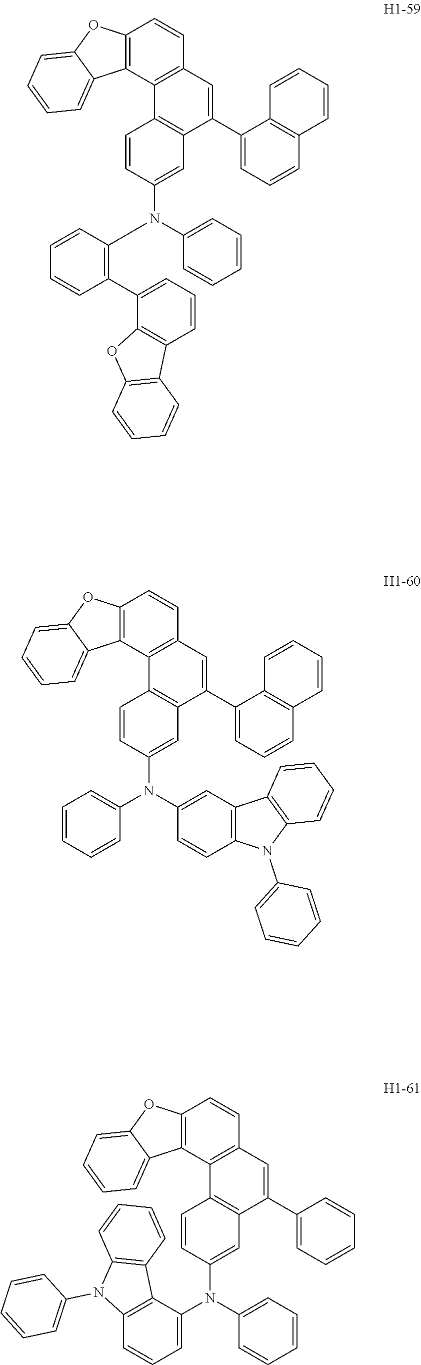 [SMILES: c1ccc(N(c2ccc3c(c2)c(-c2cccc4ccccc24)cc2ccc4oc5ccccc5c4c23)c2ccccc2-c2cccc3c2oc2ccccc23)cc1 ; c1ccc(N(c2ccc3c(c2)c(-c2cccc4ccccc24)cc2ccc4oc5ccccc5c4c23)c2ccc3c(c2)c2ccccc2n3-c2ccccc2)cc1 ; c1ccc(-c2cc3ccc4oc5ccccc5c4c3c3ccc(N(c4ccccc4)c4cccc5c4c4ccccc4n5-c4ccccc4)cc23)cc1]

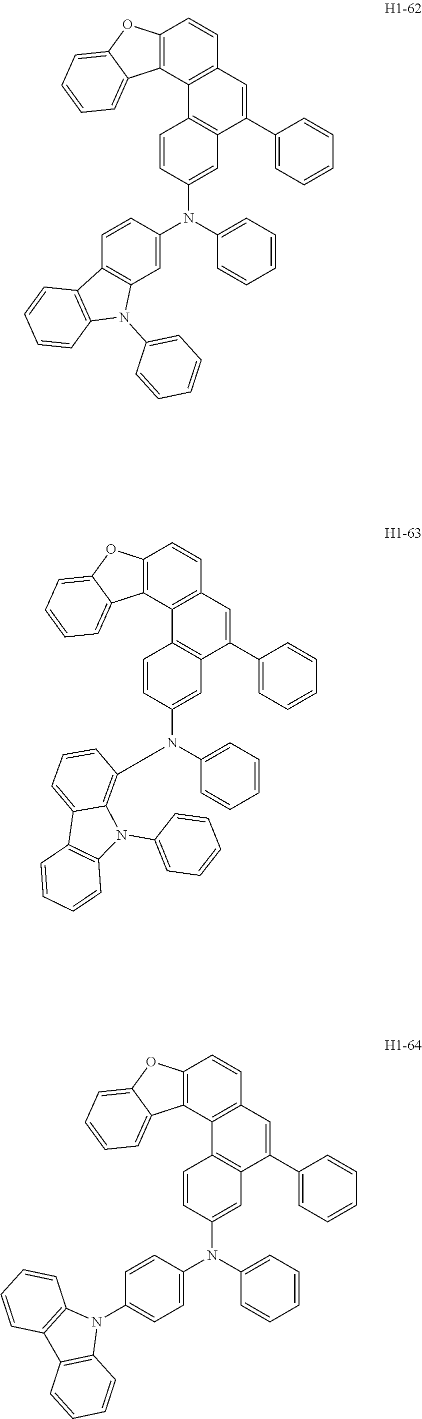 [SMILES: c1ccc(-c2cc3ccc4oc5ccccc5c4c3c3ccc(N(c4ccccc4)c4ccc5c6ccccc6n(-c6ccccc6)c5c4)cc23)cc1 ; c1ccc(-c2cc3ccc4oc5ccccc5c4c3c3ccc(N(c4ccccc4)c4cccc5c6ccccc6n(-c6ccccc6)c45)cc23)cc1 ; c1ccc(-c2cc3ccc4oc5ccccc5c4c3c3ccc(N(c4ccccc4)c4ccc(-n5c6ccccc6c6ccccc65)cc4)cc23)cc1]

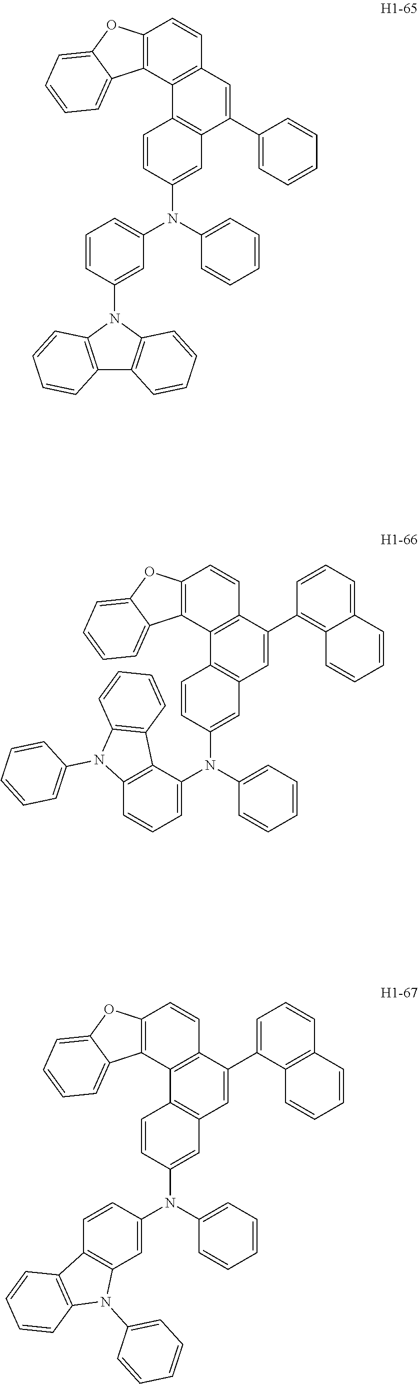 [SMILES: c1ccc(-c2cc3ccc4oc5ccccc5c4c3c3ccc(N(c4ccccc4)c4cccc(-n5c6ccccc6c6ccccc65)c4)cc23)cc1 ; c1ccc(N(c2ccc3c(c2)cc(-c2cccc4ccccc24)c2ccc4oc5ccccc5c4c23)c2cccc3c2c2ccccc2n3-c2ccccc2)cc1 ; c1ccc(N(c2ccc3c(c2)cc(-c2cccc4ccccc24)c2ccc4oc5ccccc5c4c23)c2ccc3c4ccccc4n(-c4ccccc4)c3c2)cc1]

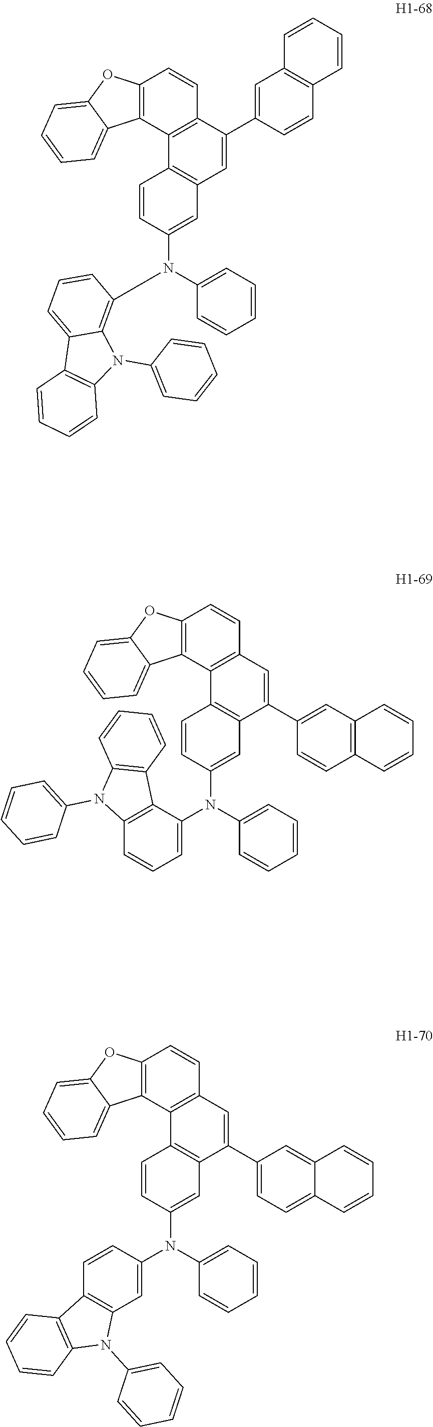 [SMILES: c1ccc(N(c2ccc3c(c2)cc(-c2ccc4ccccc4c2)c2ccc4oc5ccccc5c4c23)c2cccc3c4ccccc4n(-c4ccccc4)c23)cc1 ; c1ccc(N(c2ccc3c(c2)c(-c2ccc4ccccc4c2)cc2ccc4oc5ccccc5c4c23)c2cccc3c2c2ccccc2n3-c2ccccc2)cc1 ; c1ccc(N(c2ccc3c(c2)c(-c2ccc4ccccc4c2)cc2ccc4oc5ccccc5c4c23)c2ccc3c4ccccc4n(-c4ccccc4)c3c2)cc1]

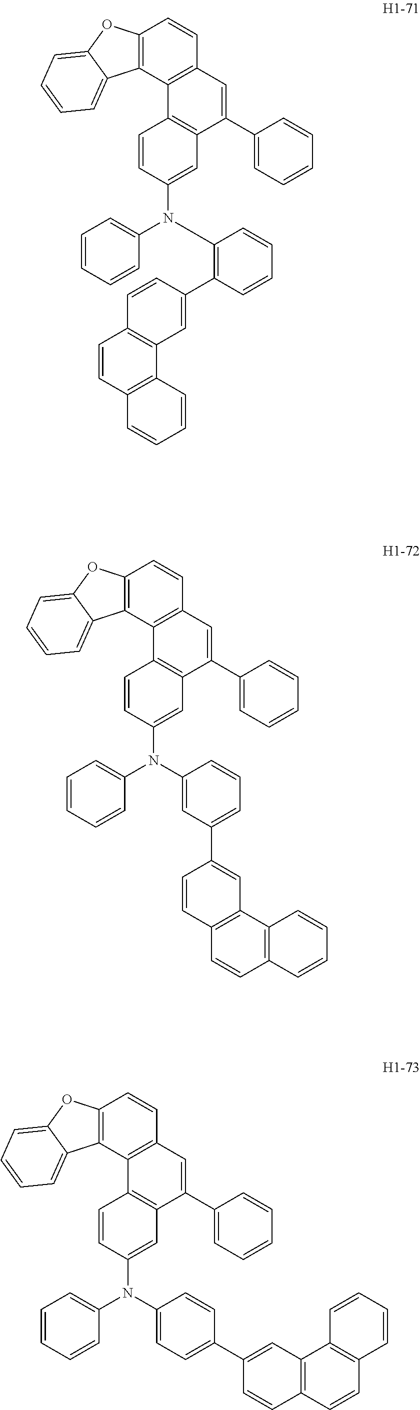 [SMILES: c1ccc(-c2cc3ccc4oc5ccccc5c4c3c3ccc(N(c4ccccc4)c4ccccc4-c4ccc5ccc6ccccc6c5c4)cc23)cc1 ; c1ccc(-c2cc3ccc4oc5ccccc5c4c3c3ccc(N(c4ccccc4)c4cccc(-c5ccc6ccc7ccccc7c6c5)c4)cc23)cc1 ; c1ccc(-c2cc3ccc4oc5ccccc5c4c3c3ccc(N(c4ccccc4)c4ccc(-c5ccc6ccc7ccccc7c6c5)cc4)cc23)cc1]

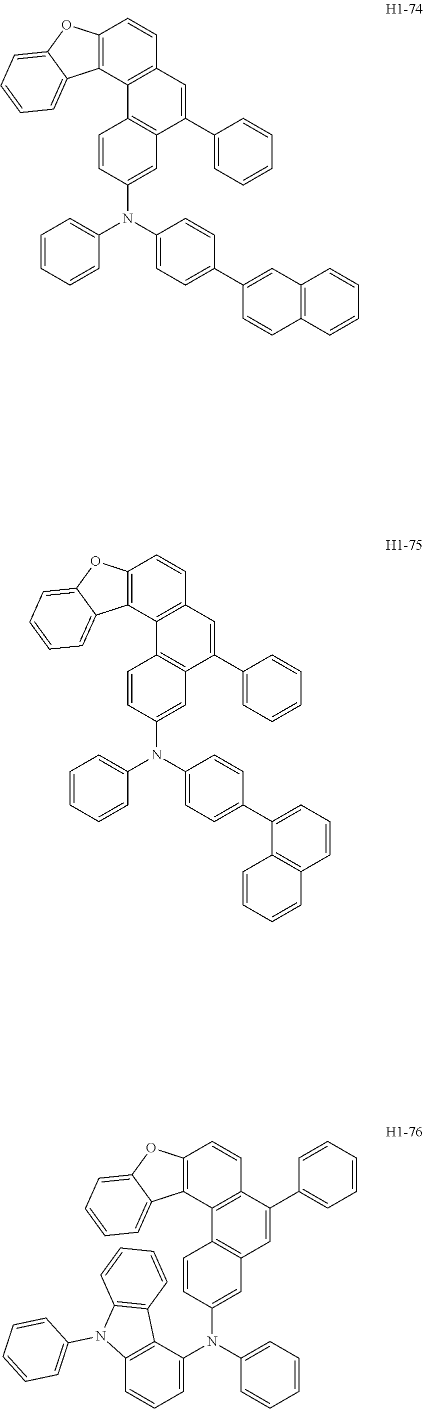 [SMILES: c1ccc(-c2cc3ccc4oc5ccccc5c4c3c3ccc(N(c4ccccc4)c4ccc(-c5ccc6ccccc6c5)cc4)cc23)cc1 ; c1ccc(-c2cc3ccc4oc5ccccc5c4c3c3ccc(N(c4ccccc4)c4ccc(-c5cccc6ccccc56)cc4)cc23)cc1 ; c1ccc(-c2cc3cc(N(c4ccccc4)c4cccc5c4c4ccccc4n5-c4ccccc4)ccc3c3c2ccc2oc4ccccc4c23)cc1]

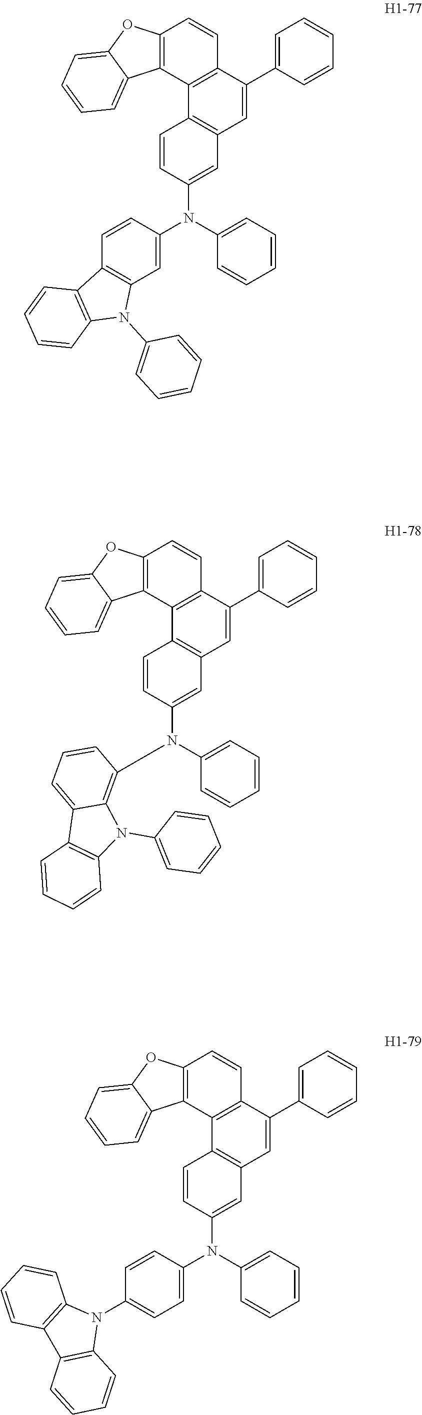 [SMILES: c1ccc(-c2cc3cc(N(c4ccccc4)c4ccc5c6ccccc6n(-c6ccccc6)c5c4)ccc3c3c2ccc2oc4ccccc4c23)cc1 ; c1ccc(-c2cc3cc(N(c4ccccc4)c4cccc5c6ccccc6n(-c6ccccc6)c45)ccc3c3c2ccc2oc4ccccc4c23)cc1 ; c1ccc(-c2cc3cc(N(c4ccccc4)c4ccc(-n5c6ccccc6c6ccccc65)cc4)ccc3c3c2ccc2oc4ccccc4c23)cc1]

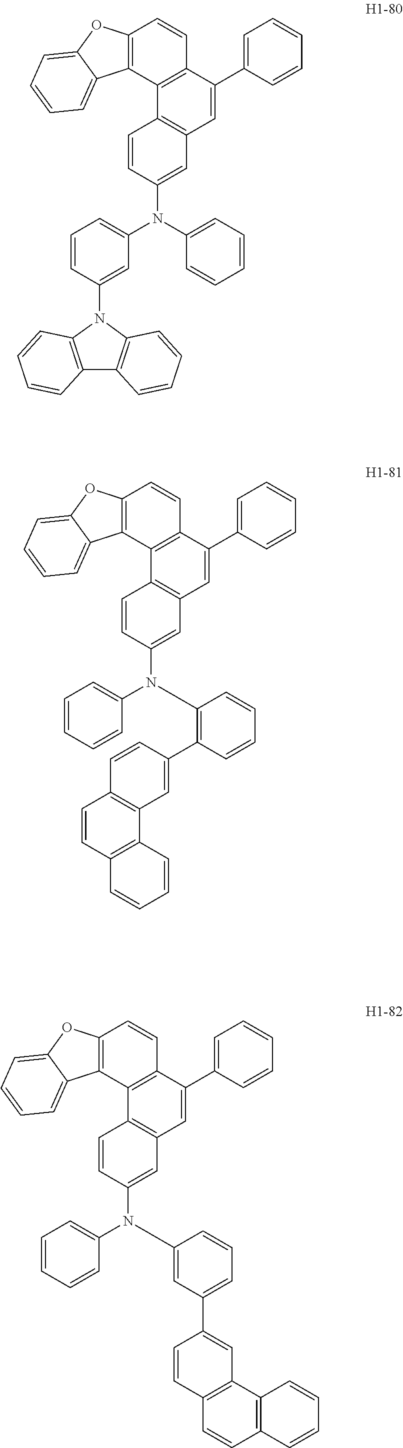 [SMILES: c1ccc(-c2cc3cc(N(c4ccccc4)c4cccc(-n5c6ccccc6c6ccccc65)c4)ccc3c3c2ccc2oc4ccccc4c23)cc1 ; c1ccc(-c2cc3cc(N(c4ccccc4)c4ccccc4-c4ccc5ccc6ccccc6c5c4)ccc3c3c2ccc2oc4ccccc4c23)cc1 ; c1ccc(-c2cc3cc(N(c4ccccc4)c4cccc(-c5ccc6ccc7ccccc7c6c5)c4)ccc3c3c2ccc2oc4ccccc4c23)cc1]

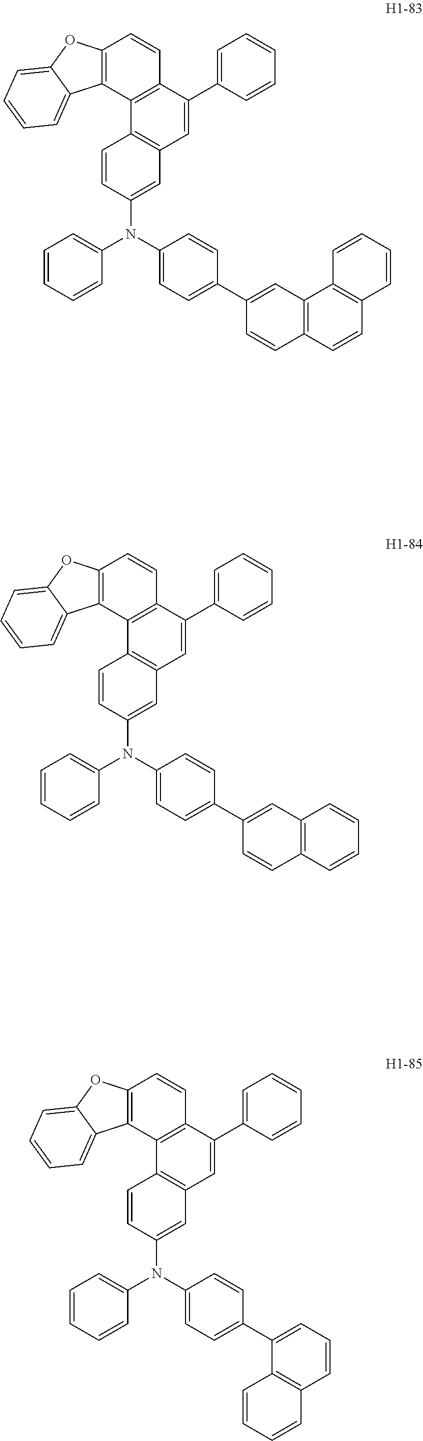 [SMILES: c1ccc(-c2cc3cc(N(c4ccccc4)c4ccc(-c5ccc6ccc7ccccc7c6c5)cc4)ccc3c3c2ccc2oc4ccccc4c23)cc1 ; c1ccc(-c2cc3cc(N(c4ccccc4)c4ccc(-c5ccc6ccccc6c5)cc4)ccc3c3c2ccc2oc4ccccc4c23)cc1 ; c1ccc(-c2cc3cc(N(c4ccccc4)c4ccc(-c5cccc6ccccc56)cc4)ccc3c3c2ccc2oc4ccccc4c23)cc1]

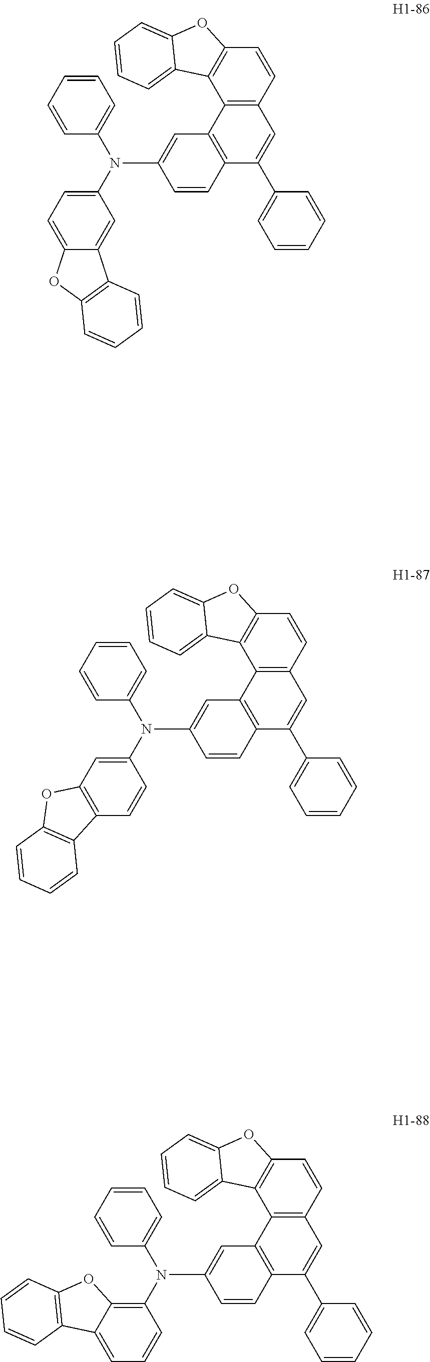 [SMILES: c1ccc(-c2cc3ccc4oc5ccccc5c4c3c3cc(N(c4ccccc4)c4ccc5oc6ccccc6c5c4)ccc23)cc1 ; c1ccc(-c2cc3ccc4oc5ccccc5c4c3c3cc(N(c4ccccc4)c4ccc5c(c4)oc4ccccc45)ccc23)cc1 ; c1ccc(-c2cc3ccc4oc5ccccc5c4c3c3cc(N(c4ccccc4)c4cccc5c4oc4ccccc45)ccc23)cc1]

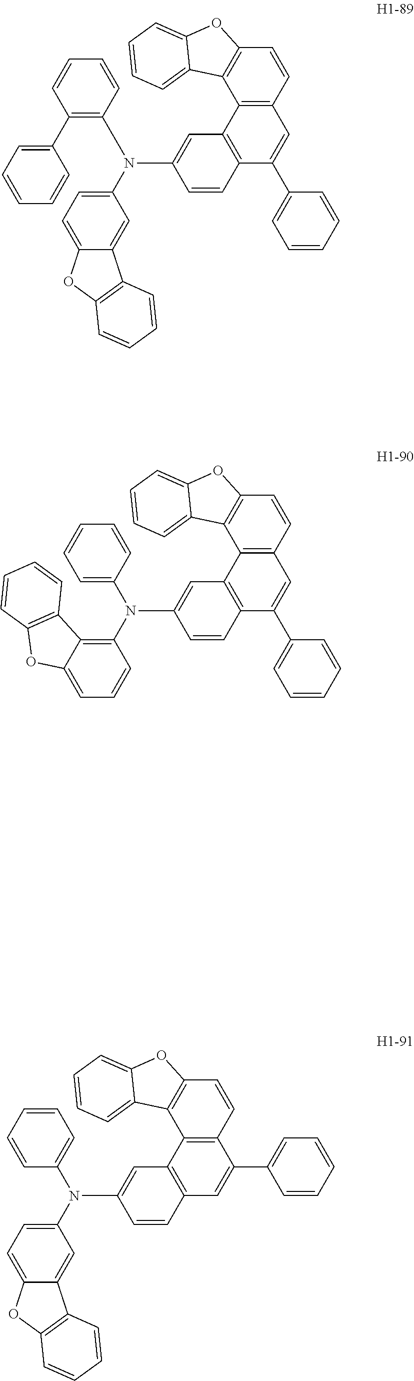 [SMILES: c1ccc(-c2ccccc2N(c2ccc3oc4ccccc4c3c2)c2ccc3c(-c4ccccc4)cc4ccc5oc6ccccc6c5c4c3c2)cc1 ; c1ccc(-c2cc3ccc4oc5ccccc5c4c3c3cc(N(c4ccccc4)c4cccc5oc6ccccc6c45)ccc23)cc1 ; c1ccc(-c2cc3ccc(N(c4ccccc4)c4ccc5oc6ccccc6c5c4)cc3c3c2ccc2oc4ccccc4c23)cc1]

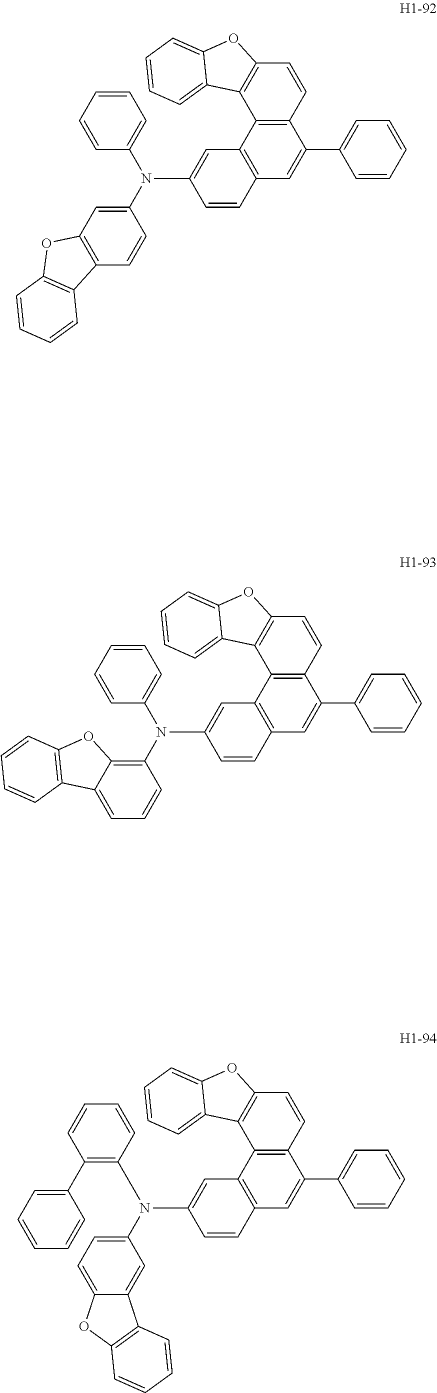 [SMILES: c1ccc(-c2cc3ccc(N(c4ccccc4)c4ccc5c(c4)oc4ccccc45)cc3c3c2ccc2oc4ccccc4c23)cc1 ; c1ccc(-c2cc3ccc(N(c4ccccc4)c4cccc5c4oc4ccccc45)cc3c3c2ccc2oc4ccccc4c23)cc1 ; c1ccc(-c2ccccc2N(c2ccc3oc4ccccc4c3c2)c2ccc3cc(-c4ccccc4)c4ccc5oc6ccccc6c5c4c3c2)cc1]

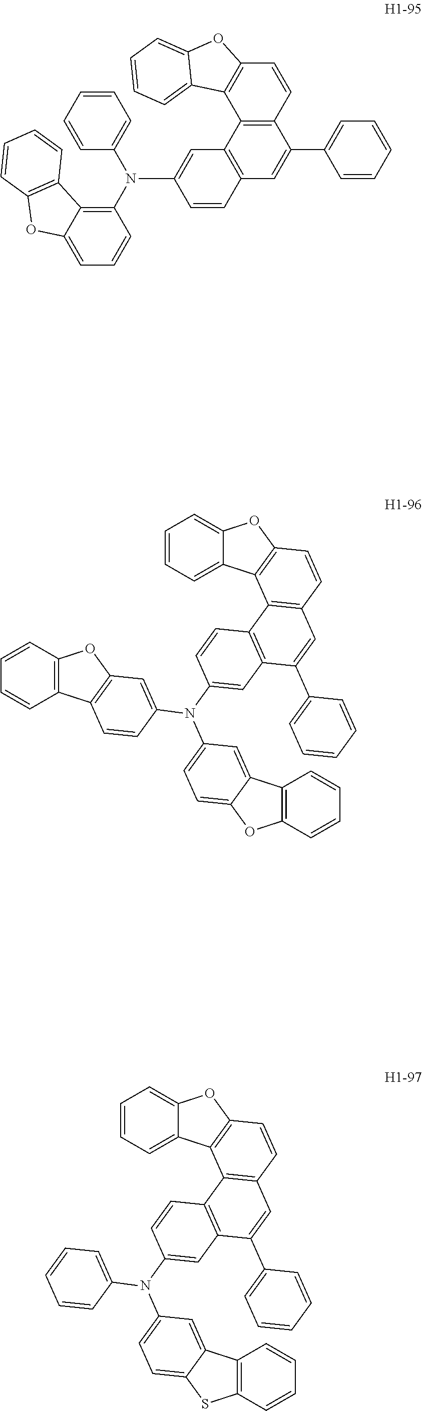 [SMILES: c1ccc(-c2cc3ccc(N(c4ccccc4)c4cccc5oc6ccccc6c45)cc3c3c2ccc2oc4ccccc4c23)cc1 ; c1ccc(-c2cc3ccc4oc5ccccc5c4c3c3ccc(N(c4ccc5c(c4)oc4ccccc45)c4ccc5oc6ccccc6c5c4)cc23)cc1 ; c1ccc(-c2cc3ccc4oc5ccccc5c4c3c3ccc(N(c4ccccc4)c4ccc5sc6ccccc6c5c4)cc23)cc1]

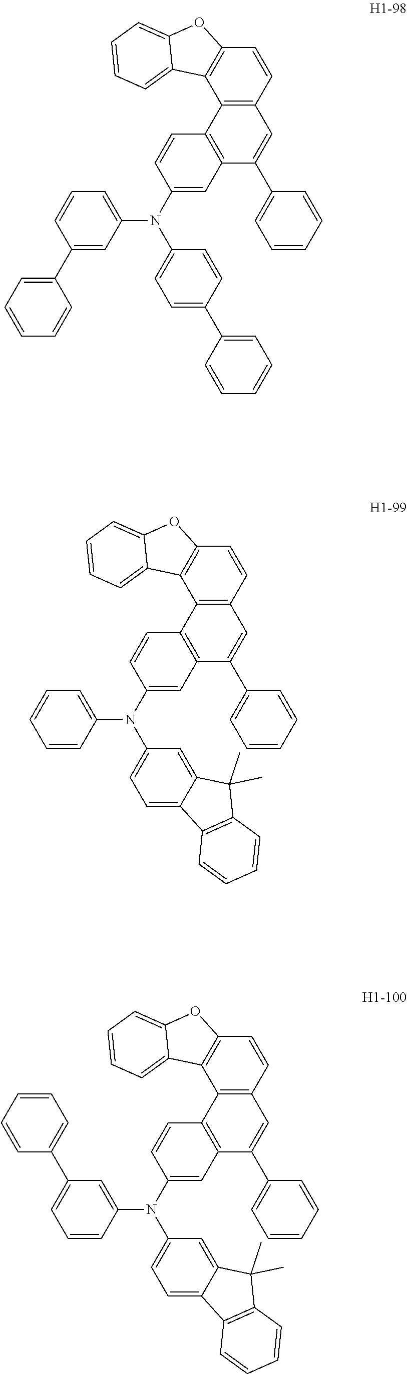 [SMILES: c1ccc(-c2ccc(N(c3cccc(-c4ccccc4)c3)c3ccc4c(c3)c(-c3ccccc3)cc3ccc5oc6ccccc6c5c34)cc2)cc1 ; CC1(C)c2ccccc2-c2ccc(N(c3ccccc3)c3ccc4c(c3)c(-c3ccccc3)cc3ccc5oc6ccccc6c5c34)cc21 ; CC1(C)c2ccccc2-c2ccc(N(c3cccc(-c4ccccc4)c3)c3ccc4c(c3)c(-c3ccccc3)cc3ccc5oc6ccccc6c5c34)cc21]

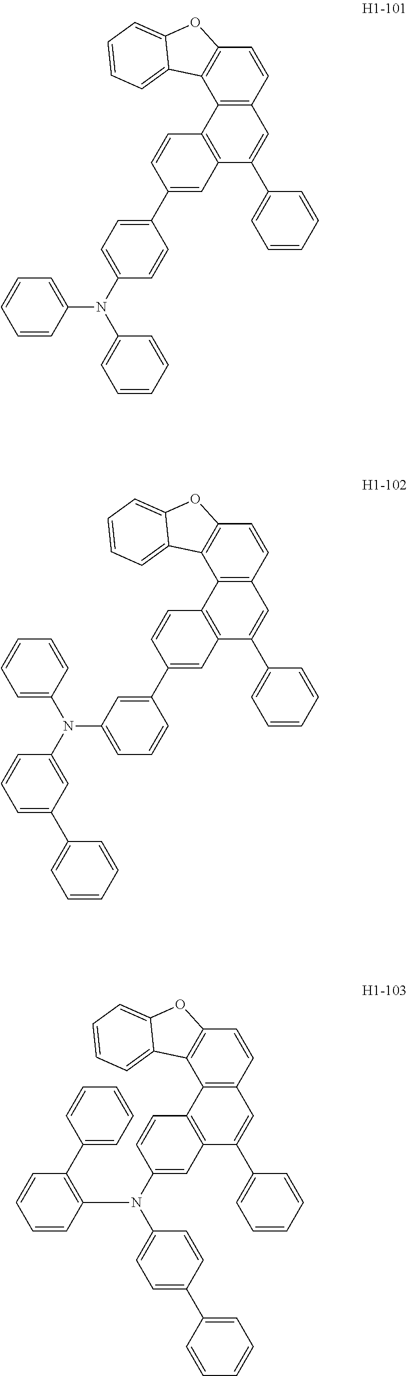 [SMILES: c1ccc(-c2cc3ccc4oc5ccccc5c4c3c3ccc(-c4ccc(N(c5ccccc5)c5ccccc5)cc4)cc23)cc1 ; c1ccc(-c2cccc(N(c3ccccc3)c3cccc(-c4ccc5c(c4)c(-c4ccccc4)cc4ccc6oc7ccccc7c6c45)c3)c2)cc1 ; c1ccc(-c2ccc(N(c3ccc4c(c3)c(-c3ccccc3)cc3ccc5oc6ccccc6c5c34)c3ccccc3-c3ccccc3)cc2)cc1]

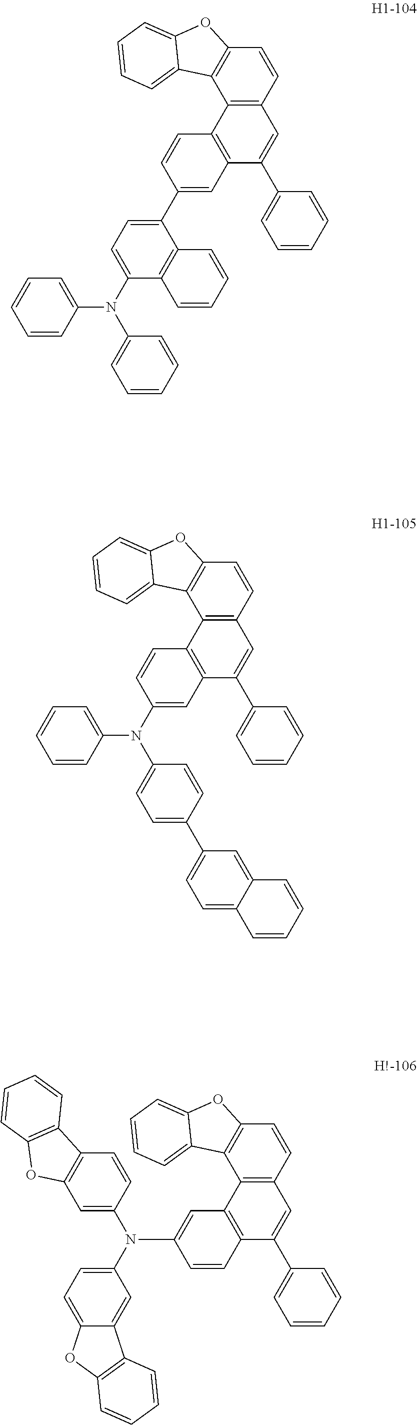 [SMILES: c1ccc(-c2cc3ccc4oc5ccccc5c4c3c3ccc(-c4ccc(N(c5ccccc5)c5ccccc5)c5ccccc45)cc23)cc1 ; c1ccc(-c2cc3ccc4oc5ccccc5c4c3c3ccc(N(c4ccccc4)c4ccc(-c5ccc6ccccc6c5)cc4)cc23)cc1 ; c1ccc(-c2cc3ccc4oc5ccccc5c4c3c3cc(N(c4ccc5c(c4)oc4ccccc45)c4ccc5oc6ccccc6c5c4)ccc23)cc1]

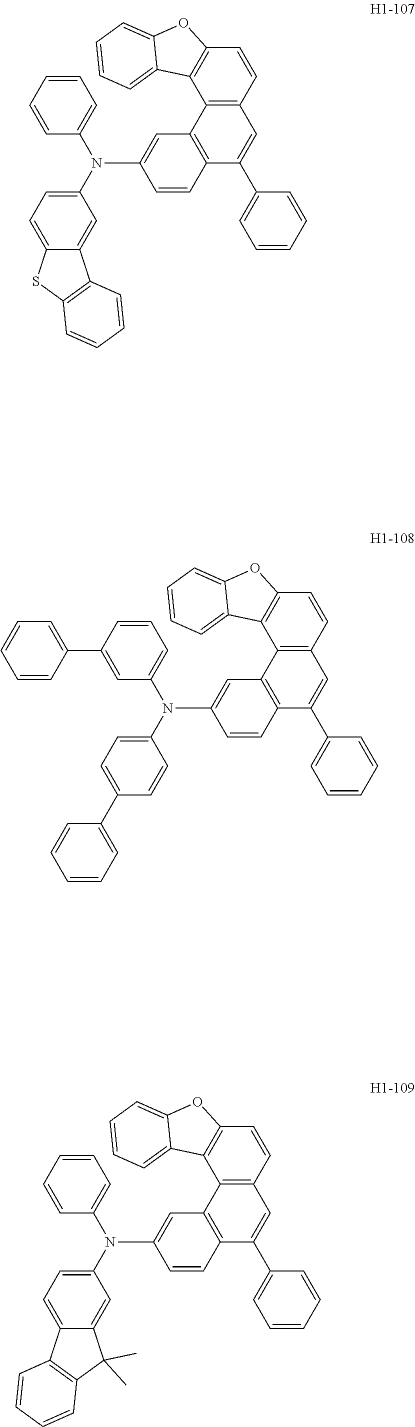 [SMILES: c1ccc(-c2cc3ccc4oc5ccccc5c4c3c3cc(N(c4ccccc4)c4ccc5sc6ccccc6c5c4)ccc23)cc1 ; c1ccc(-c2ccc(N(c3cccc(-c4ccccc4)c3)c3ccc4c(-c5ccccc5)cc5ccc6oc7ccccc7c6c5c4c3)cc2)cc1 ; CC1(C)c2ccccc2-c2ccc(N(c3ccccc3)c3ccc4c(-c5ccccc5)cc5ccc6oc7ccccc7c6c5c4c3)cc21]

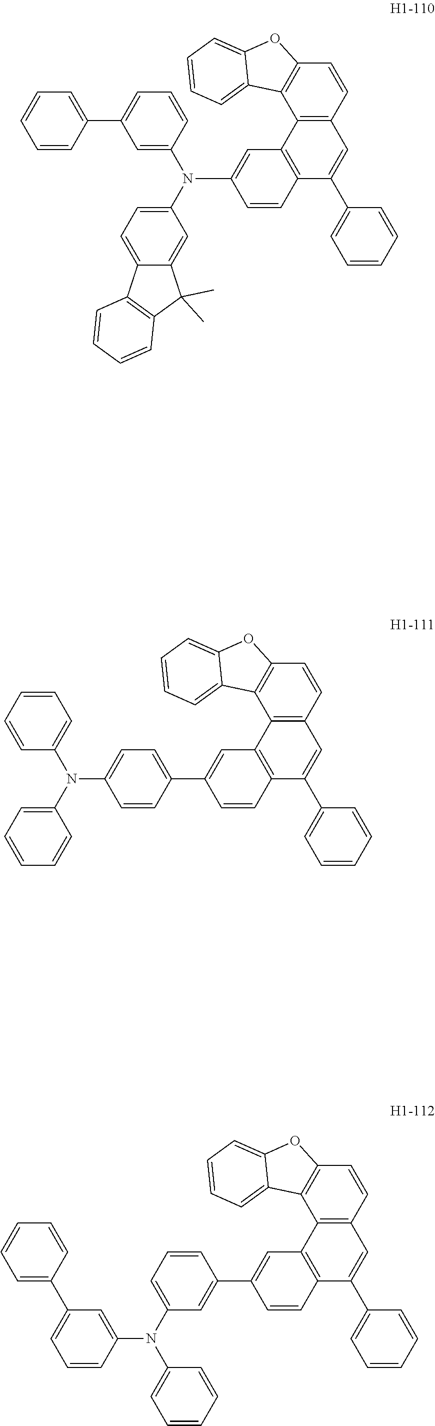 [SMILES: CC1(C)c2ccccc2-c2ccc(N(c3cccc(-c4ccccc4)c3)c3ccc4c(-c5ccccc5)cc5ccc6oc7ccccc7c6c5c4c3)cc21 ; c1ccc(-c2cc3ccc4oc5ccccc5c4c3c3cc(-c4ccc(N(c5ccccc5)c5ccccc5)cc4)ccc23)cc1 ; c1ccc(-c2cccc(N(c3ccccc3)c3cccc(-c4ccc5c(-c6ccccc6)cc6ccc7oc8ccccc8c7c6c5c4)c3)c2)cc1]

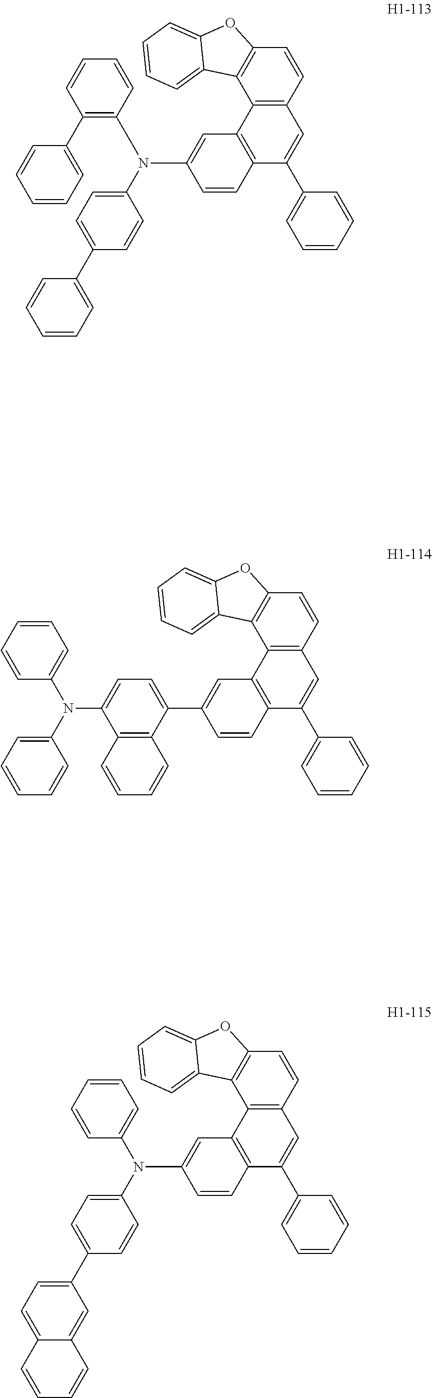 [SMILES: c1ccc(-c2ccc(N(c3ccc4c(-c5ccccc5)cc5ccc6oc7ccccc7c6c5c4c3)c3ccccc3-c3ccccc3)cc2)cc1 ; c1ccc(-c2cc3ccc4oc5ccccc5c4c3c3cc(-c4ccc(N(c5ccccc5)c5ccccc5)c5ccccc45)ccc23)cc1 ; c1ccc(-c2cc3ccc4oc5ccccc5c4c3c3cc(N(c4ccccc4)c4ccc(-c5ccc6ccccc6c5)cc4)ccc23)cc1]

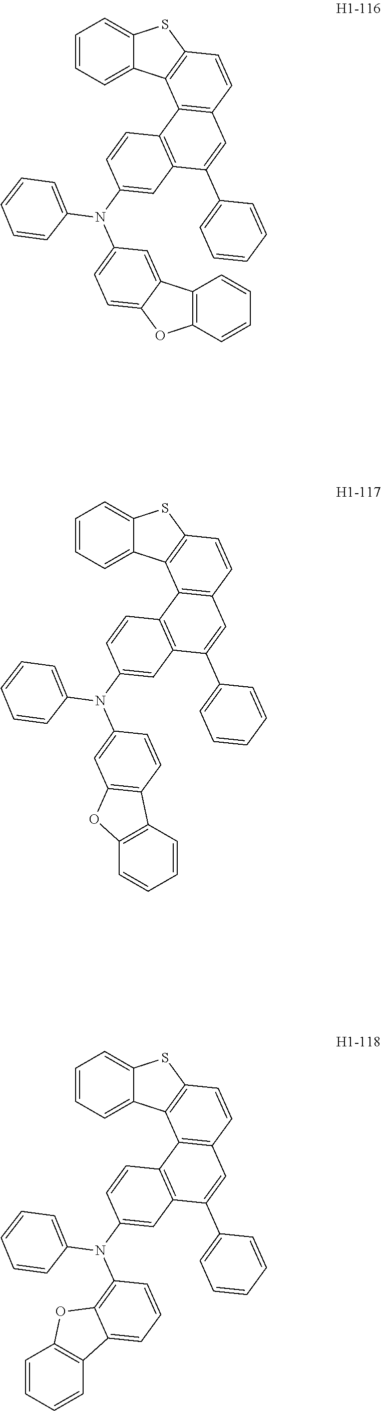 [SMILES: c1ccc(-c2cc3ccc4sc5ccccc5c4c3c3ccc(N(c4ccccc4)c4ccc5oc6ccccc6c5c4)cc23)cc1 ; c1ccc(-c2cc3ccc4sc5ccccc5c4c3c3ccc(N(c4ccccc4)c4ccc5c(c4)oc4ccccc45)cc23)cc1 ; c1ccc(-c2cc3ccc4sc5ccccc5c4c3c3ccc(N(c4ccccc4)c4cccc5c4oc4ccccc45)cc23)cc1]

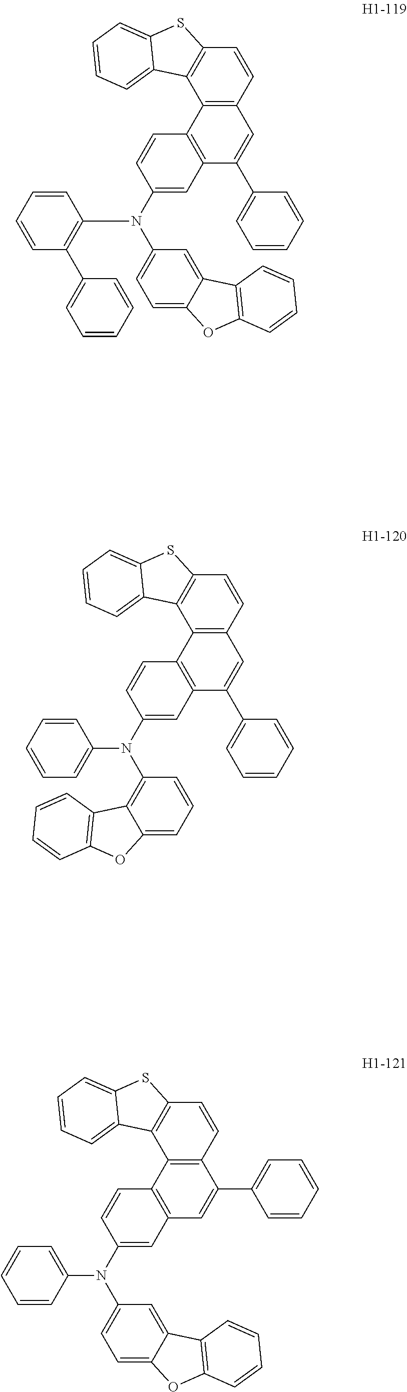

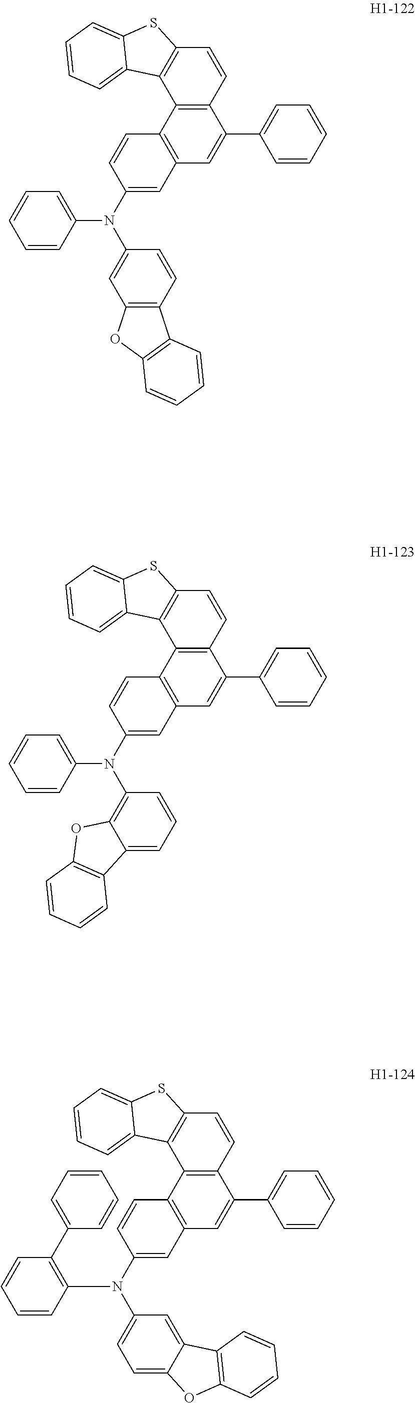 [SMILES: c1ccc(-c2cc3cc(N(c4ccccc4)c4ccc5c(c4)oc4ccccc45)ccc3c3c2ccc2sc4ccccc4c23)cc1 ; c1ccc(-c2cc3cc(N(c4ccccc4)c4cccc5c4oc4ccccc45)ccc3c3c2ccc2sc4ccccc4c23)cc1 ; c1ccc(-c2ccccc2N(c2ccc3c(c2)cc(-c2ccccc2)c2ccc4sc5ccccc5c4c23)c2ccc3oc4ccccc4c3c2)cc1]

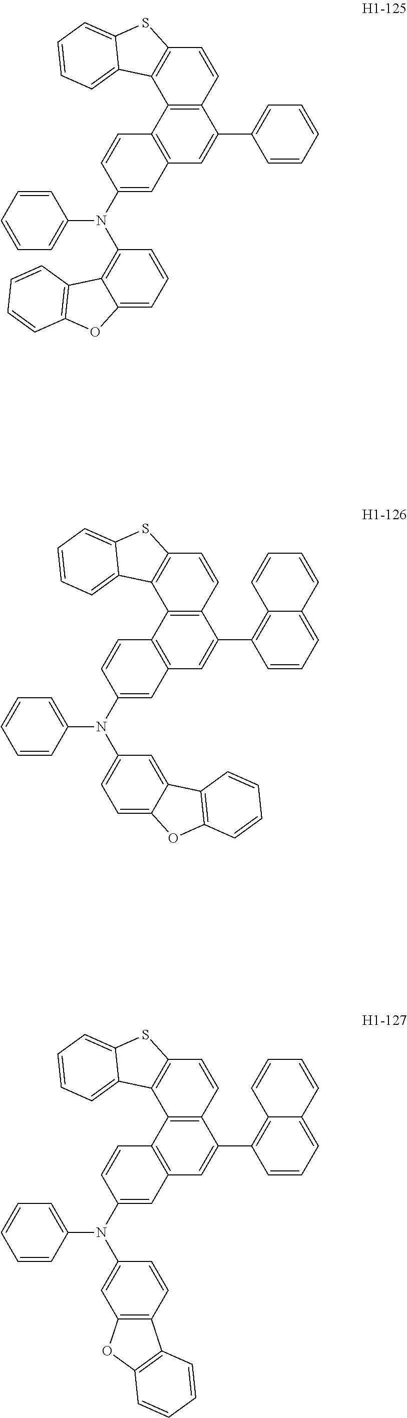 [SMILES: c1ccc(-c2cc3cc(N(c4ccccc4)c4cccc5oc6ccccc6c45)ccc3c3c2ccc2sc4ccccc4c23)cc1 ; c1ccc(N(c2ccc3c(c2)cc(-c2cccc4ccccc24)c2ccc4sc5ccccc5c4c23)c2ccc3oc4ccccc4c3c2)cc1 ; c1ccc(N(c2ccc3c(c2)cc(-c2cccc4ccccc24)c2ccc4sc5ccccc5c4c23)c2ccc3c(c2)oc2ccccc23)cc1]

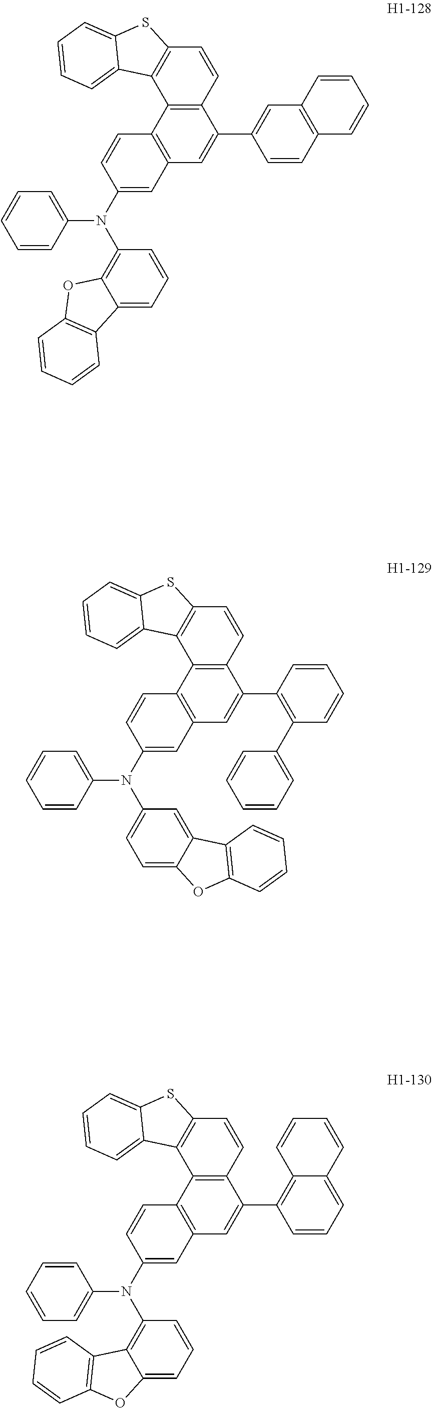 [SMILES: c1ccc(N(c2ccc3c(c2)cc(-c2ccc4ccccc4c2)c2ccc4sc5ccccc5c4c23)c2cccc3c2oc2ccccc23)cc1 ; c1ccc(-c2ccccc2-c2cc3cc(N(c4ccccc4)c4ccc5oc6ccccc6c5c4)ccc3c3c2ccc2sc4ccccc4c23)cc1 ; c1ccc(N(c2ccc3c(c2)cc(-c2cccc4ccccc24)c2ccc4sc5ccccc5c4c23)c2cccc3oc4ccccc4c23)cc1]

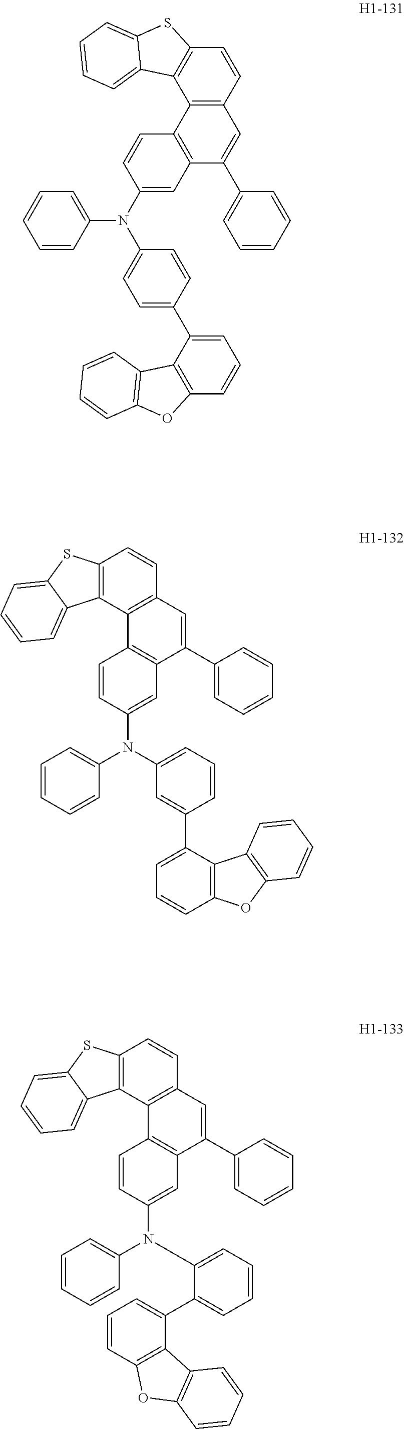 [SMILES: c1ccc(-c2cc3ccc4sc5ccccc5c4c3c3ccc(N(c4ccccc4)c4ccc(-c5cccc6oc7ccccc7c56)cc4)cc23)cc1 ; c1ccc(-c2cc3ccc4sc5ccccc5c4c3c3ccc(N(c4ccccc4)c4cccc(-c5cccc6oc7ccccc7c56)c4)cc23)cc1 ; c1ccc(-c2cc3ccc4sc5ccccc5c4c3c3ccc(N(c4ccccc4)c4ccccc4-c4cccc5oc6ccccc6c45)cc23)cc1]

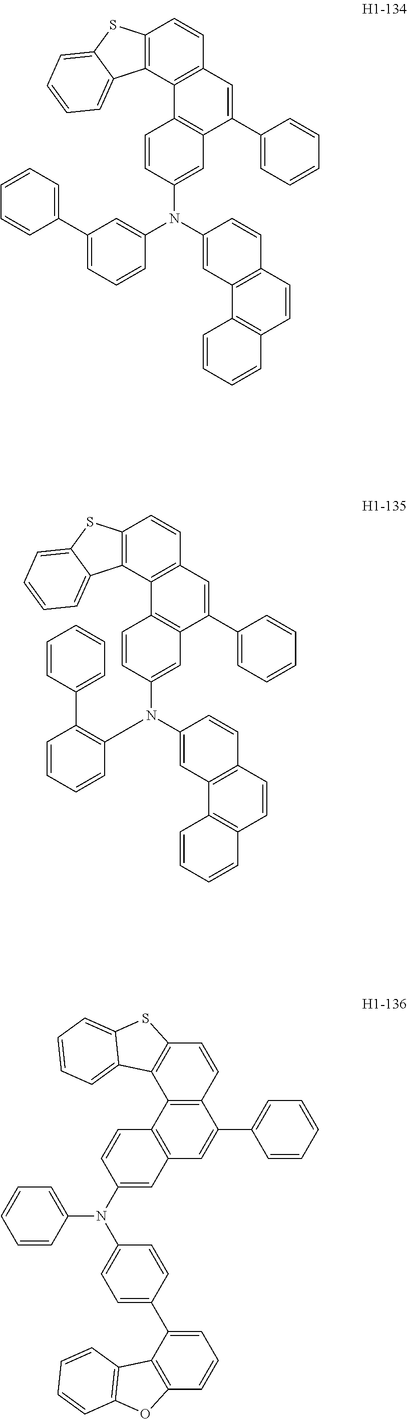 [SMILES: c1ccc(-c2cccc(N(c3ccc4c(c3)c(-c3ccccc3)cc3ccc5sc6ccccc6c5c34)c3ccc4ccc5ccccc5c4c3)c2)cc1 ; c1ccc(-c2ccccc2N(c2ccc3c(c2)c(-c2ccccc2)cc2ccc4sc5ccccc5c4c23)c2ccc3ccc4ccccc4c3c2)cc1 ; c1ccc(-c2cc3cc(N(c4ccccc4)c4ccc(-c5cccc6oc7ccccc7c56)cc4)ccc3c3c2ccc2sc4ccccc4c23)cc1]

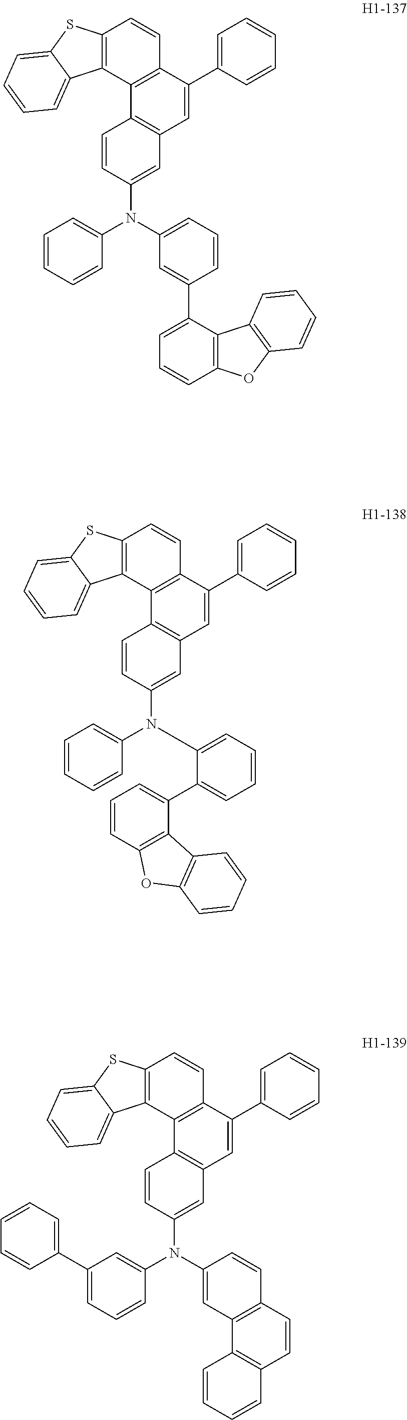 [SMILES: c1ccc(-c2cc3cc(N(c4ccccc4)c4cccc(-c5cccc6oc7ccccc7c56)c4)ccc3c3c2ccc2sc4ccccc4c23)cc1 ; c1ccc(-c2cc3cc(N(c4ccccc4)c4ccccc4-c4cccc5oc6ccccc6c45)ccc3c3c2ccc2sc4ccccc4c23)cc1 ; c1ccc(-c2cccc(N(c3ccc4c(c3)cc(-c3ccccc3)c3ccc5sc6ccccc6c5c34)c3ccc4ccc5ccccc5c4c3)c2)cc1]

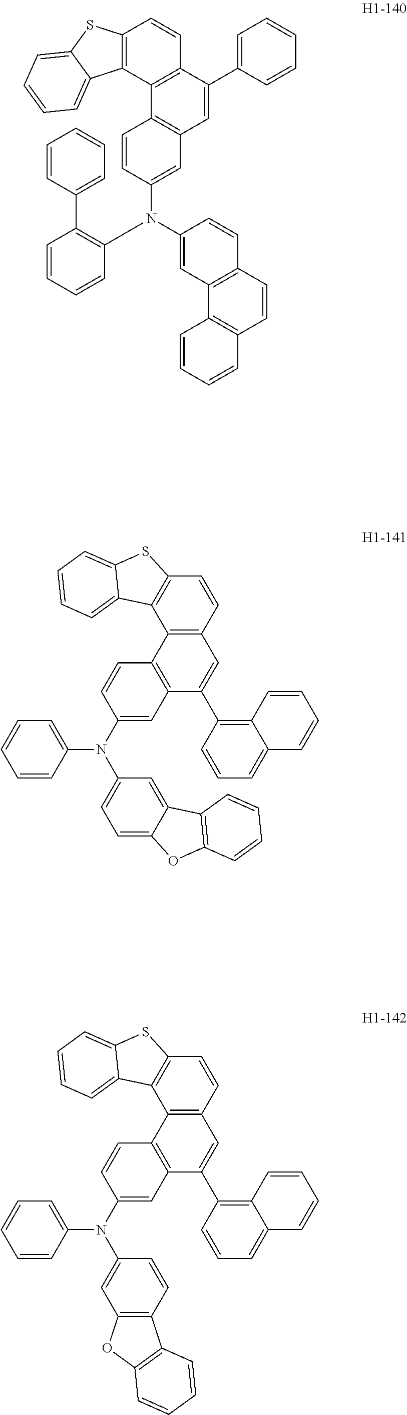 [SMILES: c1ccc(-c2ccccc2N(c2ccc3c(c2)cc(-c2ccccc2)c2ccc4sc5ccccc5c4c23)c2ccc3ccc4ccccc4c3c2)cc1 ; c1ccc(N(c2ccc3c(c2)c(-c2cccc4ccccc24)cc2ccc4sc5ccccc5c4c23)c2ccc3oc4ccccc4c3c2)cc1 ; c1ccc(N(c2ccc3c(c2)oc2ccccc23)c2ccc3c(c2)c(-c2cccc4ccccc24)cc2ccc4sc5ccccc5c4c23)cc1]

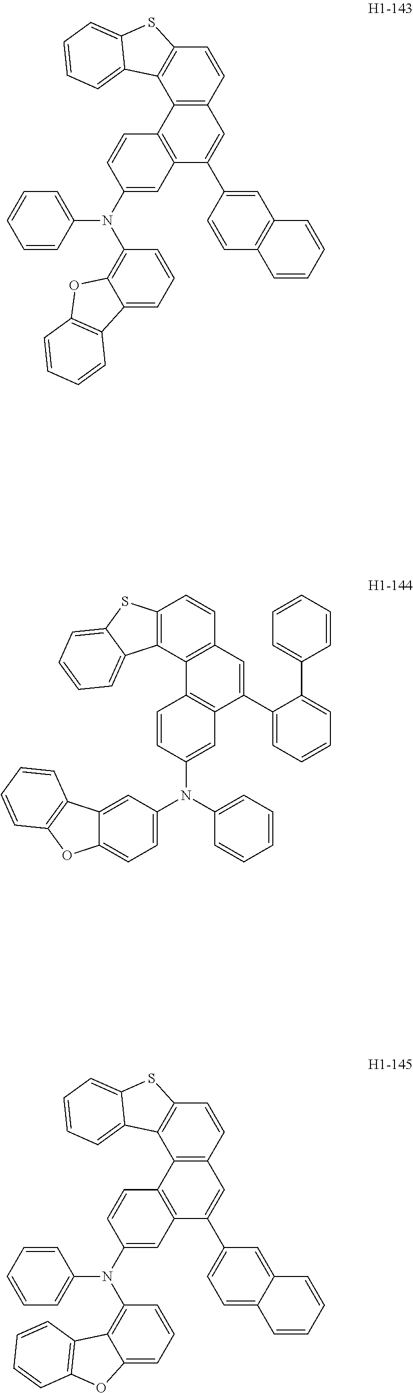 [SMILES: c1ccc(N(c2ccc3c(c2)c(-c2ccc4ccccc4c2)cc2ccc4sc5ccccc5c4c23)c2cccc3c2oc2ccccc23)cc1 ; c1ccc(-c2ccccc2-c2cc3ccc4sc5ccccc5c4c3c3ccc(N(c4ccccc4)c4ccc5oc6ccccc6c5c4)cc23)cc1 ; c1ccc(N(c2ccc3c(c2)c(-c2ccc4ccccc4c2)cc2ccc4sc5ccccc5c4c23)c2cccc3oc4ccccc4c23)cc1]

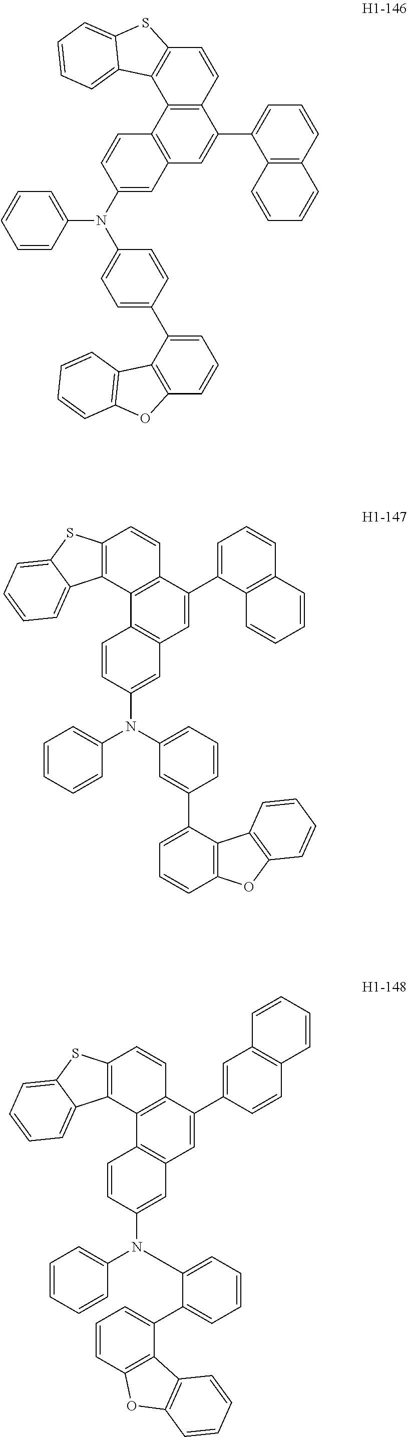 [SMILES: c1ccc(N(c2ccc(-c3cccc4oc5ccccc5c34)cc2)c2ccc3c(c2)cc(-c2cccc4ccccc24)c2ccc4sc5ccccc5c4c23)cc1 ; c1ccc(N(c2cccc(-c3cccc4oc5ccccc5c34)c2)c2ccc3c(c2)cc(-c2cccc4ccccc24)c2ccc4sc5ccccc5c4c23)cc1 ; c1ccc(N(c2ccc3c(c2)cc(-c2ccc4ccccc4c2)c2ccc4sc5ccccc5c4c23)c2ccccc2-c2cccc3oc4ccccc4c23)cc1]

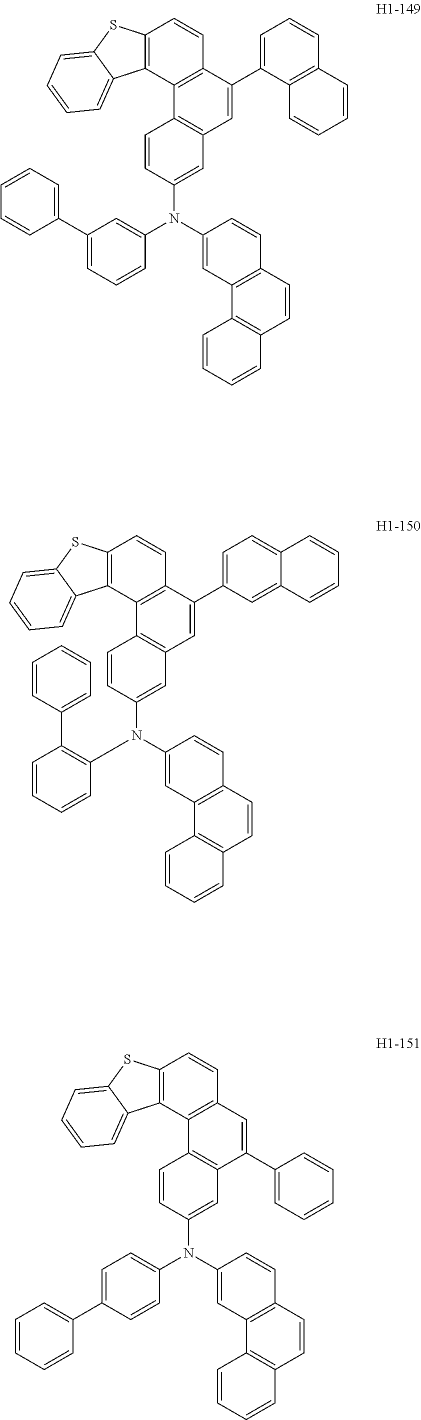 [SMILES: c1ccc(-c2cccc(N(c3ccc4c(c3)cc(-c3cccc5ccccc35)c3ccc5sc6ccccc6c5c34)c3ccc4ccc5ccccc5c4c3)c2)cc1 ; c1ccc(-c2ccccc2N(c2ccc3c(c2)cc(-c2ccc4ccccc4c2)c2ccc4sc5ccccc5c4c23)c2ccc3ccc4ccccc4c3c2)cc1 ; c1ccc(-c2ccc(N(c3ccc4c(c3)c(-c3ccccc3)cc3ccc5sc6ccccc6c5c34)c3ccc4ccc5ccccc5c4c3)cc2)cc1]

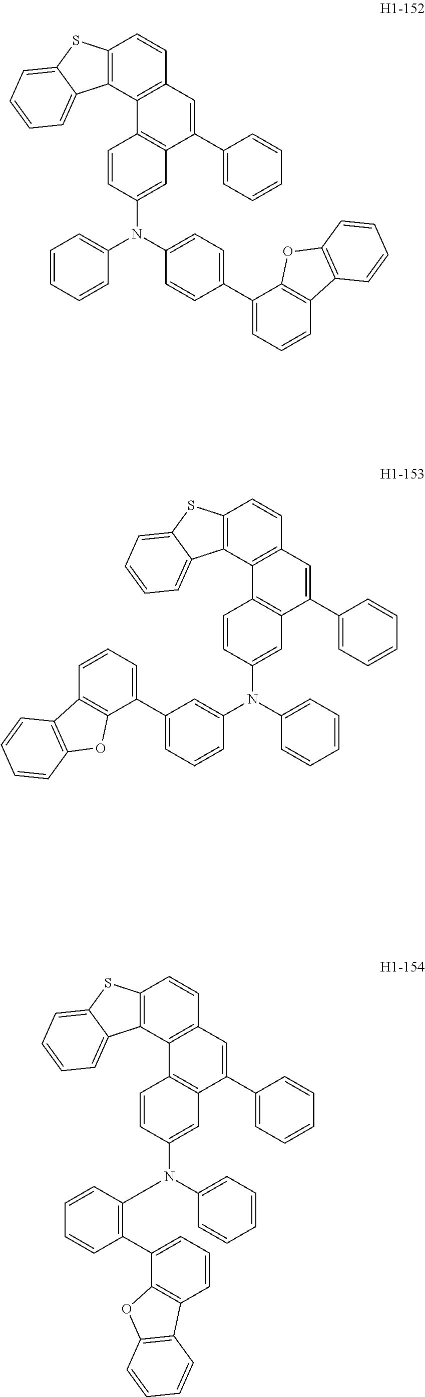 [SMILES: c1ccc(-c2cc3ccc4sc5ccccc5c4c3c3ccc(N(c4ccccc4)c4ccc(-c5cccc6c5oc5ccccc56)cc4)cc23)cc1 ; c1ccc(-c2cc3ccc4sc5ccccc5c4c3c3ccc(N(c4ccccc4)c4cccc(-c5cccc6c5oc5ccccc56)c4)cc23)cc1 ; c1ccc(-c2cc3ccc4sc5ccccc5c4c3c3ccc(N(c4ccccc4)c4ccccc4-c4cccc5c4oc4ccccc45)cc23)cc1]

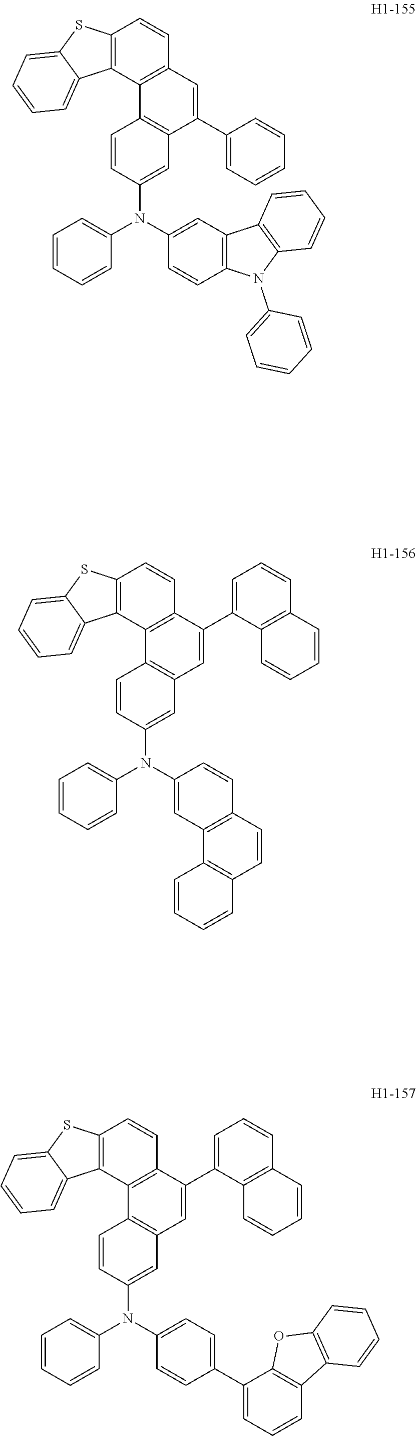 [SMILES: c1ccc(-c2cc3ccc4sc5ccccc5c4c3c3ccc(N(c4ccccc4)c4ccc5c(c4)c4ccccc4n5-c4ccccc4)cc23)cc1 ; c1ccc(N(c2ccc3c(c2)cc(-c2cccc4ccccc24)c2ccc4sc5ccccc5c4c23)c2ccc3ccc4ccccc4c3c2)cc1 ; c1ccc(N(c2ccc(-c3cccc4c3oc3ccccc34)cc2)c2ccc3c(c2)cc(-c2cccc4ccccc24)c2ccc4sc5ccccc5c4c23)cc1]

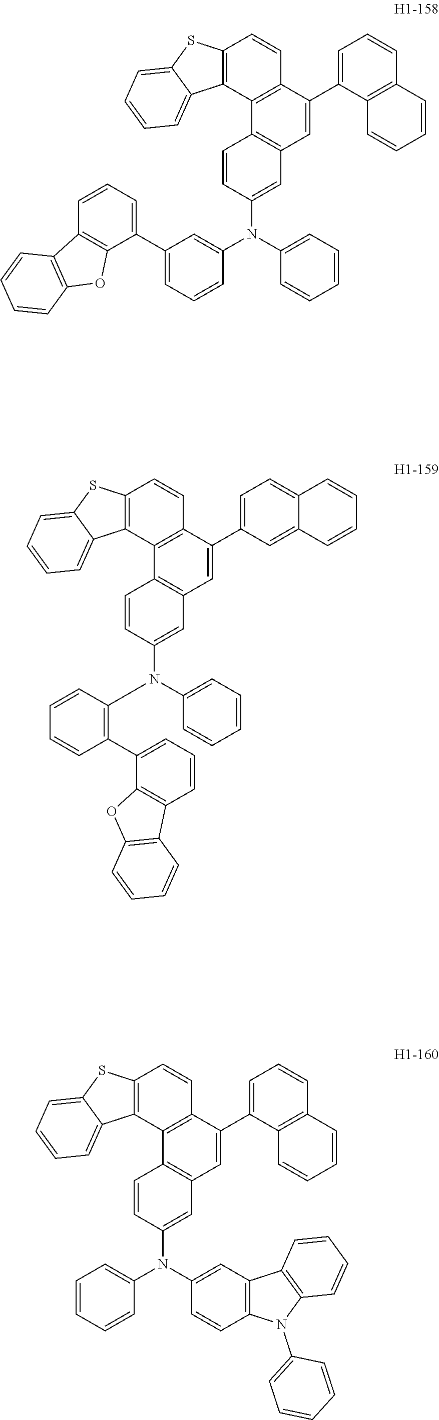 [SMILES: c1ccc(N(c2cccc(-c3cccc4c3oc3ccccc34)c2)c2ccc3c(c2)cc(-c2cccc4ccccc24)c2ccc4sc5ccccc5c4c23)cc1 ; c1ccc(N(c2ccc3c(c2)cc(-c2ccc4ccccc4c2)c2ccc4sc5ccccc5c4c23)c2ccccc2-c2cccc3c2oc2ccccc23)cc1 ; c1ccc(N(c2ccc3c(c2)cc(-c2cccc4ccccc24)c2ccc4sc5ccccc5c4c23)c2ccc3c(c2)c2ccccc2n3-c2ccccc2)cc1]

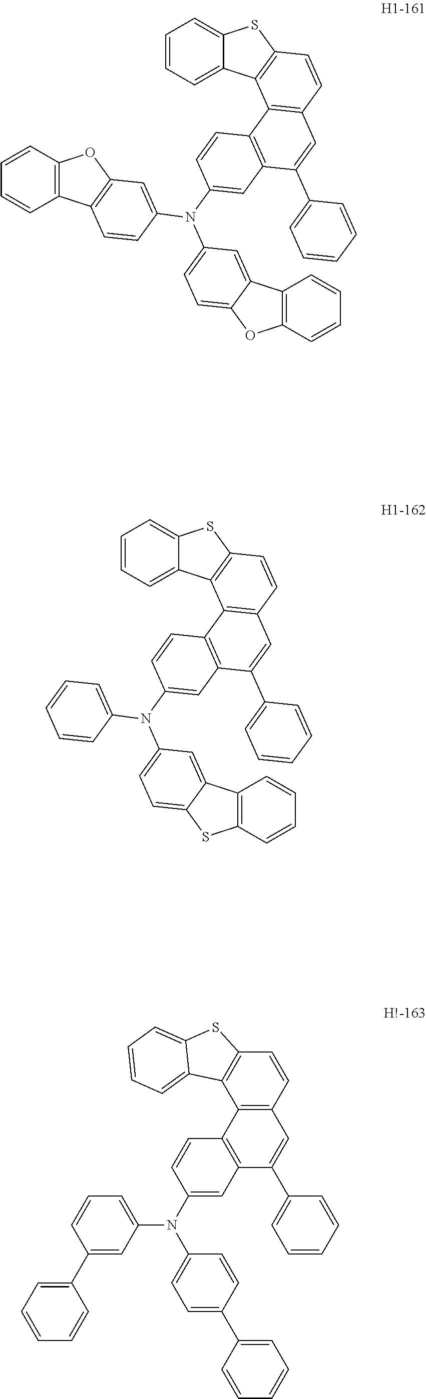 [SMILES: c1ccc(-c2cc3ccc4sc5ccccc5c4c3c3ccc(N(c4ccc5c(c4)oc4ccccc45)c4ccc5oc6ccccc6c5c4)cc23)cc1 ; c1ccc(-c2cc3ccc4sc5ccccc5c4c3c3ccc(N(c4ccccc4)c4ccc5sc6ccccc6c5c4)cc23)cc1 ; c1ccc(-c2ccc(N(c3cccc(-c4ccccc4)c3)c3ccc4c(c3)c(-c3ccccc3)cc3ccc5sc6ccccc6c5c34)cc2)cc1]

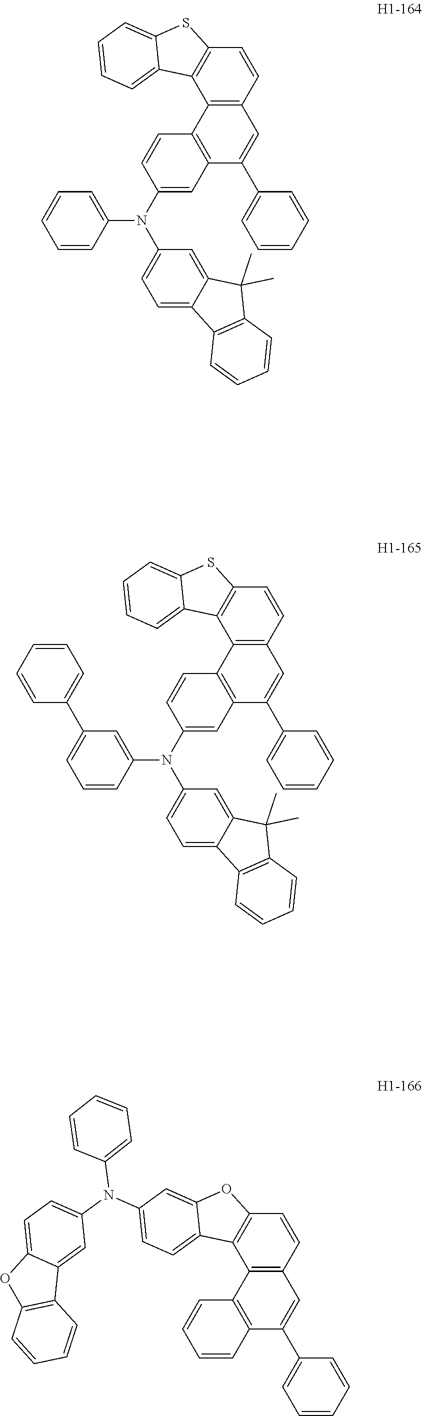 [SMILES: CC1(C)c2ccccc2-c2ccc(N(c3ccccc3)c3ccc4c(c3)c(-c3ccccc3)cc3ccc5sc6ccccc6c5c34)cc21 ; CC1(C)c2ccccc2-c2ccc(N(c3cccc(-c4ccccc4)c3)c3ccc4c(c3)c(-c3ccccc3)cc3ccc5sc6ccccc6c5c34)cc21 ; c1ccc(-c2cc3ccc4oc5cc(N(c6ccccc6)c6ccc7oc8ccccc8c7c6)ccc5c4c3c3ccccc23)cc1]

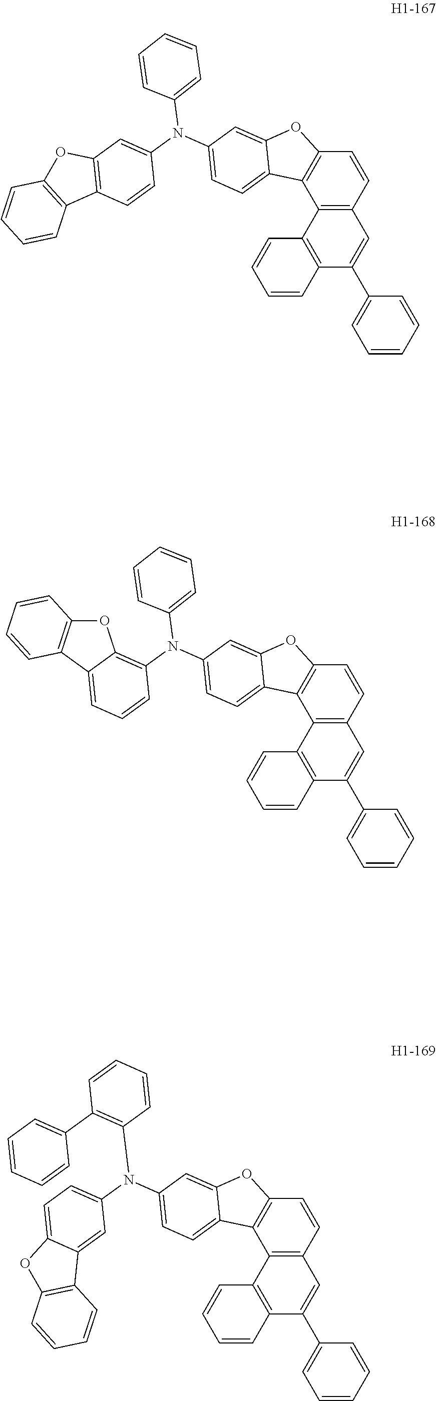 [SMILES: c1ccc(-c2cc3ccc4oc5cc(N(c6ccccc6)c6ccc7c(c6)oc6ccccc67)ccc5c4c3c3ccccc23)cc1 ; c1ccc(-c2cc3ccc4oc5cc(N(c6ccccc6)c6cccc7c6oc6ccccc67)ccc5c4c3c3ccccc23)cc1 ; c1ccc(-c2ccccc2N(c2ccc3c(c2)oc2ccc4cc(-c5ccccc5)c5ccccc5c4c23)c2ccc3oc4ccccc4c3c2)cc1]

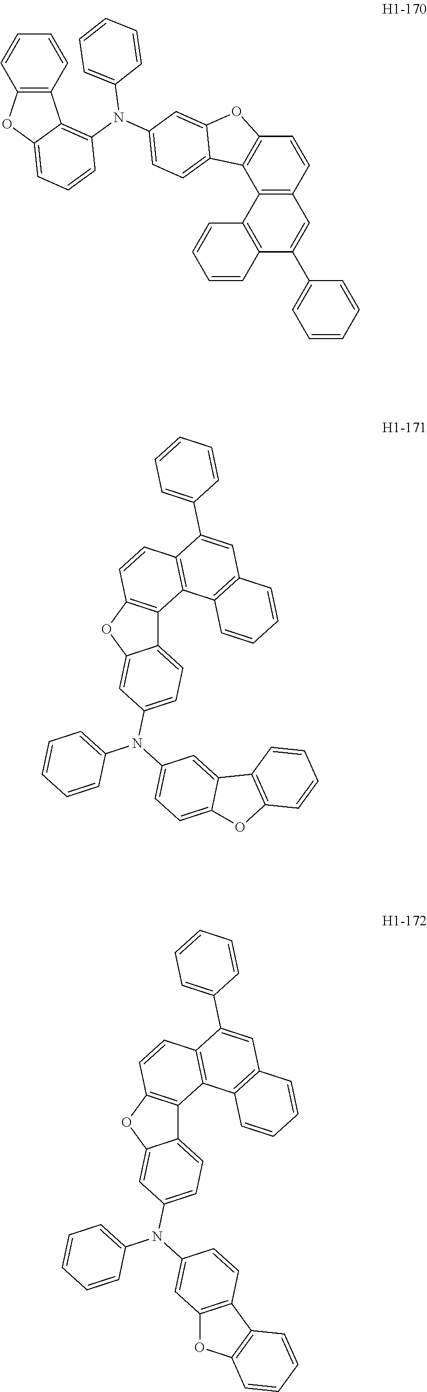 [SMILES: c1ccc(-c2cc3ccc4oc5cc(N(c6ccccc6)c6cccc7oc8ccccc8c67)ccc5c4c3c3ccccc23)cc1 ; c1ccc(-c2cc3ccccc3c3c2ccc2oc4cc(N(c5ccccc5)c5ccc6oc7ccccc7c6c5)ccc4c23)cc1 ; c1ccc(-c2cc3ccccc3c3c2ccc2oc4cc(N(c5ccccc5)c5ccc6c(c5)oc5ccccc56)ccc4c23)cc1]

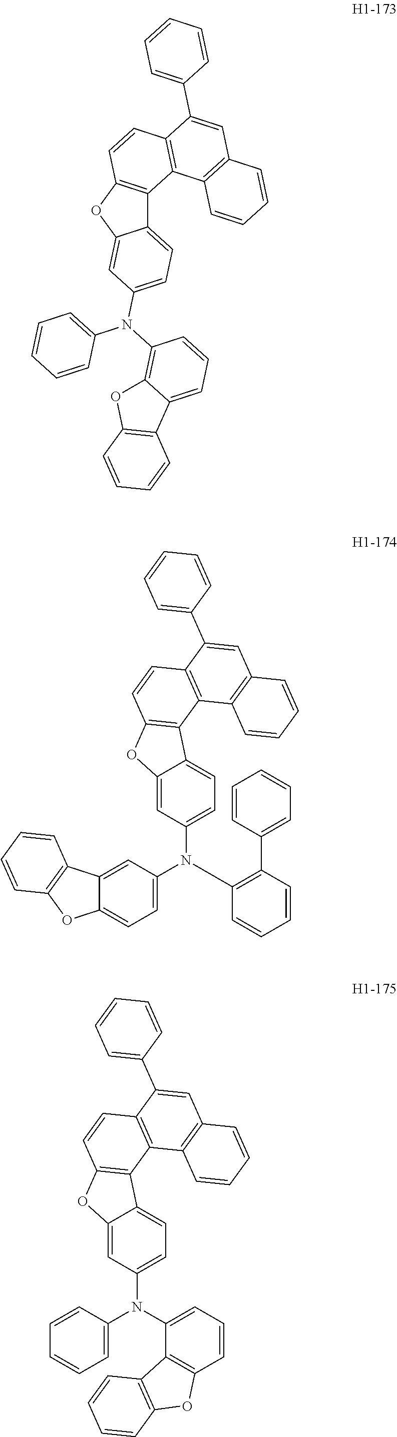 [SMILES: c1ccc(-c2cc3ccccc3c3c2ccc2oc4cc(N(c5ccccc5)c5cccc6c5oc5ccccc56)ccc4c23)cc1 ; c1ccc(-c2ccccc2N(c2ccc3c(c2)oc2ccc4c(-c5ccccc5)cc5ccccc5c4c23)c2ccc3oc4ccccc4c3c2)cc1 ; c1ccc(-c2cc3ccccc3c3c2ccc2oc4cc(N(c5ccccc5)c5cccc6oc7ccccc7c56)ccc4c23)cc1]

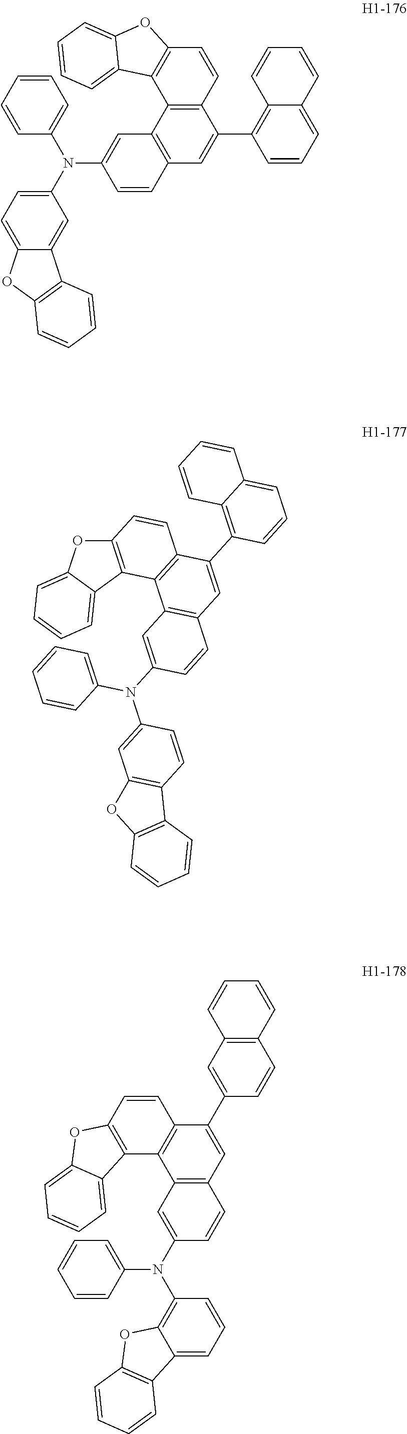 [SMILES: c1ccc(N(c2ccc3oc4ccccc4c3c2)c2ccc3cc(-c4cccc5ccccc45)c4ccc5oc6ccccc6c5c4c3c2)cc1 ; c1ccc(N(c2ccc3c(c2)oc2ccccc23)c2ccc3cc(-c4cccc5ccccc45)c4ccc5oc6ccccc6c5c4c3c2)cc1 ; c1ccc(N(c2ccc3cc(-c4ccc5ccccc5c4)c4ccc5oc6ccccc6c5c4c3c2)c2cccc3c2oc2ccccc23)cc1]

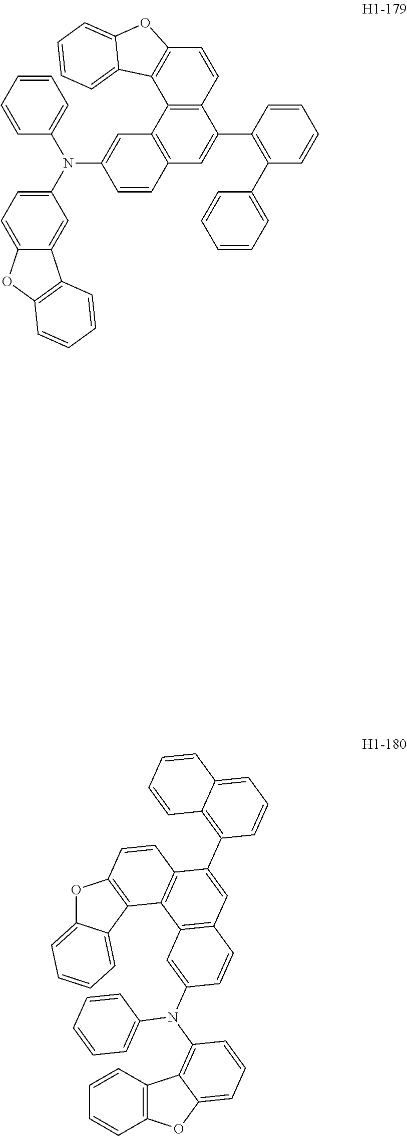 [SMILES: c1ccc(-c2ccccc2-c2cc3ccc(N(c4ccccc4)c4ccc5oc6ccccc6c5c4)cc3c3c2ccc2oc4ccccc4c23)cc1 ; c1ccc(N(c2ccc3cc(-c4cccc5ccccc45)c4ccc5oc6ccccc6c5c4c3c2)c2cccc3oc4ccccc4c23)cc1]

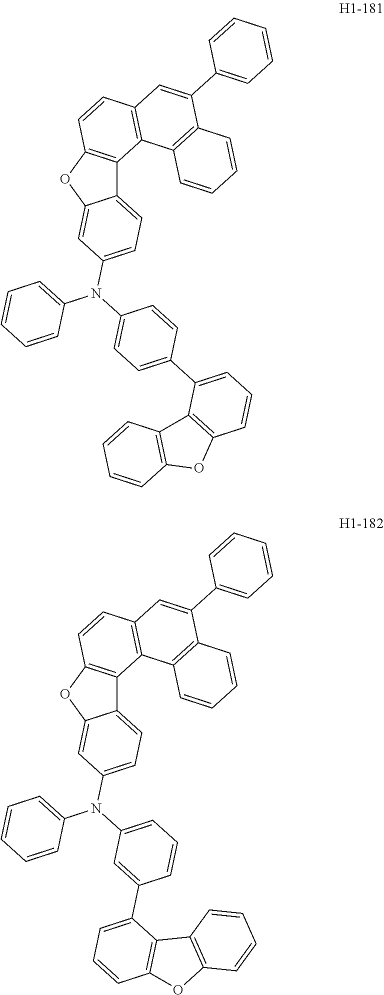 [SMILES: c1ccc(-c2cc3ccc4oc5cc(N(c6ccccc6)c6ccc(-c7cccc8oc9ccccc9c78)cc6)ccc5c4c3c3ccccc23)cc1 ; c1ccc(-c2cc3ccc4oc5cc(N(c6ccccc6)c6cccc(-c7cccc8oc9ccccc9c78)c6)ccc5c4c3c3ccccc23)cc1]

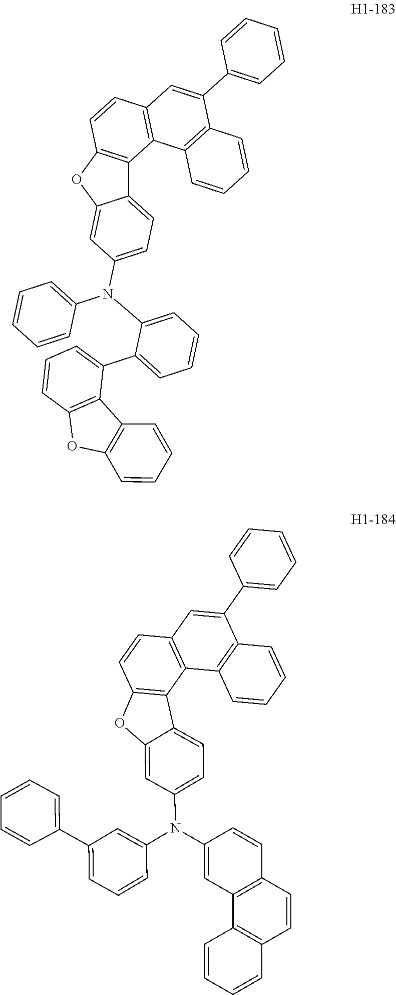 [SMILES: c1ccc(-c2cc3ccc4oc5cc(N(c6ccccc6)c6ccccc6-c6cccc7oc8ccccc8c67)ccc5c4c3c3ccccc23)cc1 ; c1ccc(-c2cccc(N(c3ccc4c(c3)oc3ccc5cc(-c6ccccc6)c6ccccc6c5c34)c3ccc4ccc5ccccc5c4c3)c2)cc1]

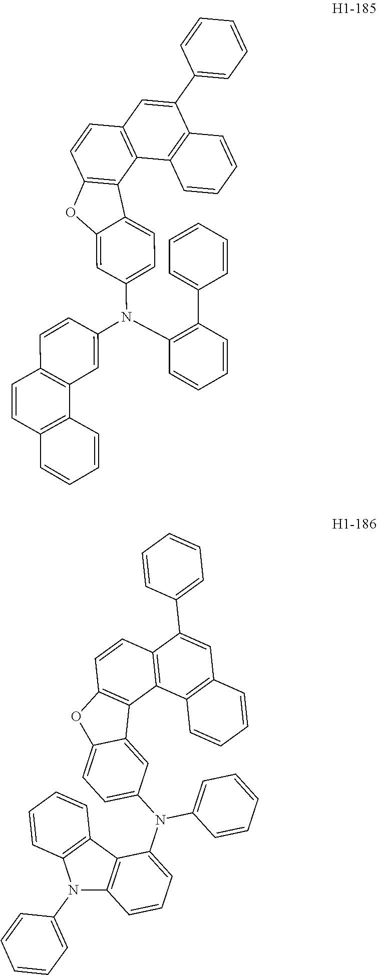 [SMILES: c1ccc(-c2ccccc2N(c2ccc3c(c2)oc2ccc4cc(-c5ccccc5)c5ccccc5c4c23)c2ccc3ccc4ccccc4c3c2)cc1 ; c1ccc(-c2cc3ccccc3c3c2ccc2oc4ccc(N(c5ccccc5)c5cccc6c5c5ccccc5n6-c5ccccc5)cc4c23)cc1]

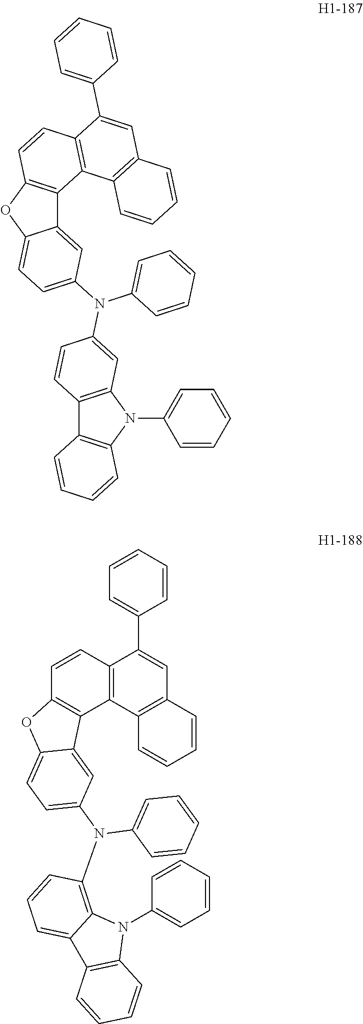 [SMILES: c1ccc(-c2cc3ccccc3c3c2ccc2oc4ccc(N(c5ccccc5)c5ccc6c7ccccc7n(-c7ccccc7)c6c5)cc4c23)cc1 ; c1ccc(-c2cc3ccccc3c3c2ccc2oc4ccc(N(c5ccccc5)c5cccc6c7ccccc7n(-c7ccccc7)c56)cc4c23)cc1]

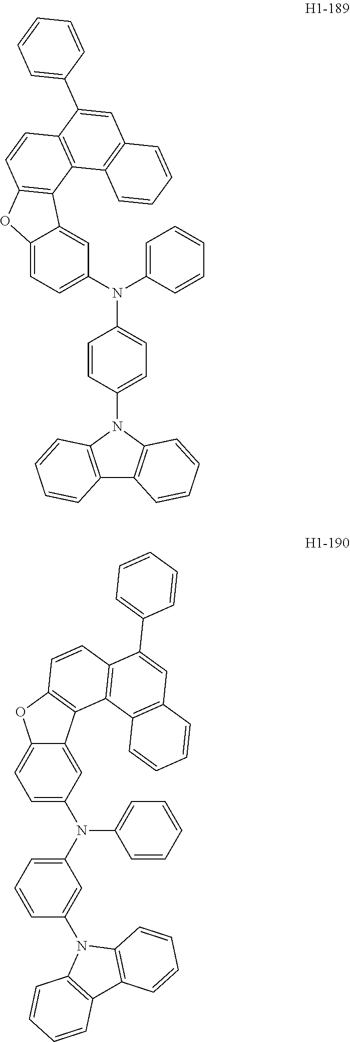 [SMILES: c1ccc(-c2cc3ccccc3c3c2ccc2oc4ccc(N(c5ccccc5)c5ccc(-n6c7ccccc7c7ccccc76)cc5)cc4c23)cc1 ; c1ccc(-c2cc3ccccc3c3c2ccc2oc4ccc(N(c5ccccc5)c5cccc(-n6c7ccccc7c7ccccc76)c5)cc4c23)cc1]

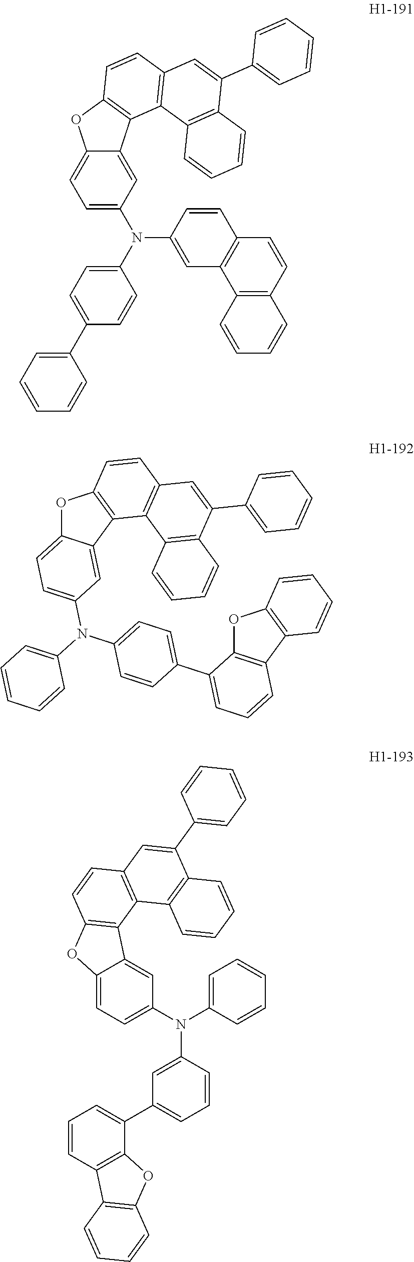 [SMILES: c1ccc(-c2ccc(N(c3ccc4ccc5ccccc5c4c3)c3ccc4oc5ccc6cc(-c7ccccc7)c7ccccc7c6c5c4c3)cc2)cc1 ; c1ccc(-c2cc3ccc4oc5ccc(N(c6ccccc6)c6ccc(-c7cccc8c7oc7ccccc78)cc6)cc5c4c3c3ccccc23)cc1 ; c1ccc(-c2cc3ccc4oc5ccc(N(c6ccccc6)c6cccc(-c7cccc8c7oc7ccccc78)c6)cc5c4c3c3ccccc23)cc1]

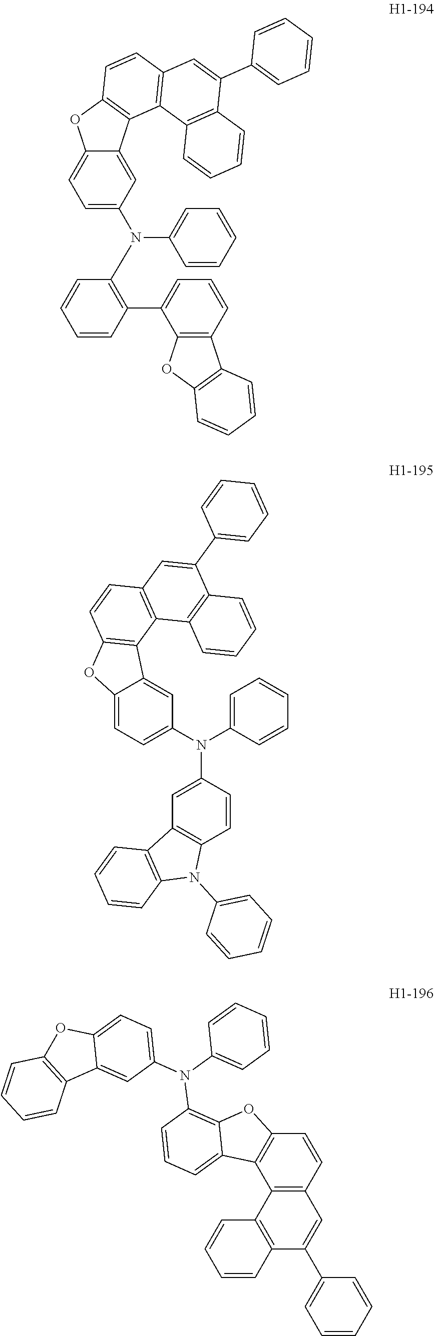

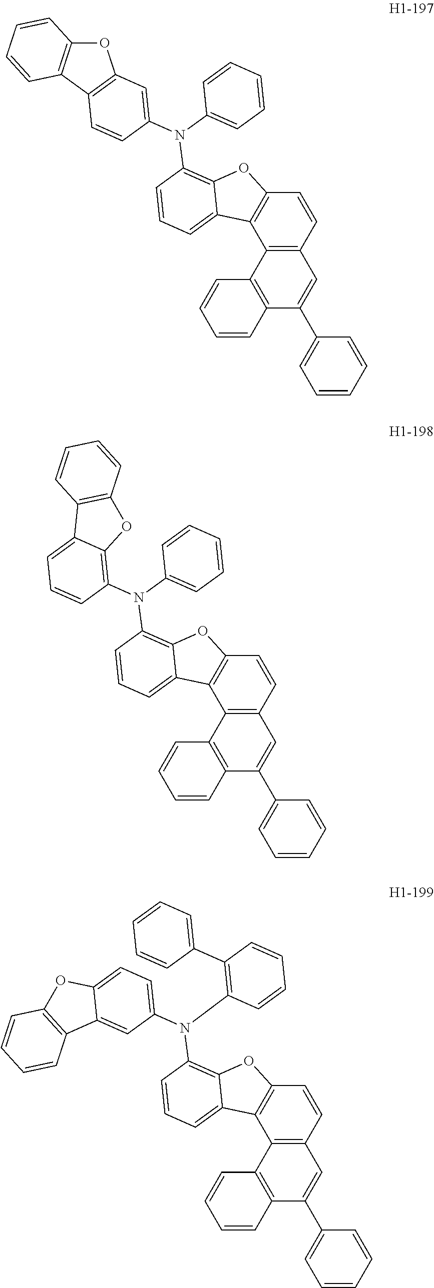 [SMILES: c1ccc(-c2cc3ccc4oc5c(N(c6ccccc6)c6ccc7c(c6)oc6ccccc67)cccc5c4c3c3ccccc23)cc1 ; c1ccc(-c2cc3ccc4oc5c(N(c6ccccc6)c6cccc7c6oc6ccccc67)cccc5c4c3c3ccccc23)cc1 ; c1ccc(-c2ccccc2N(c2ccc3oc4ccccc4c3c2)c2cccc3c2oc2ccc4cc(-c5ccccc5)c5ccccc5c4c23)cc1]

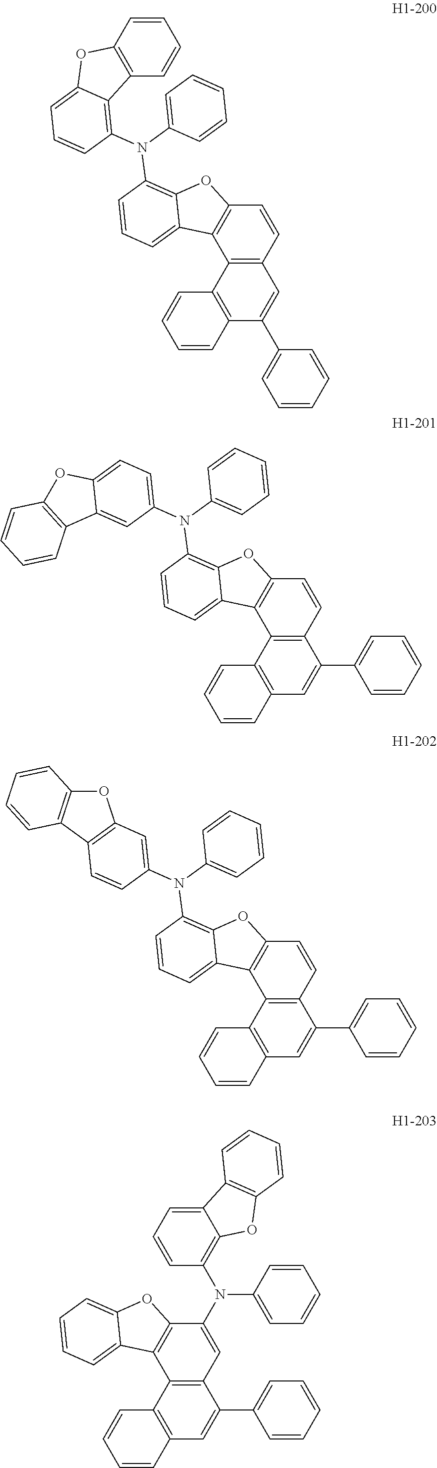

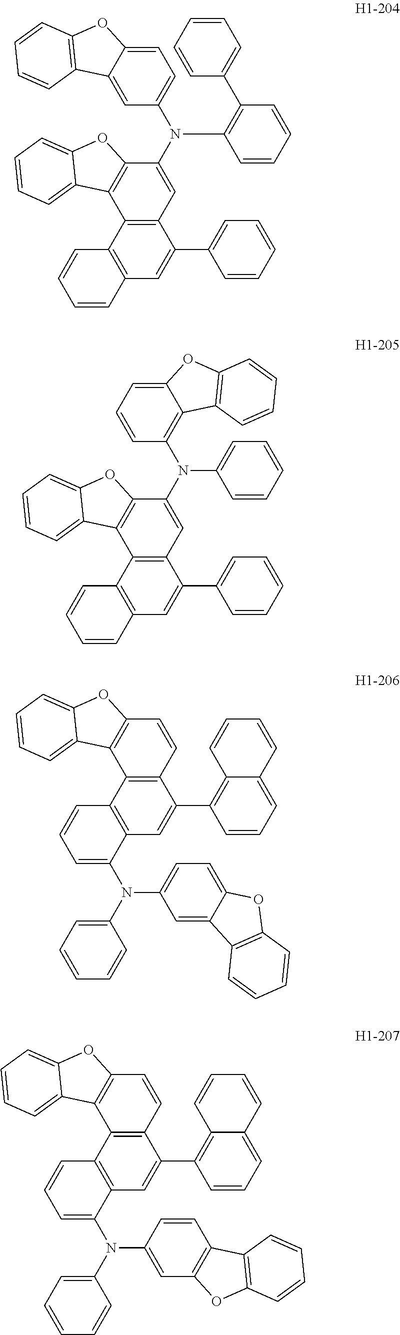 [SMILES: c1ccc(-c2ccccc2N(c2ccc3oc4ccccc4c3c2)c2cc3c(-c4ccccc4)cc4ccccc4c3c3c2oc2ccccc23)cc1 ; c1ccc(-c2cc3ccccc3c3c2cc(N(c2ccccc2)c2cccc4oc5ccccc5c24)c2oc4ccccc4c23)cc1 ; c1ccc(N(c2ccc3oc4ccccc4c3c2)c2cccc3c2cc(-c2cccc4ccccc24)c2ccc4oc5ccccc5c4c23)cc1 ; c1ccc(N(c2ccc3c(c2)oc2ccccc23)c2cccc3c2cc(-c2cccc4ccccc24)c2ccc4oc5ccccc5c4c23)cc1]

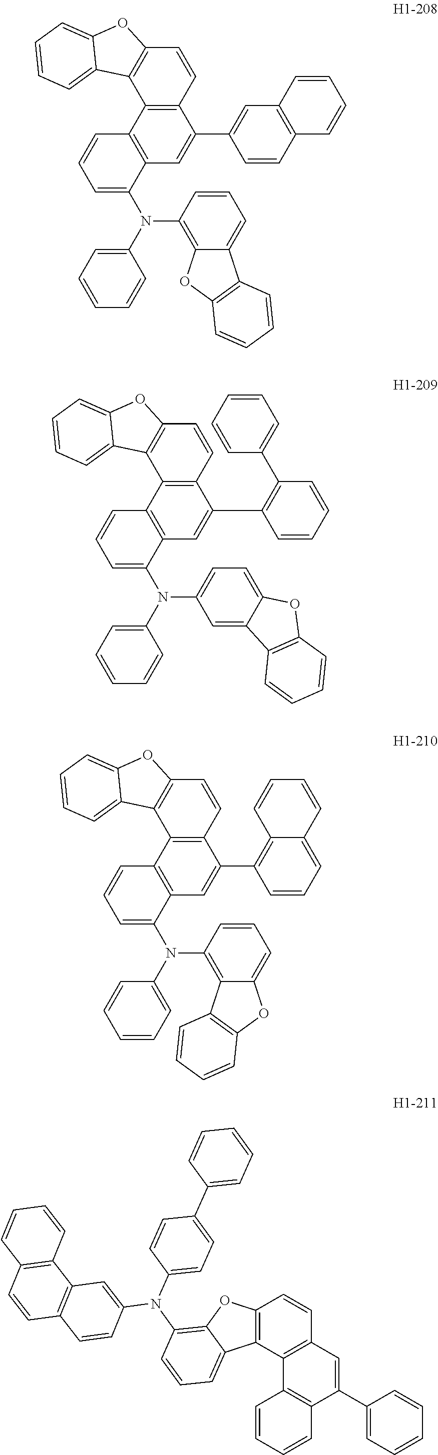 [SMILES: c1ccc(N(c2cccc3c2cc(-c2ccc4ccccc4c2)c2ccc4oc5ccccc5c4c23)c2cccc3c2oc2ccccc23)cc1 ; c1ccc(-c2ccccc2-c2cc3c(N(c4ccccc4)c4ccc5oc6ccccc6c5c4)cccc3c3c2ccc2oc4ccccc4c23)cc1 ; c1ccc(N(c2cccc3c2cc(-c2cccc4ccccc24)c2ccc4oc5ccccc5c4c23)c2cccc3oc4ccccc4c23)cc1 ; c1ccc(-c2ccc(N(c3ccc4ccc5ccccc5c4c3)c3cccc4c3oc3ccc5cc(-c6ccccc6)c6ccccc6c5c34)cc2)cc1]

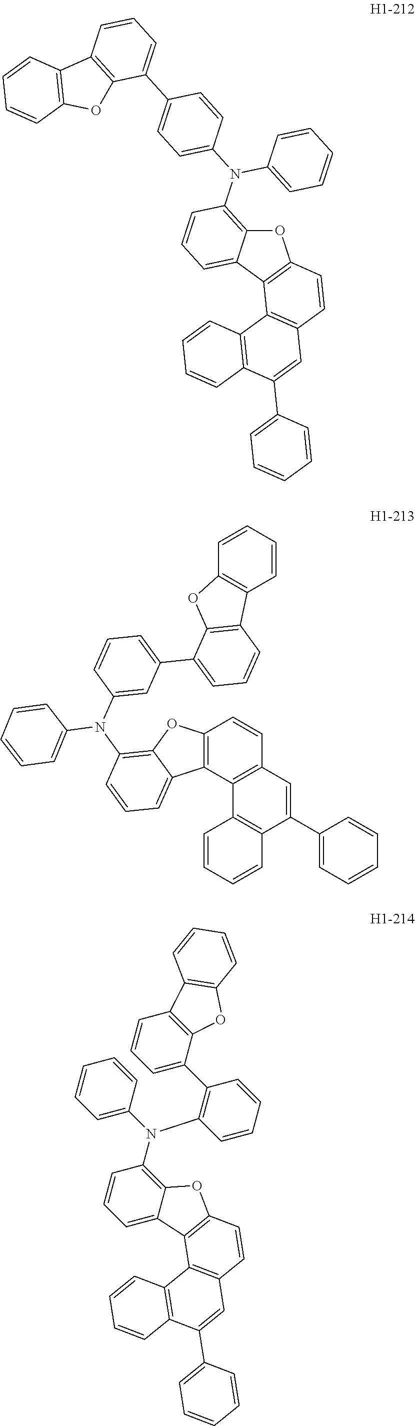 [SMILES: c1ccc(-c2cc3ccc4oc5c(N(c6ccccc6)c6ccc(-c7cccc8c7oc7ccccc78)cc6)cccc5c4c3c3ccccc23)cc1 ; c1ccc(-c2cc3ccc4oc5c(N(c6ccccc6)c6cccc(-c7cccc8c7oc7ccccc78)c6)cccc5c4c3c3ccccc23)cc1 ; c1ccc(-c2cc3ccc4oc5c(N(c6ccccc6)c6ccccc6-c6cccc7c6oc6ccccc67)cccc5c4c3c3ccccc23)cc1]

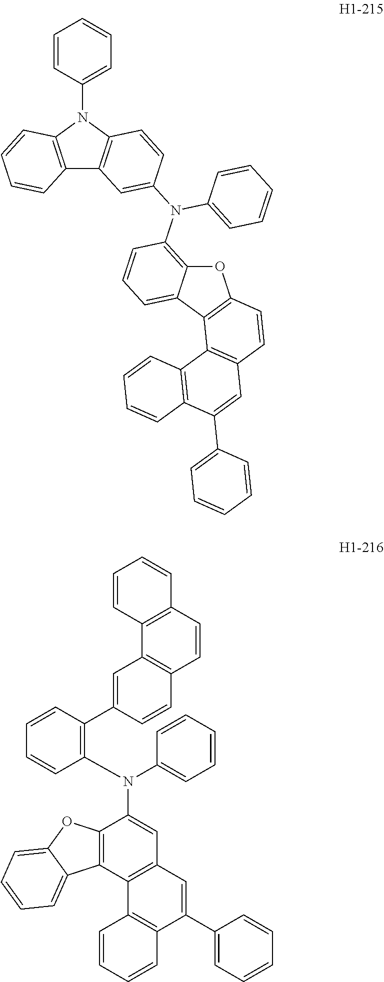 [SMILES: c1ccc(-c2cc3ccc4oc5c(N(c6ccccc6)c6ccc7c(c6)c6ccccc6n7-c6ccccc6)cccc5c4c3c3ccccc23)cc1 ; c1ccc(-c2cc3cc(N(c4ccccc4)c4ccccc4-c4ccc5ccc6ccccc6c5c4)c4oc5ccccc5c4c3c3ccccc23)cc1]

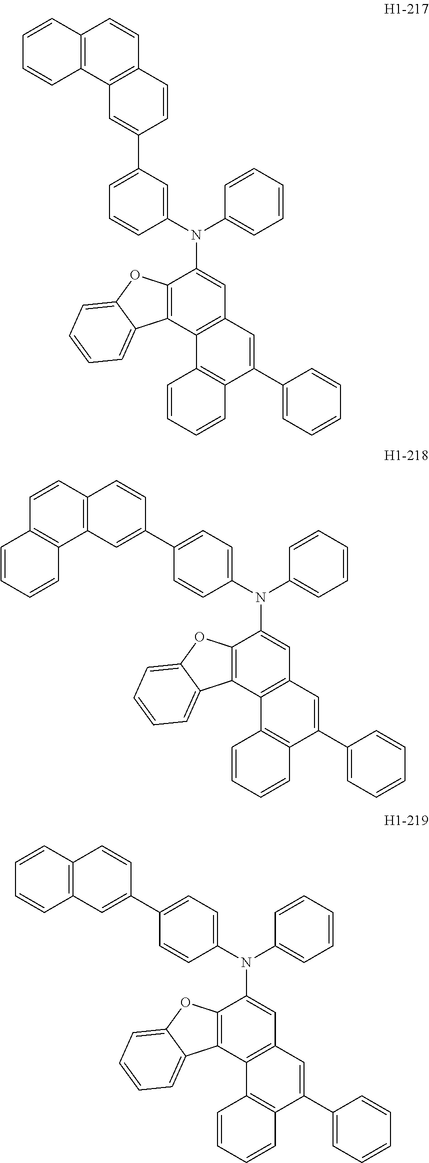 [SMILES: c1ccc(-c2cc3cc(N(c4ccccc4)c4cccc(-c5ccc6ccc7ccccc7c6c5)c4)c4oc5ccccc5c4c3c3ccccc23)cc1 ; c1ccc(-c2cc3cc(N(c4ccccc4)c4ccc(-c5ccc6ccc7ccccc7c6c5)cc4)c4oc5ccccc5c4c3c3ccccc23)cc1 ; c1ccc(-c2cc3cc(N(c4ccccc4)c4ccc(-c5ccc6ccccc6c5)cc4)c4oc5ccccc5c4c3c3ccccc23)cc1]

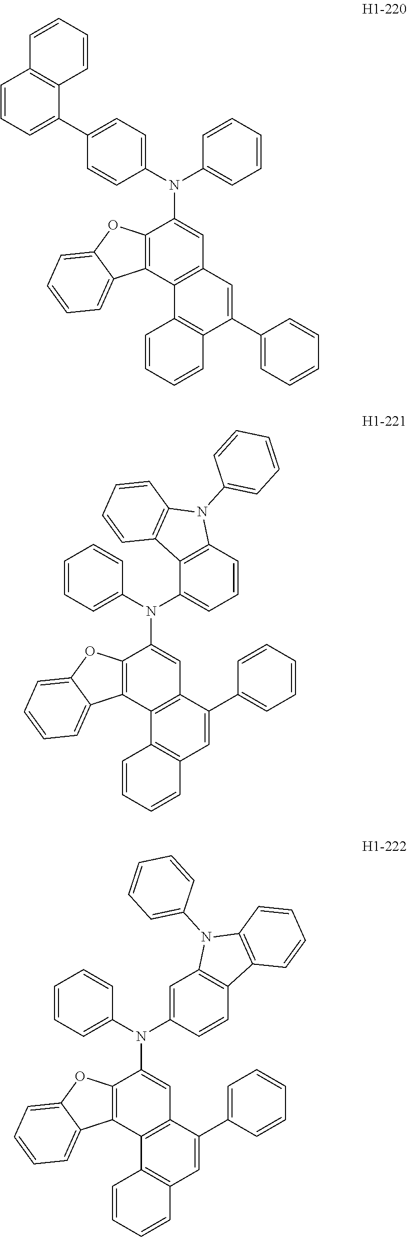 [SMILES: c1ccc(-c2cc3cc(N(c4ccccc4)c4ccc(-c5cccc6ccccc56)cc4)c4oc5ccccc5c4c3c3ccccc23)cc1 ; c1ccc(-c2cc3ccccc3c3c2cc(N(c2ccccc2)c2cccc4c2c2ccccc2n4-c2ccccc2)c2oc4ccccc4c23)cc1 ; c1ccc(-c2cc3ccccc3c3c2cc(N(c2ccccc2)c2ccc4c5ccccc5n(-c5ccccc5)c4c2)c2oc4ccccc4c23)cc1]

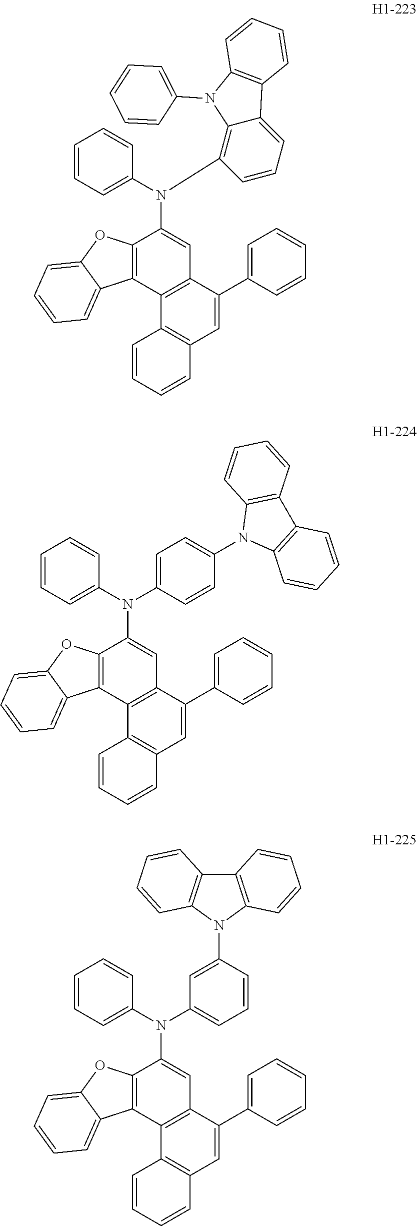 [SMILES: c1ccc(-c2cc3ccccc3c3c2cc(N(c2ccccc2)c2cccc4c5ccccc5n(-c5ccccc5)c24)c2oc4ccccc4c23)cc1 ; c1ccc(-c2cc3ccccc3c3c2cc(N(c2ccccc2)c2ccc(-n4c5ccccc5c5ccccc54)cc2)c2oc4ccccc4c23)cc1 ; c1ccc(-c2cc3ccccc3c3c2cc(N(c2ccccc2)c2cccc(-n4c5ccccc5c5ccccc54)c2)c2oc4ccccc4c23)cc1]

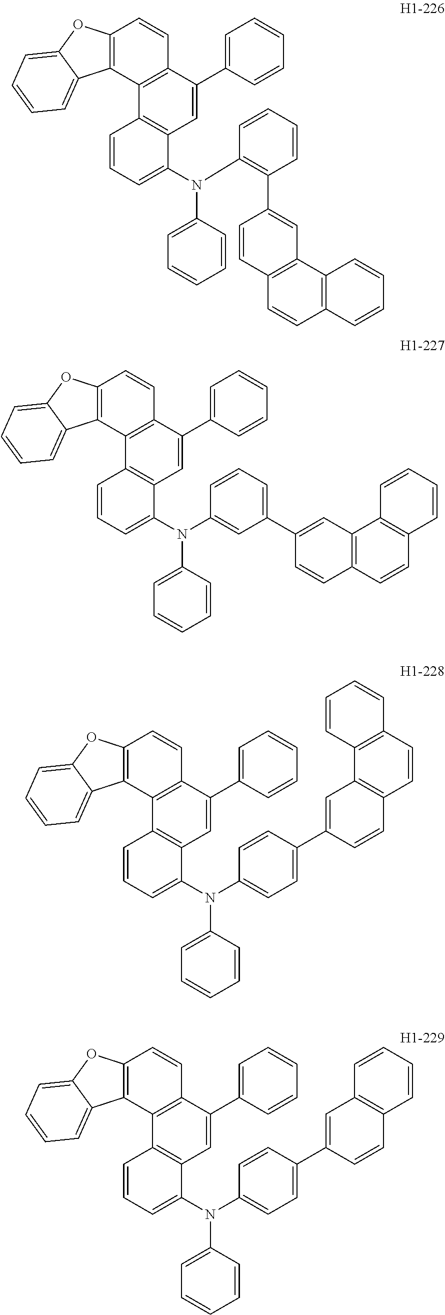 [SMILES: c1ccc(-c2cc3c(N(c4ccccc4)c4ccccc4-c4ccc5ccc6ccccc6c5c4)cccc3c3c2ccc2oc4ccccc4c23)cc1 ; c1ccc(-c2cc3c(N(c4ccccc4)c4cccc(-c5ccc6ccc7ccccc7c6c5)c4)cccc3c3c2ccc2oc4ccccc4c23)cc1 ; c1ccc(-c2cc3c(N(c4ccccc4)c4ccc(-c5ccc6ccc7ccccc7c6c5)cc4)cccc3c3c2ccc2oc4ccccc4c23)cc1 ; c1ccc(-c2cc3c(N(c4ccccc4)c4ccc(-c5ccc6ccccc6c5)cc4)cccc3c3c2ccc2oc4ccccc4c23)cc1]

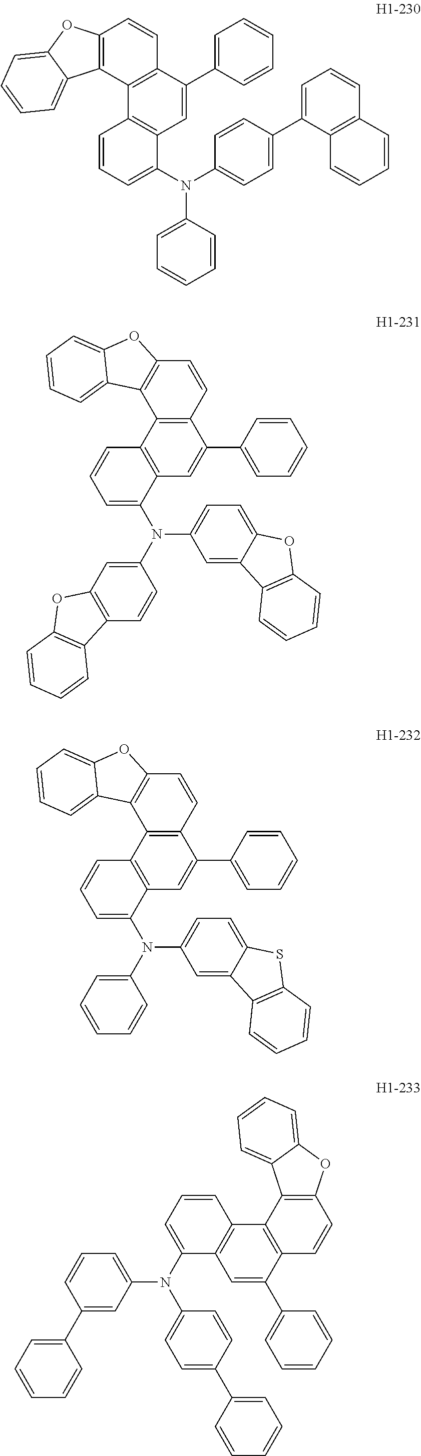

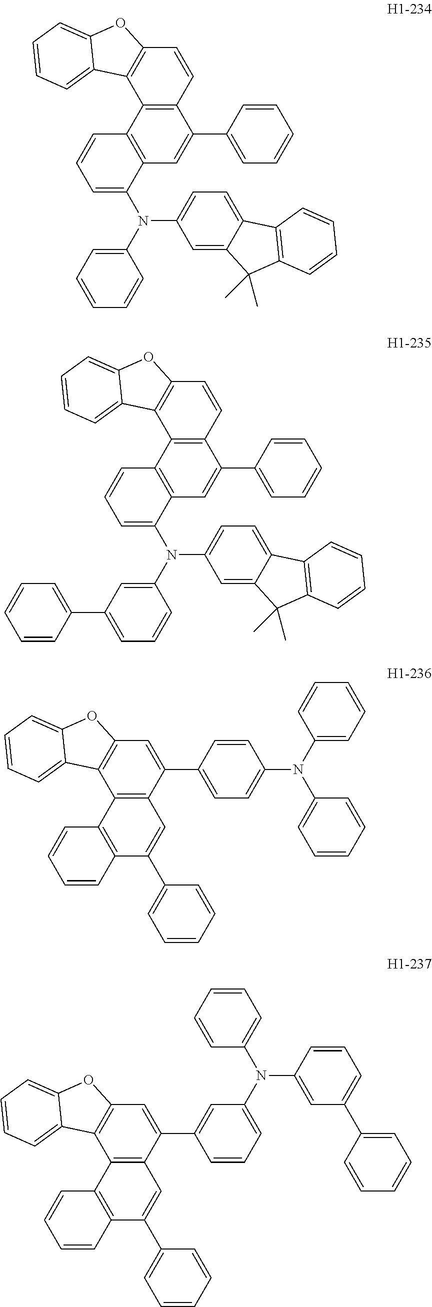 [SMILES: CC1(C)c2ccccc2-c2ccc(N(c3ccccc3)c3cccc4c3cc(-c3ccccc3)c3ccc5oc6ccccc6c5c34)cc21 ; CC1(C)c2ccccc2-c2ccc(N(c3cccc(-c4ccccc4)c3)c3cccc4c3cc(-c3ccccc3)c3ccc5oc6ccccc6c5c34)cc21 ; c1ccc(-c2cc3c(-c4ccc(N(c5ccccc5)c5ccccc5)cc4)cc4oc5ccccc5c4c3c3ccccc23)cc1 ; c1ccc(-c2cccc(N(c3ccccc3)c3cccc(-c4cc5oc6ccccc6c5c5c4cc(-c4ccccc4)c4ccccc45)c3)c2)cc1]

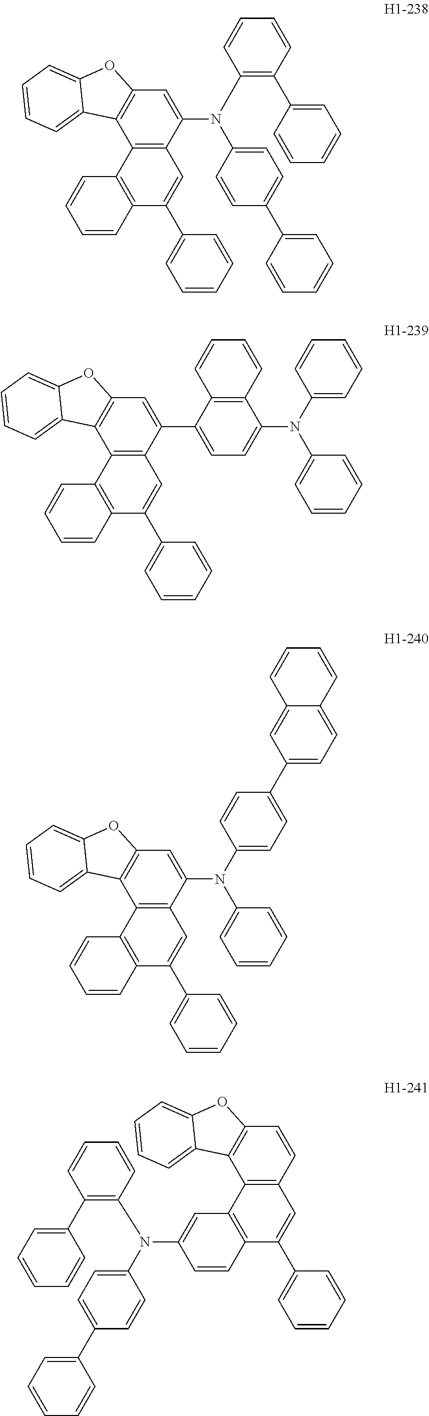 [SMILES: c1ccc(-c2ccc(N(c3ccccc3-c3ccccc3)c3cc4oc5ccccc5c4c4c3cc(-c3ccccc3)c3ccccc34)cc2)cc1 ; c1ccc(-c2cc3c(-c4ccc(N(c5ccccc5)c5ccccc5)c5ccccc45)cc4oc5ccccc5c4c3c3ccccc23)cc1 ; c1ccc(-c2cc3c(N(c4ccccc4)c4ccc(-c5ccc6ccccc6c5)cc4)cc4oc5ccccc5c4c3c3ccccc23)cc1 ; c1ccc(-c2ccc(N(c3ccc4c(-c5ccccc5)cc5ccc6oc7ccccc7c6c5c4c3)c3ccccc3-c3ccccc3)cc2)cc1]

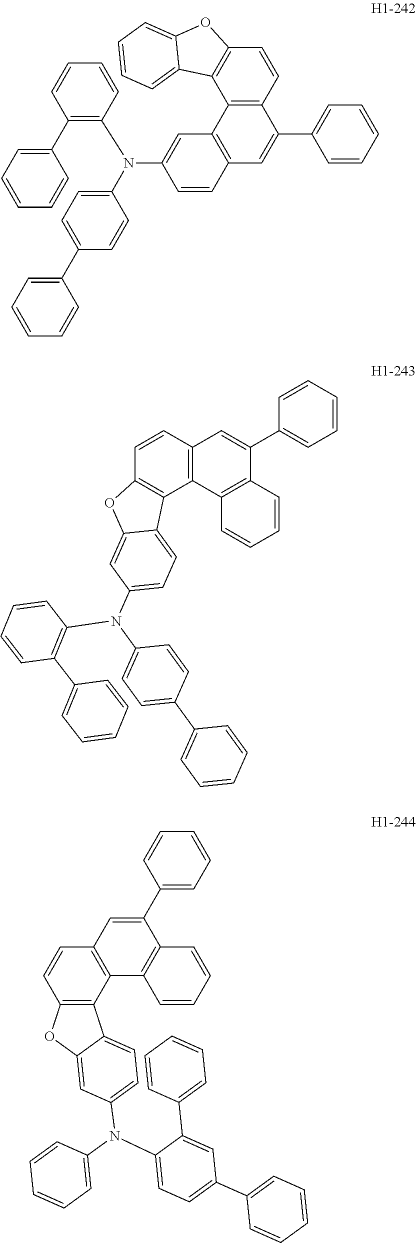

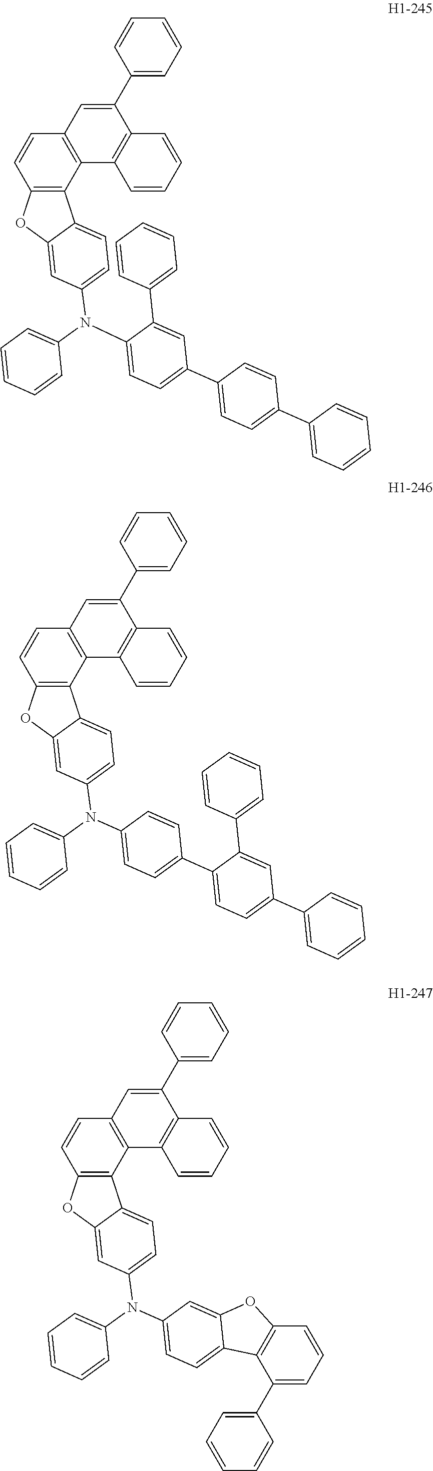 [SMILES: c1ccc(-c2ccc(-c3ccc(N(c4ccccc4)c4ccc5c(c4)oc4ccc6cc(-c7ccccc7)c7ccccc7c6c45)c(-c4ccccc4)c3)cc2)cc1 ; c1ccc(-c2ccc(-c3ccc(N(c4ccccc4)c4ccc5c(c4)oc4ccc6cc(-c7ccccc7)c7ccccc7c6c45)cc3)c(-c3ccccc3)c2)cc1 ; c1ccc(-c2cc3ccc4oc5cc(N(c6ccccc6)c6ccc7c(c6)oc6cccc(-c8ccccc8)c67)ccc5c4c3c3ccccc23)cc1]

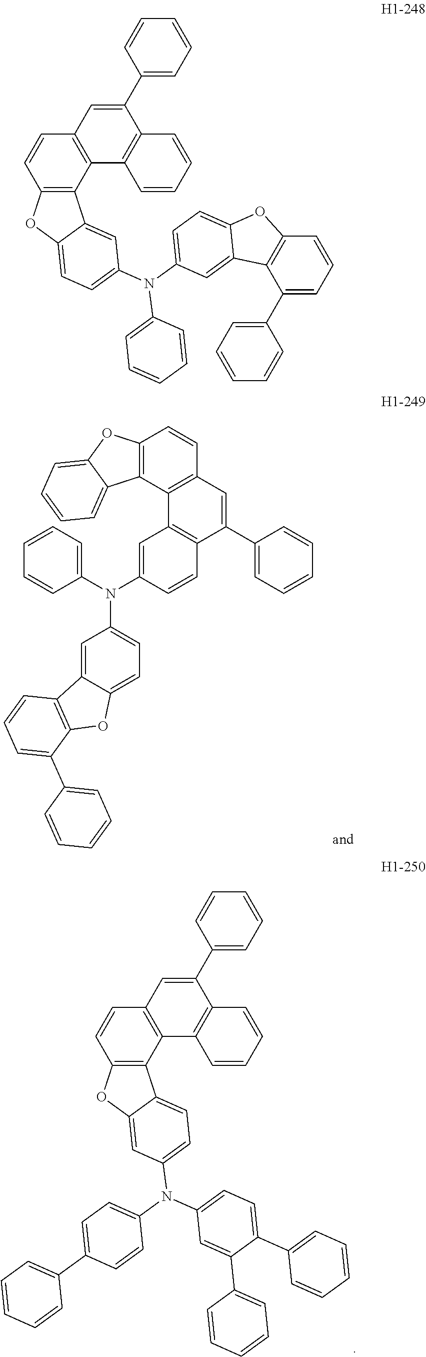

6. The plurality of host materials according to claim 1, wherein the compound represented by Formula 2 is selected from the following compounds:

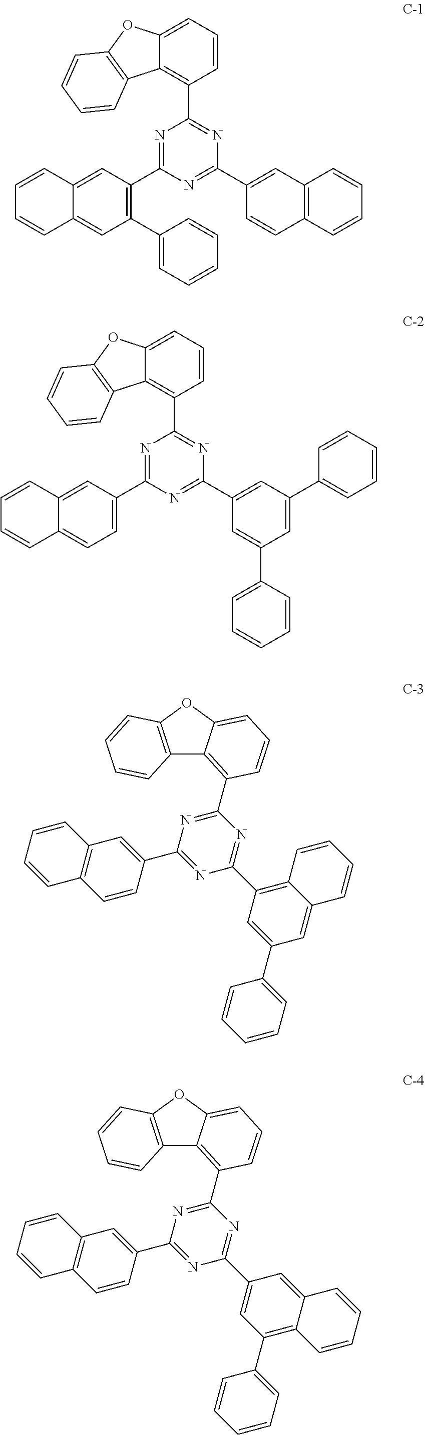 [SMILES: c1ccc(-c2cc3ccccc3cc2-c2nc(-c3ccc4ccccc4c3)nc(-c3cccc4oc5ccccc5c34)n2)cc1 ; c1ccc(-c2cc(-c3ccccc3)cc(-c3nc(-c4ccc5ccccc5c4)nc(-c4cccc5oc6ccccc6c45)n3)c2)cc1 ; c1ccc(-c2cc(-c3nc(-c4ccc5ccccc5c4)nc(-c4cccc5oc6ccccc6c45)n3)c3ccccc3c2)cc1 ; c1ccc(-c2cc(-c3nc(-c4ccc5ccccc5c4)nc(-c4cccc5oc6ccccc6c45)n3)cc3ccccc23)cc1]

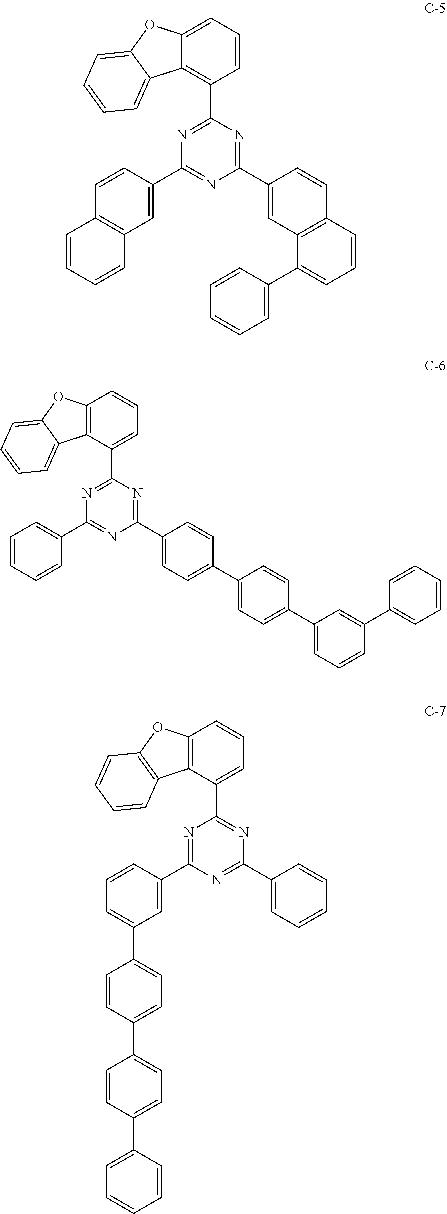 [SMILES: c1ccc(-c2cccc3ccc(-c4nc(-c5ccc6ccccc6c5)nc(-c5cccc6oc7ccccc7c56)n4)cc23)cc1 ; c1ccc(-c2cccc(-c3ccc(-c4ccc(-c5nc(-c6ccccc6)nc(-c6cccc7oc8ccccc8c67)n5)cc4)cc3)c2)cc1 ; c1ccc(-c2ccc(-c3ccc(-c4cccc(-c5nc(-c6ccccc6)nc(-c6cccc7oc8ccccc8c67)n5)c4)cc3)cc2)cc1]

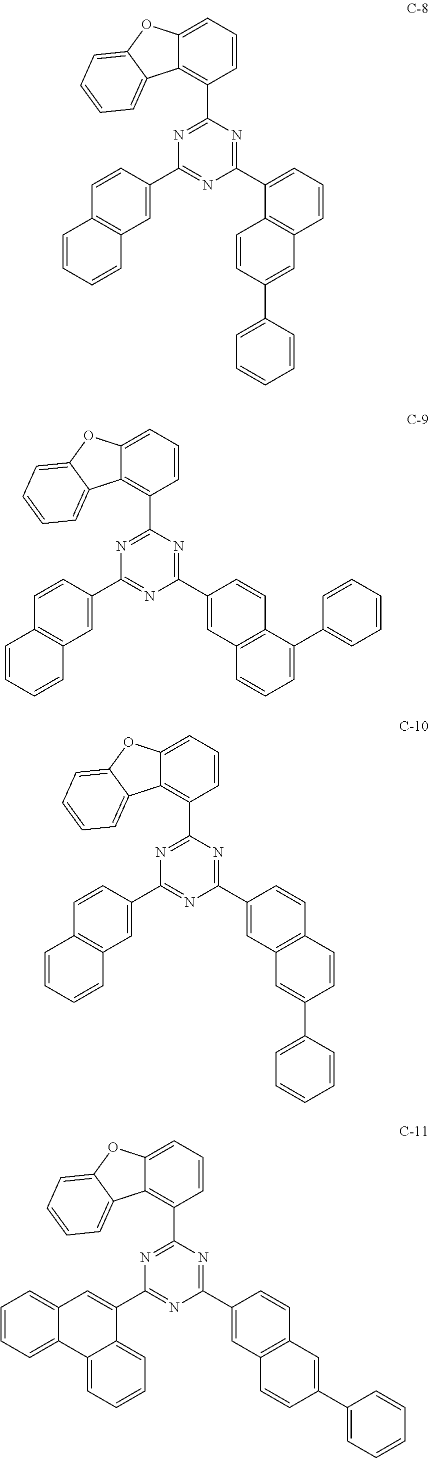 [SMILES: c1ccc(-c2ccc3c(-c4nc(-c5ccc6ccccc6c5)nc(-c5cccc6oc7ccccc7c56)n4)cccc3c2)cc1 ; c1ccc(-c2cccc3cc(-c4nc(-c5ccc6ccccc6c5)nc(-c5cccc6oc7ccccc7c56)n4)ccc23)cc1 ; c1ccc(-c2ccc3ccc(-c4nc(-c5ccc6ccccc6c5)nc(-c5cccc6oc7ccccc7c56)n4)cc3c2)cc1 ; c1ccc(-c2ccc3cc(-c4nc(-c5cc6ccccc6c6ccccc56)nc(-c5cccc6oc7ccccc7c56)n4)ccc3c2)cc1]

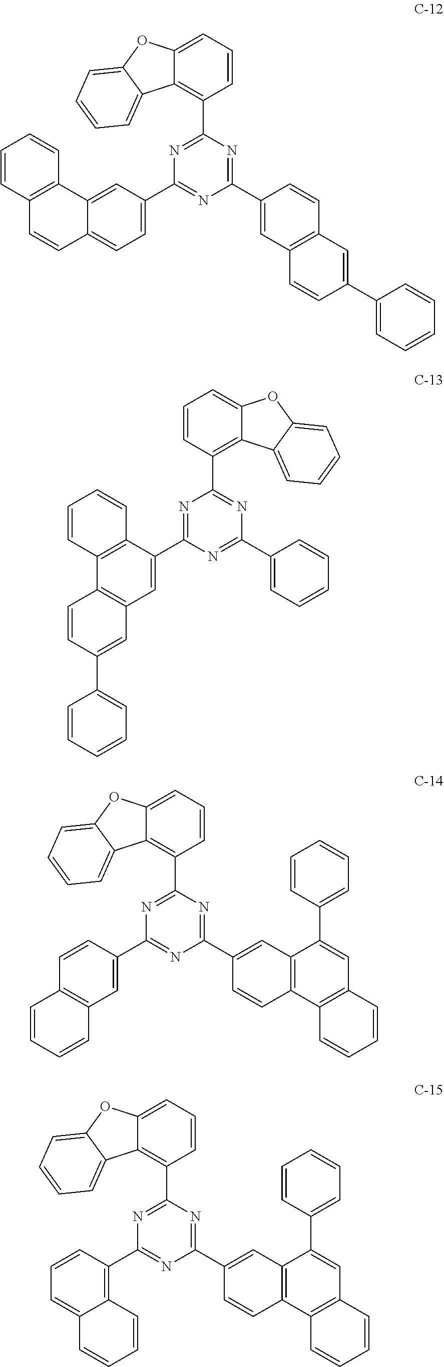

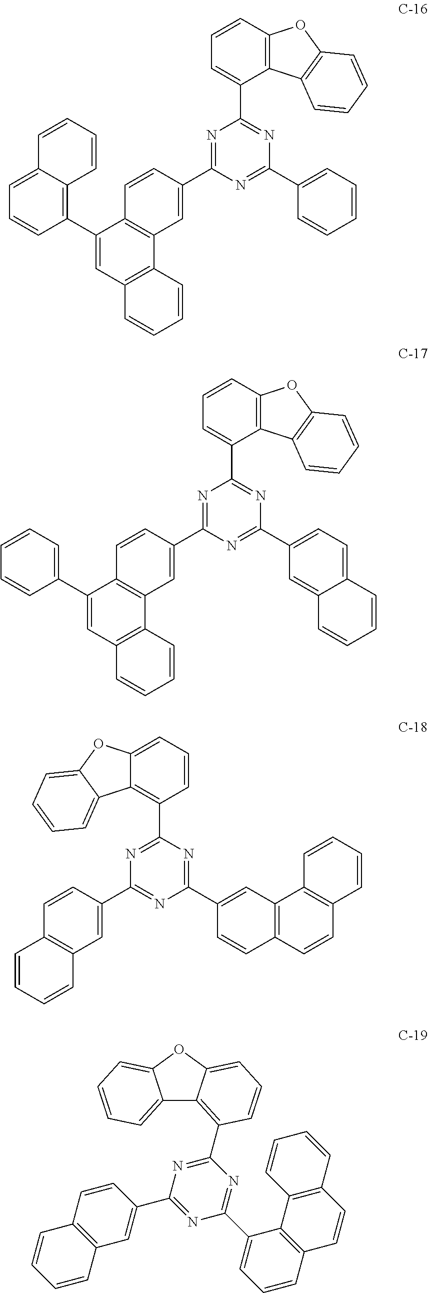

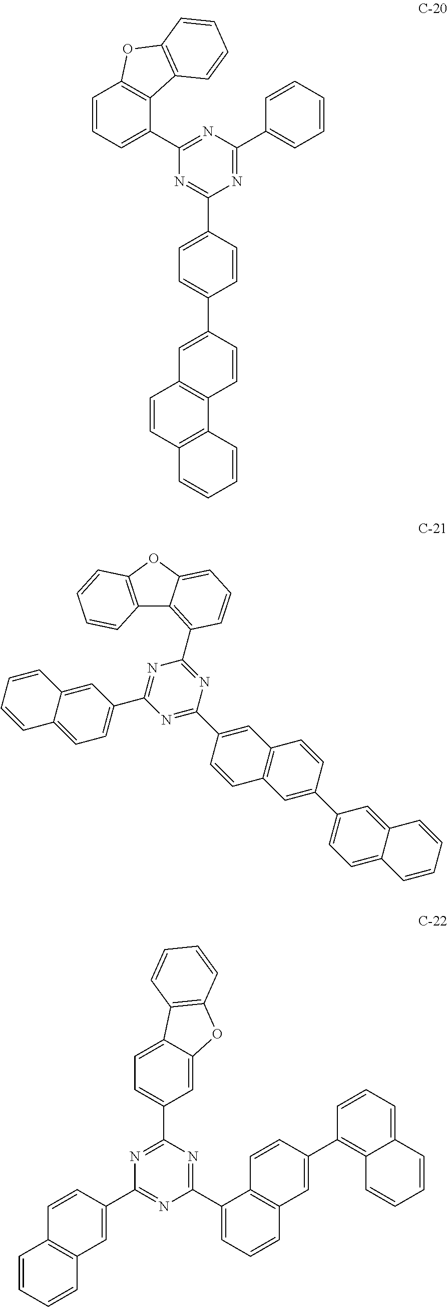 [SMILES: c1ccc(-c2nc(-c3ccc(-c4ccc5c(ccc6ccccc65)c4)cc3)nc(-c3cccc4oc5ccccc5c34)n2)cc1 ; c1ccc2cc(-c3ccc4cc(-c5nc(-c6ccc7ccccc7c6)nc(-c6cccc7oc8ccccc8c67)n5)ccc4c3)ccc2c1 ; c1ccc2cc(-c3nc(-c4ccc5c(c4)oc4ccccc45)nc(-c4cccc5cc(-c6cccc7ccccc67)ccc45)n3)ccc2c1]

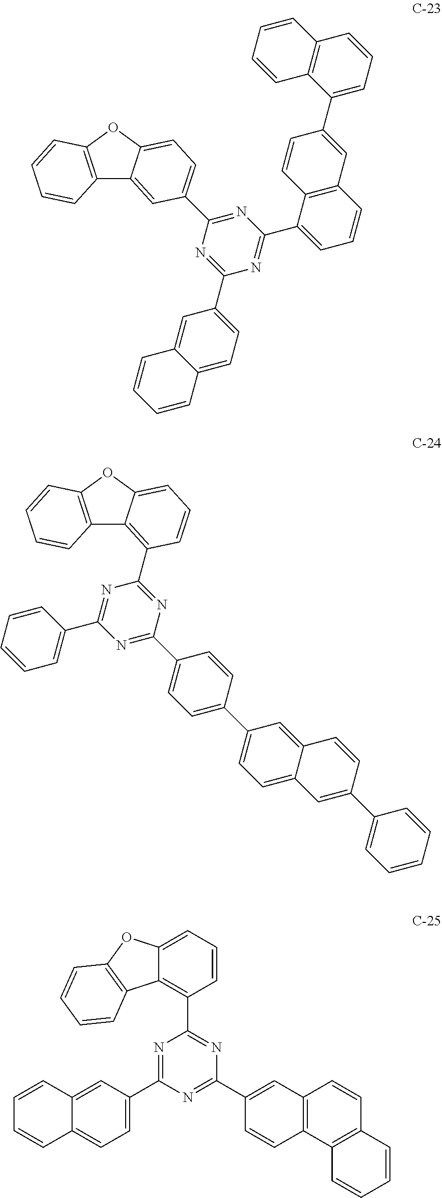 [SMILES: c1ccc2cc(-c3nc(-c4ccc5oc6ccccc6c5c4)nc(-c4cccc5cc(-c6cccc7ccccc67)ccc45)n3)ccc2c1 ; c1ccc(-c2ccc3cc(-c4ccc(-c5nc(-c6ccccc6)nc(-c6cccc7oc8ccccc8c67)n5)cc4)ccc3c2)cc1 ; c1ccc2cc(-c3nc(-c4ccc5c(ccc6ccccc65)c4)nc(-c4cccc5oc6ccccc6c45)n3)ccc2c1]

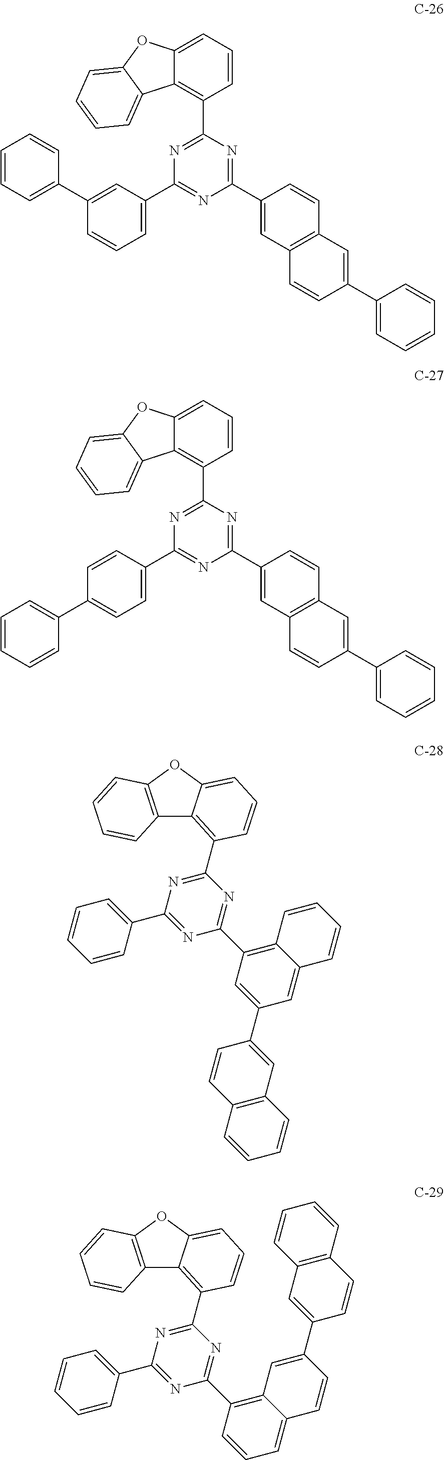 [SMILES: c1ccc(-c2cccc(-c3nc(-c4ccc5cc(-c6ccccc6)ccc5c4)nc(-c4cccc5oc6ccccc6c45)n3)c2)cc1 ; c1ccc(-c2ccc(-c3nc(-c4ccc5cc(-c6ccccc6)ccc5c4)nc(-c4cccc5oc6ccccc6c45)n3)cc2)cc1 ; c1ccc(-c2nc(-c3cc(-c4ccc5ccccc5c4)cc4ccccc34)nc(-c3cccc4oc5ccccc5c34)n2)cc1 ; c1ccc(-c2nc(-c3cccc4ccc(-c5ccc6ccccc6c5)cc34)nc(-c3cccc4oc5ccccc5c34)n2)cc1]

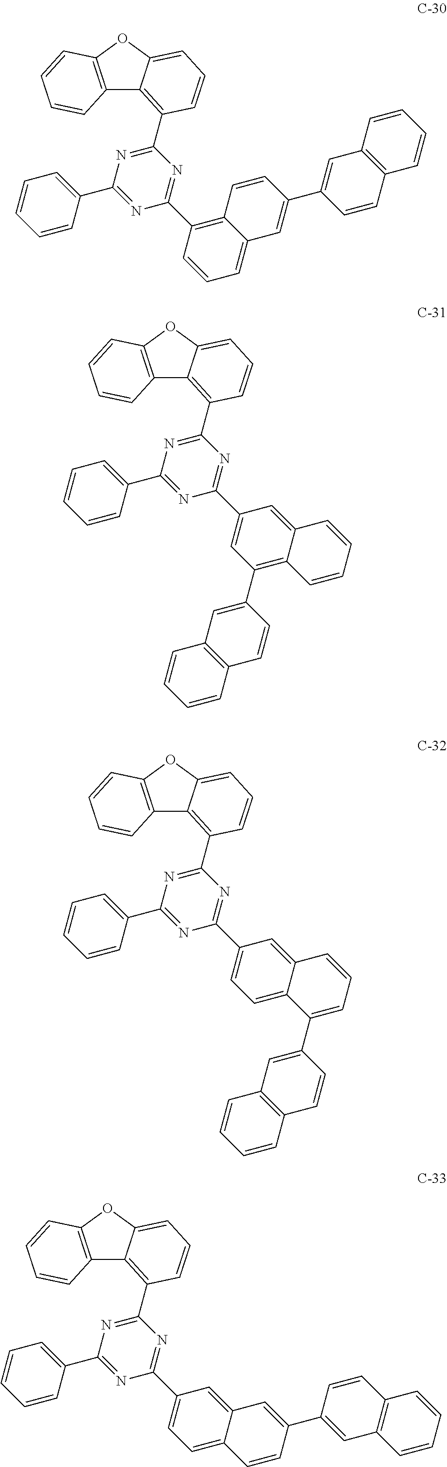 [SMILES: c1ccc(-c2nc(-c3cccc4cc(-c5ccc6ccccc6c5)ccc34)nc(-c3cccc4oc5ccccc5c34)n2)cc1 ; c1ccc(-c2nc(-c3cc(-c4ccc5ccccc5c4)c4ccccc4c3)nc(-c3cccc4oc5ccccc5c34)n2)cc1 ; c1ccc(-c2nc(-c3ccc4c(-c5ccc6ccccc6c5)cccc4c3)nc(-c3cccc4oc5ccccc5c34)n2)cc1 ; c1ccc(-c2nc(-c3ccc4ccc(-c5ccc6ccccc6c5)cc4c3)nc(-c3cccc4oc5ccccc5c34)n2)cc1]

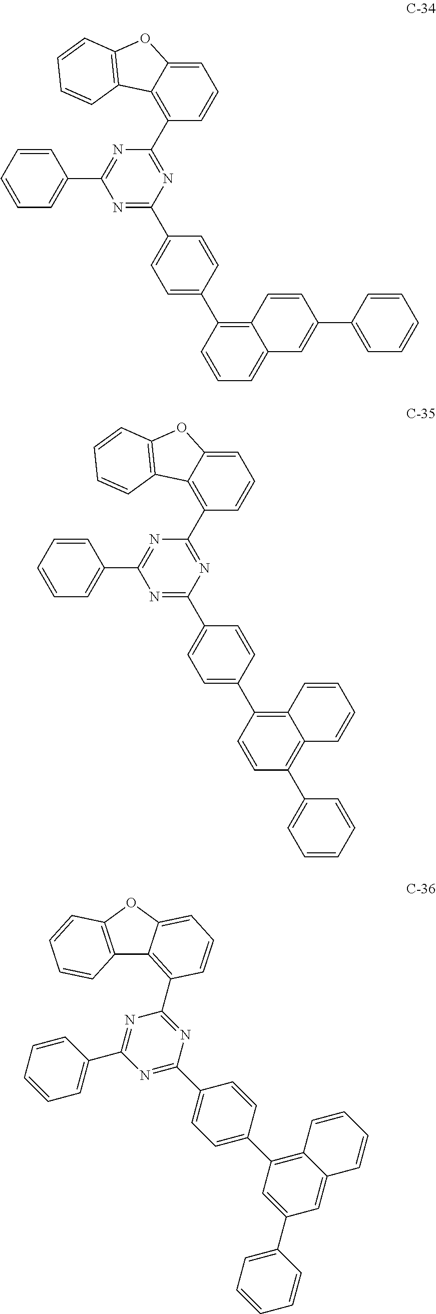 [SMILES: c1ccc(-c2ccc3c(-c4ccc(-c5nc(-c6ccccc6)nc(-c6cccc7oc8ccccc8c67)n5)cc4)cccc3c2)cc1 ; c1ccc(-c2nc(-c3ccc(-c4ccc(-c5ccccc5)c5ccccc45)cc3)nc(-c3cccc4oc5ccccc5c34)n2)cc1 ; c1ccc(-c2cc(-c3ccc(-c4nc(-c5ccccc5)nc(-c5cccc6oc7ccccc7c56)n4)cc3)c3ccccc3c2)cc1]

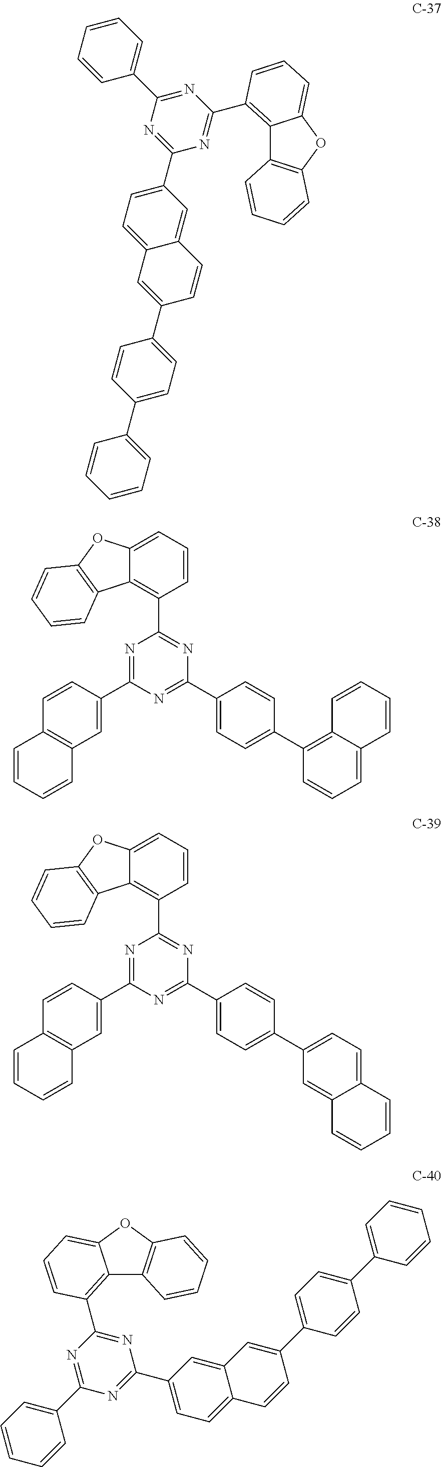

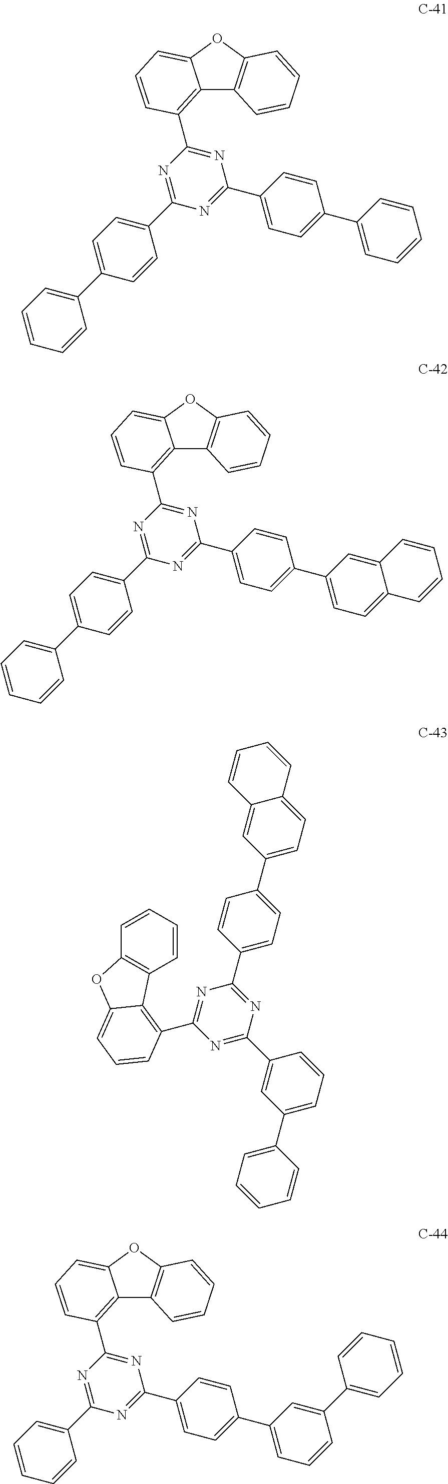 [SMILES: c1ccc(-c2ccc(-c3nc(-c4ccc(-c5ccccc5)cc4)nc(-c4cccc5oc6ccccc6c45)n3)cc2)cc1 ; c1ccc(-c2ccc(-c3nc(-c4ccc(-c5ccc6ccccc6c5)cc4)nc(-c4cccc5oc6ccccc6c45)n3)cc2)cc1 ; c1ccc(-c2cccc(-c3nc(-c4ccc(-c5ccc6ccccc6c5)cc4)nc(-c4cccc5oc6ccccc6c45)n3)c2)cc1 ; c1ccc(-c2cccc(-c3ccc(-c4nc(-c5ccccc5)nc(-c5cccc6oc7ccccc7c56)n4)cc3)c2)cc1]

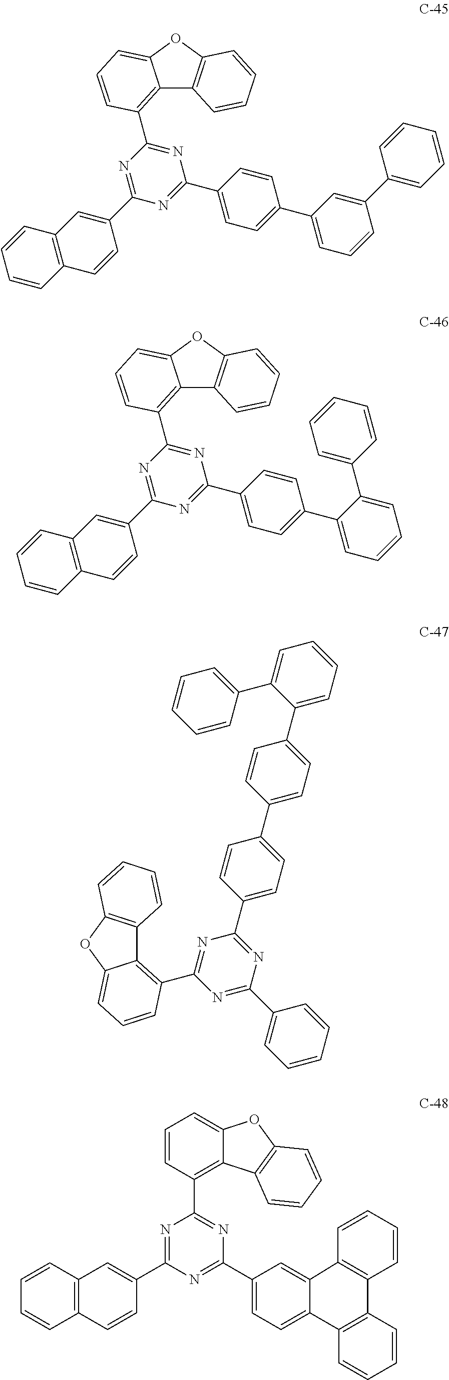 [SMILES: c1ccc(-c2cccc(-c3ccc(-c4nc(-c5ccc6ccccc6c5)nc(-c5cccc6oc7ccccc7c56)n4)cc3)c2)cc1 ; c1ccc(-c2ccccc2-c2ccc(-c3nc(-c4ccc5ccccc5c4)nc(-c4cccc5oc6ccccc6c45)n3)cc2)cc1 ; c1ccc(-c2nc(-c3ccc(-c4ccc(-c5ccccc5-c5ccccc5)cc4)cc3)nc(-c3cccc4oc5ccccc5c34)n2)cc1 ; c1ccc2cc(-c3nc(-c4ccc5c6ccccc6c6ccccc6c5c4)nc(-c4cccc5oc6ccccc6c45)n3)ccc2c1]

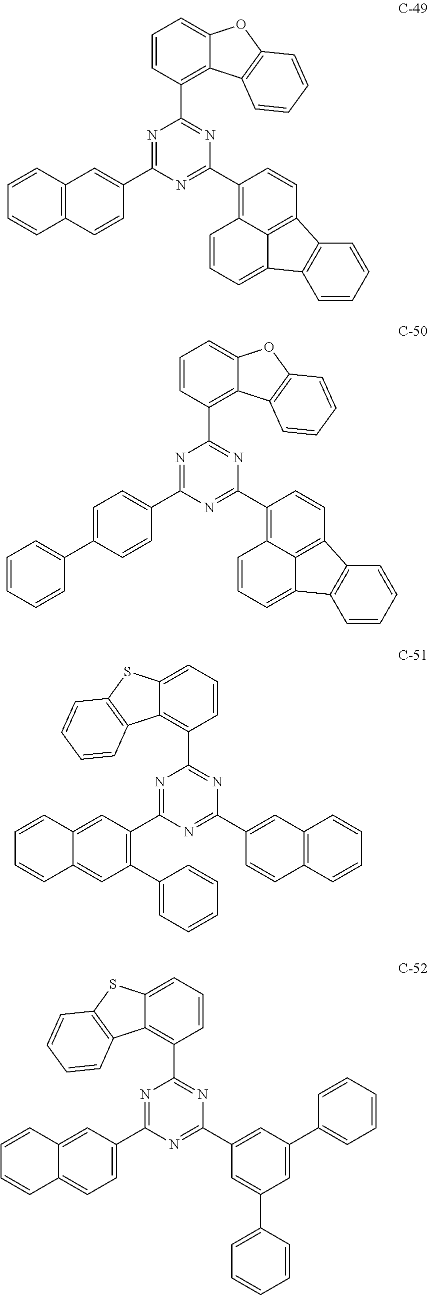 [SMILES: c1ccc2c(c1)-c1cccc3c(-c4nc(-c5ccc6ccccc6c5)nc(-c5cccc6oc7ccccc7c56)n4)ccc-2c13 ; c1ccc(-c2ccc(-c3nc(-c4ccc5c6c(cccc46)-c4ccccc4-5)nc(-c4cccc5oc6ccccc6c45)n3)cc2)cc1 ; c1ccc(-c2cc3ccccc3cc2-c2nc(-c3ccc4ccccc4c3)nc(-c3cccc4sc5ccccc5c34)n2)cc1 ; c1ccc(-c2cc(-c3ccccc3)cc(-c3nc(-c4ccc5ccccc5c4)nc(-c4cccc5sc6ccccc6c45)n3)c2)cc1]

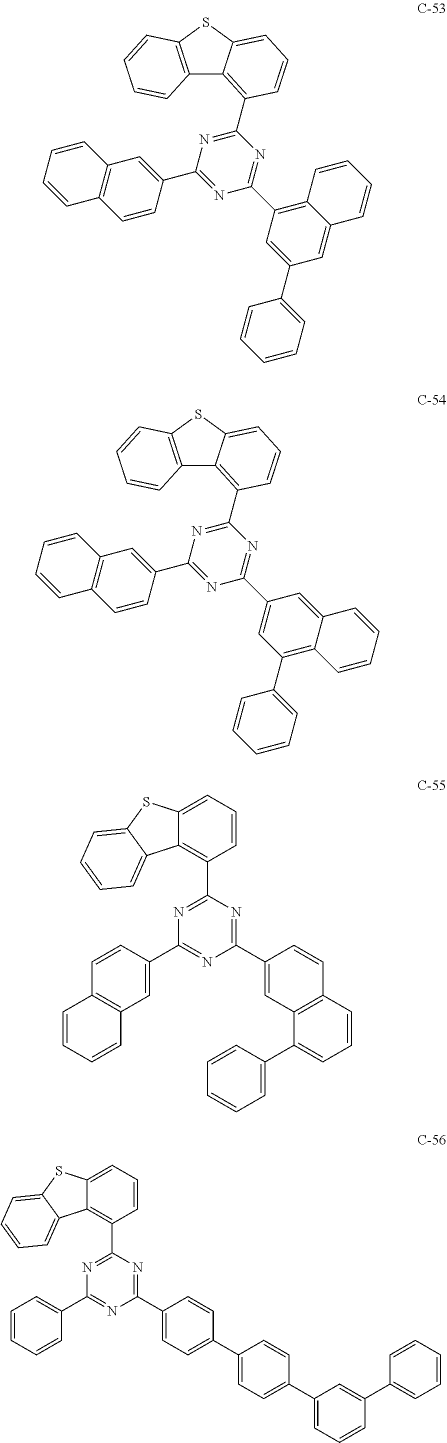 [SMILES: c1ccc(-c2cc(-c3nc(-c4ccc5ccccc5c4)nc(-c4cccc5sc6ccccc6c45)n3)c3ccccc3c2)cc1 ; c1ccc(-c2cc(-c3nc(-c4ccc5ccccc5c4)nc(-c4cccc5sc6ccccc6c45)n3)cc3ccccc23)cc1 ; c1ccc(-c2cccc3ccc(-c4nc(-c5ccc6ccccc6c5)nc(-c5cccc6sc7ccccc7c56)n4)cc23)cc1 ; c1ccc(-c2cccc(-c3ccc(-c4ccc(-c5nc(-c6ccccc6)nc(-c6cccc7sc8ccccc8c67)n5)cc4)cc3)c2)cc1]

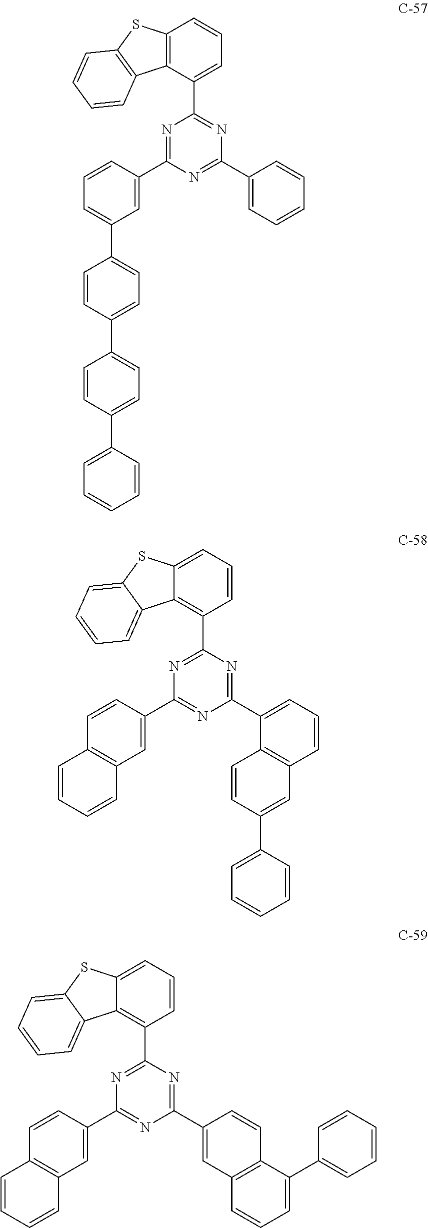 [SMILES: c1ccc(-c2ccc(-c3ccc(-c4cccc(-c5nc(-c6ccccc6)nc(-c6cccc7sc8ccccc8c67)n5)c4)cc3)cc2)cc1 ; c1ccc(-c2ccc3c(-c4nc(-c5ccc6ccccc6c5)nc(-c5cccc6sc7ccccc7c56)n4)cccc3c2)cc1 ; c1ccc(-c2cccc3cc(-c4nc(-c5ccc6ccccc6c5)nc(-c5cccc6sc7ccccc7c56)n4)ccc23)cc1]

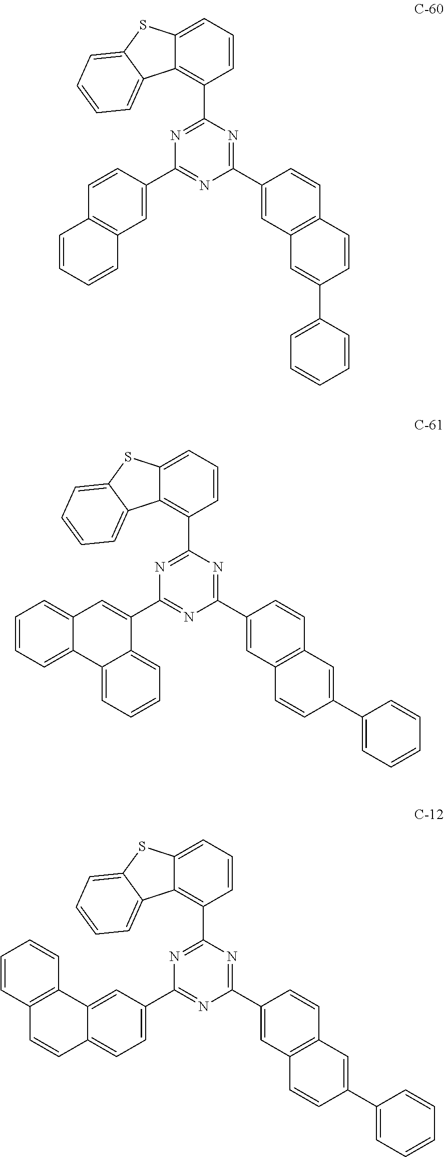 [SMILES: c1ccc(-c2ccc3ccc(-c4nc(-c5ccc6ccccc6c5)nc(-c5cccc6sc7ccccc7c56)n4)cc3c2)cc1 ; c1ccc(-c2ccc3cc(-c4nc(-c5cc6ccccc6c6ccccc56)nc(-c5cccc6sc7ccccc7c56)n4)ccc3c2)cc1 ; c1ccc(-c2ccc3cc(-c4nc(-c5ccc6ccc7ccccc7c6c5)nc(-c5cccc6sc7ccccc7c56)n4)ccc3c2)cc1]

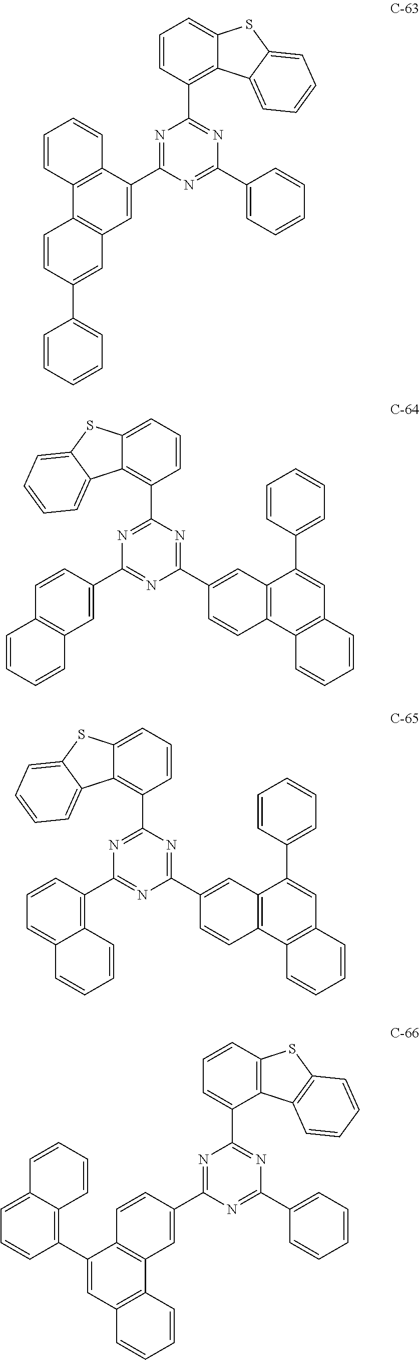

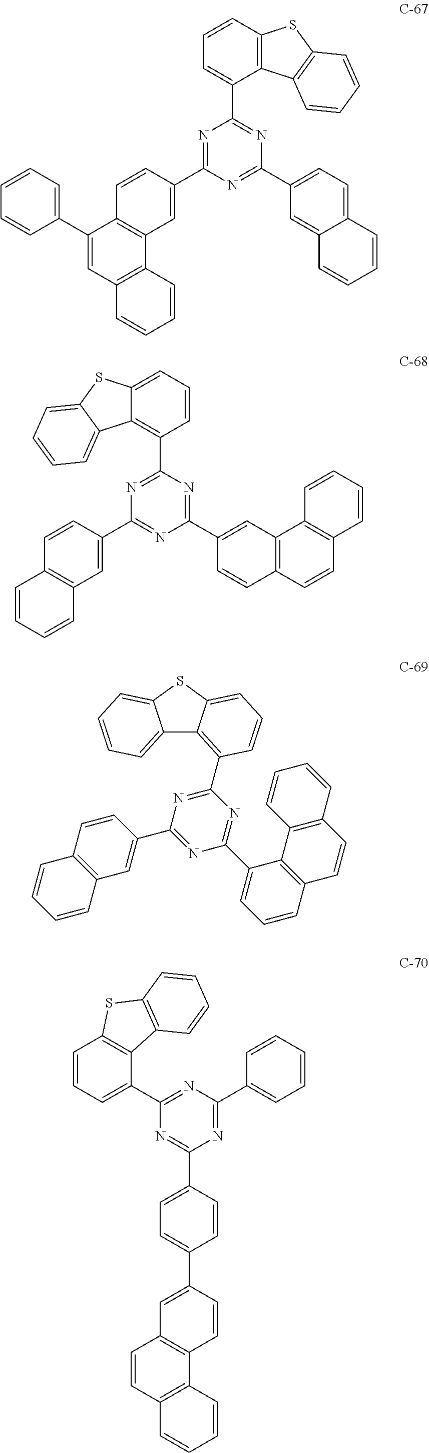

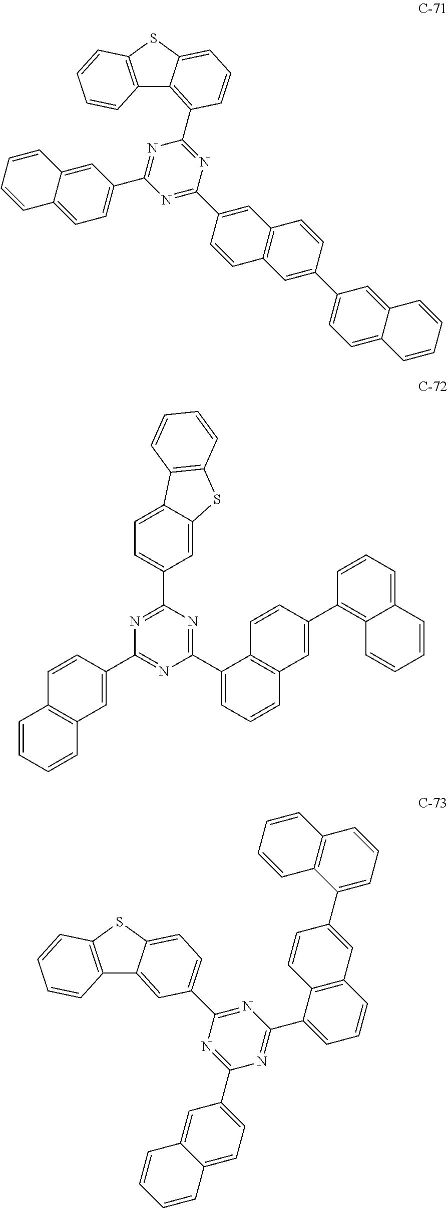 [SMILES: c1ccc2cc(-c3ccc4cc(-c5nc(-c6ccc7ccccc7c6)nc(-c6cccc7sc8ccccc8c67)n5)ccc4c3)ccc2c1 ; c1ccc2cc(-c3nc(-c4ccc5c(c4)sc4ccccc45)nc(-c4cccc5cc(-c6cccc7ccccc67)ccc45)n3)ccc2c1 ; c1ccc2cc(-c3nc(-c4ccc5sc6ccccc6c5c4)nc(-c4cccc5cc(-c6cccc7ccccc67)ccc45)n3)ccc2c1]

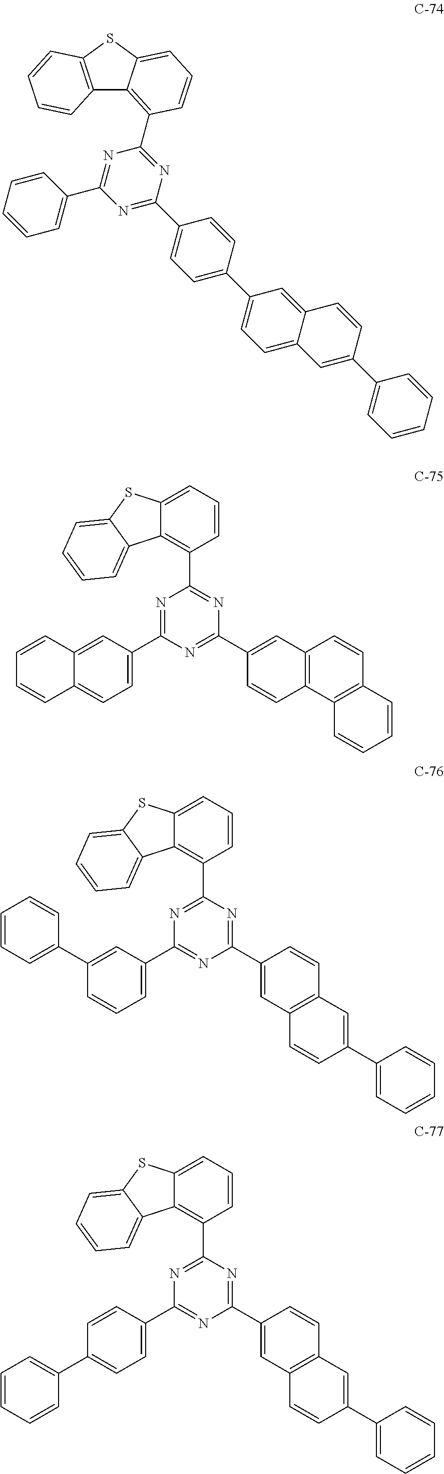 [SMILES: c1ccc(-c2ccc3cc(-c4ccc(-c5nc(-c6ccccc6)nc(-c6cccc7sc8ccccc8c67)n5)cc4)ccc3c2)cc1 ; c1ccc2cc(-c3nc(-c4ccc5c(ccc6ccccc65)c4)nc(-c4cccc5sc6ccccc6c45)n3)ccc2c1 ; c1ccc(-c2cccc(-c3nc(-c4ccc5cc(-c6ccccc6)ccc5c4)nc(-c4cccc5sc6ccccc6c45)n3)c2)cc1 ; c1ccc(-c2ccc(-c3nc(-c4ccc5cc(-c6ccccc6)ccc5c4)nc(-c4cccc5sc6ccccc6c45)n3)cc2)cc1]

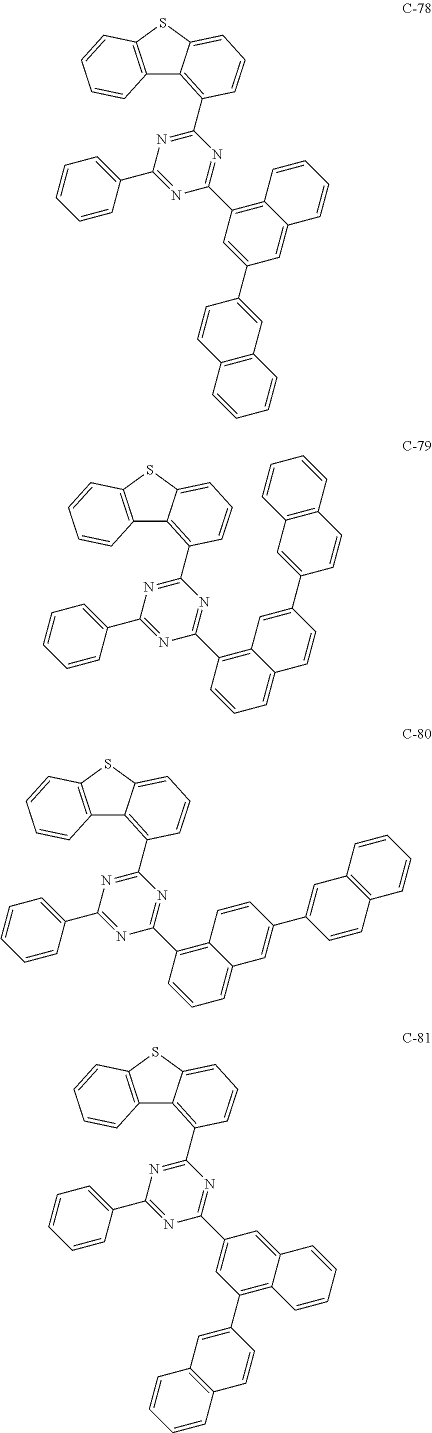 [SMILES: c1ccc(-c2nc(-c3cc(-c4ccc5ccccc5c4)cc4ccccc34)nc(-c3cccc4sc5ccccc5c34)n2)cc1 ; c1ccc(-c2nc(-c3cccc4ccc(-c5ccc6ccccc6c5)cc34)nc(-c3cccc4sc5ccccc5c34)n2)cc1 ; c1ccc(-c2nc(-c3cccc4cc(-c5ccc6ccccc6c5)ccc34)nc(-c3cccc4sc5ccccc5c34)n2)cc1 ; c1ccc(-c2nc(-c3cc(-c4ccc5ccccc5c4)c4ccccc4c3)nc(-c3cccc4sc5ccccc5c34)n2)cc1]

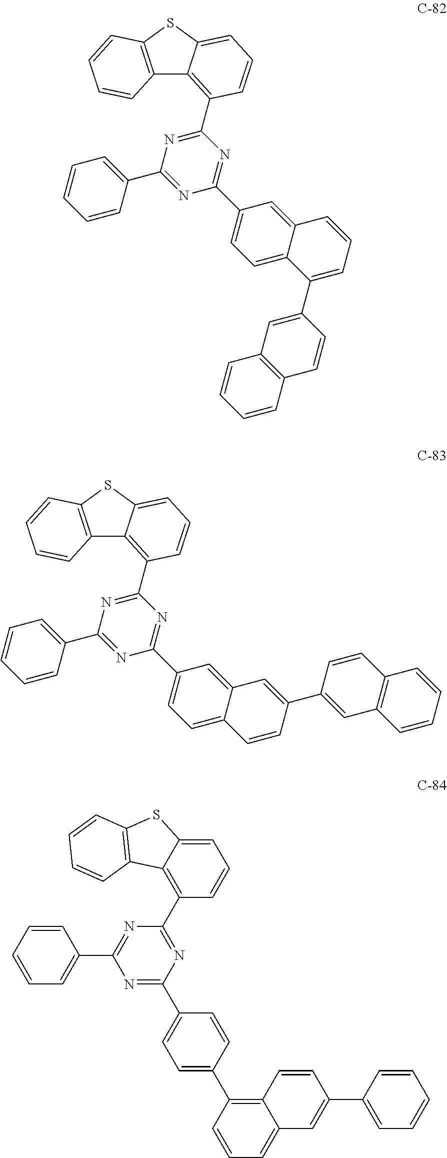 [SMILES: c1ccc(-c2nc(-c3ccc4c(-c5ccc6ccccc6c5)cccc4c3)nc(-c3cccc4sc5ccccc5c34)n2)cc1 ; c1ccc(-c2nc(-c3ccc4ccc(-c5ccc6ccccc6c5)cc4c3)nc(-c3cccc4sc5ccccc5c34)n2)cc1 ; c1ccc(-c2ccc3c(-c4ccc(-c5nc(-c6ccccc6)nc(-c6cccc7sc8ccccc8c67)n5)cc4)cccc3c2)cc1]

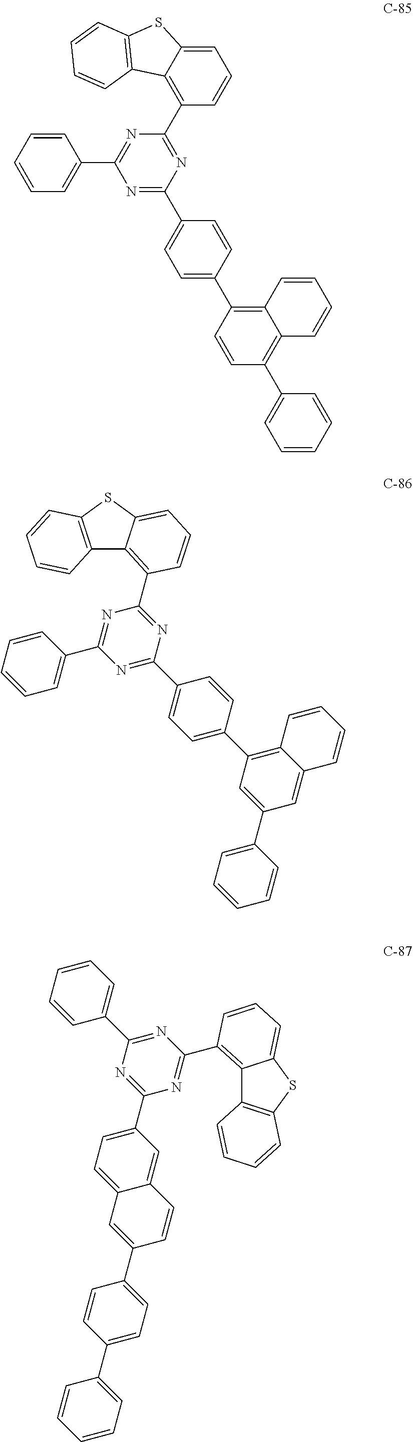 [SMILES: c1ccc(-c2nc(-c3ccc(-c4ccc(-c5ccccc5)c5ccccc45)cc3)nc(-c3cccc4sc5ccccc5c34)n2)cc1 ; c1ccc(-c2cc(-c3ccc(-c4nc(-c5ccccc5)nc(-c5cccc6sc7ccccc7c56)n4)cc3)c3ccccc3c2)cc1 ; c1ccc(-c2ccc(-c3ccc4cc(-c5nc(-c6ccccc6)nc(-c6cccc7sc8ccccc8c67)n5)ccc4c3)cc2)cc1]

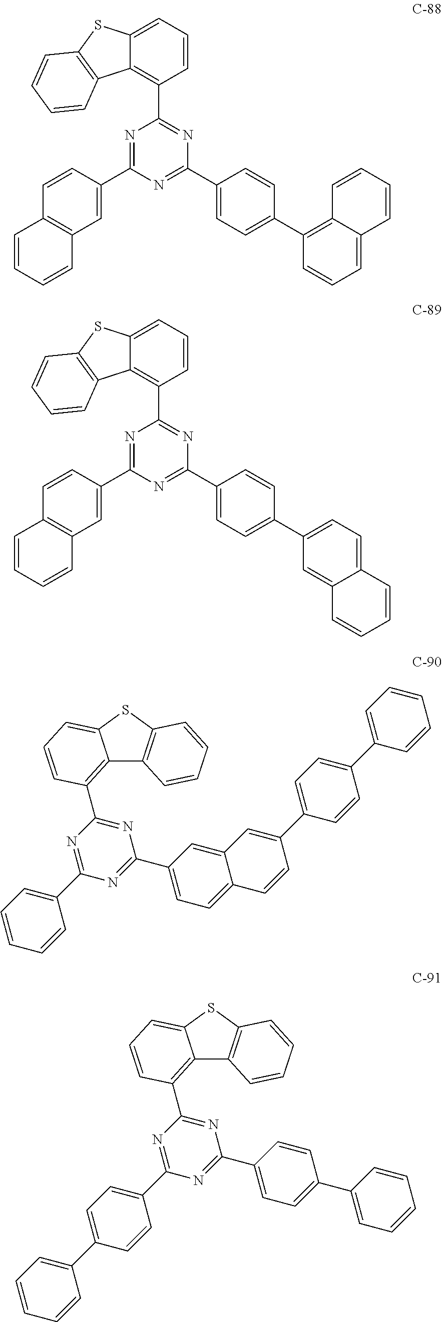 [SMILES: c1ccc2cc(-c3nc(-c4ccc(-c5cccc6ccccc56)cc4)nc(-c4cccc5sc6ccccc6c45)n3)ccc2c1 ; c1ccc2cc(-c3ccc(-c4nc(-c5ccc6ccccc6c5)nc(-c5cccc6sc7ccccc7c56)n4)cc3)ccc2c1 ; c1ccc(-c2ccc(-c3ccc4ccc(-c5nc(-c6ccccc6)nc(-c6cccc7sc8ccccc8c67)n5)cc4c3)cc2)cc1 ; c1ccc(-c2ccc(-c3nc(-c4ccc(-c5ccccc5)cc4)nc(-c4cccc5sc6ccccc6c45)n3)cc2)cc1]

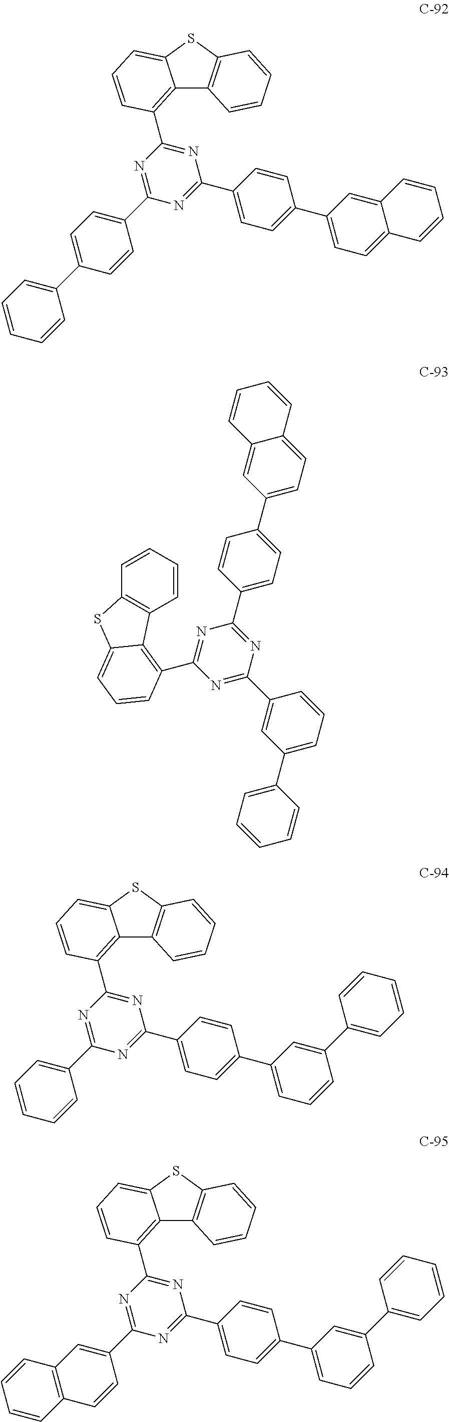 [SMILES: c1ccc(-c2ccc(-c3nc(-c4ccc(-c5ccc6ccccc6c5)cc4)nc(-c4cccc5sc6ccccc6c45)n3)cc2)cc1 ; c1ccc(-c2cccc(-c3nc(-c4ccc(-c5ccc6ccccc6c5)cc4)nc(-c4cccc5sc6ccccc6c45)n3)c2)cc1 ; c1ccc(-c2cccc(-c3ccc(-c4nc(-c5ccccc5)nc(-c5cccc6sc7ccccc7c56)n4)cc3)c2)cc1 ; c1ccc(-c2cccc(-c3ccc(-c4nc(-c5ccc6ccccc6c5)nc(-c5cccc6sc7ccccc7c56)n4)cc3)c2)cc1]

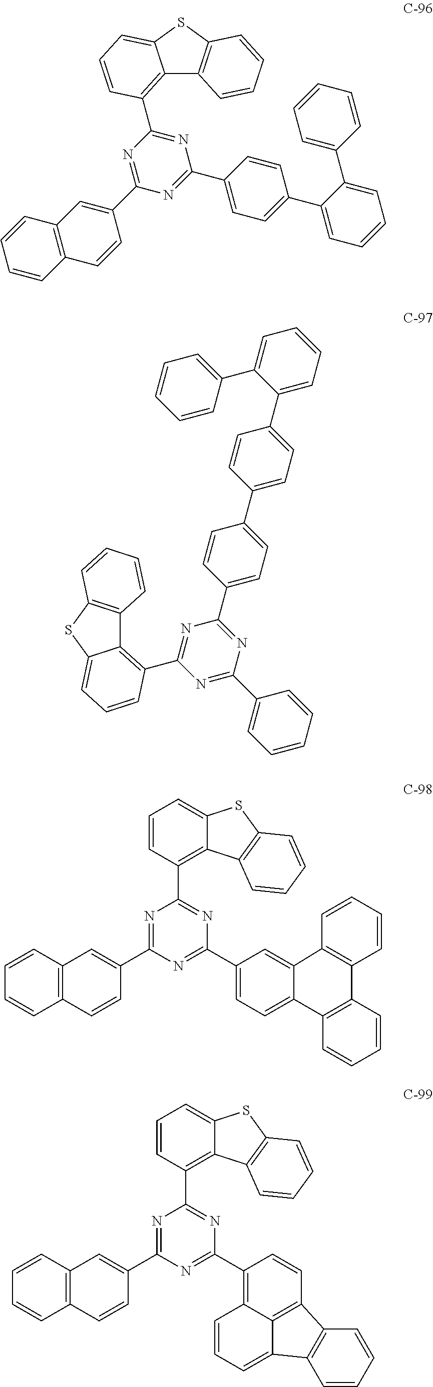 [SMILES: c1ccc(-c2ccccc2-c2ccc(-c3nc(-c4ccc5ccccc5c4)nc(-c4cccc5sc6ccccc6c45)n3)cc2)cc1 ; c1ccc(-c2nc(-c3ccc(-c4ccc(-c5ccccc5-c5ccccc5)cc4)cc3)nc(-c3cccc4sc5ccccc5c34)n2)cc1 ; c1ccc2cc(-c3nc(-c4ccc5c6ccccc6c6ccccc6c5c4)nc(-c4cccc5sc6ccccc6c45)n3)ccc2c1 ; c1ccc2c(c1)-c1cccc3c(-c4nc(-c5ccc6ccccc6c5)nc(-c5cccc6sc7ccccc7c56)n4)ccc-2c13]

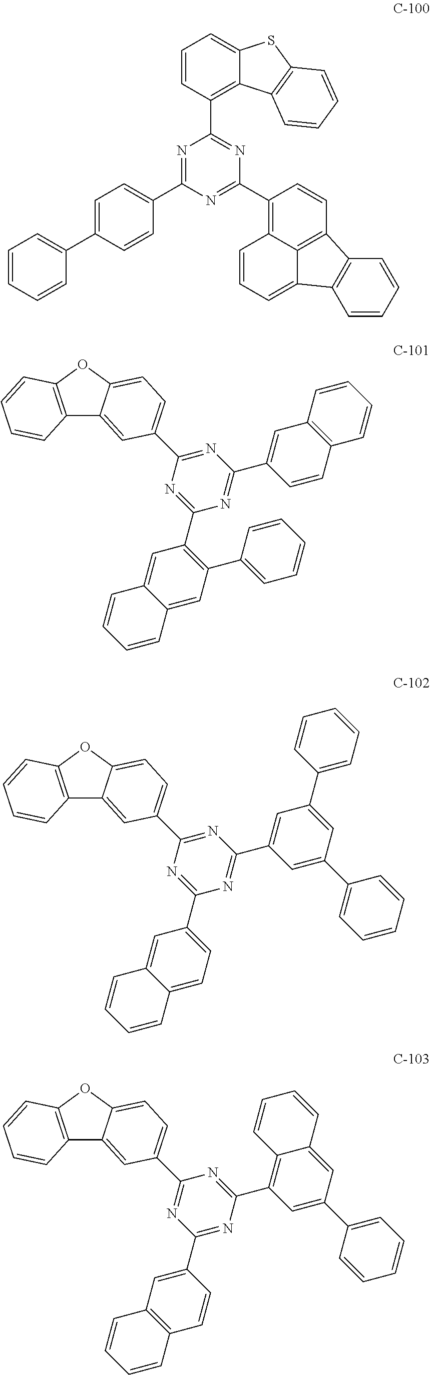 [SMILES: c1ccc(-c2ccc(-c3nc(-c4ccc5c6c(cccc46)-c4ccccc4-5)nc(-c4cccc5sc6ccccc6c45)n3)cc2)cc1 ; c1ccc(-c2cc3ccccc3cc2-c2nc(-c3ccc4ccccc4c3)nc(-c3ccc4oc5ccccc5c4c3)n2)cc1 ; c1ccc(-c2cc(-c3ccccc3)cc(-c3nc(-c4ccc5ccccc5c4)nc(-c4ccc5oc6ccccc6c5c4)n3)c2)cc1 ; c1ccc(-c2cc(-c3nc(-c4ccc5ccccc5c4)nc(-c4ccc5oc6ccccc6c5c4)n3)c3ccccc3c2)cc1]

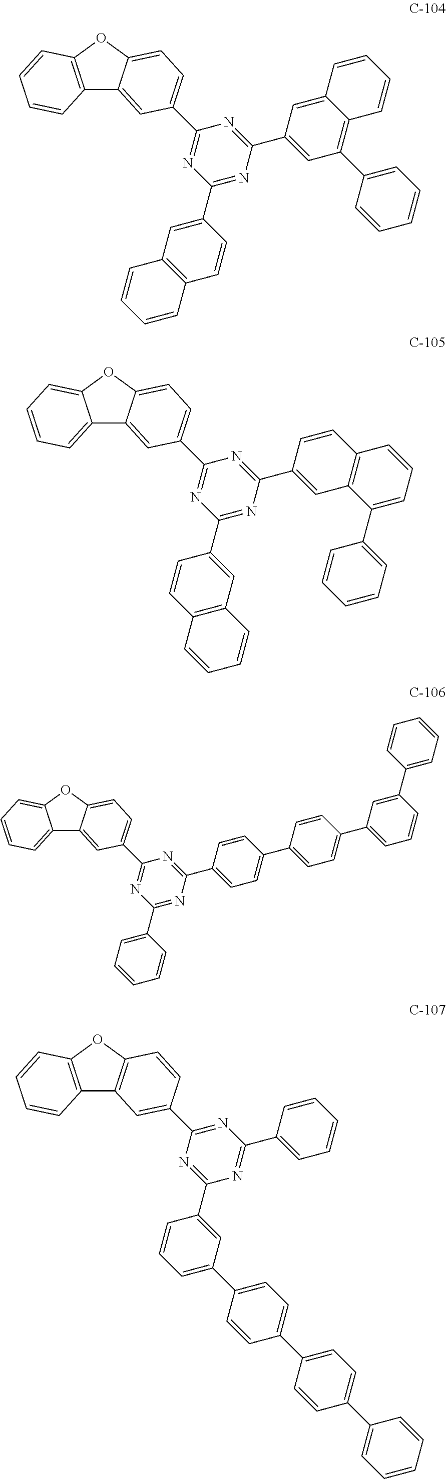 [SMILES: c1ccc(-c2cc(-c3nc(-c4ccc5ccccc5c4)nc(-c4ccc5oc6ccccc6c5c4)n3)cc3ccccc23)cc1 ; c1ccc(-c2cccc3ccc(-c4nc(-c5ccc6ccccc6c5)nc(-c5ccc6oc7ccccc7c6c5)n4)cc23)cc1 ; c1ccc(-c2cccc(-c3ccc(-c4ccc(-c5nc(-c6ccccc6)nc(-c6ccc7oc8ccccc8c7c6)n5)cc4)cc3)c2)cc1 ; c1ccc(-c2ccc(-c3ccc(-c4cccc(-c5nc(-c6ccccc6)nc(-c6ccc7oc8ccccc8c7c6)n5)c4)cc3)cc2)cc1]

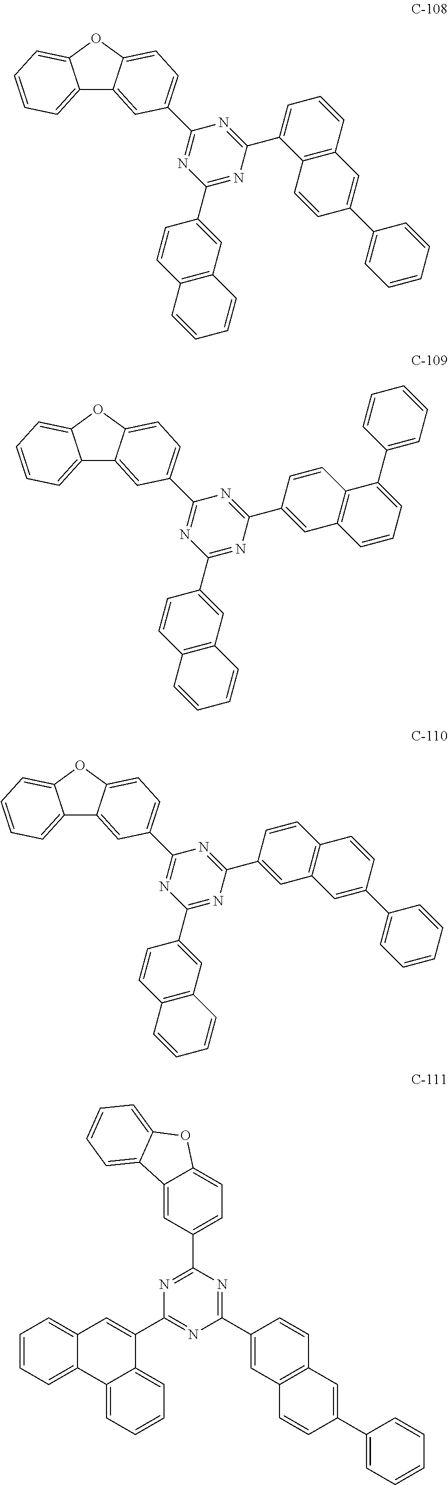 [SMILES: c1ccc(-c2ccc3c(-c4nc(-c5ccc6ccccc6c5)nc(-c5ccc6oc7ccccc7c6c5)n4)cccc3c2)cc1 ; c1ccc(-c2cccc3cc(-c4nc(-c5ccc6ccccc6c5)nc(-c5ccc6oc7ccccc7c6c5)n4)ccc23)cc1 ; c1ccc(-c2ccc3ccc(-c4nc(-c5ccc6ccccc6c5)nc(-c5ccc6oc7ccccc7c6c5)n4)cc3c2)cc1 ; c1ccc(-c2ccc3cc(-c4nc(-c5ccc6oc7ccccc7c6c5)nc(-c5cc6ccccc6c6ccccc56)n4)ccc3c2)cc1]

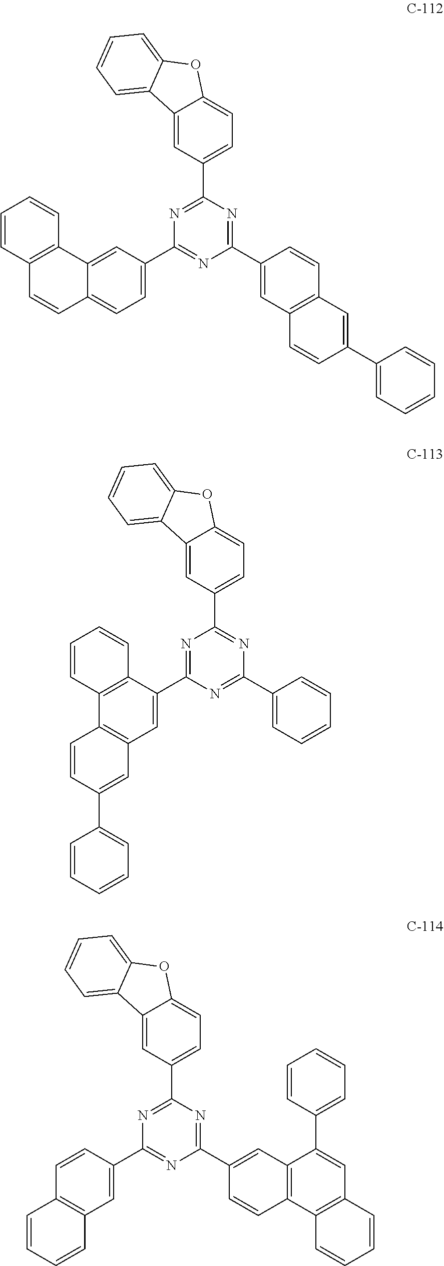

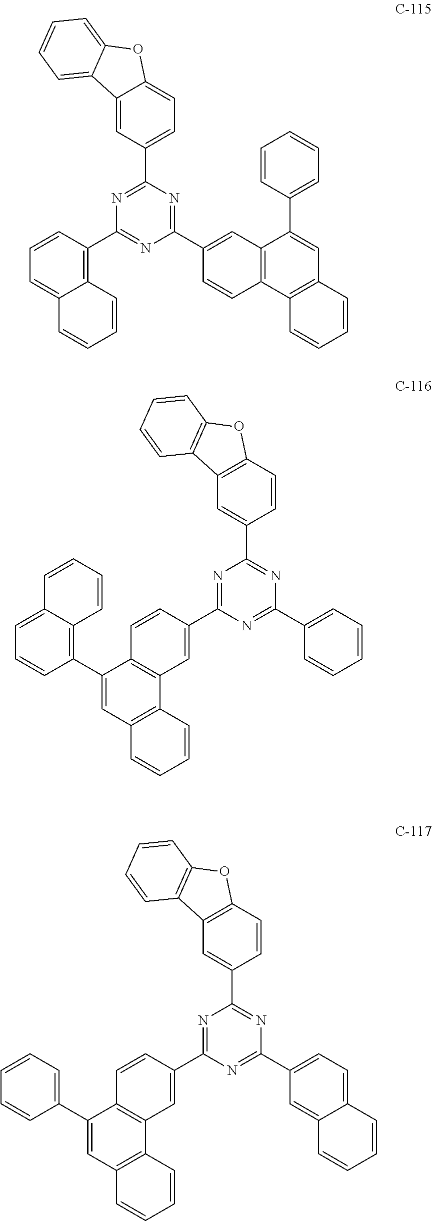 [SMILES: c1ccc(-c2cc3ccccc3c3ccc(-c4nc(-c5ccc6oc7ccccc7c6c5)nc(-c5cccc6ccccc56)n4)cc23)cc1 ; c1ccc(-c2nc(-c3ccc4oc5ccccc5c4c3)nc(-c3ccc4c(-c5cccc6ccccc56)cc5ccccc5c4c3)n2)cc1 ; c1ccc(-c2cc3ccccc3c3cc(-c4nc(-c5ccc6ccccc6c5)nc(-c5ccc6oc7ccccc7c6c5)n4)ccc23)cc1]

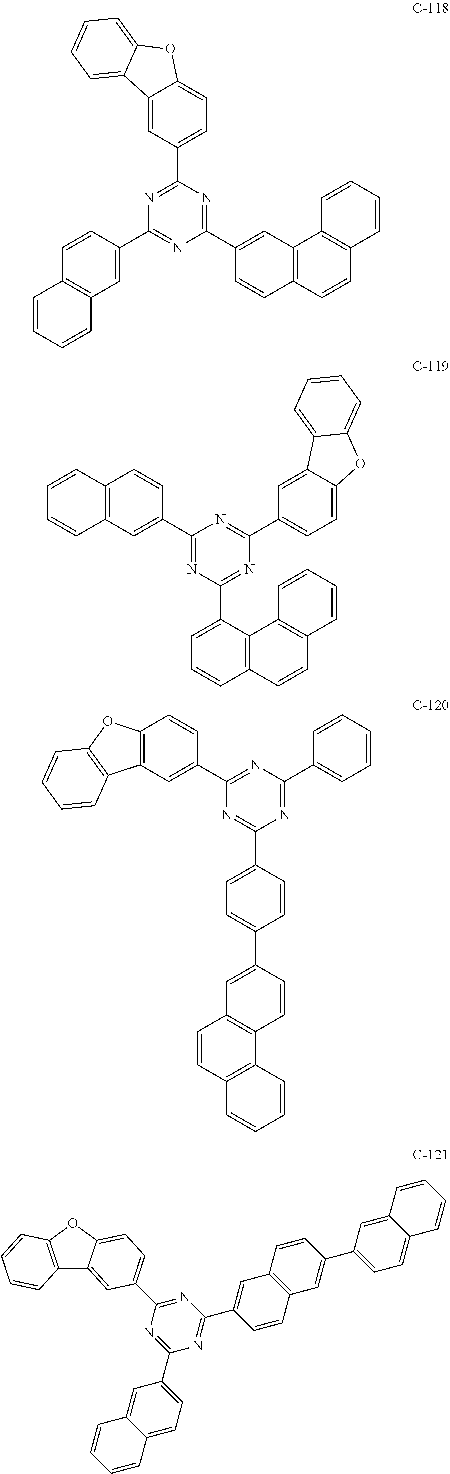 [SMILES: c1ccc2cc(-c3nc(-c4ccc5ccc6ccccc6c5c4)nc(-c4ccc5oc6ccccc6c5c4)n3)ccc2c1 ; c1ccc2cc(-c3nc(-c4ccc5oc6ccccc6c5c4)nc(-c4cccc5ccc6ccccc6c45)n3)ccc2c1 ; c1ccc(-c2nc(-c3ccc(-c4ccc5c(ccc6ccccc65)c4)cc3)nc(-c3ccc4oc5ccccc5c4c3)n2)cc1 ; c1ccc2cc(-c3ccc4cc(-c5nc(-c6ccc7ccccc7c6)nc(-c6ccc7oc8ccccc8c7c6)n5)ccc4c3)ccc2c1]

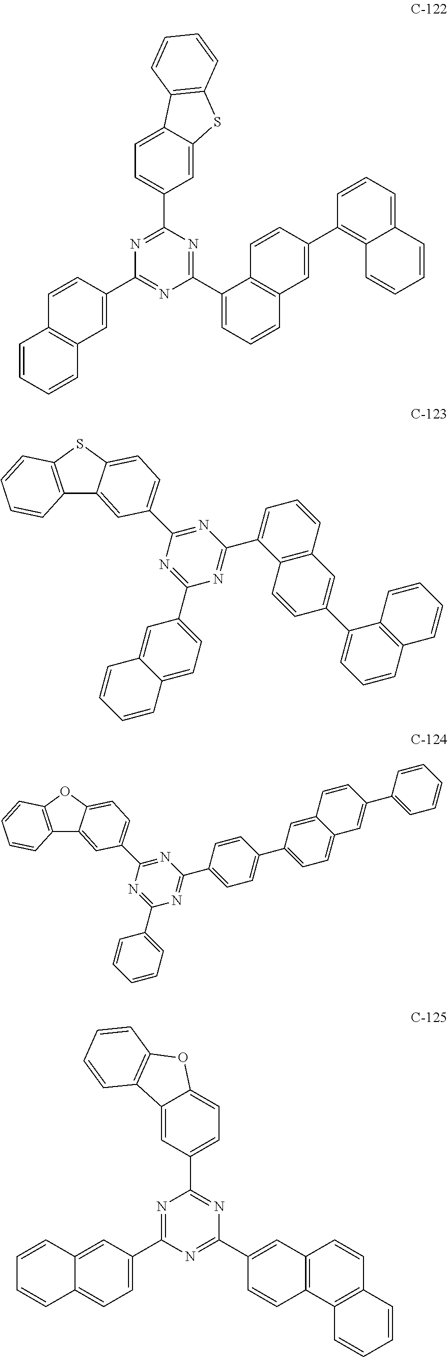

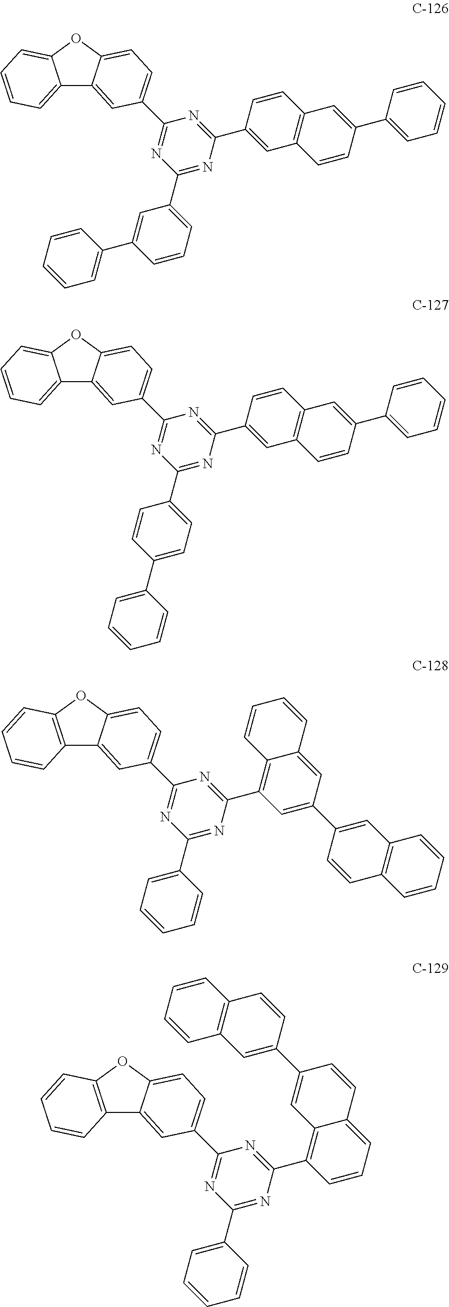 [SMILES: c1ccc(-c2cccc(-c3nc(-c4ccc5cc(-c6ccccc6)ccc5c4)nc(-c4ccc5oc6ccccc6c5c4)n3)c2)cc1 ; c1ccc(-c2ccc(-c3nc(-c4ccc5cc(-c6ccccc6)ccc5c4)nc(-c4ccc5oc6ccccc6c5c4)n3)cc2)cc1 ; c1ccc(-c2nc(-c3ccc4oc5ccccc5c4c3)nc(-c3cc(-c4ccc5ccccc5c4)cc4ccccc34)n2)cc1 ; c1ccc(-c2nc(-c3ccc4oc5ccccc5c4c3)nc(-c3cccc4ccc(-c5ccc6ccccc6c5)cc34)n2)cc1]

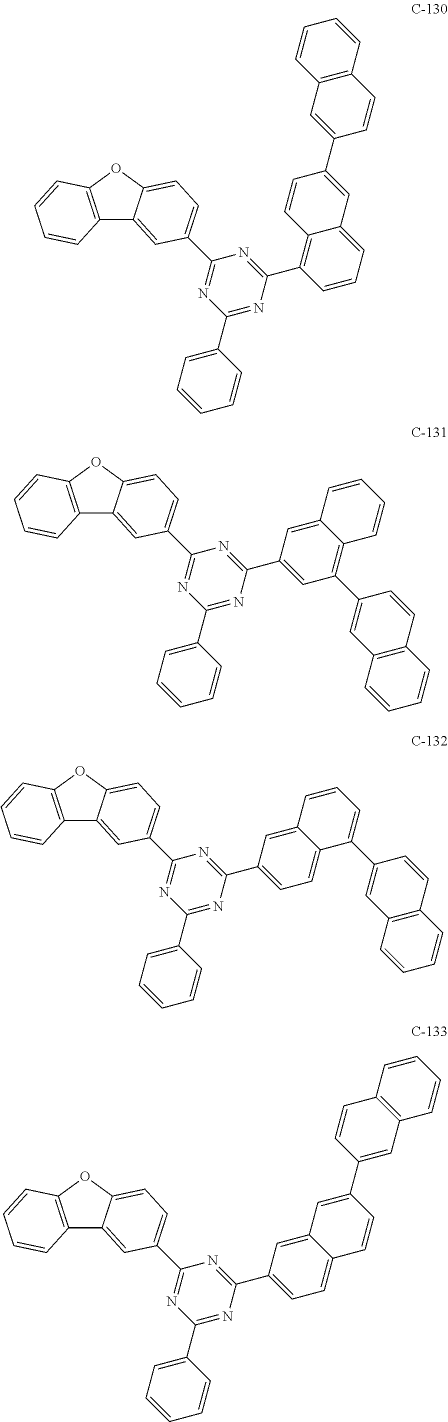 [SMILES: c1ccc(-c2nc(-c3ccc4oc5ccccc5c4c3)nc(-c3cccc4cc(-c5ccc6ccccc6c5)ccc34)n2)cc1 ; c1ccc(-c2nc(-c3cc(-c4ccc5ccccc5c4)c4ccccc4c3)nc(-c3ccc4oc5ccccc5c4c3)n2)cc1 ; c1ccc(-c2nc(-c3ccc4c(-c5ccc6ccccc6c5)cccc4c3)nc(-c3ccc4oc5ccccc5c4c3)n2)cc1 ; c1ccc(-c2nc(-c3ccc4ccc(-c5ccc6ccccc6c5)cc4c3)nc(-c3ccc4oc5ccccc5c4c3)n2)cc1]

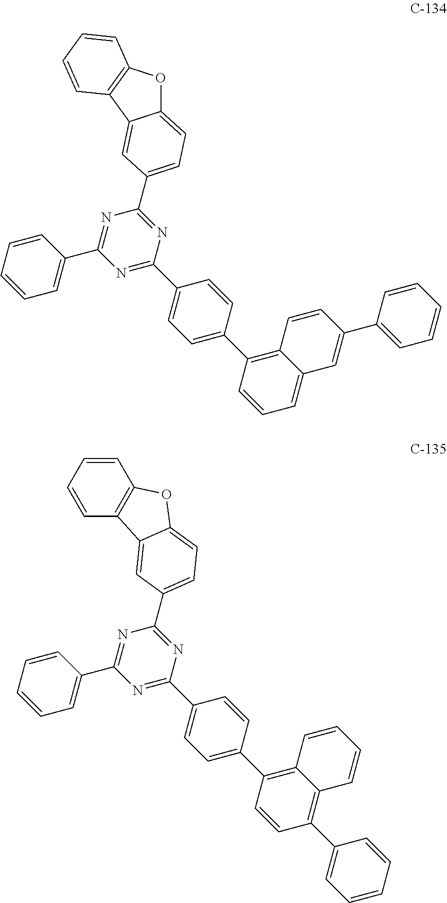 [SMILES: c1ccc(-c2ccc3c(-c4ccc(-c5nc(-c6ccccc6)nc(-c6ccc7oc8ccccc8c7c6)n5)cc4)cccc3c2)cc1 ; c1ccc(-c2nc(-c3ccc(-c4ccc(-c5ccccc5)c5ccccc45)cc3)nc(-c3ccc4oc5ccccc5c4c3)n2)cc1]

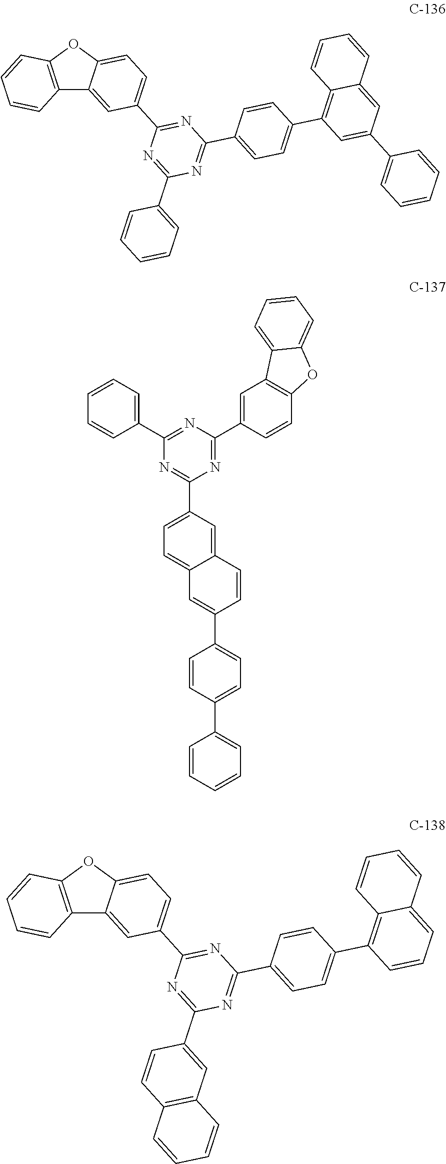 [SMILES: c1ccc(-c2cc(-c3ccc(-c4nc(-c5ccccc5)nc(-c5ccc6oc7ccccc7c6c5)n4)cc3)c3ccccc3c2)cc1 ; c1ccc(-c2ccc(-c3ccc4cc(-c5nc(-c6ccccc6)nc(-c6ccc7oc8ccccc8c7c6)n5)ccc4c3)cc2)cc1 ; c1ccc2cc(-c3nc(-c4ccc(-c5cccc6ccccc56)cc4)nc(-c4ccc5oc6ccccc6c5c4)n3)ccc2c1]

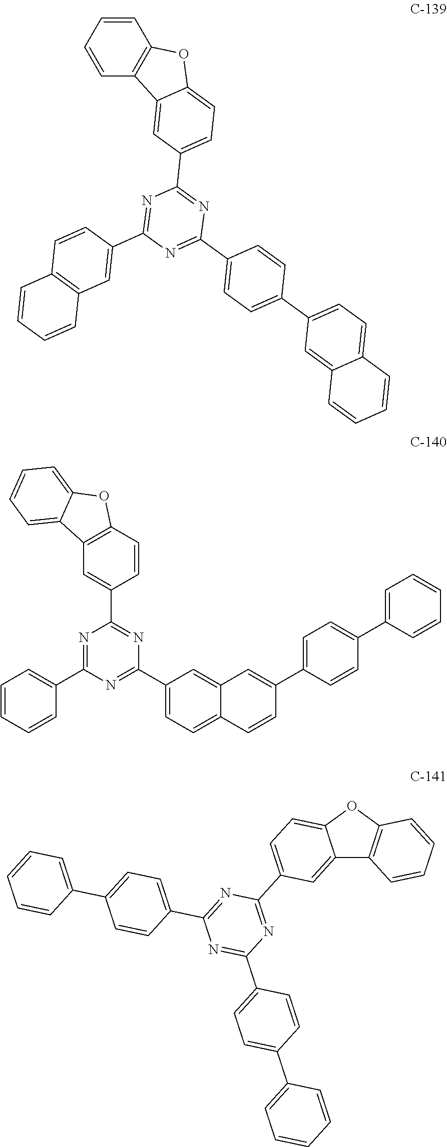 [SMILES: c1ccc2cc(-c3ccc(-c4nc(-c5ccc6ccccc6c5)nc(-c5ccc6oc7ccccc7c6c5)n4)cc3)ccc2c1 ; c1ccc(-c2ccc(-c3ccc4ccc(-c5nc(-c6ccccc6)nc(-c6ccc7oc8ccccc8c7c6)n5)cc4c3)cc2)cc1 ; c1ccc(-c2ccc(-c3nc(-c4ccc(-c5ccccc5)cc4)nc(-c4ccc5oc6ccccc6c5c4)n3)cc2)cc1]

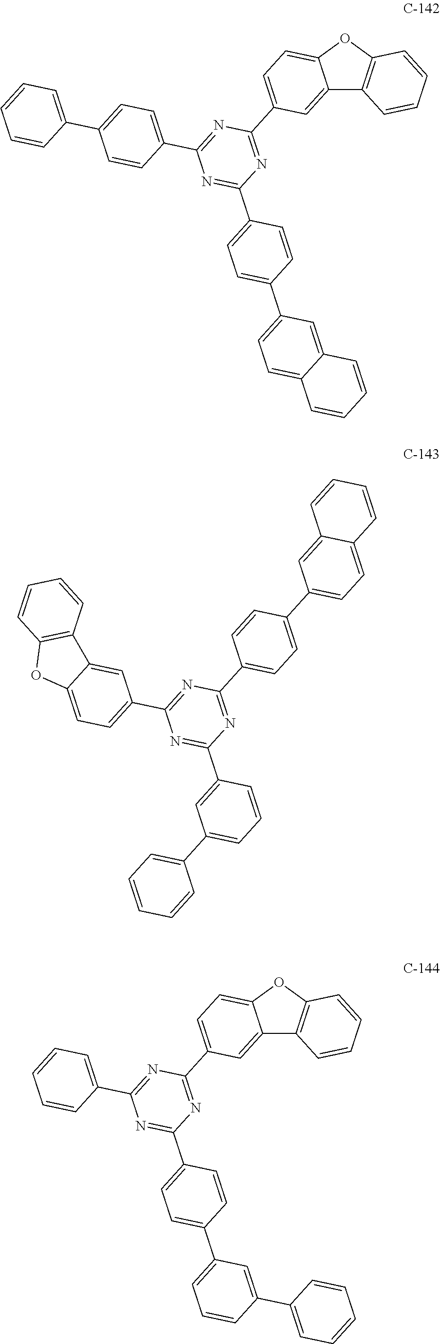 [SMILES: c1ccc(-c2ccc(-c3nc(-c4ccc(-c5ccc6ccccc6c5)cc4)nc(-c4ccc5oc6ccccc6c5c4)n3)cc2)cc1 ; c1ccc(-c2cccc(-c3nc(-c4ccc(-c5ccc6ccccc6c5)cc4)nc(-c4ccc5oc6ccccc6c5c4)n3)c2)cc1 ; c1ccc(-c2cccc(-c3ccc(-c4nc(-c5ccccc5)nc(-c5ccc6oc7ccccc7c6c5)n4)cc3)c2)cc1]

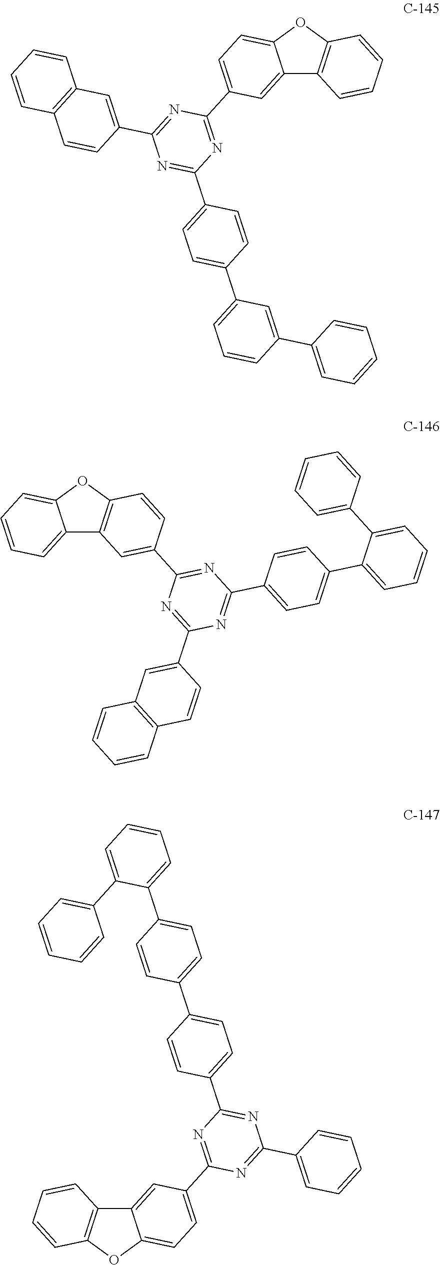 [SMILES: c1ccc(-c2cccc(-c3ccc(-c4nc(-c5ccc6ccccc6c5)nc(-c5ccc6oc7ccccc7c6c5)n4)cc3)c2)cc1 ; c1ccc(-c2ccccc2-c2ccc(-c3nc(-c4ccc5ccccc5c4)nc(-c4ccc5oc6ccccc6c5c4)n3)cc2)cc1 ; c1ccc(-c2nc(-c3ccc(-c4ccc(-c5ccccc5-c5ccccc5)cc4)cc3)nc(-c3ccc4oc5ccccc5c4c3)n2)cc1]

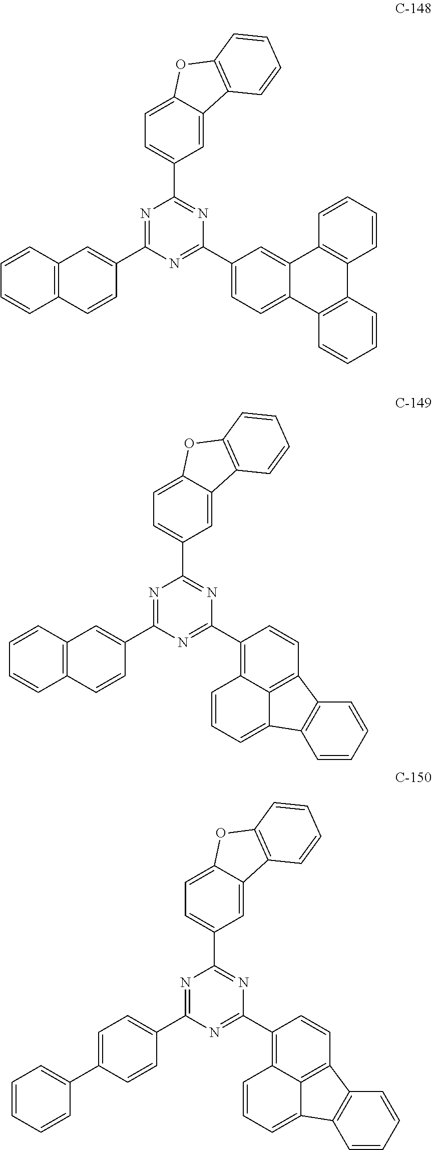 [SMILES: c1ccc2cc(-c3nc(-c4ccc5oc6ccccc6c5c4)nc(-c4ccc5c6ccccc6c6ccccc6c5c4)n3)ccc2c1 ; c1ccc2c(c1)-c1cccc3c(-c4nc(-c5ccc6ccccc6c5)nc(-c5ccc6oc7ccccc7c6c5)n4)ccc-2c13 ; c1ccc(-c2ccc(-c3nc(-c4ccc5oc6ccccc6c5c4)nc(-c4ccc5c6c(cccc46)-c4ccccc4-5)n3)cc2)cc1]

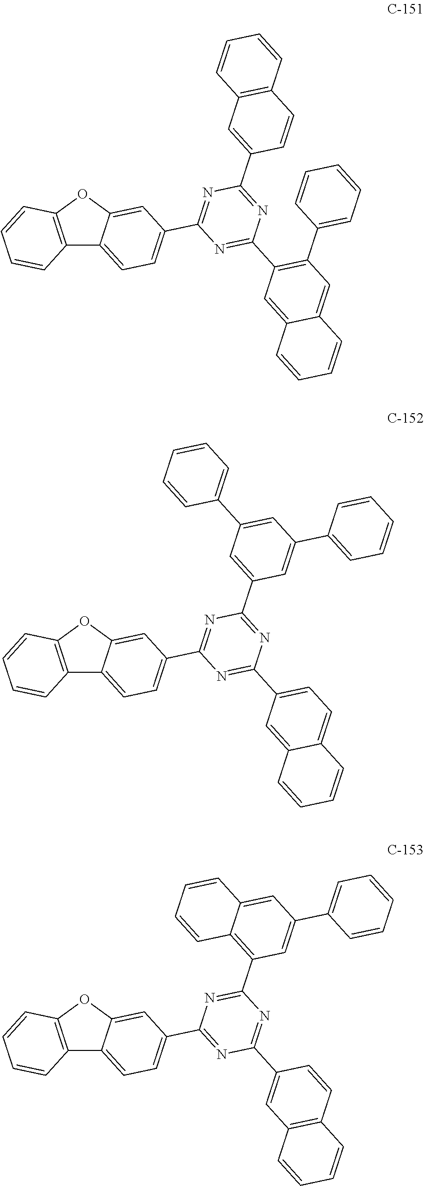 [SMILES: c1ccc(-c2cc3ccccc3cc2-c2nc(-c3ccc4ccccc4c3)nc(-c3ccc4c(c3)oc3ccccc34)n2)cc1 ; c1ccc(-c2cc(-c3ccccc3)cc(-c3nc(-c4ccc5ccccc5c4)nc(-c4ccc5c(c4)oc4ccccc45)n3)c2)cc1 ; c1ccc(-c2cc(-c3nc(-c4ccc5ccccc5c4)nc(-c4ccc5c(c4)oc4ccccc45)n3)c3ccccc3c2)cc1]

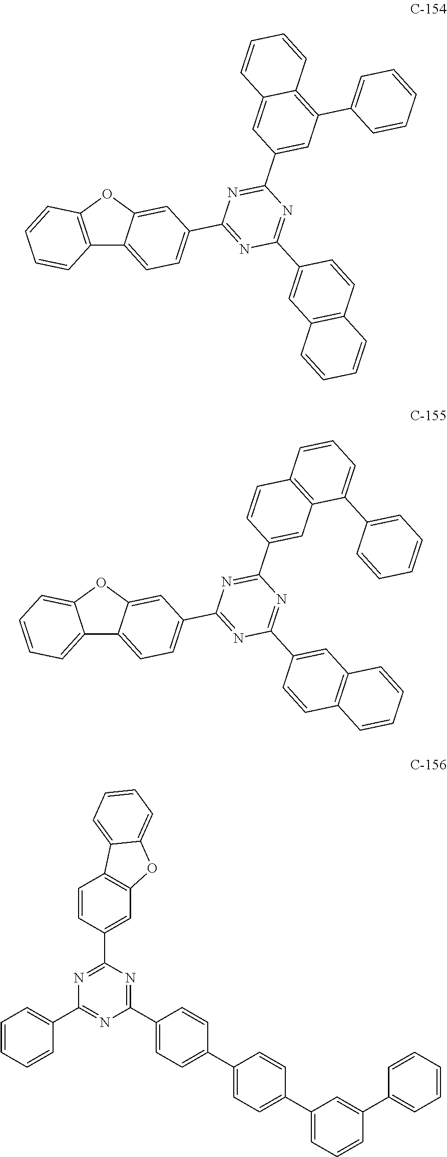 [SMILES: c1ccc(-c2cc(-c3nc(-c4ccc5ccccc5c4)nc(-c4ccc5c(c4)oc4ccccc45)n3)cc3ccccc23)cc1 ; c1ccc(-c2cccc3ccc(-c4nc(-c5ccc6ccccc6c5)nc(-c5ccc6c(c5)oc5ccccc56)n4)cc23)cc1 ; c1ccc(-c2cccc(-c3ccc(-c4ccc(-c5nc(-c6ccccc6)nc(-c6ccc7c(c6)oc6ccccc67)n5)cc4)cc3)c2)cc1]

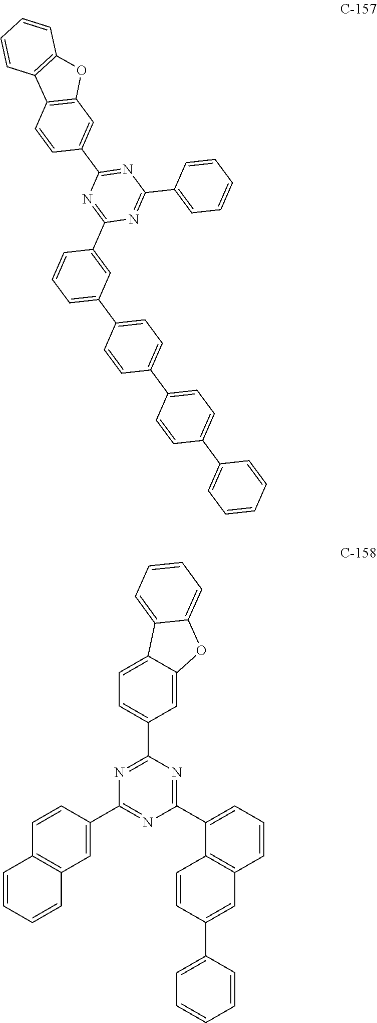 [SMILES: c1ccc(-c2ccc(-c3ccc(-c4cccc(-c5nc(-c6ccccc6)nc(-c6ccc7c(c6)oc6ccccc67)n5)c4)cc3)cc2)cc1 ; c1ccc(-c2ccc3c(-c4nc(-c5ccc6ccccc6c5)nc(-c5ccc6c(c5)oc5ccccc56)n4)cccc3c2)cc1]

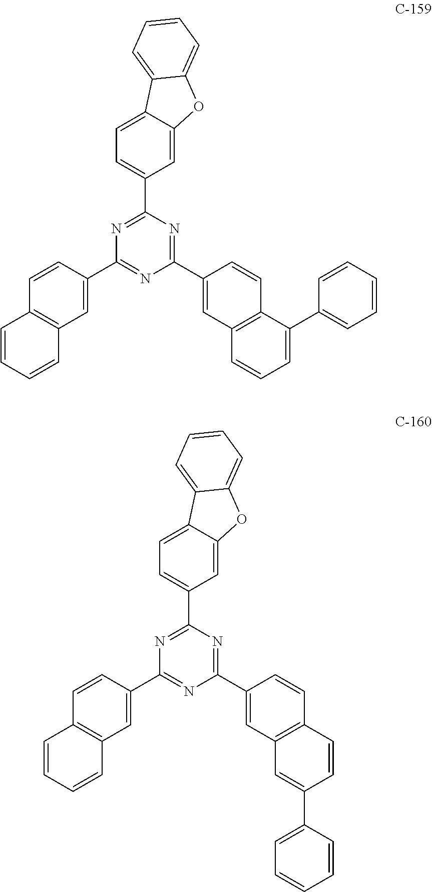 [SMILES: c1ccc(-c2cccc3cc(-c4nc(-c5ccc6ccccc6c5)nc(-c5ccc6c(c5)oc5ccccc56)n4)ccc23)cc1 ; c1ccc(-c2ccc3ccc(-c4nc(-c5ccc6ccccc6c5)nc(-c5ccc6c(c5)oc5ccccc56)n4)cc3c2)cc1]

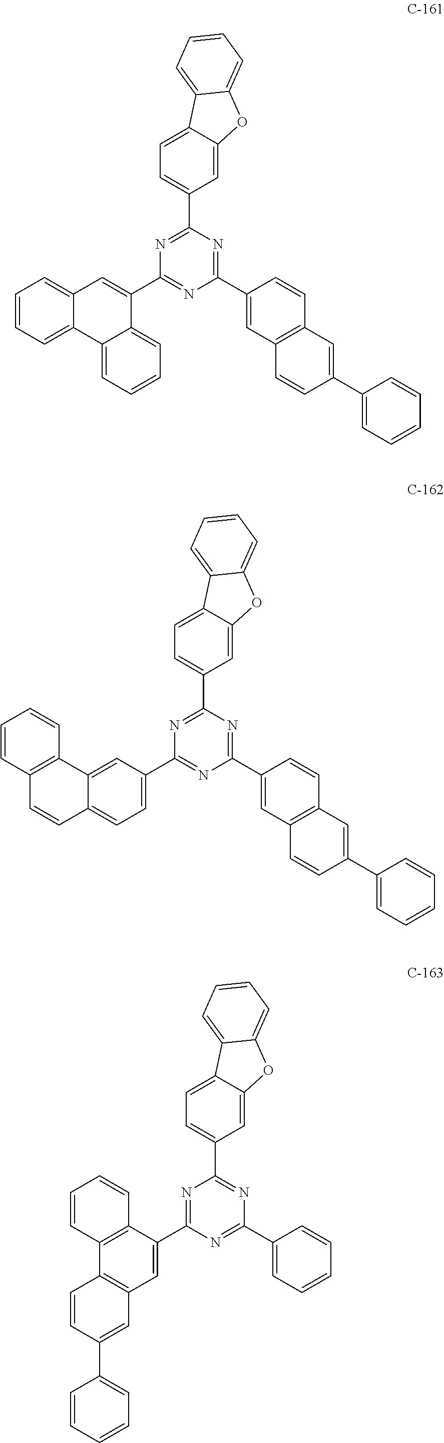 [SMILES: c1ccc(-c2ccc3cc(-c4nc(-c5ccc6c(c5)oc5ccccc56)nc(-c5cc6ccccc6c6ccccc56)n4)ccc3c2)cc1 ; c1ccc(-c2ccc3cc(-c4nc(-c5ccc6c(c5)oc5ccccc56)nc(-c5ccc6ccc7ccccc7c6c5)n4)ccc3c2)cc1 ; c1ccc(-c2ccc3c(c2)cc(-c2nc(-c4ccccc4)nc(-c4ccc5c(c4)oc4ccccc45)n2)c2ccccc23)cc1]

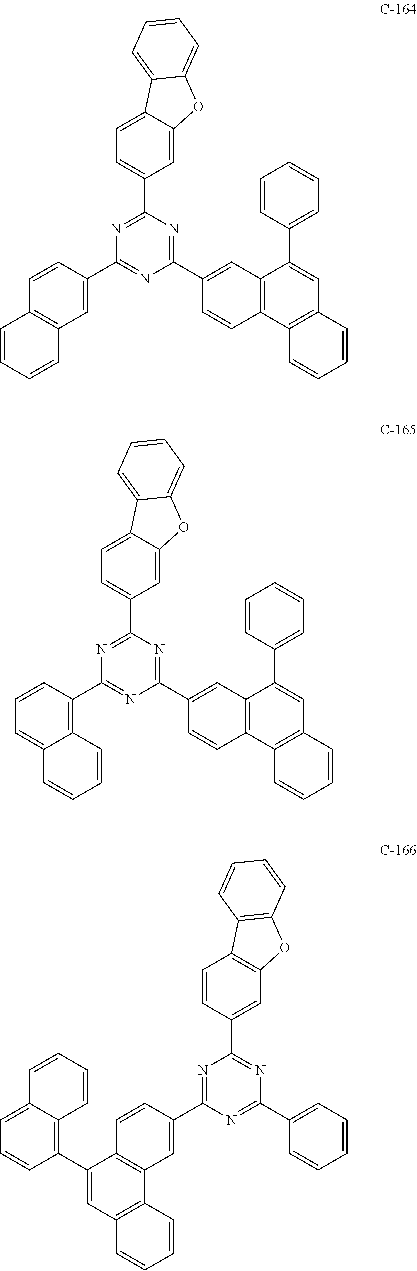 [SMILES: c1ccc(-c2cc3ccccc3c3ccc(-c4nc(-c5ccc6ccccc6c5)nc(-c5ccc6c(c5)oc5ccccc56)n4)cc23)cc1 ; c1ccc(-c2cc3ccccc3c3ccc(-c4nc(-c5ccc6c(c5)oc5ccccc56)nc(-c5cccc6ccccc56)n4)cc23)cc1 ; c1ccc(-c2nc(-c3ccc4c(c3)oc3ccccc34)nc(-c3ccc4c(-c5cccc6ccccc56)cc5ccccc5c4c3)n2)cc1]

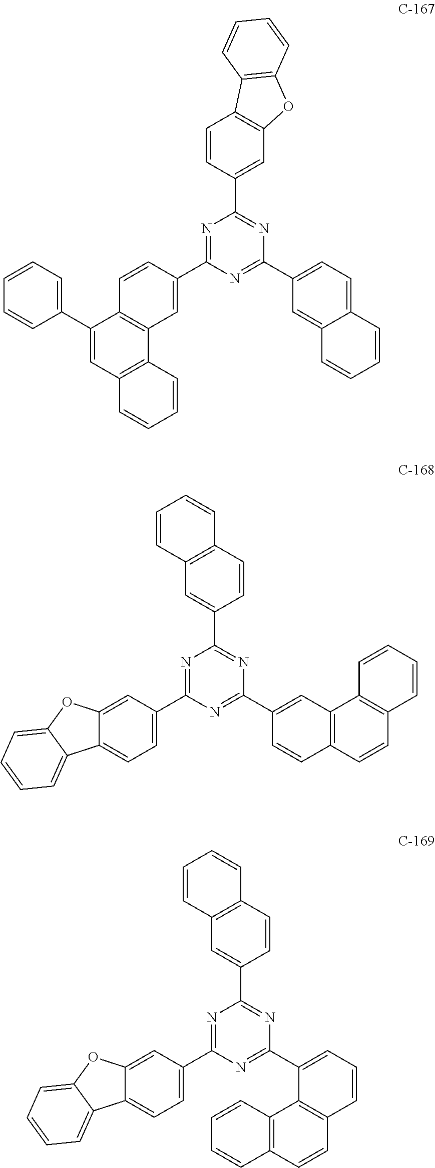 [SMILES: c1ccc(-c2cc3ccccc3c3cc(-c4nc(-c5ccc6ccccc6c5)nc(-c5ccc6c(c5)oc5ccccc56)n4)ccc23)cc1 ; c1ccc2cc(-c3nc(-c4ccc5c(c4)oc4ccccc45)nc(-c4ccc5ccc6ccccc6c5c4)n3)ccc2c1 ; c1ccc2cc(-c3nc(-c4ccc5c(c4)oc4ccccc45)nc(-c4cccc5ccc6ccccc6c45)n3)ccc2c1]

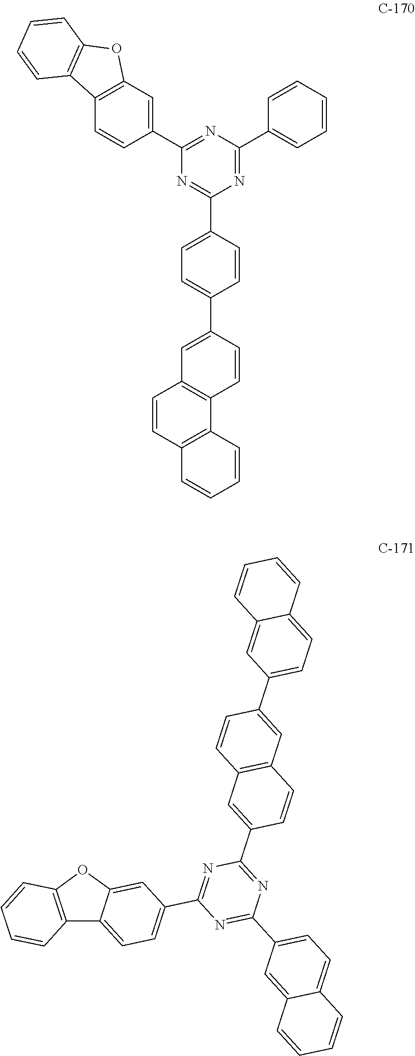 [SMILES: c1ccc(-c2nc(-c3ccc(-c4ccc5c(ccc6ccccc65)c4)cc3)nc(-c3ccc4c(c3)oc3ccccc34)n2)cc1 ; c1ccc2cc(-c3ccc4cc(-c5nc(-c6ccc7ccccc7c6)nc(-c6ccc7c(c6)oc6ccccc67)n5)ccc4c3)ccc2c1]

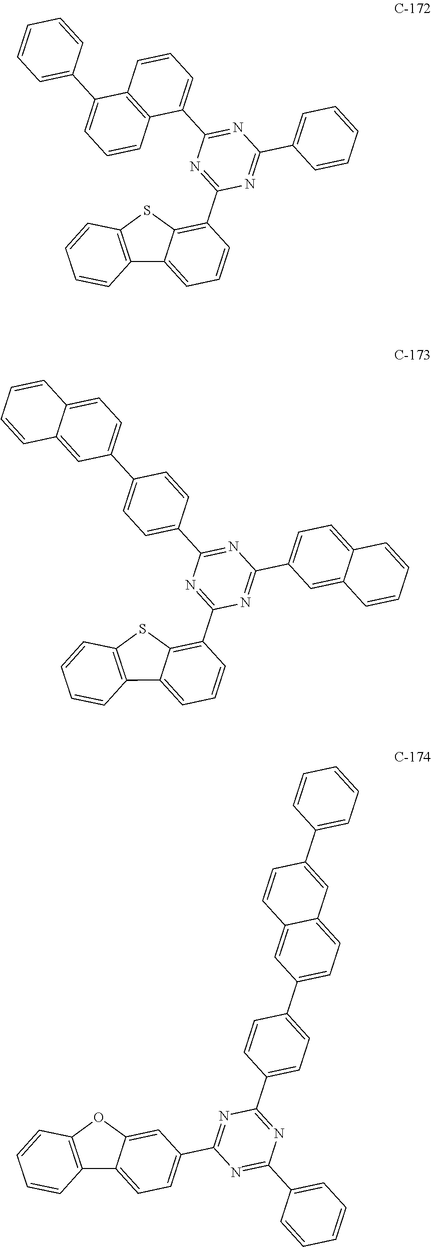 [SMILES: c1ccc(-c2nc(-c3cccc4c(-c5ccccc5)cccc34)nc(-c3cccc4c3sc3ccccc34)n2)cc1 ; c1ccc2cc(-c3ccc(-c4nc(-c5ccc6ccccc6c5)nc(-c5cccc6c5sc5ccccc56)n4)cc3)ccc2c1 ; c1ccc(-c2ccc3cc(-c4ccc(-c5nc(-c6ccccc6)nc(-c6ccc7c(c6)oc6ccccc67)n5)cc4)ccc3c2)cc1]

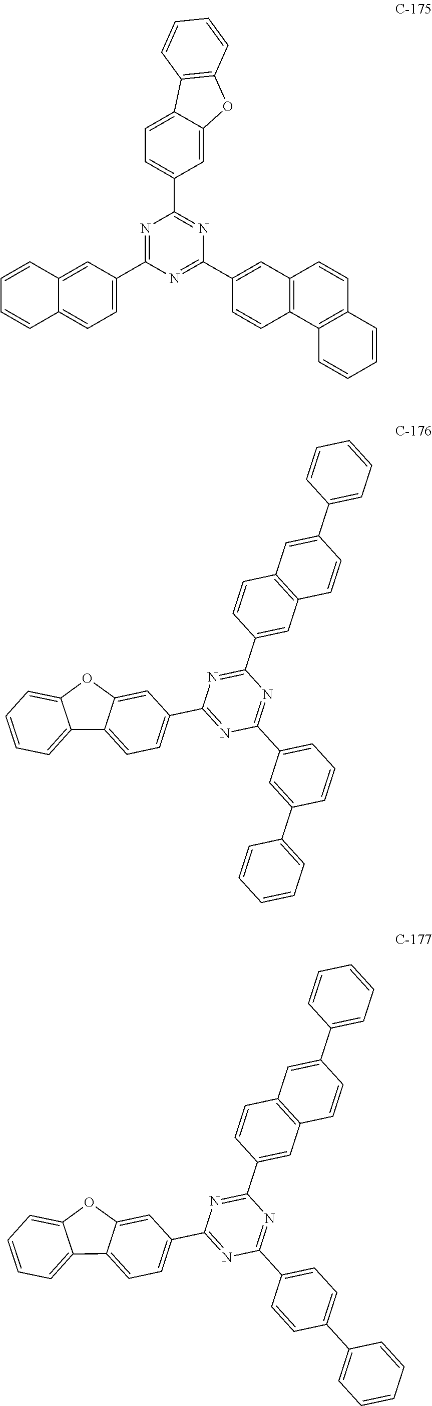 [SMILES: c1ccc2cc(-c3nc(-c4ccc5c(ccc6ccccc65)c4)nc(-c4ccc5c(c4)oc4ccccc45)n3)ccc2c1 ; c1ccc(-c2cccc(-c3nc(-c4ccc5cc(-c6ccccc6)ccc5c4)nc(-c4ccc5c(c4)oc4ccccc45)n3)c2)cc1 ; c1ccc(-c2ccc(-c3nc(-c4ccc5cc(-c6ccccc6)ccc5c4)nc(-c4ccc5c(c4)oc4ccccc45)n3)cc2)cc1]

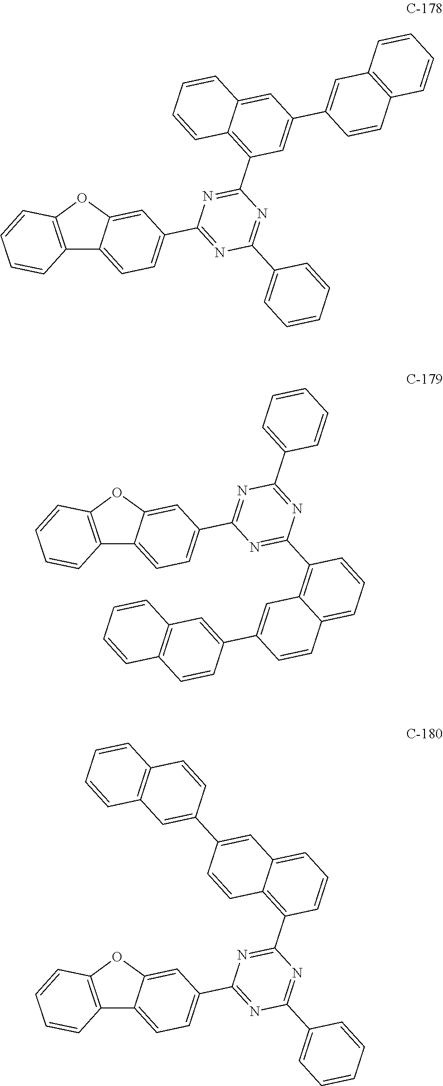 [SMILES: c1ccc(-c2nc(-c3ccc4c(c3)oc3ccccc34)nc(-c3cc(-c4ccc5ccccc5c4)cc4ccccc34)n2)cc1 ; c1ccc(-c2nc(-c3ccc4c(c3)oc3ccccc34)nc(-c3cccc4ccc(-c5ccc6ccccc6c5)cc34)n2)cc1 ; c1ccc(-c2nc(-c3ccc4c(c3)oc3ccccc34)nc(-c3cccc4cc(-c5ccc6ccccc6c5)ccc34)n2)cc1]

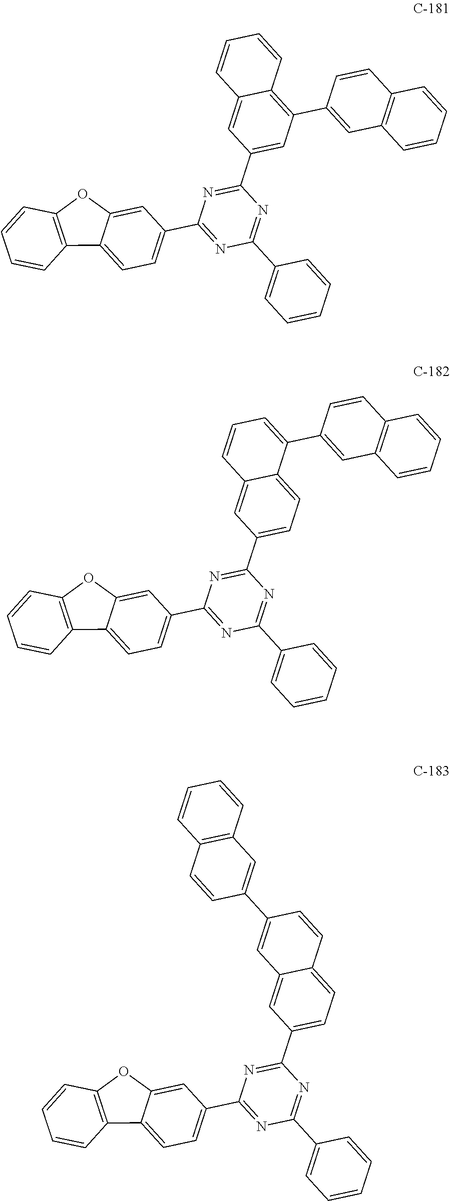 [SMILES: c1ccc(-c2nc(-c3cc(-c4ccc5ccccc5c4)c4ccccc4c3)nc(-c3ccc4c(c3)oc3ccccc34)n2)cc1 ; c1ccc(-c2nc(-c3ccc4c(-c5ccc6ccccc6c5)cccc4c3)nc(-c3ccc4c(c3)oc3ccccc34)n2)cc1 ; c1ccc(-c2nc(-c3ccc4ccc(-c5ccc6ccccc6c5)cc4c3)nc(-c3ccc4c(c3)oc3ccccc34)n2)cc1]

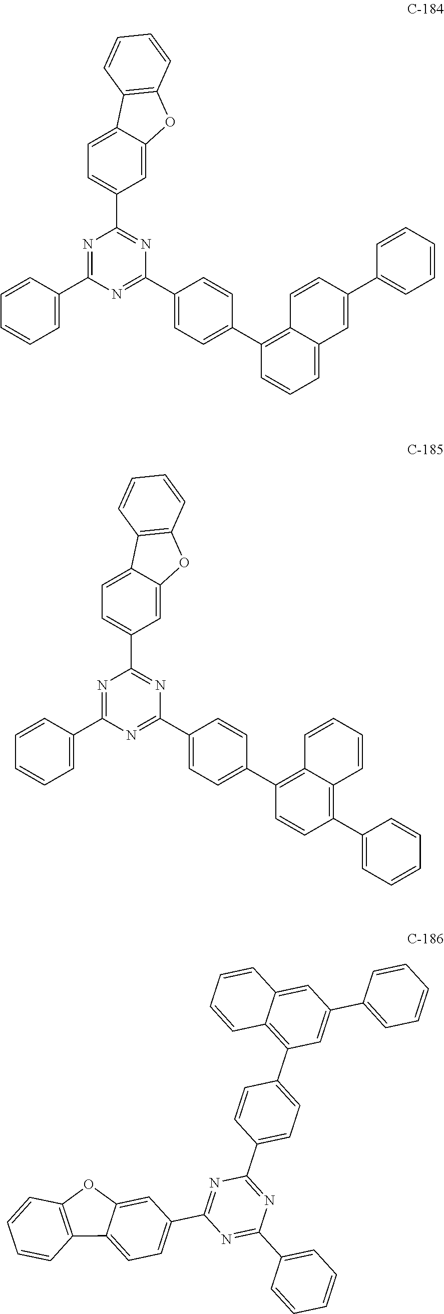 [SMILES: c1ccc(-c2ccc3c(-c4ccc(-c5nc(-c6ccccc6)nc(-c6ccc7c(c6)oc6ccccc67)n5)cc4)cccc3c2)cc1 ; c1ccc(-c2nc(-c3ccc(-c4ccc(-c5ccccc5)c5ccccc45)cc3)nc(-c3ccc4c(c3)oc3ccccc34)n2)cc1 ; c1ccc(-c2cc(-c3ccc(-c4nc(-c5ccccc5)nc(-c5ccc6c(c5)oc5ccccc56)n4)cc3)c3ccccc3c2)cc1]

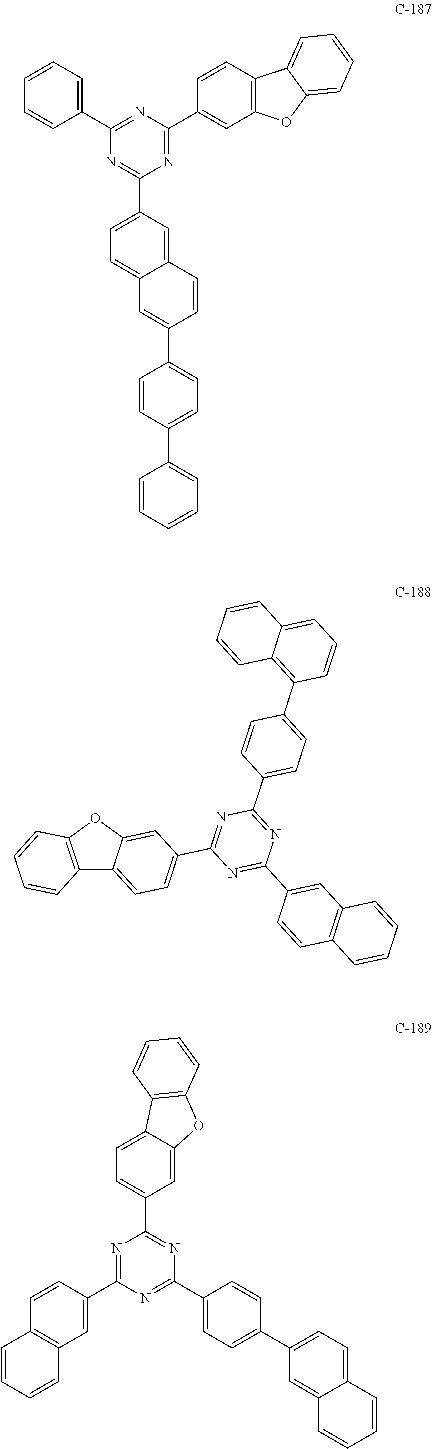 [SMILES: c1ccc(-c2ccc(-c3ccc4cc(-c5nc(-c6ccccc6)nc(-c6ccc7c(c6)oc6ccccc67)n5)ccc4c3)cc2)cc1 ; c1ccc2cc(-c3nc(-c4ccc(-c5cccc6ccccc56)cc4)nc(-c4ccc5c(c4)oc4ccccc45)n3)ccc2c1 ; c1ccc2cc(-c3ccc(-c4nc(-c5ccc6ccccc6c5)nc(-c5ccc6c(c5)oc5ccccc56)n4)cc3)ccc2c1]

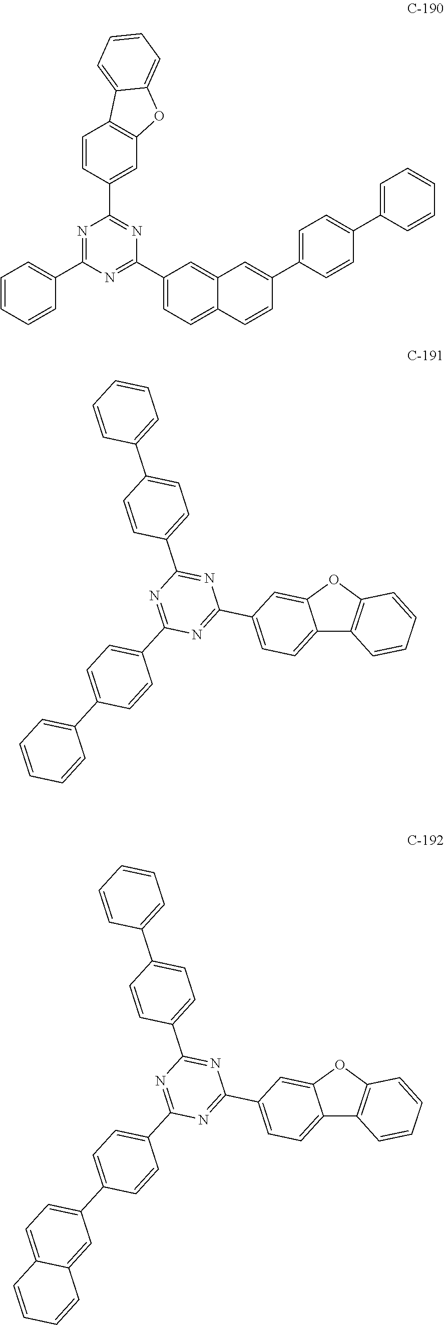 [SMILES: c1ccc(-c2ccc(-c3ccc4ccc(-c5nc(-c6ccccc6)nc(-c6ccc7c(c6)oc6ccccc67)n5)cc4c3)cc2)cc1 ; c1ccc(-c2ccc(-c3nc(-c4ccc(-c5ccccc5)cc4)nc(-c4ccc5c(c4)oc4ccccc45)n3)cc2)cc1 ; c1ccc(-c2ccc(-c3nc(-c4ccc(-c5ccc6ccccc6c5)cc4)nc(-c4ccc5c(c4)oc4ccccc45)n3)cc2)cc1]

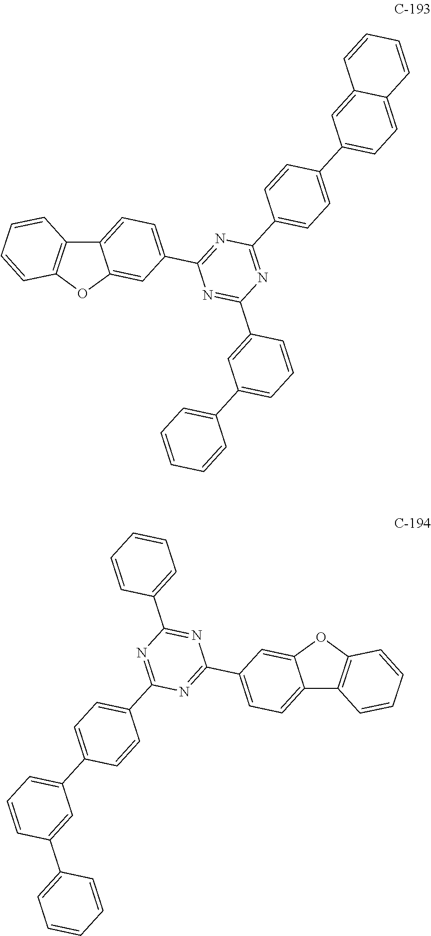 [SMILES: c1ccc(-c2cccc(-c3nc(-c4ccc(-c5ccc6ccccc6c5)cc4)nc(-c4ccc5c(c4)oc4ccccc45)n3)c2)cc1 ; c1ccc(-c2cccc(-c3ccc(-c4nc(-c5ccccc5)nc(-c5ccc6c(c5)oc5ccccc56)n4)cc3)c2)cc1]

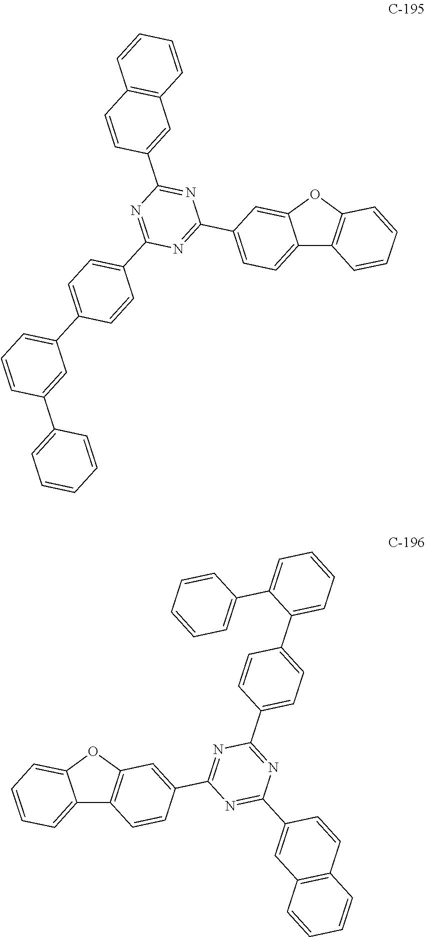 [SMILES: c1ccc(-c2cccc(-c3ccc(-c4nc(-c5ccc6ccccc6c5)nc(-c5ccc6c(c5)oc5ccccc56)n4)cc3)c2)cc1 ; c1ccc(-c2ccccc2-c2ccc(-c3nc(-c4ccc5ccccc5c4)nc(-c4ccc5c(c4)oc4ccccc45)n3)cc2)cc1]

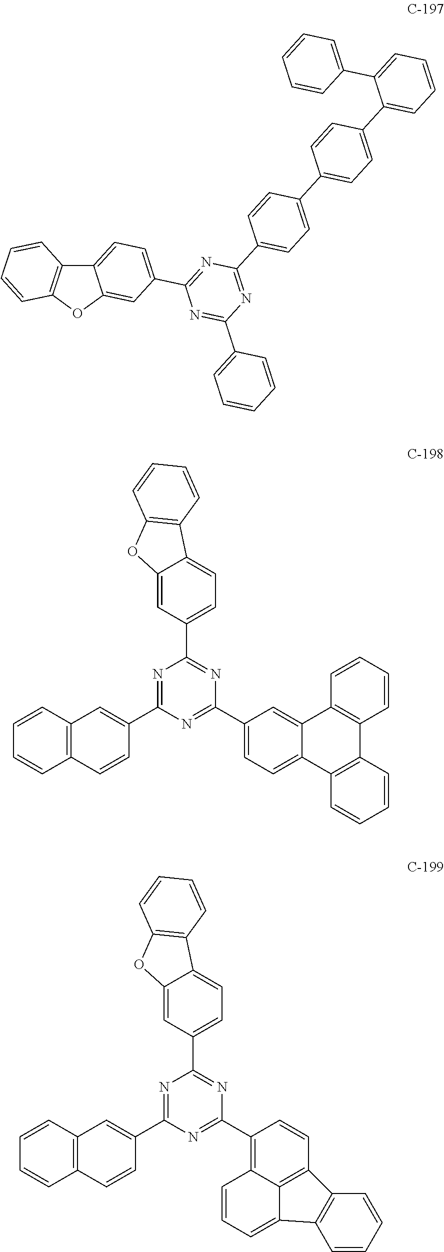 [SMILES: c1ccc(-c2nc(-c3ccc(-c4ccc(-c5ccccc5-c5ccccc5)cc4)cc3)nc(-c3ccc4c(c3)oc3ccccc34)n2)cc1 ; c1ccc2cc(-c3nc(-c4ccc5c(c4)oc4ccccc45)nc(-c4ccc5c6ccccc6c6ccccc6c5c4)n3)ccc2c1 ; c1ccc2c(c1)-c1cccc3c(-c4nc(-c5ccc6ccccc6c5)nc(-c5ccc6c(c5)oc5ccccc56)n4)ccc-2c13]

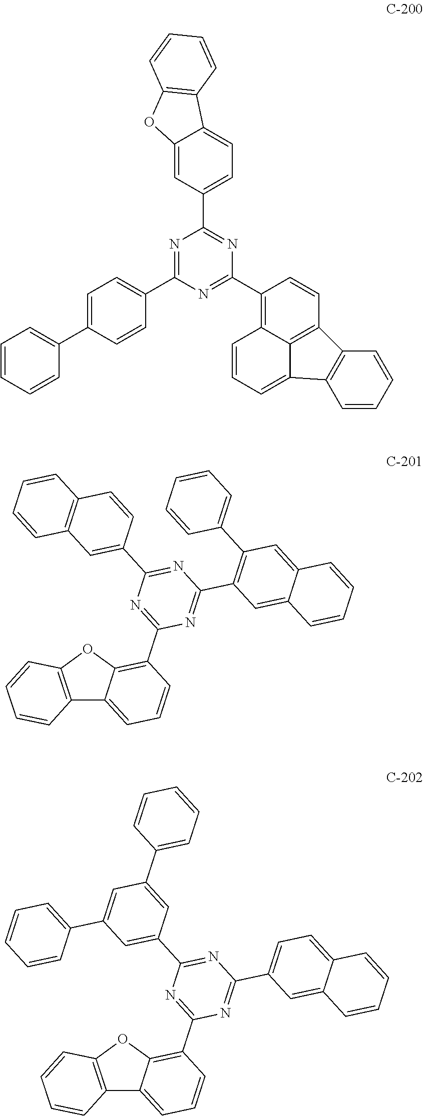 [SMILES: c1ccc(-c2ccc(-c3nc(-c4ccc5c(c4)oc4ccccc45)nc(-c4ccc5c6c(cccc46)-c4ccccc4-5)n3)cc2)cc1 ; c1ccc(-c2cc3ccccc3cc2-c2nc(-c3ccc4ccccc4c3)nc(-c3cccc4c3oc3ccccc34)n2)cc1 ; c1ccc(-c2cc(-c3ccccc3)cc(-c3nc(-c4ccc5ccccc5c4)nc(-c4cccc5c4oc4ccccc45)n3)c2)cc1]

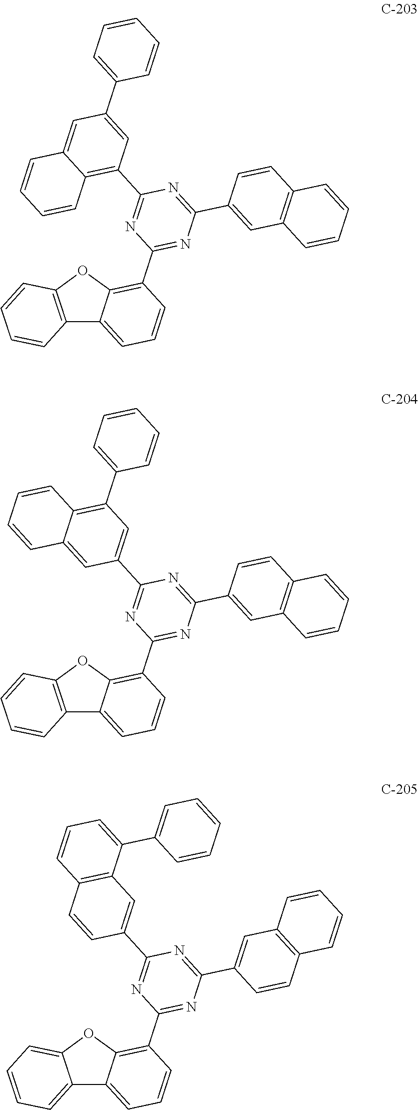 [SMILES: c1ccc(-c2cc(-c3nc(-c4ccc5ccccc5c4)nc(-c4cccc5c4oc4ccccc45)n3)c3ccccc3c2)cc1 ; c1ccc(-c2cc(-c3nc(-c4ccc5ccccc5c4)nc(-c4cccc5c4oc4ccccc45)n3)cc3ccccc23)cc1 ; c1ccc(-c2cccc3ccc(-c4nc(-c5ccc6ccccc6c5)nc(-c5cccc6c5oc5ccccc56)n4)cc23)cc1]

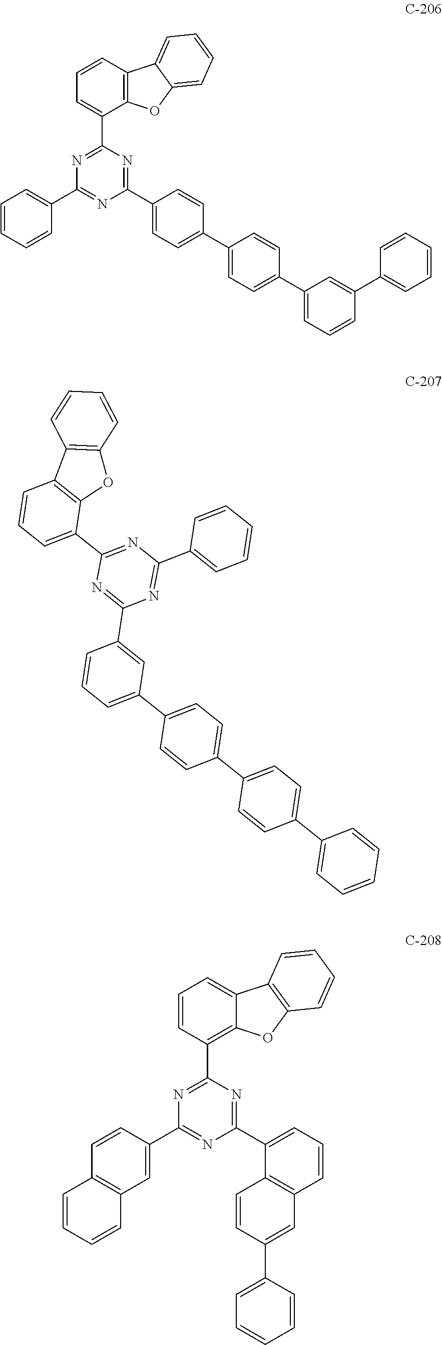 [SMILES: c1ccc(-c2cccc(-c3ccc(-c4ccc(-c5nc(-c6ccccc6)nc(-c6cccc7c6oc6ccccc67)n5)cc4)cc3)c2)cc1 ; c1ccc(-c2ccc(-c3ccc(-c4cccc(-c5nc(-c6ccccc6)nc(-c6cccc7c6oc6ccccc67)n5)c4)cc3)cc2)cc1 ; c1ccc(-c2ccc3c(-c4nc(-c5ccc6ccccc6c5)nc(-c5cccc6c5oc5ccccc56)n4)cccc3c2)cc1]

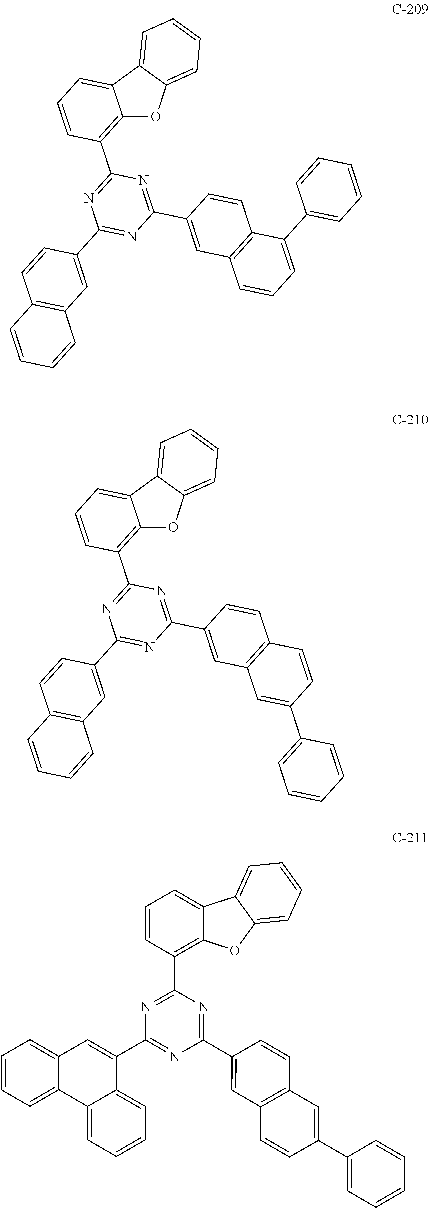 [SMILES: c1ccc(-c2cccc3cc(-c4nc(-c5ccc6ccccc6c5)nc(-c5cccc6c5oc5ccccc56)n4)ccc23)cc1 ; c1ccc(-c2ccc3ccc(-c4nc(-c5ccc6ccccc6c5)nc(-c5cccc6c5oc5ccccc56)n4)cc3c2)cc1 ; c1ccc(-c2ccc3cc(-c4nc(-c5cc6ccccc6c6ccccc56)nc(-c5cccc6c5oc5ccccc56)n4)ccc3c2)cc1]

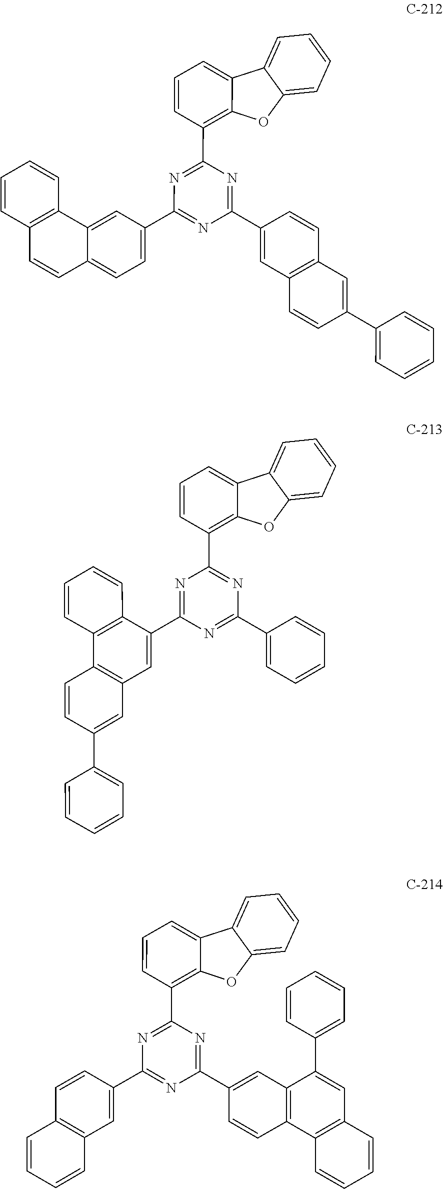 [SMILES: c1ccc(-c2ccc3cc(-c4nc(-c5ccc6ccc7ccccc7c6c5)nc(-c5cccc6c5oc5ccccc56)n4)ccc3c2)cc1 ; c1ccc(-c2ccc3c(c2)cc(-c2nc(-c4ccccc4)nc(-c4cccc5c4oc4ccccc45)n2)c2ccccc23)cc1 ; c1ccc(-c2cc3ccccc3c3ccc(-c4nc(-c5ccc6ccccc6c5)nc(-c5cccc6c5oc5ccccc56)n4)cc23)cc1]

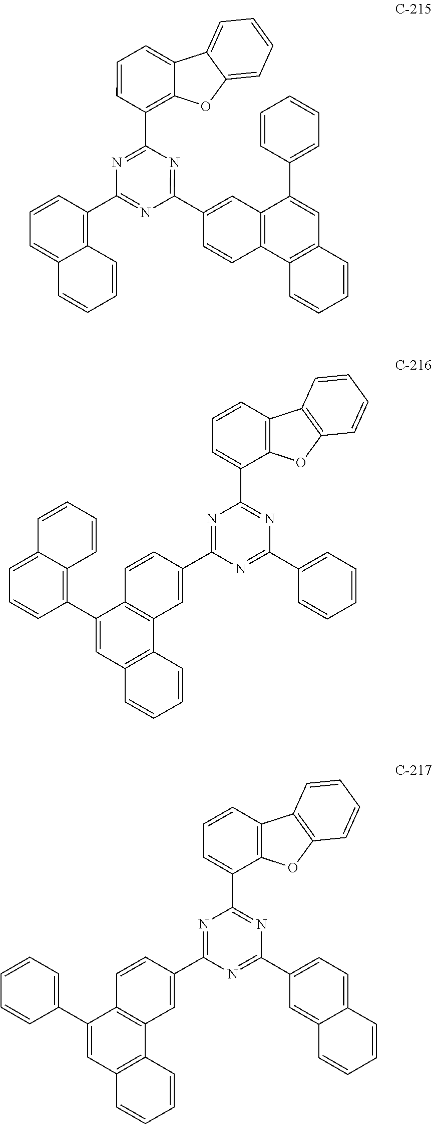 [SMILES: c1ccc(-c2cc3ccccc3c3ccc(-c4nc(-c5cccc6ccccc56)nc(-c5cccc6c5oc5ccccc56)n4)cc23)cc1 ; c1ccc(-c2nc(-c3ccc4c(-c5cccc6ccccc56)cc5ccccc5c4c3)nc(-c3cccc4c3oc3ccccc34)n2)cc1 ; c1ccc(-c2cc3ccccc3c3cc(-c4nc(-c5ccc6ccccc6c5)nc(-c5cccc6c5oc5ccccc56)n4)ccc23)cc1]

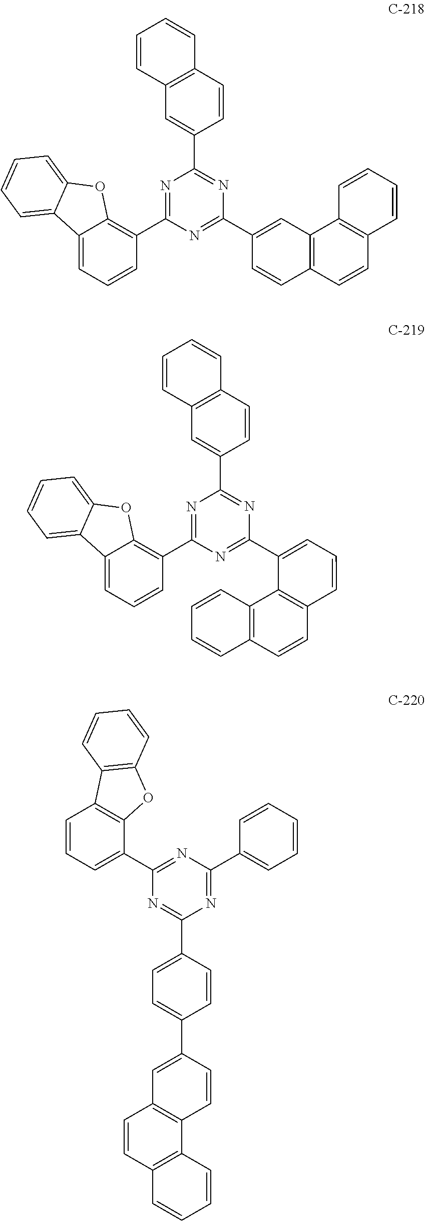 [SMILES: c1ccc2cc(-c3nc(-c4ccc5ccc6ccccc6c5c4)nc(-c4cccc5c4oc4ccccc45)n3)ccc2c1 ; c1ccc2cc(-c3nc(-c4cccc5c4oc4ccccc45)nc(-c4cccc5ccc6ccccc6c45)n3)ccc2c1 ; c1ccc(-c2nc(-c3ccc(-c4ccc5c(ccc6ccccc65)c4)cc3)nc(-c3cccc4c3oc3ccccc34)n2)cc1]

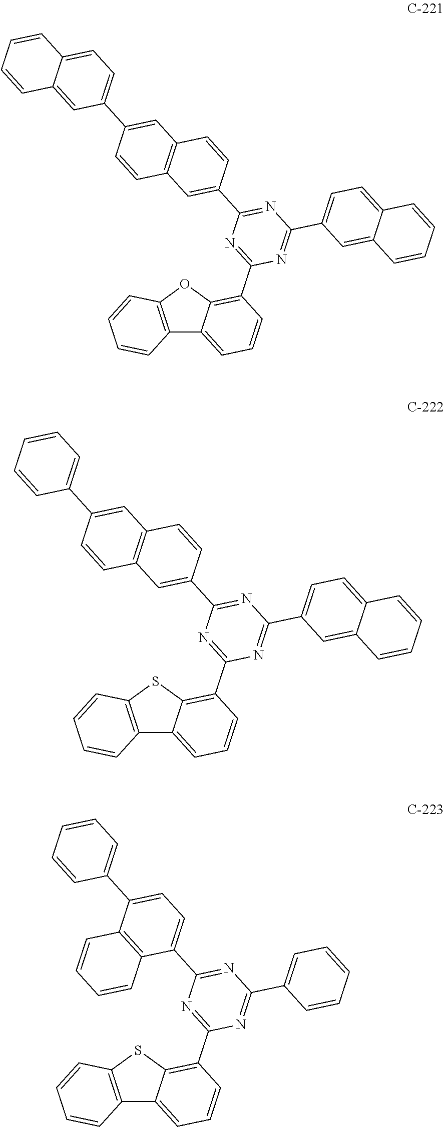 [SMILES: c1ccc2cc(-c3ccc4cc(-c5nc(-c6ccc7ccccc7c6)nc(-c6cccc7c6oc6ccccc67)n5)ccc4c3)ccc2c1 ; c1ccc(-c2ccc3cc(-c4nc(-c5ccc6ccccc6c5)nc(-c5cccc6c5sc5ccccc56)n4)ccc3c2)cc1 ; c1ccc(-c2nc(-c3ccc(-c4ccccc4)c4ccccc34)nc(-c3cccc4c3sc3ccccc34)n2)cc1]

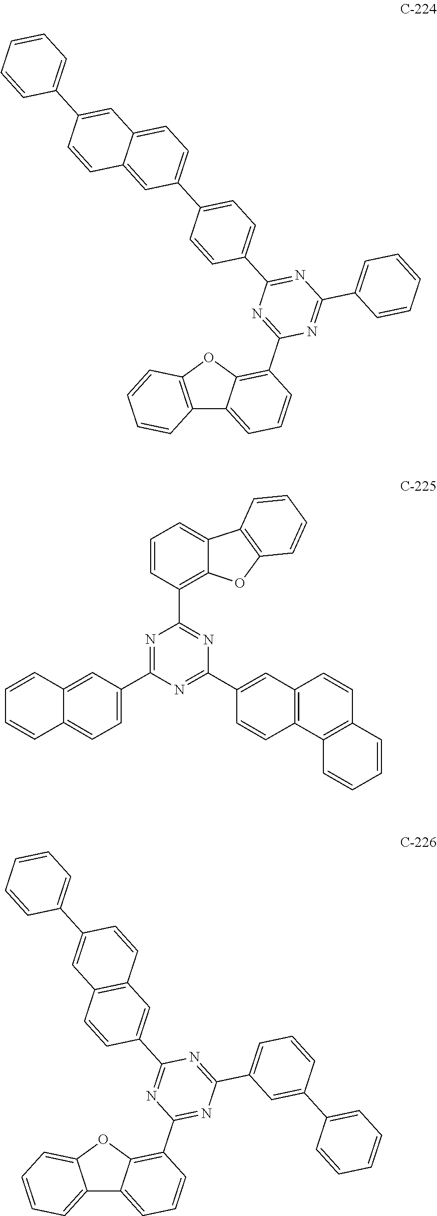 [SMILES: c1ccc(-c2ccc3cc(-c4ccc(-c5nc(-c6ccccc6)nc(-c6cccc7c6oc6ccccc67)n5)cc4)ccc3c2)cc1 ; c1ccc2cc(-c3nc(-c4ccc5c(ccc6ccccc65)c4)nc(-c4cccc5c4oc4ccccc45)n3)ccc2c1 ; c1ccc(-c2cccc(-c3nc(-c4ccc5cc(-c6ccccc6)ccc5c4)nc(-c4cccc5c4oc4ccccc45)n3)c2)cc1]

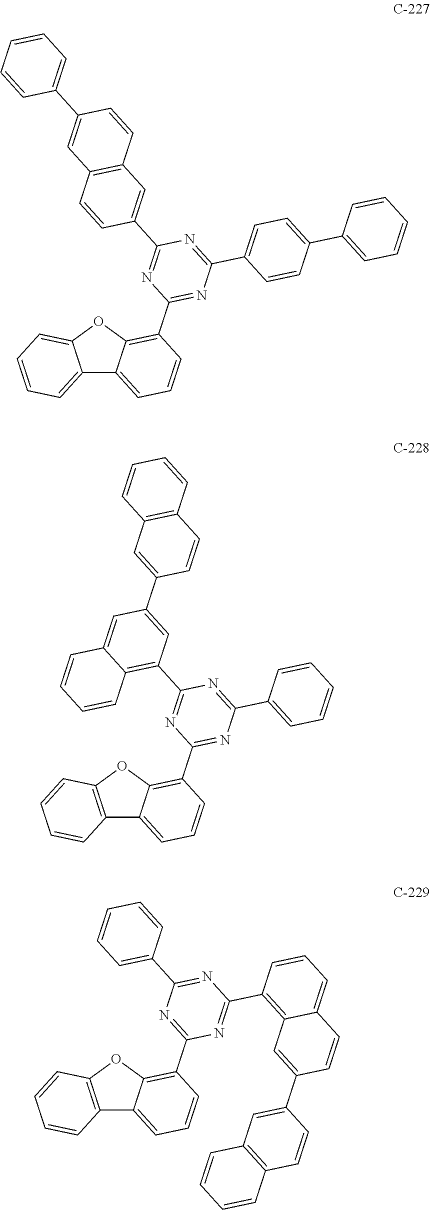 [SMILES: c1ccc(-c2ccc(-c3nc(-c4ccc5cc(-c6ccccc6)ccc5c4)nc(-c4cccc5c4oc4ccccc45)n3)cc2)cc1 ; c1ccc(-c2nc(-c3cc(-c4ccc5ccccc5c4)cc4ccccc34)nc(-c3cccc4c3oc3ccccc34)n2)cc1 ; c1ccc(-c2nc(-c3cccc4ccc(-c5ccc6ccccc6c5)cc34)nc(-c3cccc4c3oc3ccccc34)n2)cc1]

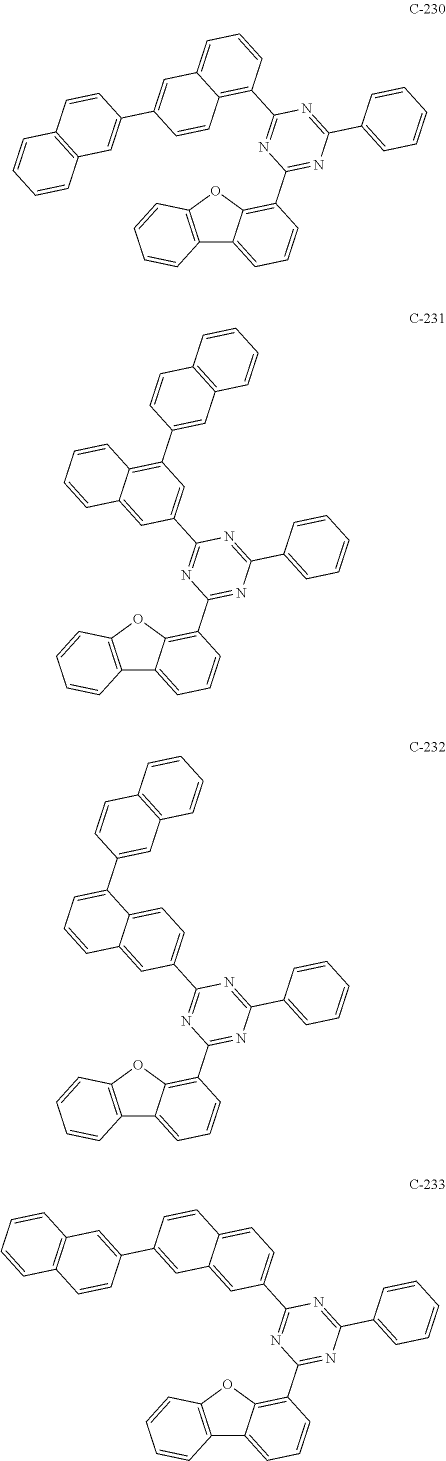 [SMILES: c1ccc(-c2nc(-c3cccc4cc(-c5ccc6ccccc6c5)ccc34)nc(-c3cccc4c3oc3ccccc34)n2)cc1 ; c1ccc(-c2nc(-c3cc(-c4ccc5ccccc5c4)c4ccccc4c3)nc(-c3cccc4c3oc3ccccc34)n2)cc1 ; c1ccc(-c2nc(-c3ccc4c(-c5ccc6ccccc6c5)cccc4c3)nc(-c3cccc4c3oc3ccccc34)n2)cc1 ; c1ccc(-c2nc(-c3ccc4ccc(-c5ccc6ccccc6c5)cc4c3)nc(-c3cccc4c3oc3ccccc34)n2)cc1]

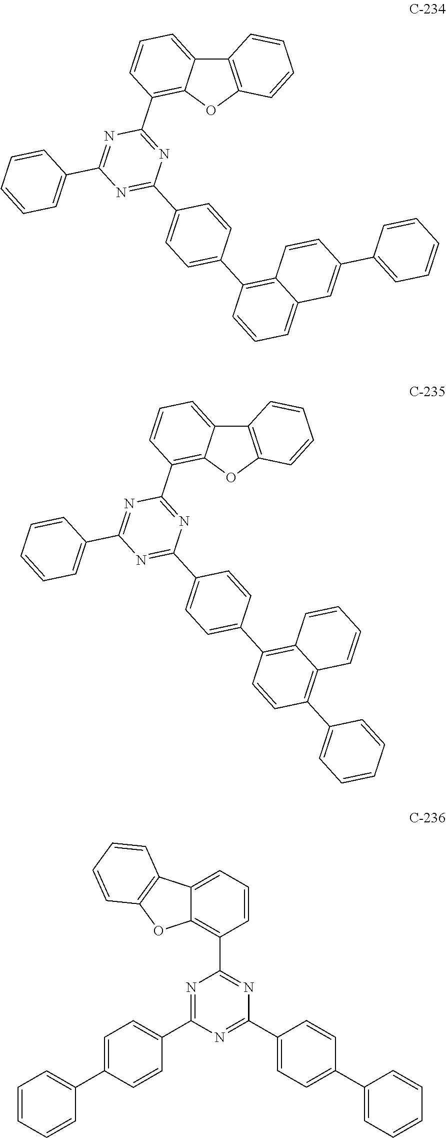 [SMILES: c1ccc(-c2ccc3c(-c4ccc(-c5nc(-c6ccccc6)nc(-c6cccc7c6oc6ccccc67)n5)cc4)cccc3c2)cc1 ; c1ccc(-c2nc(-c3ccc(-c4ccc(-c5ccccc5)c5ccccc45)cc3)nc(-c3cccc4c3oc3ccccc34)n2)cc1 ; c1ccc(-c2ccc(-c3nc(-c4ccc(-c5ccccc5)cc4)nc(-c4cccc5c4oc4ccccc45)n3)cc2)cc1]

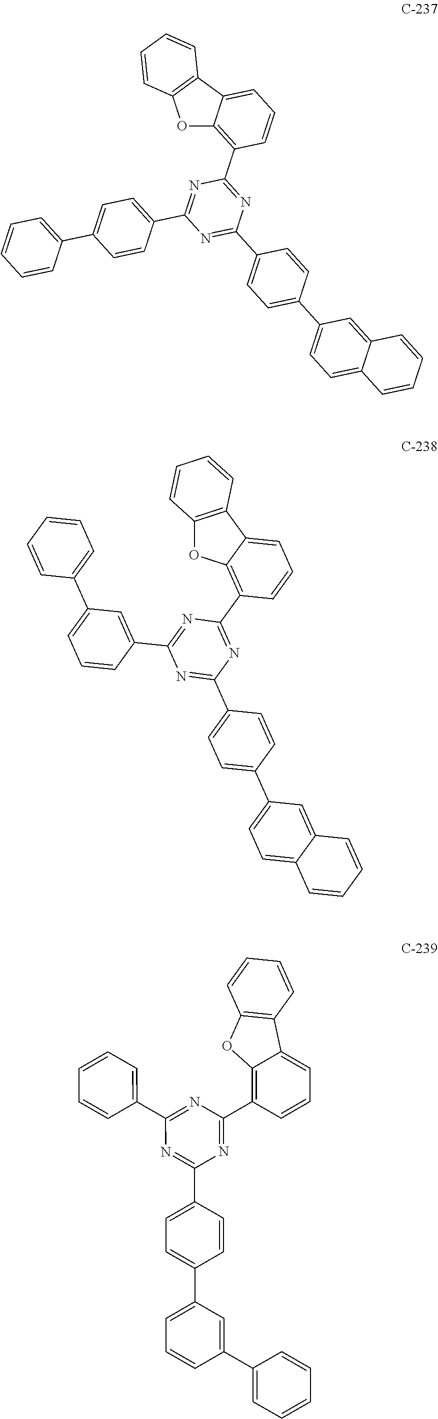 [SMILES: c1ccc(-c2ccc(-c3nc(-c4ccc(-c5ccc6ccccc6c5)cc4)nc(-c4cccc5c4oc4ccccc45)n3)cc2)cc1 ; c1ccc(-c2cccc(-c3nc(-c4ccc(-c5ccc6ccccc6c5)cc4)nc(-c4cccc5c4oc4ccccc45)n3)c2)cc1 ; c1ccc(-c2cccc(-c3ccc(-c4nc(-c5ccccc5)nc(-c5cccc6c5oc5ccccc56)n4)cc3)c2)cc1]

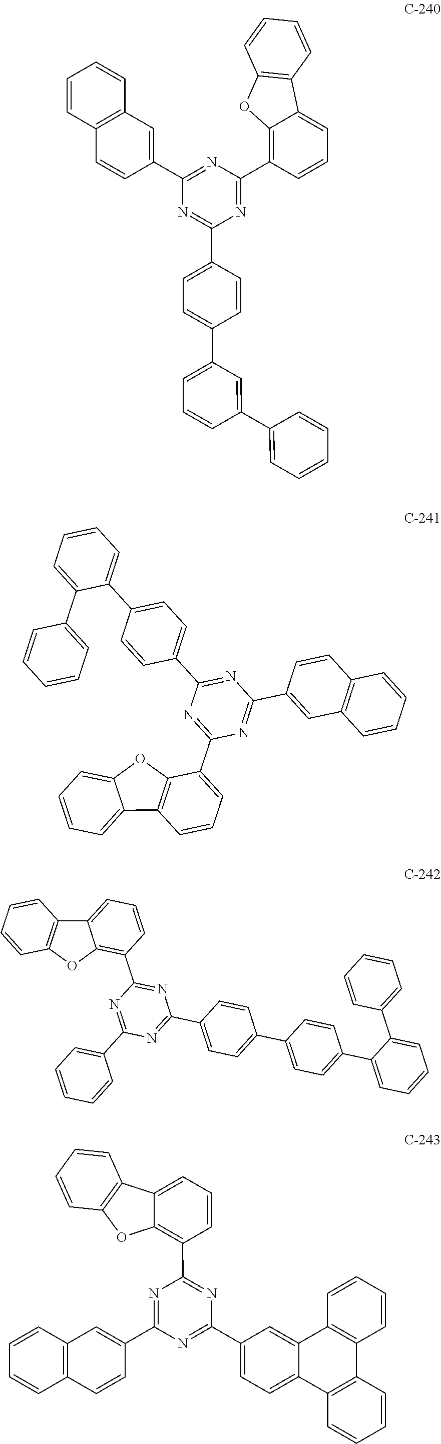 [SMILES: c1ccc(-c2cccc(-c3ccc(-c4nc(-c5ccc6ccccc6c5)nc(-c5cccc6c5oc5ccccc56)n4)cc3)c2)cc1 ; c1ccc(-c2ccccc2-c2ccc(-c3nc(-c4ccc5ccccc5c4)nc(-c4cccc5c4oc4ccccc45)n3)cc2)cc1 ; c1ccc(-c2nc(-c3ccc(-c4ccc(-c5ccccc5-c5ccccc5)cc4)cc3)nc(-c3cccc4c3oc3ccccc34)n2)cc1 ; c1ccc2cc(-c3nc(-c4ccc5c6ccccc6c6ccccc6c5c4)nc(-c4cccc5c4oc4ccccc45)n3)ccc2c1]

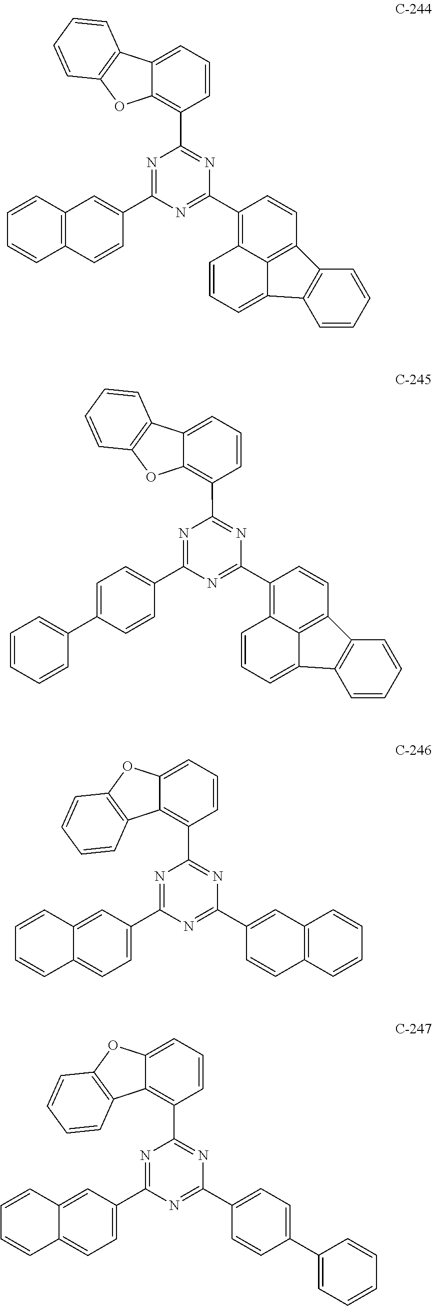 [SMILES: c1ccc2c(c1)-c1cccc3c(-c4nc(-c5ccc6ccccc6c5)nc(-c5cccc6c5oc5ccccc56)n4)ccc-2c13 ; c1ccc(-c2ccc(-c3nc(-c4ccc5c6c(cccc46)-c4ccccc4-5)nc(-c4cccc5c4oc4ccccc45)n3)cc2)cc1 ; c1ccc2cc(-c3nc(-c4ccc5ccccc5c4)nc(-c4cccc5oc6ccccc6c45)n3)ccc2c1 ; c1ccc(-c2ccc(-c3nc(-c4ccc5ccccc5c4)nc(-c4cccc5oc6ccccc6c45)n3)cc2)cc1]

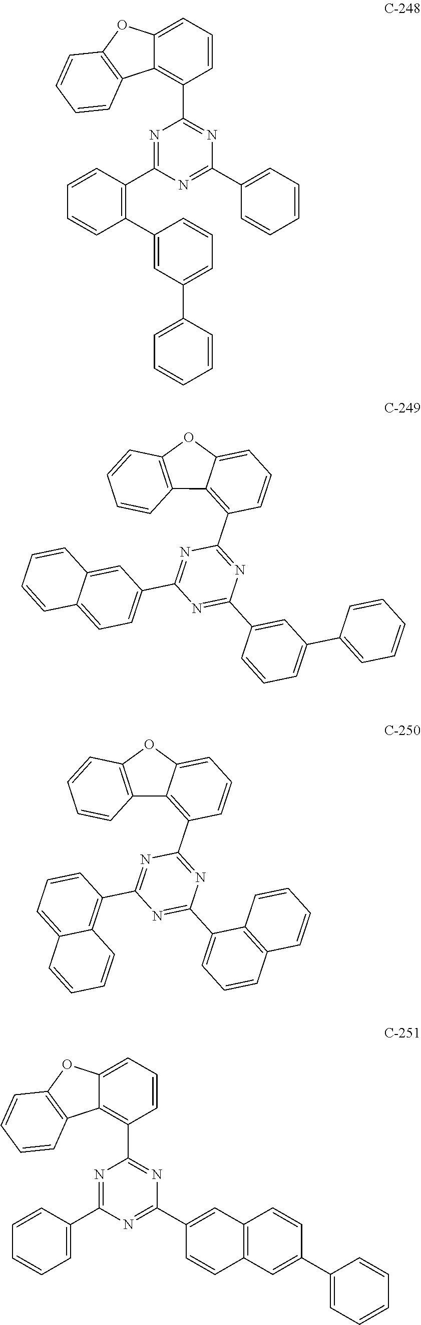 [SMILES: c1ccc(-c2cccc(-c3ccccc3-c3nc(-c4ccccc4)nc(-c4cccc5oc6ccccc6c45)n3)c2)cc1 ; c1ccc(-c2cccc(-c3nc(-c4ccc5ccccc5c4)nc(-c4cccc5oc6ccccc6c45)n3)c2)cc1 ; c1ccc2c(-c3nc(-c4cccc5ccccc45)nc(-c4cccc5oc6ccccc6c45)n3)cccc2c1 ; c1ccc(-c2ccc3cc(-c4nc(-c5ccccc5)nc(-c5cccc6oc7ccccc7c56)n4)ccc3c2)cc1]

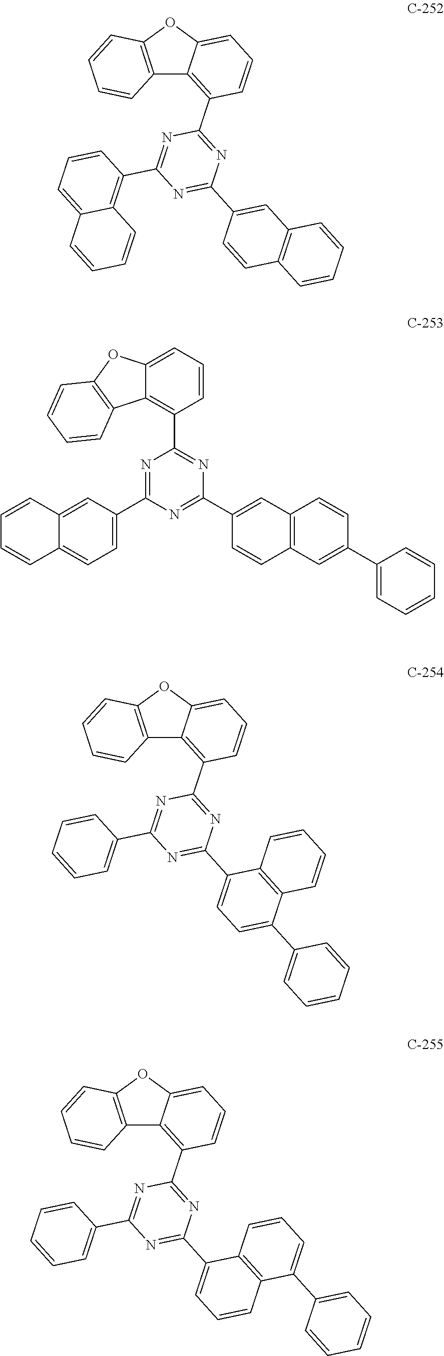 [SMILES: c1ccc2cc(-c3nc(-c4cccc5ccccc45)nc(-c4cccc5oc6ccccc6c45)n3)ccc2c1 ; c1ccc(-c2ccc3cc(-c4nc(-c5ccc6ccccc6c5)nc(-c5cccc6oc7ccccc7c56)n4)ccc3c2)cc1 ; c1ccc(-c2nc(-c3ccc(-c4ccccc4)c4ccccc34)nc(-c3cccc4oc5ccccc5c34)n2)cc1 ; c1ccc(-c2nc(-c3cccc4c(-c5ccccc5)cccc34)nc(-c3cccc4oc5ccccc5c34)n2)cc1]

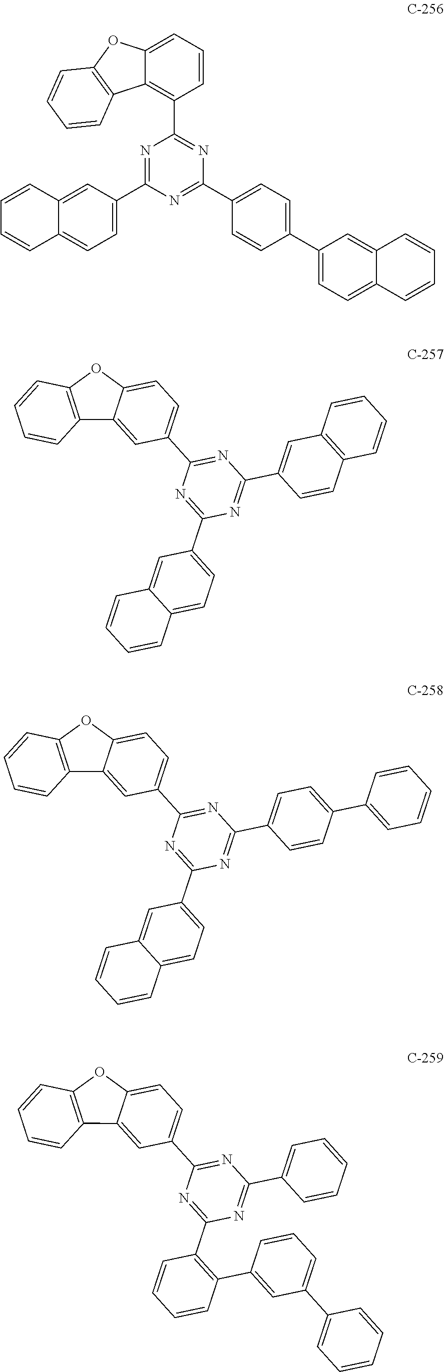 [SMILES: c1ccc2cc(-c3ccc(-c4nc(-c5ccc6ccccc6c5)nc(-c5cccc6oc7ccccc7c56)n4)cc3)ccc2c1 ; c1ccc2cc(-c3nc(-c4ccc5ccccc5c4)nc(-c4ccc5oc6ccccc6c5c4)n3)ccc2c1 ; c1ccc(-c2ccc(-c3nc(-c4ccc5ccccc5c4)nc(-c4ccc5oc6ccccc6c5c4)n3)cc2)cc1 ; c1ccc(-c2cccc(-c3ccccc3-c3nc(-c4ccccc4)nc(-c4ccc5oc6ccccc6c5c4)n3)c2)cc1]

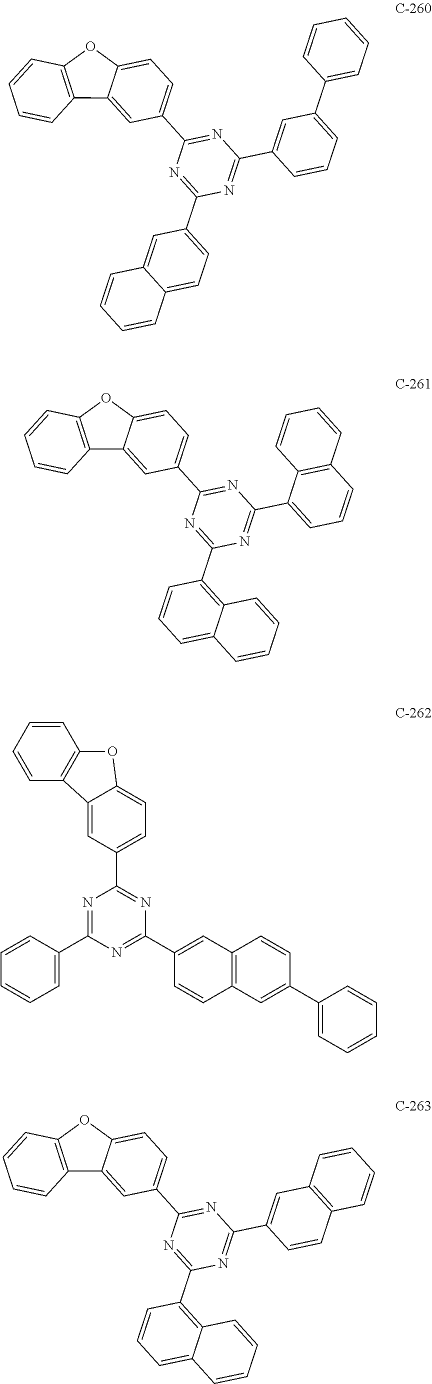 [SMILES: c1ccc(-c2cccc(-c3nc(-c4ccc5ccccc5c4)nc(-c4ccc5oc6ccccc6c5c4)n3)c2)cc1 ; c1ccc2c(-c3nc(-c4ccc5oc6ccccc6c5c4)nc(-c4cccc5ccccc45)n3)cccc2c1 ; c1ccc(-c2ccc3cc(-c4nc(-c5ccccc5)nc(-c5ccc6oc7ccccc7c6c5)n4)ccc3c2)cc1 ; c1ccc2cc(-c3nc(-c4ccc5oc6ccccc6c5c4)nc(-c4cccc5ccccc45)n3)ccc2c1]

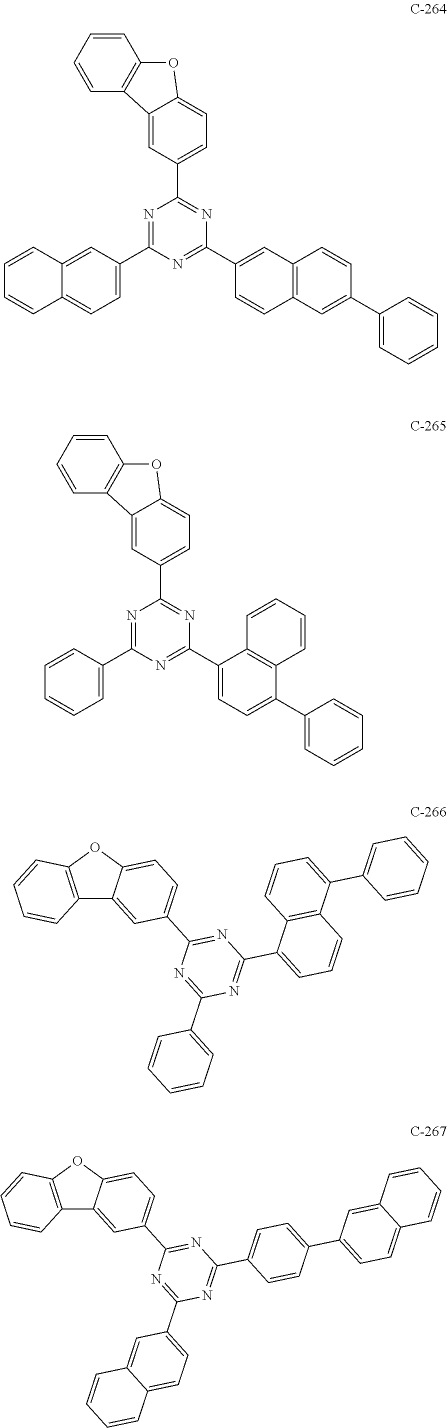 [SMILES: c1ccc(-c2ccc3cc(-c4nc(-c5ccc6ccccc6c5)nc(-c5ccc6oc7ccccc7c6c5)n4)ccc3c2)cc1 ; c1ccc(-c2nc(-c3ccc4oc5ccccc5c4c3)nc(-c3ccc(-c4ccccc4)c4ccccc34)n2)cc1 ; c1ccc(-c2nc(-c3ccc4oc5ccccc5c4c3)nc(-c3cccc4c(-c5ccccc5)cccc34)n2)cc1 ; c1ccc2cc(-c3ccc(-c4nc(-c5ccc6ccccc6c5)nc(-c5ccc6oc7ccccc7c6c5)n4)cc3)ccc2c1]

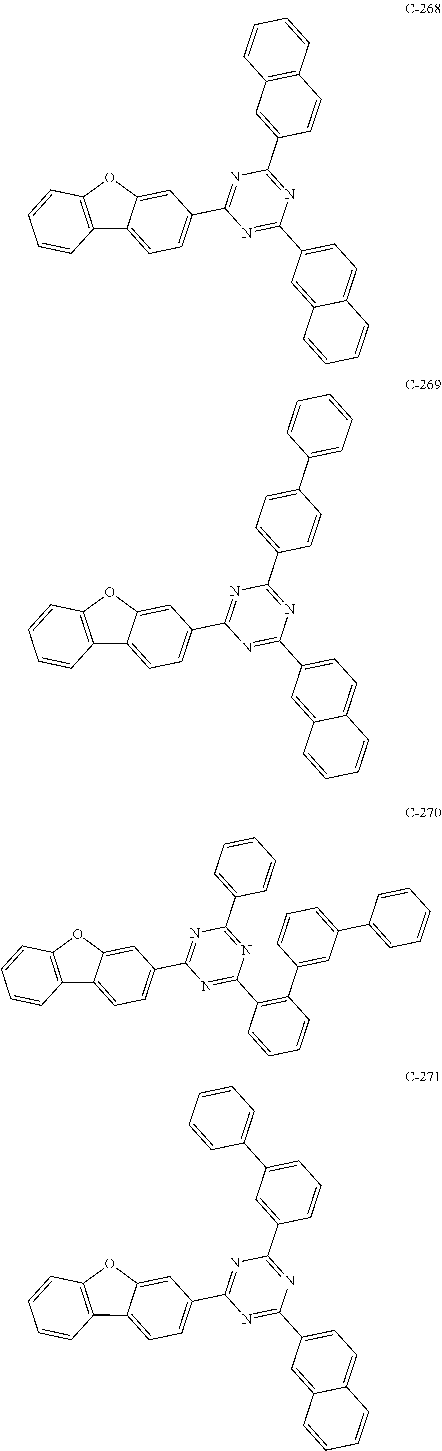

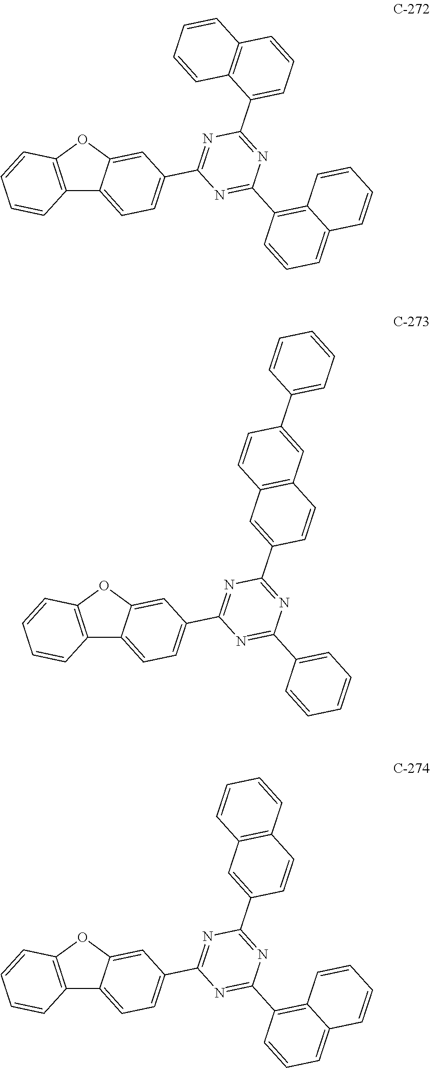 [SMILES: c1ccc2c(-c3nc(-c4ccc5c(c4)oc4ccccc45)nc(-c4cccc5ccccc45)n3)cccc2c1 ; c1ccc(-c2ccc3cc(-c4nc(-c5ccccc5)nc(-c5ccc6c(c5)oc5ccccc56)n4)ccc3c2)cc1 ; c1ccc2cc(-c3nc(-c4ccc5c(c4)oc4ccccc45)nc(-c4cccc5ccccc45)n3)ccc2c1]

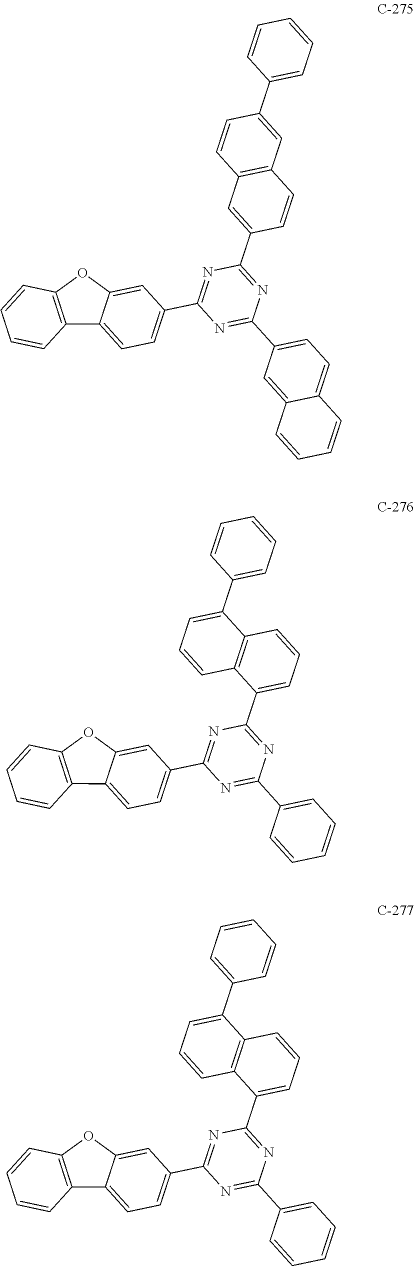 [SMILES: c1ccc(-c2ccc3cc(-c4nc(-c5ccc6ccccc6c5)nc(-c5ccc6c(c5)oc5ccccc56)n4)ccc3c2)cc1 ; c1ccc(-c2nc(-c3ccc4c(c3)oc3ccccc34)nc(-c3cccc4c(-c5ccccc5)cccc34)n2)cc1 ; c1ccc(-c2nc(-c3ccc4c(c3)oc3ccccc34)nc(-c3cccc4c(-c5ccccc5)cccc34)n2)cc1]

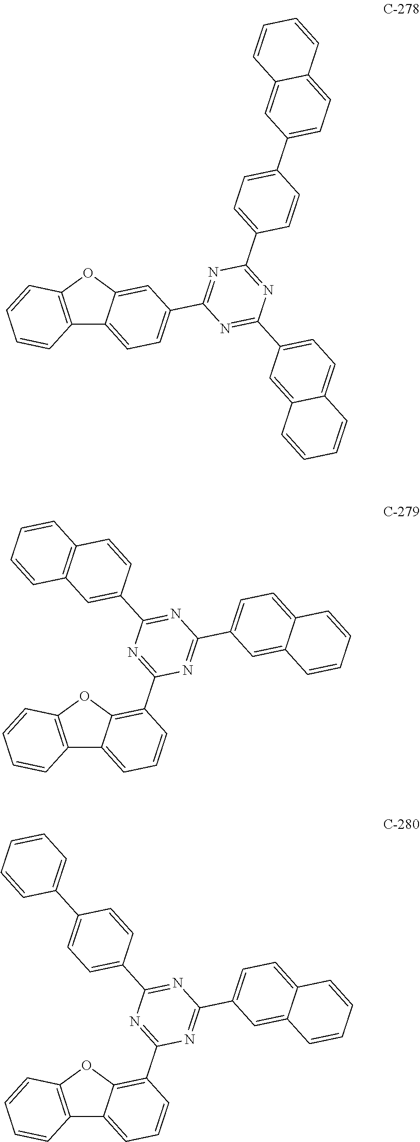 [SMILES: c1ccc2cc(-c3ccc(-c4nc(-c5ccc6ccccc6c5)nc(-c5ccc6c(c5)oc5ccccc56)n4)cc3)ccc2c1 ; c1ccc2cc(-c3nc(-c4ccc5ccccc5c4)nc(-c4cccc5c4oc4ccccc45)n3)ccc2c1 ; c1ccc(-c2ccc(-c3nc(-c4ccc5ccccc5c4)nc(-c4cccc5c4oc4ccccc45)n3)cc2)cc1]

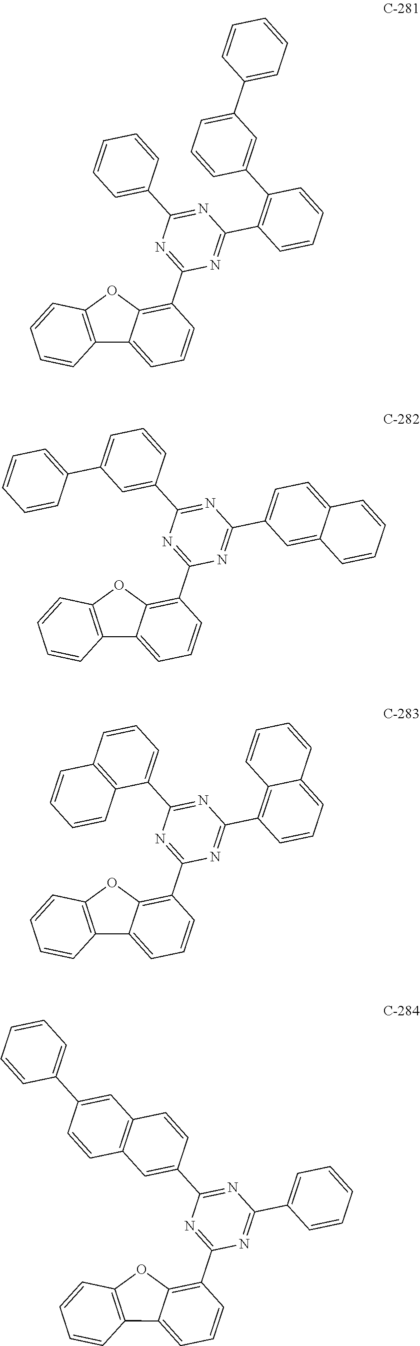 [SMILES: c1ccc(-c2cccc(-c3ccccc3-c3nc(-c4ccccc4)nc(-c4cccc5c4oc4ccccc45)n3)c2)cc1 ; c1ccc(-c2cccc(-c3nc(-c4ccc5ccccc5c4)nc(-c4cccc5c4oc4ccccc45)n3)c2)cc1 ; c1ccc2c(-c3nc(-c4cccc5ccccc45)nc(-c4cccc5c4oc4ccccc45)n3)cccc2c1 ; c1ccc(-c2ccc3cc(-c4nc(-c5ccccc5)nc(-c5cccc6c5oc5ccccc56)n4)ccc3c2)cc1]

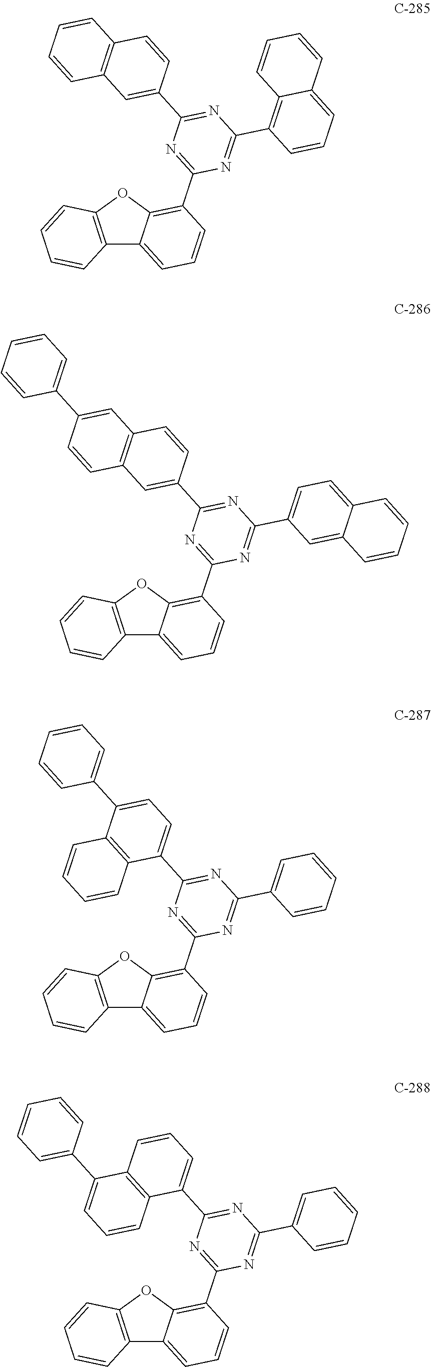 [SMILES: c1ccc2cc(-c3nc(-c4cccc5ccccc45)nc(-c4cccc5c4oc4ccccc45)n3)ccc2c1 ; c1ccc(-c2ccc3cc(-c4nc(-c5ccc6ccccc6c5)nc(-c5cccc6c5oc5ccccc56)n4)ccc3c2)cc1 ; c1ccc(-c2nc(-c3ccc(-c4ccccc4)c4ccccc34)nc(-c3cccc4c3oc3ccccc34)n2)cc1 ; c1ccc(-c2nc(-c3cccc4c(-c5ccccc5)cccc34)nc(-c3cccc4c3oc3ccccc34)n2)cc1]

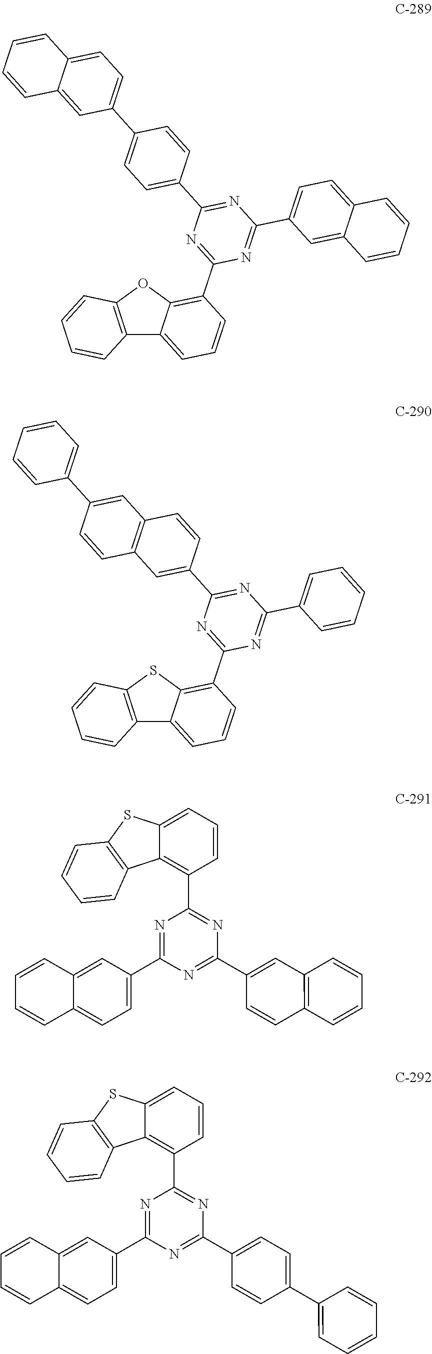 [SMILES: c1ccc2cc(-c3ccc(-c4nc(-c5ccc6ccccc6c5)nc(-c5cccc6c5oc5ccccc56)n4)cc3)ccc2c1 ; c1ccc(-c2ccc3cc(-c4nc(-c5ccccc5)nc(-c5cccc6c5sc5ccccc56)n4)ccc3c2)cc1 ; c1ccc2cc(-c3nc(-c4ccc5ccccc5c4)nc(-c4cccc5sc6ccccc6c45)n3)ccc2c1 ; c1ccc(-c2ccc(-c3nc(-c4ccc5ccccc5c4)nc(-c4cccc5sc6ccccc6c45)n3)cc2)cc1]

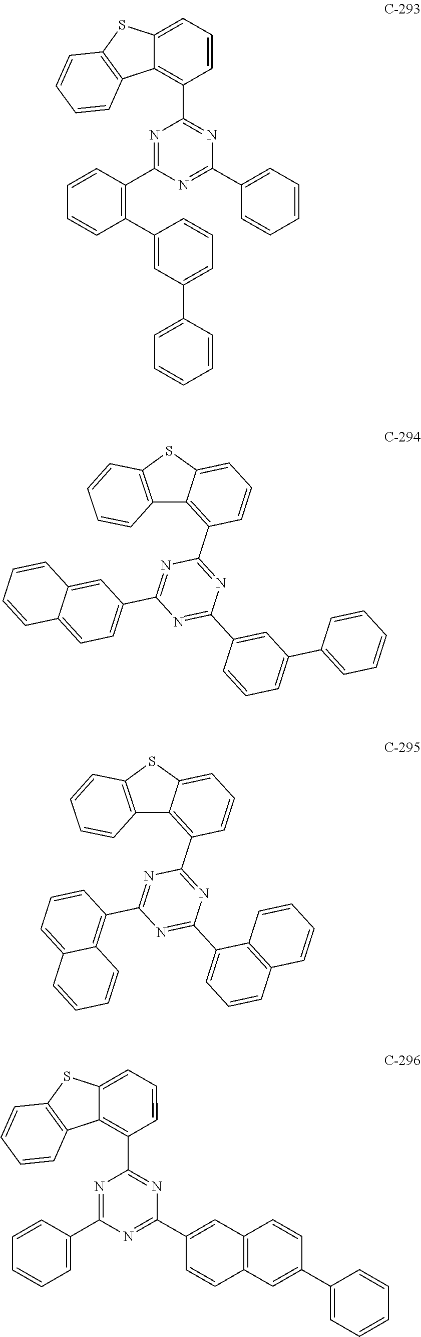 [SMILES: c1ccc(-c2cccc(-c3ccccc3-c3nc(-c4ccccc4)nc(-c4cccc5sc6ccccc6c45)n3)c2)cc1 ; c1ccc(-c2cccc(-c3nc(-c4ccc5ccccc5c4)nc(-c4cccc5sc6ccccc6c45)n3)c2)cc1 ; c1ccc2c(-c3nc(-c4cccc5ccccc45)nc(-c4cccc5sc6ccccc6c45)n3)cccc2c1 ; c1ccc(-c2ccc3cc(-c4nc(-c5ccccc5)nc(-c5cccc6sc7ccccc7c56)n4)ccc3c2)cc1]

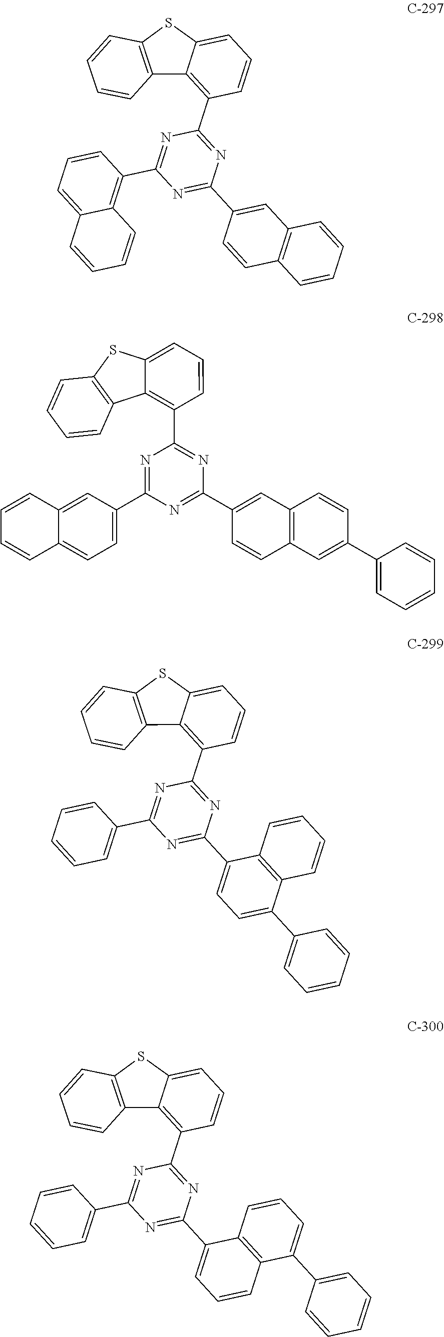 [SMILES: c1ccc2cc(-c3nc(-c4cccc5ccccc45)nc(-c4cccc5sc6ccccc6c45)n3)ccc2c1 ; c1ccc(-c2ccc3cc(-c4nc(-c5ccc6ccccc6c5)nc(-c5cccc6sc7ccccc7c56)n4)ccc3c2)cc1 ; c1ccc(-c2nc(-c3ccc(-c4ccccc4)c4ccccc34)nc(-c3cccc4sc5ccccc5c34)n2)cc1 ; c1ccc(-c2nc(-c3cccc4c(-c5ccccc5)cccc34)nc(-c3cccc4sc5ccccc5c34)n2)cc1]

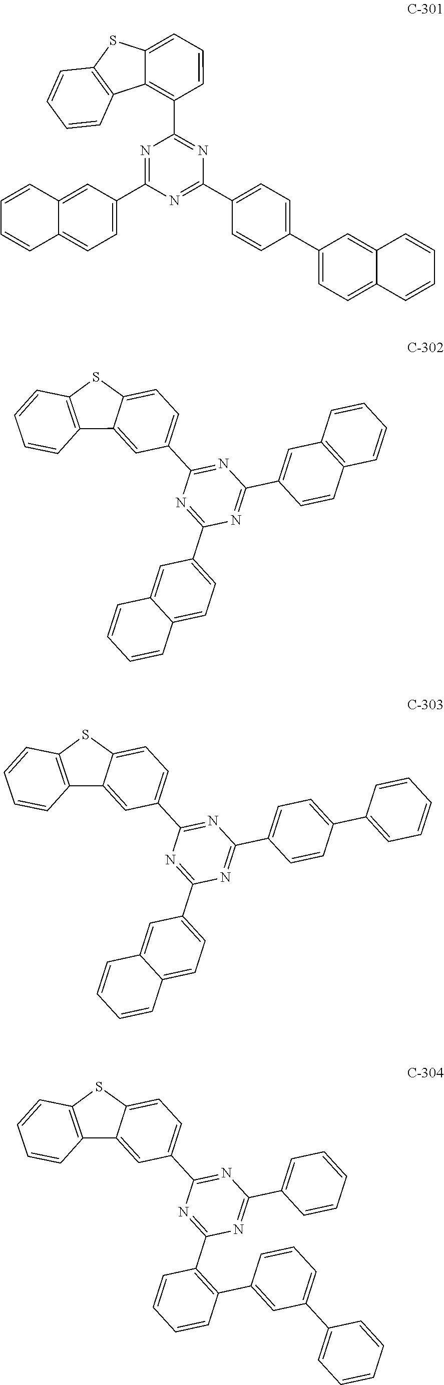 [SMILES: c1ccc2cc(-c3ccc(-c4nc(-c5ccc6ccccc6c5)nc(-c5cccc6sc7ccccc7c56)n4)cc3)ccc2c1 ; c1ccc2cc(-c3nc(-c4ccc5ccccc5c4)nc(-c4ccc5sc6ccccc6c5c4)n3)ccc2c1 ; c1ccc(-c2ccc(-c3nc(-c4ccc5ccccc5c4)nc(-c4ccc5sc6ccccc6c5c4)n3)cc2)cc1 ; c1ccc(-c2cccc(-c3ccccc3-c3nc(-c4ccccc4)nc(-c4ccc5sc6ccccc6c5c4)n3)c2)cc1]

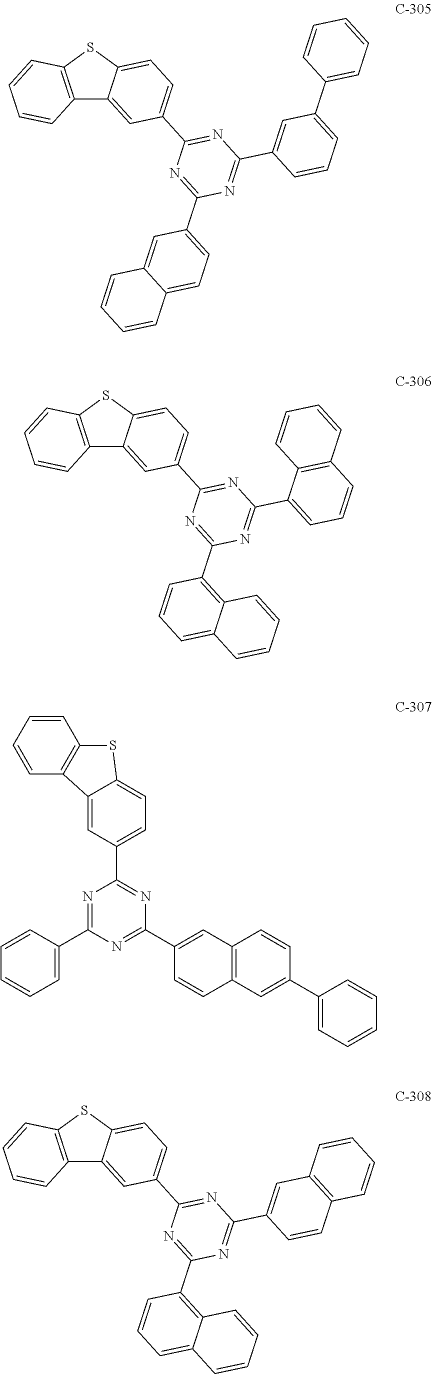 [SMILES: c1ccc(-c2cccc(-c3nc(-c4ccc5ccccc5c4)nc(-c4ccc5sc6ccccc6c5c4)n3)c2)cc1 ; c1ccc2c(-c3nc(-c4ccc5sc6ccccc6c5c4)nc(-c4cccc5ccccc45)n3)cccc2c1 ; c1ccc(-c2ccc3cc(-c4nc(-c5ccccc5)nc(-c5ccc6sc7ccccc7c6c5)n4)ccc3c2)cc1 ; c1ccc2cc(-c3nc(-c4ccc5sc6ccccc6c5c4)nc(-c4cccc5ccccc45)n3)ccc2c1]

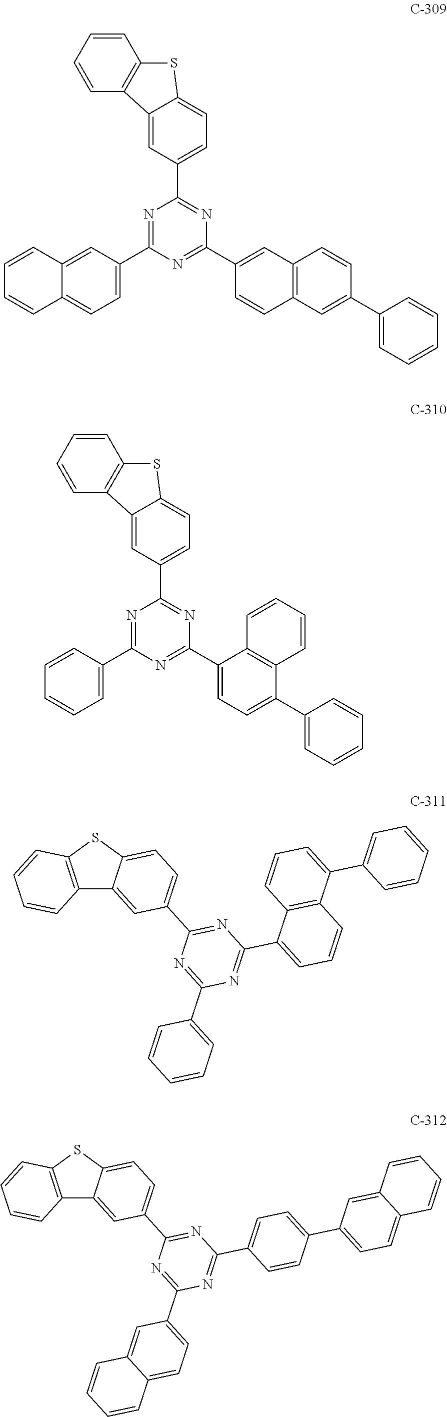 [SMILES: c1ccc(-c2ccc3cc(-c4nc(-c5ccc6ccccc6c5)nc(-c5ccc6sc7ccccc7c6c5)n4)ccc3c2)cc1 ; c1ccc(-c2nc(-c3ccc4sc5ccccc5c4c3)nc(-c3ccc(-c4ccccc4)c4ccccc34)n2)cc1 ; c1ccc(-c2nc(-c3ccc4sc5ccccc5c4c3)nc(-c3cccc4c(-c5ccccc5)cccc34)n2)cc1 ; c1ccc2cc(-c3ccc(-c4nc(-c5ccc6ccccc6c5)nc(-c5ccc6sc7ccccc7c6c5)n4)cc3)ccc2c1]

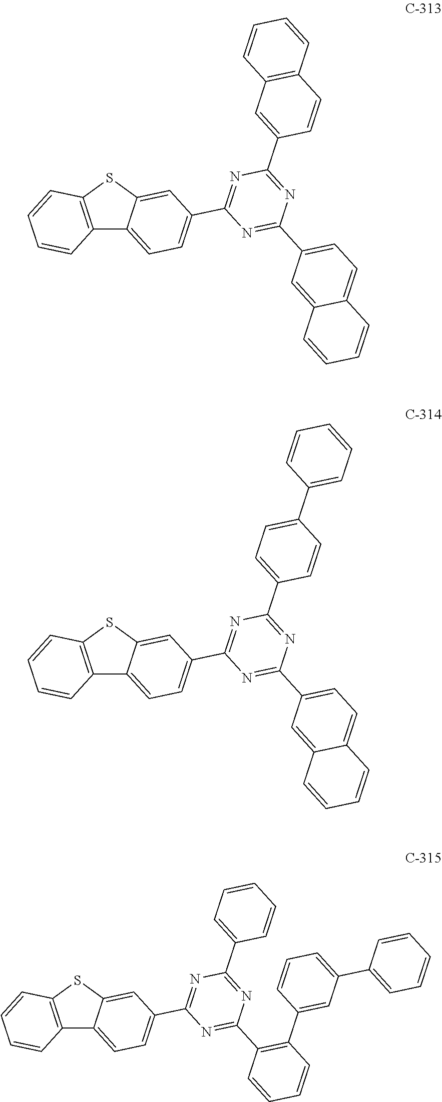 [SMILES: c1ccc2cc(-c3nc(-c4ccc5ccccc5c4)nc(-c4ccc5c(c4)sc4ccccc45)n3)ccc2c1 ; c1ccc(-c2ccc(-c3nc(-c4ccc5ccccc5c4)nc(-c4ccc5c(c4)sc4ccccc45)n3)cc2)cc1 ; c1ccc(-c2cccc(-c3ccccc3-c3nc(-c4ccccc4)nc(-c4ccc5c(c4)sc4ccccc45)n3)c2)cc1]

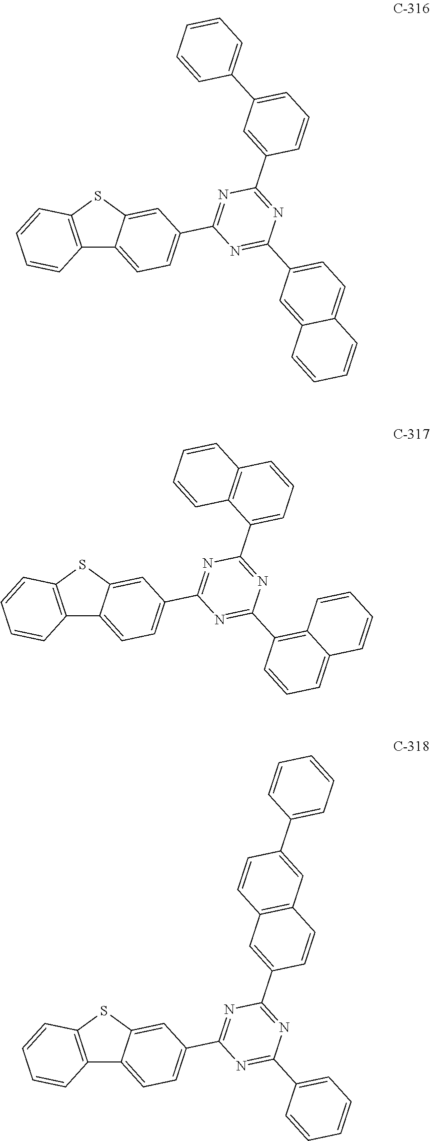 [SMILES: c1ccc(-c2cccc(-c3nc(-c4ccc5ccccc5c4)nc(-c4ccc5c(c4)sc4ccccc45)n3)c2)cc1 ; c1ccc2c(-c3nc(-c4ccc5c(c4)sc4ccccc45)nc(-c4cccc5ccccc45)n3)cccc2c1 ; c1ccc(-c2ccc3cc(-c4nc(-c5ccccc5)nc(-c5ccc6c(c5)sc5ccccc56)n4)ccc3c2)cc1]

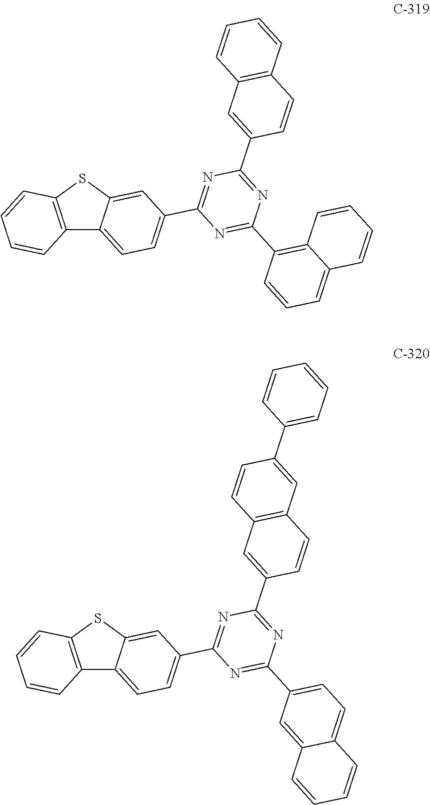 [SMILES: c1ccc2cc(-c3nc(-c4ccc5c(c4)sc4ccccc45)nc(-c4cccc5ccccc45)n3)ccc2c1 ; c1ccc(-c2ccc3cc(-c4nc(-c5ccc6ccccc6c5)nc(-c5ccc6c(c5)sc5ccccc56)n4)ccc3c2)cc1]

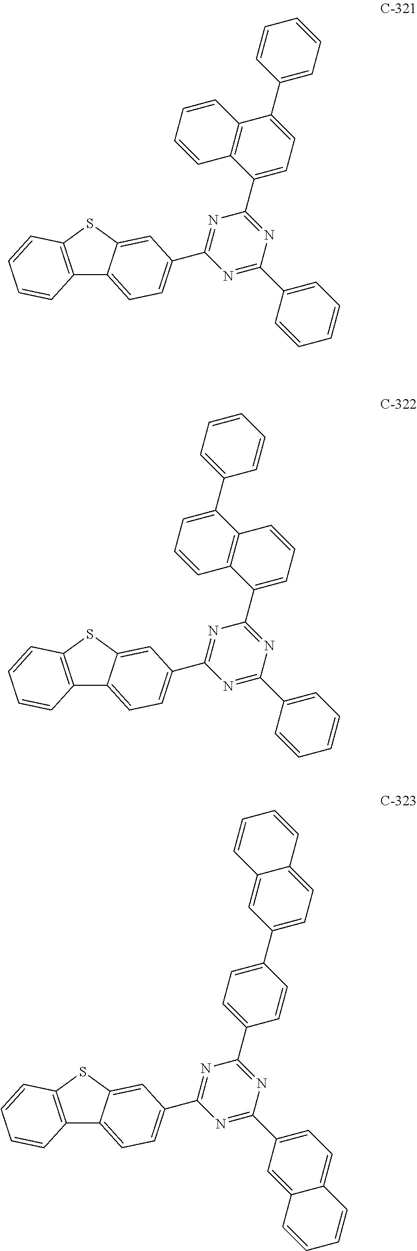 [SMILES: c1ccc(-c2nc(-c3ccc4c(c3)sc3ccccc34)nc(-c3ccc(-c4ccccc4)c4ccccc34)n2)cc1 ; c1ccc(-c2nc(-c3ccc4c(c3)sc3ccccc34)nc(-c3cccc4c(-c5ccccc5)cccc34)n2)cc1 ; c1ccc2cc(-c3ccc(-c4nc(-c5ccc6ccccc6c5)nc(-c5ccc6c(c5)sc5ccccc56)n4)cc3)ccc2c1]

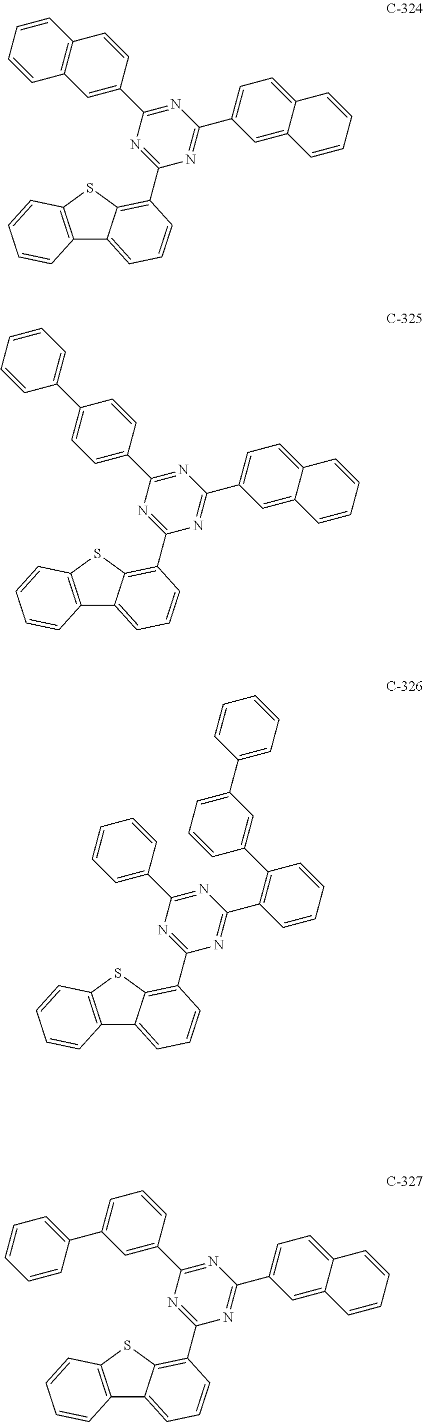 [SMILES: c1ccc2cc(-c3nc(-c4ccc5ccccc5c4)nc(-c4cccc5c4sc4ccccc45)n3)ccc2c1 ; c1ccc(-c2ccc(-c3nc(-c4ccc5ccccc5c4)nc(-c4cccc5c4sc4ccccc45)n3)cc2)cc1 ; c1ccc(-c2cccc(-c3ccccc3-c3nc(-c4ccccc4)nc(-c4cccc5c4sc4ccccc45)n3)c2)cc1 ; c1ccc(-c2cccc(-c3nc(-c4ccc5ccccc5c4)nc(-c4cccc5c4sc4ccccc45)n3)c2)cc1]

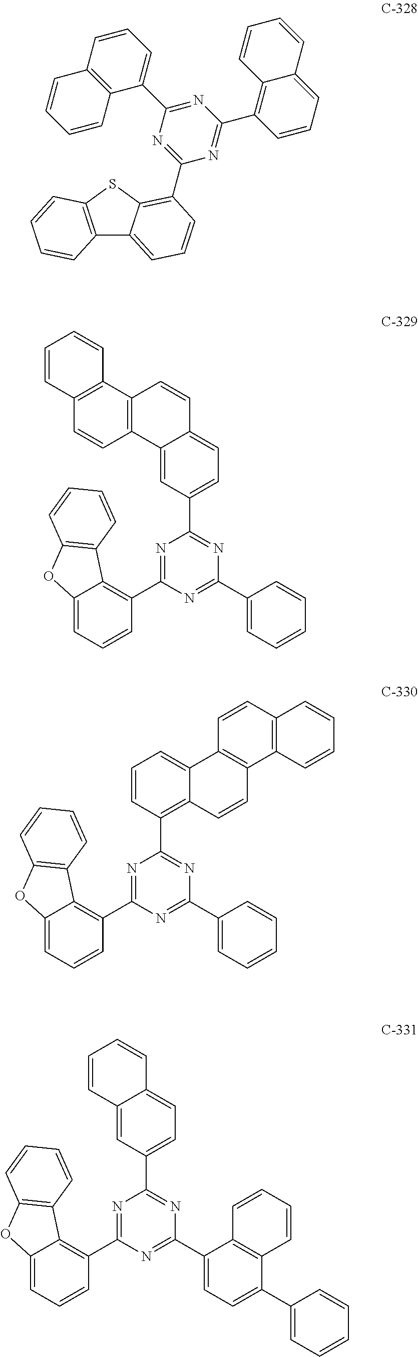 [SMILES: c1ccc2c(-c3nc(-c4cccc5ccccc45)nc(-c4cccc5c4sc4ccccc45)n3)cccc2c1 ; c1ccc(-c2nc(-c3ccc4ccc5c6ccccc6ccc5c4c3)nc(-c3cccc4oc5ccccc5c34)n2)cc1 ; c1ccc(-c2nc(-c3cccc4c3ccc3c5ccccc5ccc43)nc(-c3cccc4oc5ccccc5c34)n2)cc1 ; c1ccc(-c2ccc(-c3nc(-c4ccc5ccccc5c4)nc(-c4cccc5oc6ccccc6c45)n3)c3ccccc23)cc1]

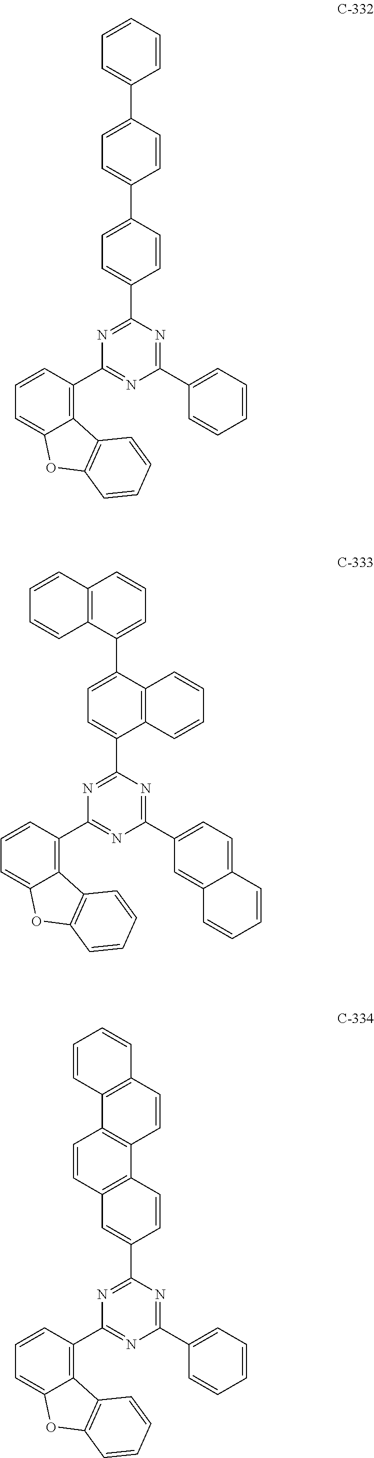 [SMILES: c1ccc(-c2ccc(-c3ccc(-c4nc(-c5ccccc5)nc(-c5cccc6oc7ccccc7c56)n4)cc3)cc2)cc1 ; c1ccc2cc(-c3nc(-c4ccc(-c5cccc6ccccc56)c5ccccc45)nc(-c4cccc5oc6ccccc6c45)n3)ccc2c1 ; c1ccc(-c2nc(-c3ccc4c(ccc5c6ccccc6ccc45)c3)nc(-c3cccc4oc5ccccc5c34)n2)cc1]

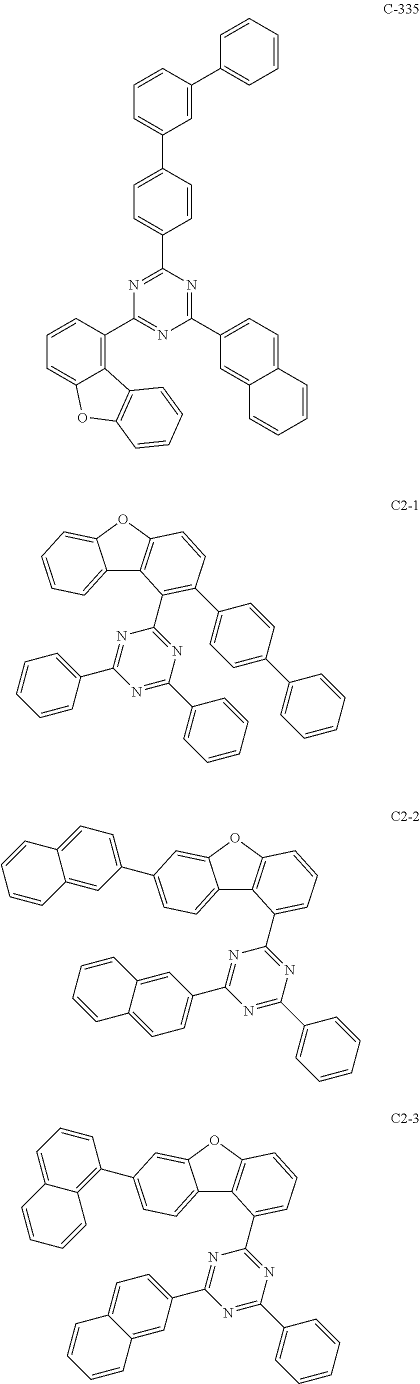 [SMILES: c1ccc(-c2cccc(-c3ccc(-c4nc(-c5ccc6ccccc6c5)nc(-c5cccc6oc7ccccc7c56)n4)cc3)c2)cc1 ; c1ccc(-c2ccc(-c3ccc4oc5ccccc5c4c3-c3nc(-c4ccccc4)nc(-c4ccccc4)n3)cc2)cc1 ; c1ccc(-c2nc(-c3ccc4ccccc4c3)nc(-c3cccc4oc5cc(-c6ccc7ccccc7c6)ccc5c34)n2)cc1 ; c1ccc(-c2nc(-c3ccc4ccccc4c3)nc(-c3cccc4oc5cc(-c6cccc7ccccc67)ccc5c34)n2)cc1]

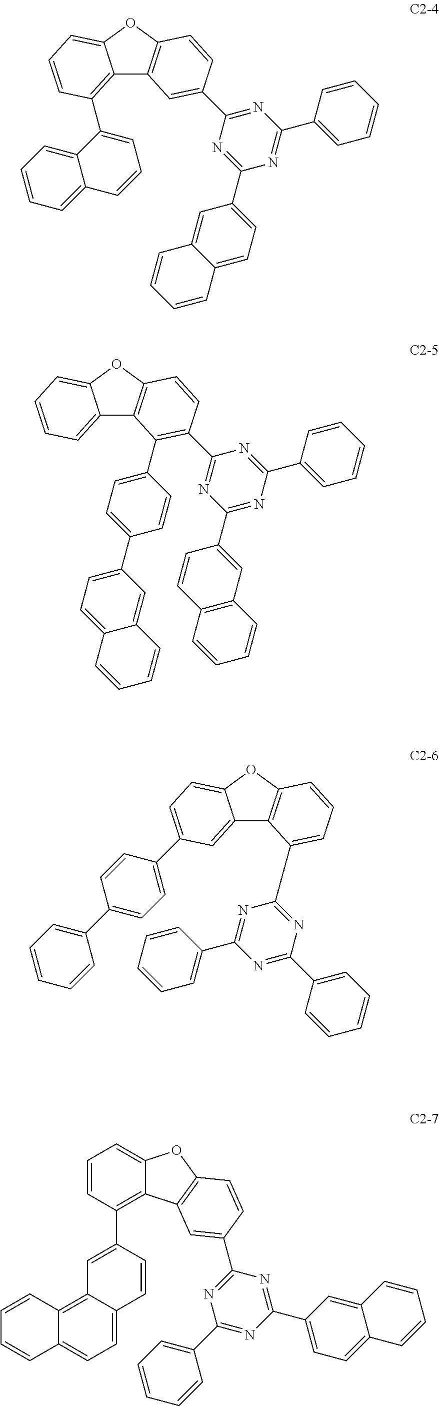 [SMILES: c1ccc(-c2nc(-c3ccc4ccccc4c3)nc(-c3ccc4oc5cccc(-c6cccc7ccccc67)c5c4c3)n2)cc1 ; c1ccc(-c2nc(-c3ccc4ccccc4c3)nc(-c3ccc4oc5ccccc5c4c3-c3ccc(-c4ccc5ccccc5c4)cc3)n2)cc1 ; c1ccc(-c2ccc(-c3ccc4oc5cccc(-c6nc(-c7ccccc7)nc(-c7ccccc7)n6)c5c4c3)cc2)cc1 ; c1ccc(-c2nc(-c3ccc4ccccc4c3)nc(-c3ccc4oc5cccc(-c6ccc7ccc8ccccc8c7c6)c5c4c3)n2)cc1]

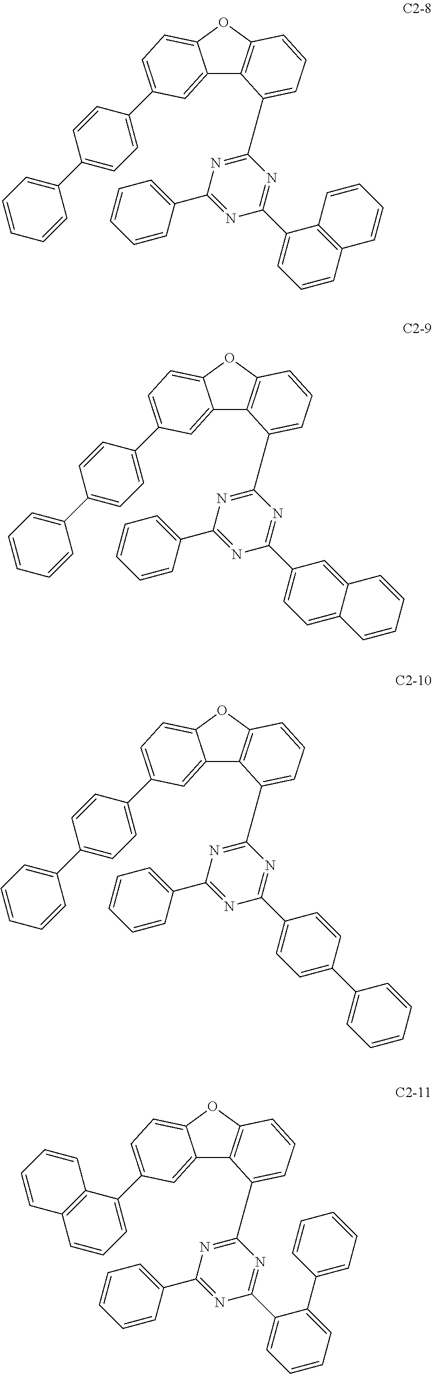 [SMILES: c1ccc(-c2ccc(-c3ccc4oc5cccc(-c6nc(-c7ccccc7)nc(-c7cccc8ccccc78)n6)c5c4c3)cc2)cc1 ; c1ccc(-c2ccc(-c3ccc4oc5cccc(-c6nc(-c7ccccc7)nc(-c7ccc8ccccc8c7)n6)c5c4c3)cc2)cc1 ; c1ccc(-c2ccc(-c3ccc4oc5cccc(-c6nc(-c7ccccc7)nc(-c7ccc(-c8ccccc8)cc7)n6)c5c4c3)cc2)cc1 ; c1ccc(-c2nc(-c3ccccc3-c3ccccc3)nc(-c3cccc4oc5ccc(-c6cccc7ccccc67)cc5c34)n2)cc1]

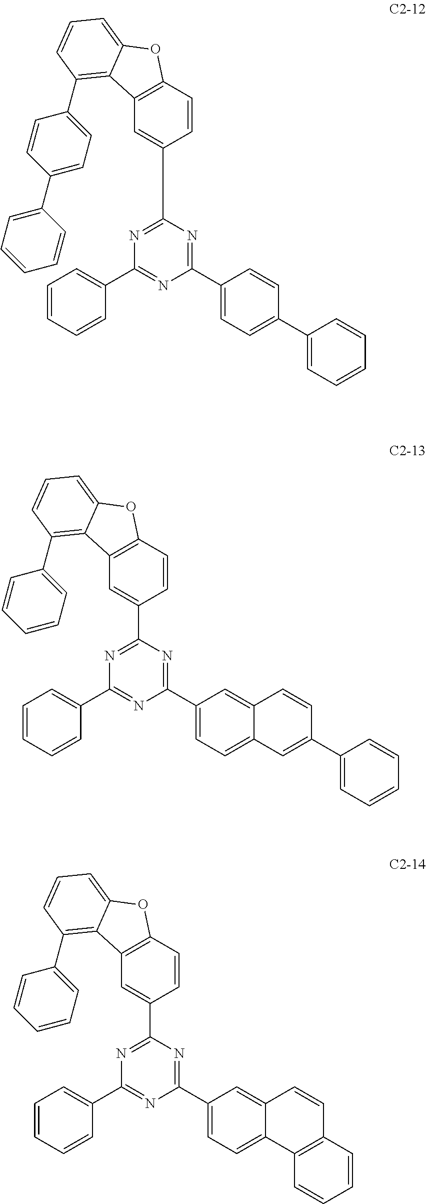 [SMILES: c1ccc(-c2ccc(-c3nc(-c4ccccc4)nc(-c4ccc5oc6cccc(-c7ccc(-c8ccccc8)cc7)c6c5c4)n3)cc2)cc1 ; c1ccc(-c2ccc3cc(-c4nc(-c5ccccc5)nc(-c5ccc6oc7cccc(-c8ccccc8)c7c6c5)n4)ccc3c2)cc1 ; c1ccc(-c2nc(-c3ccc4c(ccc5ccccc54)c3)nc(-c3ccc4oc5cccc(-c6ccccc6)c5c4c3)n2)cc1]

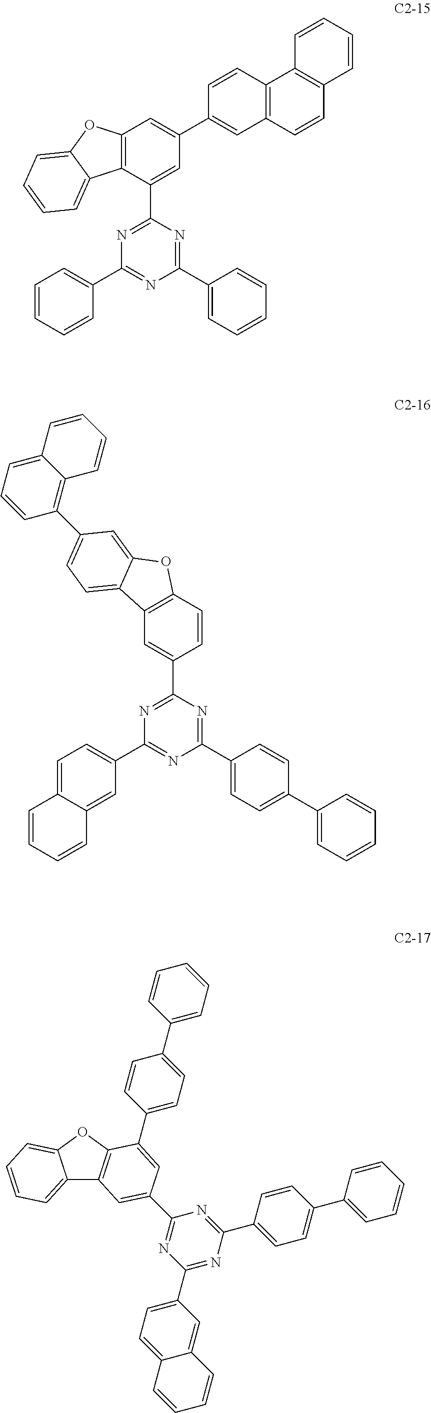 [SMILES: c1ccc(-c2nc(-c3ccccc3)nc(-c3cc(-c4ccc5c(ccc6ccccc65)c4)cc4oc5ccccc5c34)n2)cc1 ; c1ccc(-c2ccc(-c3nc(-c4ccc5ccccc5c4)nc(-c4ccc5oc6cc(-c7cccc8ccccc78)ccc6c5c4)n3)cc2)cc1 ; c1ccc(-c2ccc(-c3nc(-c4ccc5ccccc5c4)nc(-c4cc(-c5ccc(-c6ccccc6)cc5)c5oc6ccccc6c5c4)n3)cc2)cc1]

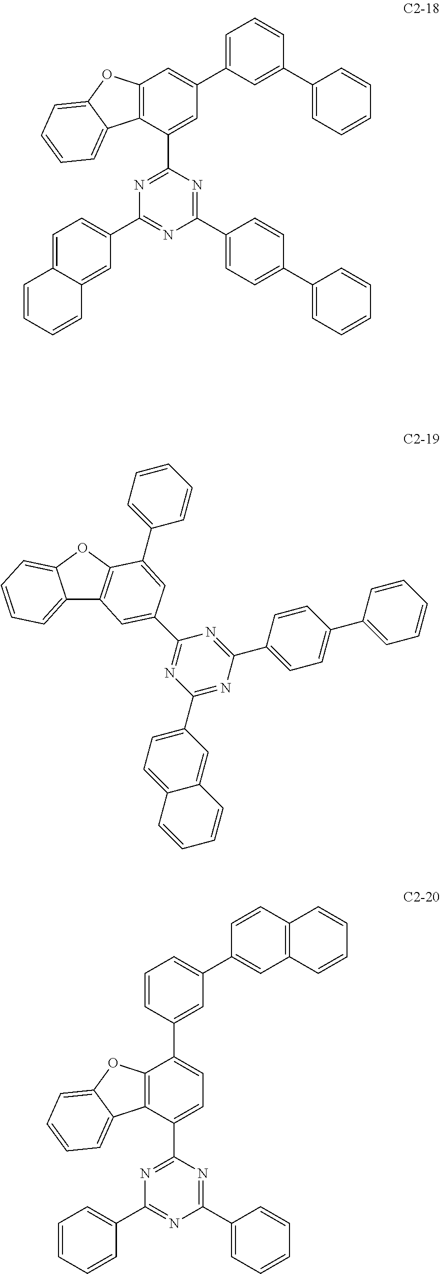 [SMILES: c1ccc(-c2ccc(-c3nc(-c4ccc5ccccc5c4)nc(-c4cc(-c5cccc(-c6ccccc6)c5)cc5oc6ccccc6c45)n3)cc2)cc1 ; c1ccc(-c2ccc(-c3nc(-c4ccc5ccccc5c4)nc(-c4cc(-c5ccccc5)c5oc6ccccc6c5c4)n3)cc2)cc1 ; c1ccc(-c2nc(-c3ccccc3)nc(-c3ccc(-c4cccc(-c5ccc6ccccc6c5)c4)c4oc5ccccc5c34)n2)cc1]

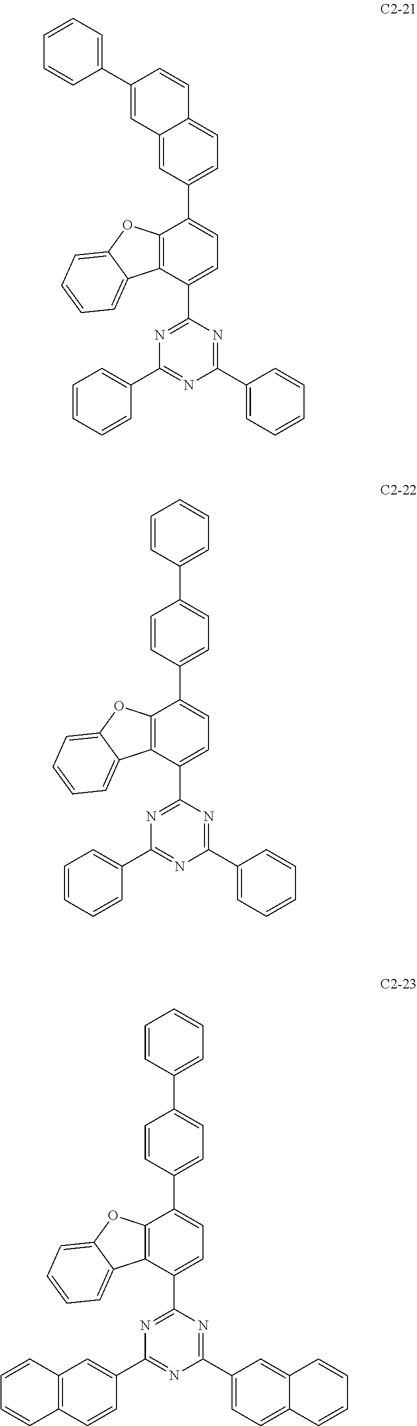 [SMILES: c1ccc(-c2ccc3ccc(-c4ccc(-c5nc(-c6ccccc6)nc(-c6ccccc6)n5)c5c4oc4ccccc45)cc3c2)cc1 ; c1ccc(-c2ccc(-c3ccc(-c4nc(-c5ccccc5)nc(-c5ccccc5)n4)c4c3oc3ccccc34)cc2)cc1 ; c1ccc(-c2ccc(-c3ccc(-c4nc(-c5ccc6ccccc6c5)nc(-c5ccc6ccccc6c5)n4)c4c3oc3ccccc34)cc2)cc1]

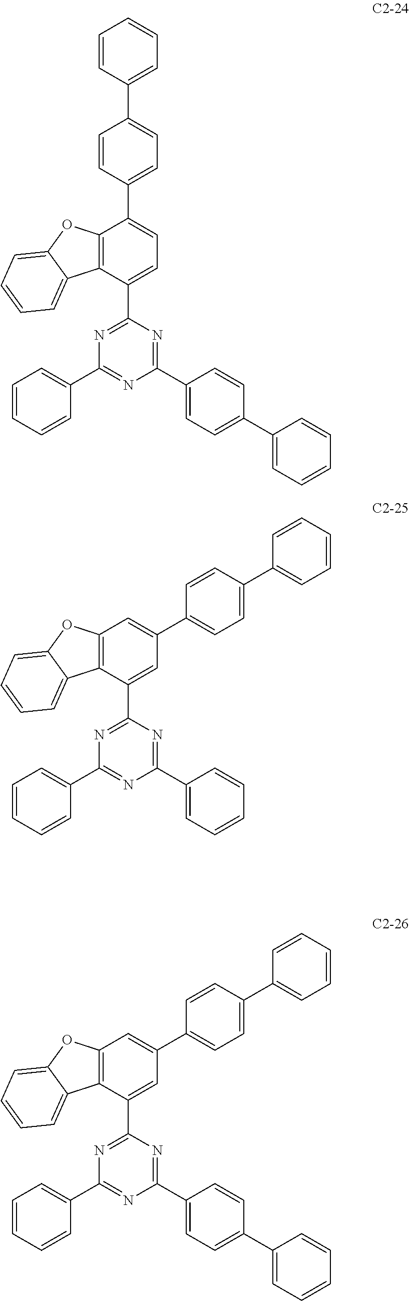

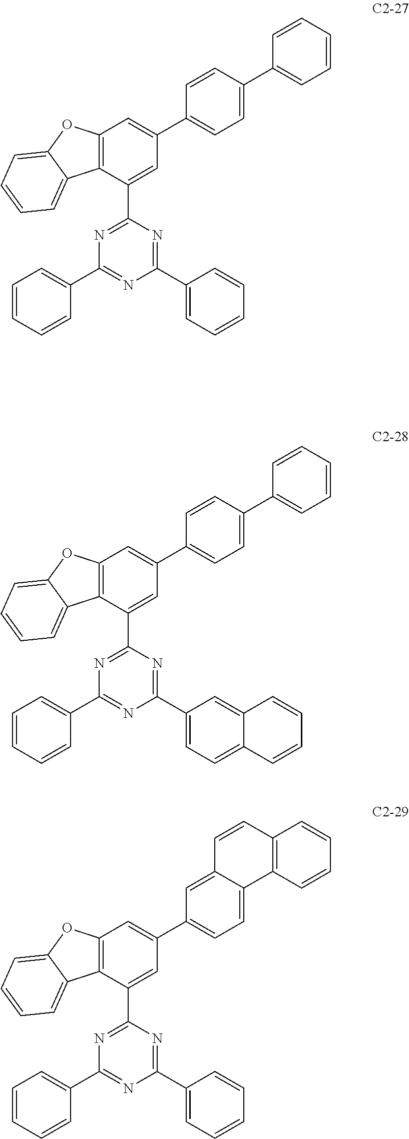 [SMILES: c1ccc(-c2ccc(-c3cc(-c4nc(-c5ccccc5)nc(-c5ccccc5)n4)c4c(c3)oc3ccccc34)cc2)cc1 ; c1ccc(-c2ccc(-c3cc(-c4nc(-c5ccccc5)nc(-c5ccc6ccccc6c5)n4)c4c(c3)oc3ccccc34)cc2)cc1 ; c1ccc(-c2nc(-c3ccccc3)nc(-c3cc(-c4ccc5c(ccc6ccccc65)c4)cc4oc5ccccc5c34)n2)cc1]

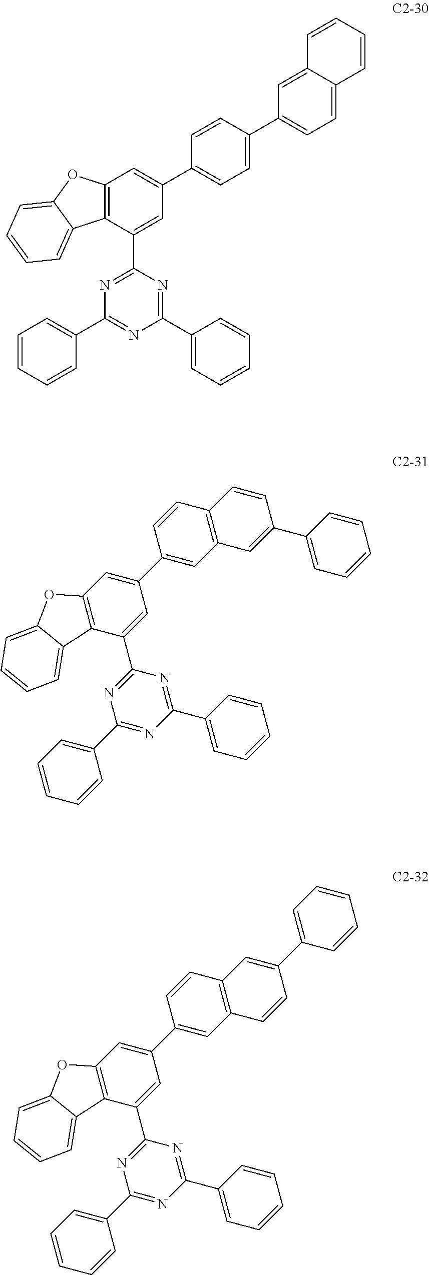 [SMILES: c1ccc(-c2nc(-c3ccccc3)nc(-c3cc(-c4ccc(-c5ccc6ccccc6c5)cc4)cc4oc5ccccc5c34)n2)cc1 ; c1ccc(-c2ccc3ccc(-c4cc(-c5nc(-c6ccccc6)nc(-c6ccccc6)n5)c5c(c4)oc4ccccc45)cc3c2)cc1 ; c1ccc(-c2ccc3cc(-c4cc(-c5nc(-c6ccccc6)nc(-c6ccccc6)n5)c5c(c4)oc4ccccc45)ccc3c2)cc1]

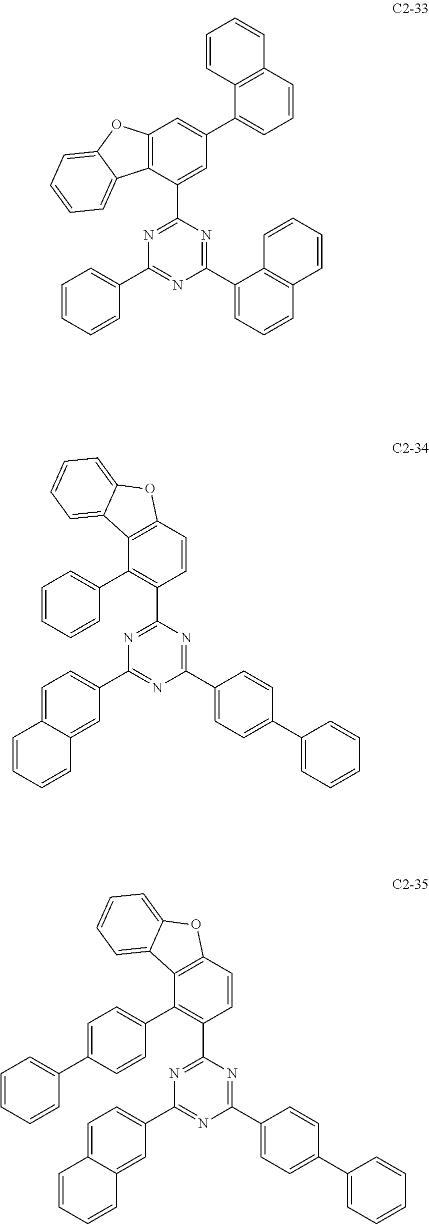 [SMILES: c1ccc(-c2nc(-c3cccc4ccccc34)nc(-c3cc(-c4cccc5ccccc45)cc4oc5ccccc5c34)n2)cc1 ; c1ccc(-c2ccc(-c3nc(-c4ccc5ccccc5c4)nc(-c4ccc5oc6ccccc6c5c4-c4ccccc4)n3)cc2)cc1 ; c1ccc(-c2ccc(-c3nc(-c4ccc5ccccc5c4)nc(-c4ccc5oc6ccccc6c5c4-c4ccc(-c5ccccc5)cc4)n3)cc2)cc1]

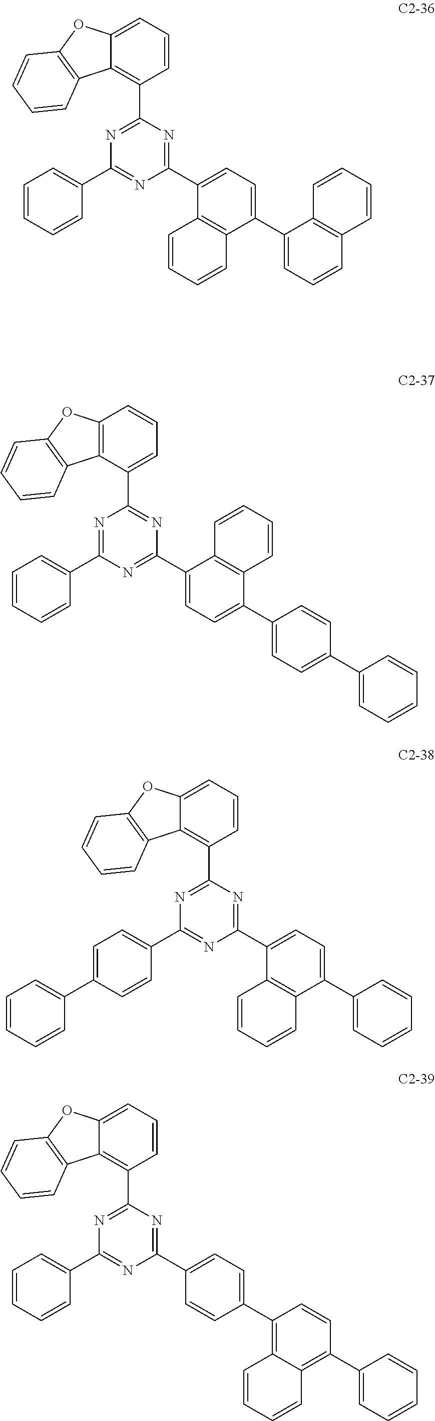 [SMILES: c1ccc(-c2nc(-c3ccc(-c4cccc5ccccc45)c4ccccc34)nc(-c3cccc4oc5ccccc5c34)n2)cc1 ; c1ccc(-c2ccc(-c3ccc(-c4nc(-c5ccccc5)nc(-c5cccc6oc7ccccc7c56)n4)c4ccccc34)cc2)cc1 ; c1ccc(-c2ccc(-c3nc(-c4ccc(-c5ccccc5)c5ccccc45)nc(-c4cccc5oc6ccccc6c45)n3)cc2)cc1 ; c1ccc(-c2nc(-c3ccc(-c4ccc(-c5ccccc5)c5ccccc45)cc3)nc(-c3cccc4oc5ccccc5c34)n2)cc1]

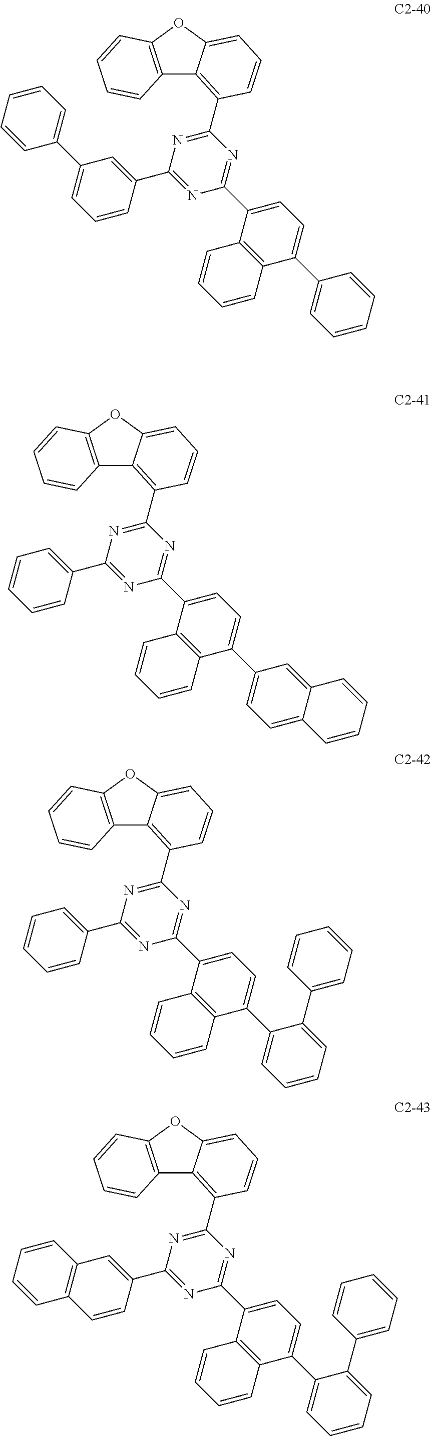 [SMILES: c1ccc(-c2cccc(-c3nc(-c4ccc(-c5ccccc5)c5ccccc45)nc(-c4cccc5oc6ccccc6c45)n3)c2)cc1 ; c1ccc(-c2nc(-c3ccc(-c4ccc5ccccc5c4)c4ccccc34)nc(-c3cccc4oc5ccccc5c34)n2)cc1 ; c1ccc(-c2nc(-c3ccc(-c4ccccc4-c4ccccc4)c4ccccc34)nc(-c3cccc4oc5ccccc5c34)n2)cc1 ; c1ccc(-c2ccccc2-c2ccc(-c3nc(-c4ccc5ccccc5c4)nc(-c4cccc5oc6ccccc6c45)n3)c3ccccc23)cc1]

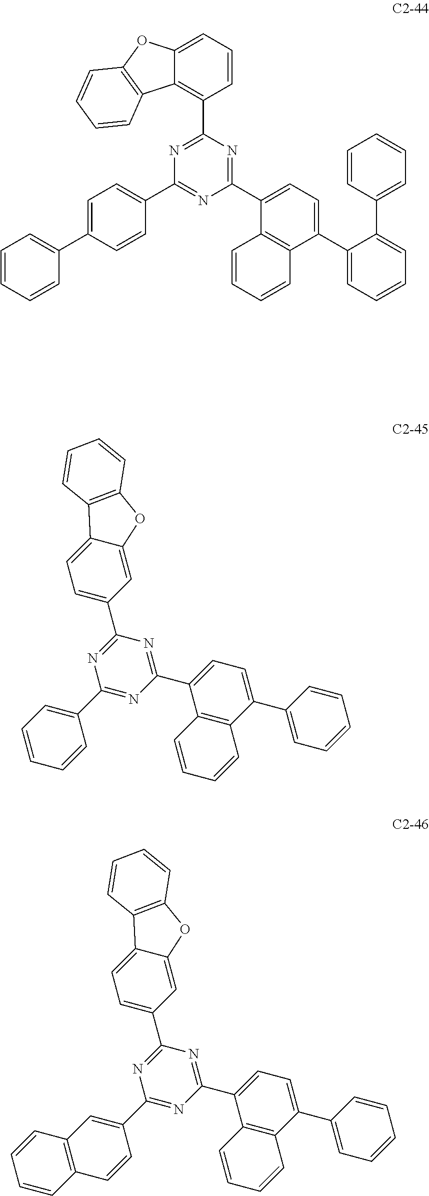 [SMILES: c1ccc(-c2ccc(-c3nc(-c4ccc(-c5ccccc5-c5ccccc5)c5ccccc45)nc(-c4cccc5oc6ccccc6c45)n3)cc2)cc1 ; c1ccc(-c2nc(-c3ccc4c(c3)oc3ccccc34)nc(-c3ccc(-c4ccccc4)c4ccccc34)n2)cc1 ; c1ccc(-c2ccc(-c3nc(-c4ccc5ccccc5c4)nc(-c4ccc5c(c4)oc4ccccc45)n3)c3ccccc23)cc1]

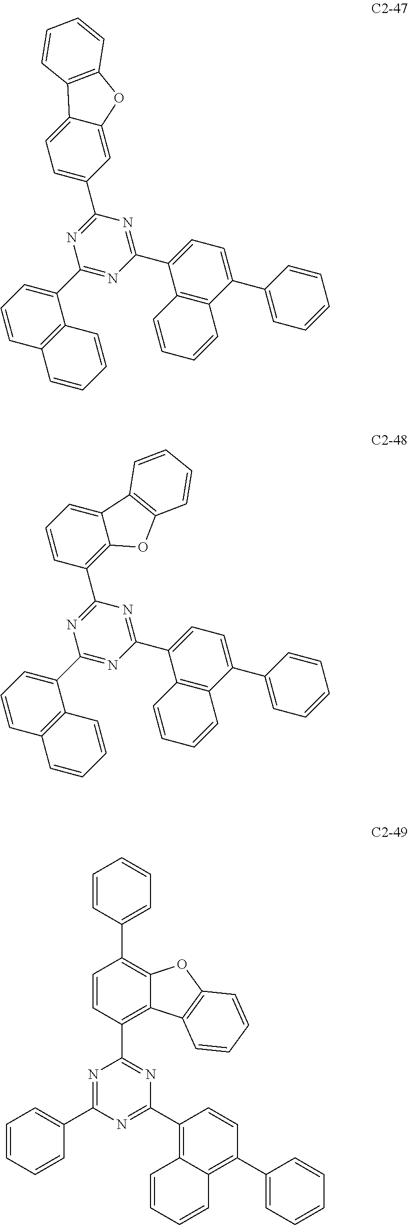 [SMILES: c1ccc(-c2ccc(-c3nc(-c4ccc5c(c4)oc4ccccc45)nc(-c4cccc5ccccc45)n3)c3ccccc23)cc1 ; c1ccc(-c2ccc(-c3nc(-c4cccc5ccccc45)nc(-c4cccc5c4oc4ccccc45)n3)c3ccccc23)cc1 ; c1ccc(-c2nc(-c3ccc(-c4ccccc4)c4ccccc34)nc(-c3ccc(-c4ccccc4)c4oc5ccccc5c34)n2)cc1]

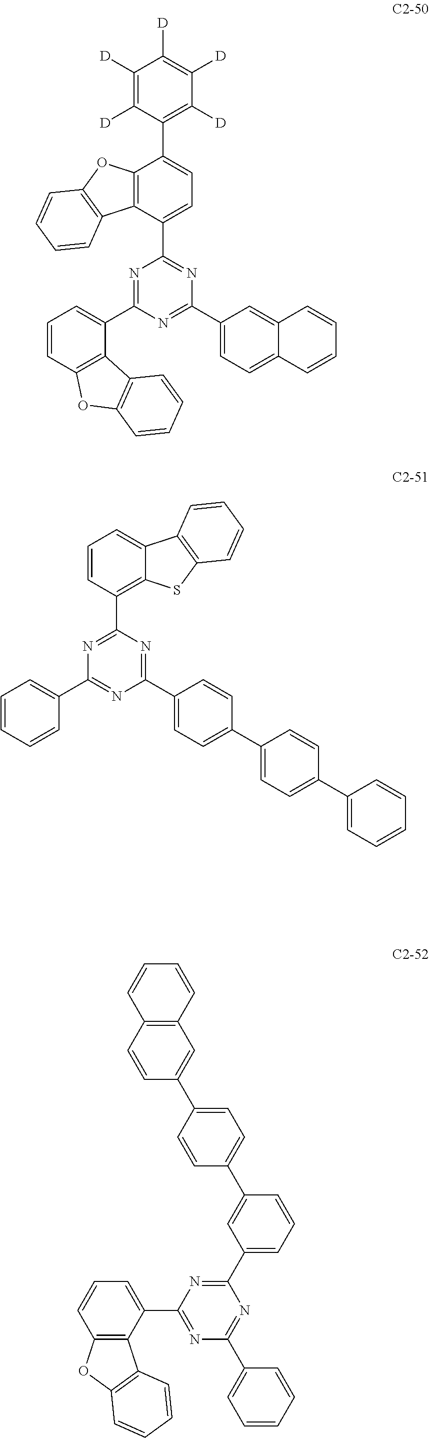 [SMILES: [2H]c1c([2H])c([2H])c(-c2ccc(-c3nc(-c4ccc5ccccc5c4)nc(-c4cccc5oc6ccccc6c45)n3)c3c2oc2ccccc23)c([2H])c1[2H] ; c1ccc(-c2ccc(-c3ccc(-c4nc(-c5ccccc5)nc(-c5cccc6c5sc5ccccc56)n4)cc3)cc2)cc1 ; c1ccc(-c2nc(-c3cccc(-c4ccc(-c5ccc6ccccc6c5)cc4)c3)nc(-c3cccc4oc5ccccc5c34)n2)cc1]

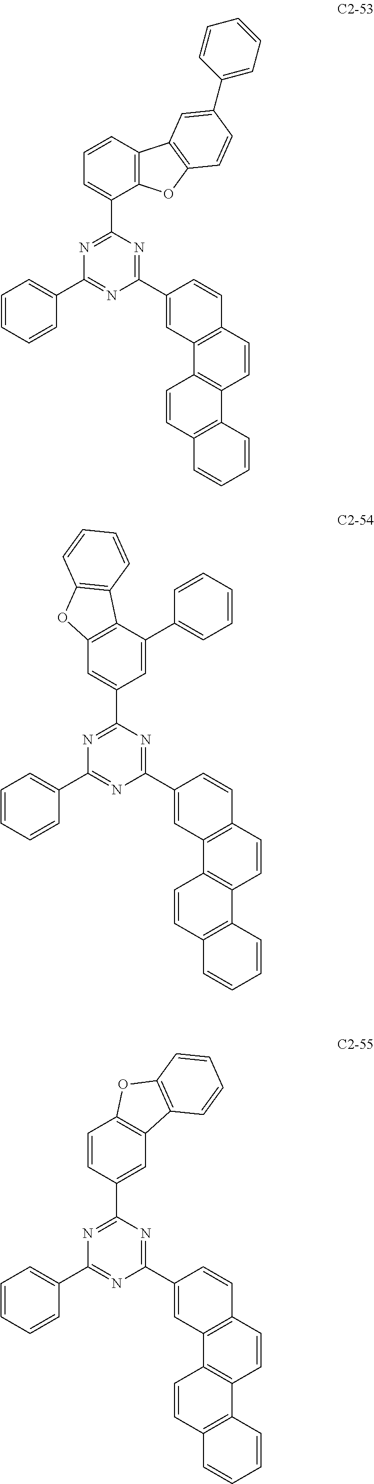 [SMILES: c1ccc(-c2ccc3oc4c(-c5nc(-c6ccccc6)nc(-c6ccc7ccc8c9ccccc9ccc8c7c6)n5)cccc4c3c2)cc1 ; c1ccc(-c2nc(-c3cc(-c4ccccc4)c4c(c3)oc3ccccc34)nc(-c3ccc4ccc5c6ccccc6ccc5c4c3)n2)cc1 ; c1ccc(-c2nc(-c3ccc4ccc5c6ccccc6ccc5c4c3)nc(-c3ccc4oc5ccccc5c4c3)n2)cc1]

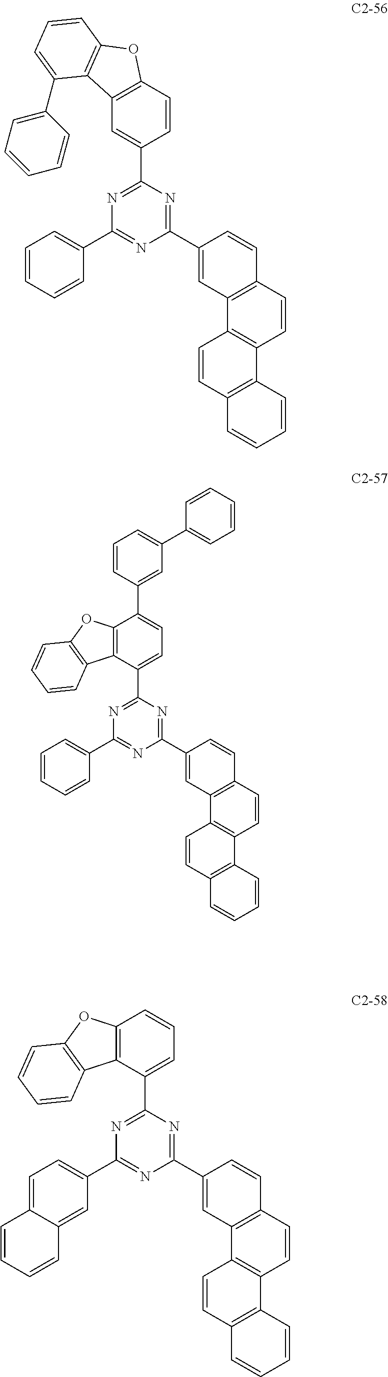 [SMILES: c1ccc(-c2nc(-c3ccc4ccc5c6ccccc6ccc5c4c3)nc(-c3ccc4oc5cccc(-c6ccccc6)c5c4c3)n2)cc1 ; c1ccc(-c2cccc(-c3ccc(-c4nc(-c5ccccc5)nc(-c5ccc6ccc7c8ccccc8ccc7c6c5)n4)c4c3oc3ccccc34)c2)cc1 ; c1ccc2cc(-c3nc(-c4ccc5ccc6c7ccccc7ccc6c5c4)nc(-c4cccc5oc6ccccc6c45)n3)ccc2c1]

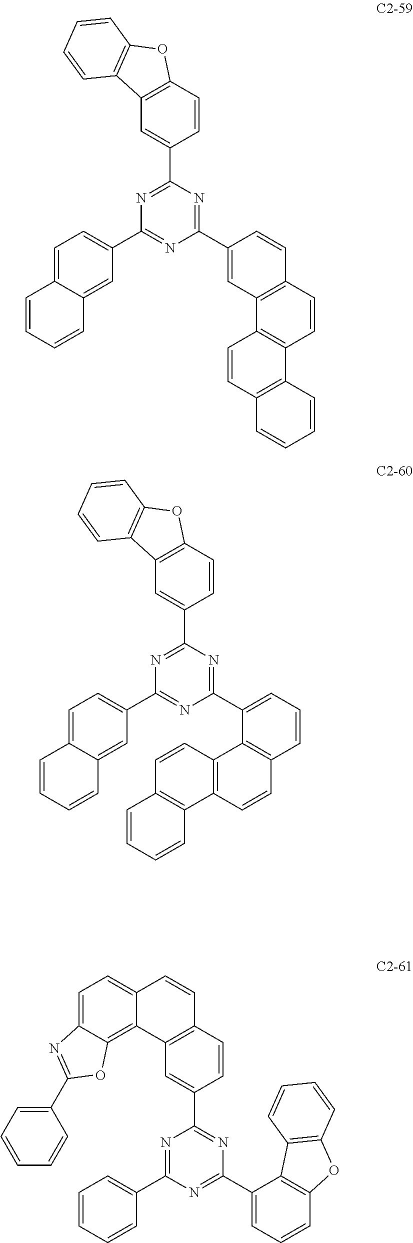 [SMILES: c1ccc2cc(-c3nc(-c4ccc5ccc6c7ccccc7ccc6c5c4)nc(-c4ccc5oc6ccccc6c5c4)n3)ccc2c1 ; c1ccc2cc(-c3nc(-c4ccc5oc6ccccc6c5c4)nc(-c4cccc5ccc6c7ccccc7ccc6c45)n3)ccc2c1 ; c1ccc(-c2nc(-c3ccc4ccc5ccc6nc(-c7ccccc7)oc6c5c4c3)nc(-c3cccc4oc5ccccc5c34)n2)cc1]

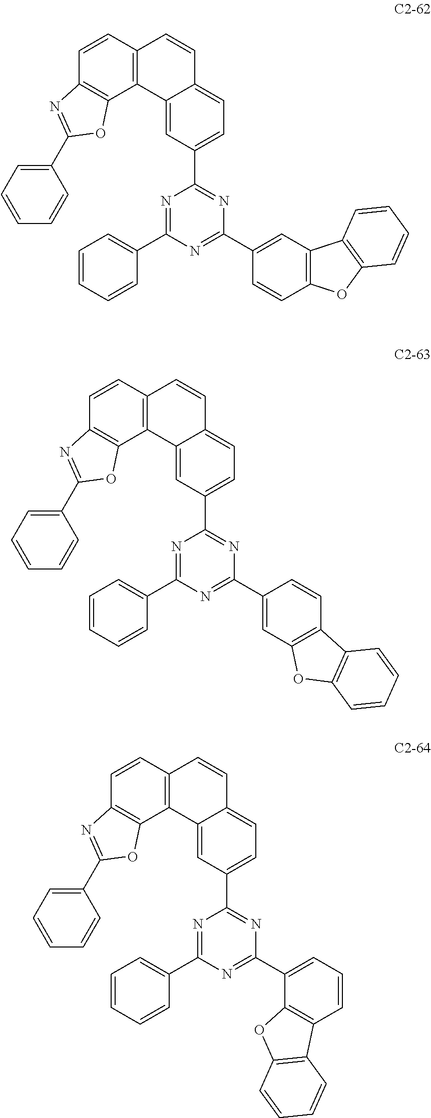 [SMILES: c1ccc(-c2nc(-c3ccc4oc5ccccc5c4c3)nc(-c3ccc4ccc5ccc6nc(-c7ccccc7)oc6c5c4c3)n2)cc1 ; c1ccc(-c2nc(-c3ccc4c(c3)oc3ccccc34)nc(-c3ccc4ccc5ccc6nc(-c7ccccc7)oc6c5c4c3)n2)cc1 ; c1ccc(-c2nc(-c3ccc4ccc5ccc6nc(-c7ccccc7)oc6c5c4c3)nc(-c3cccc4c3oc3ccccc34)n2)cc1]

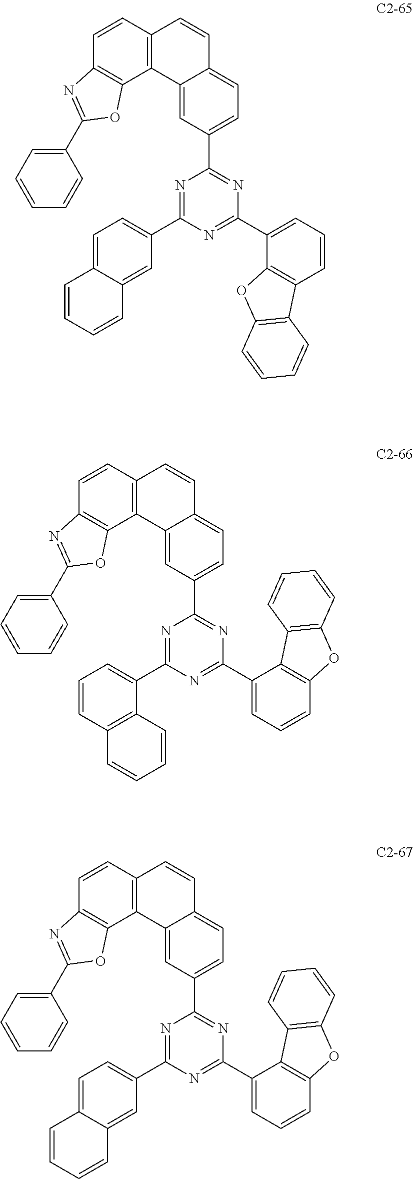 [SMILES: c1ccc(-c2nc3ccc4ccc5ccc(-c6nc(-c7ccc8ccccc8c7)nc(-c7cccc8c7oc7ccccc78)n6)cc5c4c3o2)cc1 ; c1ccc(-c2nc3ccc4ccc5ccc(-c6nc(-c7cccc8ccccc78)nc(-c7cccc8oc9ccccc9c78)n6)cc5c4c3o2)cc1 ; c1ccc(-c2nc3ccc4ccc5ccc(-c6nc(-c7ccc8ccccc8c7)nc(-c7cccc8oc9ccccc9c78)n6)cc5c4c3o2)cc1]

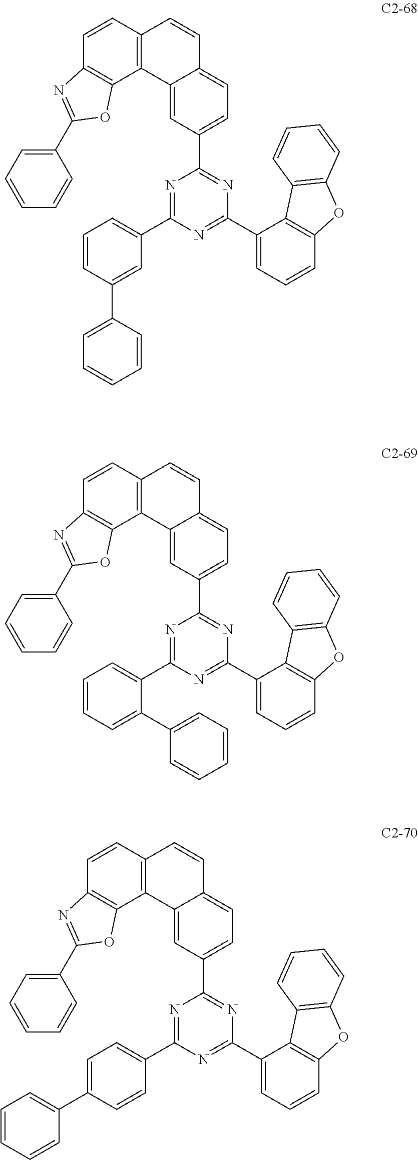 [SMILES: c1ccc(-c2cccc(-c3nc(-c4ccc5ccc6ccc7nc(-c8ccccc8)oc7c6c5c4)nc(-c4cccc5oc6ccccc6c45)n3)c2)cc1 ; c1ccc(-c2nc3ccc4ccc5ccc(-c6nc(-c7ccccc7-c7ccccc7)nc(-c7cccc8oc9ccccc9c78)n6)cc5c4c3o2)cc1 ; c1ccc(-c2ccc(-c3nc(-c4ccc5ccc6ccc7nc(-c8ccccc8)oc7c6c5c4)nc(-c4cccc5oc6ccccc6c45)n3)cc2)cc1]

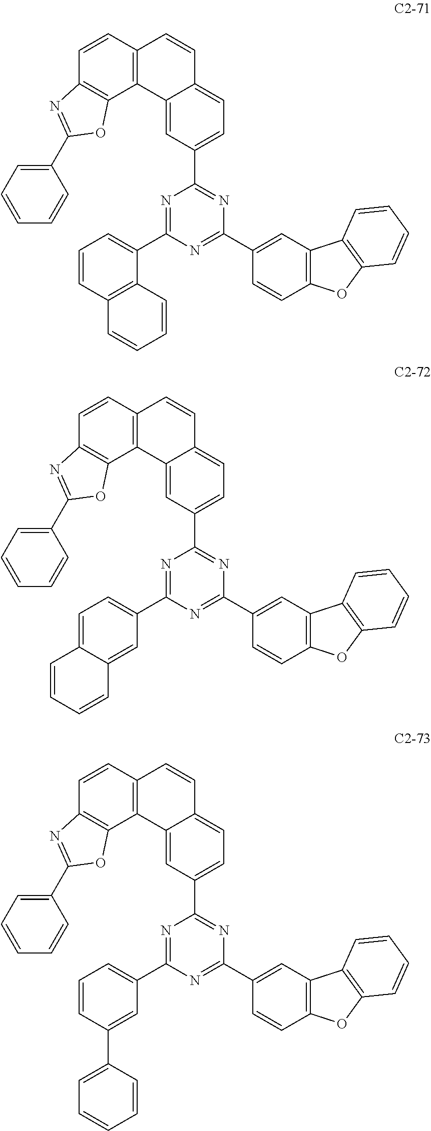 [SMILES: c1ccc(-c2nc3ccc4ccc5ccc(-c6nc(-c7ccc8oc9ccccc9c8c7)nc(-c7cccc8ccccc78)n6)cc5c4c3o2)cc1 ; c1ccc(-c2nc3ccc4ccc5ccc(-c6nc(-c7ccc8ccccc8c7)nc(-c7ccc8oc9ccccc9c8c7)n6)cc5c4c3o2)cc1 ; c1ccc(-c2cccc(-c3nc(-c4ccc5oc6ccccc6c5c4)nc(-c4ccc5ccc6ccc7nc(-c8ccccc8)oc7c6c5c4)n3)c2)cc1]

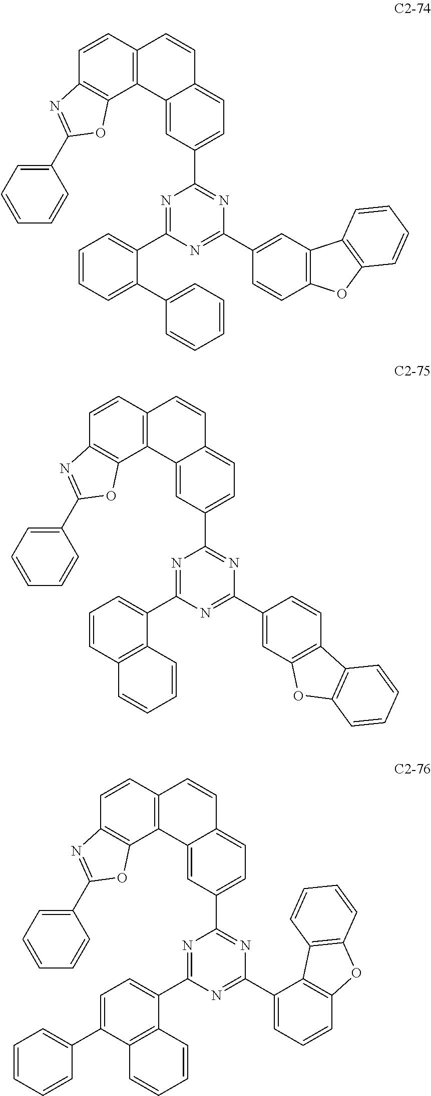 [SMILES: c1ccc(-c2nc3ccc4ccc5ccc(-c6nc(-c7ccc8oc9ccccc9c8c7)nc(-c7ccccc7-c7ccccc7)n6)cc5c4c3o2)cc1 ; c1ccc(-c2nc3ccc4ccc5ccc(-c6nc(-c7ccc8c(c7)oc7ccccc78)nc(-c7cccc8ccccc78)n6)cc5c4c3o2)cc1 ; c1ccc(-c2nc3ccc4ccc5ccc(-c6nc(-c7ccc(-c8ccccc8)c8ccccc78)nc(-c7cccc8oc9ccccc9c78)n6)cc5c4c3o2)cc1]

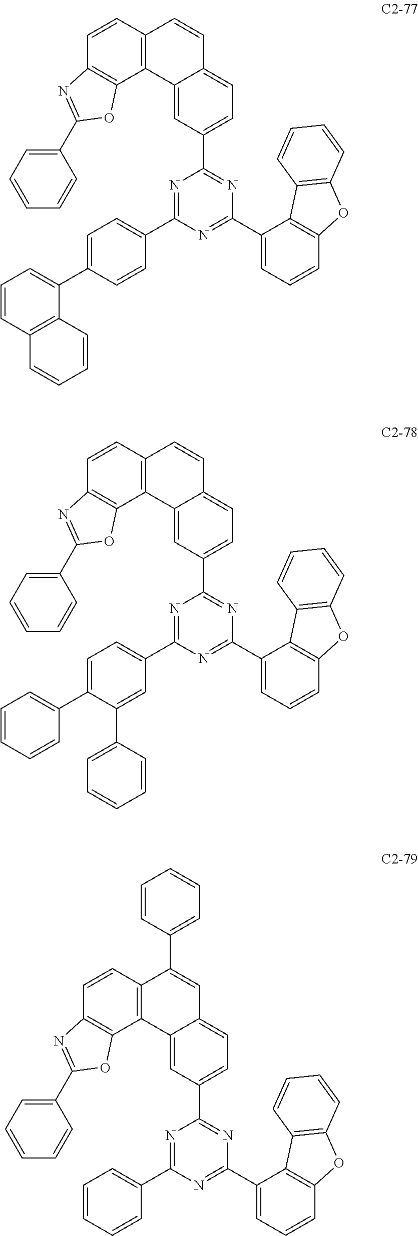 [SMILES: c1ccc(-c2nc3ccc4ccc5ccc(-c6nc(-c7ccc(-c8cccc9ccccc89)cc7)nc(-c7cccc8oc9ccccc9c78)n6)cc5c4c3o2)cc1 ; c1ccc(-c2nc3ccc4ccc5ccc(-c6nc(-c7ccc(-c8ccccc8)c(-c8ccccc8)c7)nc(-c7cccc8oc9ccccc9c78)n6)cc5c4c3o2)cc1 ; c1ccc(-c2nc(-c3ccc4cc(-c5ccccc5)c5ccc6nc(-c7ccccc7)oc6c5c4c3)nc(-c3cccc4oc5ccccc5c34)n2)cc1]

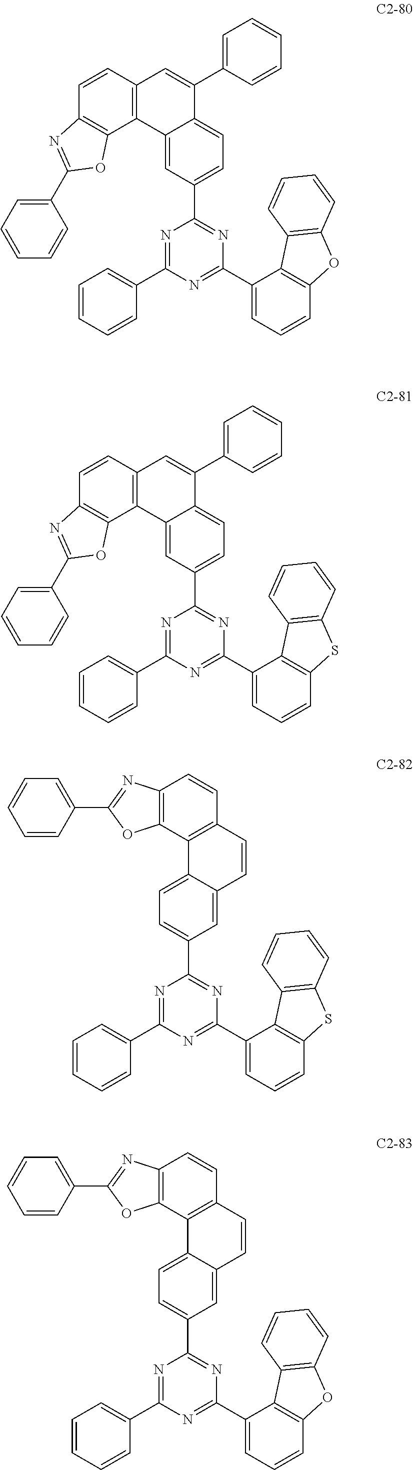 [SMILES: c1ccc(-c2nc(-c3ccc4c(-c5ccccc5)cc5ccc6nc(-c7ccccc7)oc6c5c4c3)nc(-c3cccc4oc5ccccc5c34)n2)cc1 ; c1ccc(-c2nc(-c3ccc4c(-c5ccccc5)cc5ccc6nc(-c7ccccc7)oc6c5c4c3)nc(-c3cccc4sc5ccccc5c34)n2)cc1 ; c1ccc(-c2nc(-c3ccc4c(ccc5ccc6nc(-c7ccccc7)oc6c54)c3)nc(-c3cccc4sc5ccccc5c34)n2)cc1 ; c1ccc(-c2nc(-c3ccc4c(ccc5ccc6nc(-c7ccccc7)oc6c54)c3)nc(-c3cccc4oc5ccccc5c34)n2)cc1]

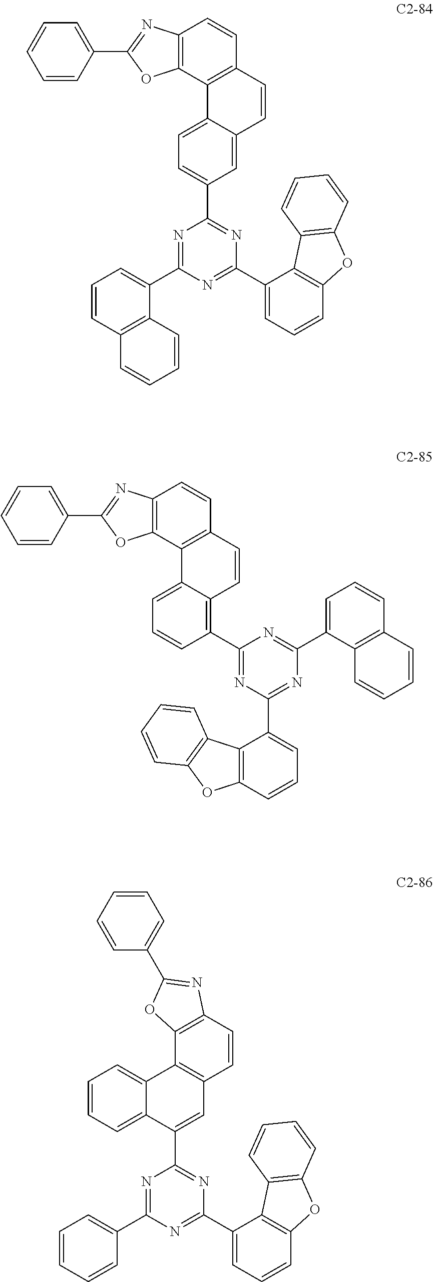 [SMILES: c1ccc(-c2nc3ccc4ccc5cc(-c6nc(-c7cccc8ccccc78)nc(-c7cccc8oc9ccccc9c78)n6)ccc5c4c3o2)cc1 ; c1ccc(-c2nc3ccc4ccc5c(-c6nc(-c7cccc8ccccc78)nc(-c7cccc8oc9ccccc9c78)n6)cccc5c4c3o2)cc1 ; c1ccc(-c2nc(-c3cc4ccc5nc(-c6ccccc6)oc5c4c4ccccc34)nc(-c3cccc4oc5ccccc5c34)n2)cc1]

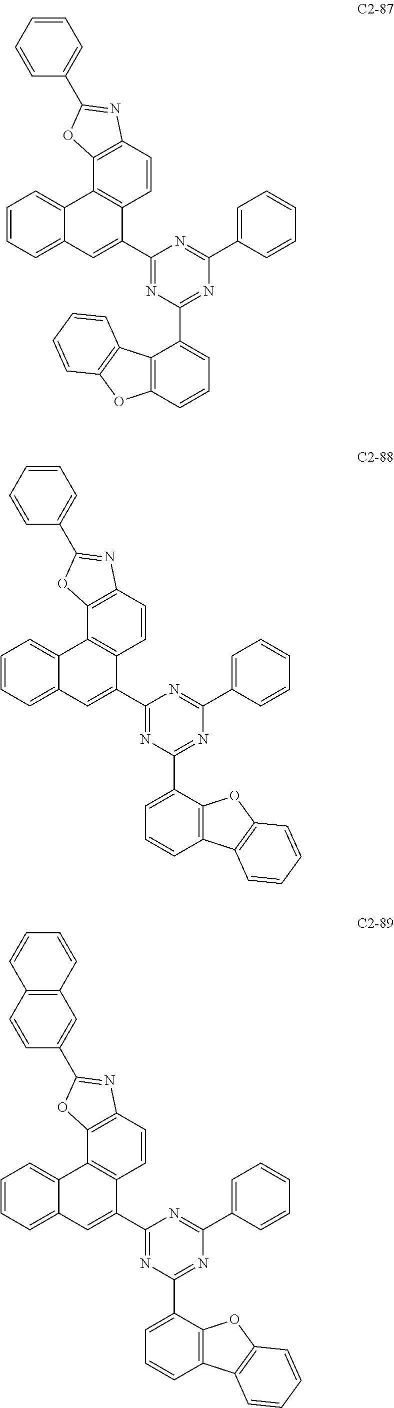 [SMILES: c1ccc(-c2nc(-c3cc4ccccc4c4c3ccc3nc(-c5ccccc5)oc34)nc(-c3cccc4oc5ccccc5c34)n2)cc1 ; c1ccc(-c2nc(-c3cc4ccccc4c4c3ccc3nc(-c5ccccc5)oc34)nc(-c3cccc4c3oc3ccccc34)n2)cc1 ; c1ccc(-c2nc(-c3cc4ccccc4c4c3ccc3nc(-c5ccc6ccccc6c5)oc34)nc(-c3cccc4c3oc3ccccc34)n2)cc1]

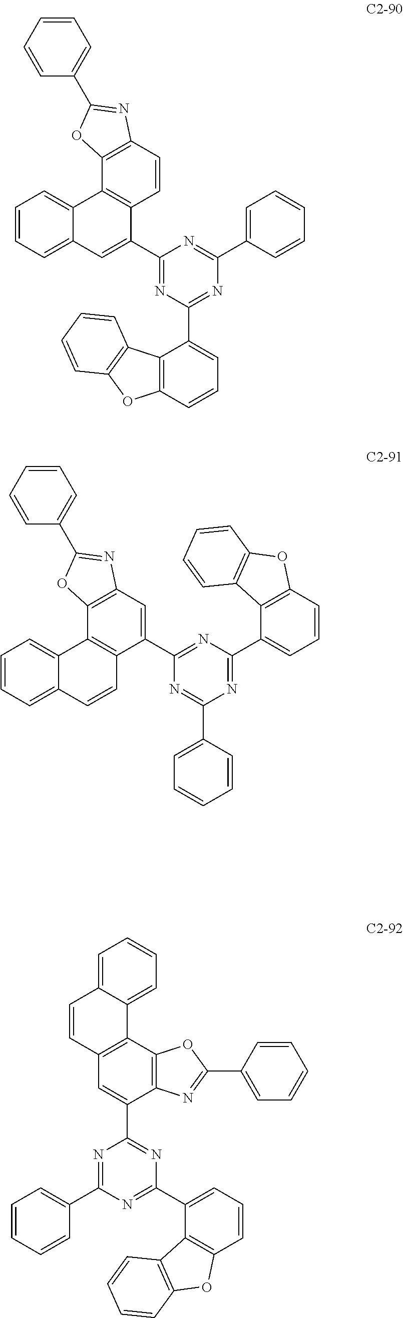 [SMILES: c1ccc(-c2nc(-c3cc4ccccc4c4c3ccc3nc(-c5ccccc5)oc34)nc(-c3cccc4oc5ccccc5c34)n2)cc1 ; c1ccc(-c2nc(-c3cc4nc(-c5ccccc5)oc4c4c3ccc3ccccc34)nc(-c3cccc4oc5ccccc5c34)n2)cc1 ; c1ccc(-c2nc(-c3cc4ccc5ccccc5c4c4oc(-c5ccccc5)nc34)nc(-c3cccc4oc5ccccc5c34)n2)cc1]

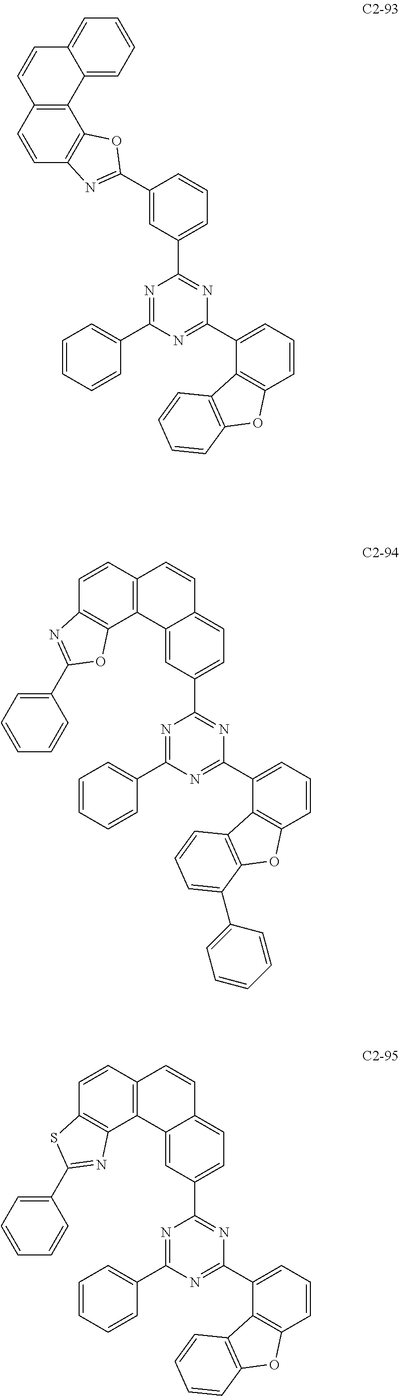 [SMILES: c1ccc(-c2nc(-c3cccc(-c4nc5ccc6ccc7ccccc7c6c5o4)c3)nc(-c3cccc4oc5ccccc5c34)n2)cc1 ; c1ccc(-c2nc(-c3ccc4ccc5ccc6nc(-c7ccccc7)oc6c5c4c3)nc(-c3cccc4oc5c(-c6ccccc6)cccc5c34)n2)cc1 ; c1ccc(-c2nc(-c3ccc4ccc5ccc6sc(-c7ccccc7)nc6c5c4c3)nc(-c3cccc4oc5ccccc5c34)n2)cc1]

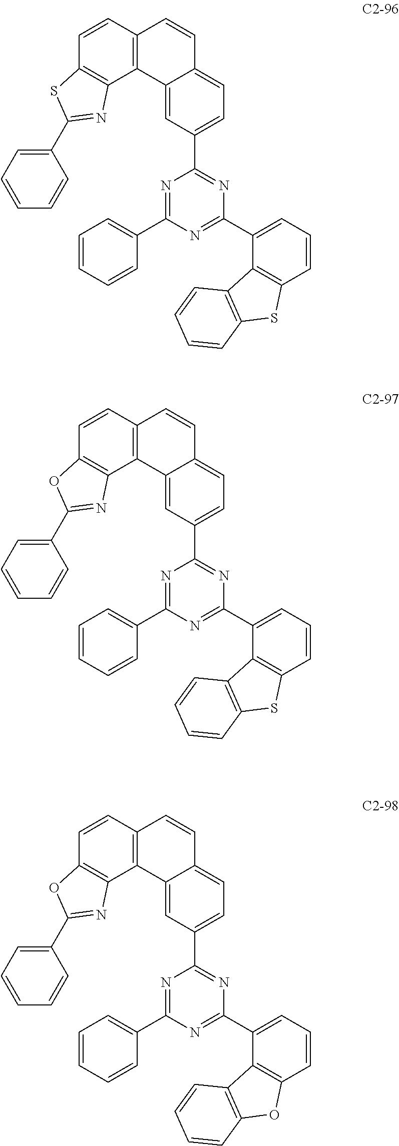 [SMILES: c1ccc(-c2nc(-c3ccc4ccc5ccc6sc(-c7ccccc7)nc6c5c4c3)nc(-c3cccc4sc5ccccc5c34)n2)cc1 ; c1ccc(-c2nc(-c3ccc4ccc5ccc6oc(-c7ccccc7)nc6c5c4c3)nc(-c3cccc4sc5ccccc5c34)n2)cc1 ; c1ccc(-c2nc(-c3ccc4ccc5ccc6oc(-c7ccccc7)nc6c5c4c3)nc(-c3cccc4oc5ccccc5c34)n2)cc1]

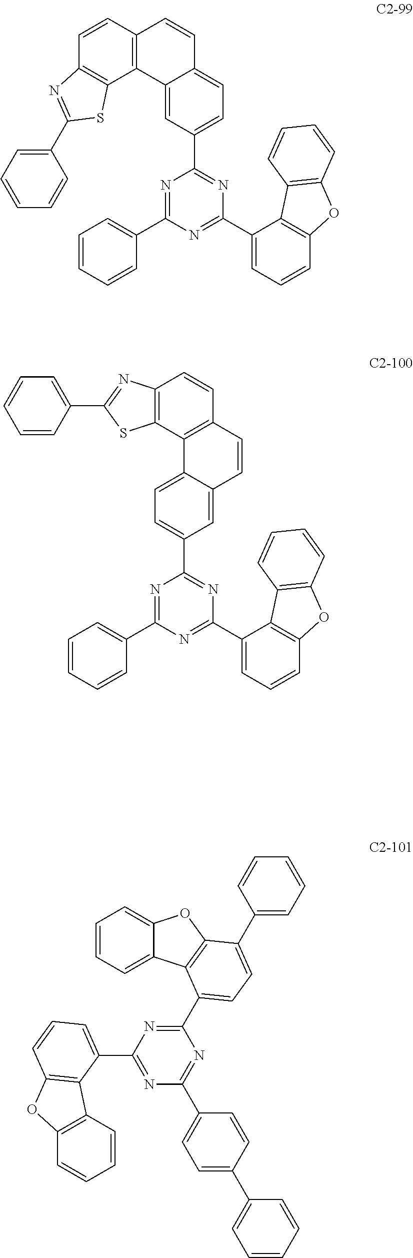 [SMILES: c1ccc(-c2nc(-c3ccc4ccc5ccc6nc(-c7ccccc7)sc6c5c4c3)nc(-c3cccc4oc5ccccc5c34)n2)cc1 ; c1ccc(-c2nc(-c3ccc4c(ccc5ccc6nc(-c7ccccc7)sc6c54)c3)nc(-c3cccc4oc5ccccc5c34)n2)cc1 ; c1ccc(-c2ccc(-c3nc(-c4cccc5oc6ccccc6c45)nc(-c4ccc(-c5ccccc5)c5oc6ccccc6c45)n3)cc2)cc1]

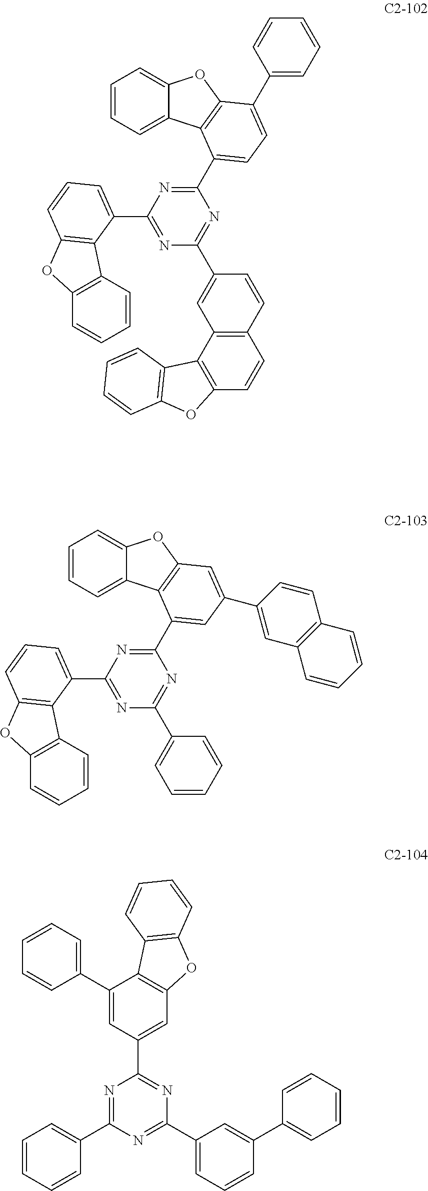 [SMILES: c1ccc(-c2ccc(-c3nc(-c4ccc5ccc6oc7ccccc7c6c5c4)nc(-c4cccc5oc6ccccc6c45)n3)c3c2oc2ccccc23)cc1 ; c1ccc(-c2nc(-c3cccc4oc5ccccc5c34)nc(-c3cc(-c4ccc5ccccc5c4)cc4oc5ccccc5c34)n2)cc1 ; c1ccc(-c2cccc(-c3nc(-c4ccccc4)nc(-c4cc(-c5ccccc5)c5c(c4)oc4ccccc45)n3)c2)cc1]

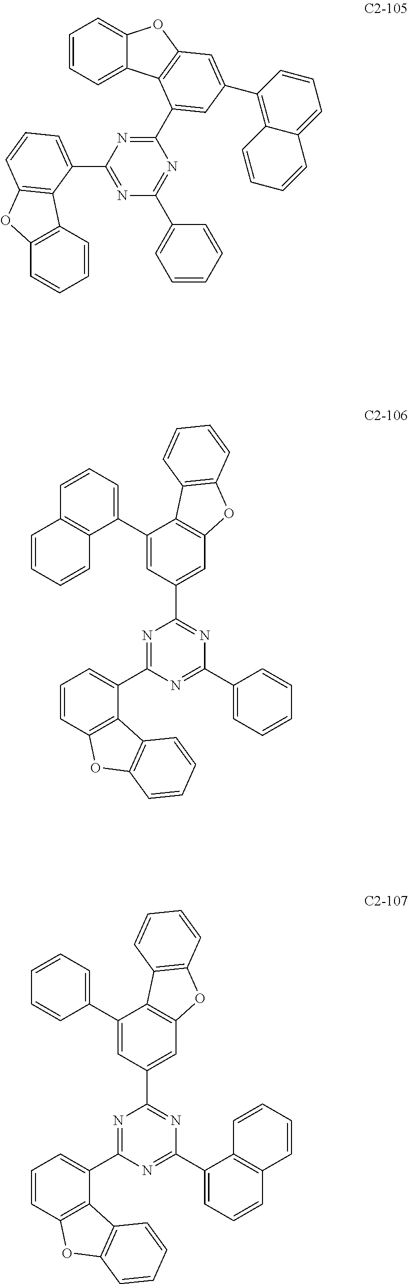 [SMILES: c1ccc(-c2nc(-c3cccc4oc5ccccc5c34)nc(-c3cc(-c4cccc5ccccc45)cc4oc5ccccc5c34)n2)cc1 ; c1ccc(-c2nc(-c3cc(-c4cccc5ccccc45)c4c(c3)oc3ccccc34)nc(-c3cccc4oc5ccccc5c34)n2)cc1 ; c1ccc(-c2cc(-c3nc(-c4cccc5ccccc45)nc(-c4cccc5oc6ccccc6c45)n3)cc3oc4ccccc4c23)cc1]

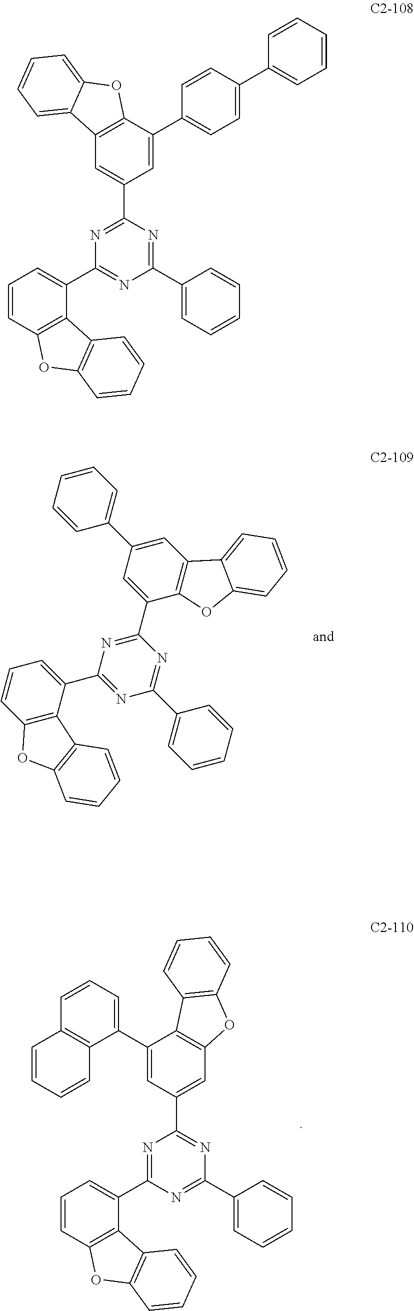 [SMILES: c1ccc(-c2ccc(-c3cc(-c4nc(-c5ccccc5)nc(-c5cccc6oc7ccccc7c56)n4)cc4c3oc3ccccc34)cc2)cc1 ; c1ccc(-c2cc(-c3nc(-c4ccccc4)nc(-c4cccc5oc6ccccc6c45)n3)c3oc4ccccc4c3c2)cc1 ; c1ccc(-c2nc(-c3cc(-c4cccc5ccccc45)c4c(c3)oc3ccccc34)nc(-c3cccc4oc5ccccc5c34)n2)cc1]

7. The plurality of host materials according to claim 1, wherein Ar₃ and Ar₄ in Formula 2 each independently represent a substituted or unsubstituted (C₆-C₂₄)aryl or a substituted or unsubstituted (3- to 20-membered)heteroaryl.

8. An organic electroluminescent device comprising an anode, a cathode, and at least one light-emitting layer between the anode and the cathode, wherein the at least one light-emitting layer comprises the plurality of host materials according to claim 1.

9. An organic electroluminescent compound represented by the following Formula 1′: 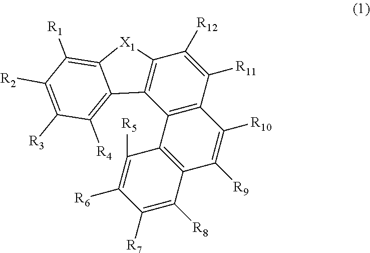
wherein in Formula 1′,
X₁ represents O, S, or CR₁₃R₁₄;
R₁₃ and R₁₄ each independently represent a substituted or unsubstituted (C₁-C₃₀)alkyl, a substituted or unsubstituted (C₆-C₃₀)aryl, or a substituted or unsubstituted (3- to 30-membered)heteroaryl, or R₁₃ and R₁₄ may be linked to each other to form a ring(s);
R₁ to R₁₂ each independently represent hydrogen, deuterium, a halogen, a cyano, a substituted or unsubstituted (C₁-C₃₀)alkyl, a substituted or unsubstituted (C₂-C₃₀)alkenyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₃-C₃₀)cycloalkenyl, a substituted or unsubstituted (3- to 7-membered)heterocycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted fused ring of (C₃-C₃₀) aliphatic ring(s) and (C₆-C₃₀) aromatic ring(s), a substituted or unsubstituted mono- or di-(C₁-C₃₀)alkylamino, a substituted or unsubstituted mono- or di-(C₆-C₃₀)arylamino, a substituted or unsubstituted (C₁-C₃₀)alkyl(C₆-C₃₀)arylamino, a substituted or unsubstituted mono- or di-(3- to 30-membered)heteroarylamino, or a substituted or unsubstituted (C₆-C₃₀)aryl(3- to 30-membered)heteroarylamino; or may be linked to the adjacent substituent(s) to form a ring(s);
wherein at least one of R₉ and R₁₀ represents a substituted or unsubstituted (C₆-C₃₀)aryl or a substituted or unsubstituted (C₆-C₃₀)heteroaryl;
with a proviso that at least one of R₁ to R₁₂ represents the following Formula 1′-a: 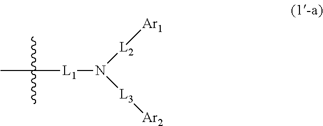
wherein in Formula 1′-a, 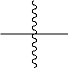
is a site linked to at least one of R₁ to R₁₂;
L₁ to L₃ each independently represent a single bond, a substituted or unsubstituted (C₆-C₃₀)arylene, a substituted or unsubstituted (3- to 30-membered)heteroarylene, or a substituted or unsubstituted (C₃-C₃₀)cycloalkylene; and
Ar₁ and Ar₂ each independently represent a substituted or unsubstituted (C₆-C₃₀)aryl, a substituted or unsubstituted (3- to 30-membered)heteroaryl, or a substituted or unsubstituted (C₃-C₃₀)cycloalkyl.

10. The organic electroluminescent compound according to claim 9, wherein the compound represented by Formula 1′ is represented by any one of the following Formulas 1′-1, 1′-2, 1′-3, 1′-6, 1′-7, 1′-8, 1′-11, and 1′-12: 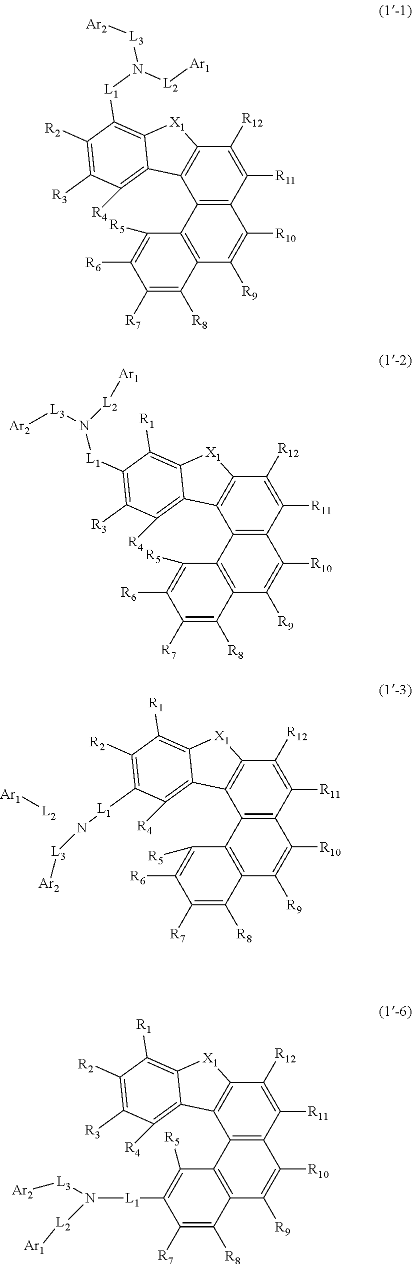 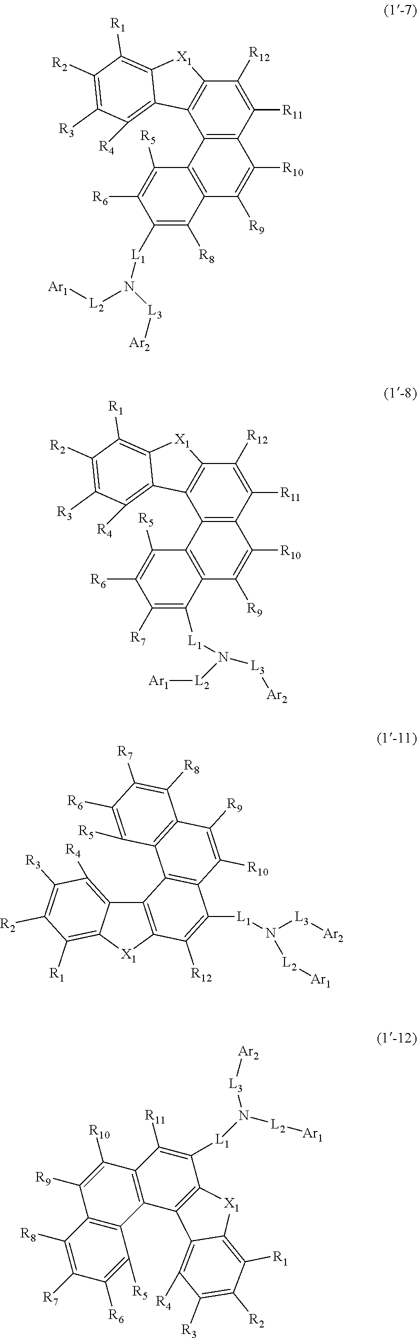
wherein in Formulas 1′-1, 1′-2, 1′-3, 1′-6, 1′-7, 1′-8, 1′-11, and 1′-12,
X₁, L₁ to L₃, Ar₁, Ar₂, and R₁ to R₁₂ are as defined in claim 9.

11. The organic electroluminescent compound according to claim 9, wherein the compound represented by Formula 1′ is selected from the group consisting of the following compounds:

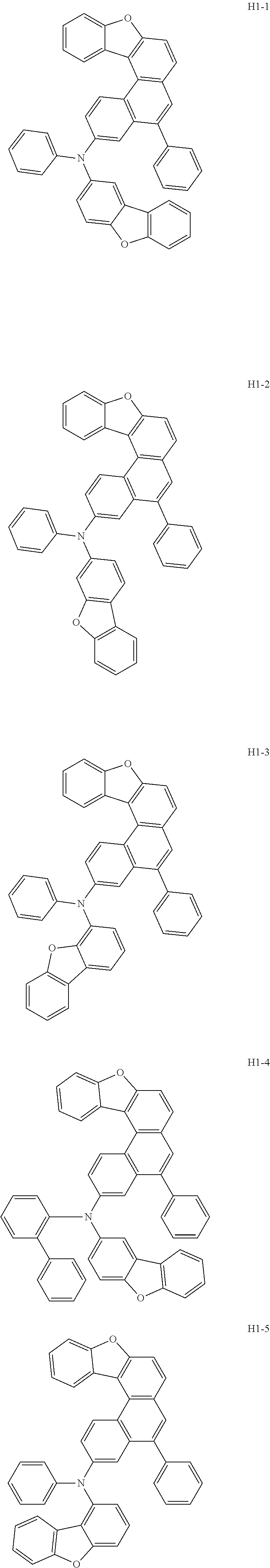 [SMILES: c1ccc(-c2cc3ccc4oc5ccccc5c4c3c3ccc(N(c4ccccc4)c4ccc5oc6ccccc6c5c4)cc23)cc1 ; c1ccc(-c2cc3ccc4oc5ccccc5c4c3c3ccc(N(c4ccccc4)c4ccc5c(c4)oc4ccccc45)cc23)cc1 ; c1ccc(-c2cc3ccc4oc5ccccc5c4c3c3ccc(N(c4ccccc4)c4cccc5c4oc4ccccc45)cc23)cc1 ; c1ccc(-c2ccccc2N(c2ccc3c(c2)c(-c2ccccc2)cc2ccc4oc5ccccc5c4c23)c2ccc3oc4ccccc4c3c2)cc1 ; c1ccc(-c2cc3ccc4oc5ccccc5c4c3c3ccc(N(c4ccccc4)c4cccc5oc6ccccc6c45)cc23)cc1]

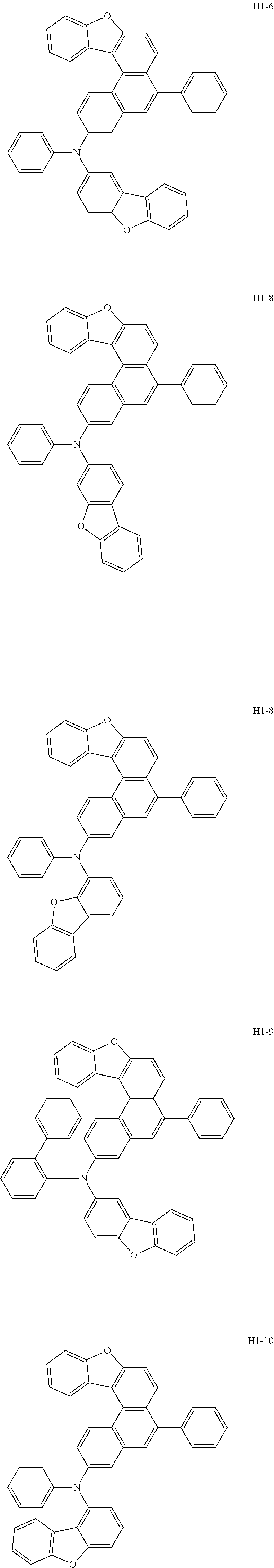 [SMILES: c1ccc(-c2cc3cc(N(c4ccccc4)c4ccc5oc6ccccc6c5c4)ccc3c3c2ccc2oc4ccccc4c23)cc1 ; c1ccc(-c2cc3cc(N(c4ccccc4)c4ccc5c(c4)oc4ccccc45)ccc3c3c2ccc2oc4ccccc4c23)cc1 ; c1ccc(-c2cc3cc(N(c4ccccc4)c4cccc5c4oc4ccccc45)ccc3c3c2ccc2oc4ccccc4c23)cc1 ; c1ccc(-c2ccccc2N(c2ccc3c(c2)cc(-c2ccccc2)c2ccc4oc5ccccc5c4c23)c2ccc3oc4ccccc4c3c2)cc1 ; c1ccc(-c2cc3cc(N(c4ccccc4)c4cccc5oc6ccccc6c45)ccc3c3c2ccc2oc4ccccc4c23)cc1]

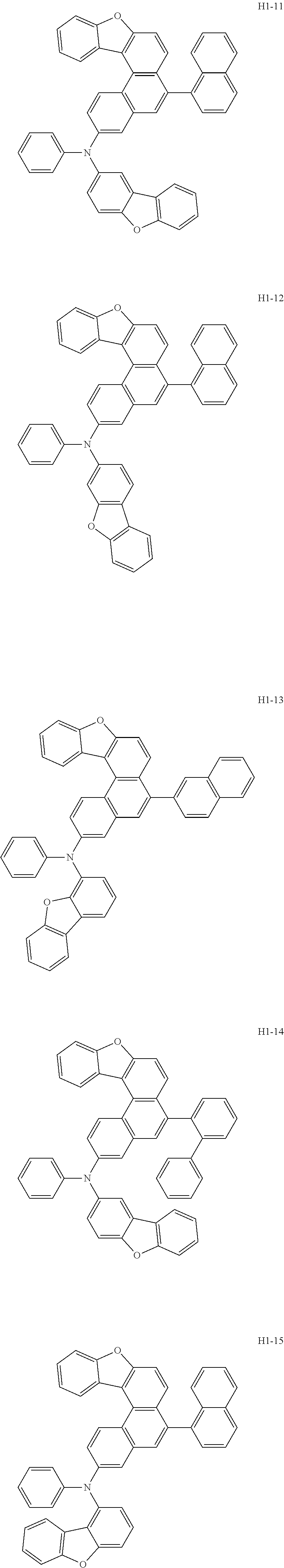 [SMILES: c1ccc(N(c2ccc3c(c2)cc(-c2cccc4ccccc24)c2ccc4oc5ccccc5c4c23)c2ccc3oc4ccccc4c3c2)cc1 ; c1ccc(N(c2ccc3c(c2)cc(-c2cccc4ccccc24)c2ccc4oc5ccccc5c4c23)c2ccc3c(c2)oc2ccccc23)cc1 ; c1ccc(N(c2ccc3c(c2)cc(-c2ccc4ccccc4c2)c2ccc4oc5ccccc5c4c23)c2cccc3c2oc2ccccc23)cc1 ; c1ccc(-c2ccccc2-c2cc3cc(N(c4ccccc4)c4ccc5oc6ccccc6c5c4)ccc3c3c2ccc2oc4ccccc4c23)cc1 ; c1ccc(N(c2ccc3c(c2)cc(-c2cccc4ccccc24)c2ccc4oc5ccccc5c4c23)c2cccc3oc4ccccc4c23)cc1]

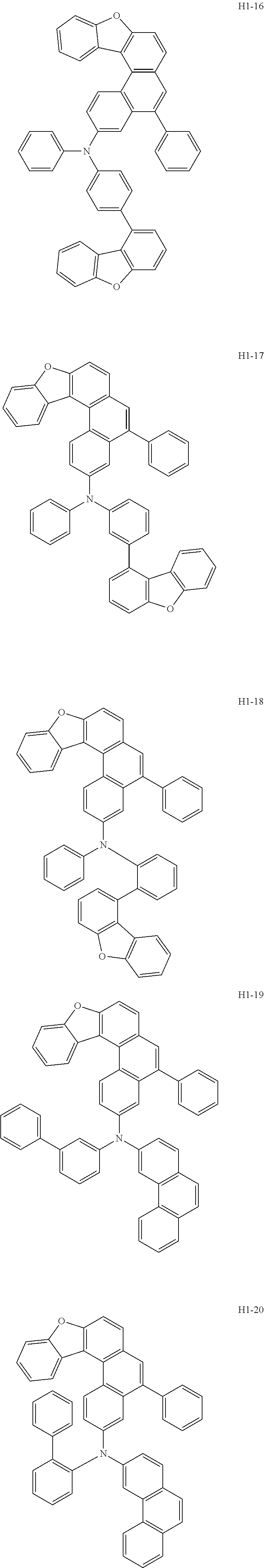

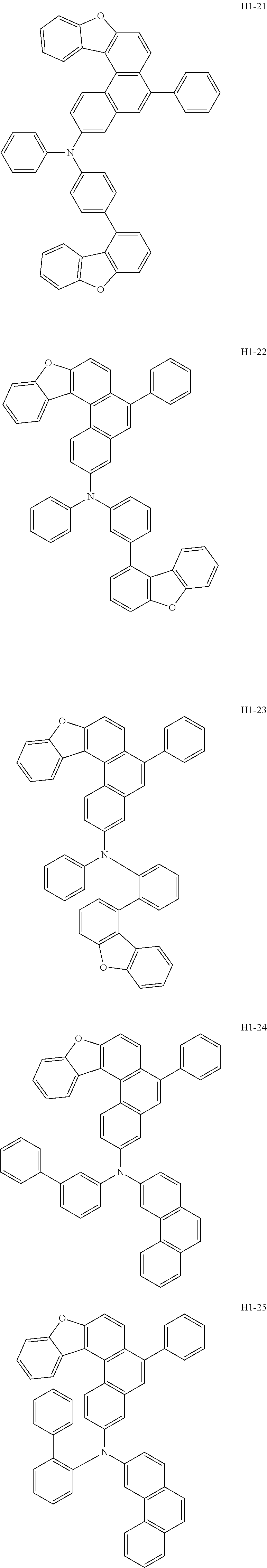 [SMILES: c1ccc(-c2cc3cc(N(c4ccccc4)c4ccc(-c5cccc6oc7ccccc7c56)cc4)ccc3c3c2ccc2oc4ccccc4c23)cc1 ; c1ccc(-c2cc3cc(N(c4ccccc4)c4cccc(-c5cccc6oc7ccccc7c56)c4)ccc3c3c2ccc2oc4ccccc4c23)cc1 ; c1ccc(-c2cc3cc(N(c4ccccc4)c4ccccc4-c4cccc5oc6ccccc6c45)ccc3c3c2ccc2oc4ccccc4c23)cc1 ; c1ccc(-c2cccc(N(c3ccc4c(c3)cc(-c3ccccc3)c3ccc5oc6ccccc6c5c34)c3ccc4ccc5ccccc5c4c3)c2)cc1 ; c1ccc(-c2ccccc2N(c2ccc3c(c2)cc(-c2ccccc2)c2ccc4oc5ccccc5c4c23)c2ccc3ccc4ccccc4c3c2)cc1]

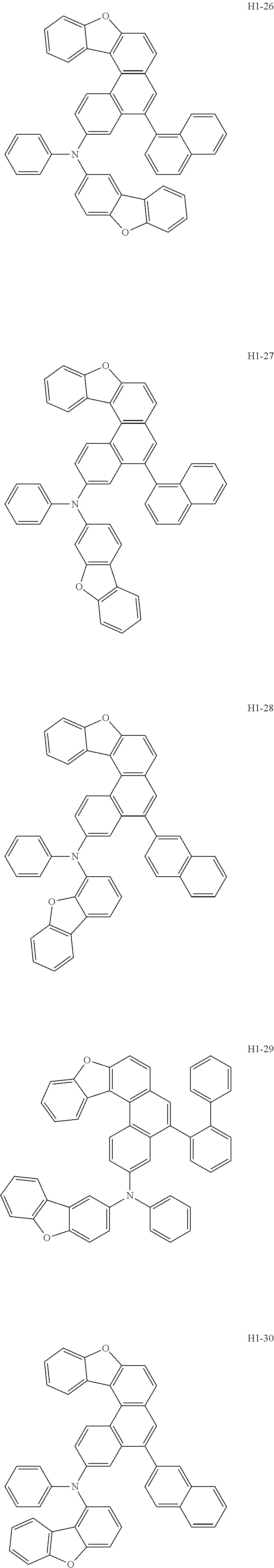 [SMILES: c1ccc(N(c2ccc3c(c2)c(-c2cccc4ccccc24)cc2ccc4oc5ccccc5c4c23)c2ccc3oc4ccccc4c3c2)cc1 ; c1ccc(N(c2ccc3c(c2)oc2ccccc23)c2ccc3c(c2)c(-c2cccc4ccccc24)cc2ccc4oc5ccccc5c4c23)cc1 ; c1ccc(N(c2ccc3c(c2)c(-c2ccc4ccccc4c2)cc2ccc4oc5ccccc5c4c23)c2cccc3c2oc2ccccc23)cc1 ; c1ccc(-c2ccccc2-c2cc3ccc4oc5ccccc5c4c3c3ccc(N(c4ccccc4)c4ccc5oc6ccccc6c5c4)cc23)cc1 ; c1ccc(N(c2ccc3c(c2)c(-c2ccc4ccccc4c2)cc2ccc4oc5ccccc5c4c23)c2cccc3oc4ccccc4c23)cc1]

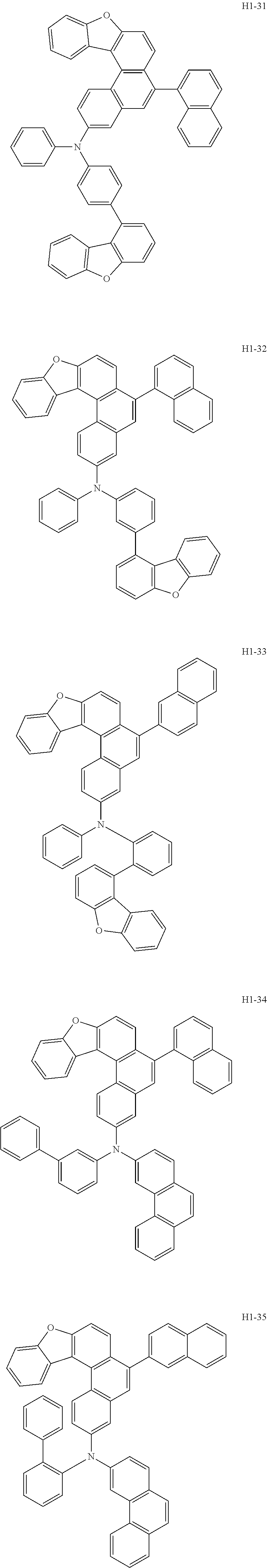 [SMILES: c1ccc(N(c2ccc(-c3cccc4oc5ccccc5c34)cc2)c2ccc3c(c2)cc(-c2cccc4ccccc24)c2ccc4oc5ccccc5c4c23)cc1 ; c1ccc(N(c2cccc(-c3cccc4oc5ccccc5c34)c2)c2ccc3c(c2)cc(-c2cccc4ccccc24)c2ccc4oc5ccccc5c4c23)cc1 ; c1ccc(N(c2ccc3c(c2)cc(-c2ccc4ccccc4c2)c2ccc4oc5ccccc5c4c23)c2ccccc2-c2cccc3oc4ccccc4c23)cc1 ; c1ccc(-c2cccc(N(c3ccc4c(c3)cc(-c3cccc5ccccc35)c3ccc5oc6ccccc6c5c34)c3ccc4ccc5ccccc5c4c3)c2)cc1 ; c1ccc(-c2ccccc2N(c2ccc3c(c2)cc(-c2ccc4ccccc4c2)c2ccc4oc5ccccc5c4c23)c2ccc3ccc4ccccc4c3c2)cc1]

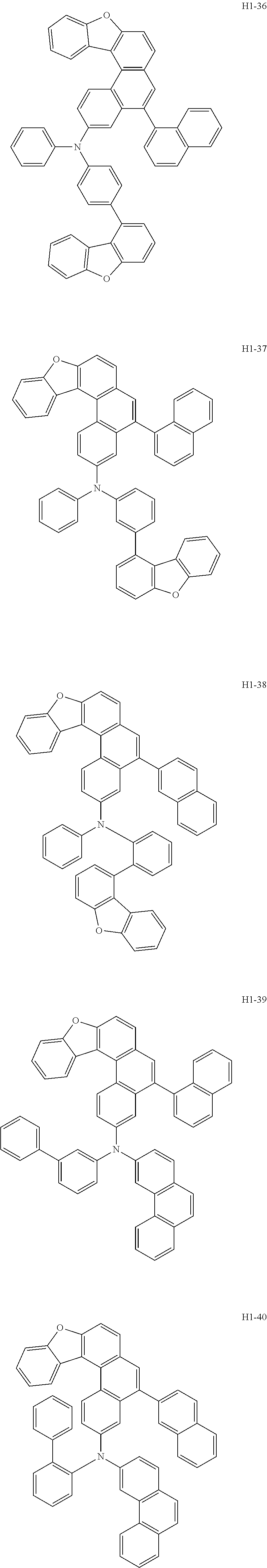 [SMILES: c1ccc(N(c2ccc(-c3cccc4oc5ccccc5c34)cc2)c2ccc3c(c2)c(-c2cccc4ccccc24)cc2ccc4oc5ccccc5c4c23)cc1 ; c1ccc(N(c2cccc(-c3cccc4oc5ccccc5c34)c2)c2ccc3c(c2)c(-c2cccc4ccccc24)cc2ccc4oc5ccccc5c4c23)cc1 ; c1ccc(N(c2ccc3c(c2)c(-c2ccc4ccccc4c2)cc2ccc4oc5ccccc5c4c23)c2ccccc2-c2cccc3oc4ccccc4c23)cc1 ; c1ccc(-c2cccc(N(c3ccc4c(c3)c(-c3cccc5ccccc35)cc3ccc5oc6ccccc6c5c34)c3ccc4ccc5ccccc5c4c3)c2)cc1 ; c1ccc(-c2ccccc2N(c2ccc3c(c2)c(-c2ccc4ccccc4c2)cc2ccc4oc5ccccc5c4c23)c2ccc3ccc4ccccc4c3c2)cc1]

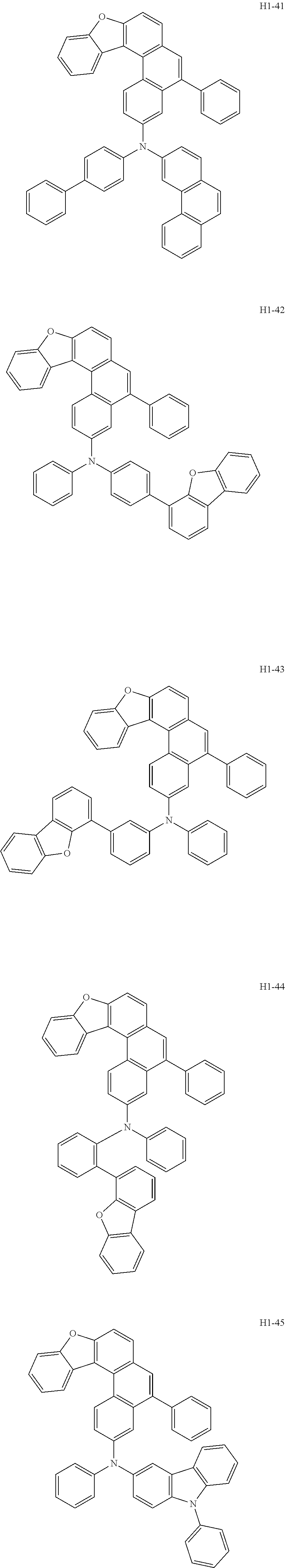 [SMILES: c1ccc(-c2ccc(N(c3ccc4c(c3)c(-c3ccccc3)cc3ccc5oc6ccccc6c5c34)c3ccc4ccc5ccccc5c4c3)cc2)cc1 ; c1ccc(-c2cc3ccc4oc5ccccc5c4c3c3ccc(N(c4ccccc4)c4ccc(-c5cccc6c5oc5ccccc56)cc4)cc23)cc1 ; c1ccc(-c2cc3ccc4oc5ccccc5c4c3c3ccc(N(c4ccccc4)c4cccc(-c5cccc6c5oc5ccccc56)c4)cc23)cc1 ; c1ccc(-c2cc3ccc4oc5ccccc5c4c3c3ccc(N(c4ccccc4)c4ccccc4-c4cccc5c4oc4ccccc45)cc23)cc1 ; c1ccc(-c2cc3ccc4oc5ccccc5c4c3c3ccc(N(c4ccccc4)c4ccc5c(c4)c4ccccc4n5-c4ccccc4)cc23)cc1]

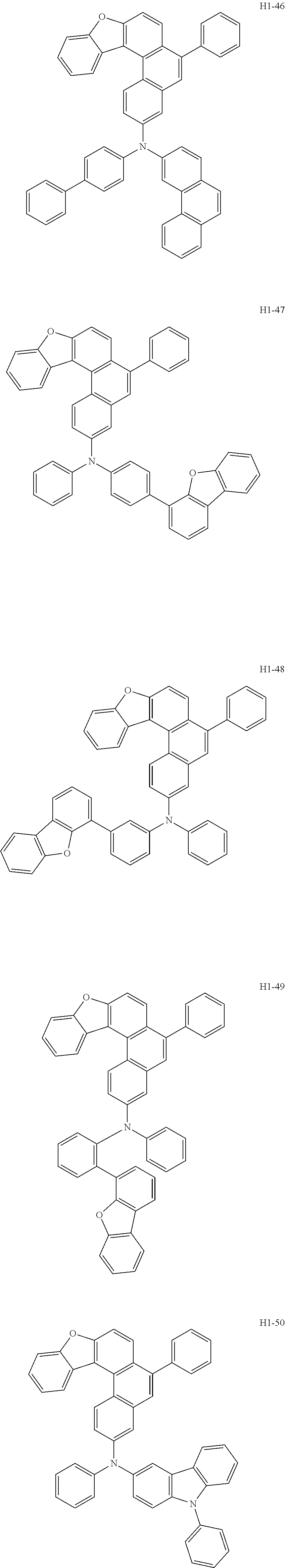 [SMILES: c1ccc(-c2ccc(N(c3ccc4c(c3)cc(-c3ccccc3)c3ccc5oc6ccccc6c5c34)c3ccc4ccc5ccccc5c4c3)cc2)cc1 ; c1ccc(-c2cc3cc(N(c4ccccc4)c4ccc(-c5cccc6c5oc5ccccc56)cc4)ccc3c3c2ccc2oc4ccccc4c23)cc1 ; c1ccc(-c2cc3cc(N(c4ccccc4)c4cccc(-c5cccc6c5oc5ccccc56)c4)ccc3c3c2ccc2oc4ccccc4c23)cc1 ; c1ccc(-c2cc3cc(N(c4ccccc4)c4ccccc4-c4cccc5c4oc4ccccc45)ccc3c3c2ccc2oc4ccccc4c23)cc1 ; c1ccc(-c2cc3cc(N(c4ccccc4)c4ccc5c(c4)c4ccccc4n5-c4ccccc4)ccc3c3c2ccc2oc4ccccc4c23)cc1]

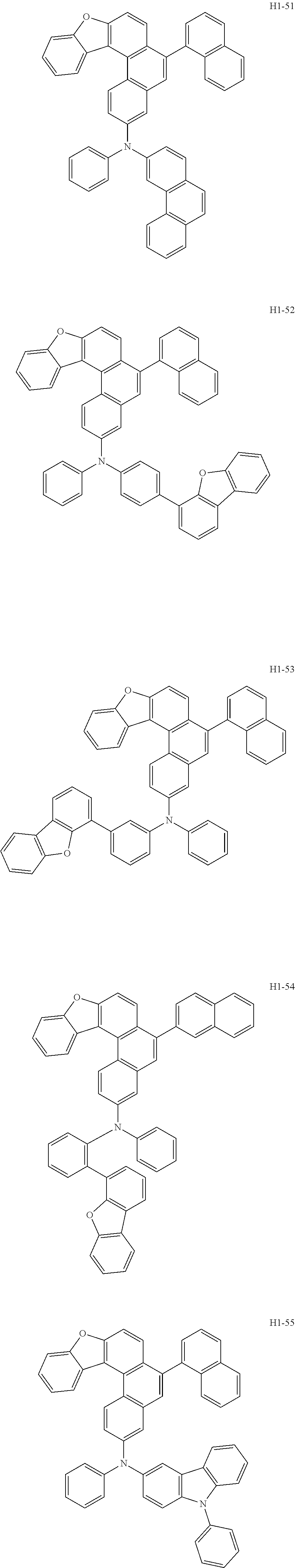 [SMILES: c1ccc(N(c2ccc3c(c2)cc(-c2cccc4ccccc24)c2ccc4oc5ccccc5c4c23)c2ccc3ccc4ccccc4c3c2)cc1 ; c1ccc(N(c2ccc(-c3cccc4c3oc3ccccc34)cc2)c2ccc3c(c2)cc(-c2cccc4ccccc24)c2ccc4oc5ccccc5c4c23)cc1 ; c1ccc(N(c2cccc(-c3cccc4c3oc3ccccc34)c2)c2ccc3c(c2)cc(-c2cccc4ccccc24)c2ccc4oc5ccccc5c4c23)cc1 ; c1ccc(N(c2ccc3c(c2)cc(-c2ccc4ccccc4c2)c2ccc4oc5ccccc5c4c23)c2ccccc2-c2cccc3c2oc2ccccc23)cc1 ; c1ccc(N(c2ccc3c(c2)cc(-c2cccc4ccccc24)c2ccc4oc5ccccc5c4c23)c2ccc3c(c2)c2ccccc2n3-c2ccccc2)cc1]

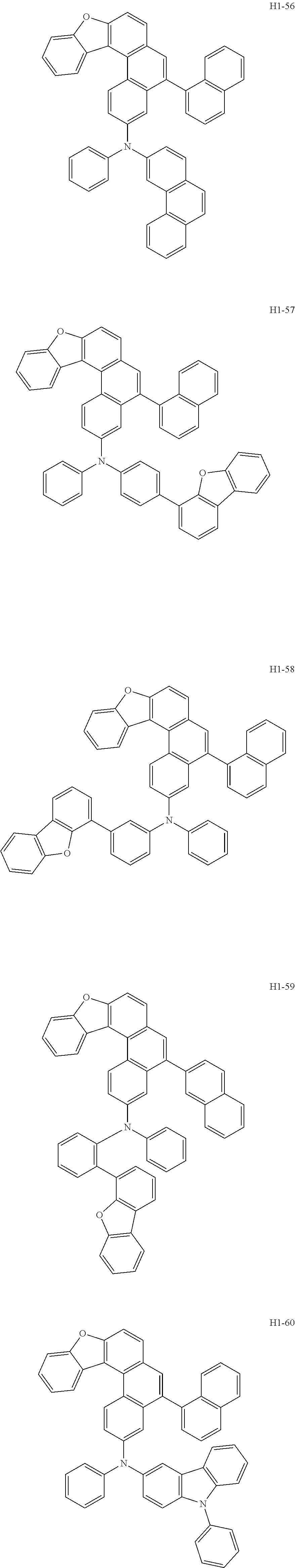 [SMILES: c1ccc(N(c2ccc3c(c2)c(-c2cccc4ccccc24)cc2ccc4oc5ccccc5c4c23)c2ccc3ccc4ccccc4c3c2)cc1 ; c1ccc(N(c2ccc(-c3cccc4c3oc3ccccc34)cc2)c2ccc3c(c2)c(-c2cccc4ccccc24)cc2ccc4oc5ccccc5c4c23)cc1 ; c1ccc(N(c2cccc(-c3cccc4c3oc3ccccc34)c2)c2ccc3c(c2)c(-c2cccc4ccccc24)cc2ccc4oc5ccccc5c4c23)cc1 ; c1ccc(N(c2ccc3c(c2)c(-c2ccc4ccccc4c2)cc2ccc4oc5ccccc5c4c23)c2ccccc2-c2cccc3c2oc2ccccc23)cc1 ; c1ccc(N(c2ccc3c(c2)c(-c2cccc4ccccc24)cc2ccc4oc5ccccc5c4c23)c2ccc3c(c2)c2ccccc2n3-c2ccccc2)cc1]

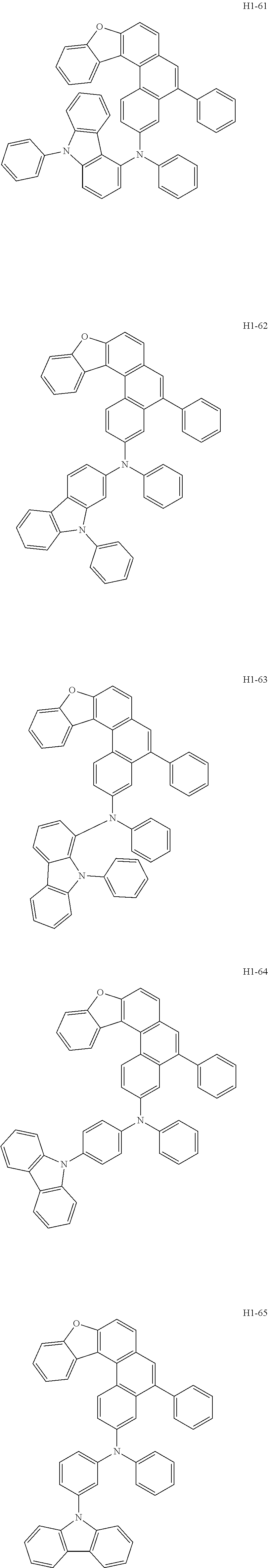 [SMILES: c1ccc(-c2cc3ccc4oc5ccccc5c4c3c3ccc(N(c4ccccc4)c4cccc5c4c4ccccc4n5-c4ccccc4)cc23)cc1 ; c1ccc(-c2cc3ccc4oc5ccccc5c4c3c3ccc(N(c4ccccc4)c4ccc5c6ccccc6n(-c6ccccc6)c5c4)cc23)cc1 ; c1ccc(-c2cc3ccc4oc5ccccc5c4c3c3ccc(N(c4ccccc4)c4cccc5c6ccccc6n(-c6ccccc6)c45)cc23)cc1 ; c1ccc(-c2cc3ccc4oc5ccccc5c4c3c3ccc(N(c4ccccc4)c4ccc(-n5c6ccccc6c6ccccc65)cc4)cc23)cc1 ; c1ccc(-c2cc3ccc4oc5ccccc5c4c3c3ccc(N(c4ccccc4)c4cccc(-n5c6ccccc6c6ccccc65)c4)cc23)cc1]

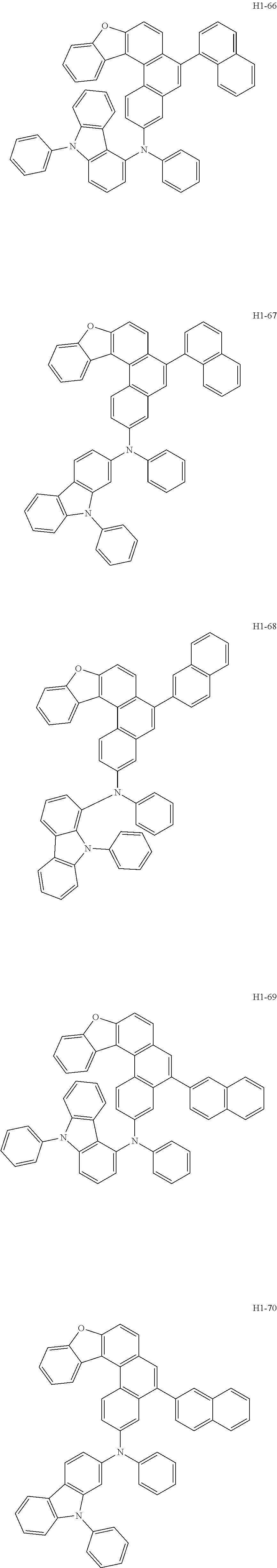 [SMILES: c1ccc(N(c2ccc3c(c2)cc(-c2cccc4ccccc24)c2ccc4oc5ccccc5c4c23)c2cccc3c2c2ccccc2n3-c2ccccc2)cc1 ; c1ccc(N(c2ccc3c(c2)cc(-c2cccc4ccccc24)c2ccc4oc5ccccc5c4c23)c2ccc3c4ccccc4n(-c4ccccc4)c3c2)cc1 ; c1ccc(N(c2ccc3c(c2)cc(-c2ccc4ccccc4c2)c2ccc4oc5ccccc5c4c23)c2cccc3c4ccccc4n(-c4ccccc4)c23)cc1 ; c1ccc(N(c2ccc3c(c2)c(-c2ccc4ccccc4c2)cc2ccc4oc5ccccc5c4c23)c2cccc3c2c2ccccc2n3-c2ccccc2)cc1 ; c1ccc(N(c2ccc3c(c2)c(-c2ccc4ccccc4c2)cc2ccc4oc5ccccc5c4c23)c2ccc3c4ccccc4n(-c4ccccc4)c3c2)cc1]

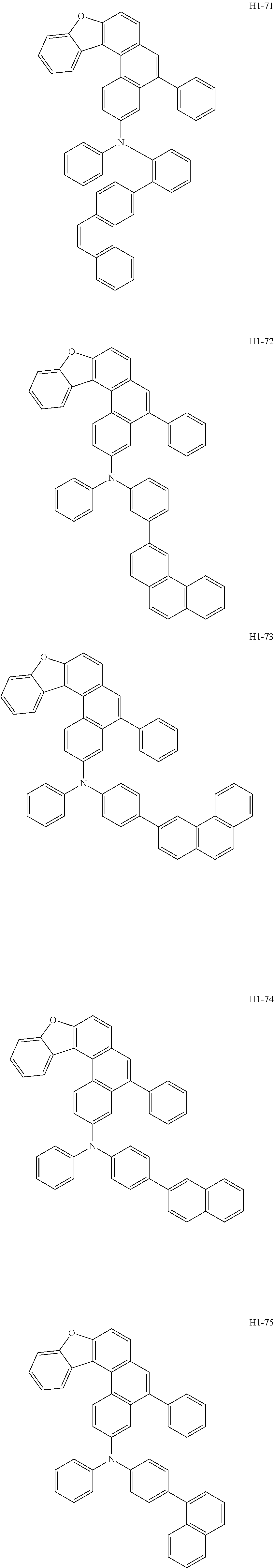 [SMILES: c1ccc(-c2cc3ccc4oc5ccccc5c4c3c3ccc(N(c4ccccc4)c4ccccc4-c4ccc5ccc6ccccc6c5c4)cc23)cc1 ; c1ccc(-c2cc3ccc4oc5ccccc5c4c3c3ccc(N(c4ccccc4)c4cccc(-c5ccc6ccc7ccccc7c6c5)c4)cc23)cc1 ; c1ccc(-c2cc3ccc4oc5ccccc5c4c3c3ccc(N(c4ccccc4)c4ccc(-c5ccc6ccc7ccccc7c6c5)cc4)cc23)cc1 ; c1ccc(-c2cc3ccc4oc5ccccc5c4c3c3ccc(N(c4ccccc4)c4ccc(-c5ccc6ccccc6c5)cc4)cc23)cc1 ; c1ccc(-c2cc3ccc4oc5ccccc5c4c3c3ccc(N(c4ccccc4)c4ccc(-c5cccc6ccccc56)cc4)cc23)cc1]

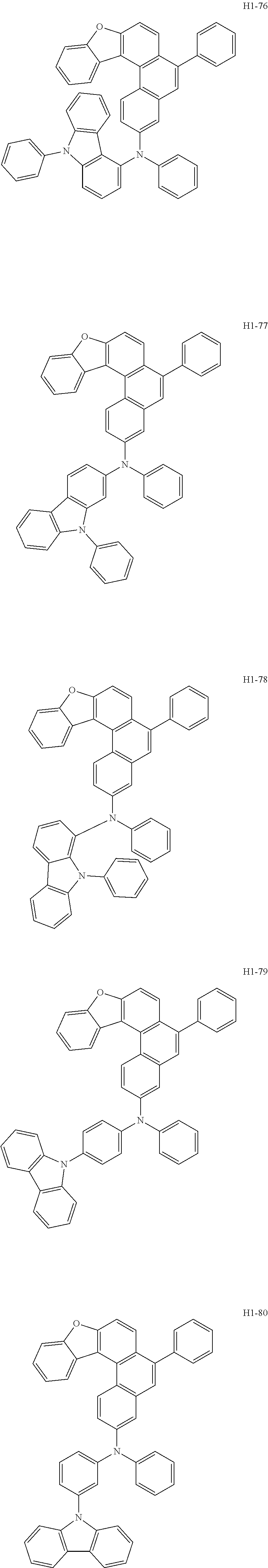 [SMILES: c1ccc(-c2cc3cc(N(c4ccccc4)c4cccc5c4c4ccccc4n5-c4ccccc4)ccc3c3c2ccc2oc4ccccc4c23)cc1 ; c1ccc(-c2cc3cc(N(c4ccccc4)c4ccc5c6ccccc6n(-c6ccccc6)c5c4)ccc3c3c2ccc2oc4ccccc4c23)cc1 ; c1ccc(-c2cc3cc(N(c4ccccc4)c4cccc5c6ccccc6n(-c6ccccc6)c45)ccc3c3c2ccc2oc4ccccc4c23)cc1 ; c1ccc(-c2cc3cc(N(c4ccccc4)c4ccc(-n5c6ccccc6c6ccccc65)cc4)ccc3c3c2ccc2oc4ccccc4c23)cc1 ; c1ccc(-c2cc3cc(N(c4ccccc4)c4cccc(-n5c6ccccc6c6ccccc65)c4)ccc3c3c2ccc2oc4ccccc4c23)cc1]

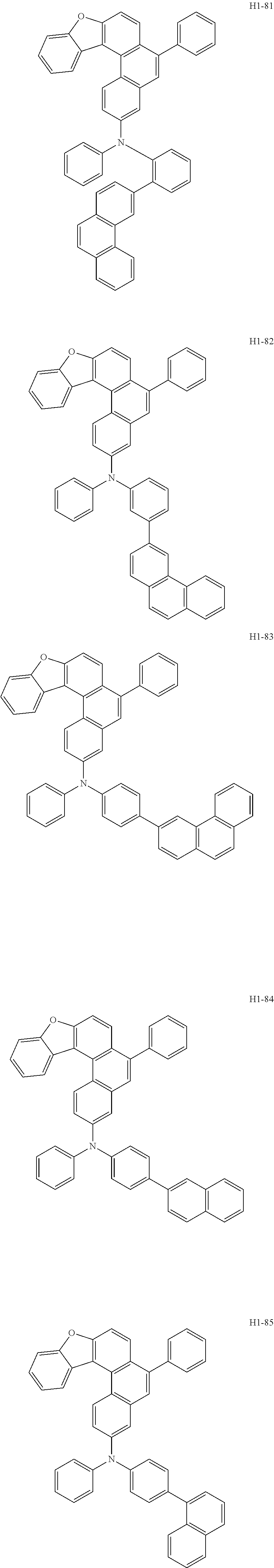 [SMILES: c1ccc(-c2cc3cc(N(c4ccccc4)c4ccccc4-c4ccc5ccc6ccccc6c5c4)ccc3c3c2ccc2oc4ccccc4c23)cc1 ; c1ccc(-c2cc3cc(N(c4ccccc4)c4cccc(-c5ccc6ccc7ccccc7c6c5)c4)ccc3c3c2ccc2oc4ccccc4c23)cc1 ; c1ccc(-c2cc3cc(N(c4ccccc4)c4ccc(-c5ccc6ccc7ccccc7c6c5)cc4)ccc3c3c2ccc2oc4ccccc4c23)cc1 ; c1ccc(-c2cc3cc(N(c4ccccc4)c4ccc(-c5ccc6ccccc6c5)cc4)ccc3c3c2ccc2oc4ccccc4c23)cc1 ; c1ccc(-c2cc3cc(N(c4ccccc4)c4ccc(-c5cccc6ccccc56)cc4)ccc3c3c2ccc2oc4ccccc4c23)cc1]

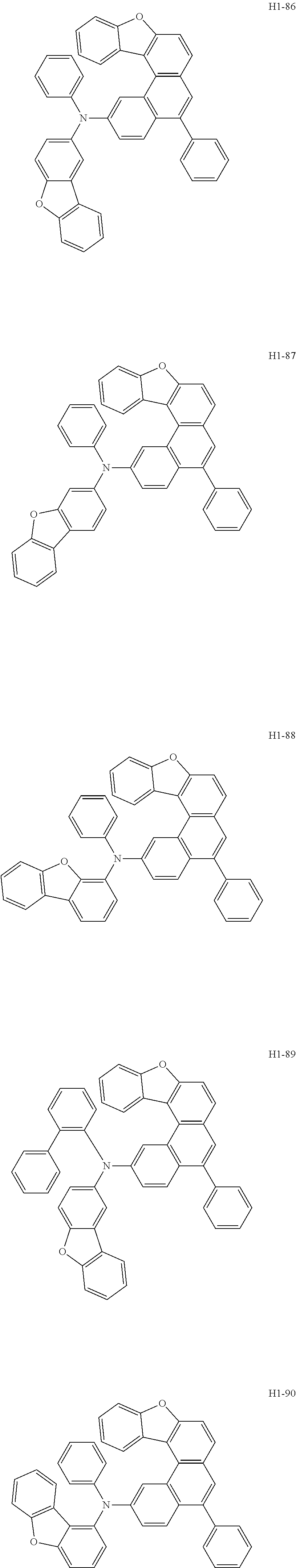 [SMILES: c1ccc(-c2cc3ccc4oc5ccccc5c4c3c3cc(N(c4ccccc4)c4ccc5oc6ccccc6c5c4)ccc23)cc1 ; c1ccc(-c2cc3ccc4oc5ccccc5c4c3c3cc(N(c4ccccc4)c4ccc5c(c4)oc4ccccc45)ccc23)cc1 ; c1ccc(-c2cc3ccc4oc5ccccc5c4c3c3cc(N(c4ccccc4)c4cccc5c4oc4ccccc45)ccc23)cc1 ; c1ccc(-c2ccccc2N(c2ccc3oc4ccccc4c3c2)c2ccc3c(-c4ccccc4)cc4ccc5oc6ccccc6c5c4c3c2)cc1 ; c1ccc(-c2cc3ccc4oc5ccccc5c4c3c3cc(N(c4ccccc4)c4cccc5oc6ccccc6c45)ccc23)cc1]

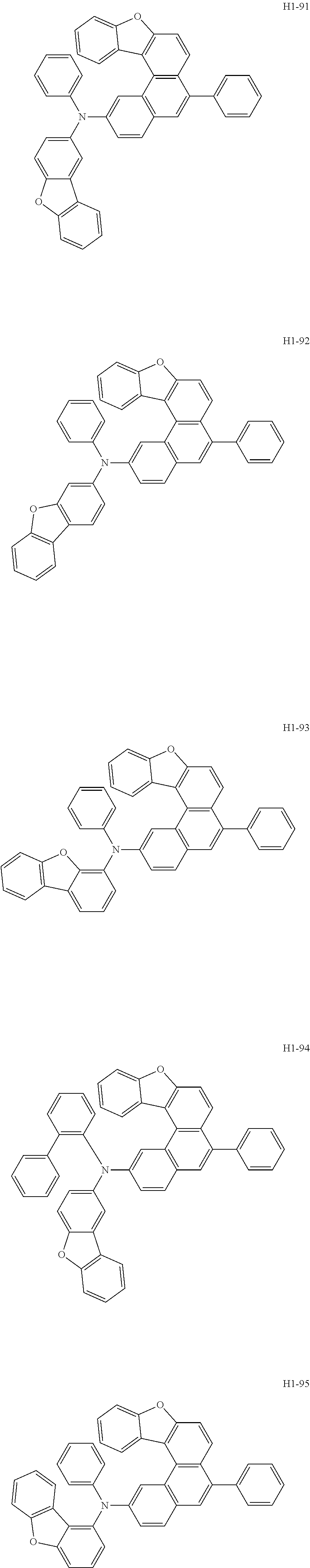 [SMILES: c1ccc(-c2cc3ccc(N(c4ccccc4)c4ccc5oc6ccccc6c5c4)cc3c3c2ccc2oc4ccccc4c23)cc1 ; c1ccc(-c2cc3ccc(N(c4ccccc4)c4ccc5c(c4)oc4ccccc45)cc3c3c2ccc2oc4ccccc4c23)cc1 ; c1ccc(-c2cc3ccc(N(c4ccccc4)c4cccc5c4oc4ccccc45)cc3c3c2ccc2oc4ccccc4c23)cc1 ; c1ccc(-c2ccccc2N(c2ccc3oc4ccccc4c3c2)c2ccc3cc(-c4ccccc4)c4ccc5oc6ccccc6c5c4c3c2)cc1 ; c1ccc(-c2cc3ccc(N(c4ccccc4)c4cccc5oc6ccccc6c45)cc3c3c2ccc2oc4ccccc4c23)cc1]

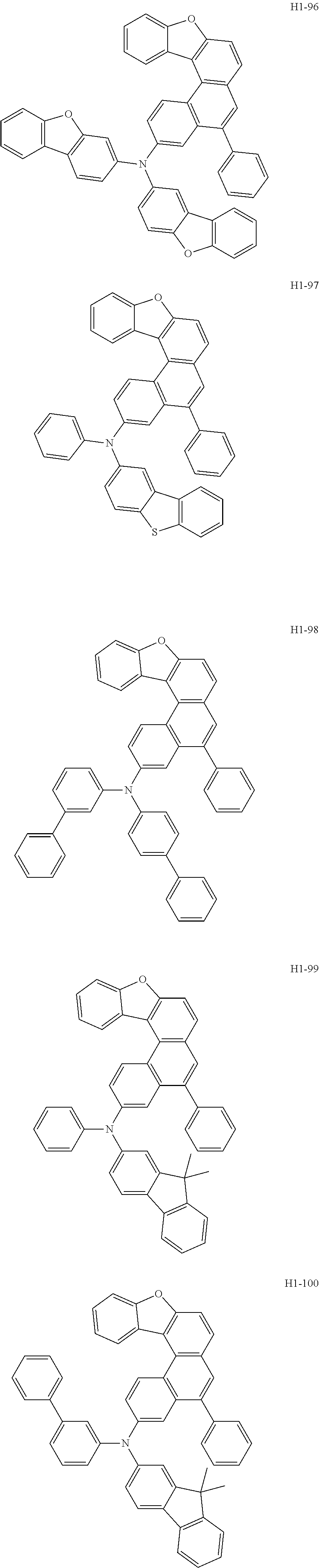 [SMILES: c1ccc(-c2cc3ccc4oc5ccccc5c4c3c3ccc(N(c4ccc5c(c4)oc4ccccc45)c4ccc5oc6ccccc6c5c4)cc23)cc1 ; c1ccc(-c2cc3ccc4oc5ccccc5c4c3c3ccc(N(c4ccccc4)c4ccc5sc6ccccc6c5c4)cc23)cc1 ; c1ccc(-c2ccc(N(c3cccc(-c4ccccc4)c3)c3ccc4c(c3)c(-c3ccccc3)cc3ccc5oc6ccccc6c5c34)cc2)cc1 ; CC1(C)c2ccccc2-c2ccc(N(c3ccccc3)c3ccc4c(c3)c(-c3ccccc3)cc3ccc5oc6ccccc6c5c34)cc21 ; CC1(C)c2ccccc2-c2ccc(N(c3cccc(-c4ccccc4)c3)c3ccc4c(c3)c(-c3ccccc3)cc3ccc5oc6ccccc6c5c34)cc21]

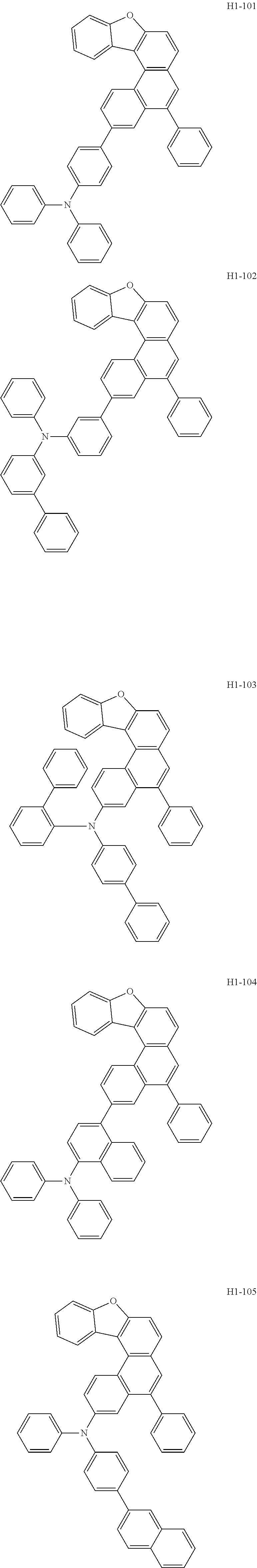

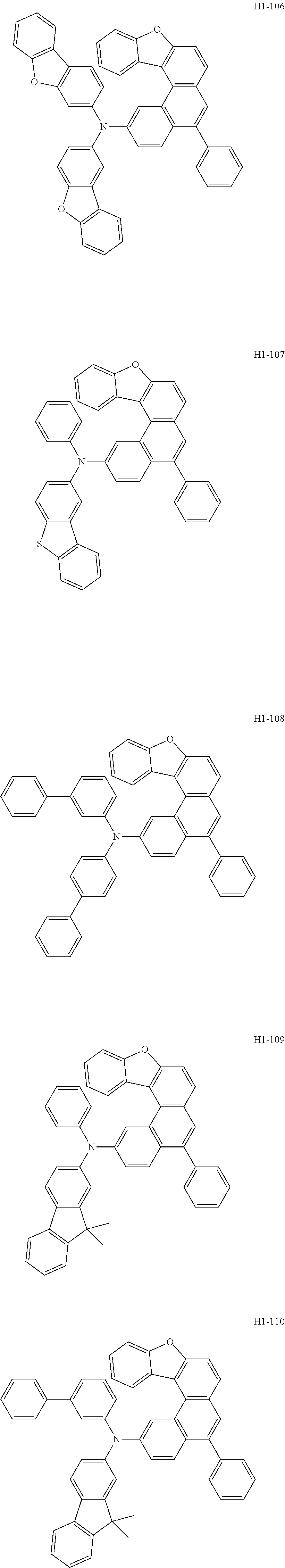 [SMILES: c1ccc(-c2cc3ccc4oc5ccccc5c4c3c3cc(N(c4ccc5c(c4)oc4ccccc45)c4ccc5oc6ccccc6c5c4)ccc23)cc1 ; c1ccc(-c2cc3ccc4oc5ccccc5c4c3c3cc(N(c4ccccc4)c4ccc5sc6ccccc6c5c4)ccc23)cc1 ; c1ccc(-c2ccc(N(c3cccc(-c4ccccc4)c3)c3ccc4c(-c5ccccc5)cc5ccc6oc7ccccc7c6c5c4c3)cc2)cc1 ; CC1(C)c2ccccc2-c2ccc(N(c3ccccc3)c3ccc4c(-c5ccccc5)cc5ccc6oc7ccccc7c6c5c4c3)cc21 ; CC1(C)c2ccccc2-c2ccc(N(c3cccc(-c4ccccc4)c3)c3ccc4c(-c5ccccc5)cc5ccc6oc7ccccc7c6c5c4c3)cc21]

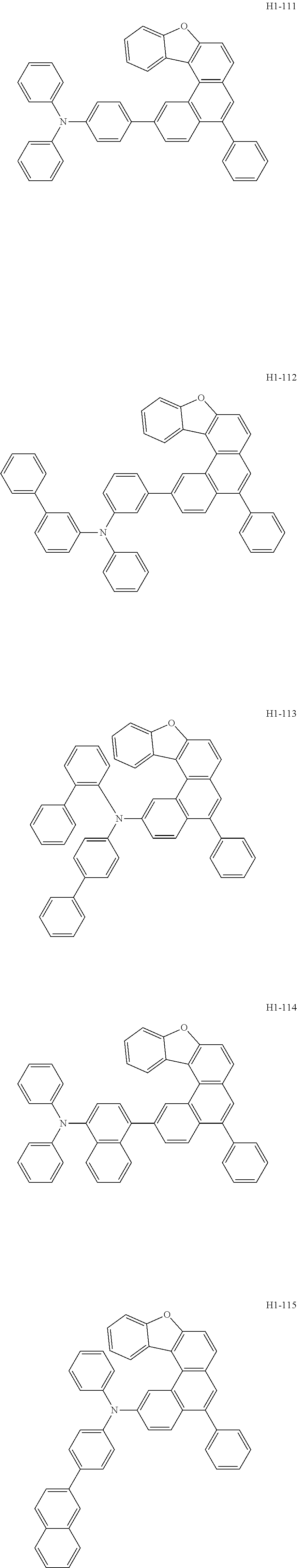 [SMILES: c1ccc(-c2cc3ccc4oc5ccccc5c4c3c3cc(-c4ccc(N(c5ccccc5)c5ccccc5)cc4)ccc23)cc1 ; c1ccc(-c2cccc(N(c3ccccc3)c3cccc(-c4ccc5c(-c6ccccc6)cc6ccc7oc8ccccc8c7c6c5c4)c3)c2)cc1 ; c1ccc(-c2ccc(N(c3ccc4c(-c5ccccc5)cc5ccc6oc7ccccc7c6c5c4c3)c3ccccc3-c3ccccc3)cc2)cc1 ; c1ccc(-c2cc3ccc4oc5ccccc5c4c3c3cc(-c4ccc(N(c5ccccc5)c5ccccc5)c5ccccc45)ccc23)cc1 ; c1ccc(-c2cc3ccc4oc5ccccc5c4c3c3cc(N(c4ccccc4)c4ccc(-c5ccc6ccccc6c5)cc4)ccc23)cc1]

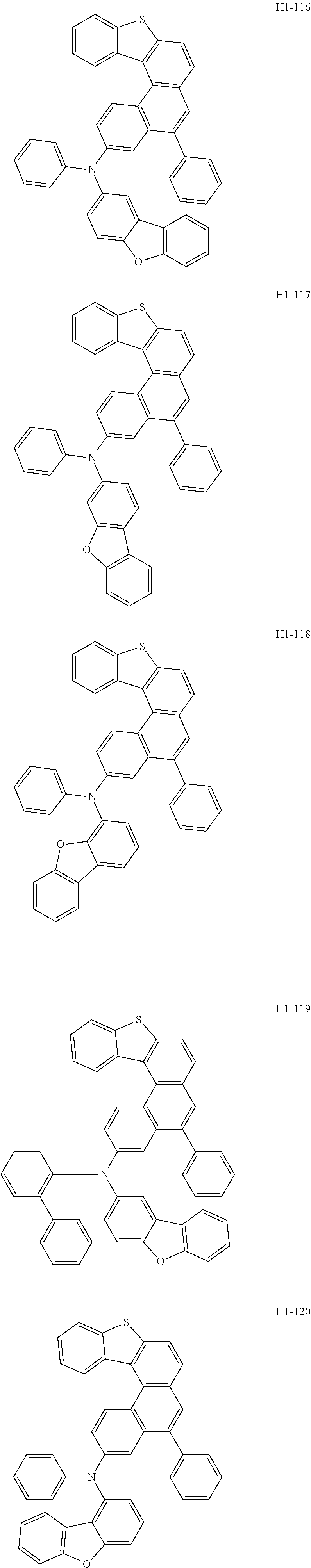 [SMILES: c1ccc(-c2cc3ccc4sc5ccccc5c4c3c3ccc(N(c4ccccc4)c4ccc5oc6ccccc6c5c4)cc23)cc1 ; c1ccc(-c2cc3ccc4sc5ccccc5c4c3c3ccc(N(c4ccccc4)c4ccc5c(c4)oc4ccccc45)cc23)cc1 ; c1ccc(-c2cc3ccc4sc5ccccc5c4c3c3ccc(N(c4ccccc4)c4cccc5c4oc4ccccc45)cc23)cc1 ; c1ccc(-c2ccccc2N(c2ccc3c(c2)c(-c2ccccc2)cc2ccc4sc5ccccc5c4c23)c2ccc3oc4ccccc4c3c2)cc1 ; c1ccc(-c2cc3ccc4sc5ccccc5c4c3c3ccc(N(c4ccccc4)c4cccc5oc6ccccc6c45)cc23)cc1]

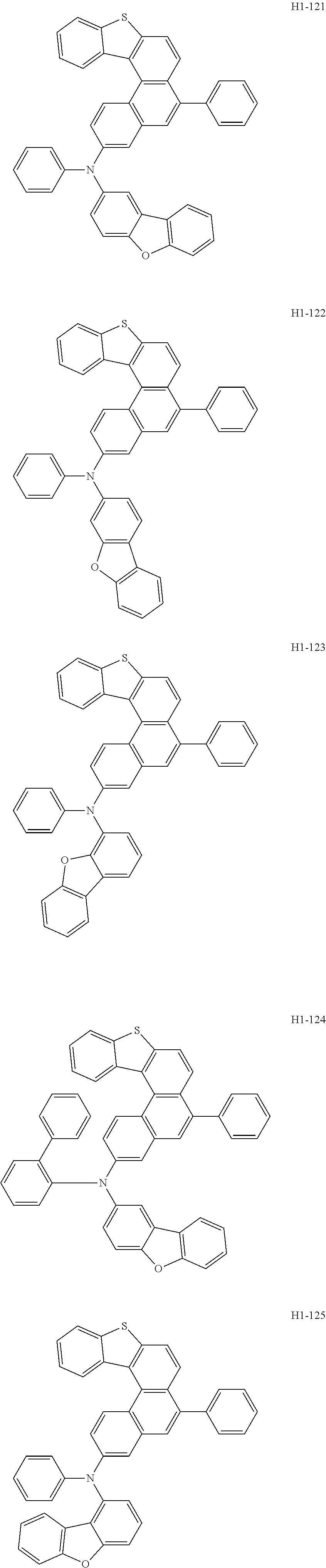 [SMILES: c1ccc(-c2cc3cc(N(c4ccccc4)c4ccc5oc6ccccc6c5c4)ccc3c3c2ccc2sc4ccccc4c23)cc1 ; c1ccc(-c2cc3cc(N(c4ccccc4)c4ccc5c(c4)oc4ccccc45)ccc3c3c2ccc2sc4ccccc4c23)cc1 ; c1ccc(-c2cc3cc(N(c4ccccc4)c4cccc5c4oc4ccccc45)ccc3c3c2ccc2sc4ccccc4c23)cc1 ; c1ccc(-c2ccccc2N(c2ccc3c(c2)cc(-c2ccccc2)c2ccc4sc5ccccc5c4c23)c2ccc3oc4ccccc4c3c2)cc1 ; c1ccc(-c2cc3cc(N(c4ccccc4)c4cccc5oc6ccccc6c45)ccc3c3c2ccc2sc4ccccc4c23)cc1]

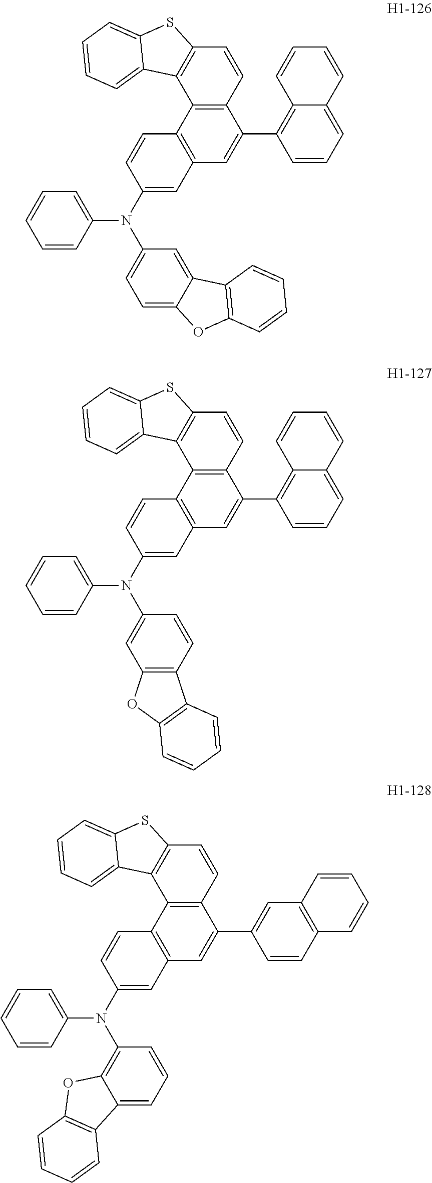 [SMILES: c1ccc(N(c2ccc3c(c2)cc(-c2cccc4ccccc24)c2ccc4sc5ccccc5c4c23)c2ccc3oc4ccccc4c3c2)cc1 ; c1ccc(N(c2ccc3c(c2)cc(-c2cccc4ccccc24)c2ccc4sc5ccccc5c4c23)c2ccc3c(c2)oc2ccccc23)cc1 ; c1ccc(N(c2ccc3c(c2)cc(-c2ccc4ccccc4c2)c2ccc4sc5ccccc5c4c23)c2cccc3c2oc2ccccc23)cc1]

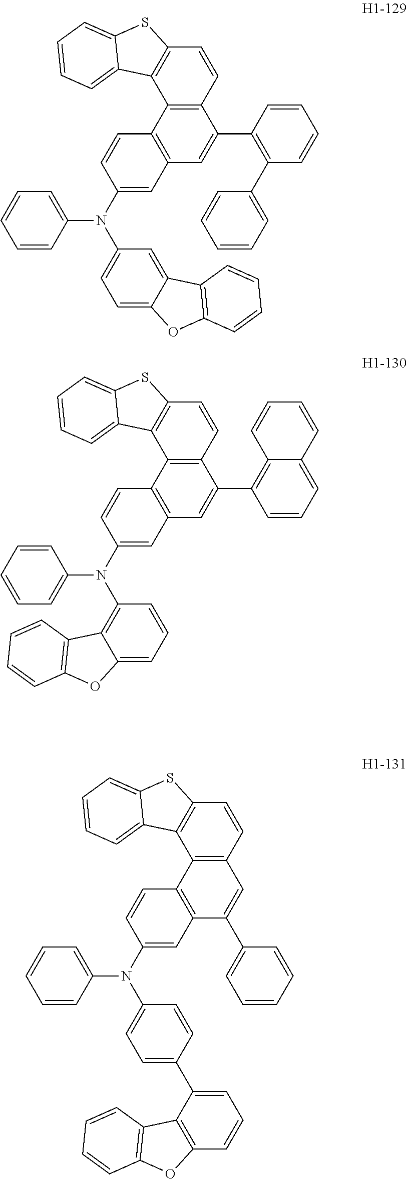 [SMILES: c1ccc(-c2ccccc2-c2cc3cc(N(c4ccccc4)c4ccc5oc6ccccc6c5c4)ccc3c3c2ccc2sc4ccccc4c23)cc1 ; c1ccc(N(c2ccc3c(c2)cc(-c2cccc4ccccc24)c2ccc4sc5ccccc5c4c23)c2cccc3oc4ccccc4c23)cc1 ; c1ccc(-c2cc3ccc4sc5ccccc5c4c3c3ccc(N(c4ccccc4)c4ccc(-c5cccc6oc7ccccc7c56)cc4)cc23)cc1]

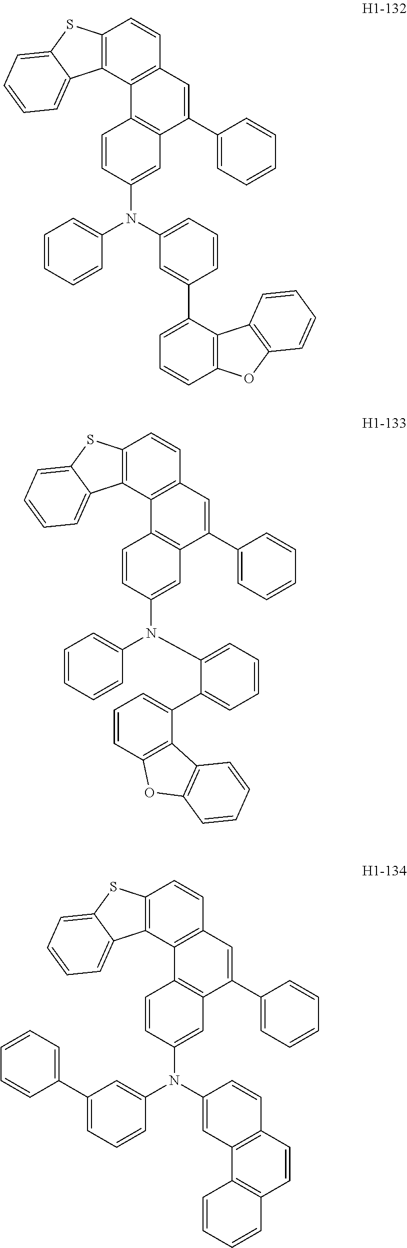 [SMILES: c1ccc(-c2cc3ccc4sc5ccccc5c4c3c3ccc(N(c4ccccc4)c4cccc(-c5cccc6oc7ccccc7c56)c4)cc23)cc1 ; c1ccc(-c2cc3ccc4sc5ccccc5c4c3c3ccc(N(c4ccccc4)c4ccccc4-c4cccc5oc6ccccc6c45)cc23)cc1 ; c1ccc(-c2cccc(N(c3ccc4c(c3)c(-c3ccccc3)cc3ccc5sc6ccccc6c5c34)c3ccc4ccc5ccccc5c4c3)c2)cc1]

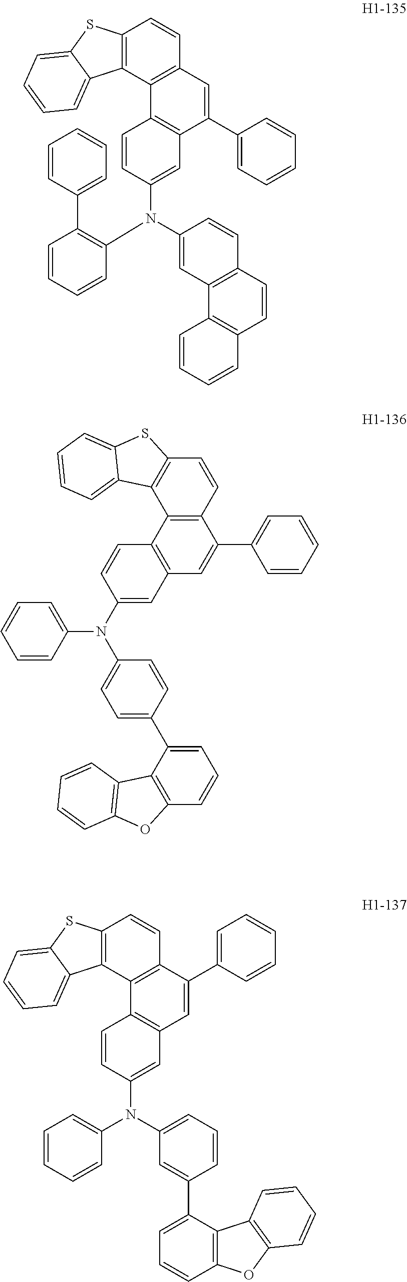 [SMILES: c1ccc(-c2ccccc2N(c2ccc3c(c2)c(-c2ccccc2)cc2ccc4sc5ccccc5c4c23)c2ccc3ccc4ccccc4c3c2)cc1 ; c1ccc(-c2cc3cc(N(c4ccccc4)c4ccc(-c5cccc6oc7ccccc7c56)cc4)ccc3c3c2ccc2sc4ccccc4c23)cc1 ; c1ccc(-c2cc3cc(N(c4ccccc4)c4cccc(-c5cccc6oc7ccccc7c56)c4)ccc3c3c2ccc2sc4ccccc4c23)cc1]

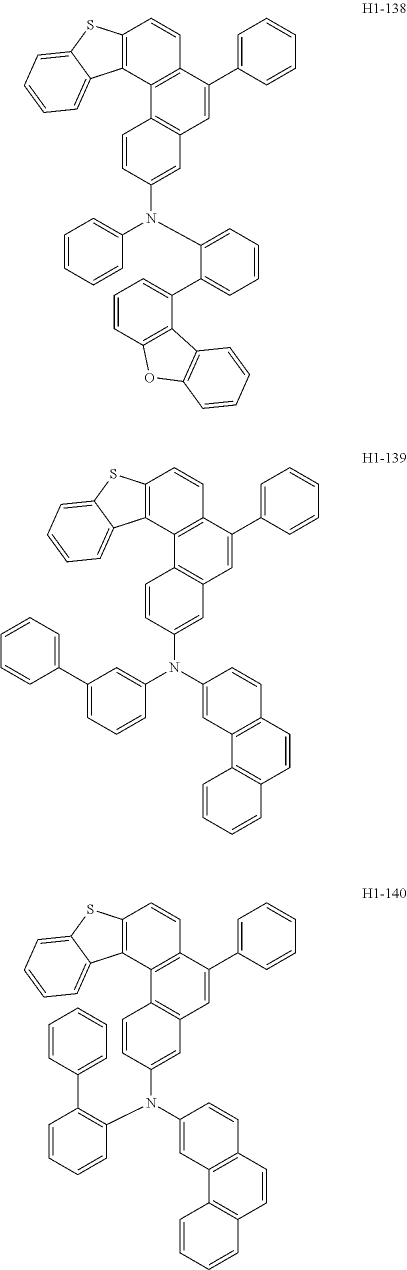 [SMILES: c1ccc(-c2cc3cc(N(c4ccccc4)c4ccccc4-c4cccc5oc6ccccc6c45)ccc3c3c2ccc2sc4ccccc4c23)cc1 ; c1ccc(-c2cccc(N(c3ccc4c(c3)cc(-c3ccccc3)c3ccc5sc6ccccc6c5c34)c3ccc4ccc5ccccc5c4c3)c2)cc1 ; c1ccc(-c2ccccc2N(c2ccc3c(c2)cc(-c2ccccc2)c2ccc4sc5ccccc5c4c23)c2ccc3ccc4ccccc4c3c2)cc1]

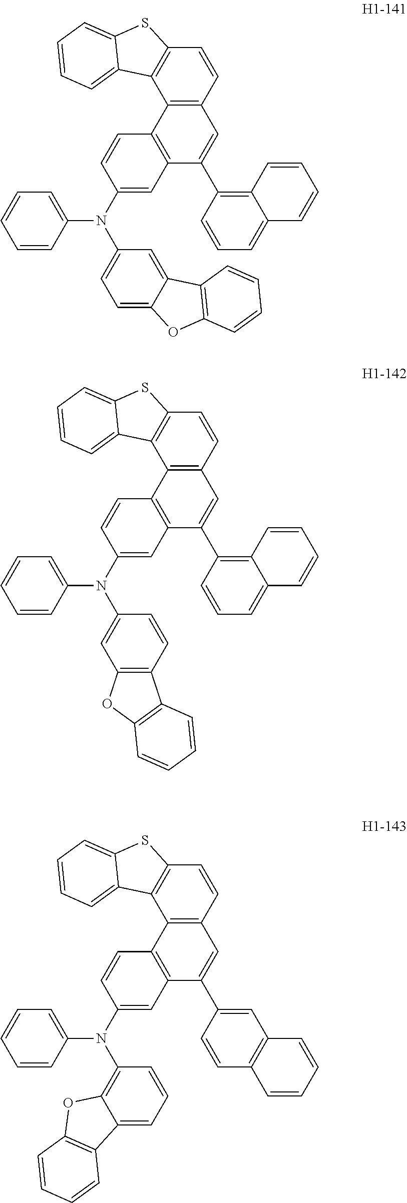 [SMILES: c1ccc(N(c2ccc3c(c2)c(-c2cccc4ccccc24)cc2ccc4sc5ccccc5c4c23)c2ccc3oc4ccccc4c3c2)cc1 ; c1ccc(N(c2ccc3c(c2)oc2ccccc23)c2ccc3c(c2)c(-c2cccc4ccccc24)cc2ccc4sc5ccccc5c4c23)cc1 ; c1ccc(N(c2ccc3c(c2)c(-c2ccc4ccccc4c2)cc2ccc4sc5ccccc5c4c23)c2cccc3c2oc2ccccc23)cc1]

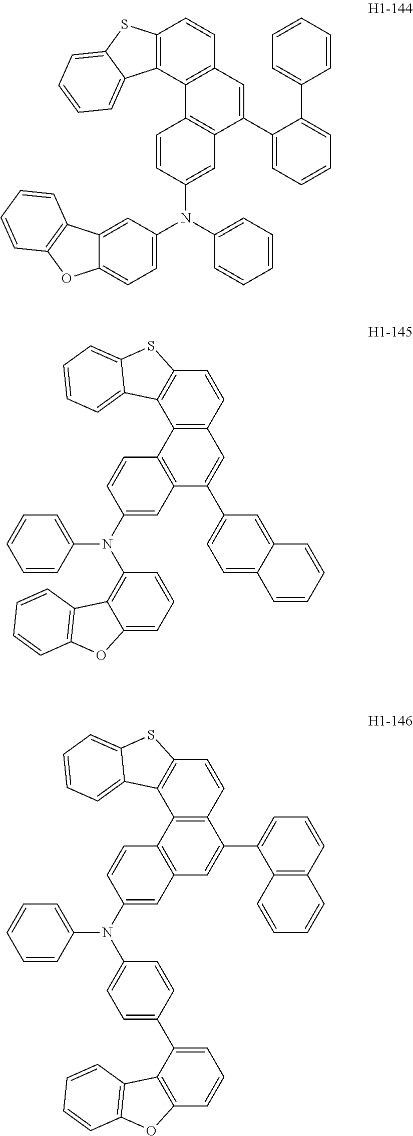 [SMILES: c1ccc(-c2ccccc2-c2cc3ccc4sc5ccccc5c4c3c3ccc(N(c4ccccc4)c4ccc5oc6ccccc6c5c4)cc23)cc1 ; c1ccc(N(c2ccc3c(c2)c(-c2ccc4ccccc4c2)cc2ccc4sc5ccccc5c4c23)c2cccc3oc4ccccc4c23)cc1 ; c1ccc(N(c2ccc(-c3cccc4oc5ccccc5c34)cc2)c2ccc3c(c2)cc(-c2cccc4ccccc24)c2ccc4sc5ccccc5c4c23)cc1]

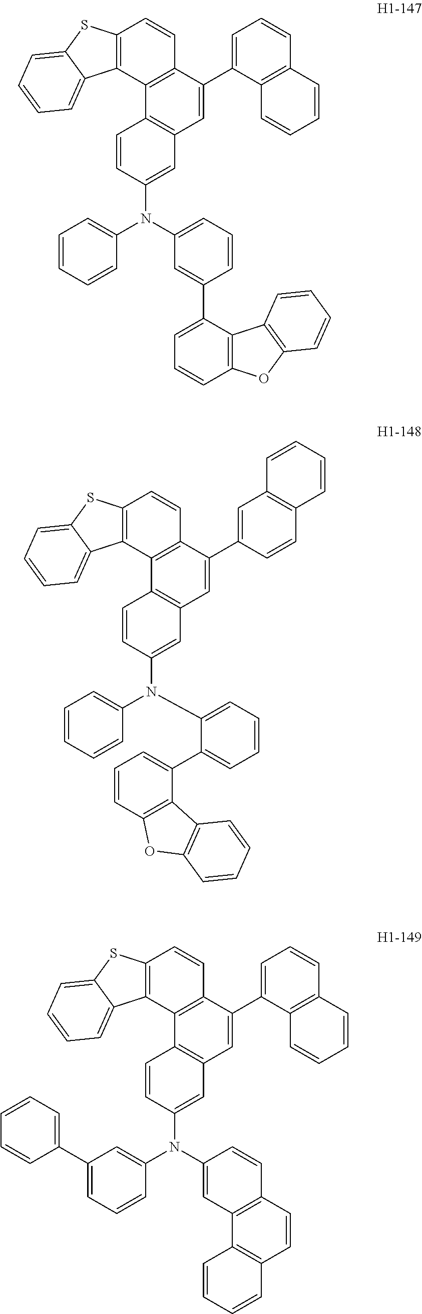 [SMILES: c1ccc(N(c2cccc(-c3cccc4oc5ccccc5c34)c2)c2ccc3c(c2)cc(-c2cccc4ccccc24)c2ccc4sc5ccccc5c4c23)cc1 ; c1ccc(N(c2ccc3c(c2)cc(-c2ccc4ccccc4c2)c2ccc4sc5ccccc5c4c23)c2ccccc2-c2cccc3oc4ccccc4c23)cc1 ; c1ccc(-c2cccc(N(c3ccc4c(c3)cc(-c3cccc5ccccc35)c3ccc5sc6ccccc6c5c34)c3ccc4ccc5ccccc5c4c3)c2)cc1]

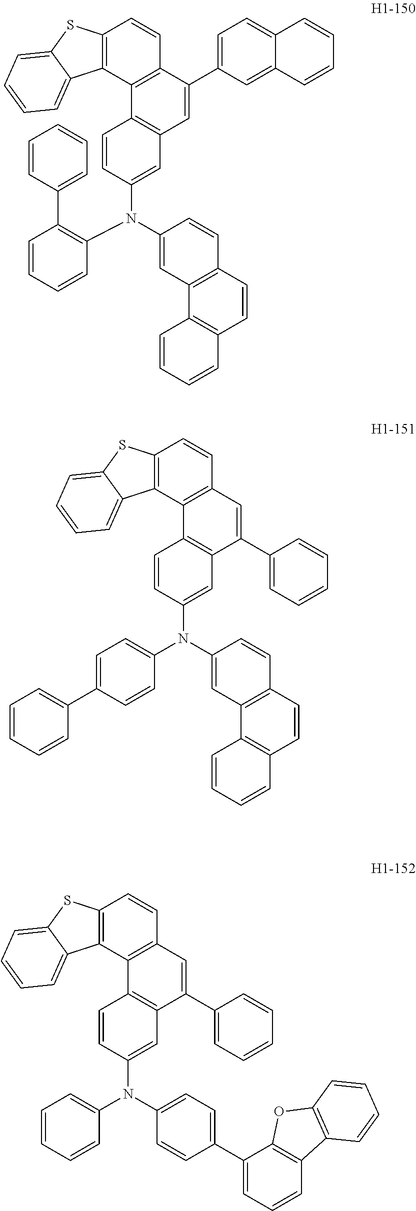 [SMILES: c1ccc(-c2ccccc2N(c2ccc3c(c2)cc(-c2ccc4ccccc4c2)c2ccc4sc5ccccc5c4c23)c2ccc3ccc4ccccc4c3c2)cc1 ; c1ccc(-c2ccc(N(c3ccc4c(c3)c(-c3ccccc3)cc3ccc5sc6ccccc6c5c34)c3ccc4ccc5ccccc5c4c3)cc2)cc1 ; c1ccc(-c2cc3ccc4sc5ccccc5c4c3c3ccc(N(c4ccccc4)c4ccc(-c5cccc6c5oc5ccccc56)cc4)cc23)cc1]

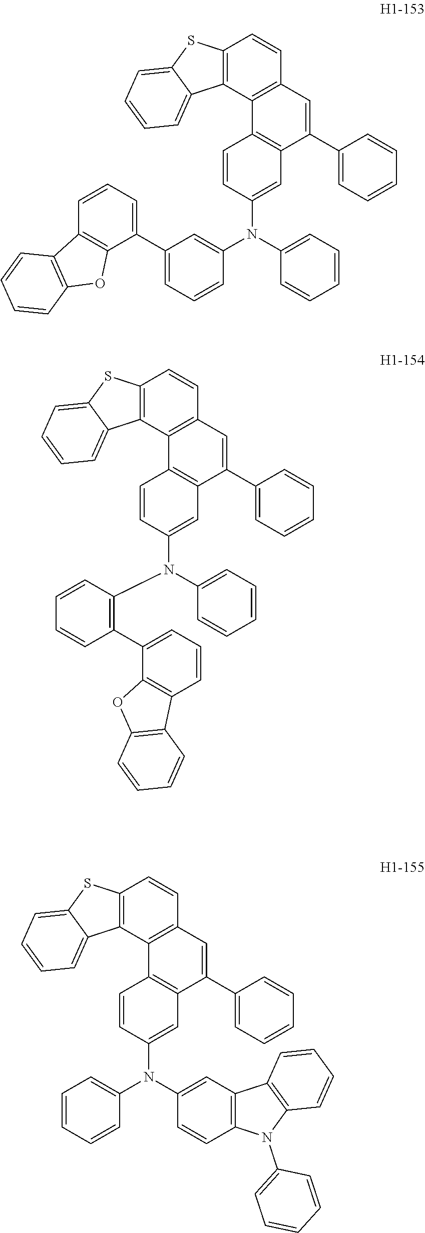 [SMILES: c1ccc(-c2cc3ccc4sc5ccccc5c4c3c3ccc(N(c4ccccc4)c4cccc(-c5cccc6c5oc5ccccc56)c4)cc23)cc1 ; c1ccc(-c2cc3ccc4sc5ccccc5c4c3c3ccc(N(c4ccccc4)c4ccccc4-c4cccc5c4oc4ccccc45)cc23)cc1 ; c1ccc(-c2cc3ccc4sc5ccccc5c4c3c3ccc(N(c4ccccc4)c4ccc5c(c4)c4ccccc4n5-c4ccccc4)cc23)cc1]

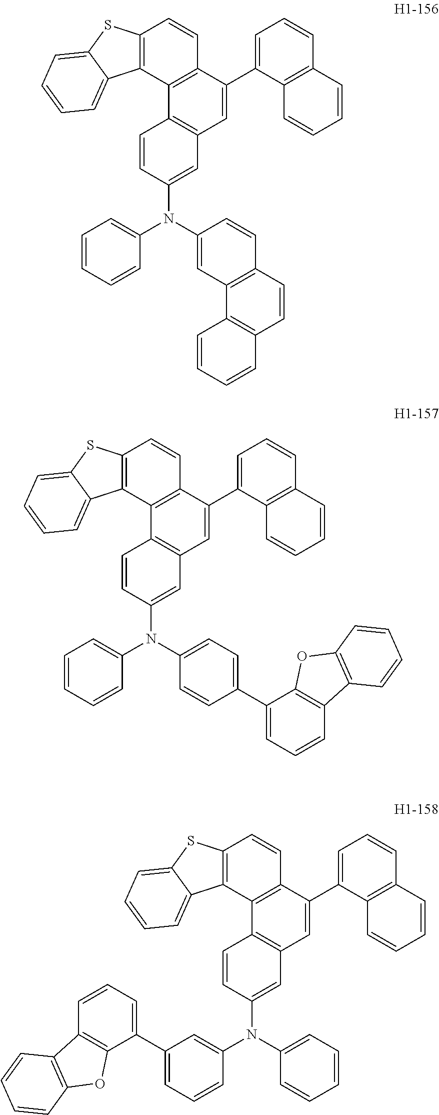 [SMILES: c1ccc(N(c2ccc3c(c2)cc(-c2cccc4ccccc24)c2ccc4sc5ccccc5c4c23)c2ccc3ccc4ccccc4c3c2)cc1 ; c1ccc(N(c2ccc(-c3cccc4c3oc3ccccc34)cc2)c2ccc3c(c2)cc(-c2cccc4ccccc24)c2ccc4sc5ccccc5c4c23)cc1 ; c1ccc(N(c2cccc(-c3cccc4c3oc3ccccc34)c2)c2ccc3c(c2)cc(-c2cccc4ccccc24)c2ccc4sc5ccccc5c4c23)cc1]

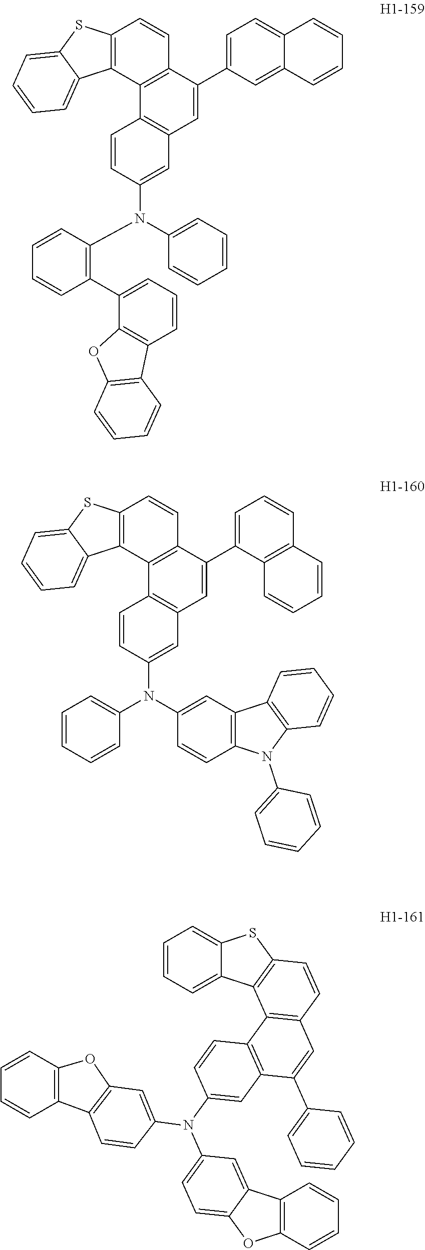 [SMILES: c1ccc(N(c2ccc3c(c2)cc(-c2ccc4ccccc4c2)c2ccc4sc5ccccc5c4c23)c2ccccc2-c2cccc3c2oc2ccccc23)cc1 ; c1ccc(N(c2ccc3c(c2)cc(-c2cccc4ccccc24)c2ccc4sc5ccccc5c4c23)c2ccc3c(c2)c2ccccc2n3-c2ccccc2)cc1 ; c1ccc(-c2cc3ccc4sc5ccccc5c4c3c3ccc(N(c4ccc5c(c4)oc4ccccc45)c4ccc5oc6ccccc6c5c4)cc23)cc1]

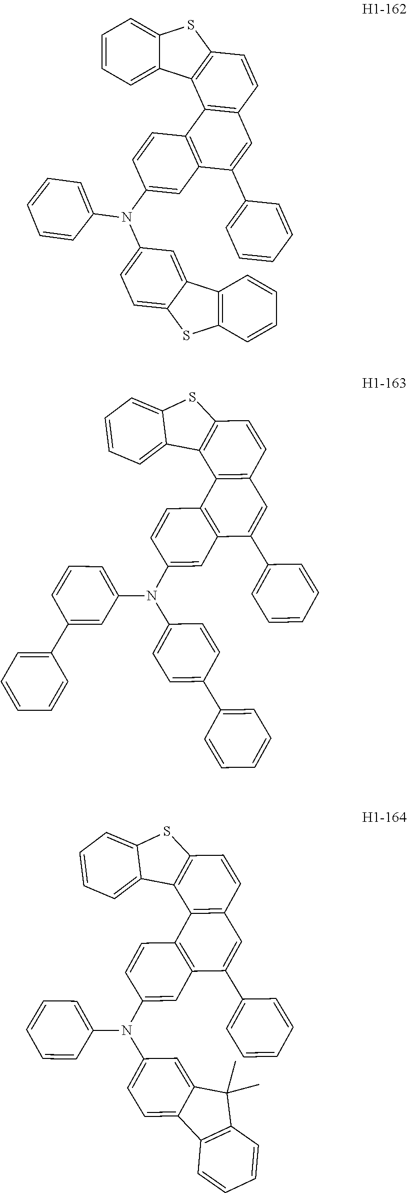 [SMILES: c1ccc(-c2cc3ccc4sc5ccccc5c4c3c3ccc(N(c4ccccc4)c4ccc5sc6ccccc6c5c4)cc23)cc1 ; c1ccc(-c2ccc(N(c3cccc(-c4ccccc4)c3)c3ccc4c(c3)c(-c3ccccc3)cc3ccc5sc6ccccc6c5c34)cc2)cc1 ; CC1(C)c2ccccc2-c2ccc(N(c3ccccc3)c3ccc4c(c3)c(-c3ccccc3)cc3ccc5sc6ccccc6c5c34)cc21]

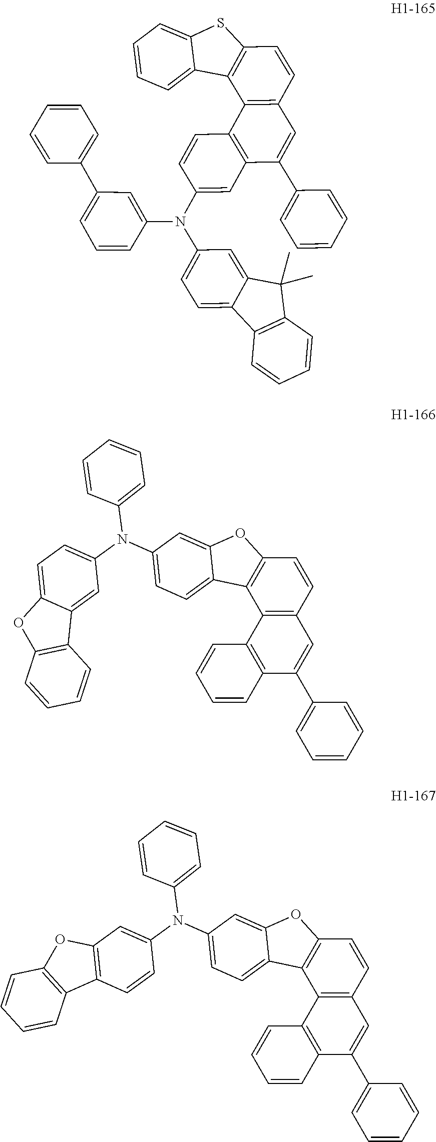 [SMILES: CC1(C)c2ccccc2-c2ccc(N(c3cccc(-c4ccccc4)c3)c3ccc4c(c3)c(-c3ccccc3)cc3ccc5sc6ccccc6c5c34)cc21 ; c1ccc(-c2cc3ccc4oc5cc(N(c6ccccc6)c6ccc7oc8ccccc8c7c6)ccc5c4c3c3ccccc23)cc1 ; c1ccc(-c2cc3ccc4oc5cc(N(c6ccccc6)c6ccc7c(c6)oc6ccccc67)ccc5c4c3c3ccccc23)cc1]

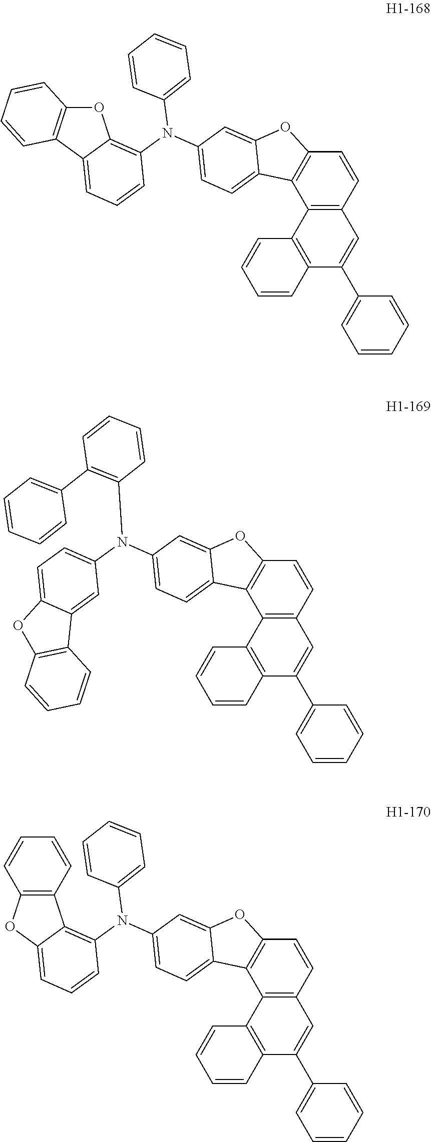 [SMILES: c1ccc(-c2cc3ccc4oc5cc(N(c6ccccc6)c6cccc7c6oc6ccccc67)ccc5c4c3c3ccccc23)cc1 ; c1ccc(-c2ccccc2N(c2ccc3c(c2)oc2ccc4cc(-c5ccccc5)c5ccccc5c4c23)c2ccc3oc4ccccc4c3c2)cc1 ; c1ccc(-c2cc3ccc4oc5cc(N(c6ccccc6)c6cccc7oc8ccccc8c67)ccc5c4c3c3ccccc23)cc1]

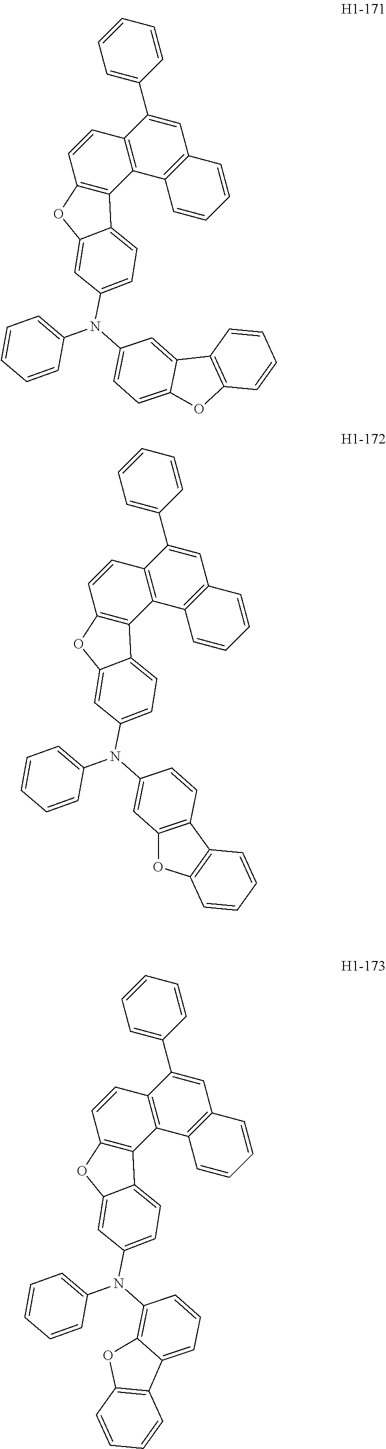

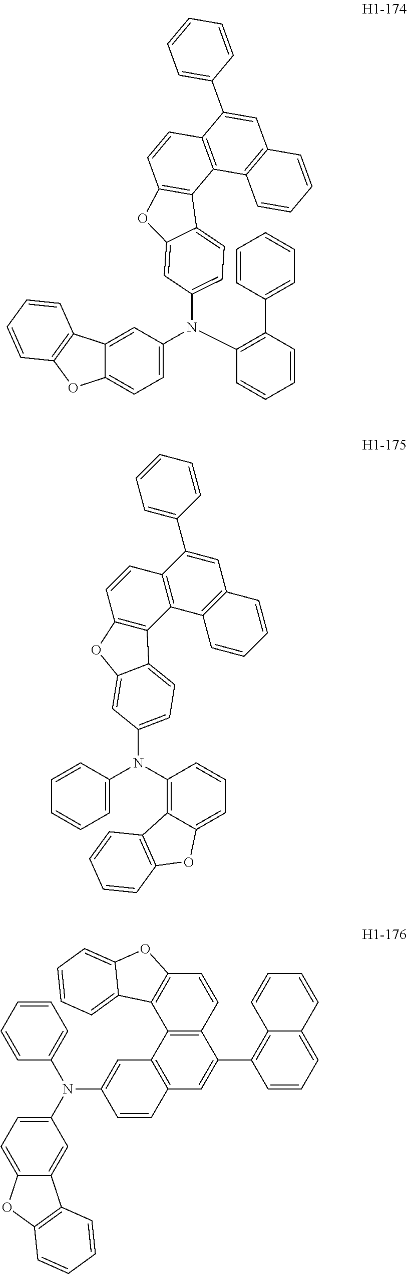 [SMILES: c1ccc(-c2ccccc2N(c2ccc3c(c2)oc2ccc4c(-c5ccccc5)cc5ccccc5c4c23)c2ccc3oc4ccccc4c3c2)cc1 ; c1ccc(-c2cc3ccccc3c3c2ccc2oc4cc(N(c5ccccc5)c5cccc6oc7ccccc7c56)ccc4c23)cc1 ; c1ccc(N(c2ccc3oc4ccccc4c3c2)c2ccc3cc(-c4cccc5ccccc45)c4ccc5oc6ccccc6c5c4c3c2)cc1]

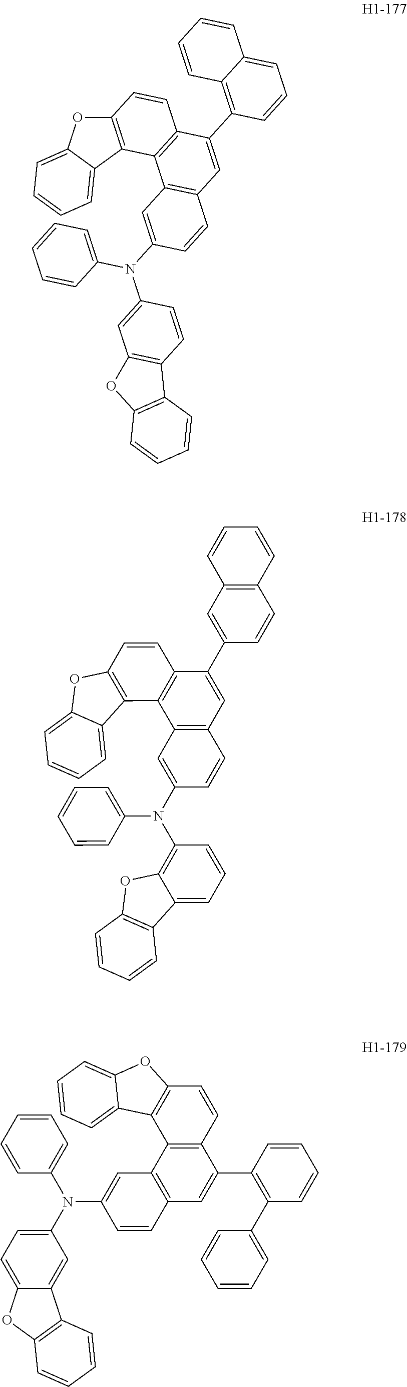 [SMILES: c1ccc(N(c2ccc3c(c2)oc2ccccc23)c2ccc3cc(-c4cccc5ccccc45)c4ccc5oc6ccccc6c5c4c3c2)cc1 ; c1ccc(N(c2ccc3cc(-c4ccc5ccccc5c4)c4ccc5oc6ccccc6c5c4c3c2)c2cccc3c2oc2ccccc23)cc1 ; c1ccc(-c2ccccc2-c2cc3ccc(N(c4ccccc4)c4ccc5oc6ccccc6c5c4)cc3c3c2ccc2oc4ccccc4c23)cc1]

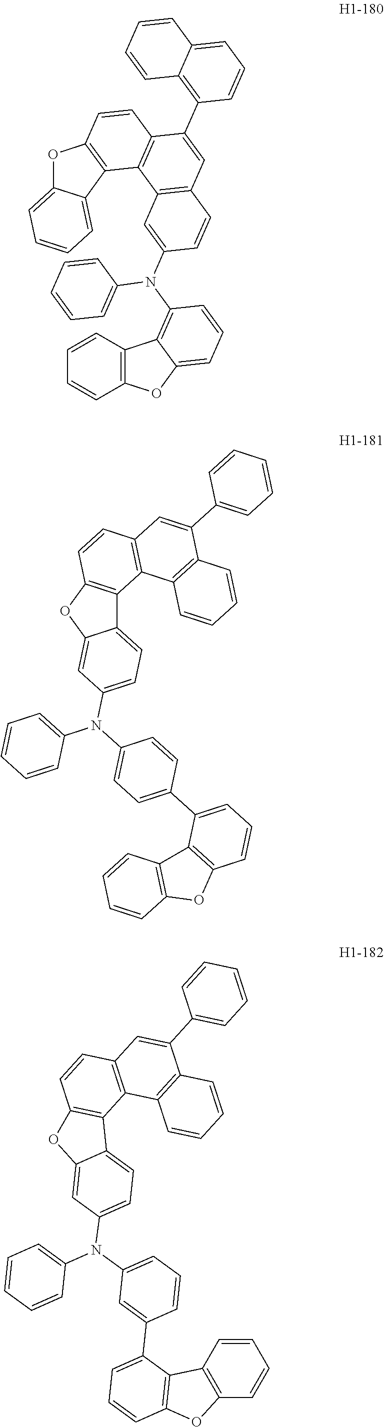 [SMILES: c1ccc(N(c2ccc3cc(-c4cccc5ccccc45)c4ccc5oc6ccccc6c5c4c3c2)c2cccc3oc4ccccc4c23)cc1 ; c1ccc(-c2cc3ccc4oc5cc(N(c6ccccc6)c6ccc(-c7cccc8oc9ccccc9c78)cc6)ccc5c4c3c3ccccc23)cc1 ; c1ccc(-c2cc3ccc4oc5cc(N(c6ccccc6)c6cccc(-c7cccc8oc9ccccc9c78)c6)ccc5c4c3c3ccccc23)cc1]

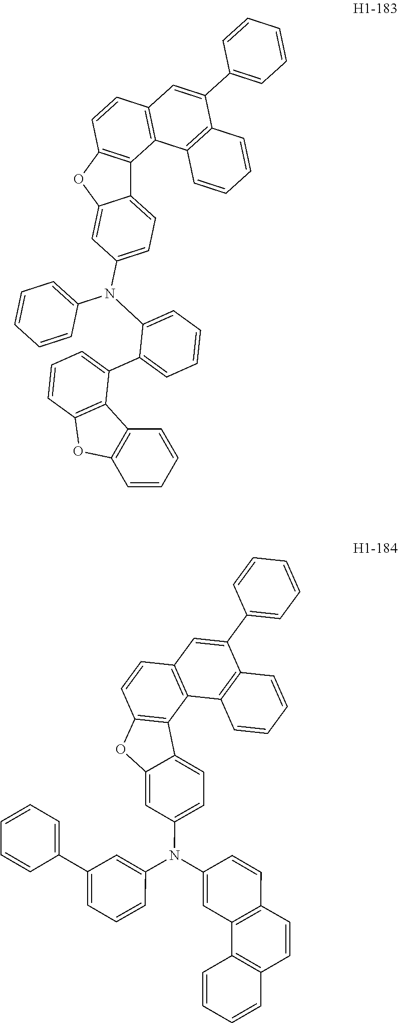 [SMILES: c1ccc(-c2cc3ccc4oc5cc(N(c6ccccc6)c6ccccc6-c6cccc7oc8ccccc8c67)ccc5c4c3c3ccccc23)cc1 ; c1ccc(-c2cccc(N(c3ccc4c(c3)oc3ccc5cc(-c6ccccc6)c6ccccc6c5c34)c3ccc4ccc5ccccc5c4c3)c2)cc1]

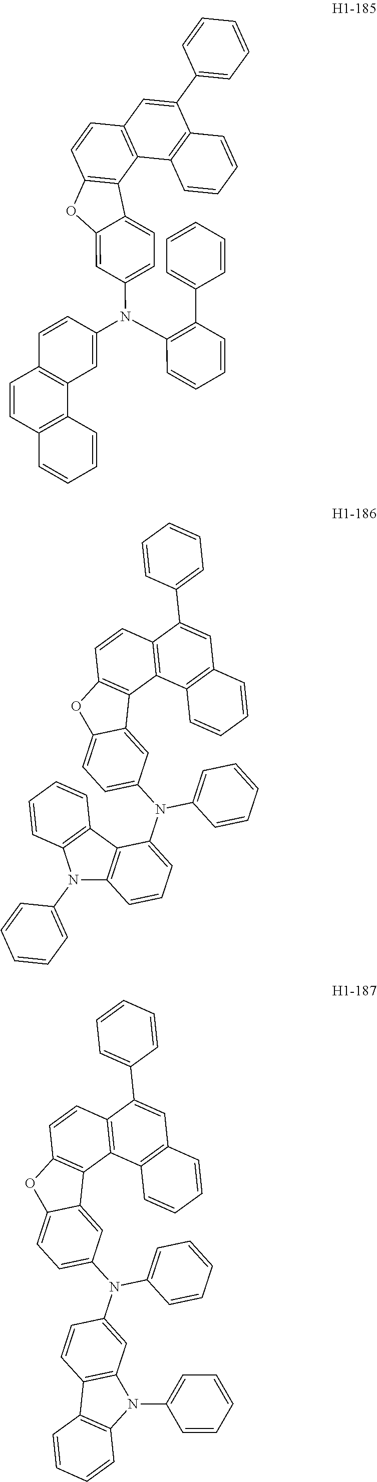 [SMILES: c1ccc(-c2ccccc2N(c2ccc3c(c2)oc2ccc4cc(-c5ccccc5)c5ccccc5c4c23)c2ccc3ccc4ccccc4c3c2)cc1 ; c1ccc(-c2cc3ccccc3c3c2ccc2oc4ccc(N(c5ccccc5)c5cccc6c5c5ccccc5n6-c5ccccc5)cc4c23)cc1 ; c1ccc(-c2cc3ccccc3c3c2ccc2oc4ccc(N(c5ccccc5)c5ccc6c7ccccc7n(-c7ccccc7)c6c5)cc4c23)cc1]

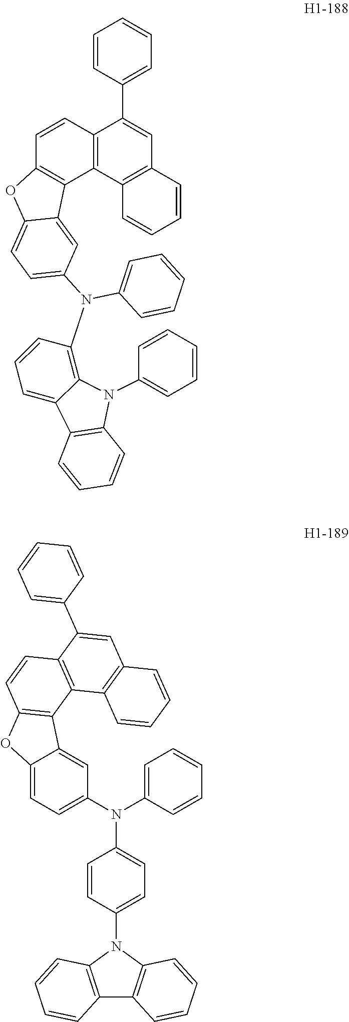 [SMILES: c1ccc(-c2cc3ccccc3c3c2ccc2oc4ccc(N(c5ccccc5)c5cccc6c7ccccc7n(-c7ccccc7)c56)cc4c23)cc1 ; c1ccc(-c2cc3ccccc3c3c2ccc2oc4ccc(N(c5ccccc5)c5ccc(-n6c7ccccc7c7ccccc76)cc5)cc4c23)cc1]

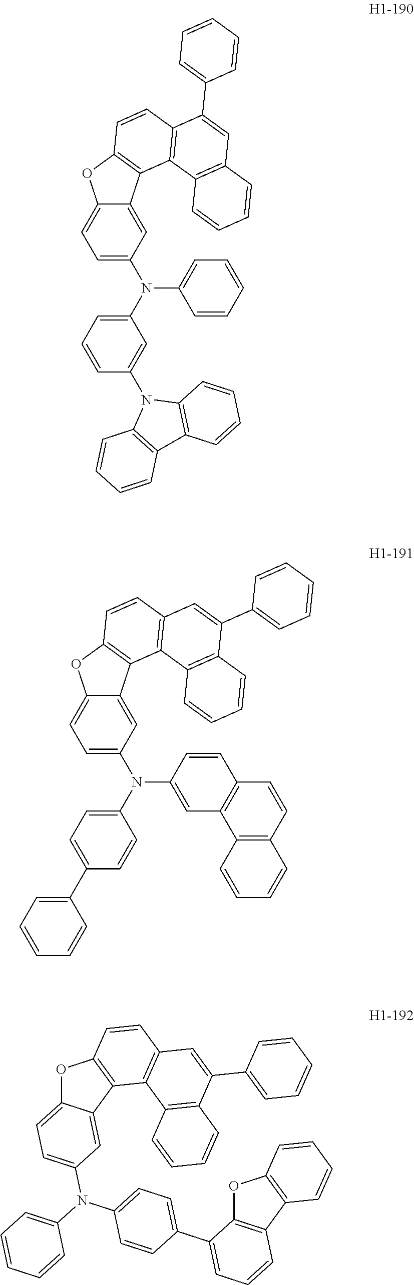 [SMILES: c1ccc(-c2cc3ccccc3c3c2ccc2oc4ccc(N(c5ccccc5)c5cccc(-n6c7ccccc7c7ccccc76)c5)cc4c23)cc1 ; c1ccc(-c2ccc(N(c3ccc4ccc5ccccc5c4c3)c3ccc4oc5ccc6cc(-c7ccccc7)c7ccccc7c6c5c4c3)cc2)cc1 ; c1ccc(-c2cc3ccc4oc5ccc(N(c6ccccc6)c6ccc(-c7cccc8c7oc7ccccc78)cc6)cc5c4c3c3ccccc23)cc1]

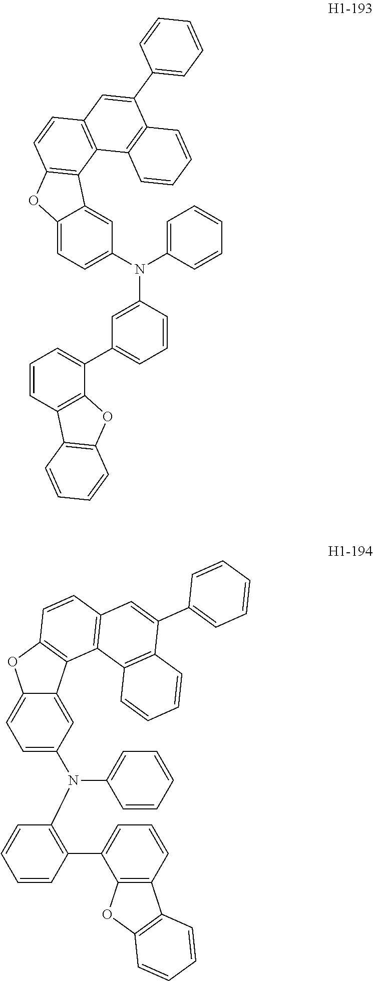 [SMILES: c1ccc(-c2cc3ccc4oc5ccc(N(c6ccccc6)c6cccc(-c7cccc8c7oc7ccccc78)c6)cc5c4c3c3ccccc23)cc1 ; c1ccc(-c2cc3ccc4oc5ccc(N(c6ccccc6)c6ccccc6-c6cccc7c6oc6ccccc67)cc5c4c3c3ccccc23)cc1]

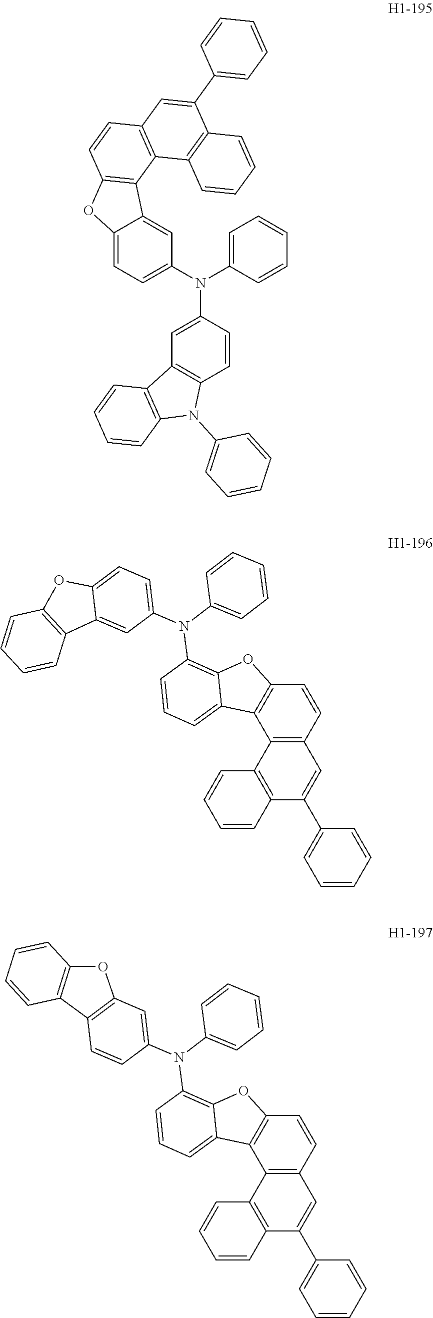 [SMILES: c1ccc(-c2cc3ccc4oc5ccc(N(c6ccccc6)c6ccc7c(c6)c6ccccc6n7-c6ccccc6)cc5c4c3c3ccccc23)cc1 ; c1ccc(-c2cc3ccc4oc5c(N(c6ccccc6)c6ccc7oc8ccccc8c7c6)cccc5c4c3c3ccccc23)cc1 ; c1ccc(-c2cc3ccc4oc5c(N(c6ccccc6)c6ccc7c(c6)oc6ccccc67)cccc5c4c3c3ccccc23)cc1]

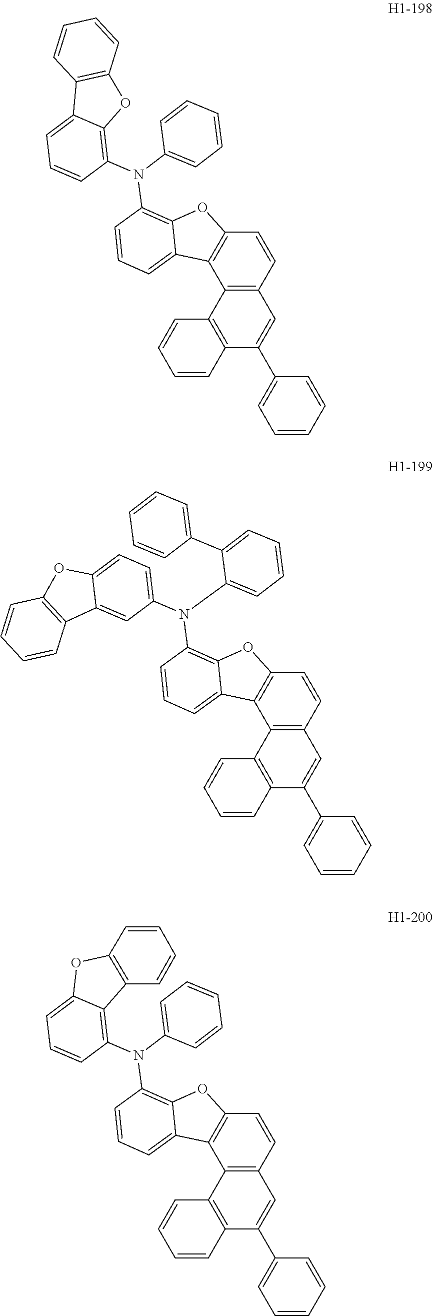 [SMILES: c1ccc(-c2cc3ccc4oc5c(N(c6ccccc6)c6cccc7c6oc6ccccc67)cccc5c4c3c3ccccc23)cc1 ; c1ccc(-c2ccccc2N(c2ccc3oc4ccccc4c3c2)c2cccc3c2oc2ccc4cc(-c5ccccc5)c5ccccc5c4c23)cc1 ; c1ccc(-c2cc3ccc4oc5c(N(c6ccccc6)c6cccc7oc8ccccc8c67)cccc5c4c3c3ccccc23)cc1]

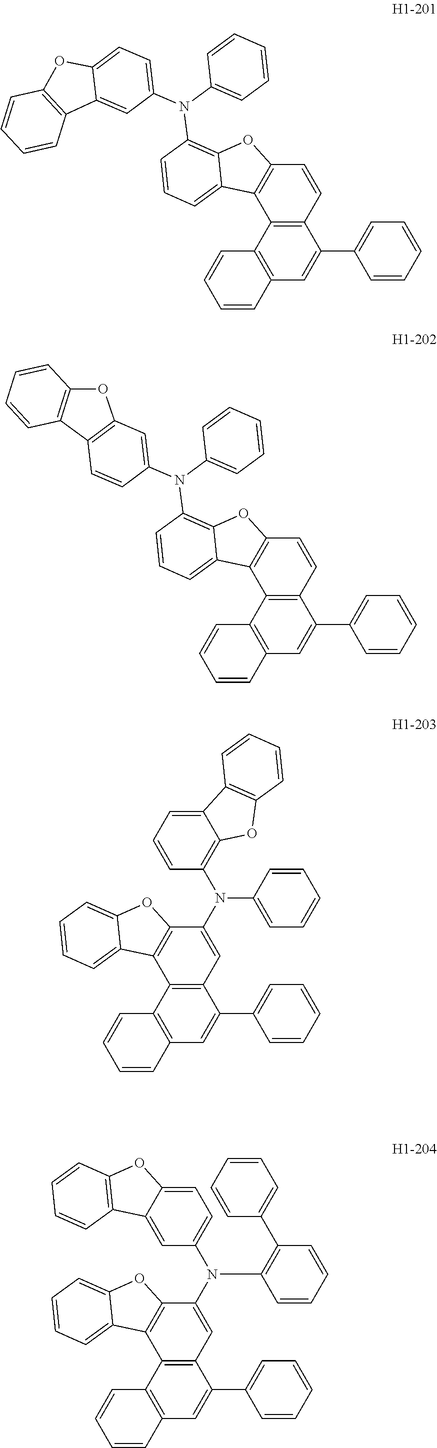 [SMILES: c1ccc(-c2cc3ccccc3c3c2ccc2oc4c(N(c5ccccc5)c5ccc6oc7ccccc7c6c5)cccc4c23)cc1 ; c1ccc(-c2cc3ccccc3c3c2ccc2oc4c(N(c5ccccc5)c5ccc6c(c5)oc5ccccc56)cccc4c23)cc1 ; c1ccc(-c2cc3ccccc3c3c2cc(N(c2ccccc2)c2cccc4c2oc2ccccc24)c2oc4ccccc4c23)cc1 ; c1ccc(-c2ccccc2N(c2ccc3oc4ccccc4c3c2)c2cc3c(-c4ccccc4)cc4ccccc4c3c3c2oc2ccccc23)cc1]

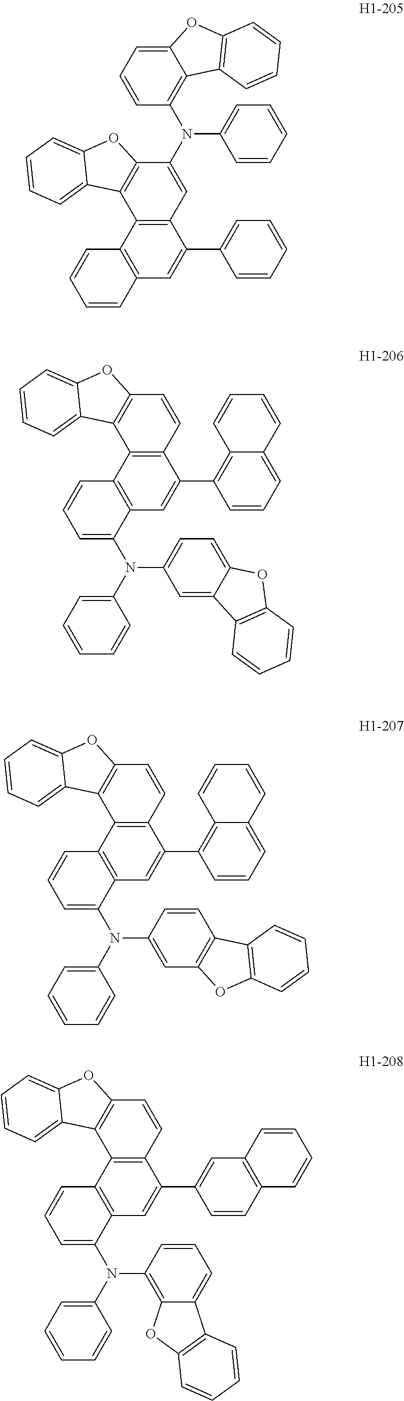 [SMILES: c1ccc(-c2cc3ccccc3c3c2cc(N(c2ccccc2)c2cccc4oc5ccccc5c24)c2oc4ccccc4c23)cc1 ; c1ccc(N(c2ccc3oc4ccccc4c3c2)c2cccc3c2cc(-c2cccc4ccccc24)c2ccc4oc5ccccc5c4c23)cc1 ; c1ccc(N(c2ccc3c(c2)oc2ccccc23)c2cccc3c2cc(-c2cccc4ccccc24)c2ccc4oc5ccccc5c4c23)cc1 ; c1ccc(N(c2cccc3c2cc(-c2ccc4ccccc4c2)c2ccc4oc5ccccc5c4c23)c2cccc3c2oc2ccccc23)cc1]

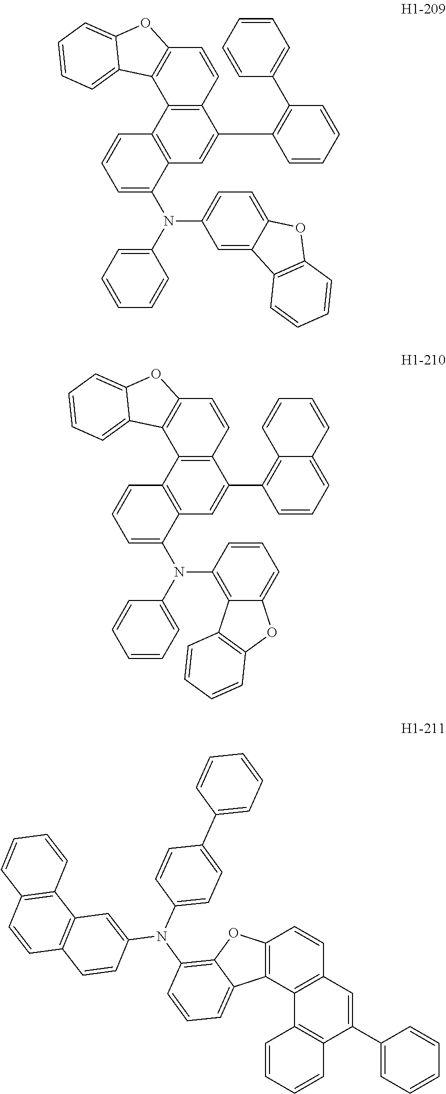 [SMILES: c1ccc(-c2ccccc2-c2cc3c(N(c4ccccc4)c4ccc5oc6ccccc6c5c4)cccc3c3c2ccc2oc4ccccc4c23)cc1 ; c1ccc(N(c2cccc3c2cc(-c2cccc4ccccc24)c2ccc4oc5ccccc5c4c23)c2cccc3oc4ccccc4c23)cc1 ; c1ccc(-c2ccc(N(c3ccc4ccc5ccccc5c4c3)c3cccc4c3oc3ccc5cc(-c6ccccc6)c6ccccc6c5c34)cc2)cc1]

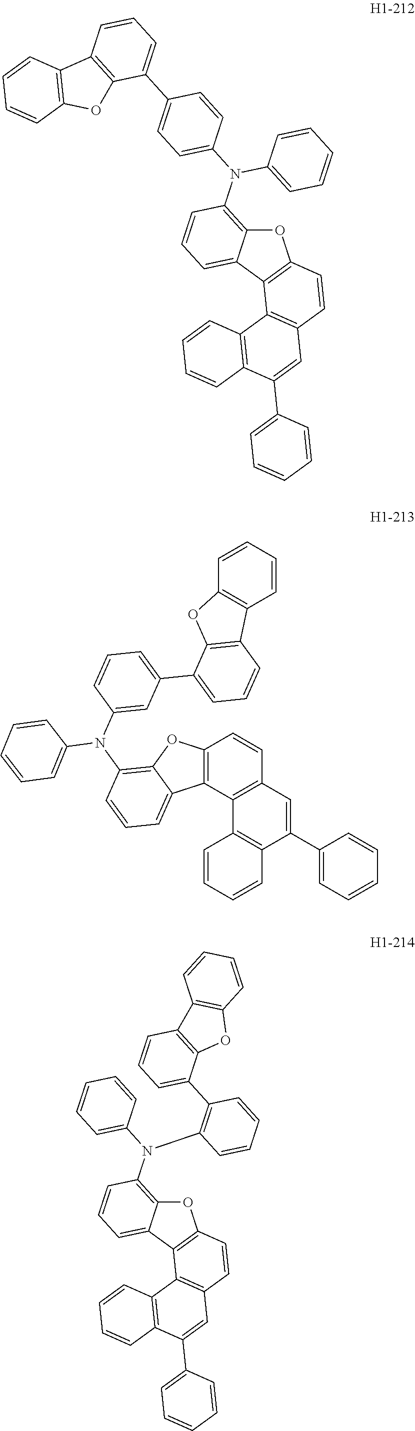 [SMILES: c1ccc(-c2cc3ccc4oc5c(N(c6ccccc6)c6ccc(-c7cccc8c7oc7ccccc78)cc6)cccc5c4c3c3ccccc23)cc1 ; c1ccc(-c2cc3ccc4oc5c(N(c6ccccc6)c6cccc(-c7cccc8c7oc7ccccc78)c6)cccc5c4c3c3ccccc23)cc1 ; c1ccc(-c2cc3ccc4oc5c(N(c6ccccc6)c6ccccc6-c6cccc7c6oc6ccccc67)cccc5c4c3c3ccccc23)cc1]

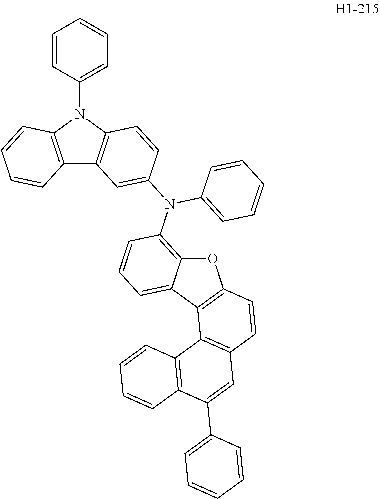 [SMILES: c1ccc(-c2cc3ccc4oc5c(N(c6ccccc6)c6ccc7c(c6)c6ccccc6n7-c6ccccc6)cccc5c4c3c3ccccc23)cc1]

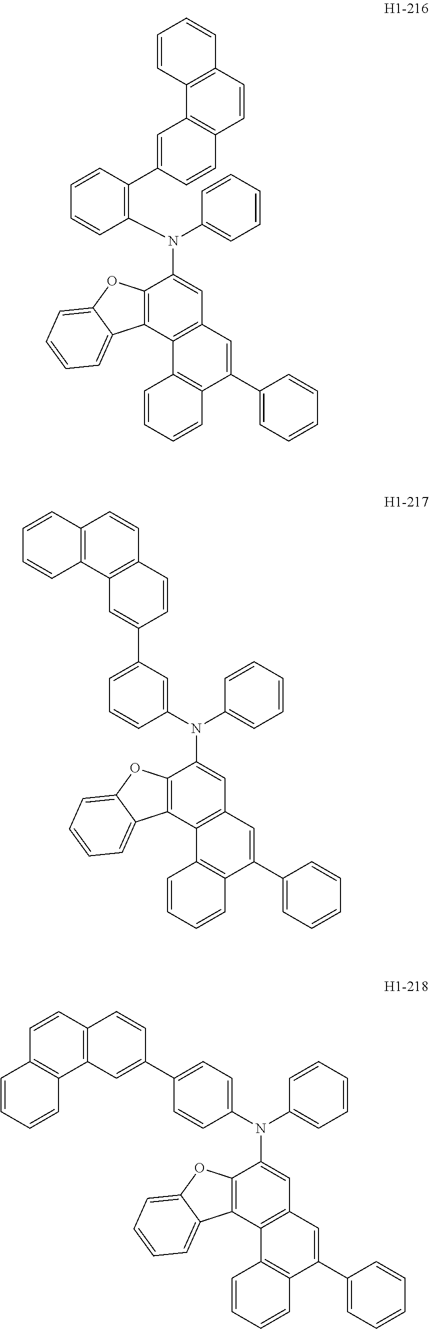 [SMILES: c1ccc(-c2cc3cc(N(c4ccccc4)c4ccccc4-c4ccc5ccc6ccccc6c5c4)c4oc5ccccc5c4c3c3ccccc23)cc1 ; c1ccc(-c2cc3cc(N(c4ccccc4)c4cccc(-c5ccc6ccc7ccccc7c6c5)c4)c4oc5ccccc5c4c3c3ccccc23)cc1 ; c1ccc(-c2cc3cc(N(c4ccccc4)c4ccc(-c5ccc6ccc7ccccc7c6c5)cc4)c4oc5ccccc5c4c3c3ccccc23)cc1]

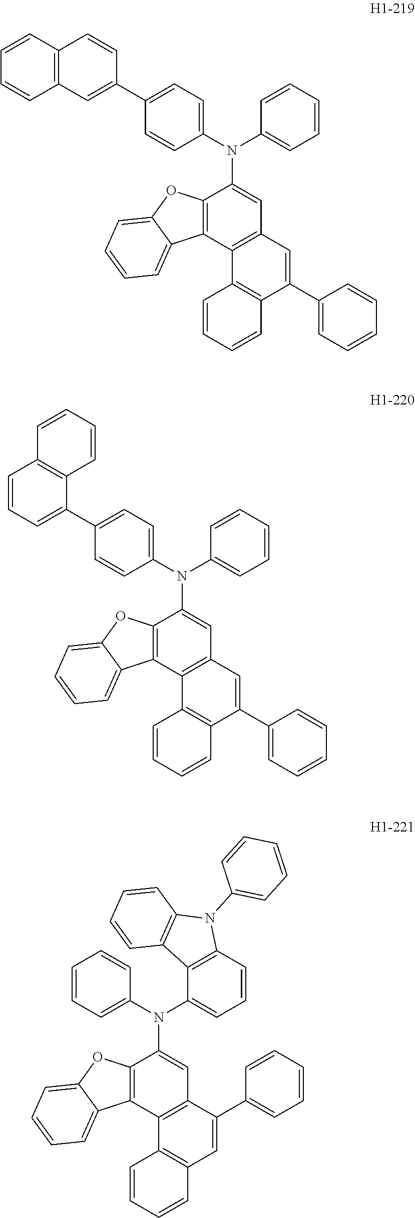 [SMILES: c1ccc(-c2cc3cc(N(c4ccccc4)c4ccc(-c5ccc6ccccc6c5)cc4)c4oc5ccccc5c4c3c3ccccc23)cc1 ; c1ccc(-c2cc3cc(N(c4ccccc4)c4ccc(-c5cccc6ccccc56)cc4)c4oc5ccccc5c4c3c3ccccc23)cc1 ; c1ccc(-c2cc3ccccc3c3c2cc(N(c2ccccc2)c2cccc4c2c2ccccc2n4-c2ccccc2)c2oc4ccccc4c23)cc1]

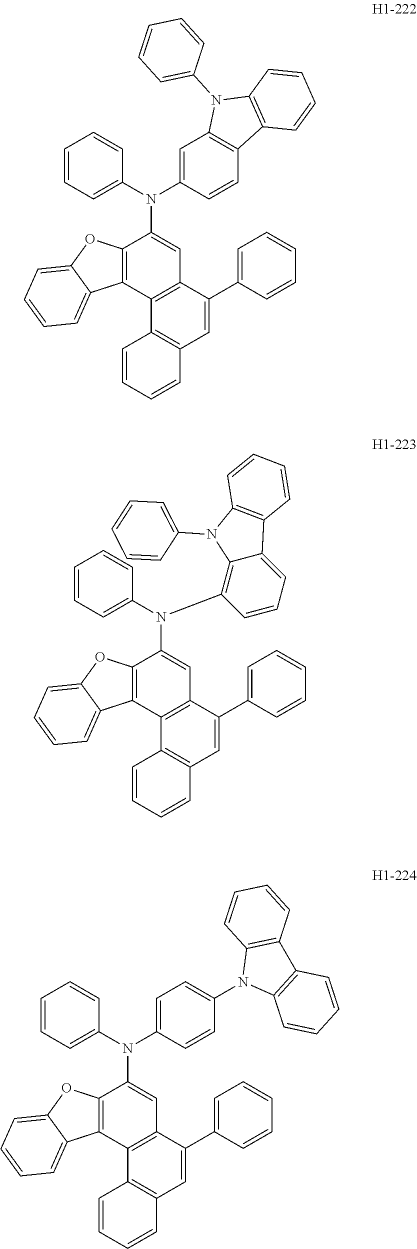 [SMILES: c1ccc(-c2cc3ccccc3c3c2cc(N(c2ccccc2)c2ccc4c5ccccc5n(-c5ccccc5)c4c2)c2oc4ccccc4c23)cc1 ; c1ccc(-c2cc3ccccc3c3c2cc(N(c2ccccc2)c2cccc4c5ccccc5n(-c5ccccc5)c24)c2oc4ccccc4c23)cc1 ; c1ccc(-c2cc3ccccc3c3c2cc(N(c2ccccc2)c2ccc(-n4c5ccccc5c5ccccc54)cc2)c2oc4ccccc4c23)cc1]

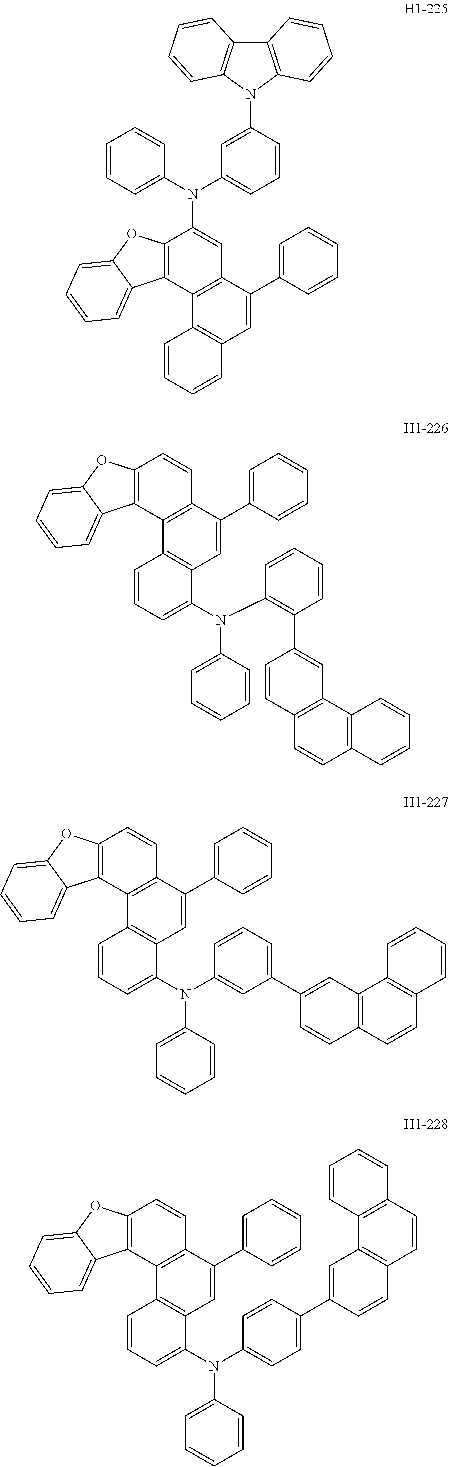 [SMILES: c1ccc(-c2cc3ccccc3c3c2cc(N(c2ccccc2)c2cccc(-n4c5ccccc5c5ccccc54)c2)c2oc4ccccc4c23)cc1 ; c1ccc(-c2cc3c(N(c4ccccc4)c4ccccc4-c4ccc5ccc6ccccc6c5c4)cccc3c3c2ccc2oc4ccccc4c23)cc1 ; c1ccc(-c2cc3c(N(c4ccccc4)c4cccc(-c5ccc6ccc7ccccc7c6c5)c4)cccc3c3c2ccc2oc4ccccc4c23)cc1 ; c1ccc(-c2cc3c(N(c4ccccc4)c4ccc(-c5ccc6ccc7ccccc7c6c5)cc4)cccc3c3c2ccc2oc4ccccc4c23)cc1]

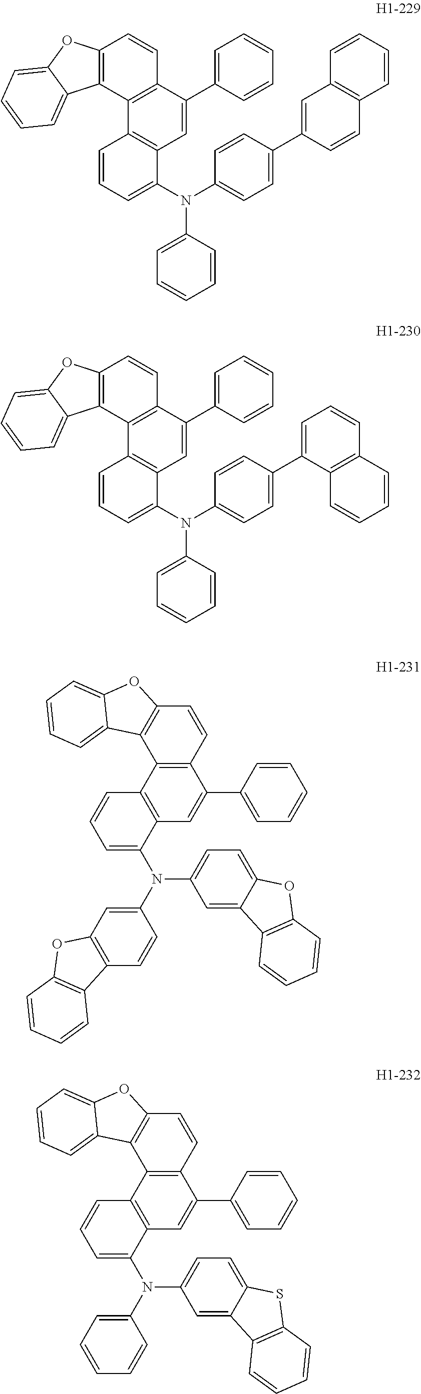

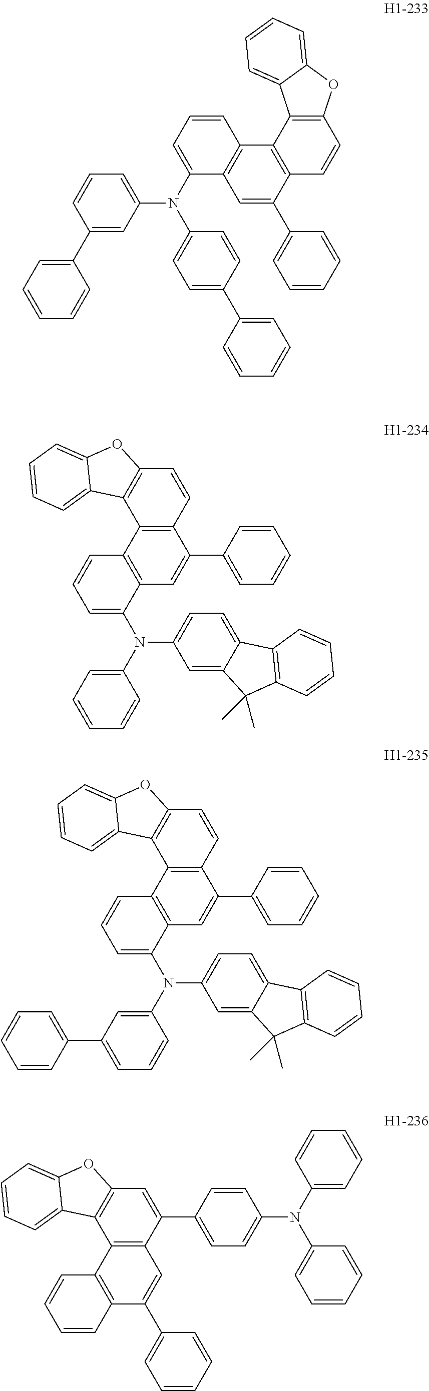 [SMILES: c1ccc(-c2ccc(N(c3cccc(-c4ccccc4)c3)c3cccc4c3cc(-c3ccccc3)c3ccc5oc6ccccc6c5c34)cc2)cc1 ; CC1(C)c2ccccc2-c2ccc(N(c3ccccc3)c3cccc4c3cc(-c3ccccc3)c3ccc5oc6ccccc6c5c34)cc21 ; CC1(C)c2ccccc2-c2ccc(N(c3cccc(-c4ccccc4)c3)c3cccc4c3cc(-c3ccccc3)c3ccc5oc6ccccc6c5c34)cc21 ; c1ccc(-c2cc3c(-c4ccc(N(c5ccccc5)c5ccccc5)cc4)cc4oc5ccccc5c4c3c3ccccc23)cc1]

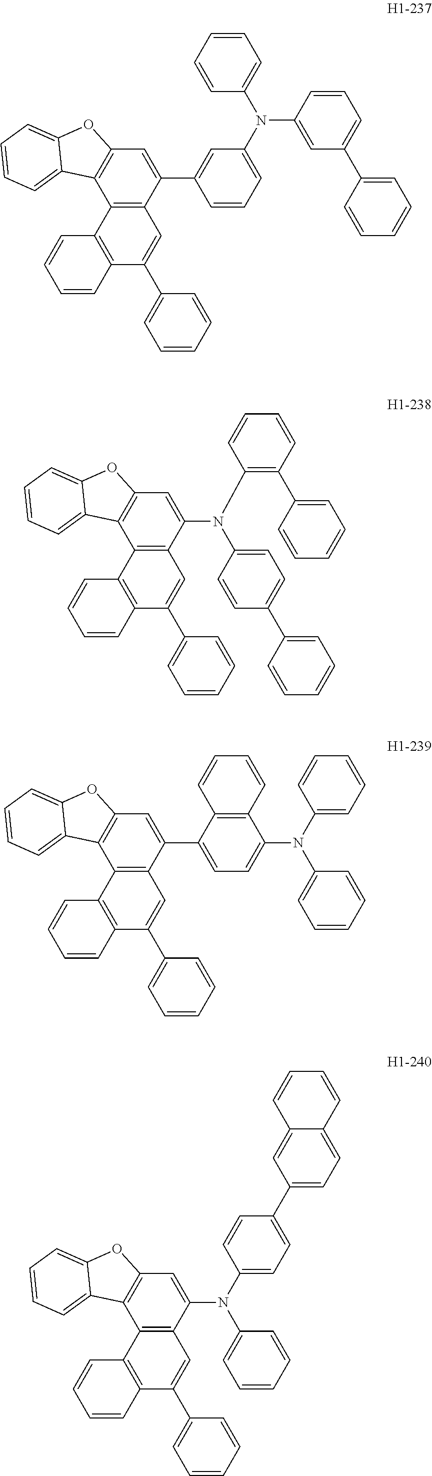 [SMILES: c1ccc(-c2cccc(N(c3ccccc3)c3cccc(-c4cc5oc6ccccc6c5c5c4cc(-c4ccccc4)c4ccccc45)c3)c2)cc1 ; c1ccc(-c2ccc(N(c3ccccc3-c3ccccc3)c3cc4oc5ccccc5c4c4c3cc(-c3ccccc3)c3ccccc34)cc2)cc1 ; c1ccc(-c2cc3c(-c4ccc(N(c5ccccc5)c5ccccc5)c5ccccc45)cc4oc5ccccc5c4c3c3ccccc23)cc1 ; c1ccc(-c2cc3c(N(c4ccccc4)c4ccc(-c5ccc6ccccc6c5)cc4)cc4oc5ccccc5c4c3c3ccccc23)cc1]

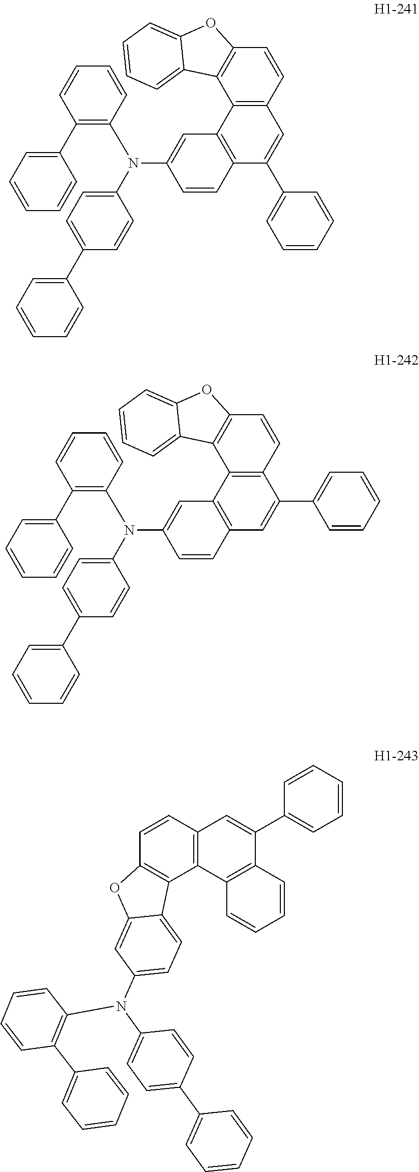 [SMILES: c1ccc(-c2ccc(N(c3ccc4c(-c5ccccc5)cc5ccc6oc7ccccc7c6c5c4c3)c3ccccc3-c3ccccc3)cc2)cc1 ; c1ccc(-c2ccc(N(c3ccc4cc(-c5ccccc5)c5ccc6oc7ccccc7c6c5c4c3)c3ccccc3-c3ccccc3)cc2)cc1 ; c1ccc(-c2ccc(N(c3ccc4c(c3)oc3ccc5cc(-c6ccccc6)c6ccccc6c5c34)c3ccccc3-c3ccccc3)cc2)cc1]

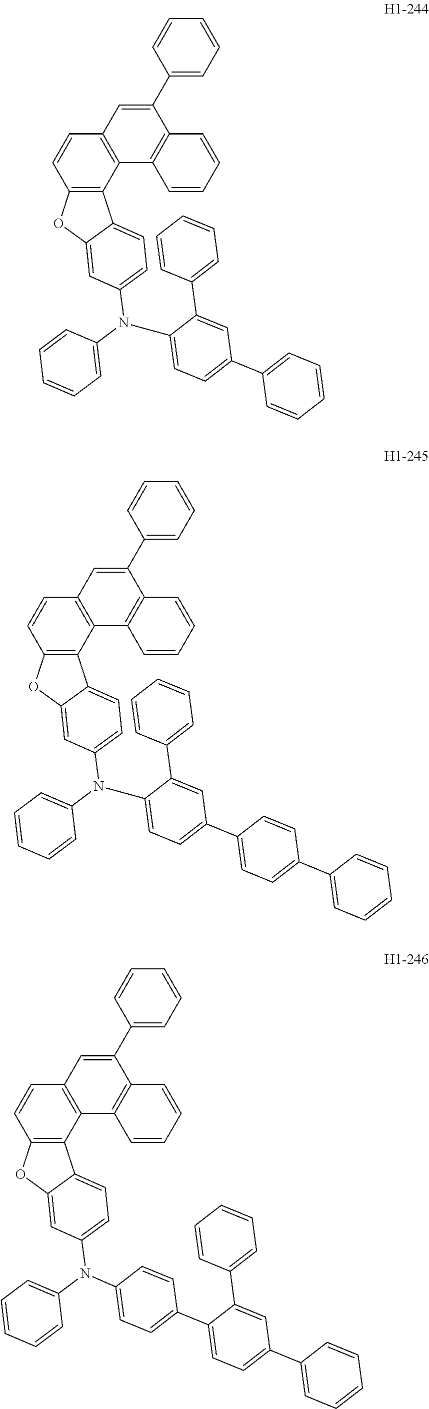 [SMILES: c1ccc(-c2ccc(N(c3ccccc3)c3ccc4c(c3)oc3ccc5cc(-c6ccccc6)c6ccccc6c5c34)c(-c3ccccc3)c2)cc1 ; c1ccc(-c2ccc(-c3ccc(N(c4ccccc4)c4ccc5c(c4)oc4ccc6cc(-c7ccccc7)c7ccccc7c6c45)c(-c4ccccc4)c3)cc2)cc1 ; c1ccc(-c2ccc(-c3ccc(N(c4ccccc4)c4ccc5c(c4)oc4ccc6cc(-c7ccccc7)c7ccccc7c6c45)cc3)c(-c3ccccc3)c2)cc1]

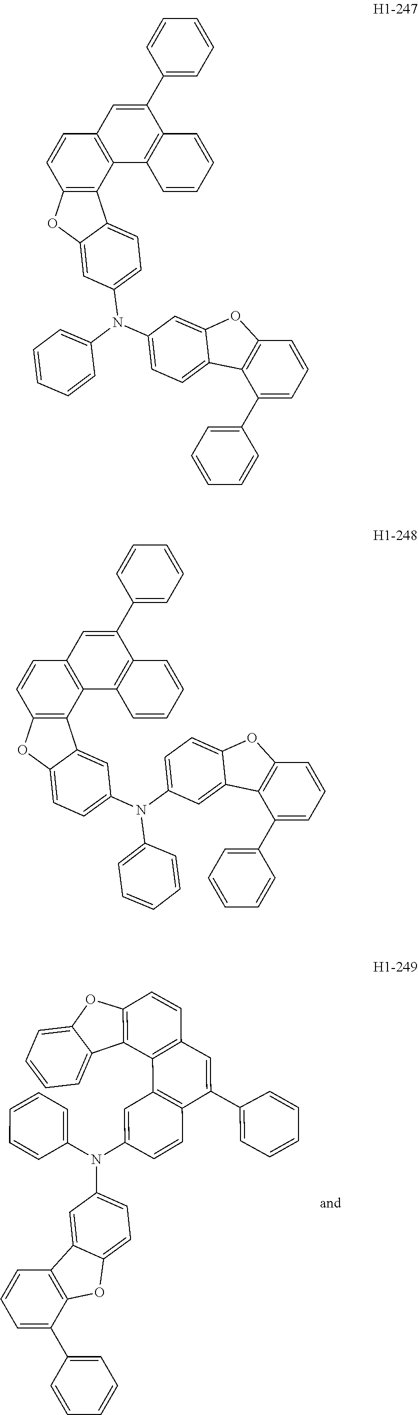 [SMILES: c1ccc(-c2cc3ccc4oc5cc(N(c6ccccc6)c6ccc7c(c6)oc6cccc(-c8ccccc8)c67)ccc5c4c3c3ccccc23)cc1 ; c1ccc(-c2cc3ccc4oc5ccc(N(c6ccccc6)c6ccc7oc8cccc(-c9ccccc9)c8c7c6)cc5c4c3c3ccccc23)cc1 ; c1ccc(-c2cc3ccc4oc5ccccc5c4c3c3cc(N(c4ccccc4)c4ccc5oc6c(-c7ccccc7)cccc6c5c4)ccc23)cc1]

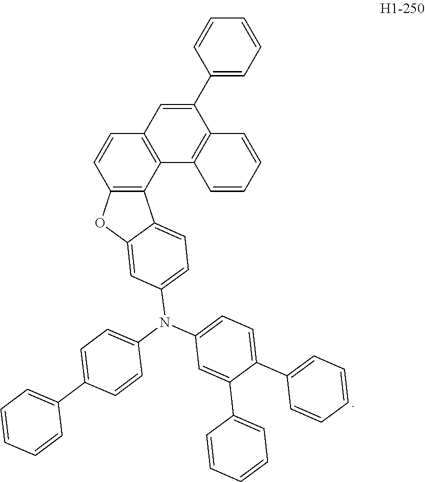 [SMILES: c1ccc(-c2ccc(N(c3ccc(-c4ccccc4)c(-c4ccccc4)c3)c3ccc4c(c3)oc3ccc5cc(-c6ccccc6)c6ccccc6c5c34)cc2)cc1]

12. An organic electroluminescent device comprising an organic electroluminescent compound according to claim 9.
